(19) United States
(12) Patent Application Publication
(10) Pub. No.: US 2019/0322928 A1
(43) Pub. Date: Oct. 24, 2019

(54) TETRADENTATE CYCLIC-METAL PLATINUM COMPLEXES COMPRISING 6-SUBSTITUTED CARBAZOLE, PRERATION AND USE THEREOF

(71) Applicants: Zhejiang University of Technology, Hangzhou (CN); AAC Microtech (Changzhou) Co., Ltd., Changzhou (CN)

(72) Inventors: Guijie Li, Shenzhen (CN); Jianxin Dai, Shenzhen (CN); Yuanbin She, Shenzhen (CN); Shaohai Chen, Shenzhen (CN)

(21) Appl. No.: 16/112,877

(22) Filed: Aug. 27, 2018

(30) Foreign Application Priority Data
Apr. 23, 2018 (CN) 201810368265.5

(51) Int. Cl. C09K 11/06; H01L 51/50

(52) U.S. Cl. CPC C09K 11/06; C09K 2211/185; C09K 2211/1044; H01L 51/5016

(57) ABSTRACT

The present disclosure relates to the field of blue phosphorescent tetradentate cyclic-metal platinum complex luminescent material, and discloses a blue phosphorescent tetradentate cyclic-metal platinum complex comprising 6-substituted carbazole, preparation and uses thereof. The complex may be a delayed fluorescence and/or phosphorescent emitter. The complex has high thermal decomposition temperature, high quantum effect, and could perform blue light emitting and have a narrower emission spectrum, therefore there are a huge application prospects in the field of blue light, especially in deep blue phosphorescent material field.

### CROSS-REFERENCE TO RELATED APPLICATIONS

This application claims the priority benefit of Chinese Patent Applications Ser. No. 201810368265.5 filed on Apr. 23, 2018, the entire content of which is incorporated herein by reference.

### FIELD OF THE PRESENT DISCLOSURE

The present disclosure generally relates to the field of blue phosphorescent tetradentate cyclic-metal platinum complex luminescent materials, in particular to a blue phosphorescent tetradentate cyclic-metal platinum complex comprising 6-substituted carbazole.

### DESCRIPTION OF RELATED ART

Compound capable of light absorbing and/or emitting may be ideally suited for a variety of optical and electroluminescent device, for example, including a light absorbing device such as a solar absorbing device and a photosensitive device, an organic light emitting diode (OLED), a light emitting device, or a device that can be capable of light-absorbing and light-emitting and can be used as marker for biological applications. Many studies have focused on the finding and optimizing organic and organometallic materials for using in the optical and electroluminescence device. In general, research in this field is intended to achieve many goals, including improvement of absorbing and emitting efficiency, and improvement of processing capability.

Despite significant advances in the study of chemical and electro-optic material, for example, red and green phosphorescent organometallic materials have been commercialized and applied to OLEDs, lighting equipment and lighting phosphorescent material in an advanced display, but there are still many shortcomings in the material available, including poor machinability, inefficient emission or absorption, and less desirable stability.

In addition, good blue light-emitting materials are very scarce, a great challenge is the stability of the blue light device is poor, and the select of host material has an important influence on the stability and efficiency of the device. Relative to red and green phosphorescent material, the lowest triplet energy level of the blue phosphorescent material is higher, which means that the triplet energy level of the host material in the blue light device needs to be higher. Therefore, the limitation of the host material in the blue light device is another important issue for its development.

Generally, changes in chemical structure will affect the electronic structure of the compound, which in turn affects the optical properties of the compound (e.g., emission and absorption spectra), thus, which can be adjusted or regulated to the compound of the present disclosure to specific emission or absorption of energy. In some aspects, the optical properties of the compounds disclosed in the present disclosure can be adjusted by changing the structure of the ligand in the metal center. For example, compounds having ligand that bearing electron-donating substituent or electron-withdrawing substituent generally exhibit different optical properties, including different emission and absorption spectra.

Since the phosphorescent multidentate platinum metal complexes can be utilized simultaneously electroluminescence excited singlet and triplet excitons, obtained 100% of internal quantum efficiency, so that these complexes can be alternative luminescent material of OLEDs. Generally, the multidentate platimum metal complex comprises luminescent groups and secondary groups. If a conjugated group, such as aromatic ring substituent or heteroatom substituent group is introduced to the light emitting portion, the energy level of the highest molecular occupied molecular orbital (HOMO) and the lowest molecular occupied molecular orbital for the luminescent material is changed, simultaneously, further adjusting the energy gap between the HOMO orbital and LOMO orbital, also can adjust the emission spectral property of multidentate platinum metal complexes, for example, making it wider or narrower, or making it red shift or blue shift.

### SUMMARY

The object of the present disclosure is to provide a blue phosphorescent tetradentate cyclic-metal platinum complex comprising 6-substituted carbazole and its uses in OLED.

The tetradentate cyclic-metal platinum complex comprising 6-substituted carbazole is provided in some embodiments of the present disclosure, its structure is shown in the following formula (I):

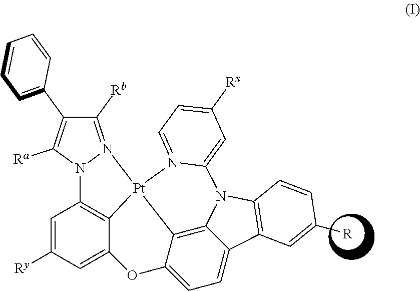

Wherein, R is alkyl, alkoxy, cycloalkyl, ether, heterocyclyl, aryl, heteroaryl, aryloxy, halogen, mono- or di-alkylamino, mono- or di-arylamino;

R^{a}, R^{b} each are alkyl, alkoxy, cycloalkyl, ether, heterocyclyl, hydroxy, aryl, heteroaryl, aryloxy, mono- or di-alkylamino, mono- or di-arylamino, halogen, sulfydryl, cyano, independently, or combination thereof;

R^{x} is alkyl, alkoxy, cycloalkyl, heterocyclyl, ether, mono- or di-alkylamino, mono- or di-arylamino, halogen, or combination thereof;

R^{y} is H, deuterium, alkyl, alkoxy, cycloalkyl, heterocyclyl, ether, mono- or di-alkylamino, mono- or di-arylamino, halogen, or combination thereof.

Preferably, the tetradentate cyclic-metal platinum complex comprising 6-substituted carbazole which is provided in some embodiments of the present disclosure, the

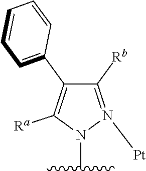

has one of structures selected from the following structures:

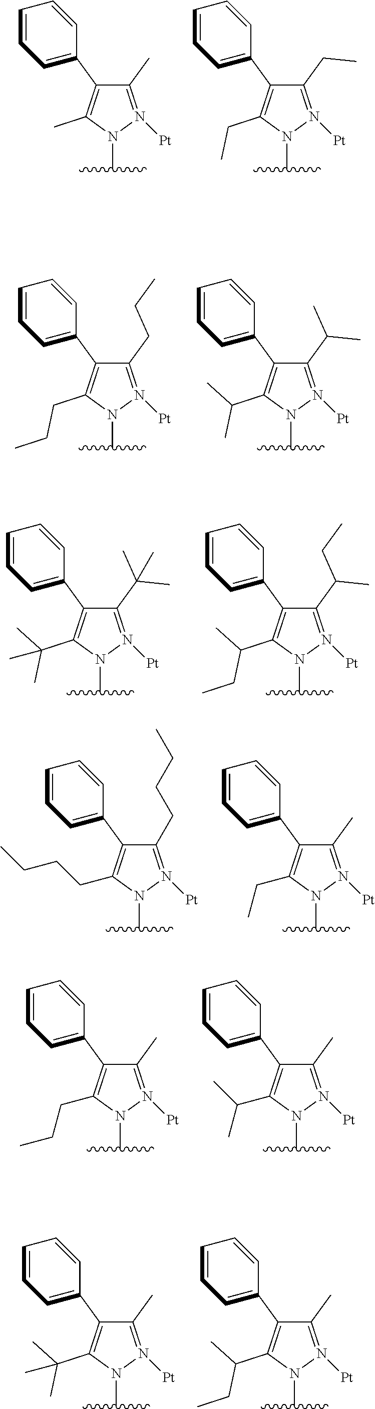

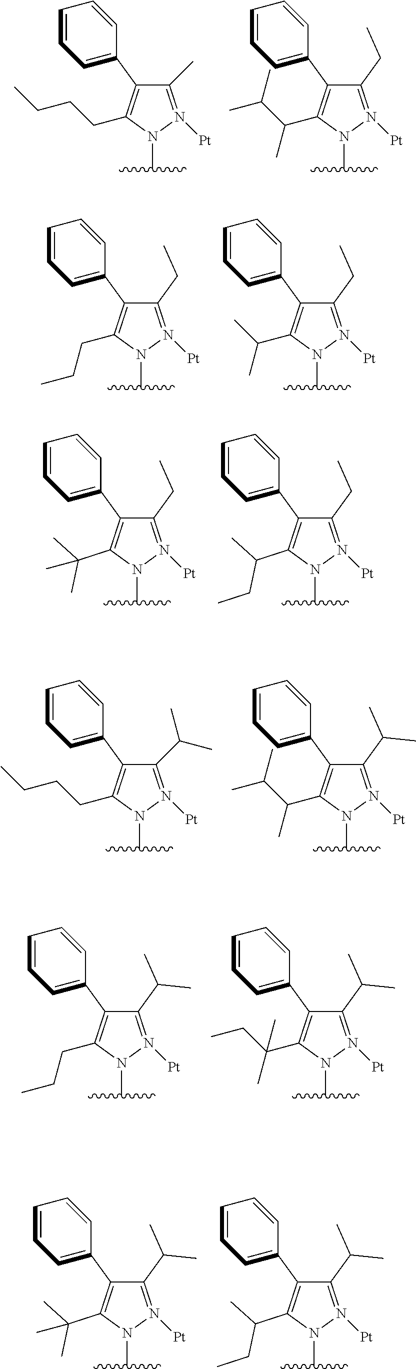

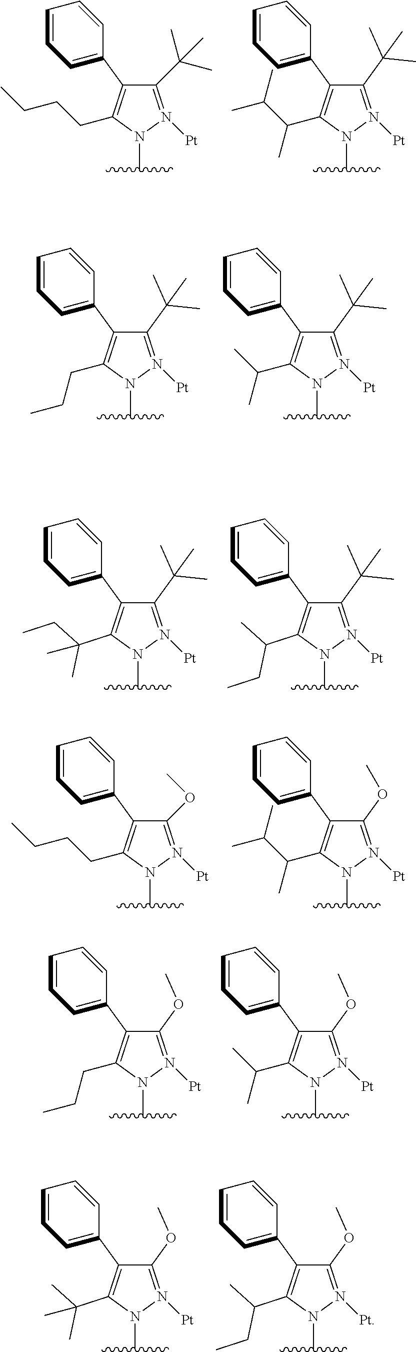

Preferably, the tetradentate cyclic-metal platinum complex comprising 6-substituted carbazole provided by some embodiments of the present disclosure has one of structures selected from the group consisting of Pt1-Pt896:

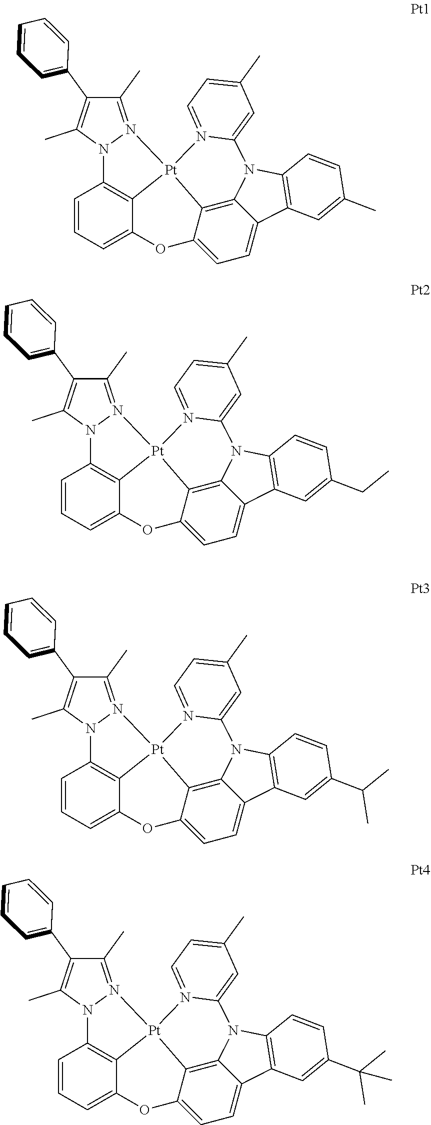

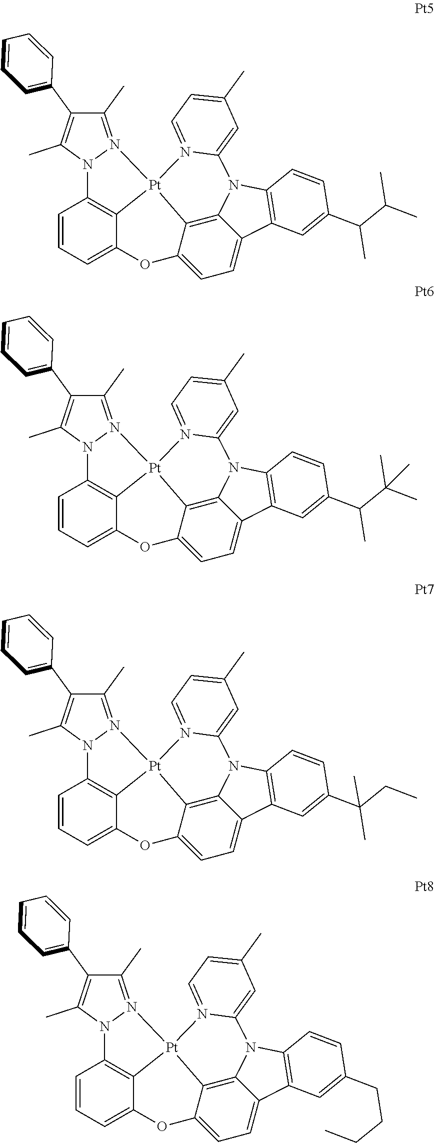

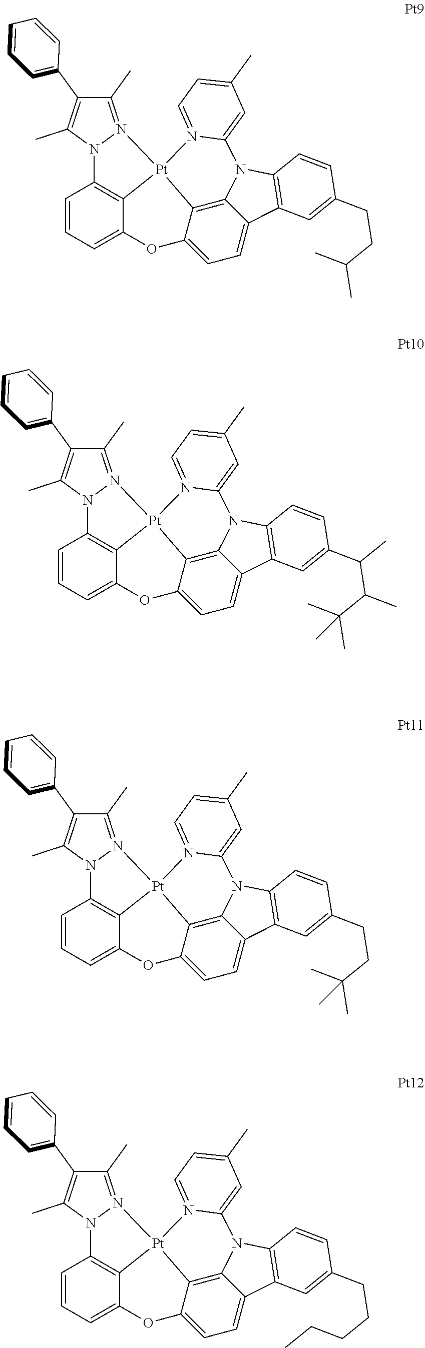

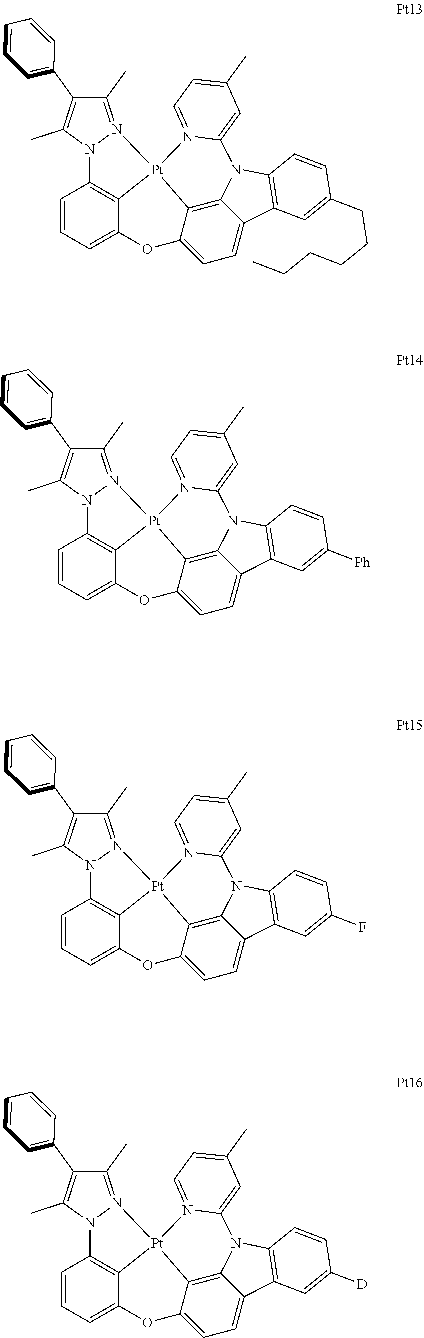

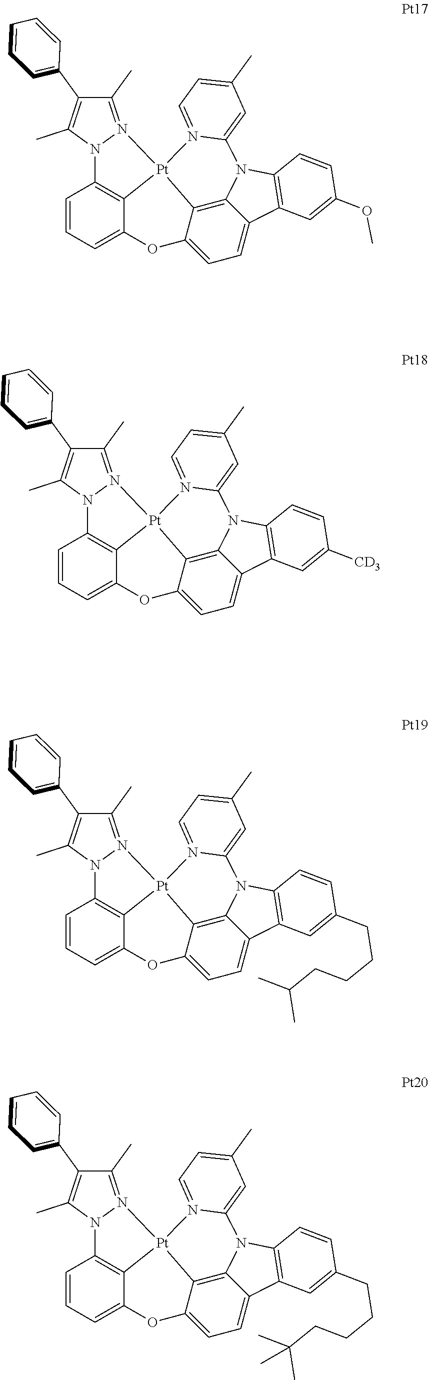

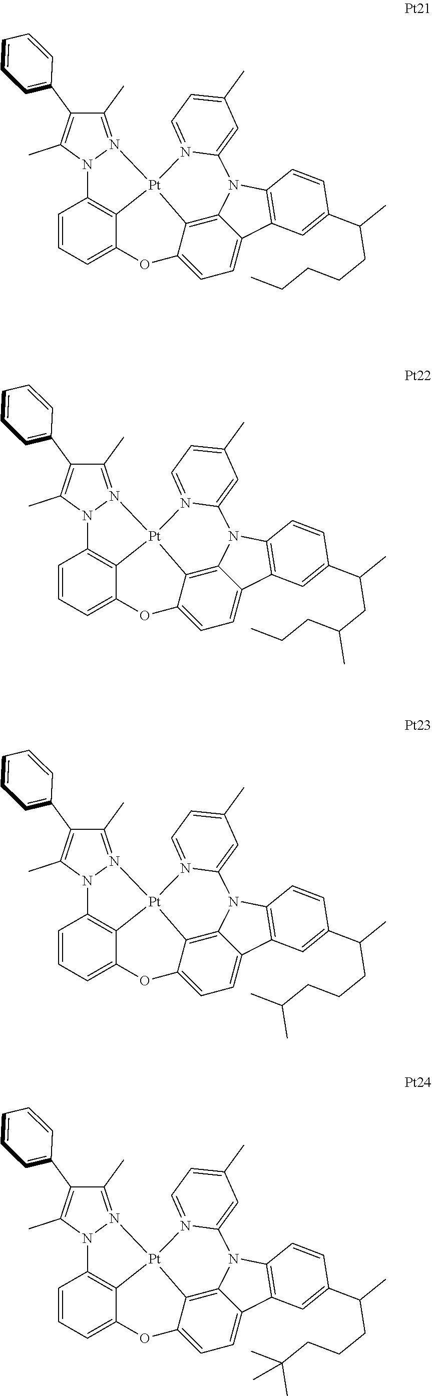

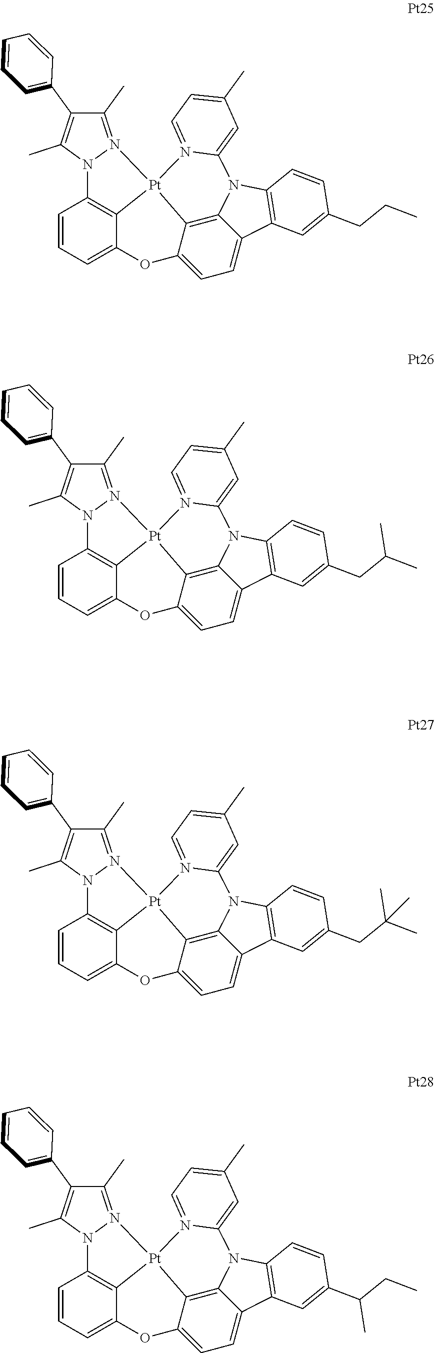

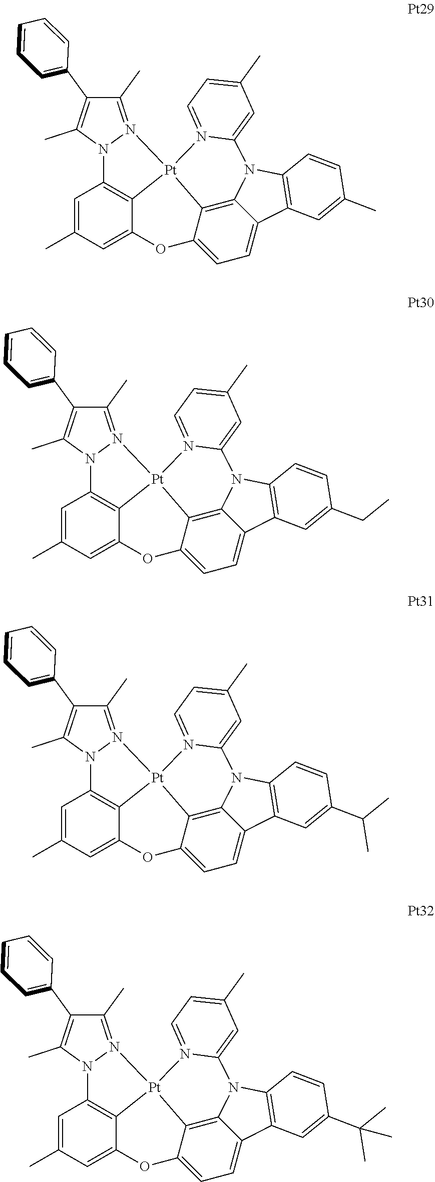

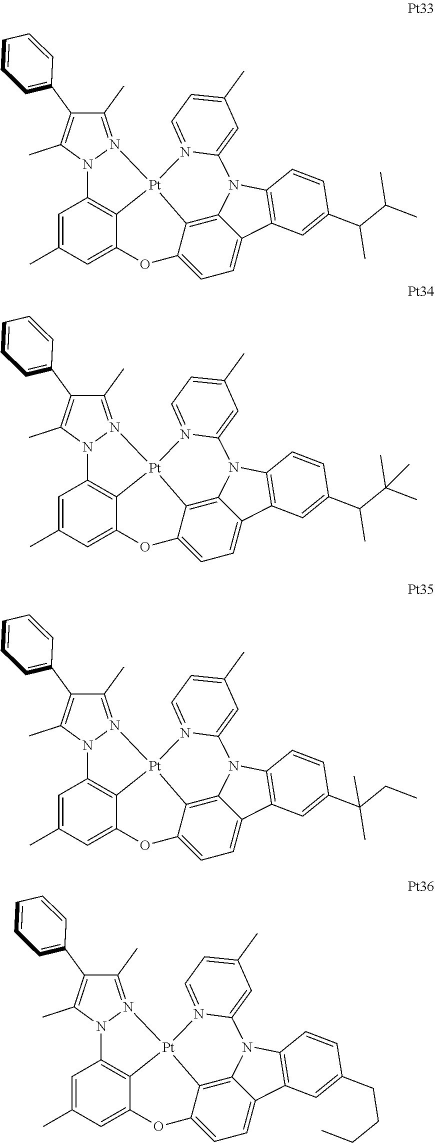

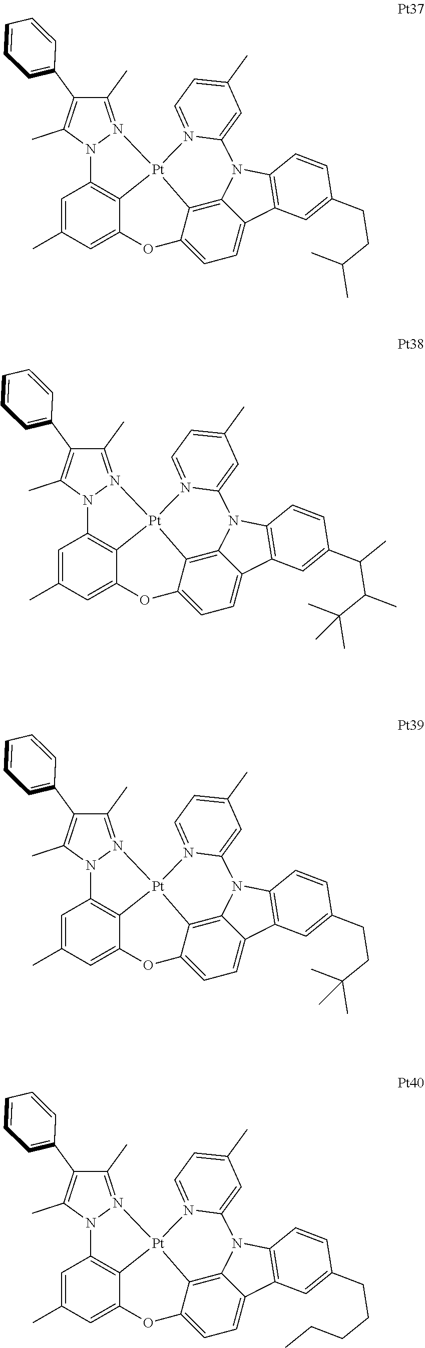

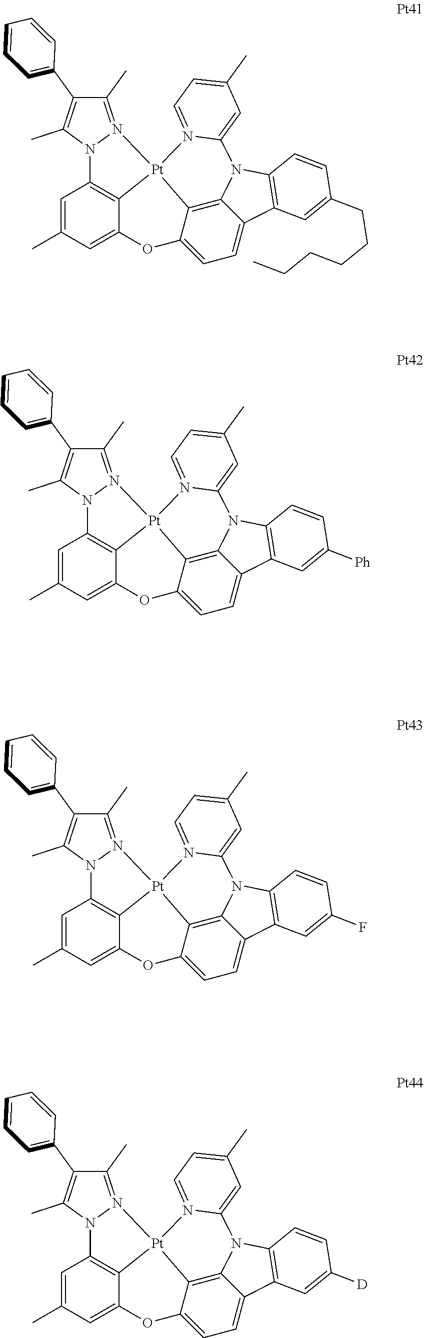

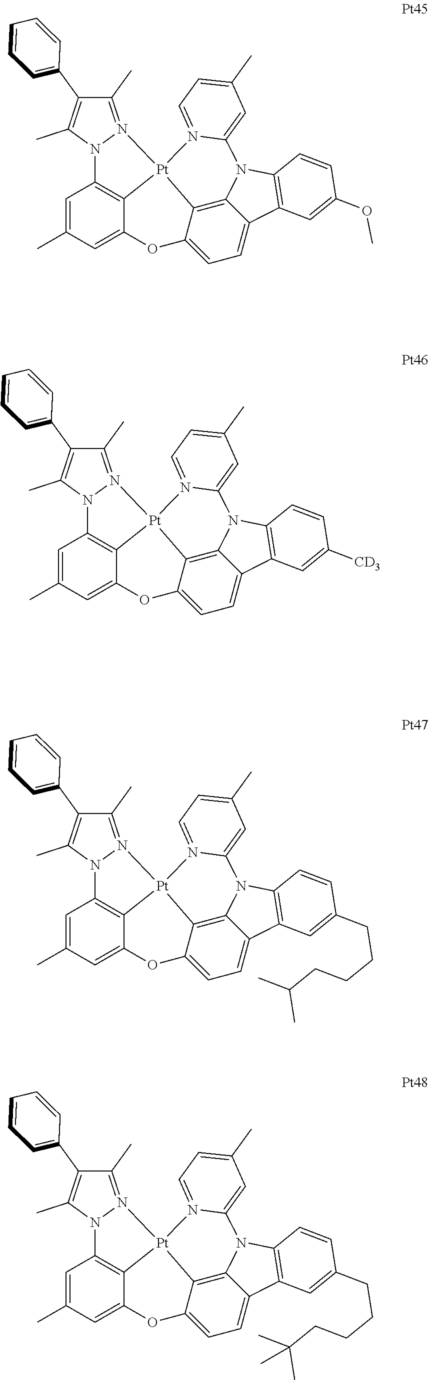

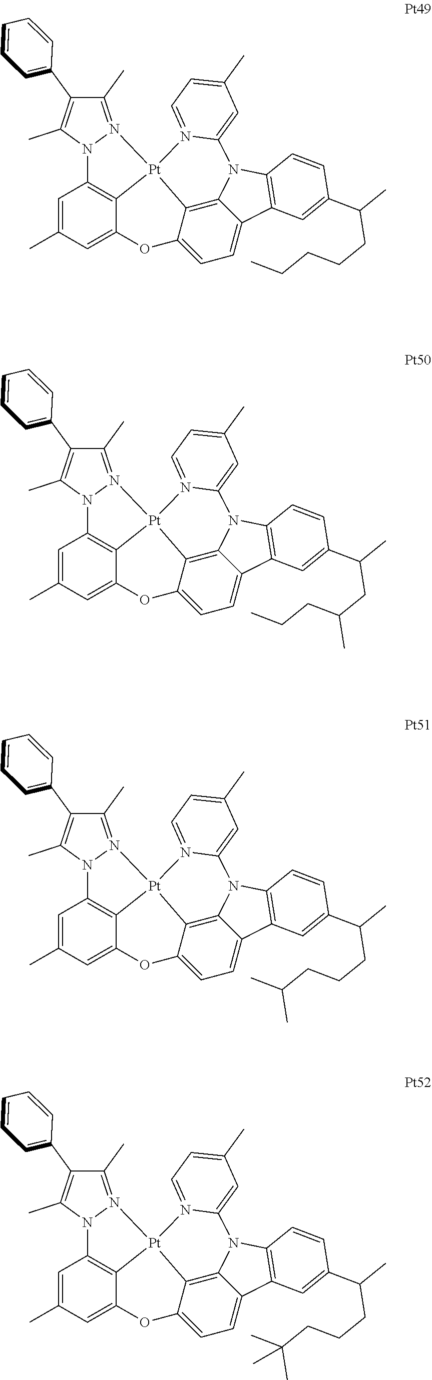

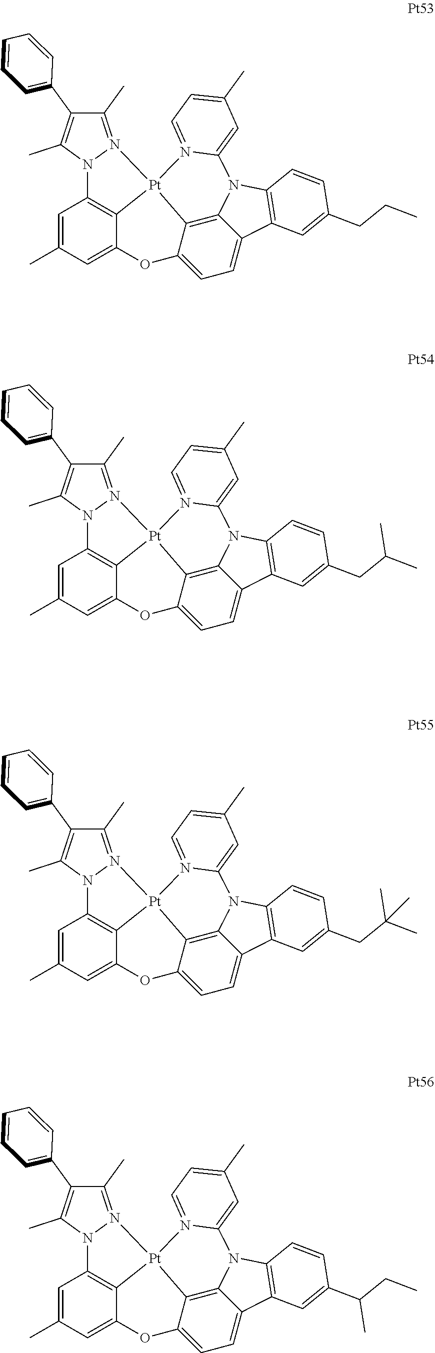

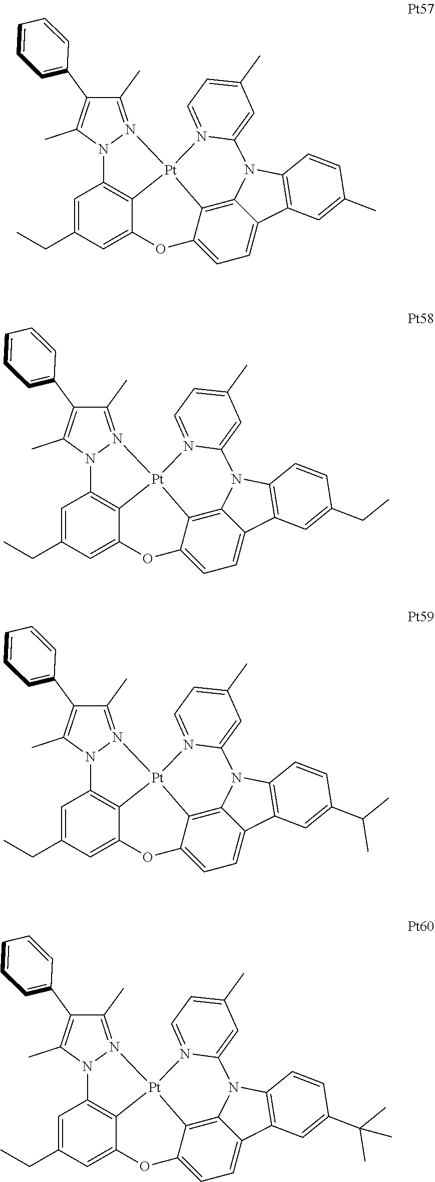

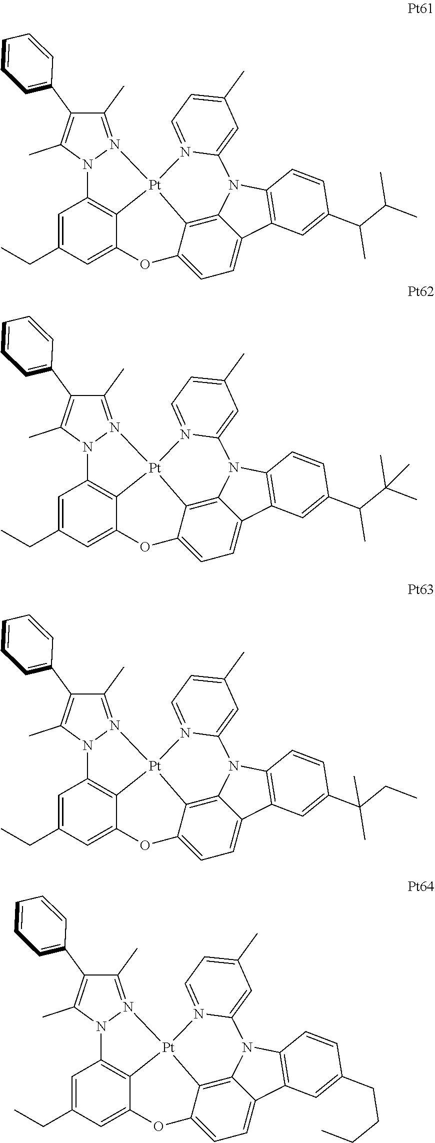

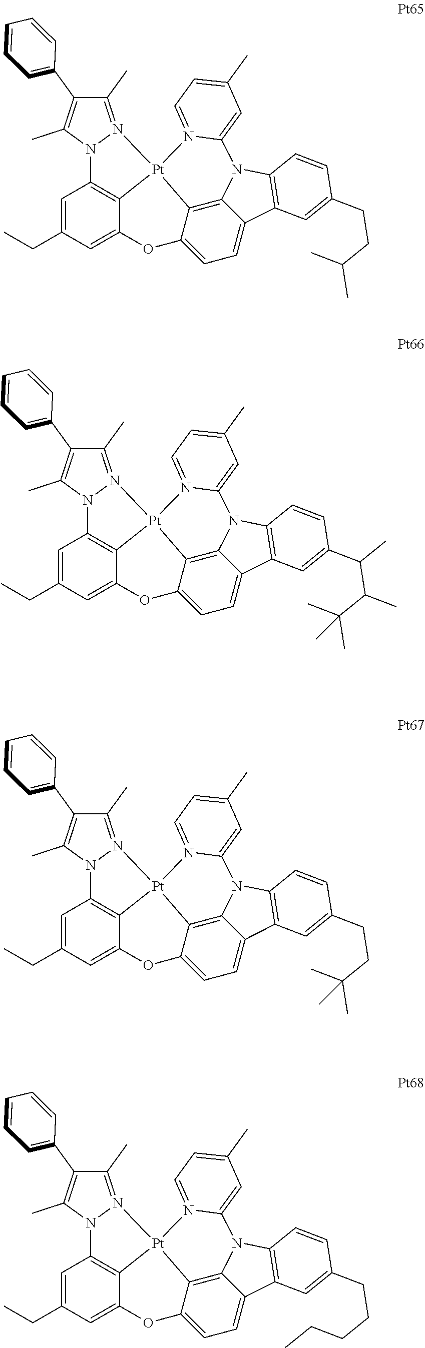

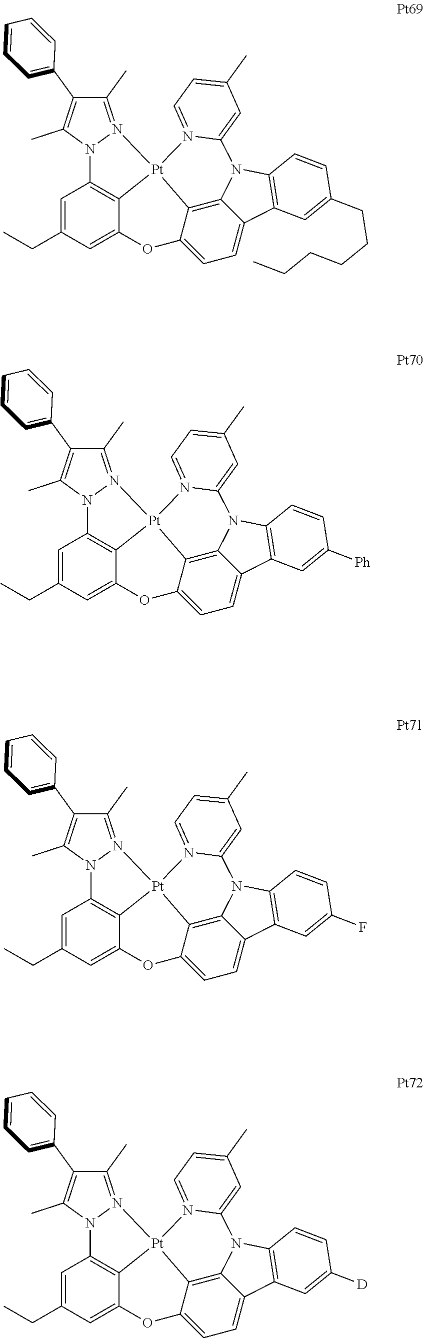

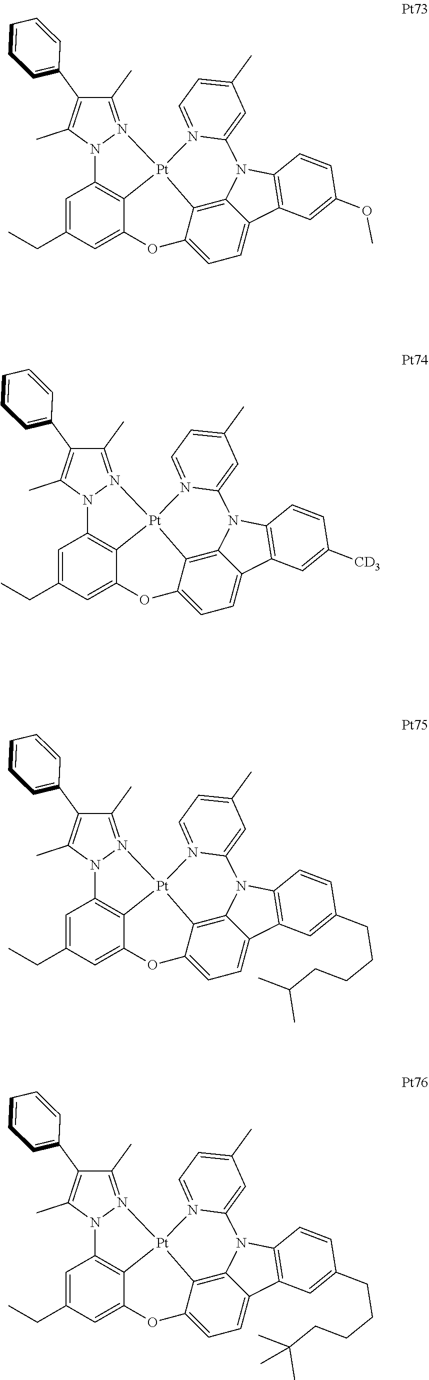

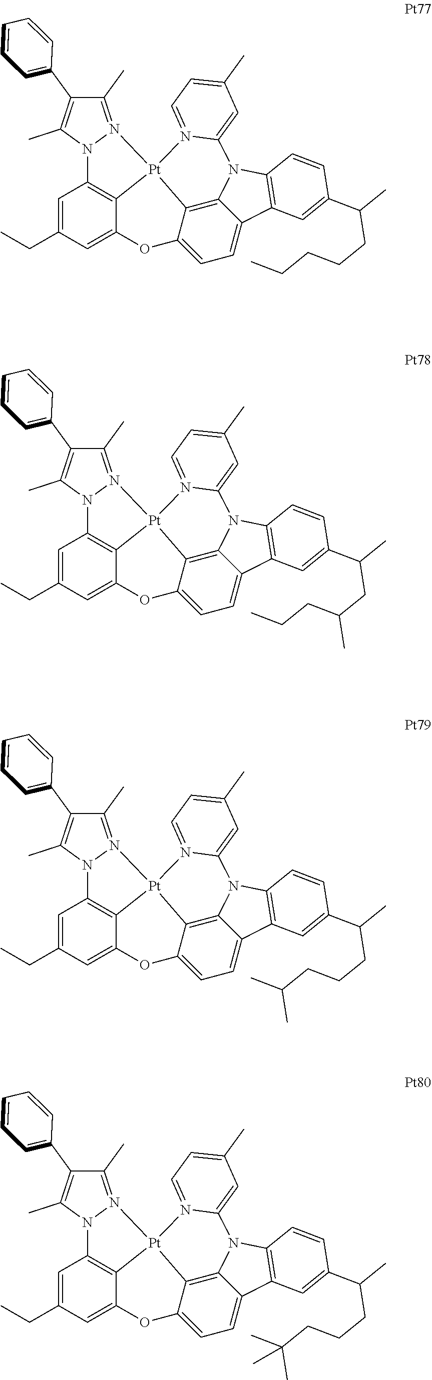

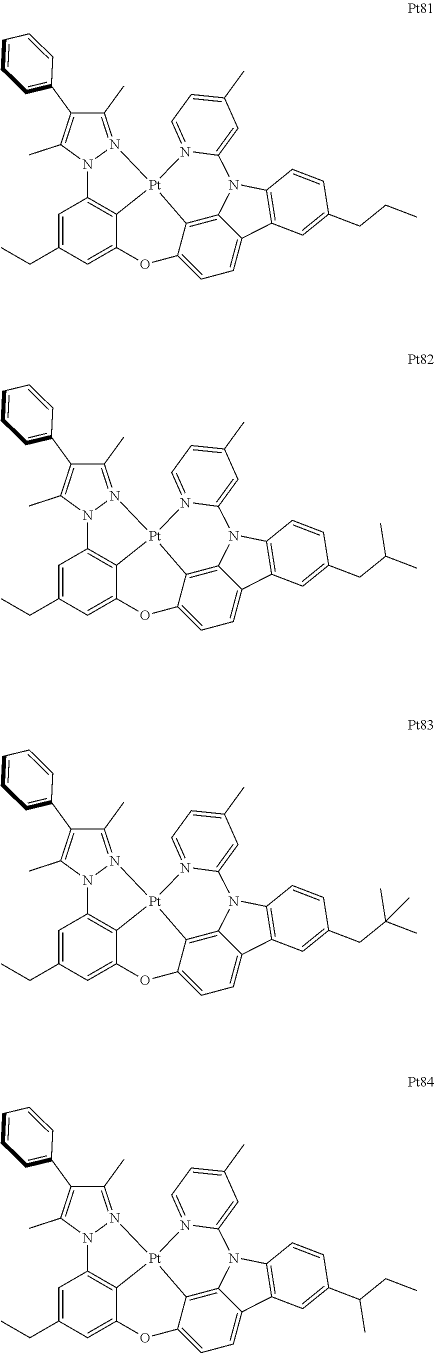

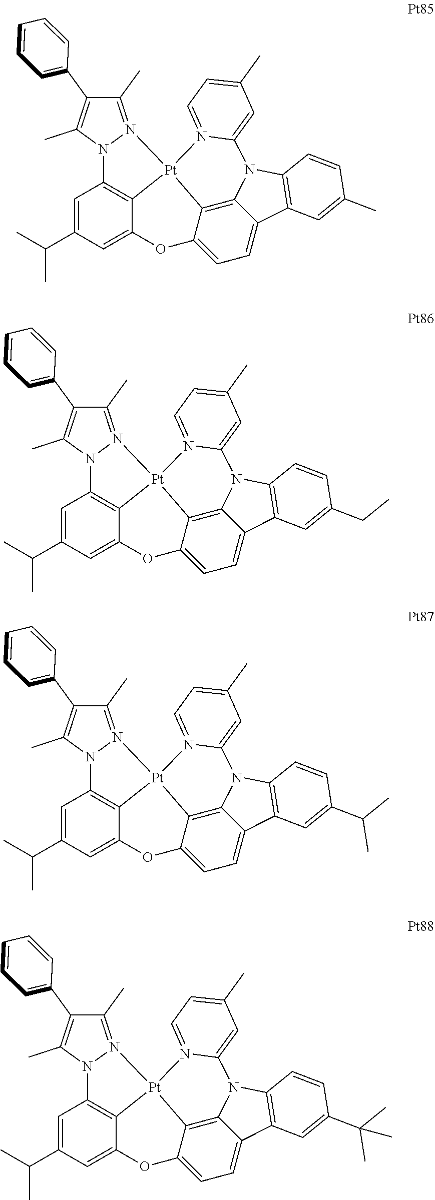

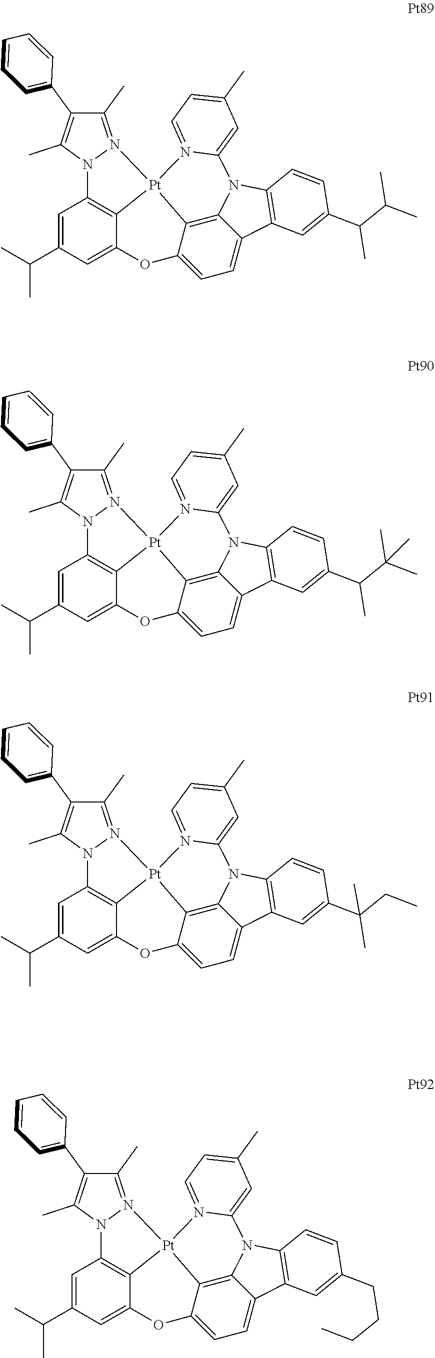

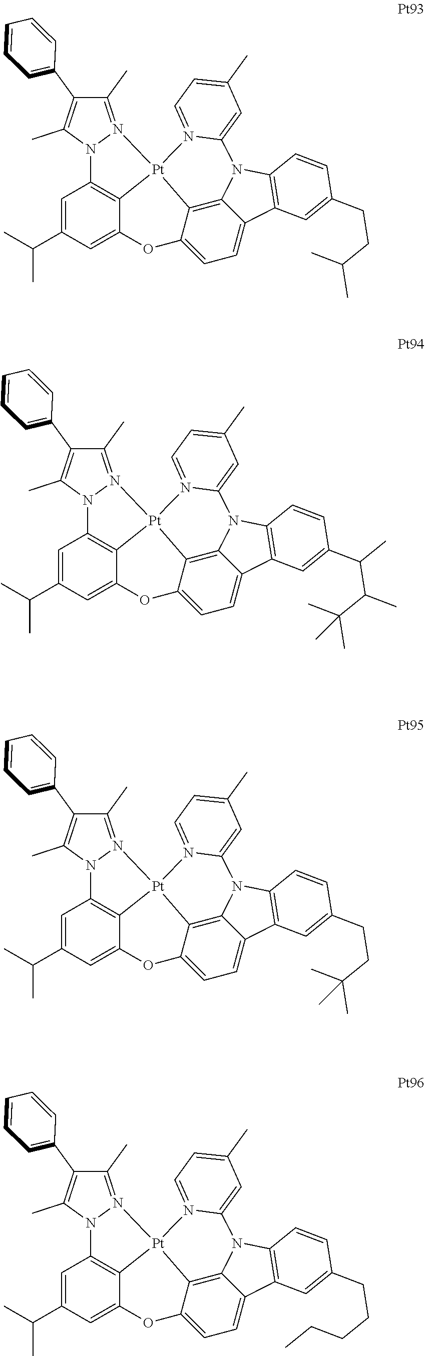

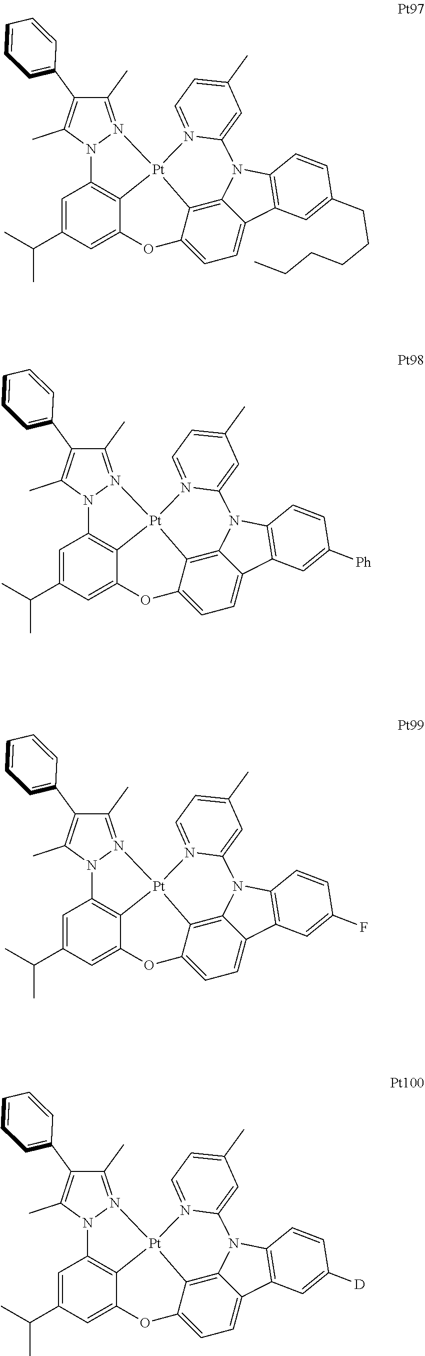

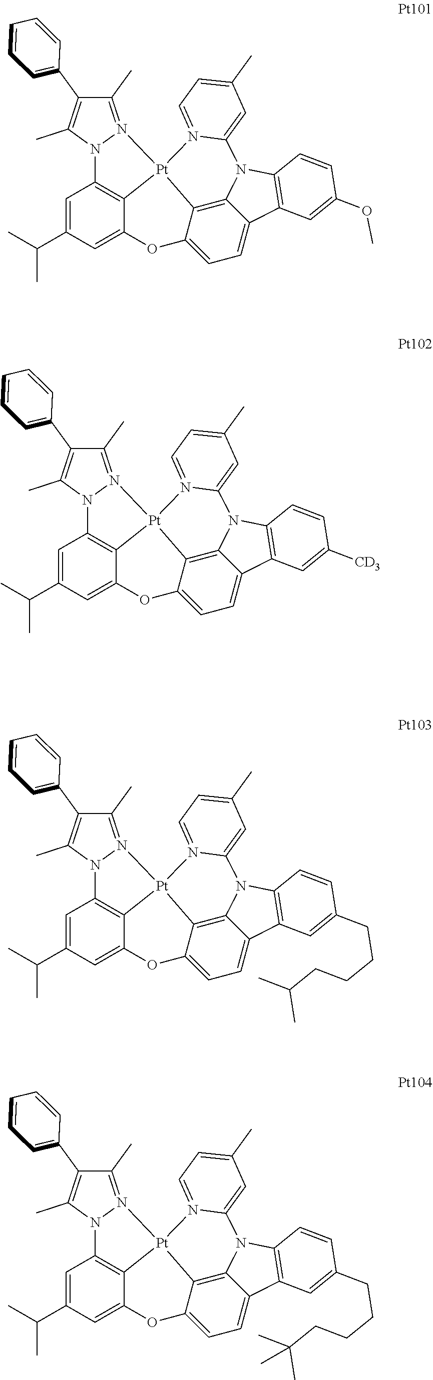

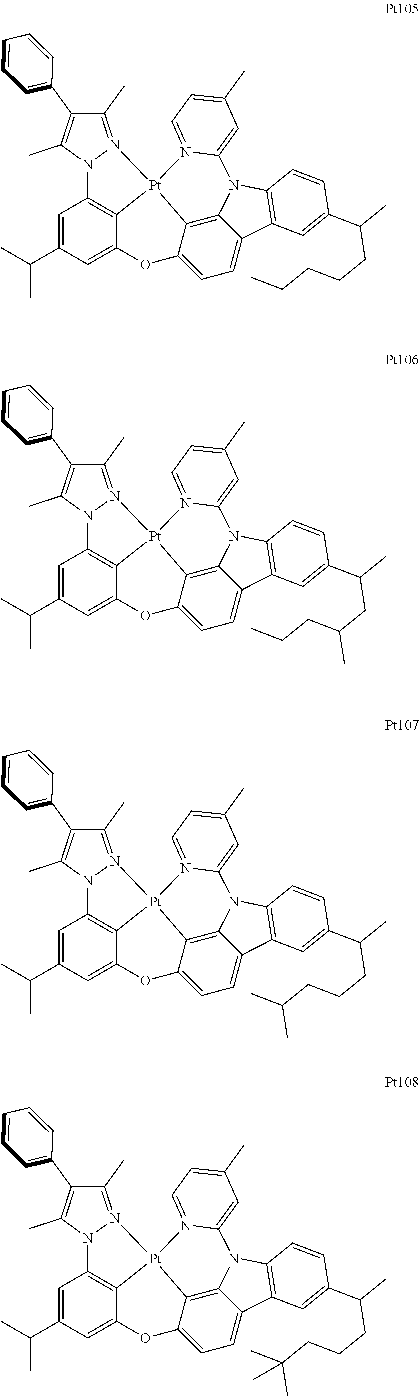

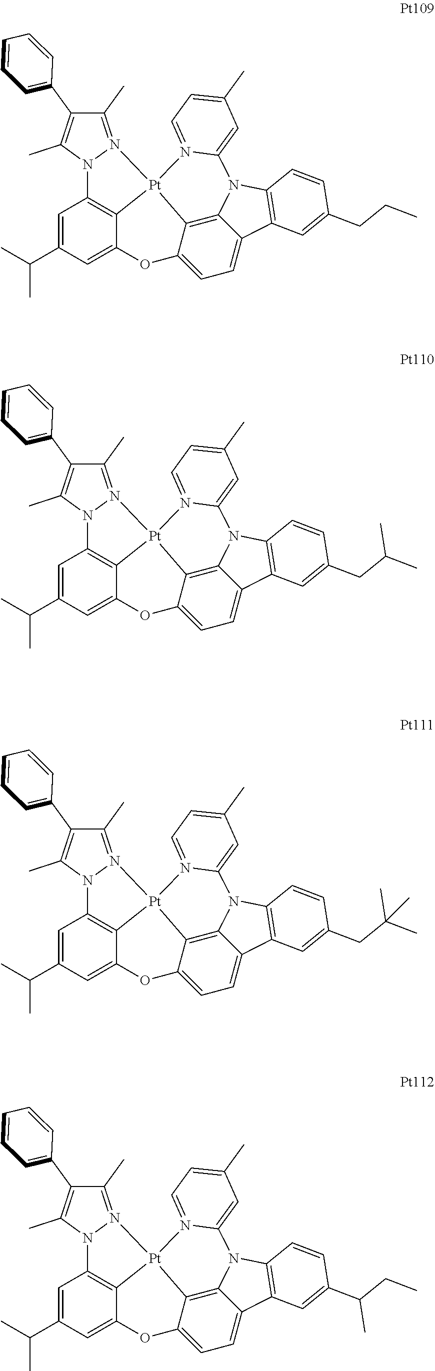

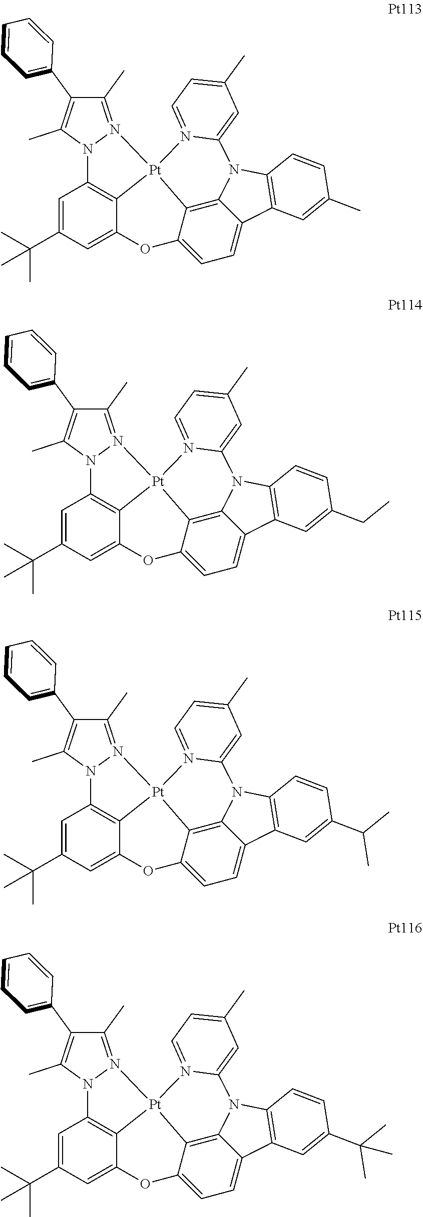

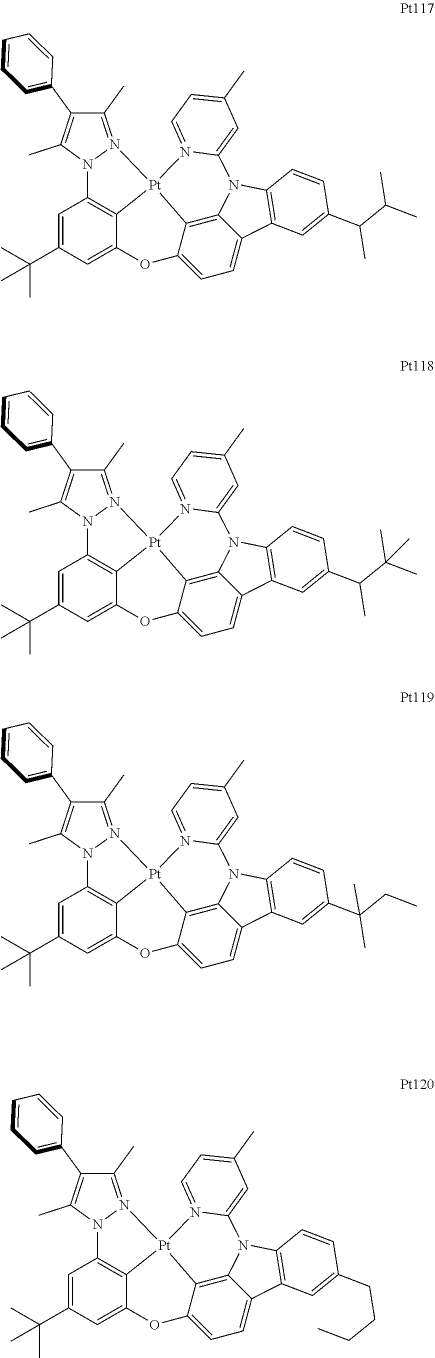

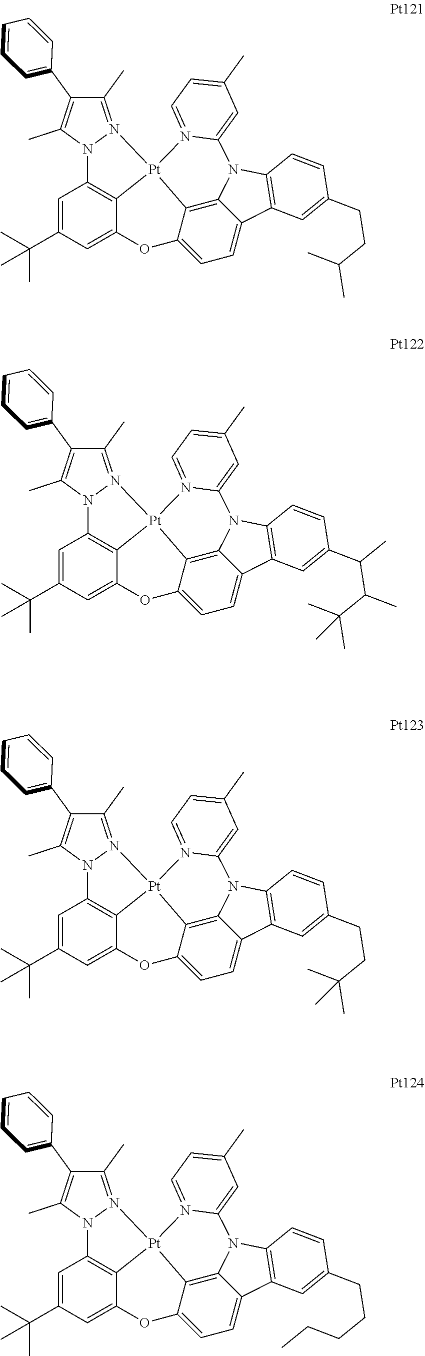

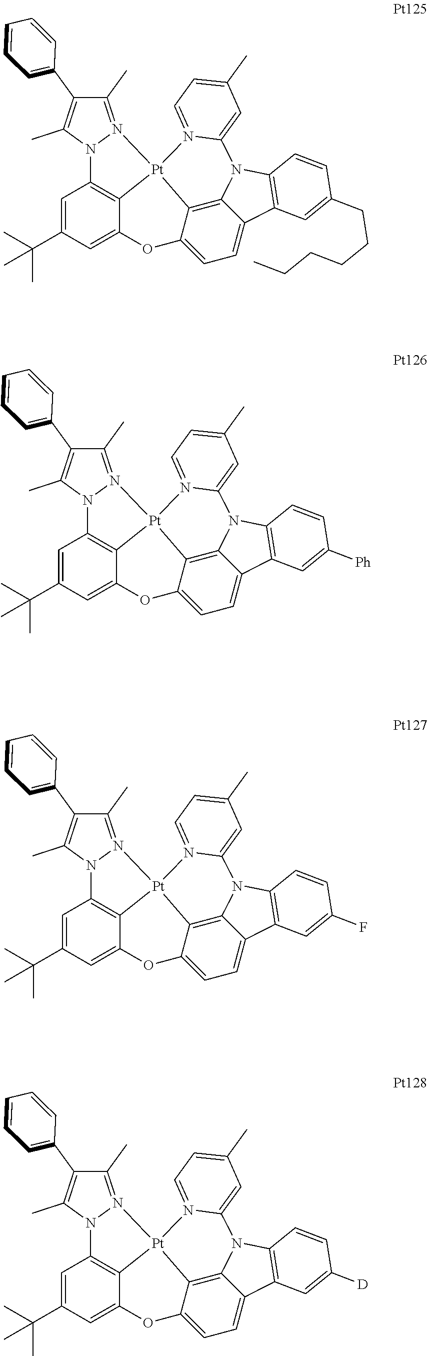

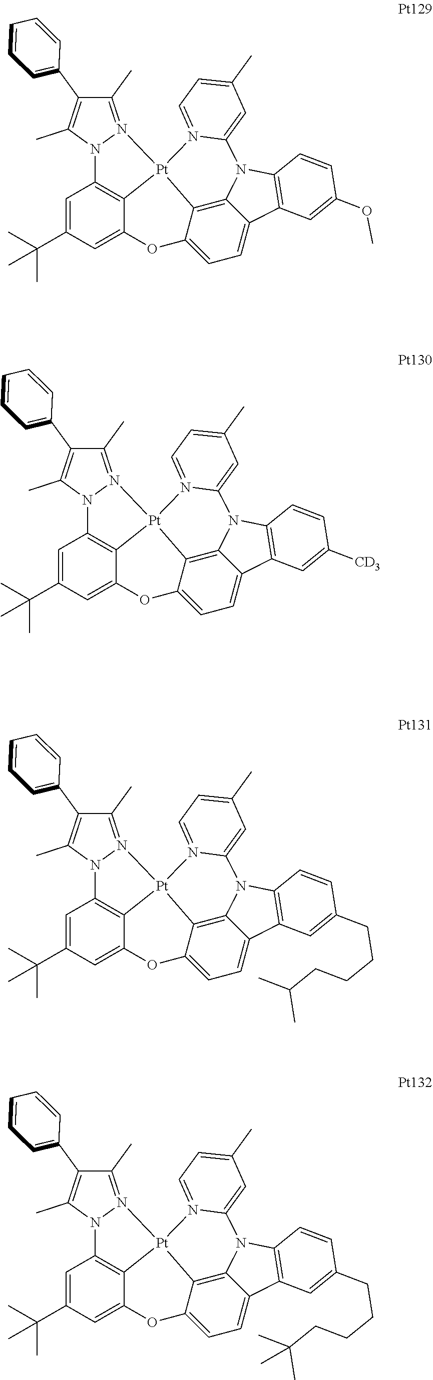

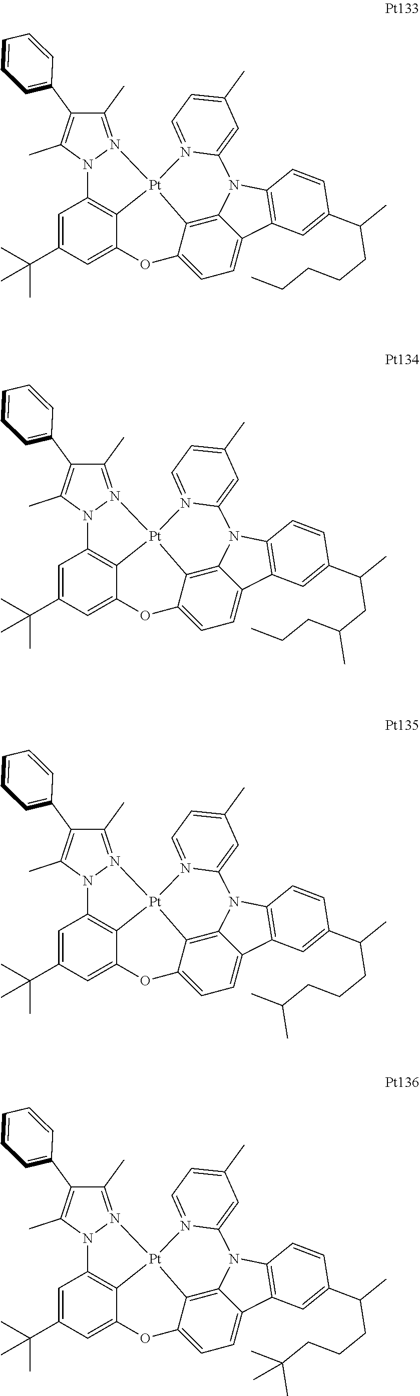

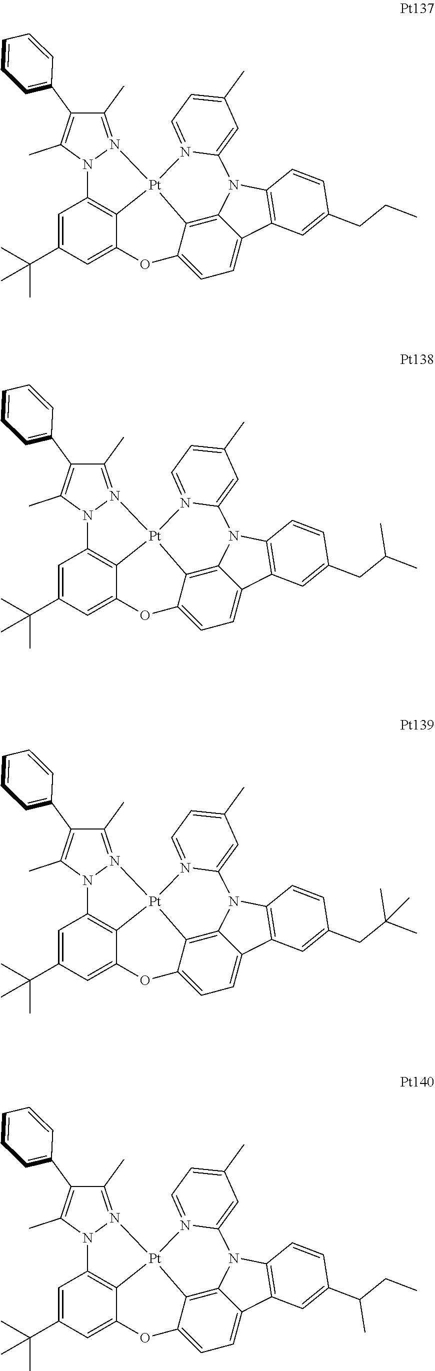

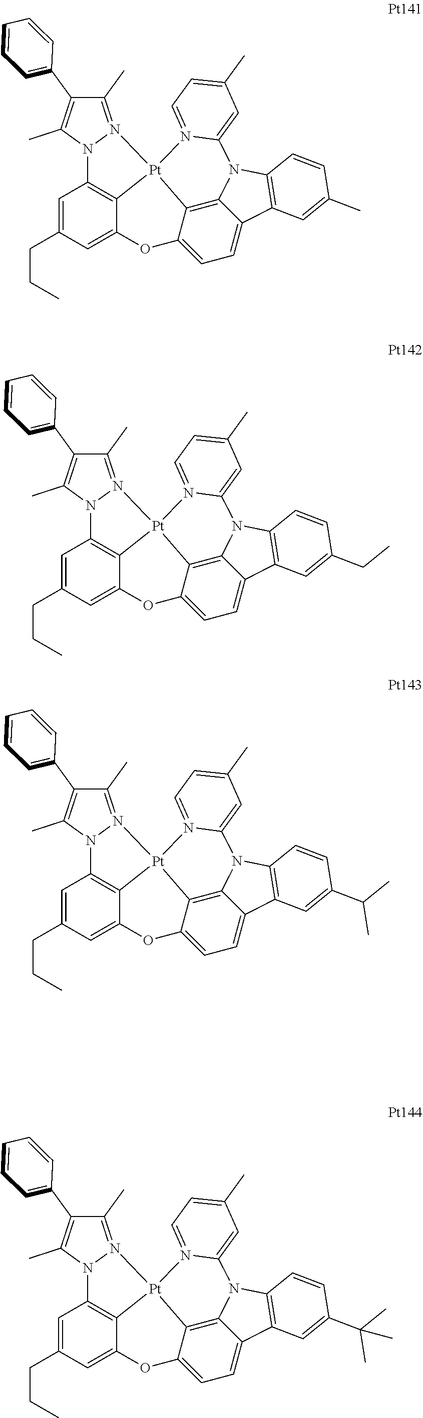

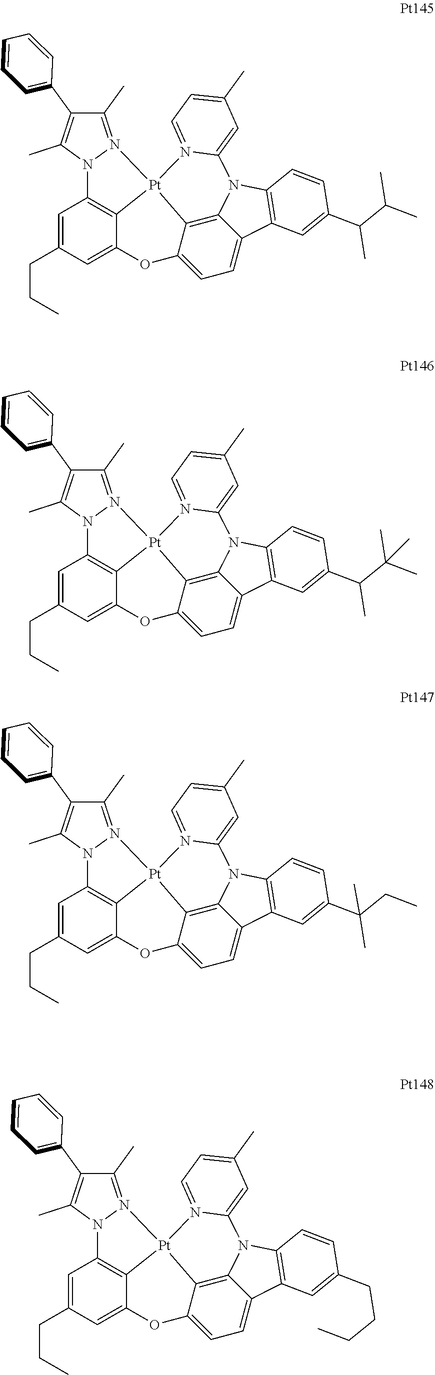

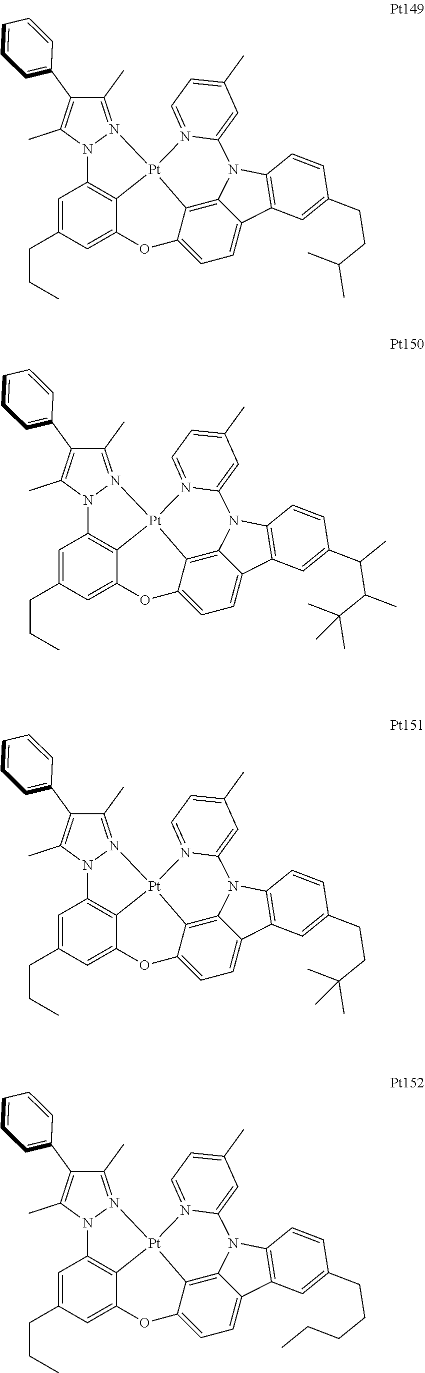

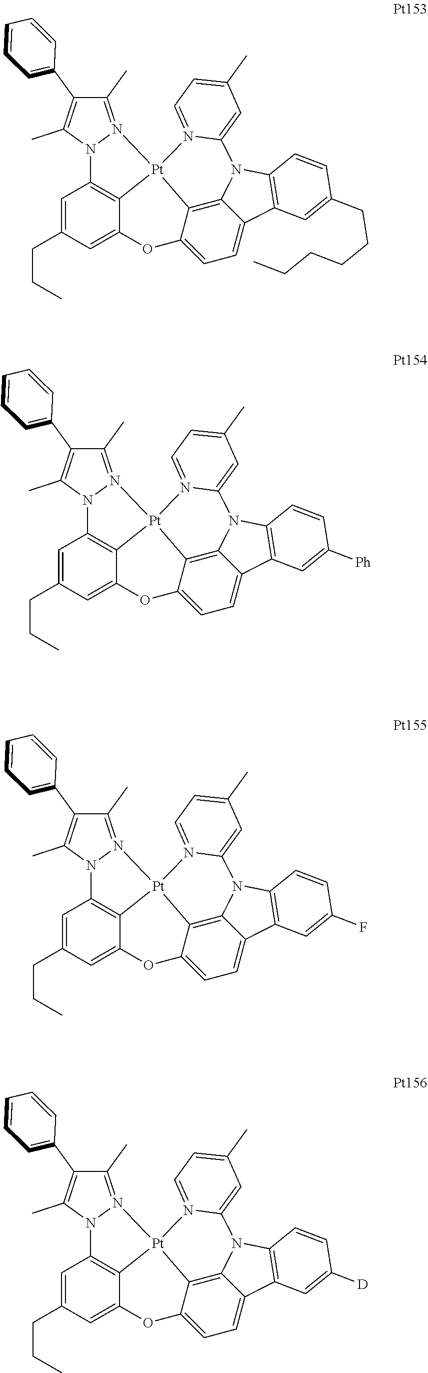

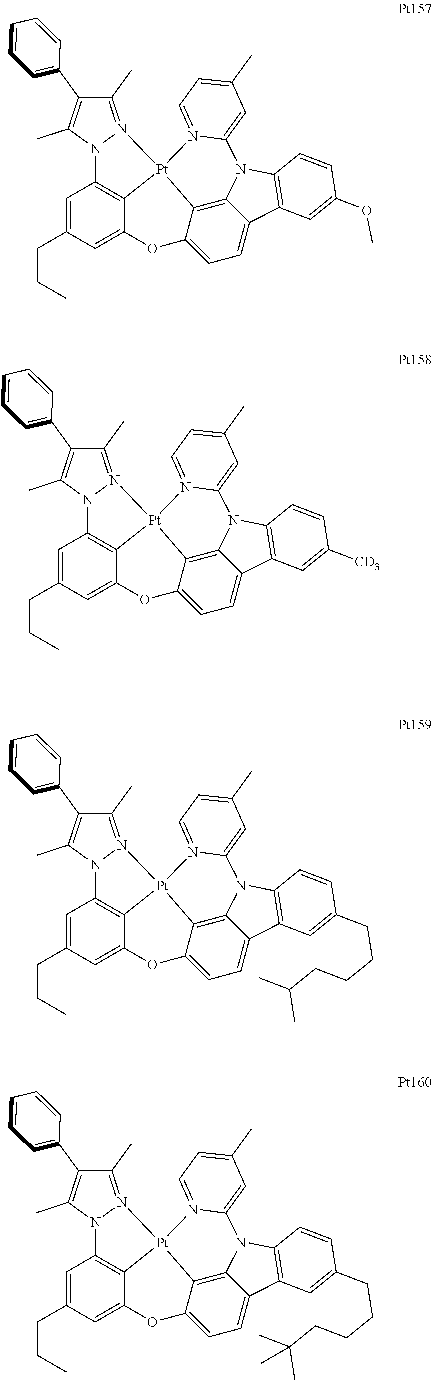

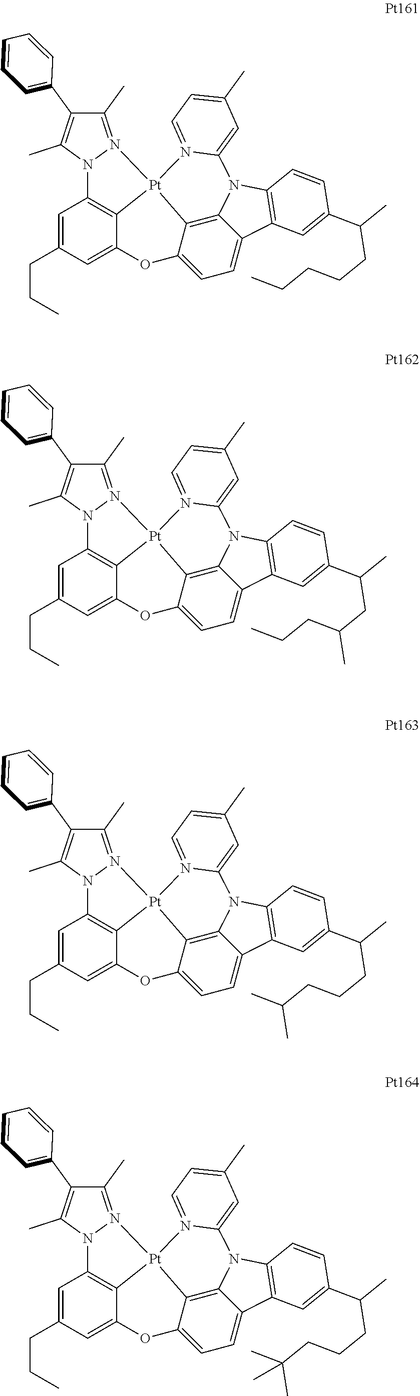

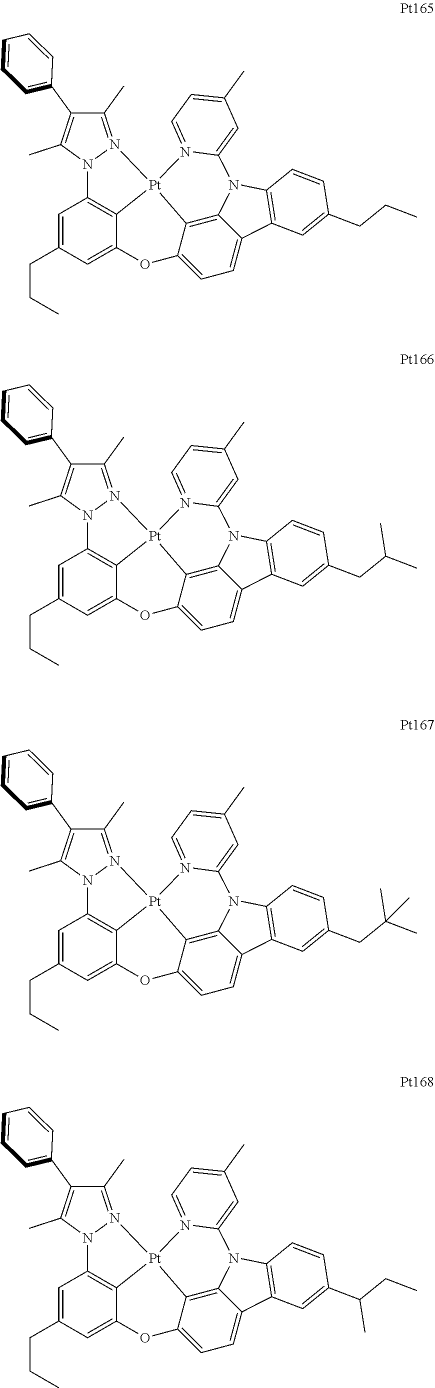

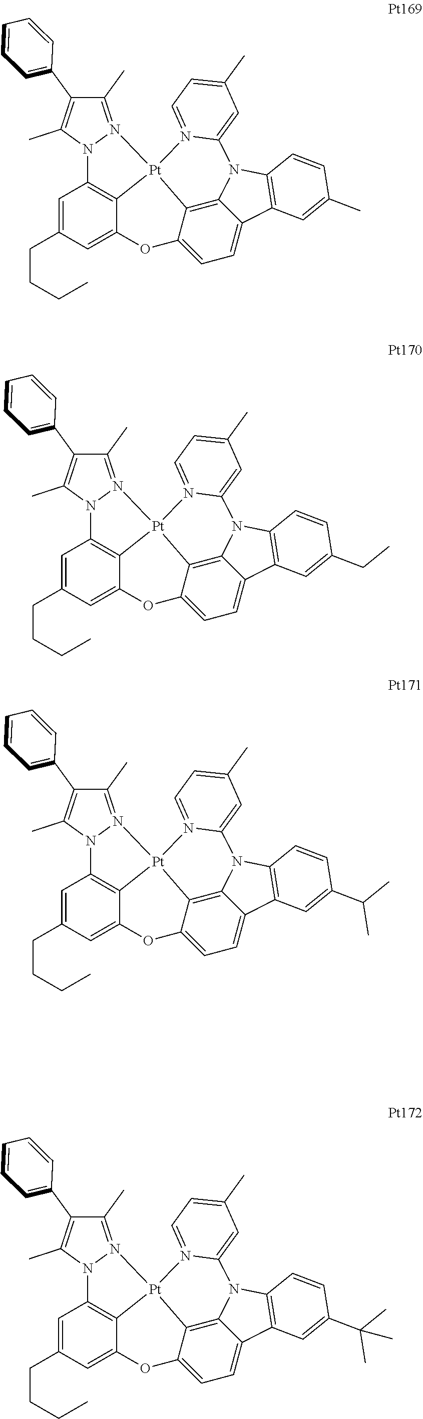

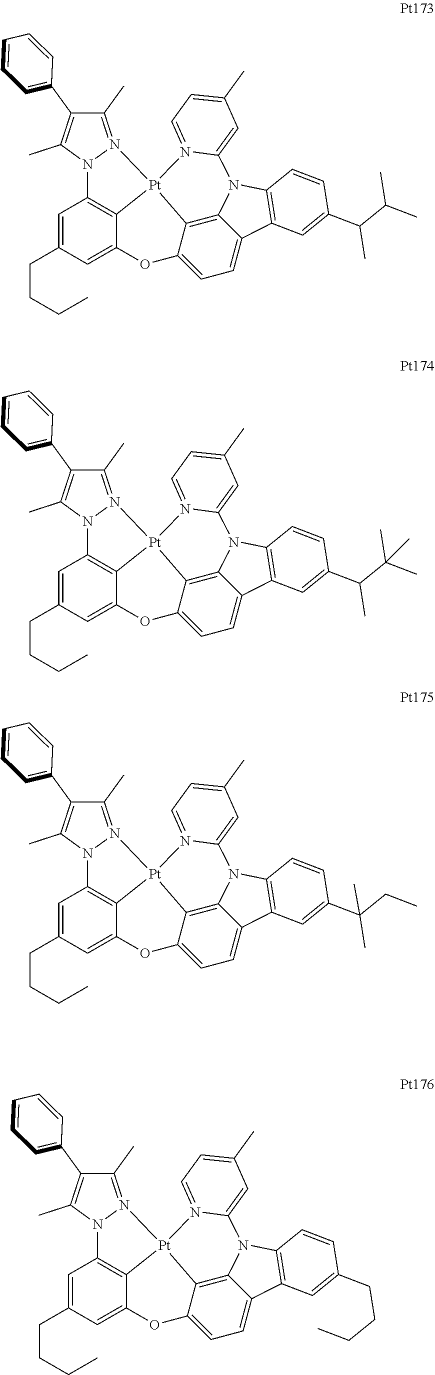

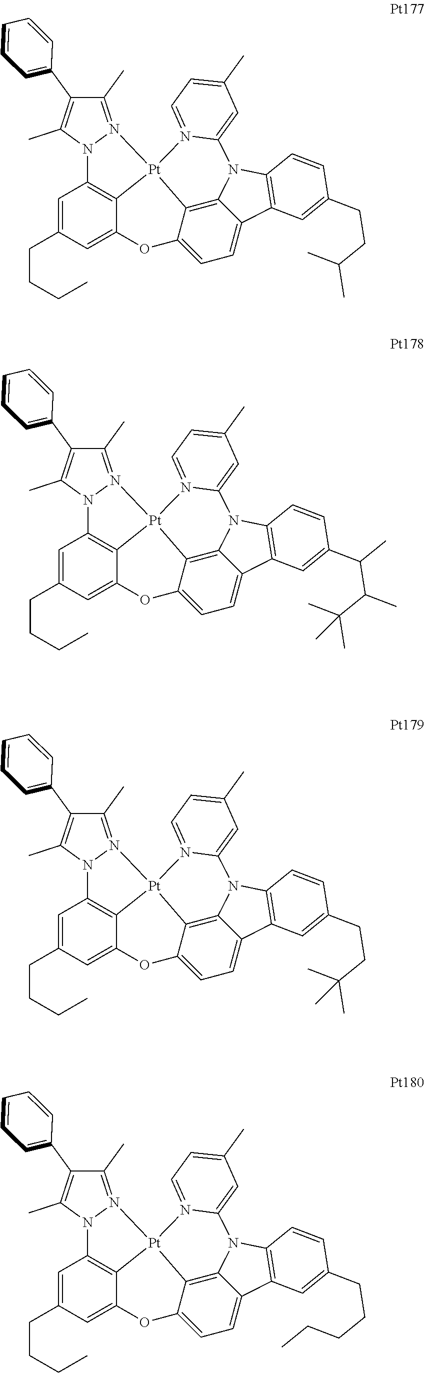

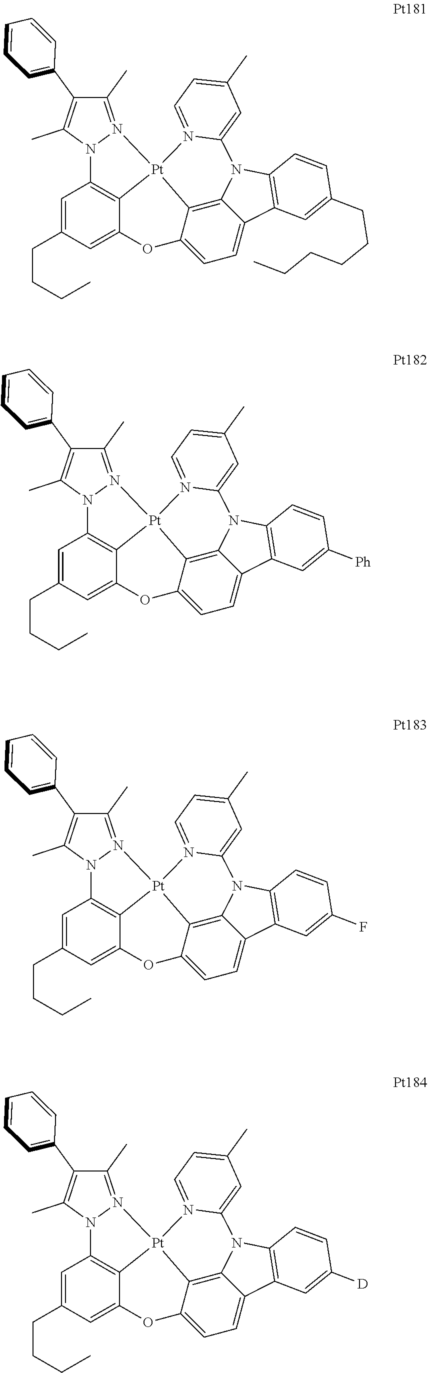

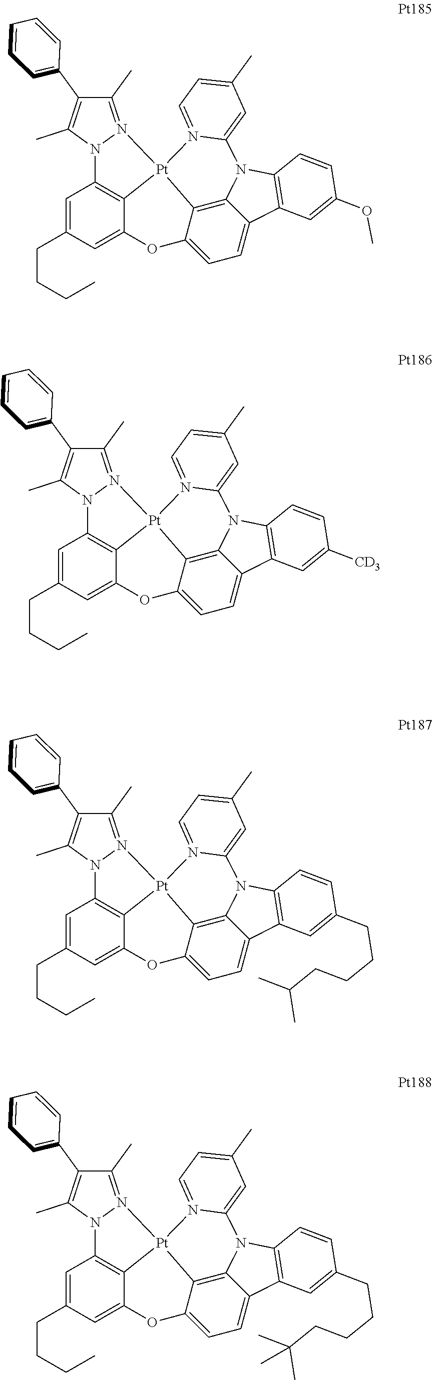

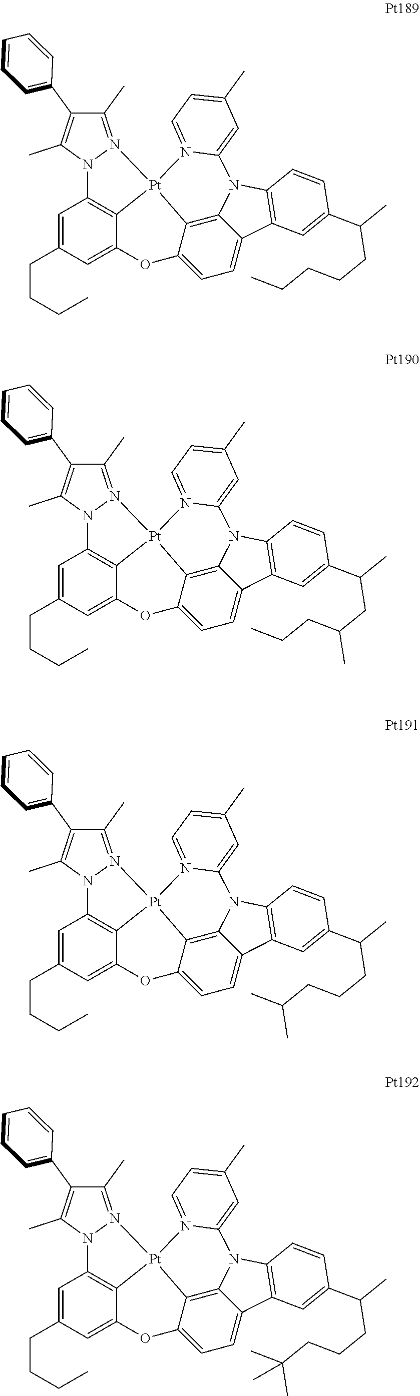

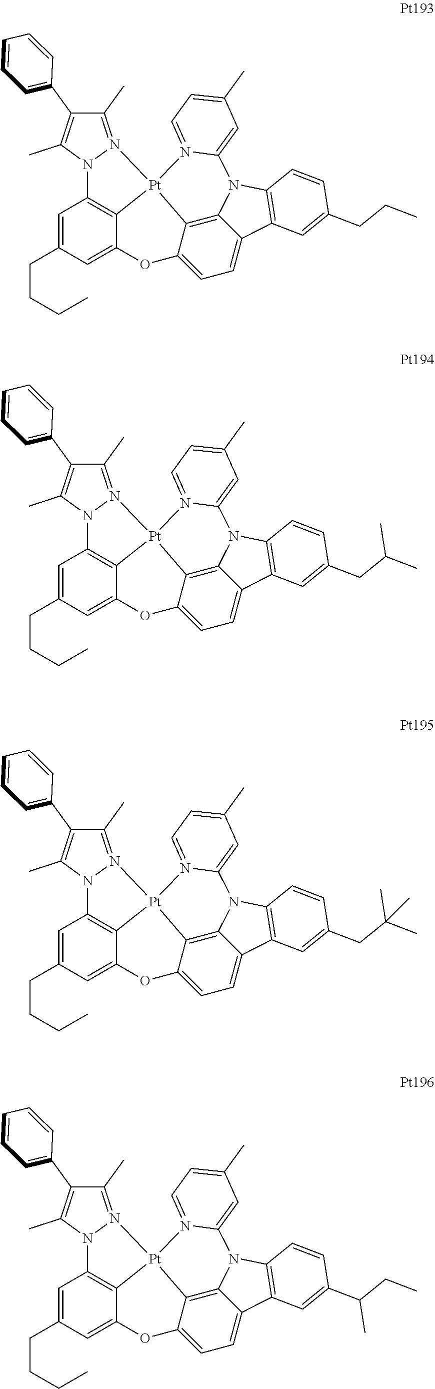

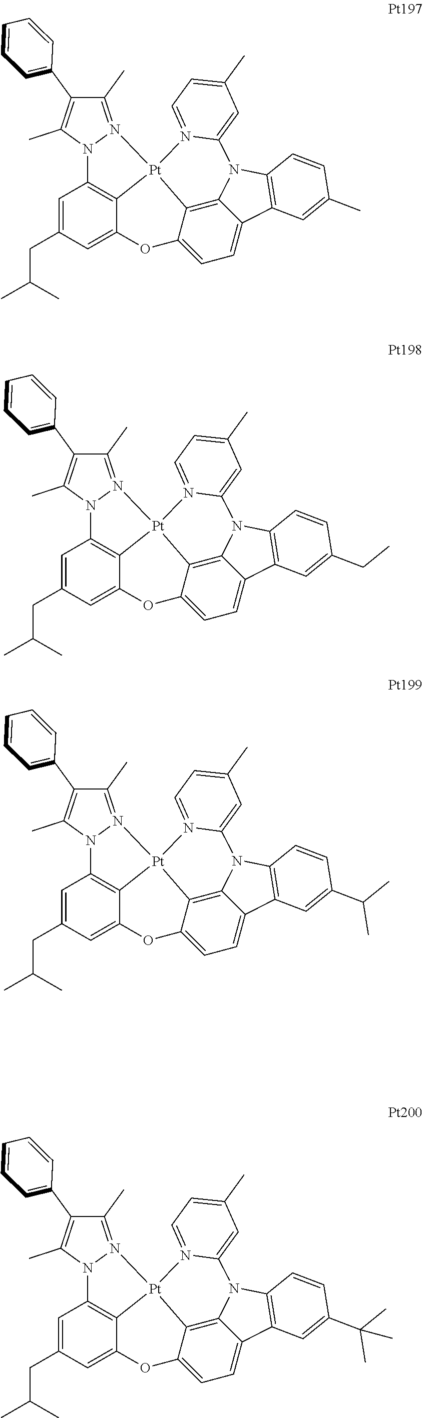

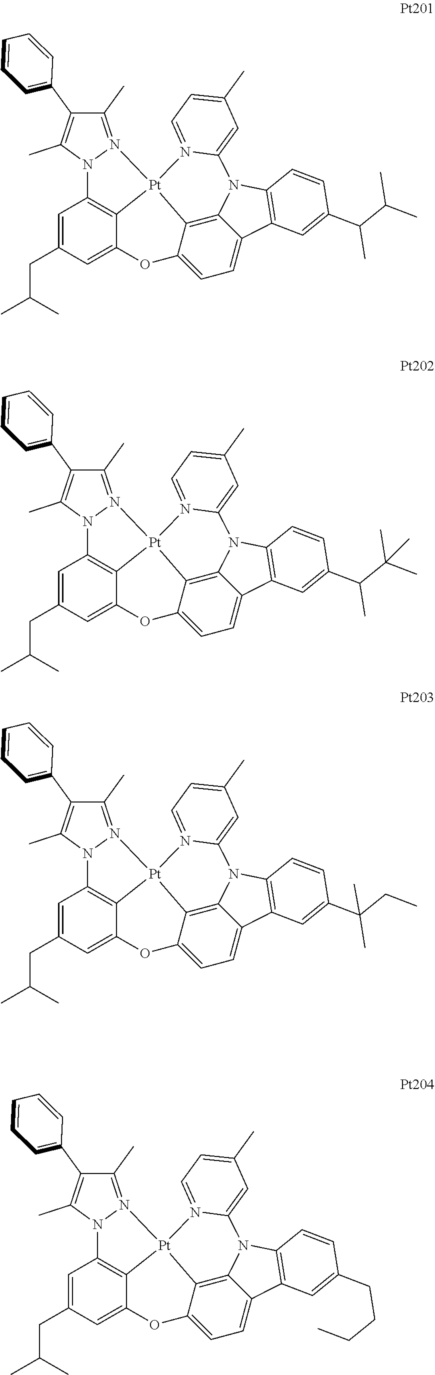

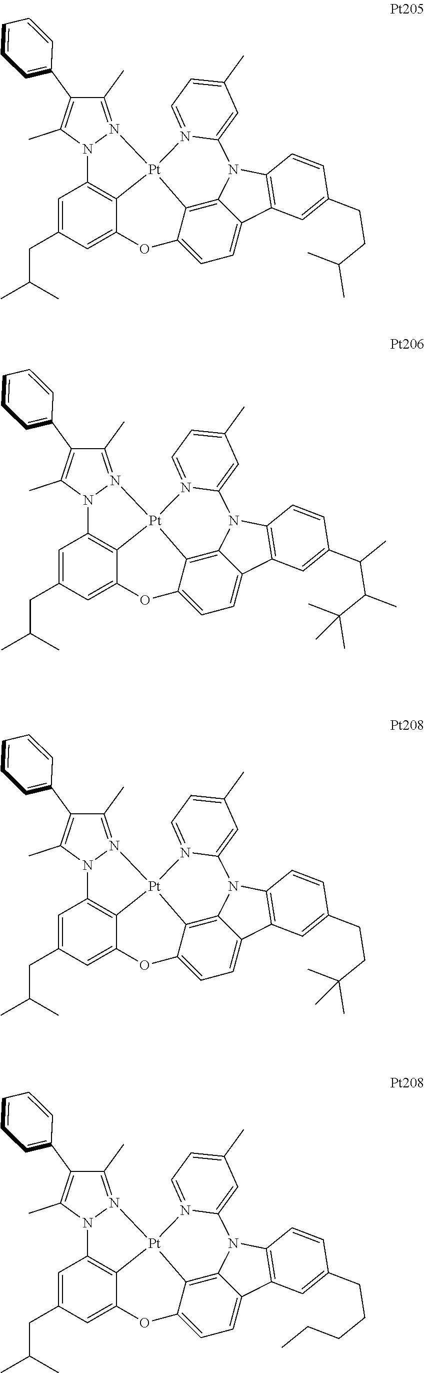

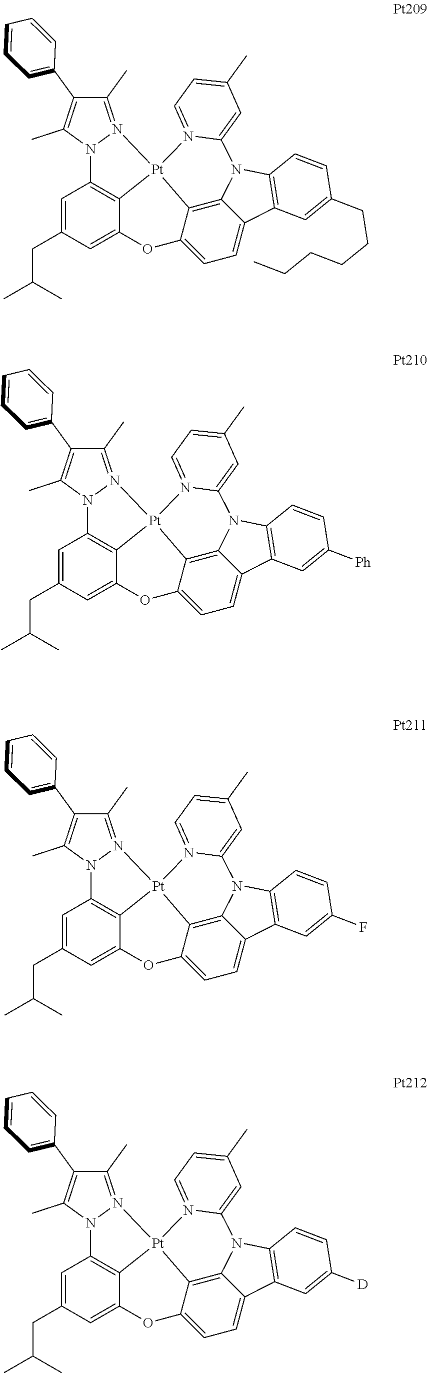

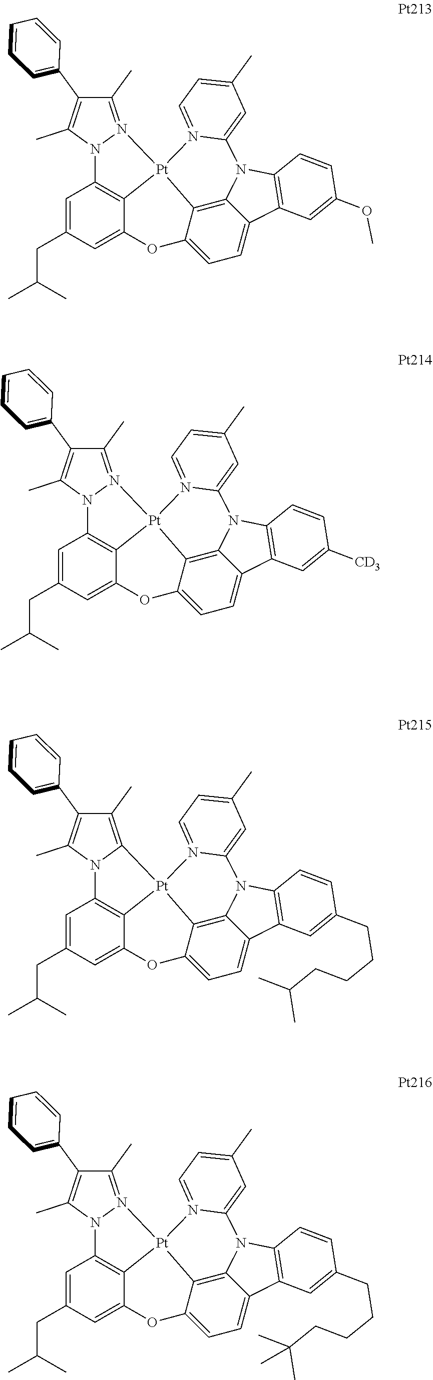

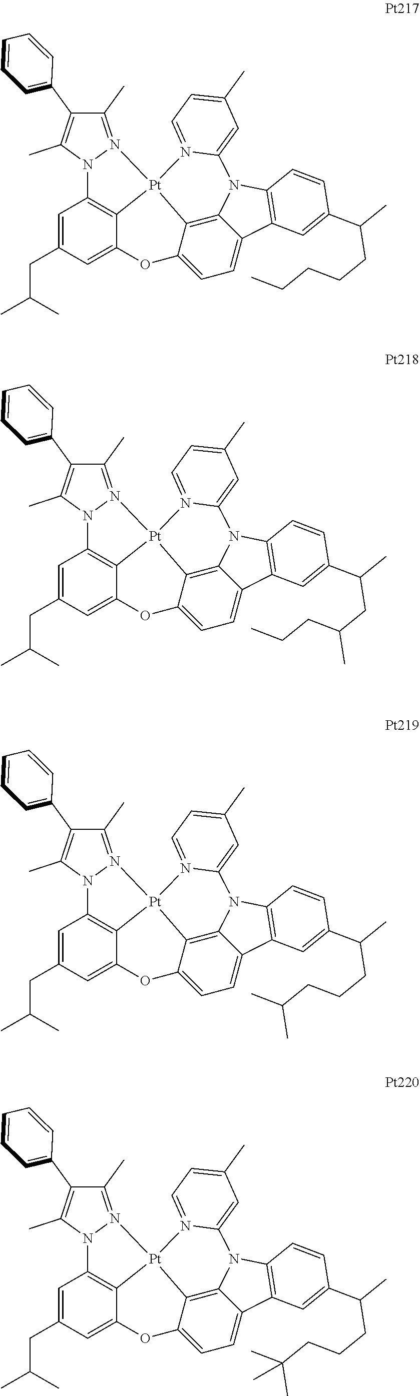

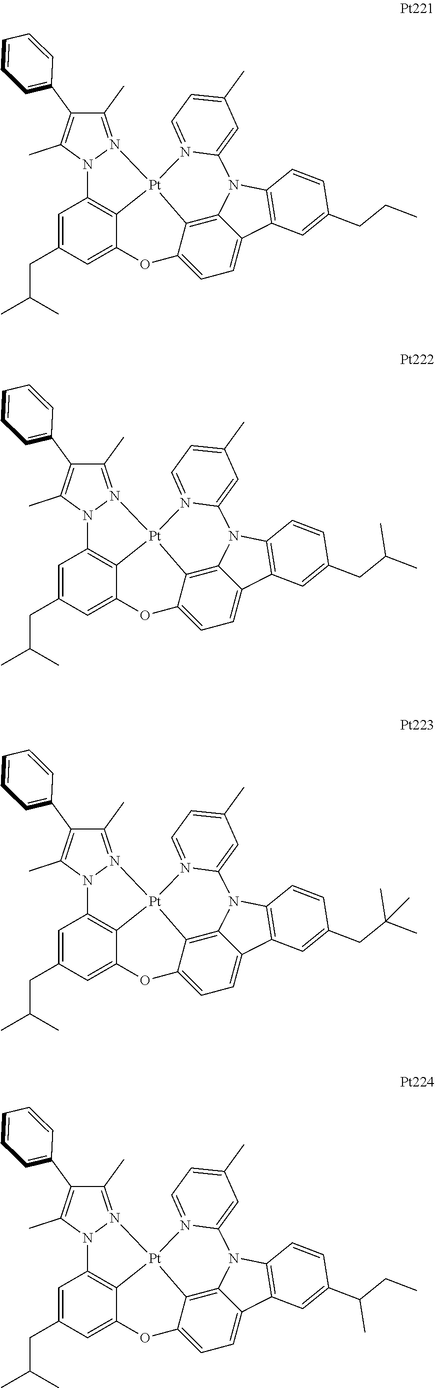

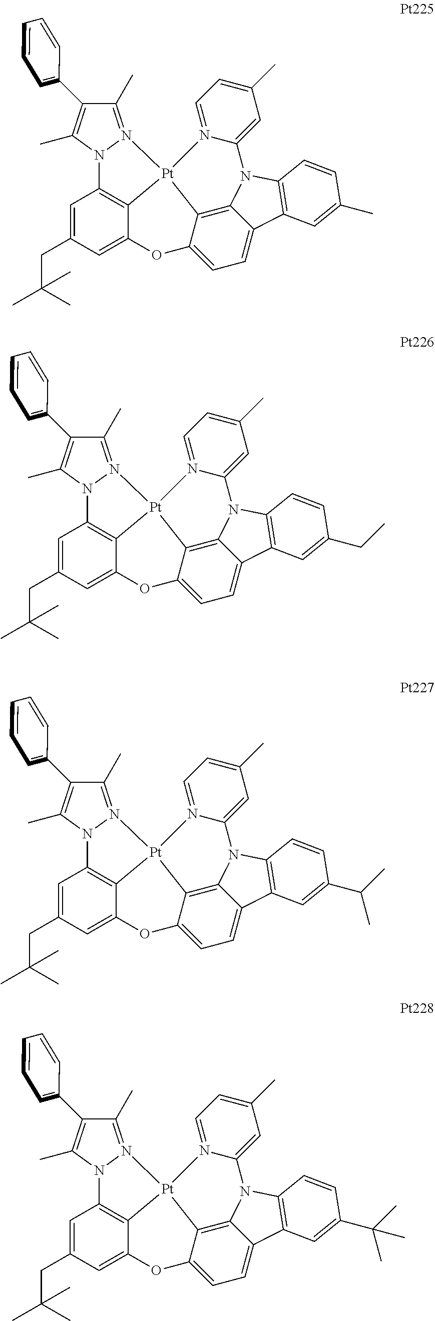

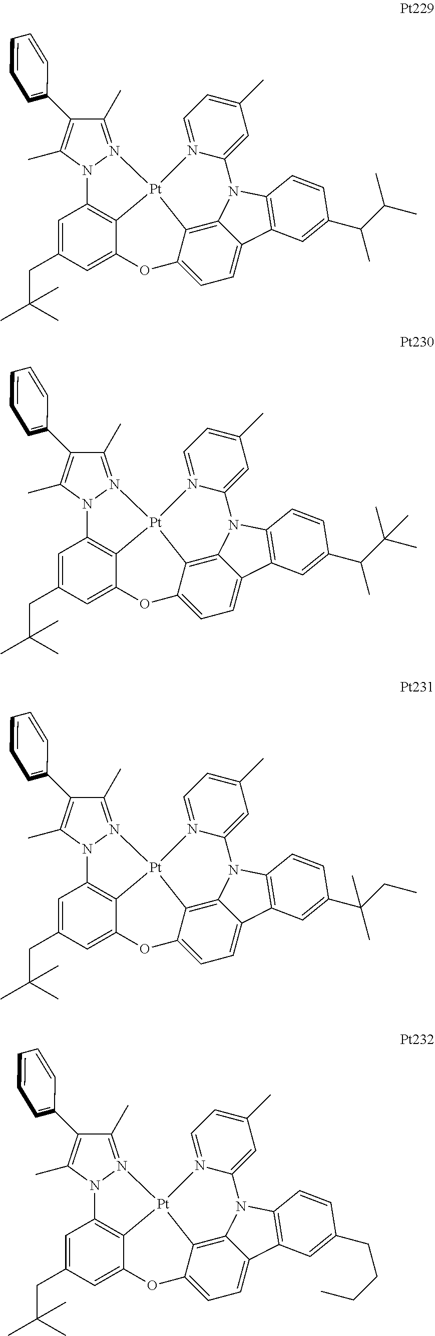

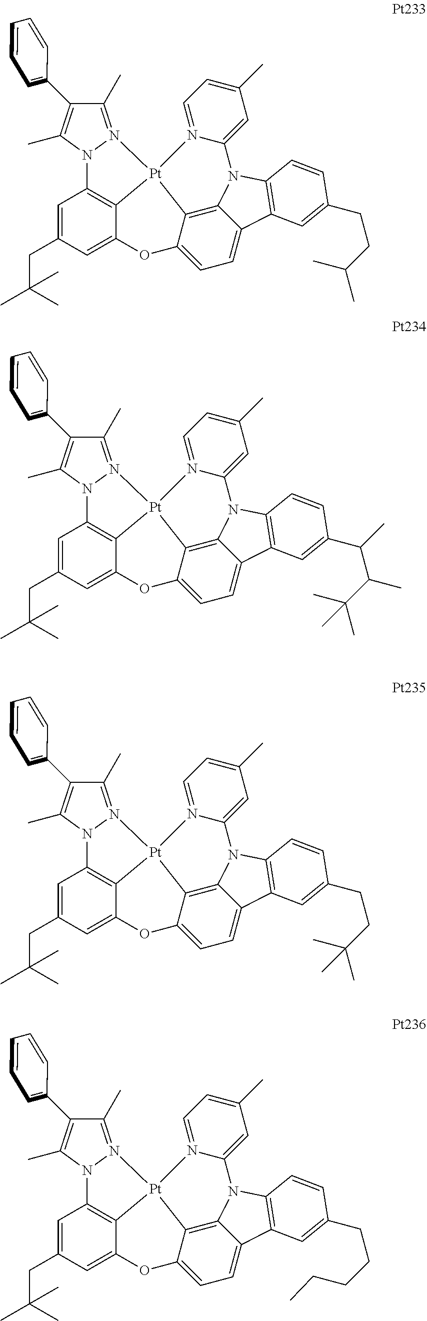

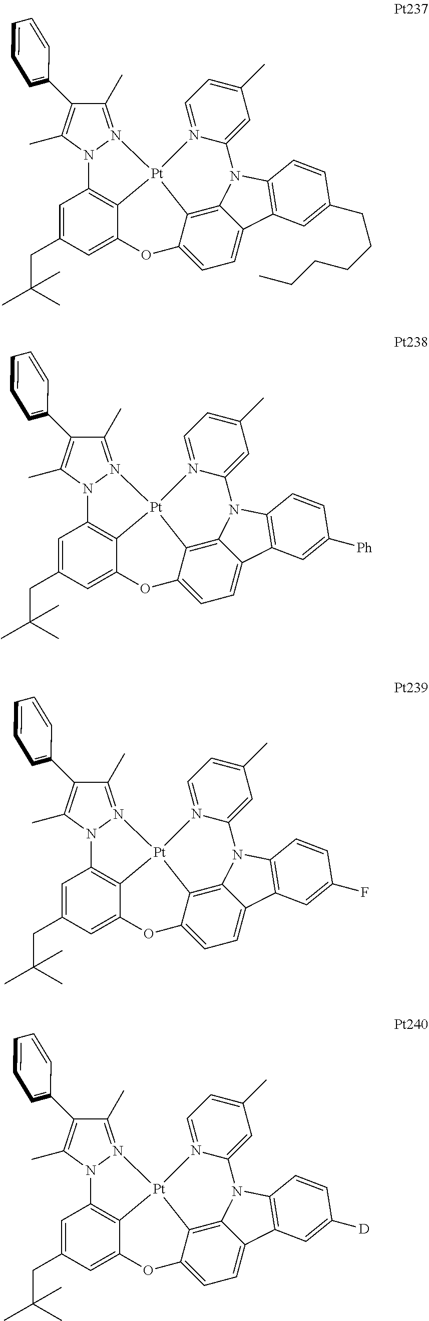

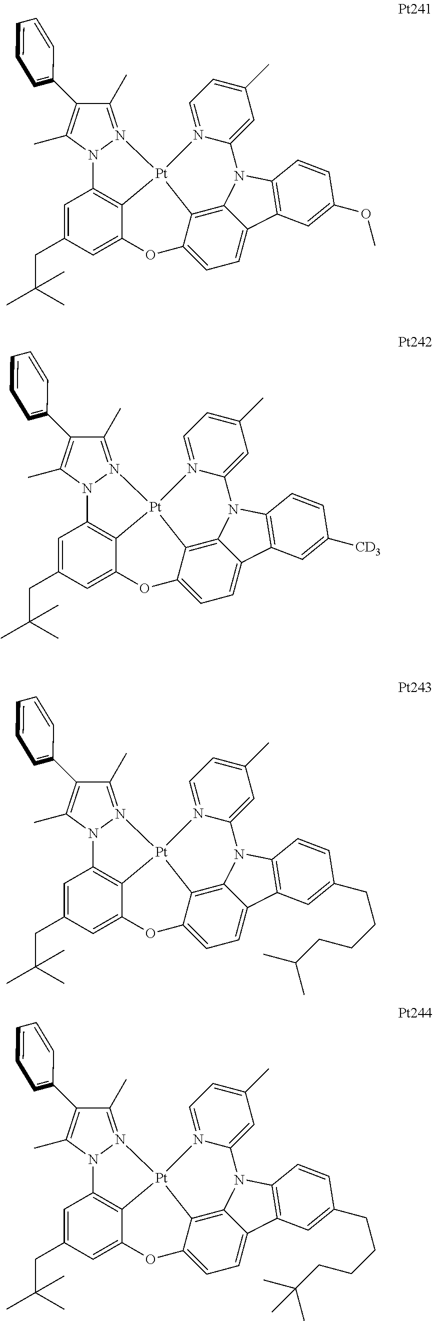

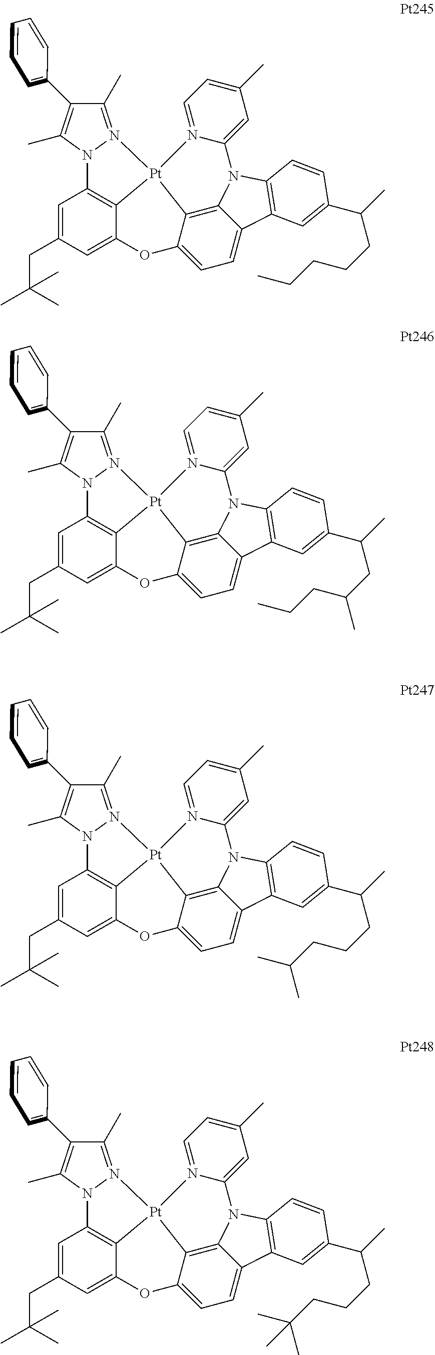

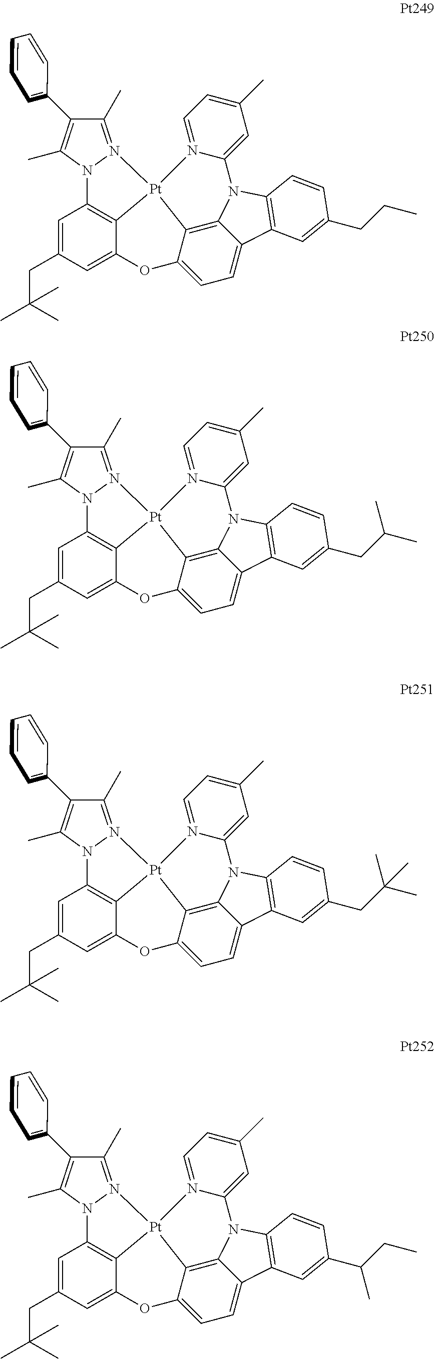

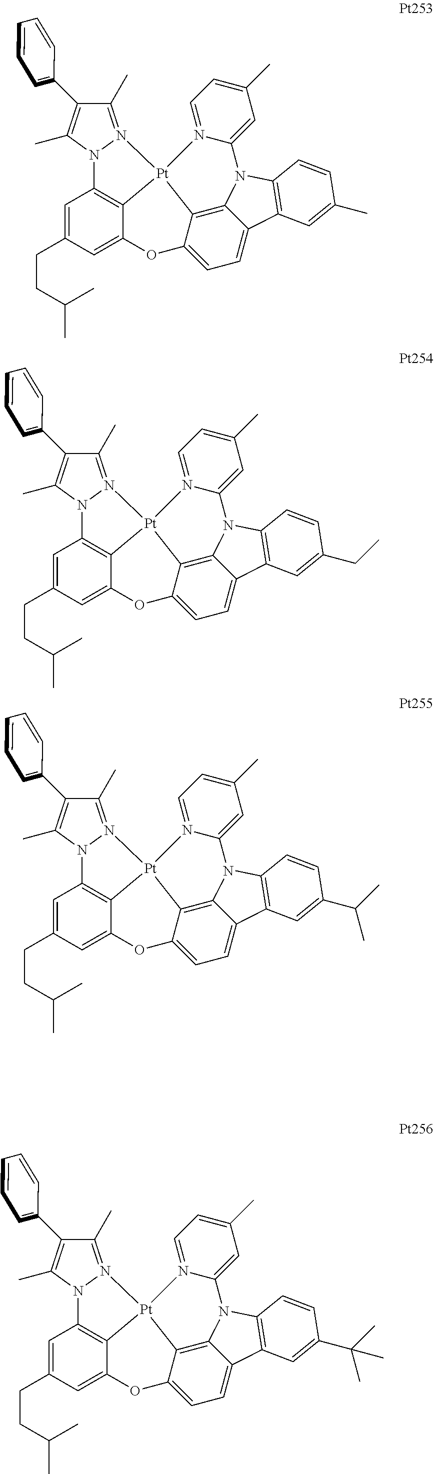

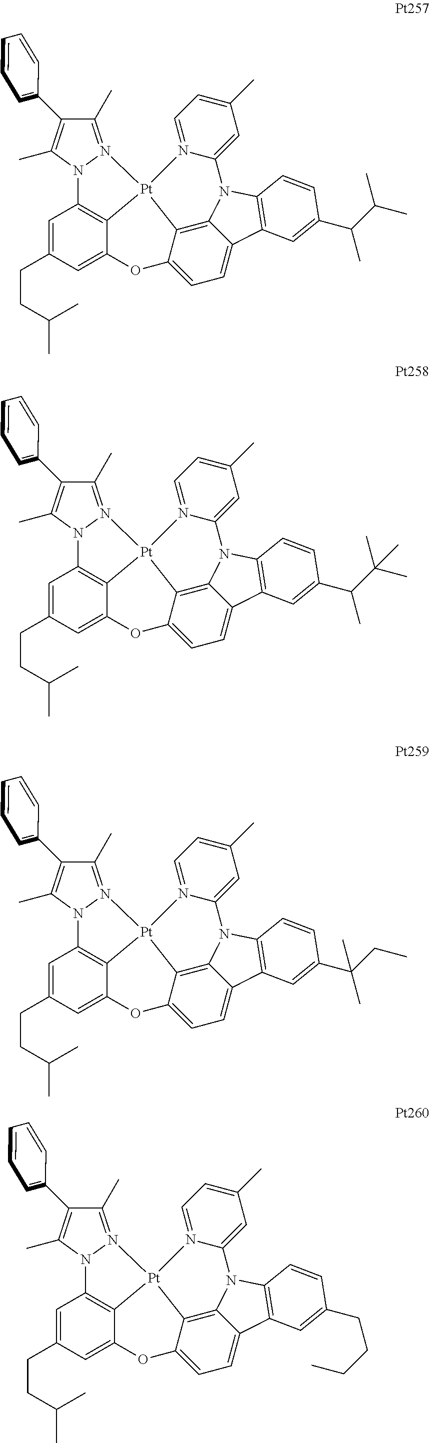

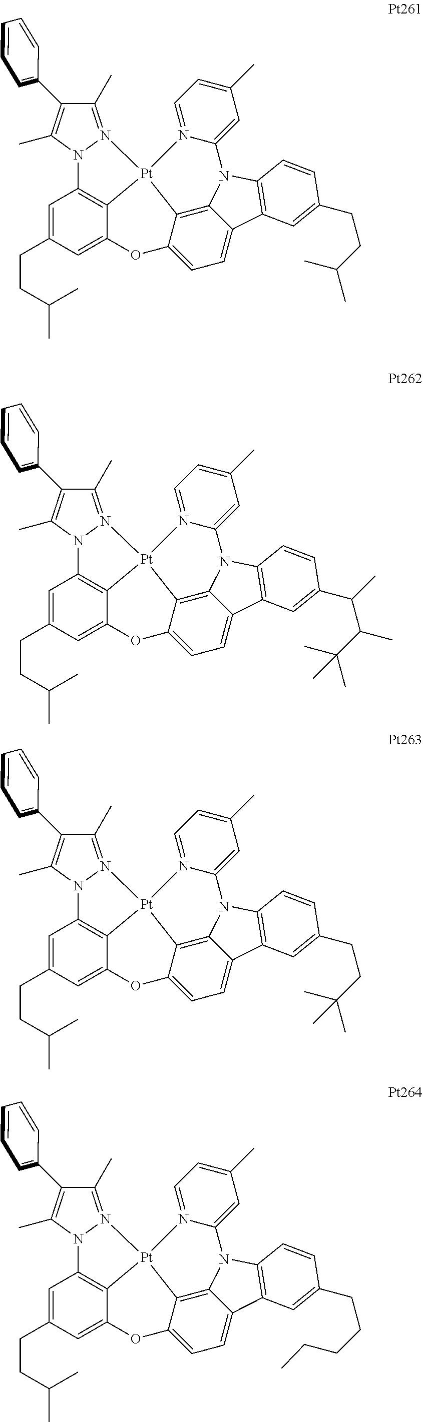

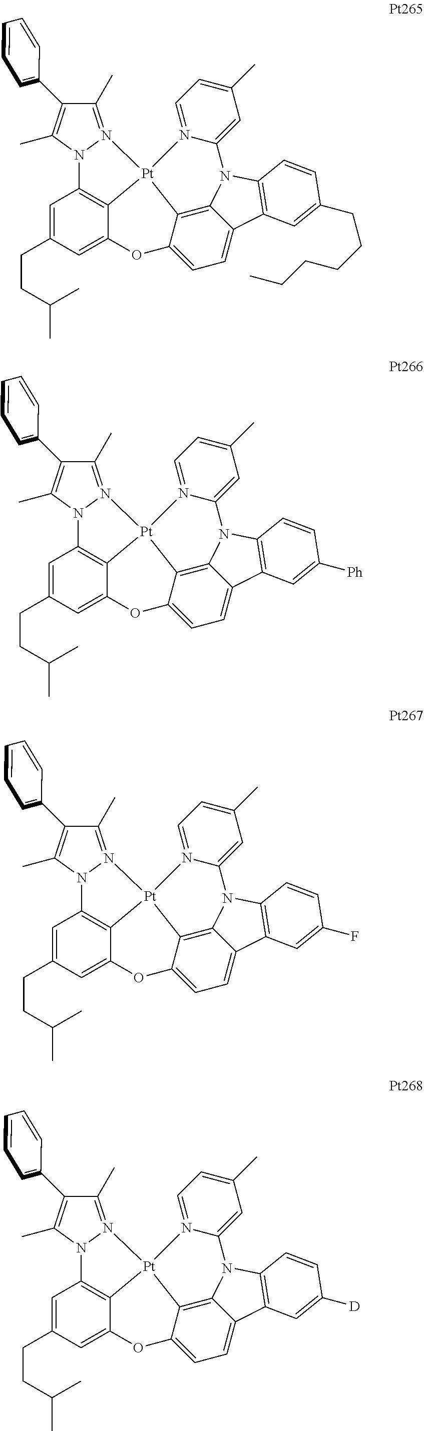

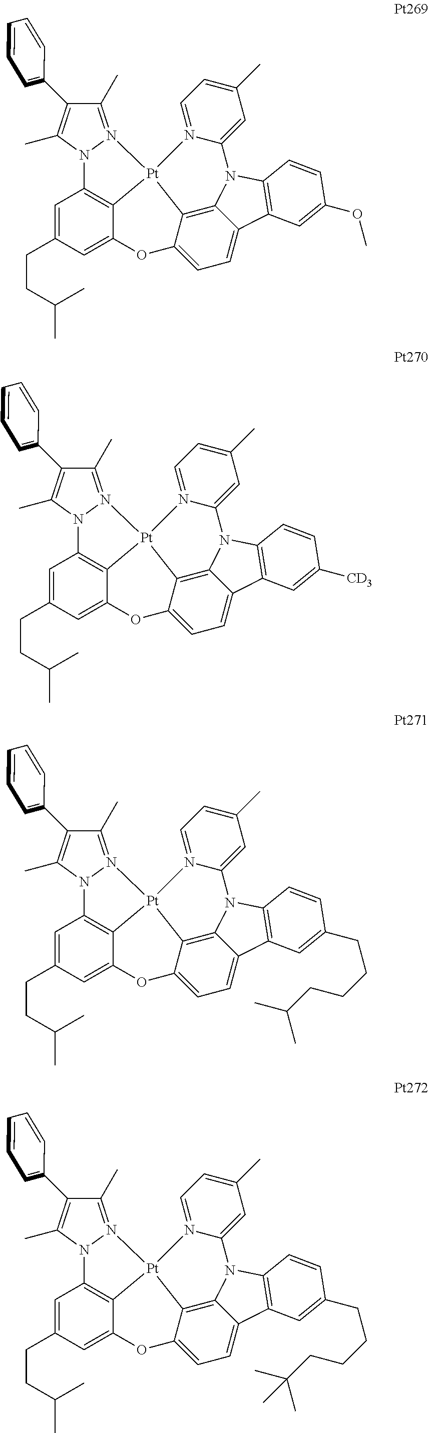

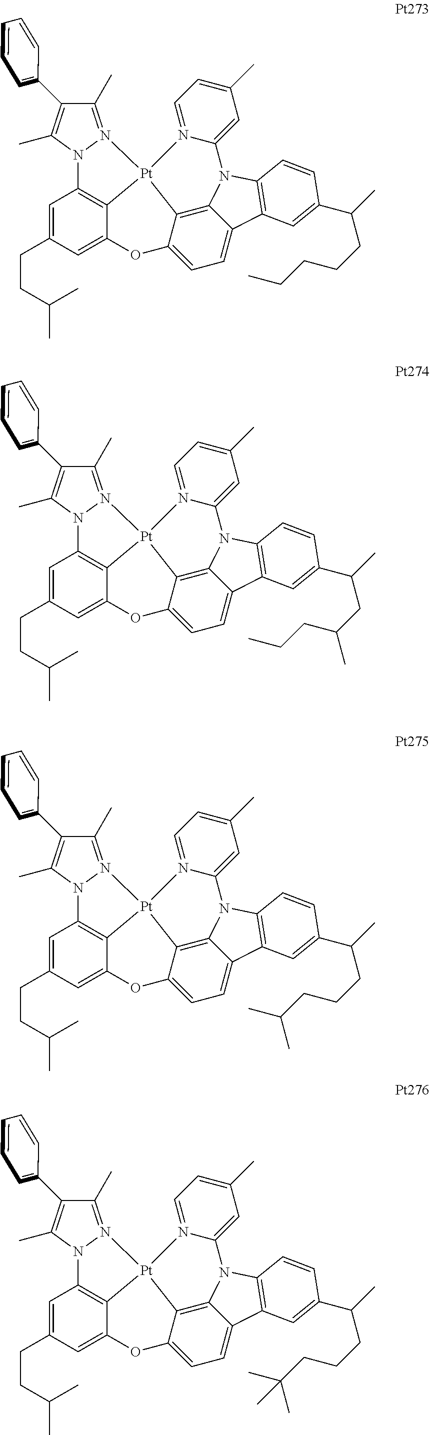

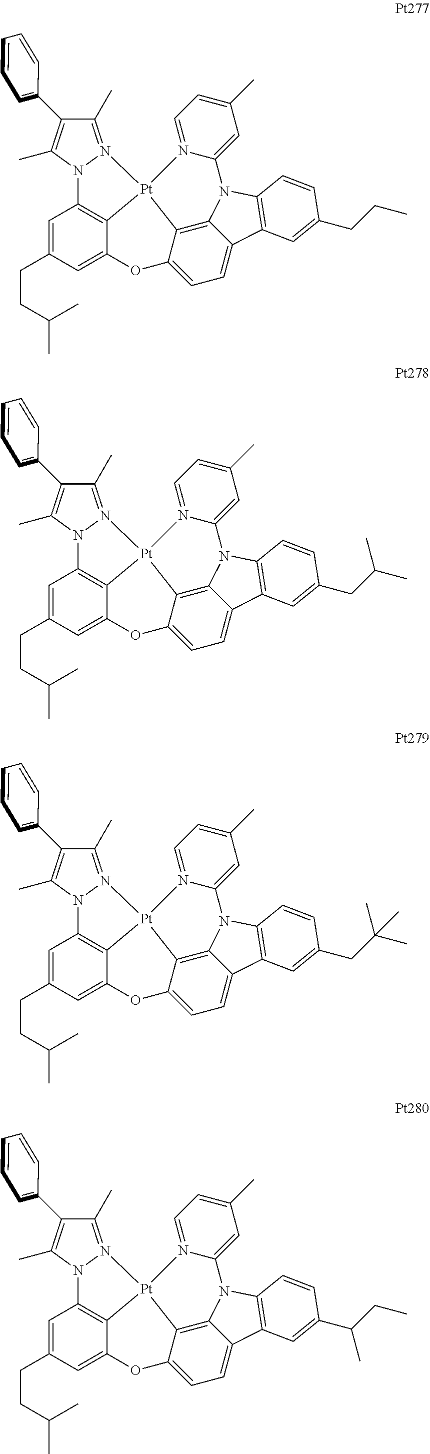

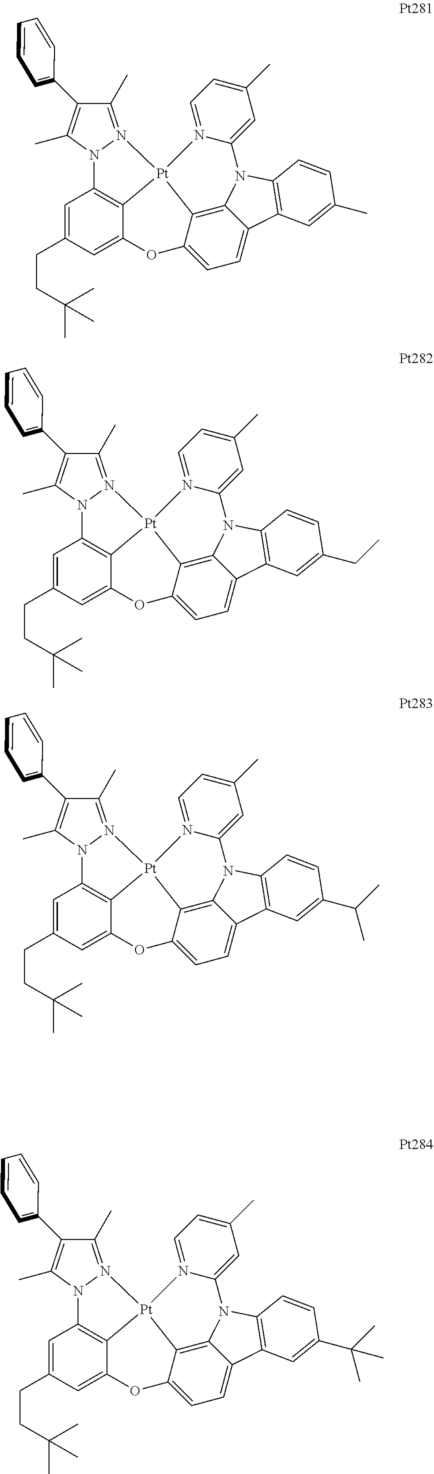

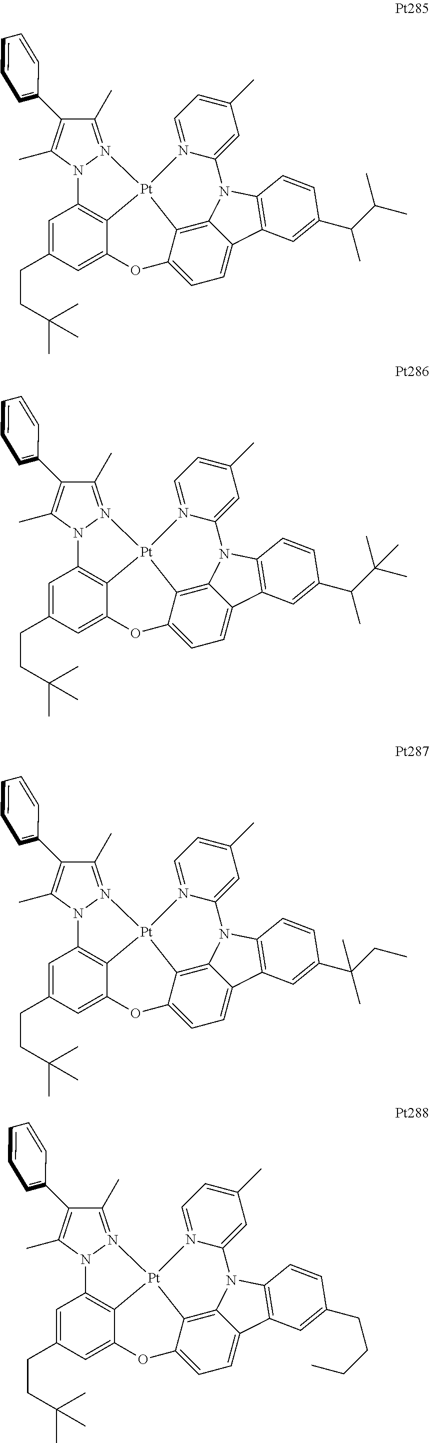

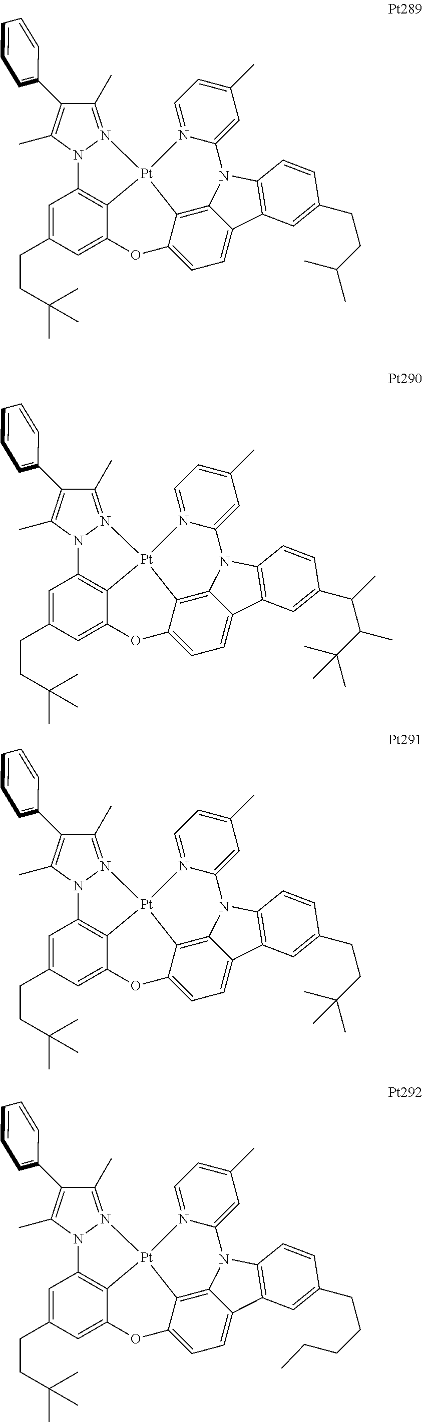

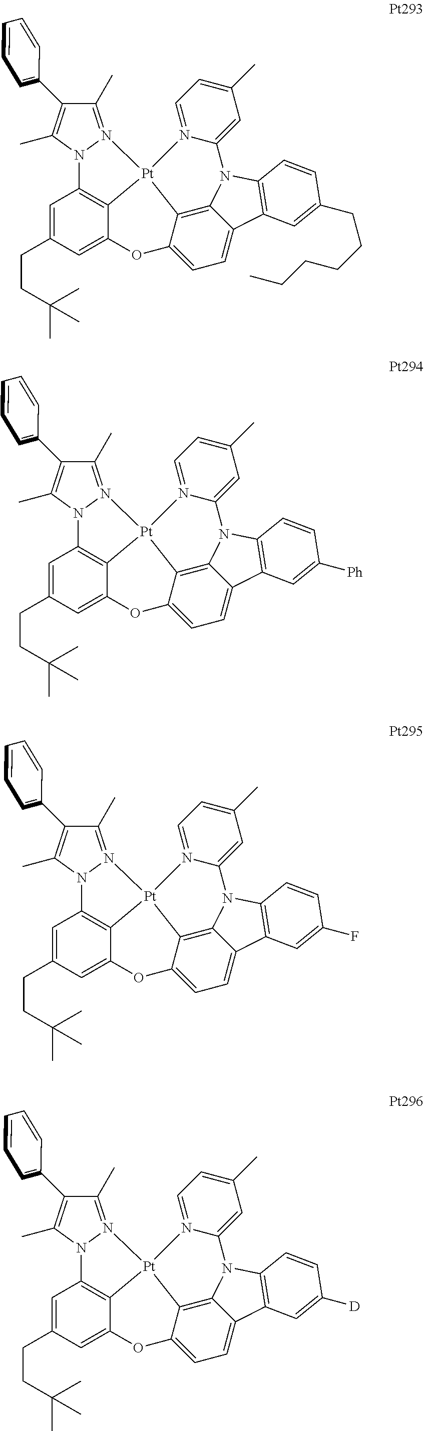

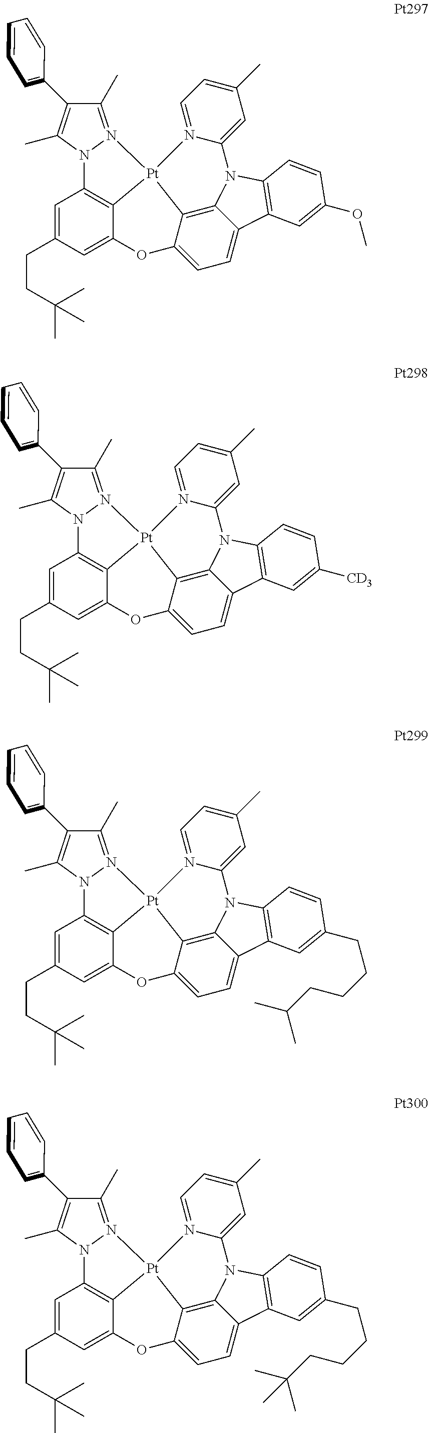

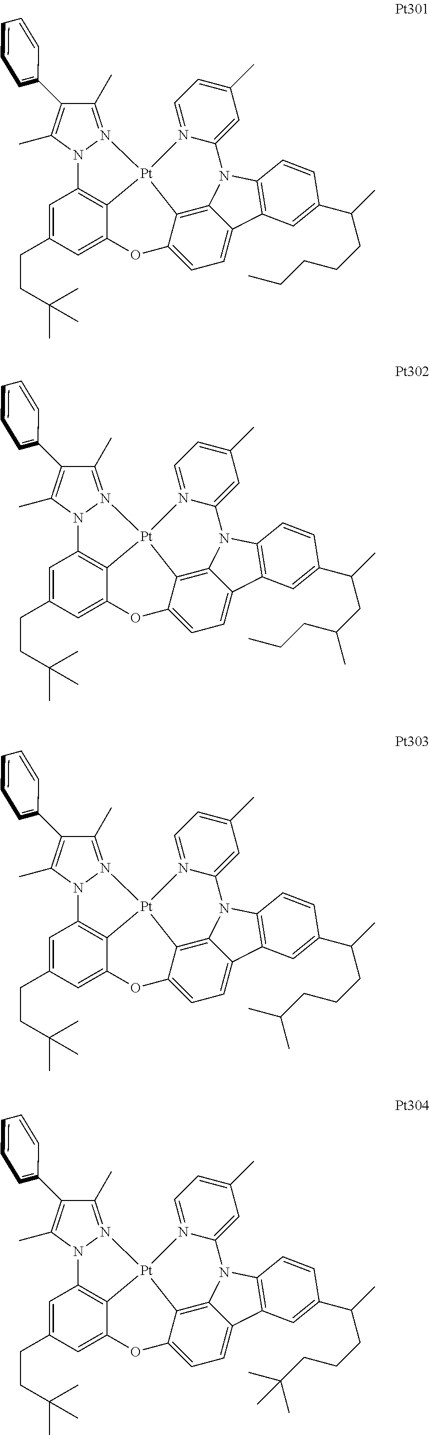

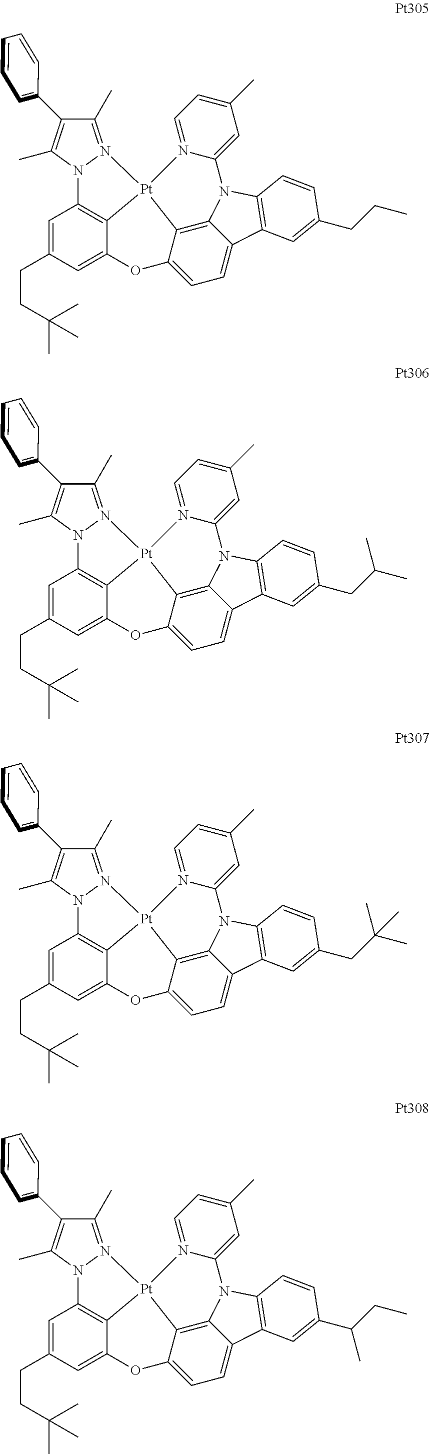

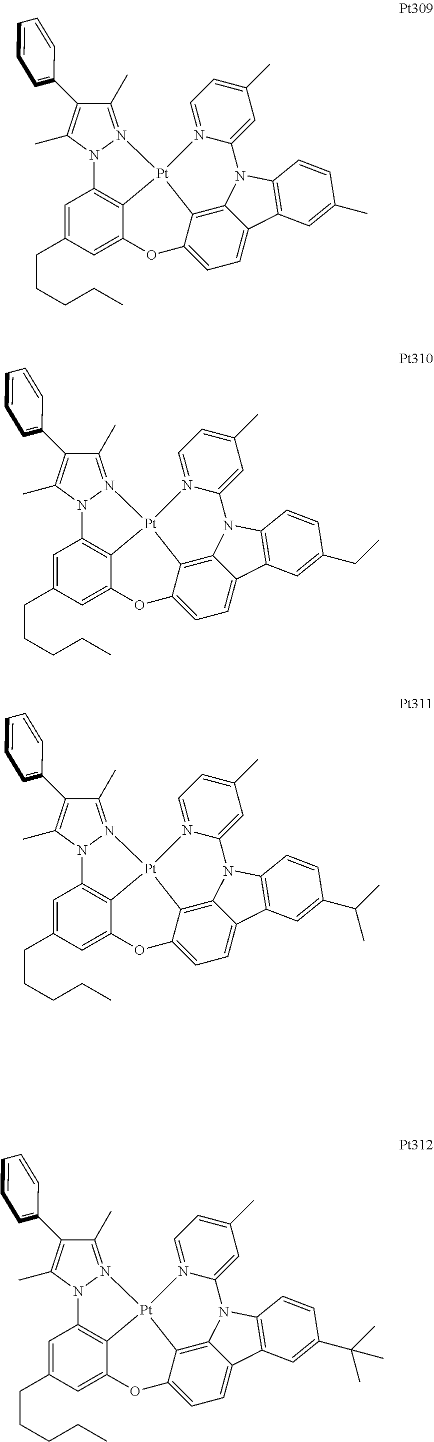

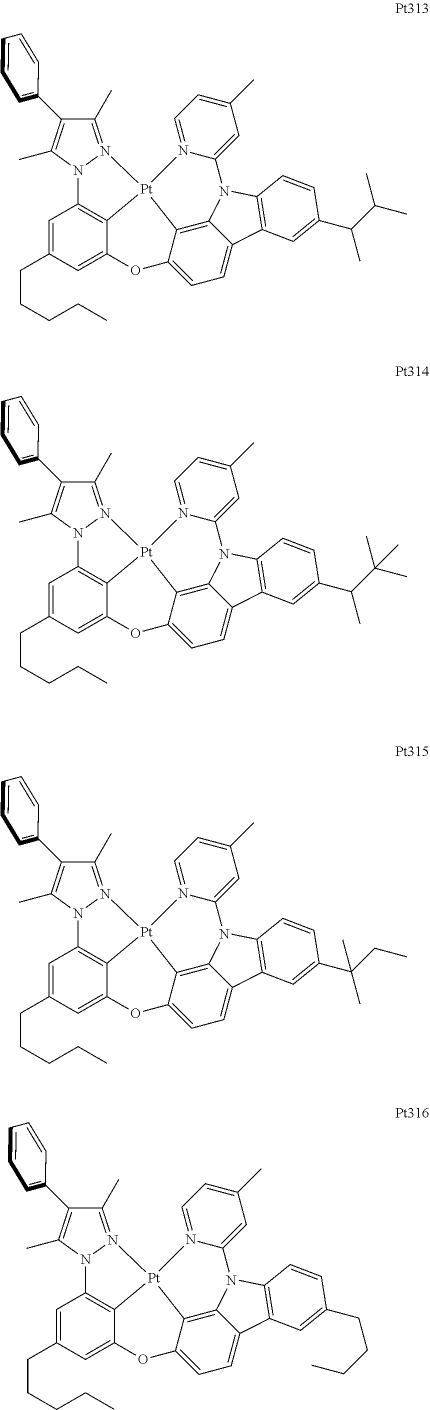

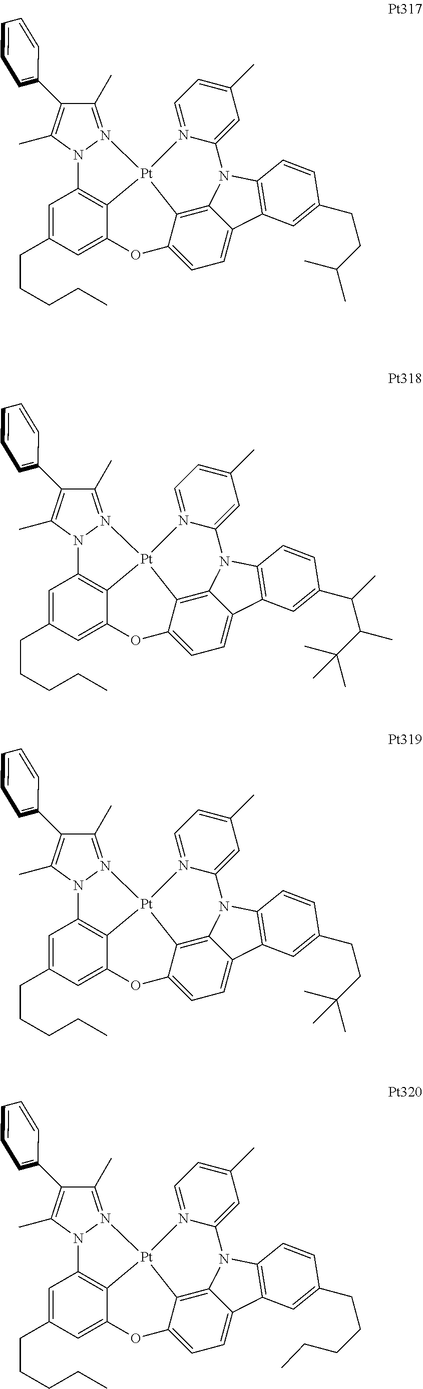

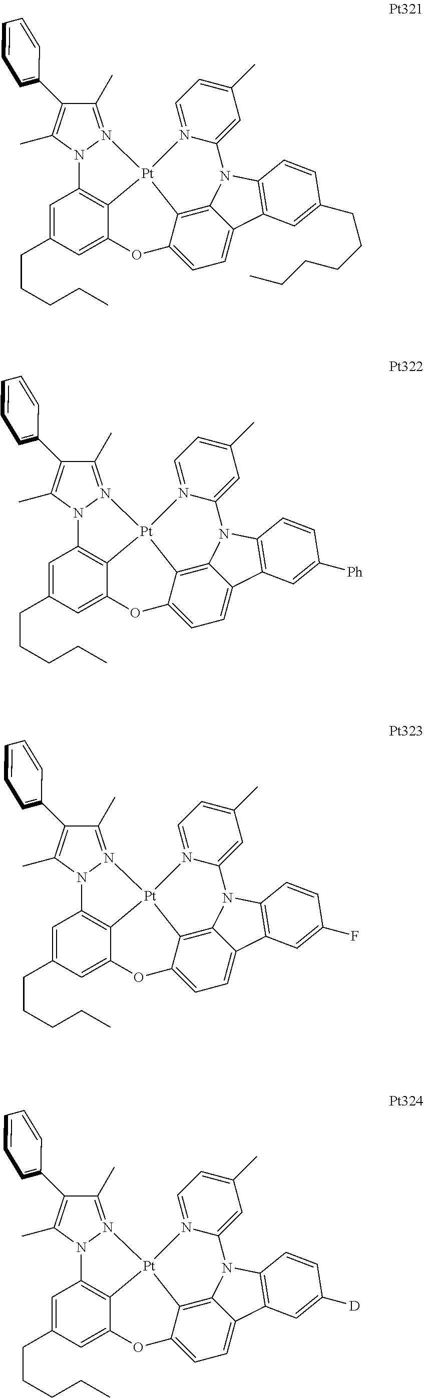

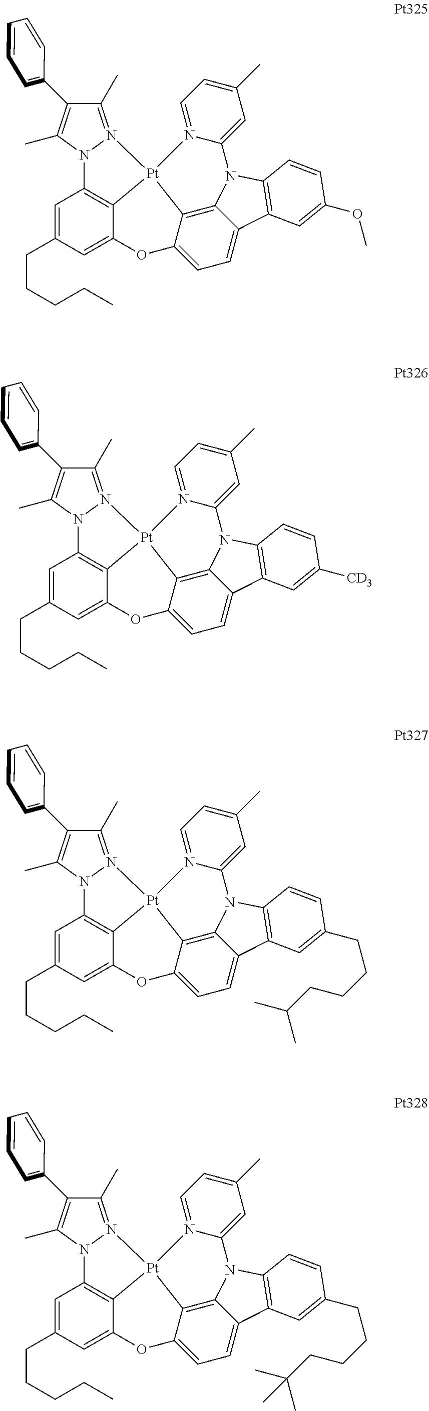

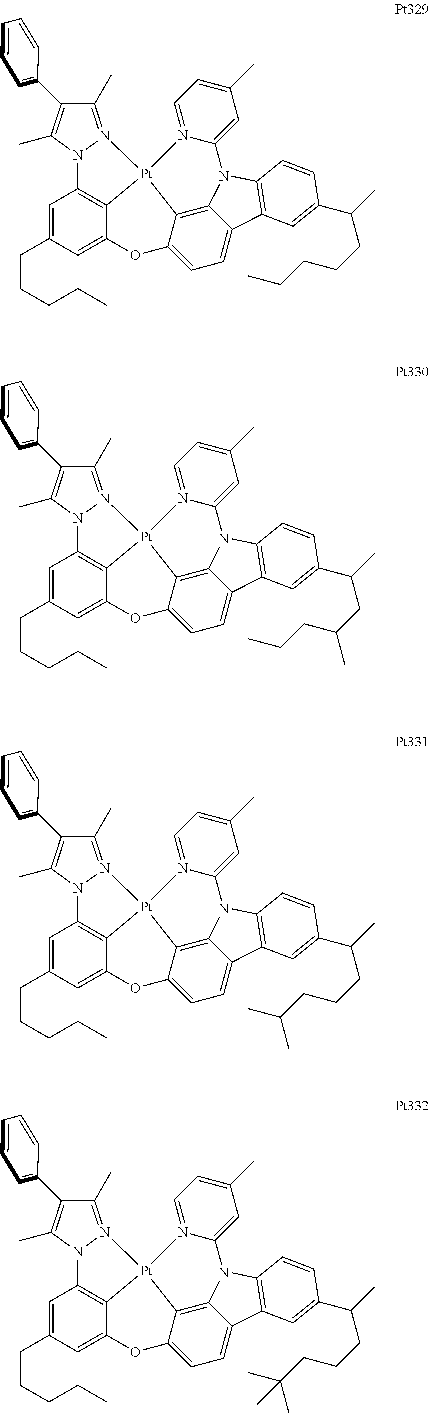

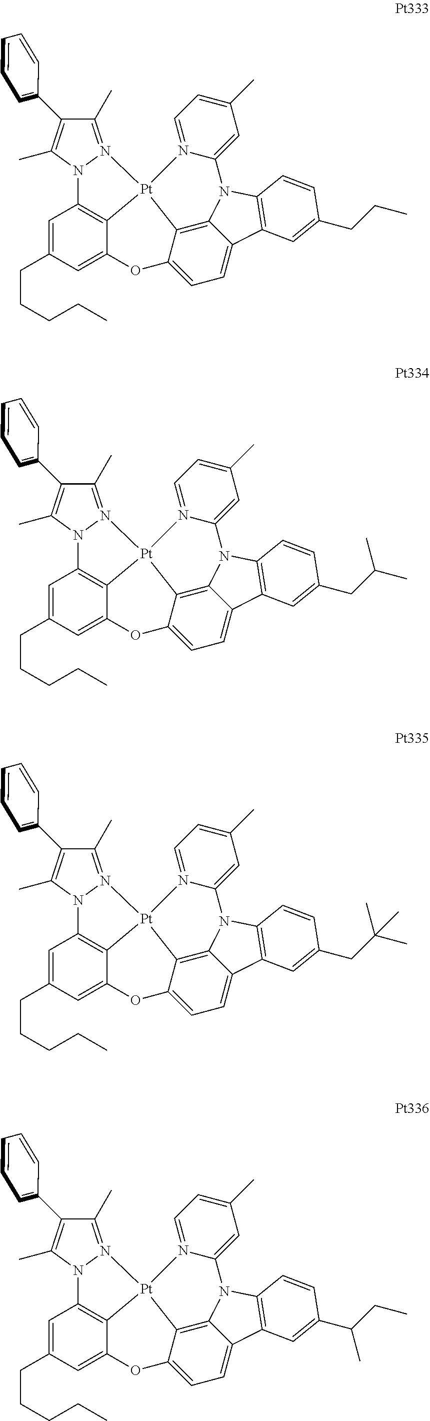

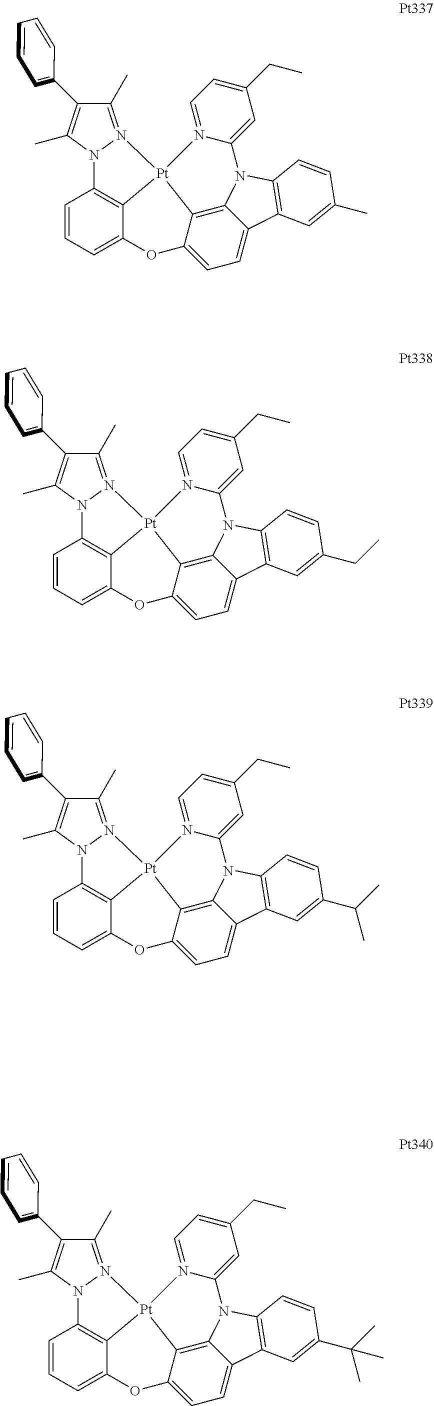

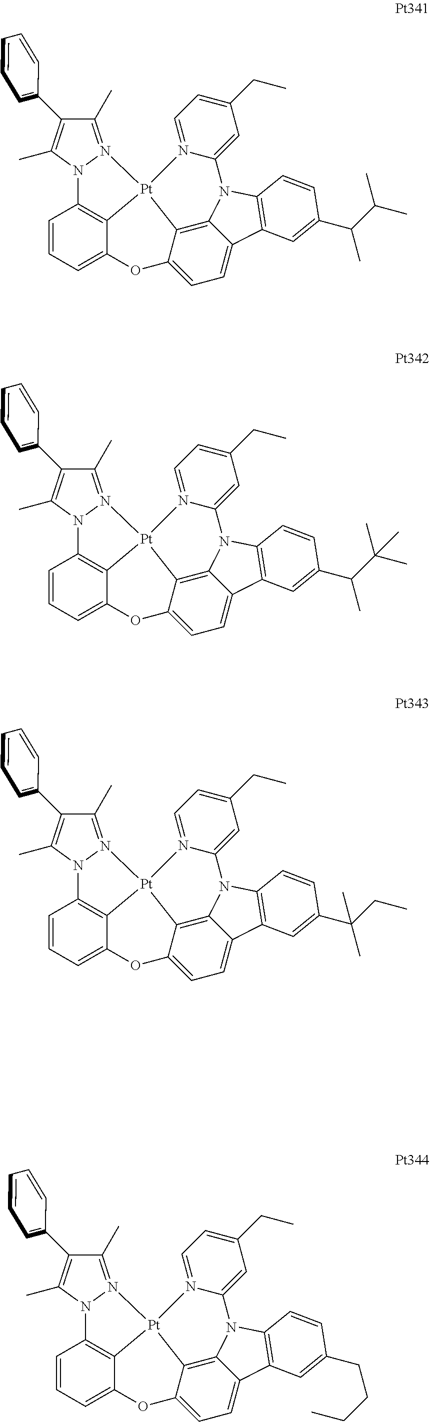

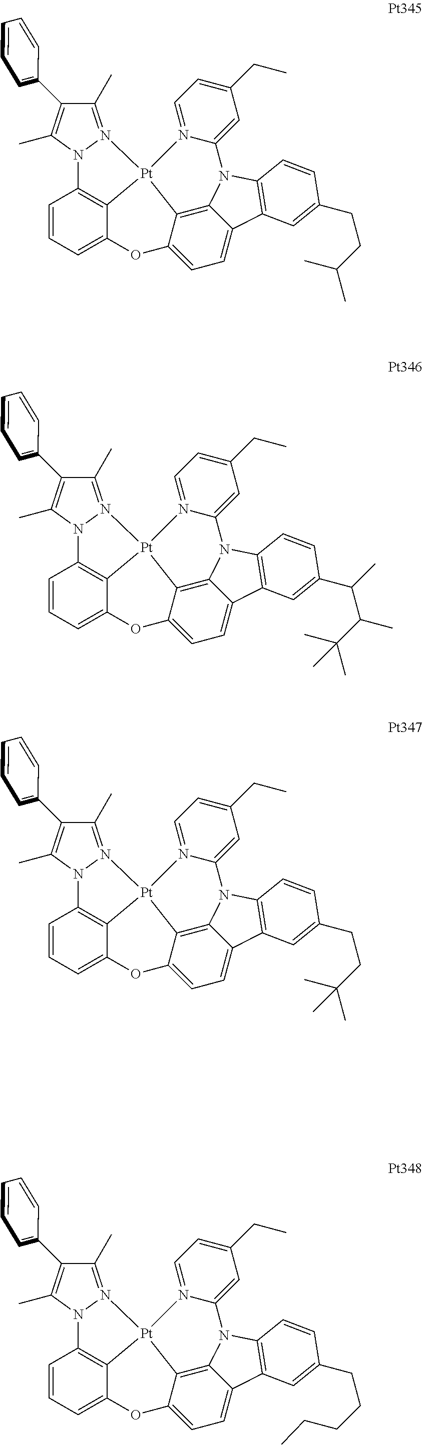

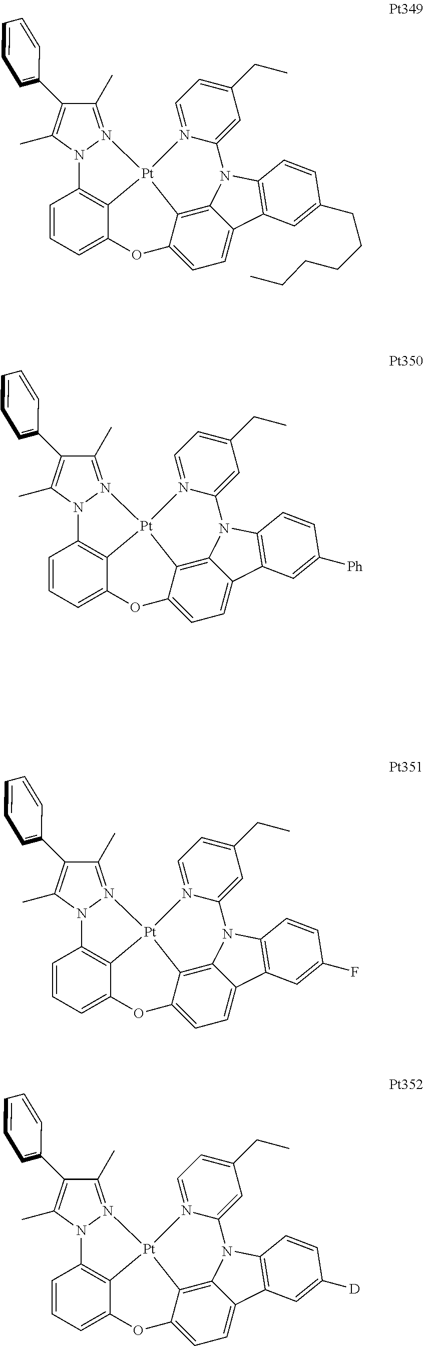

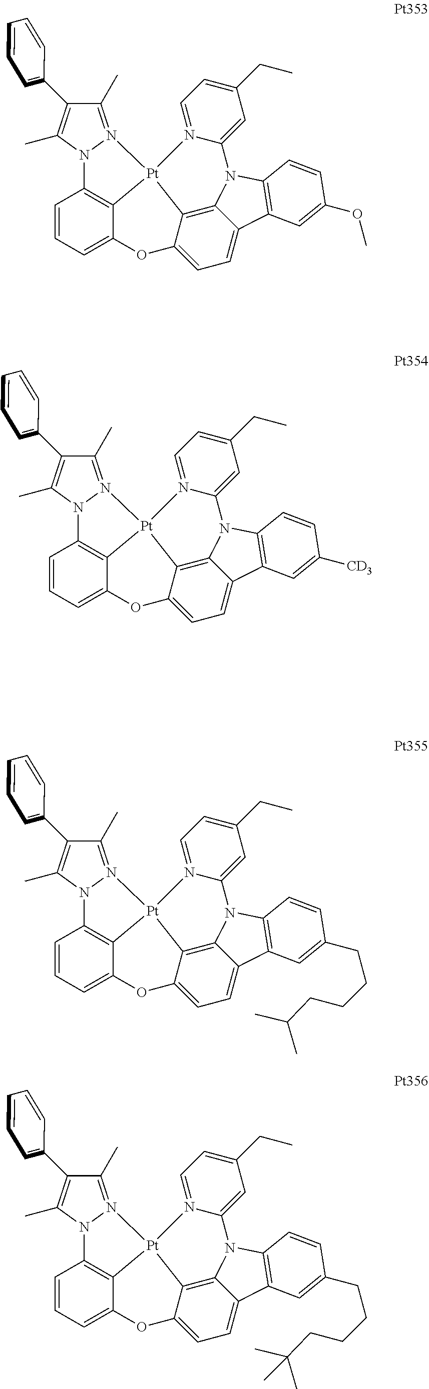

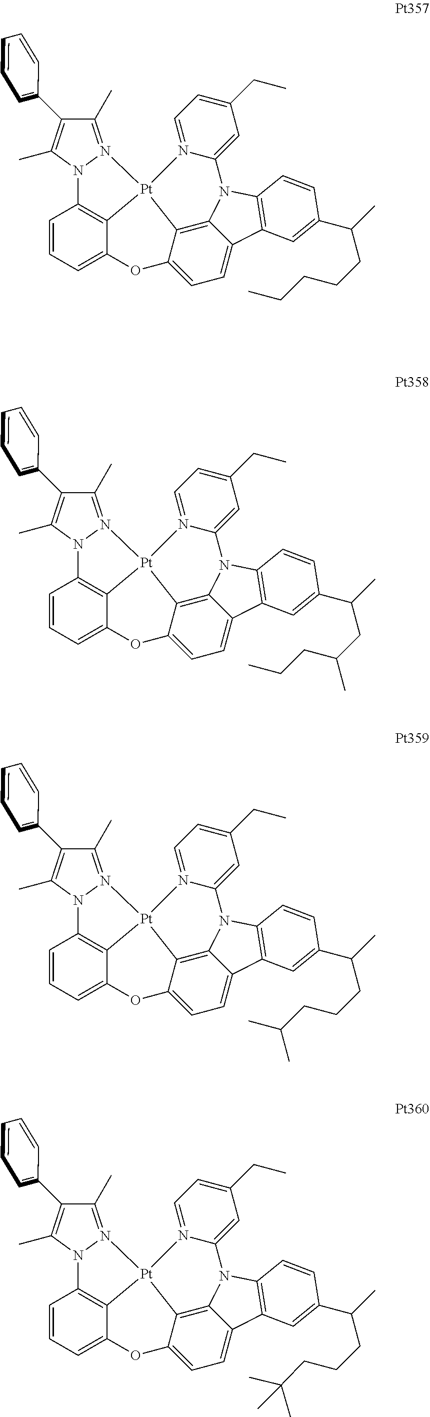

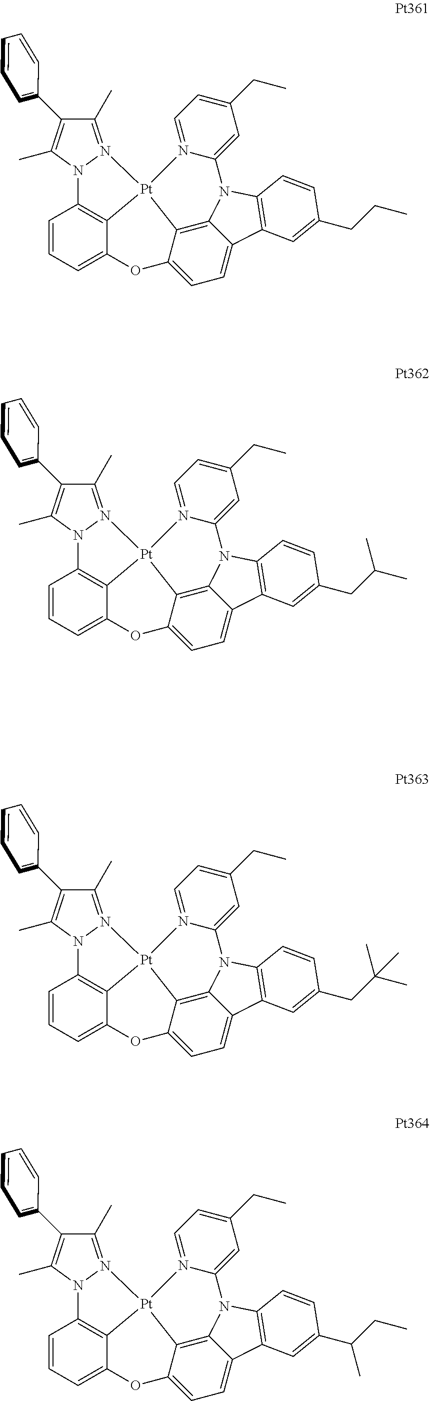

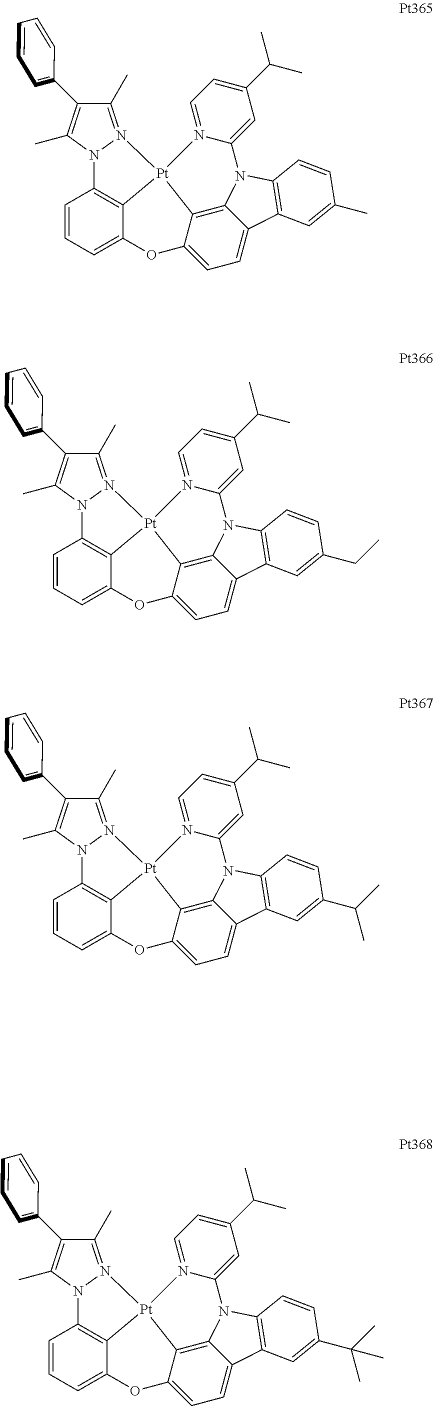

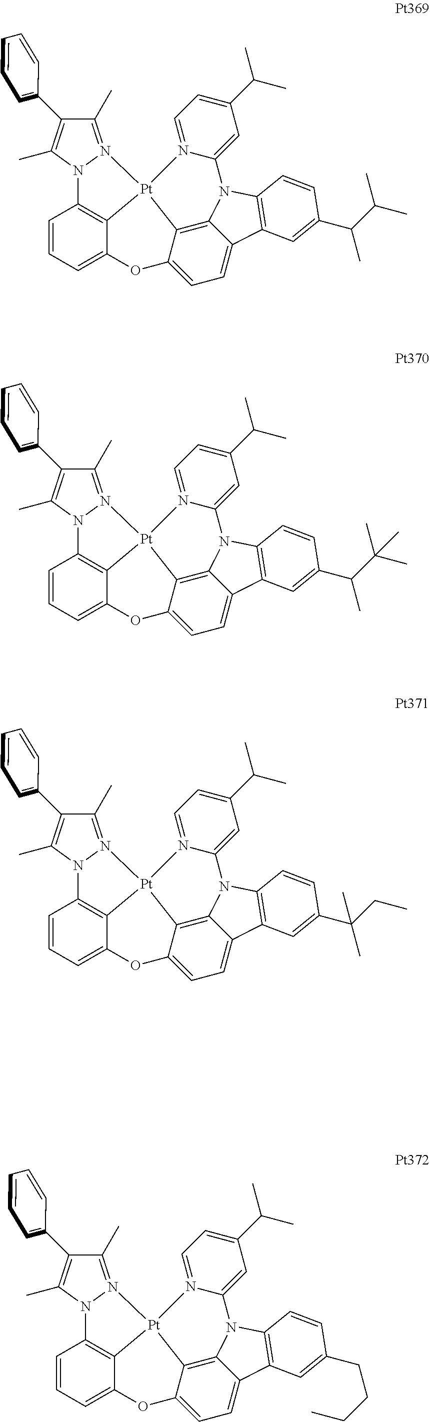

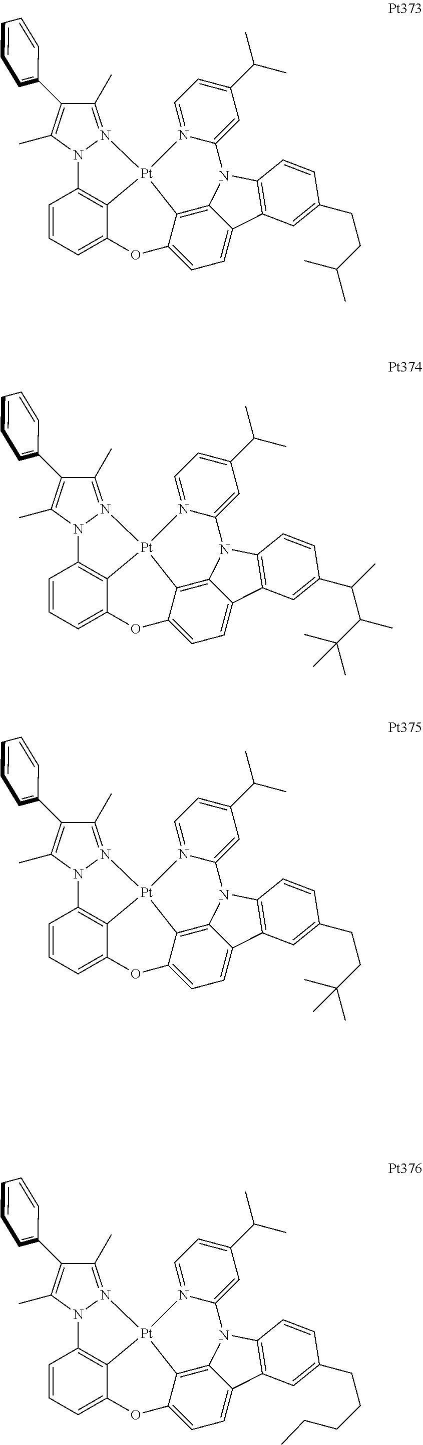

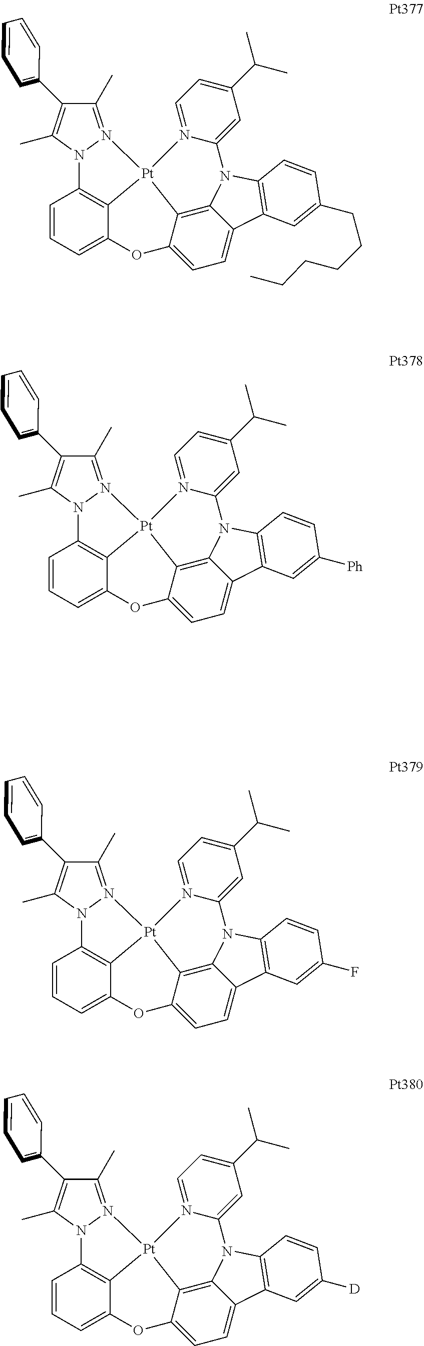

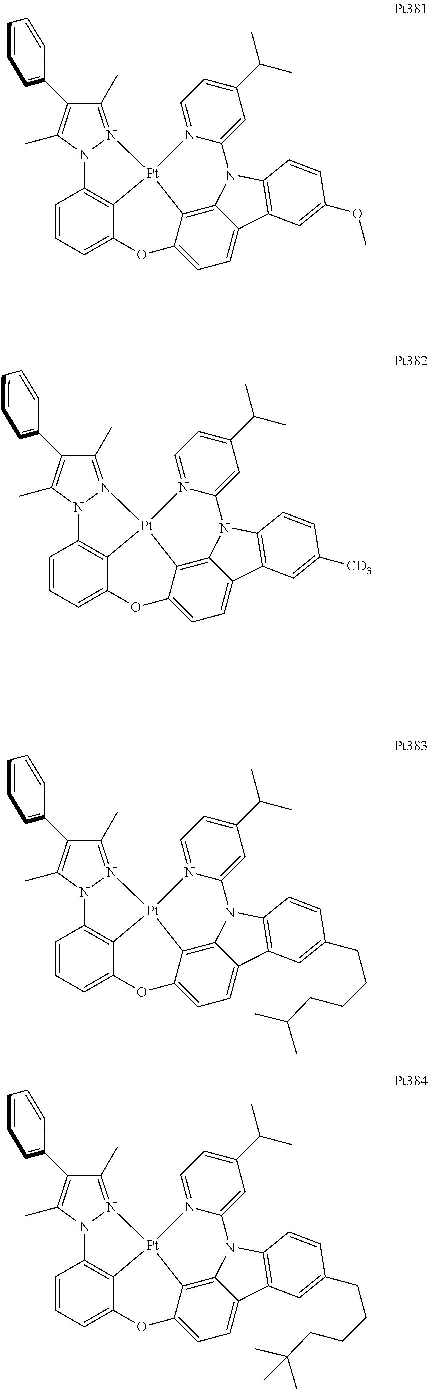

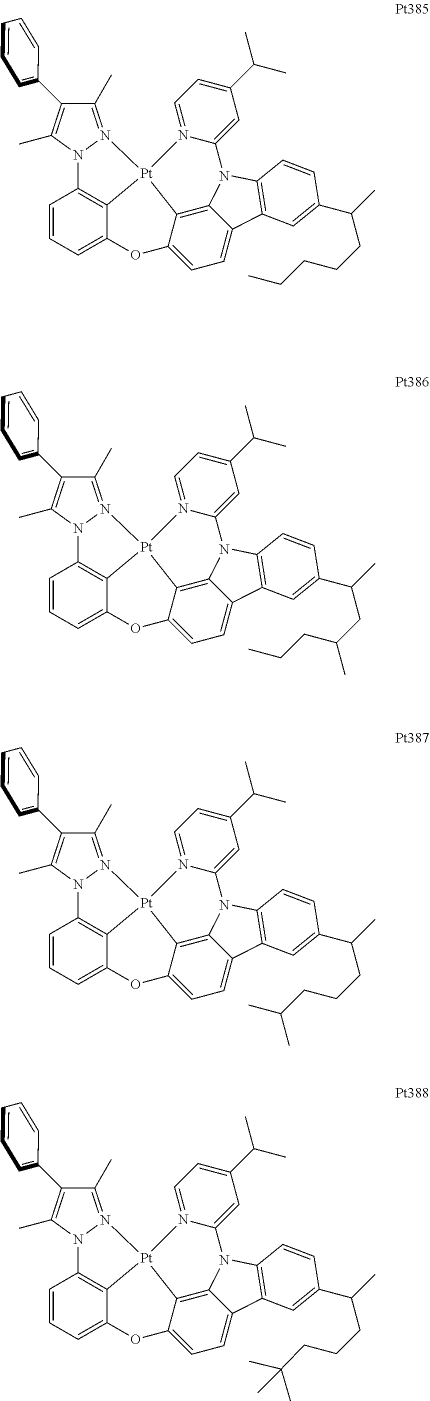

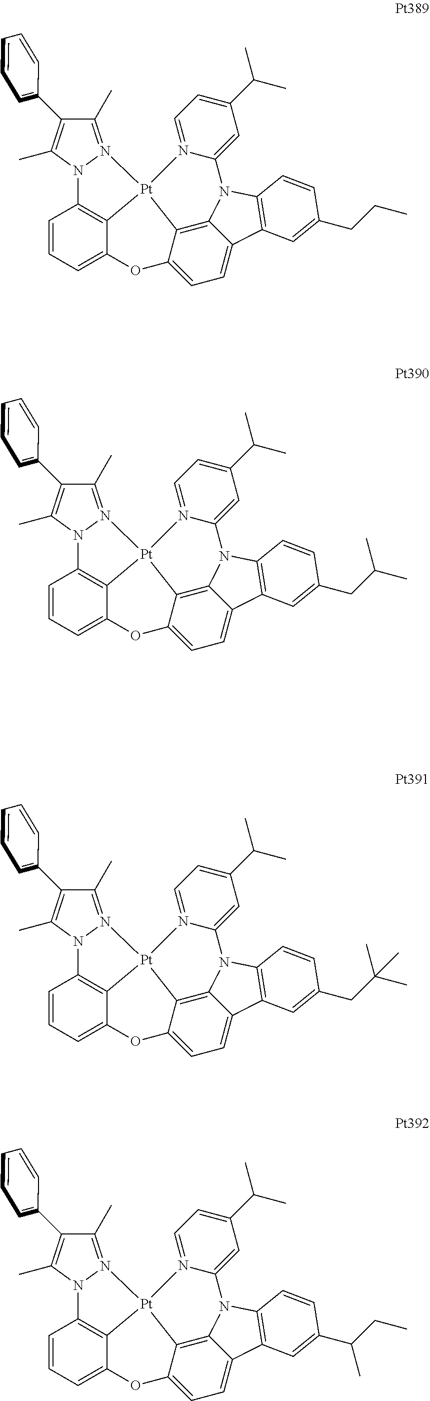

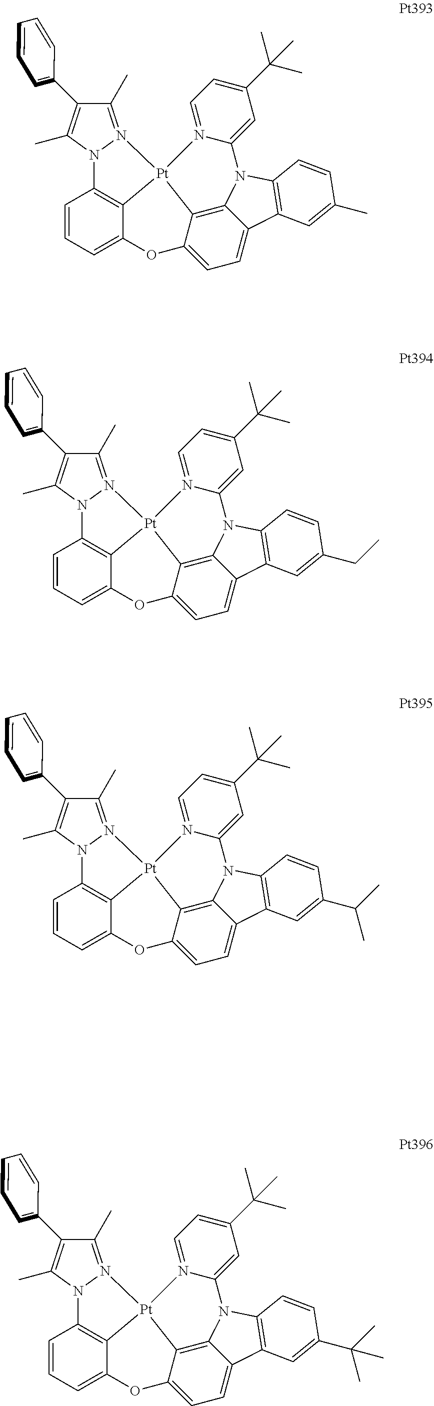

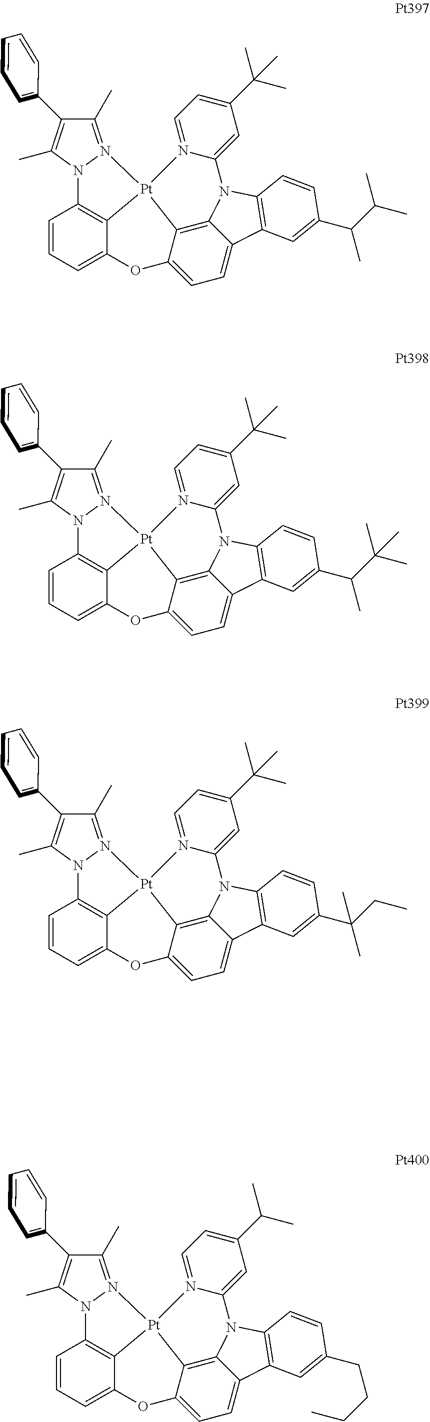

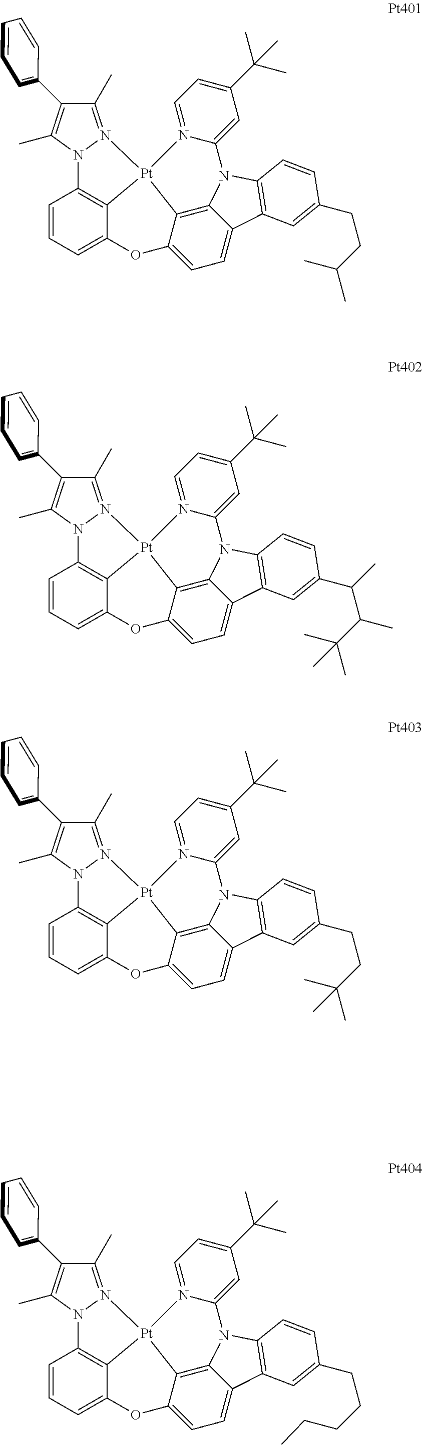

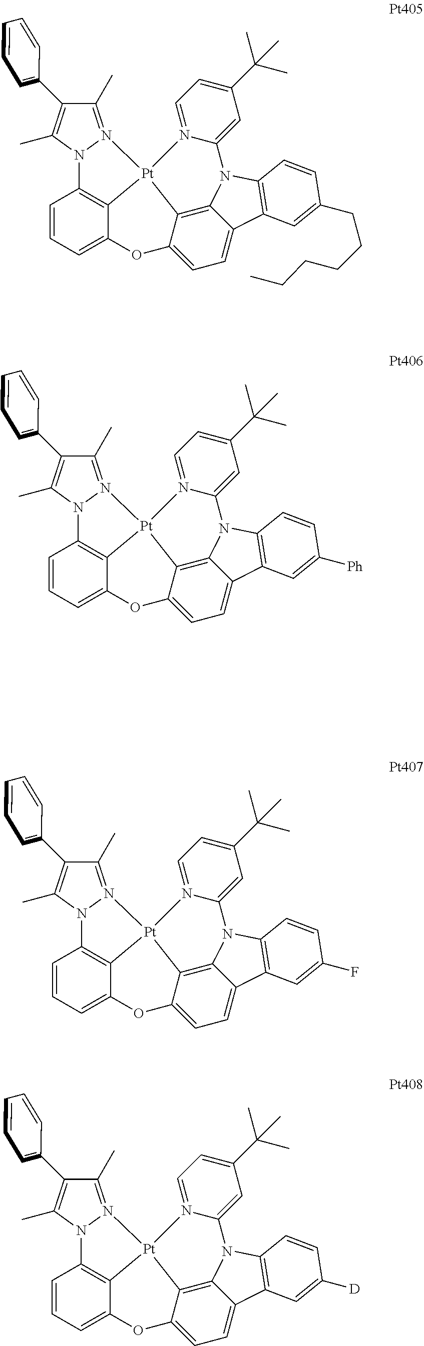

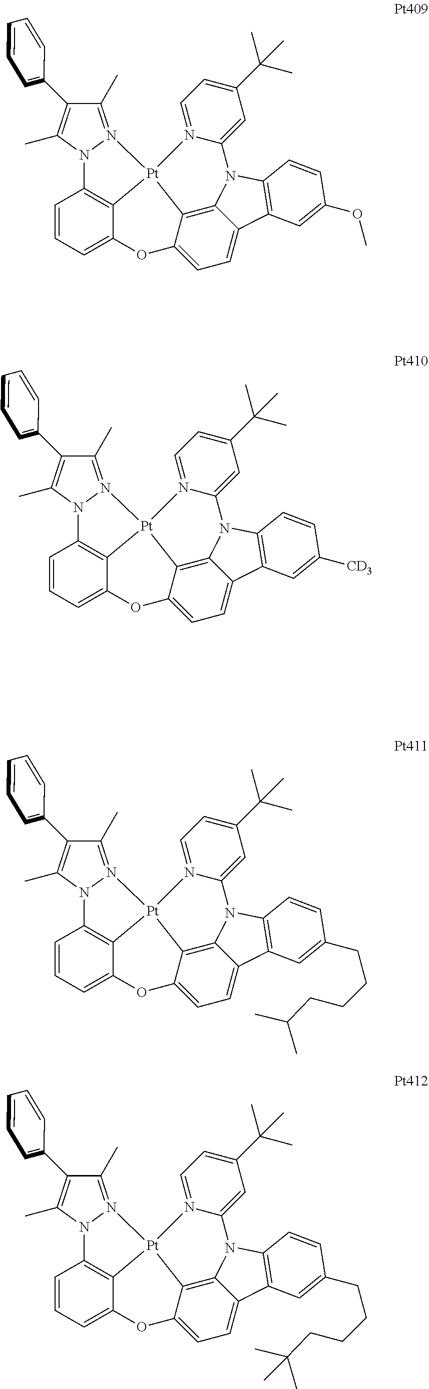

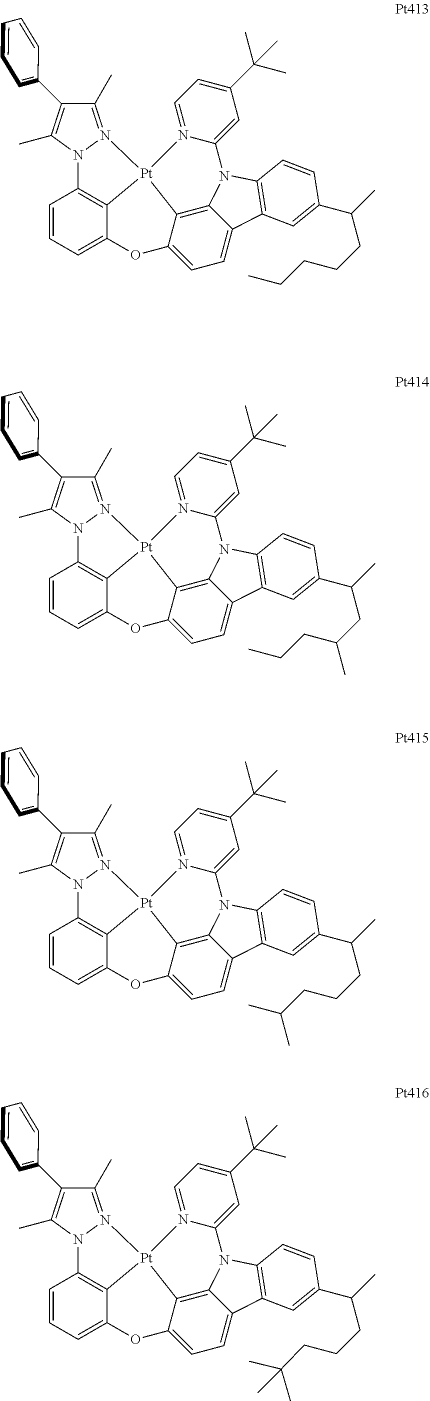

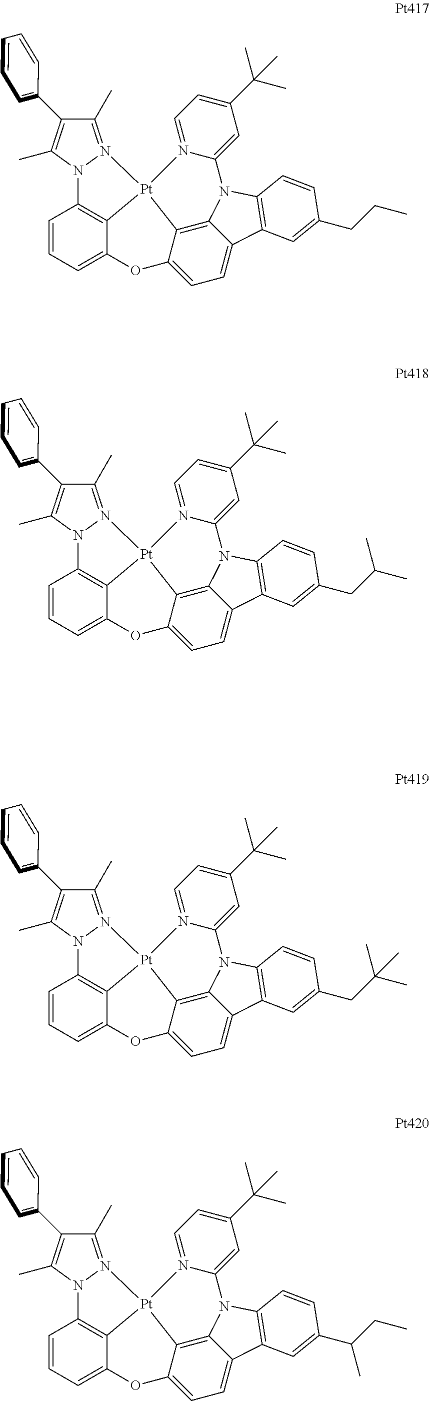

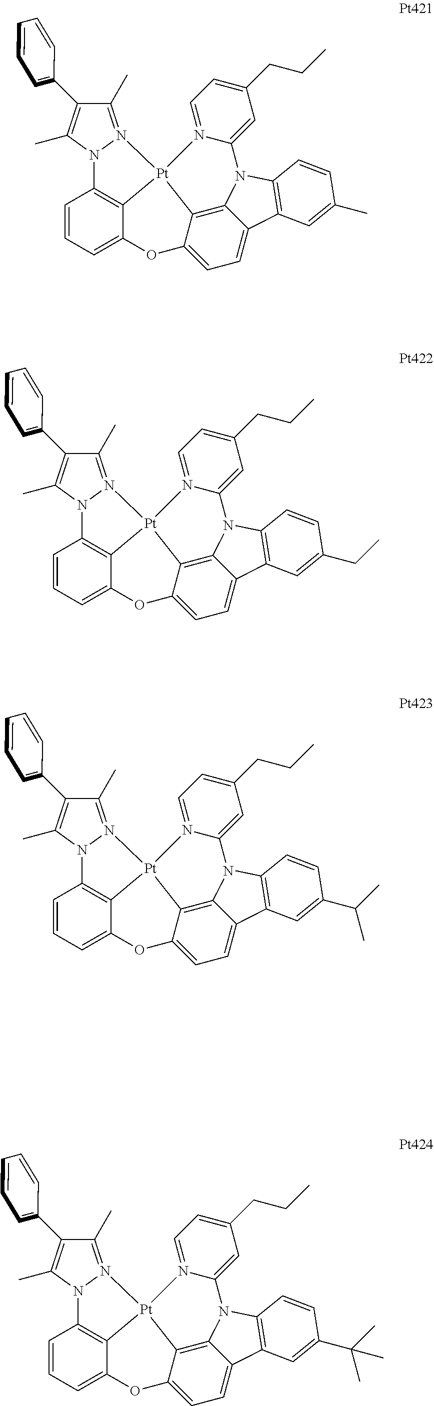

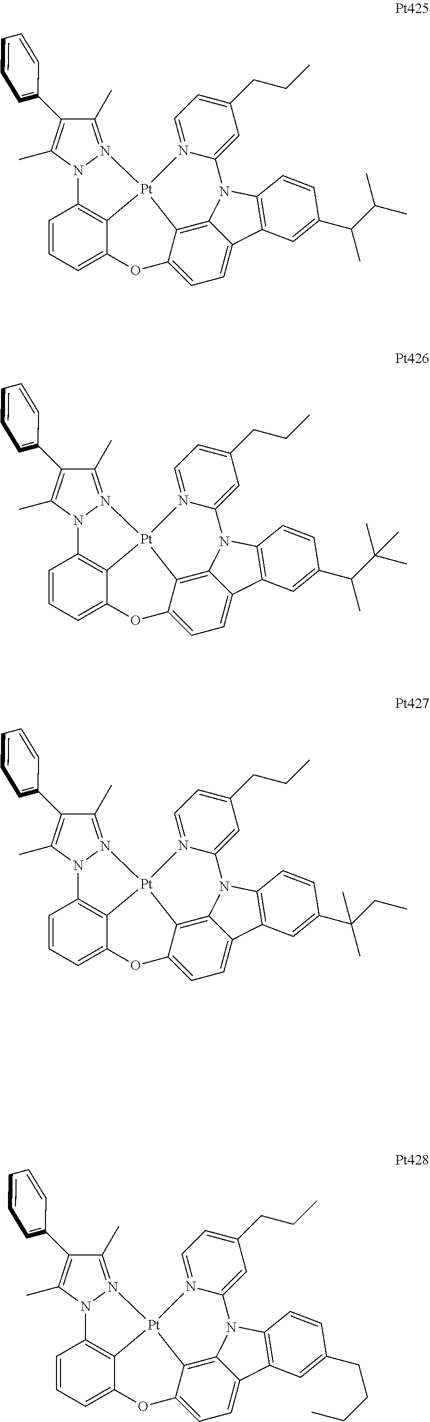

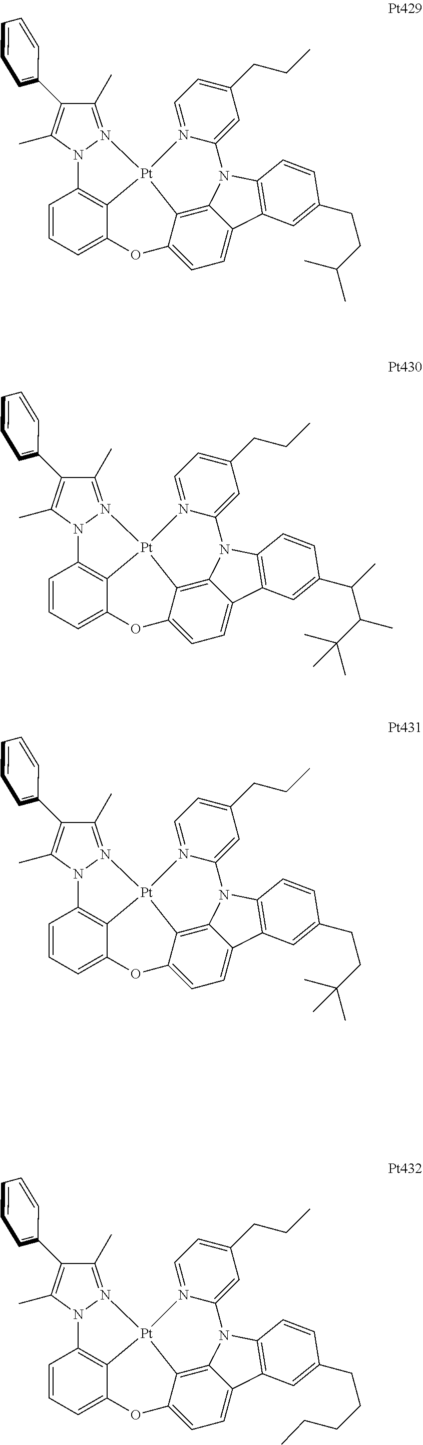

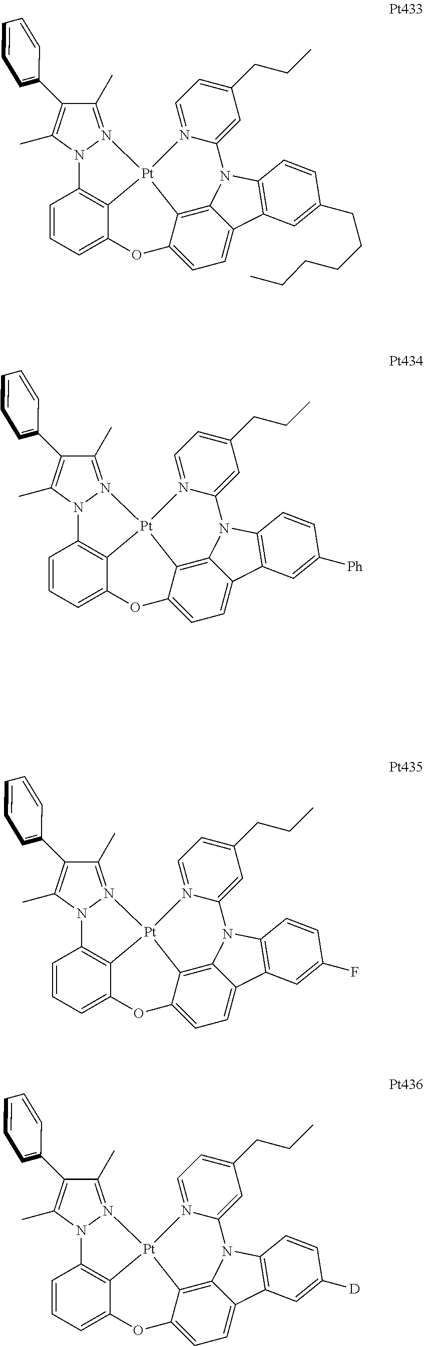

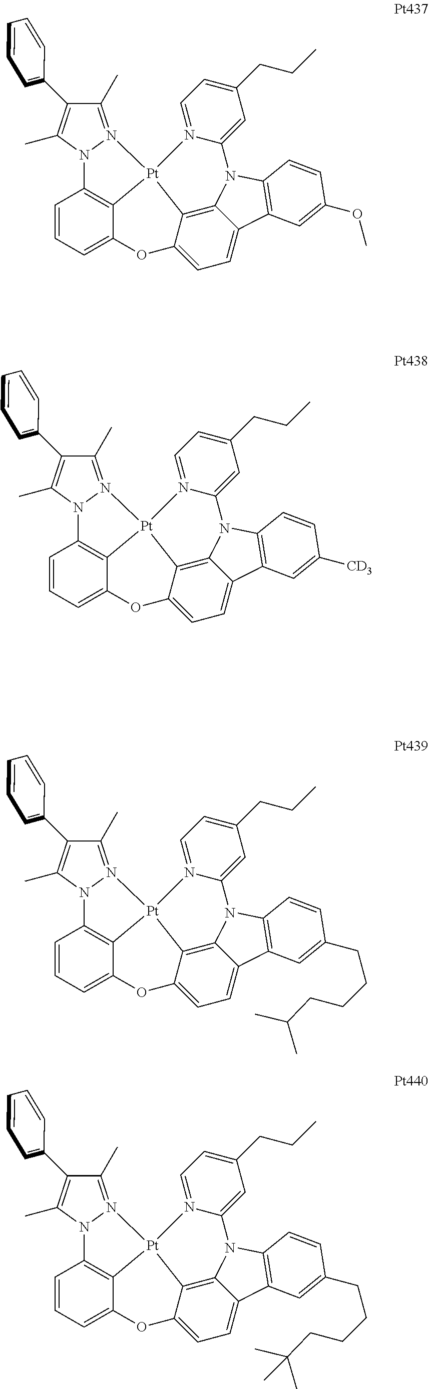

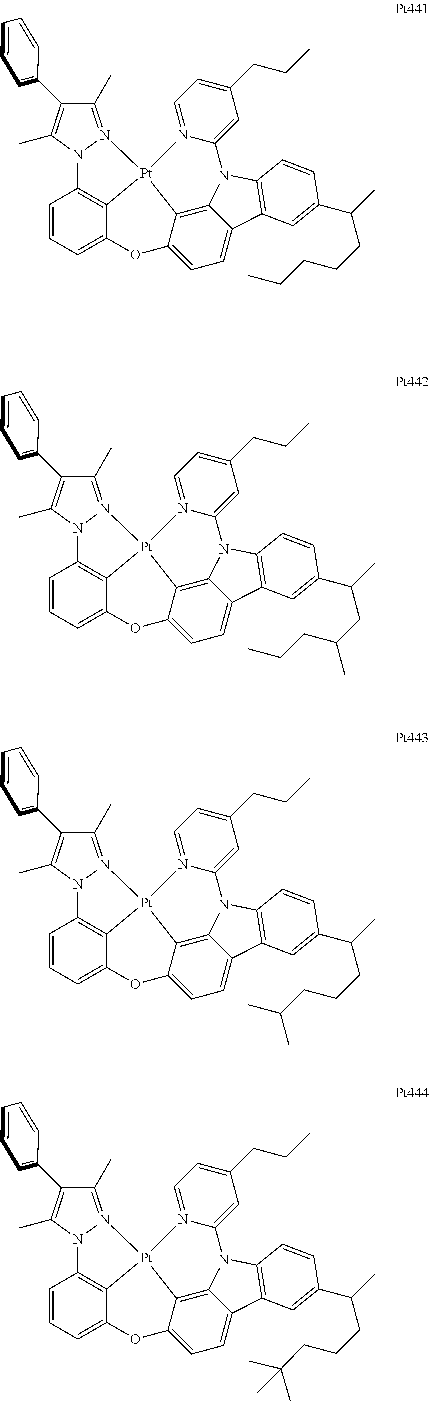

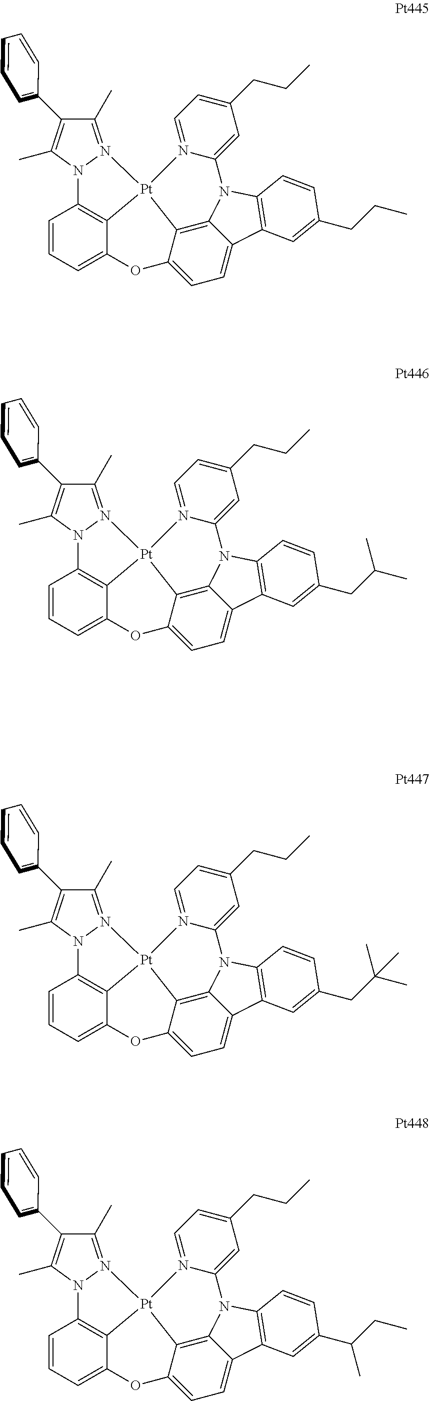

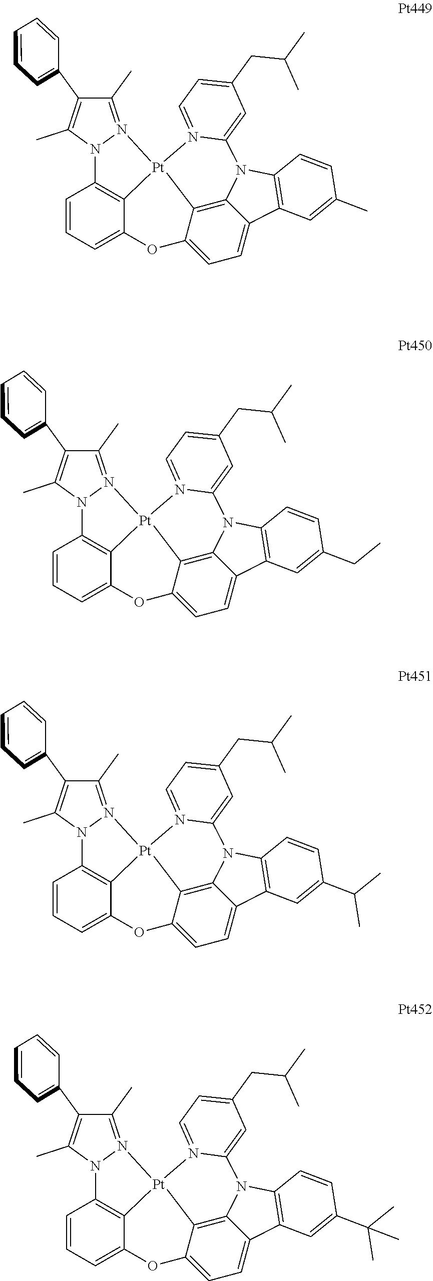

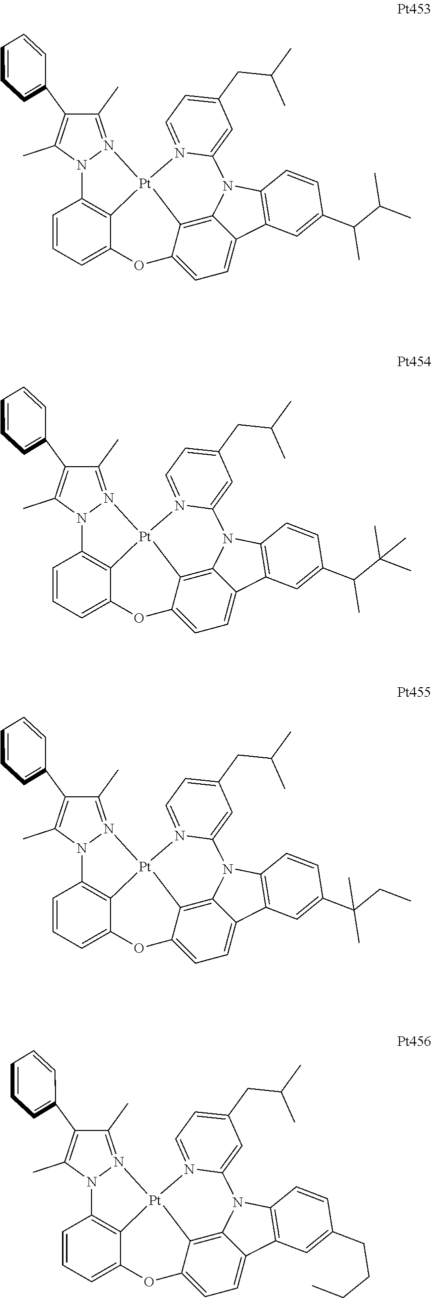

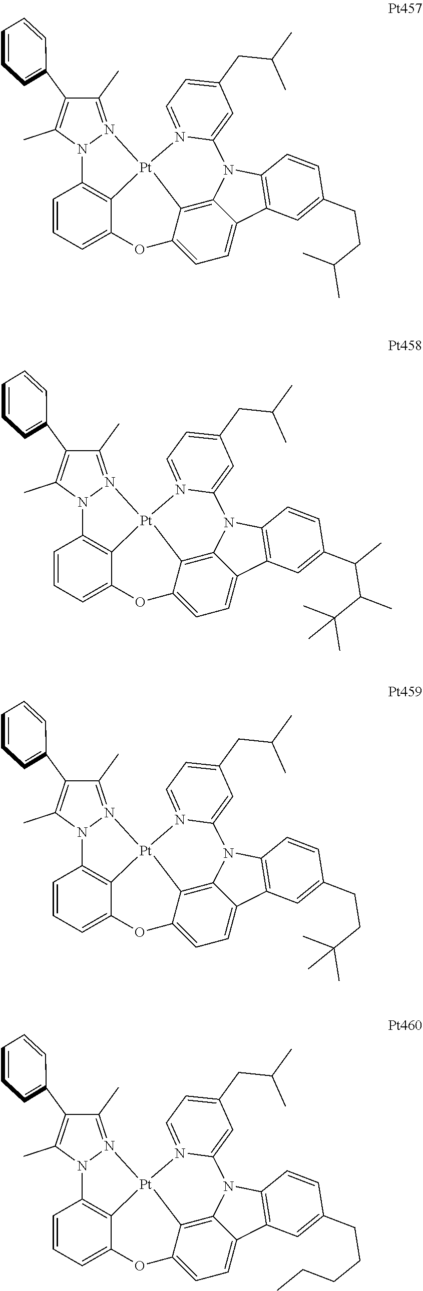

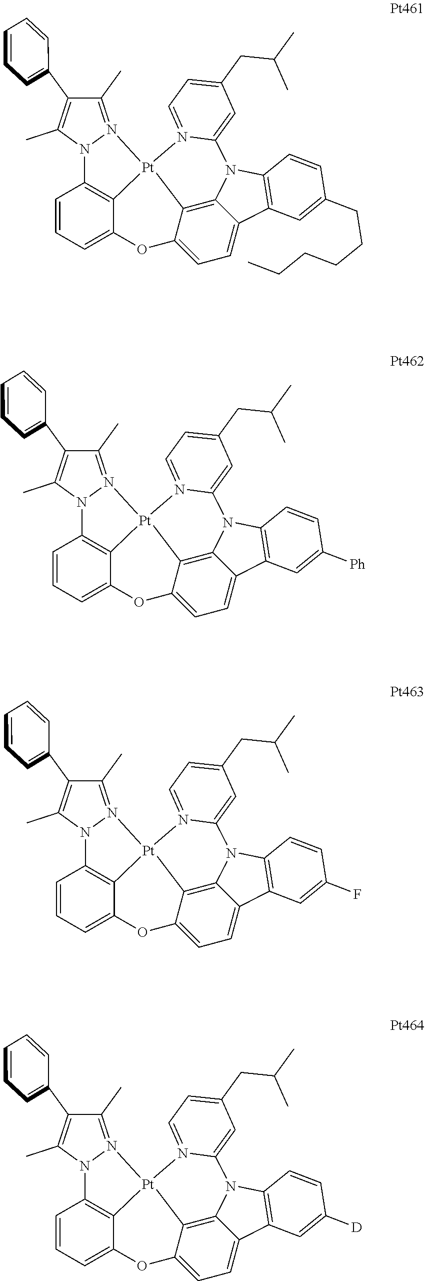

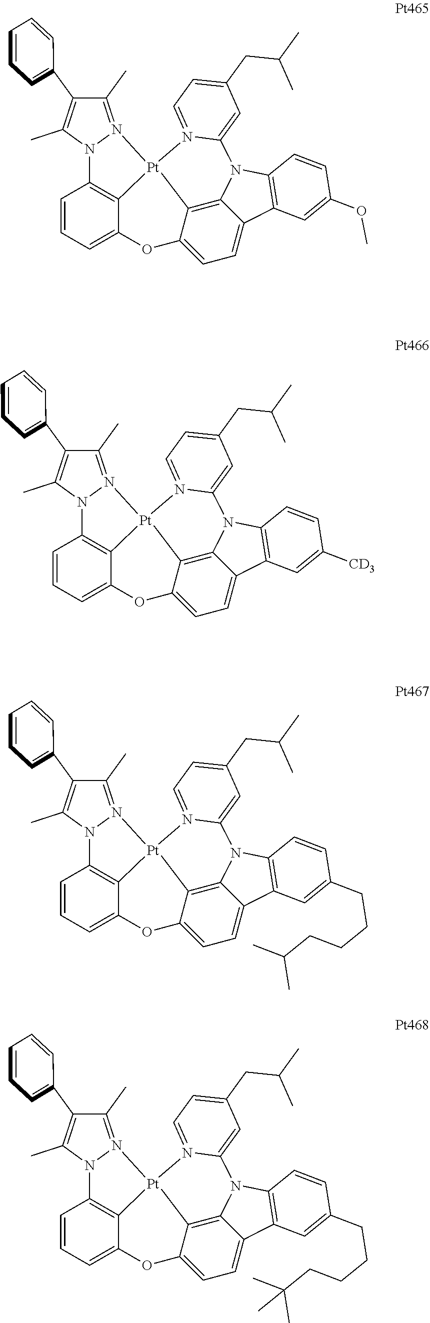

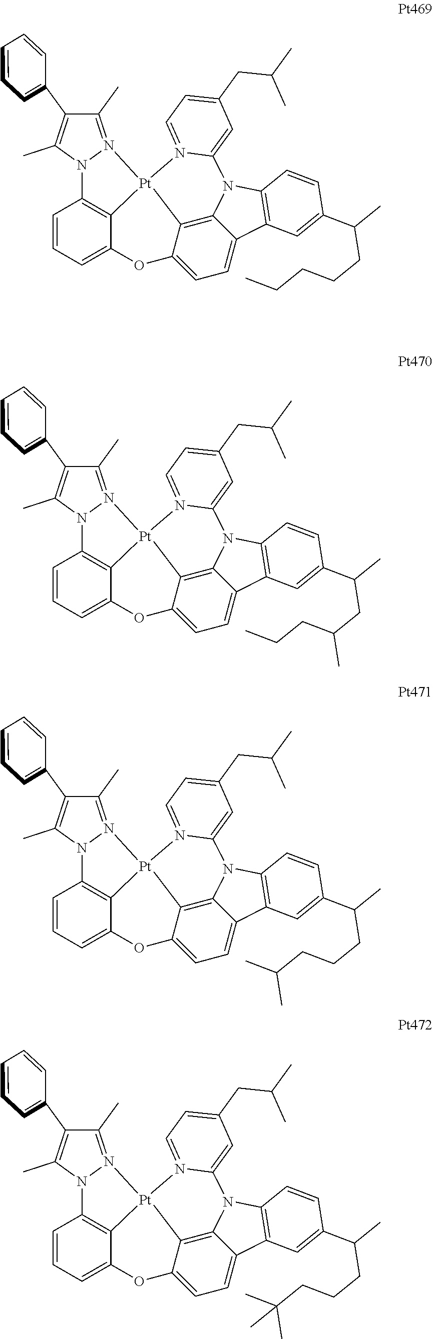

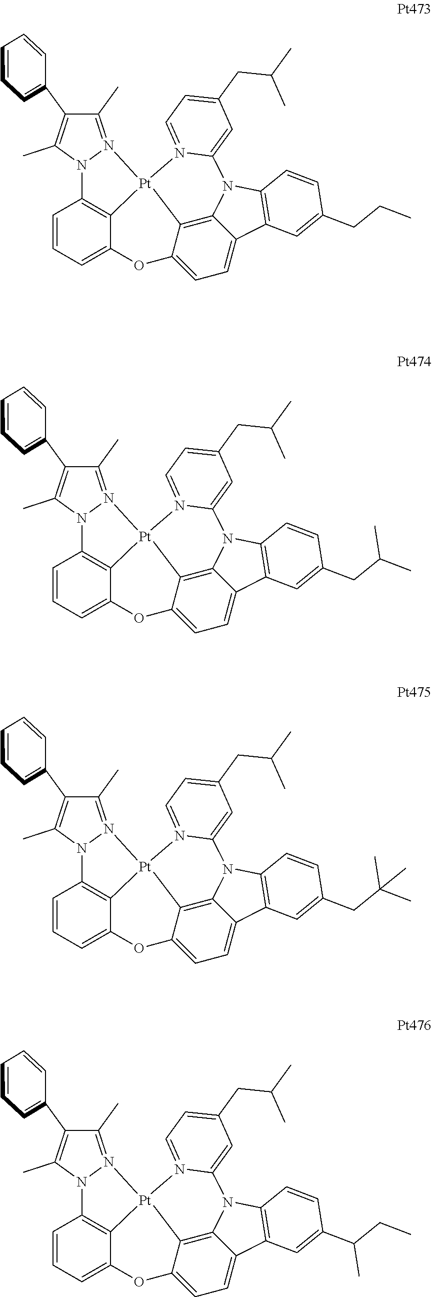

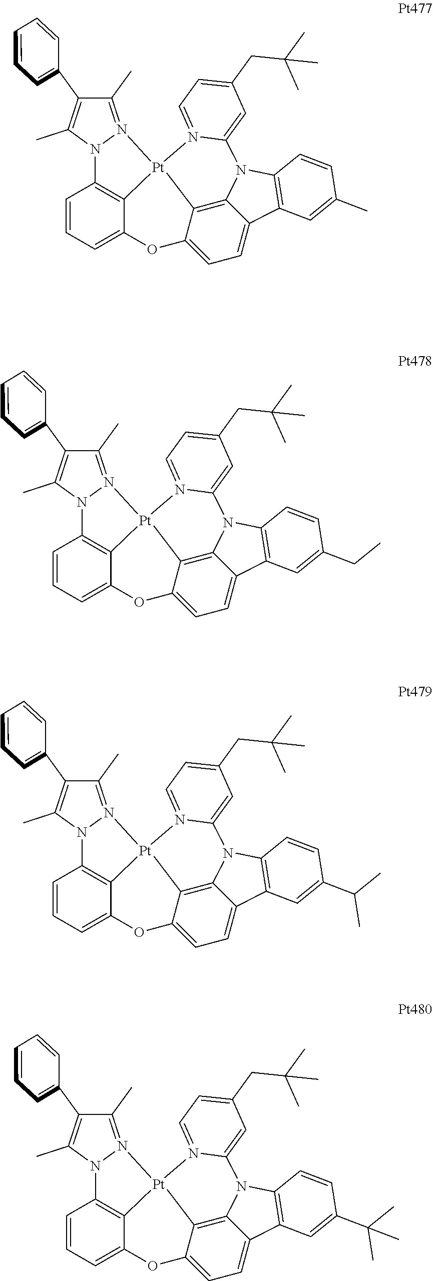

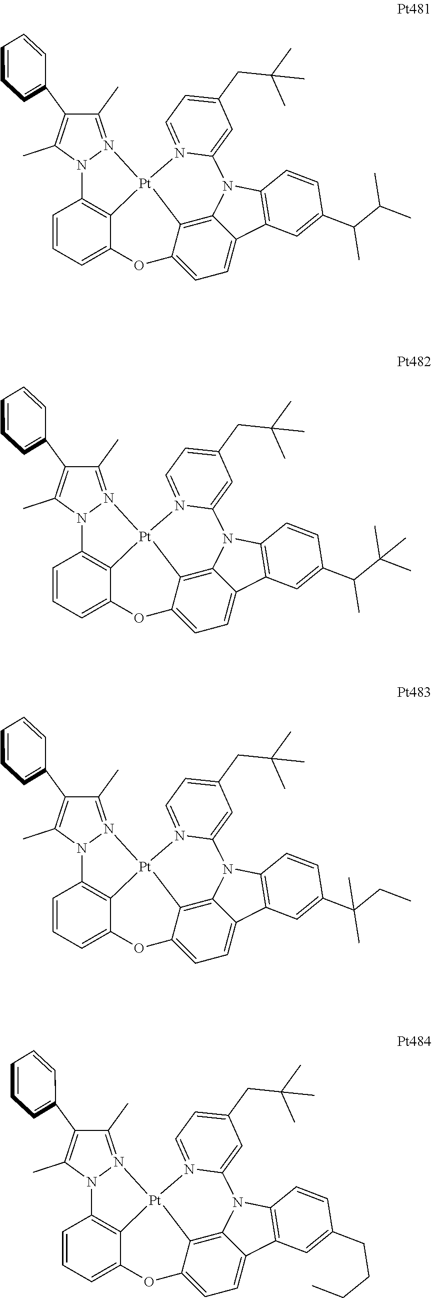

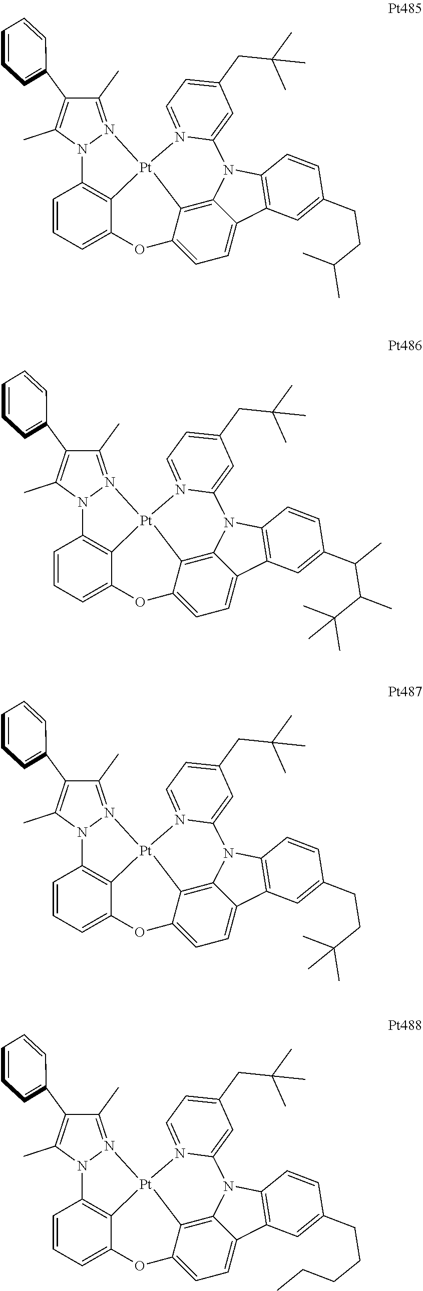

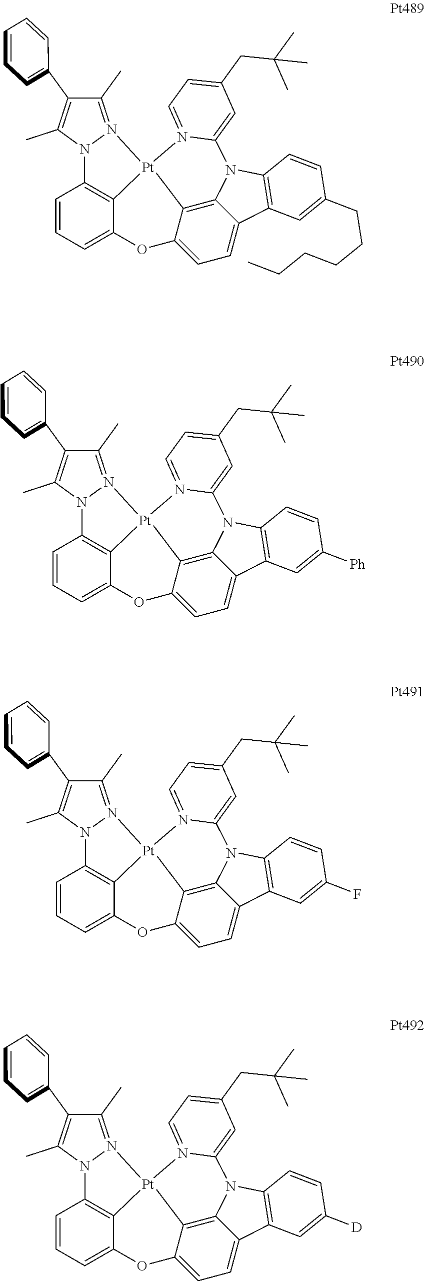

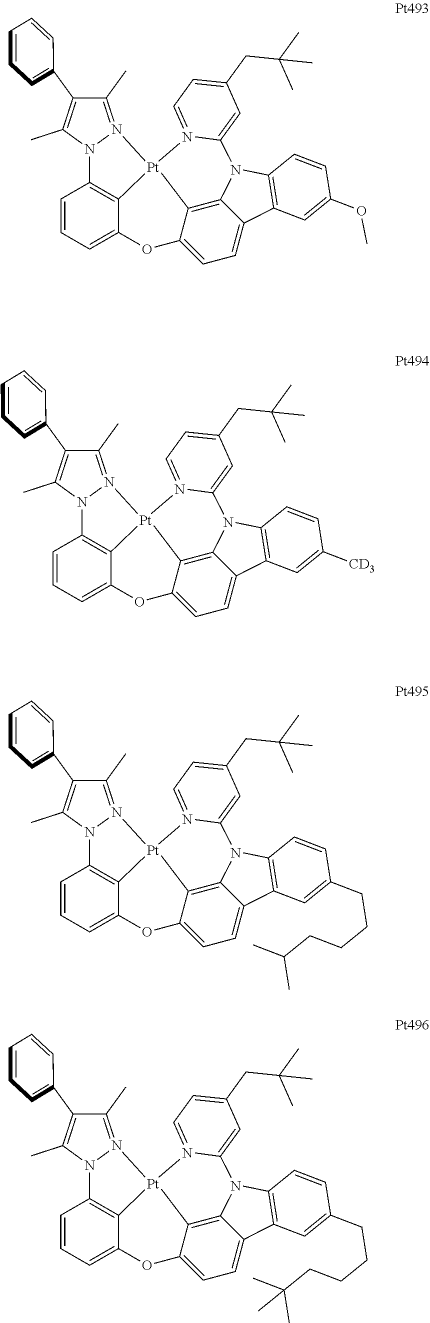

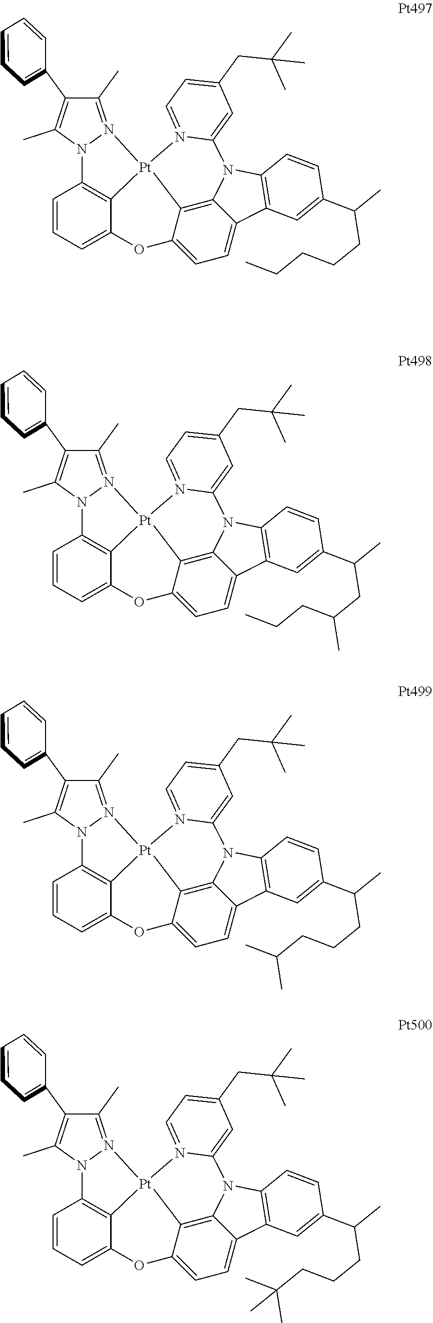

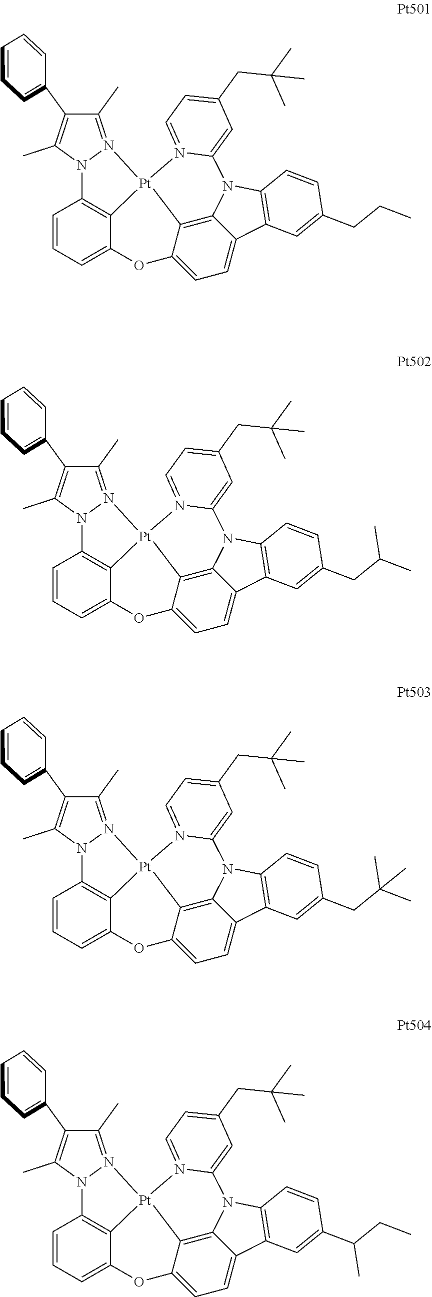

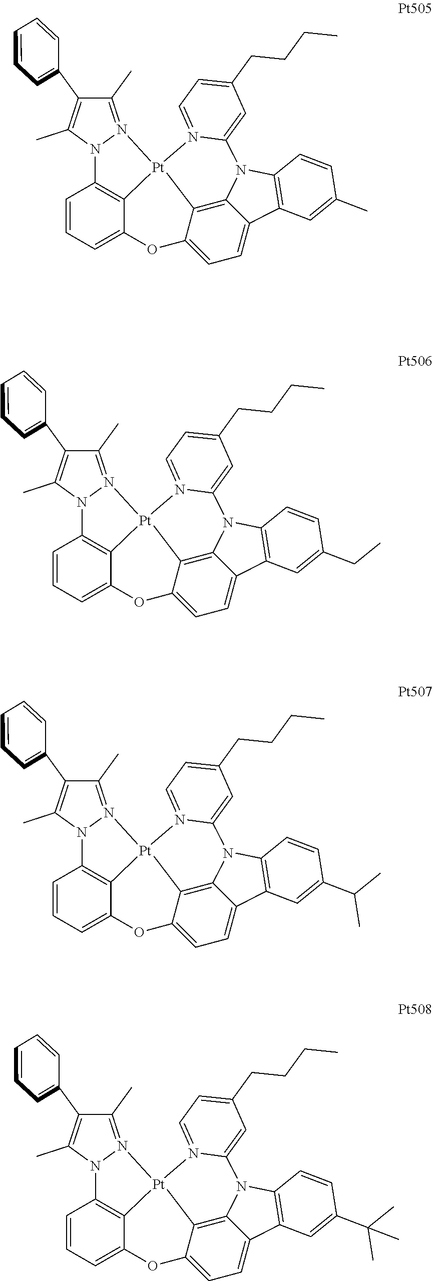

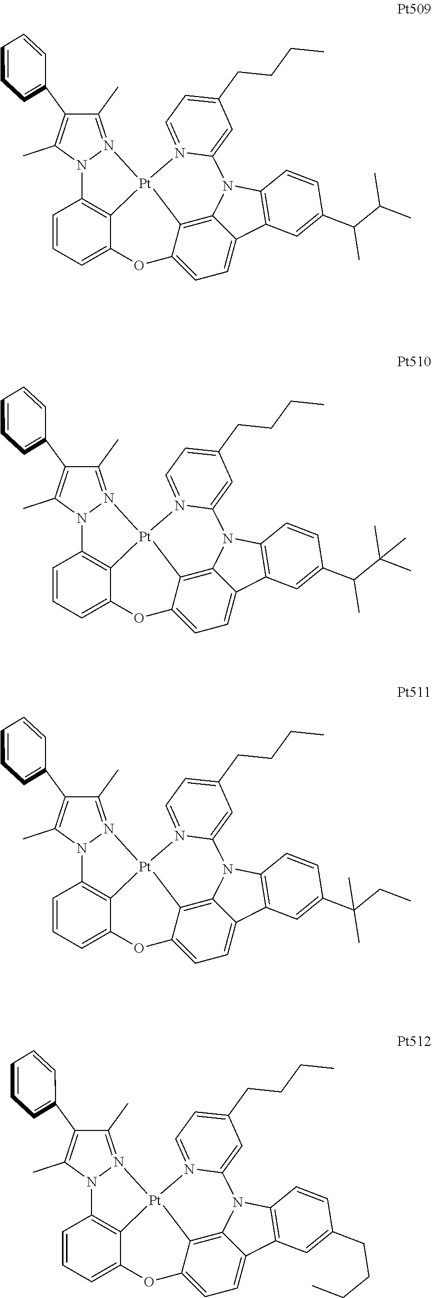

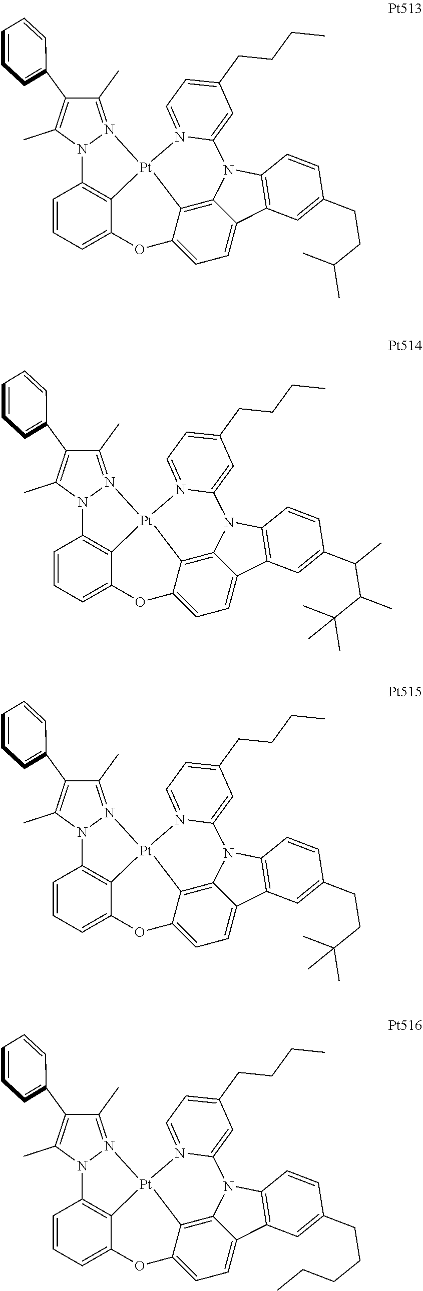

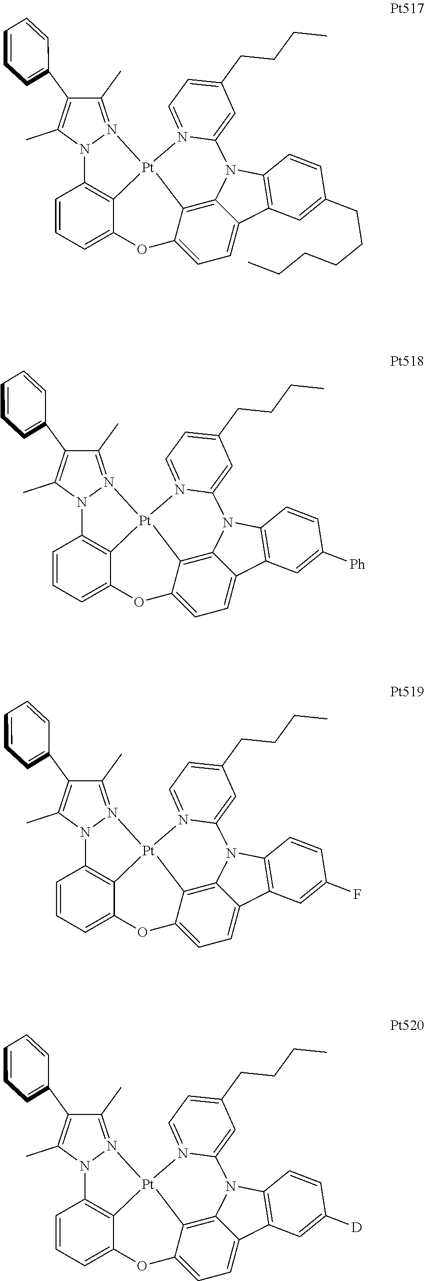

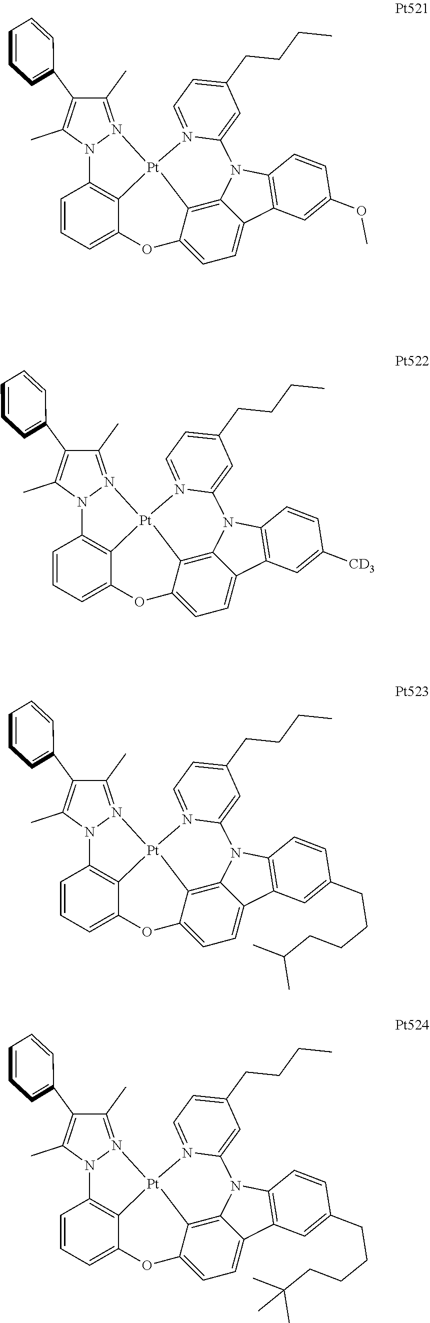

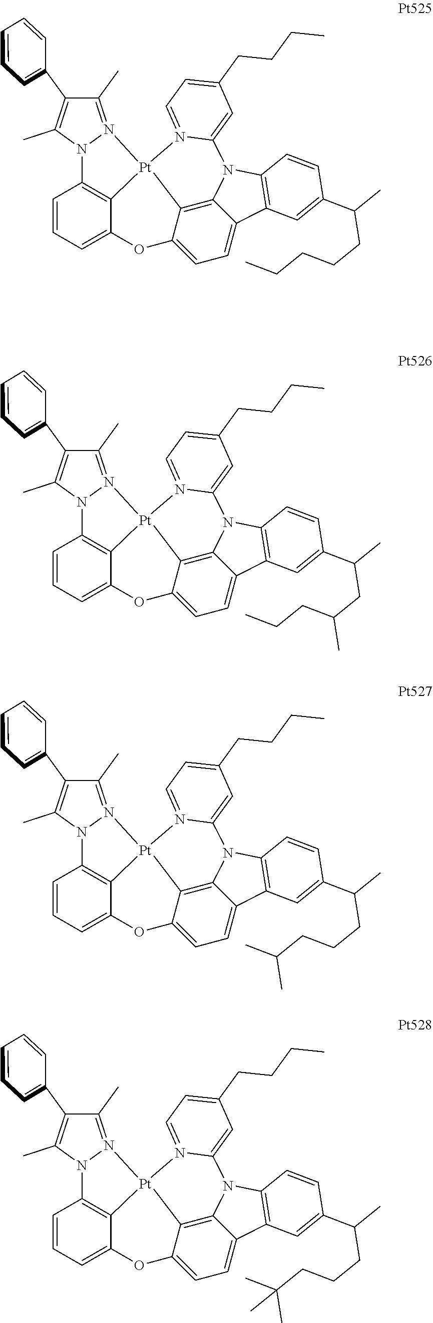

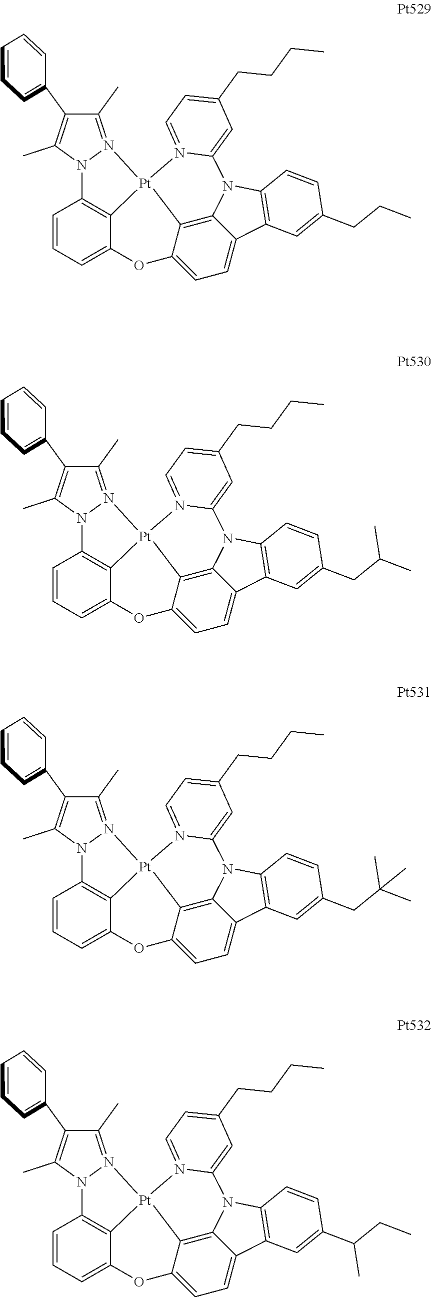

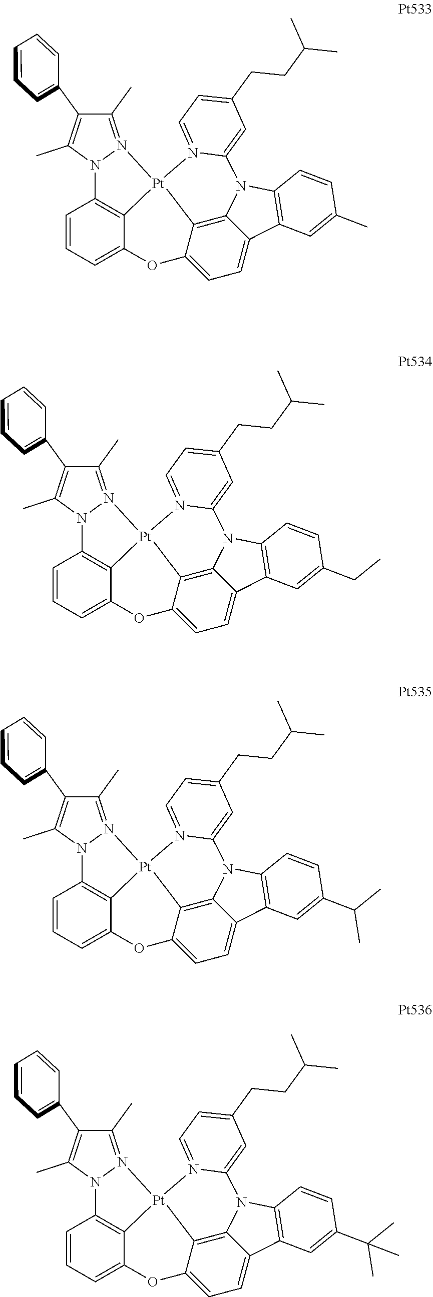

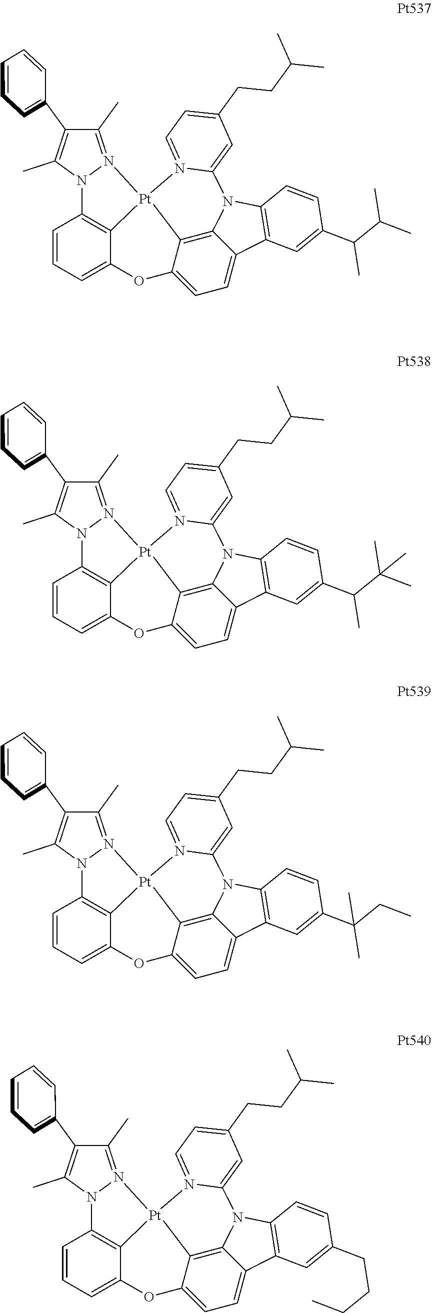

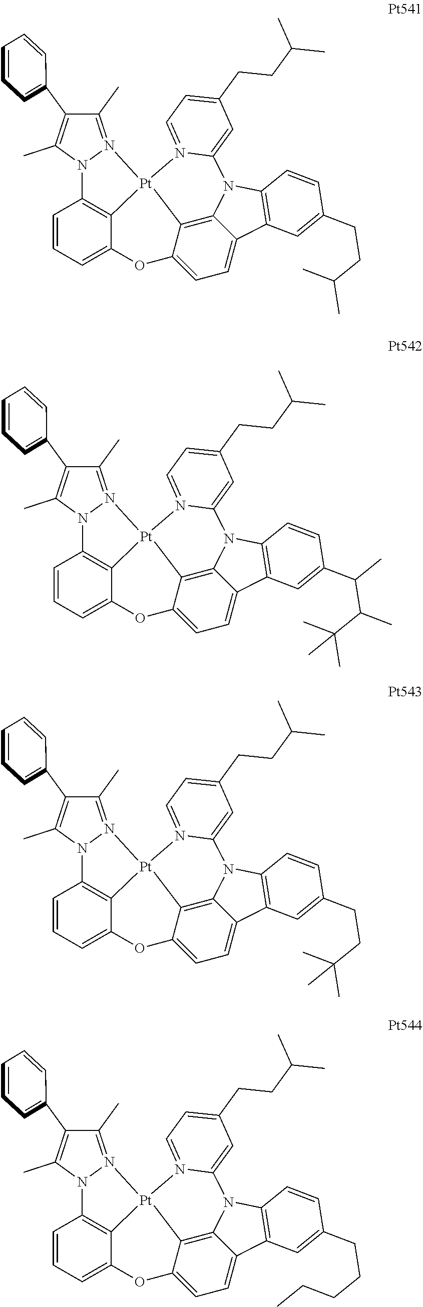

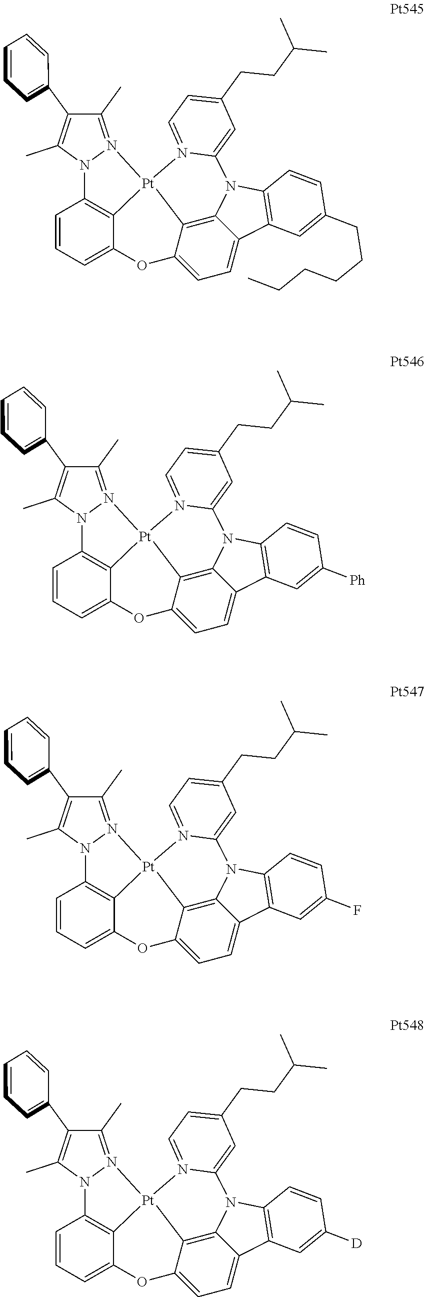

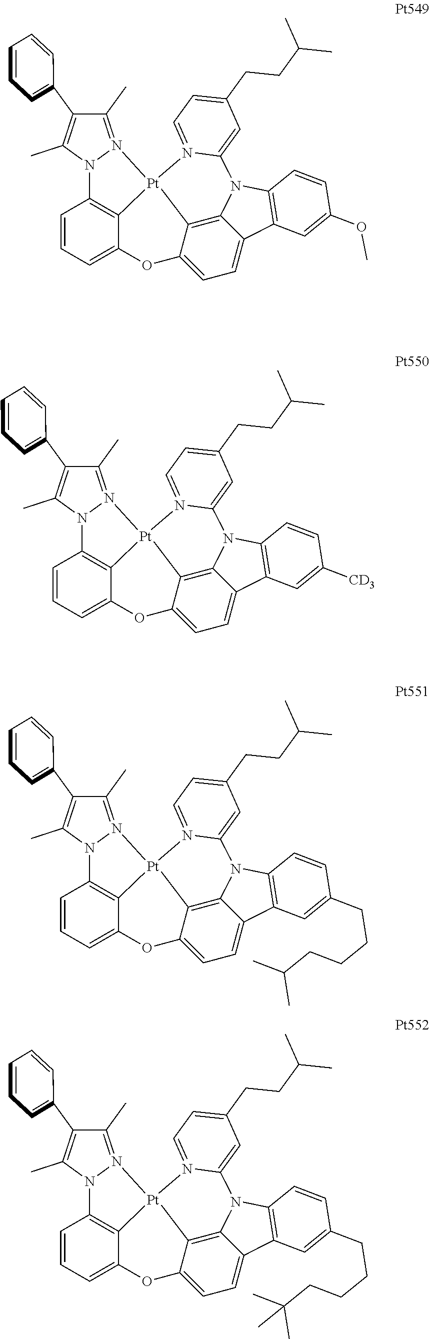

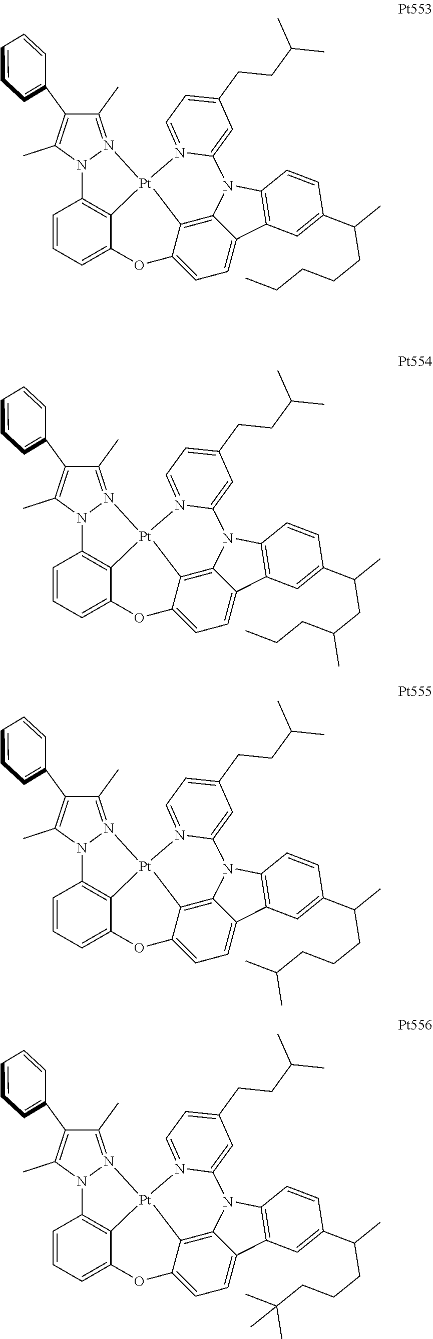

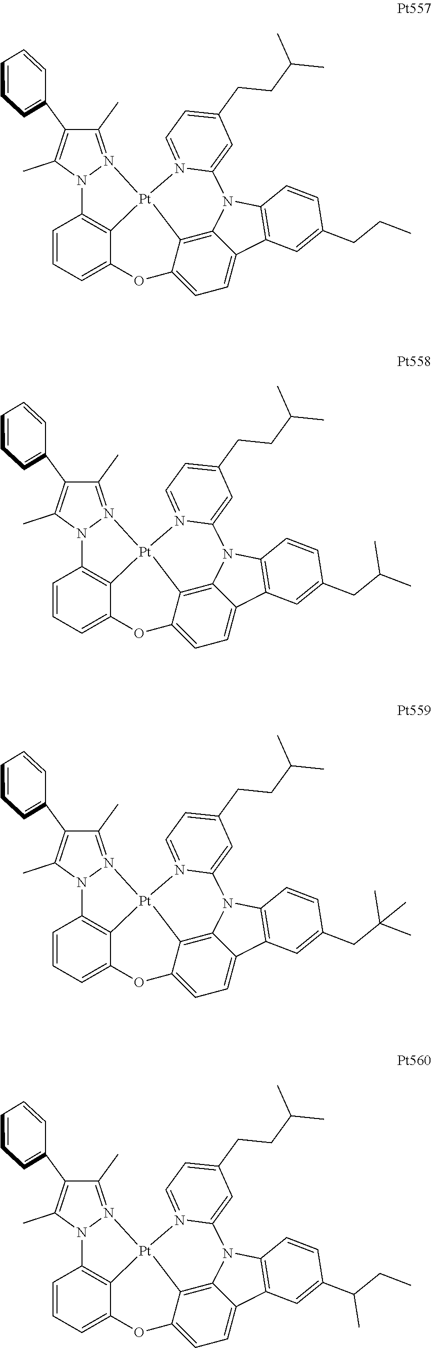

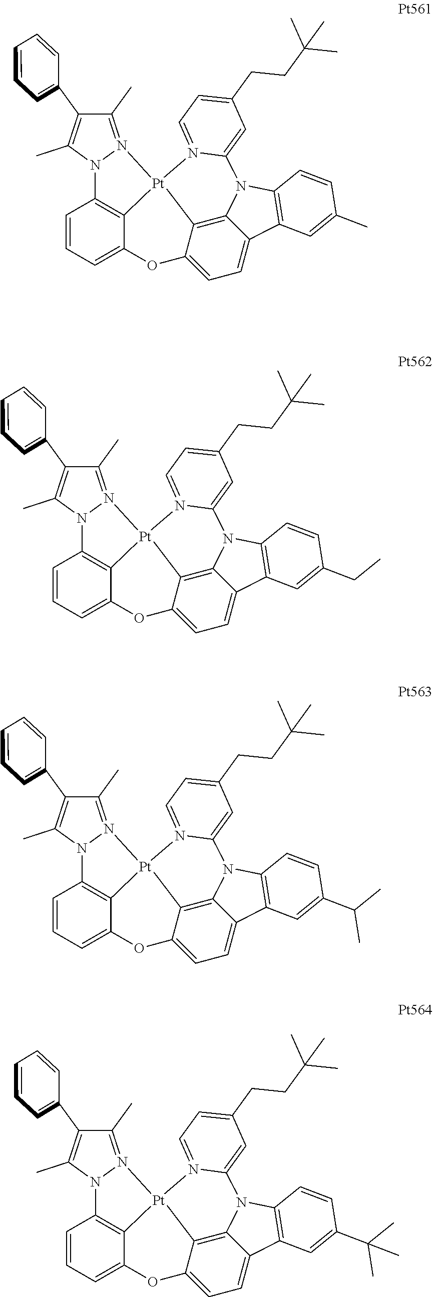

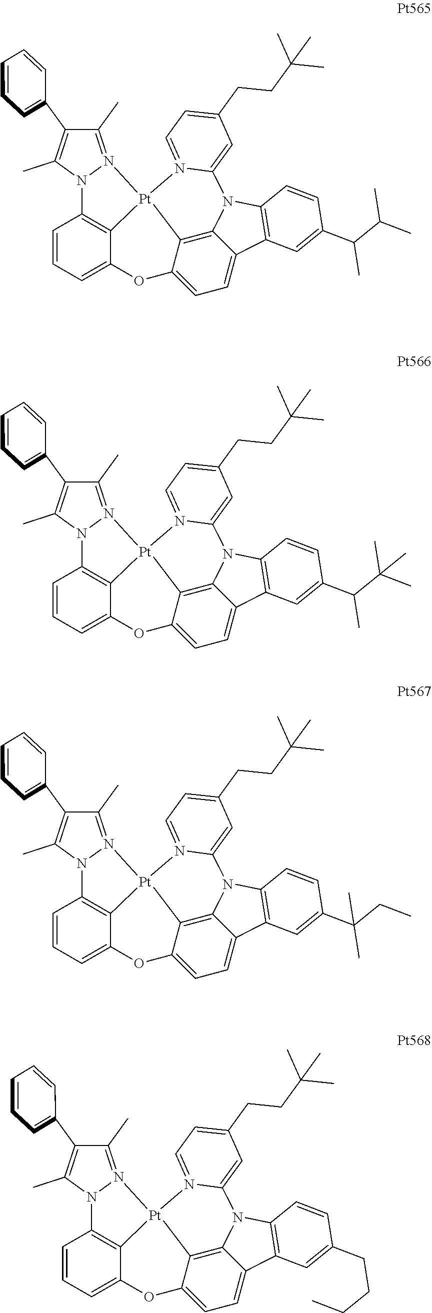

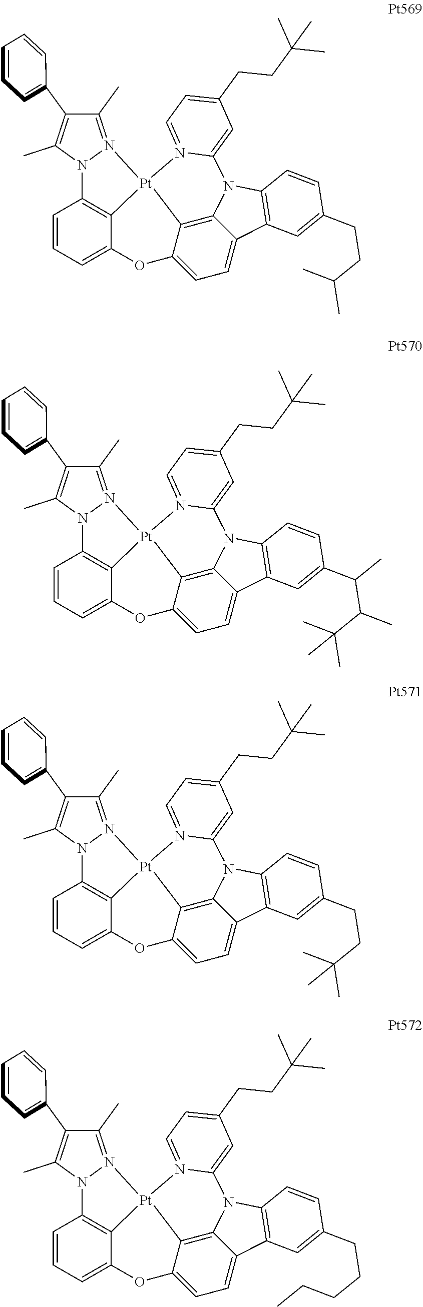

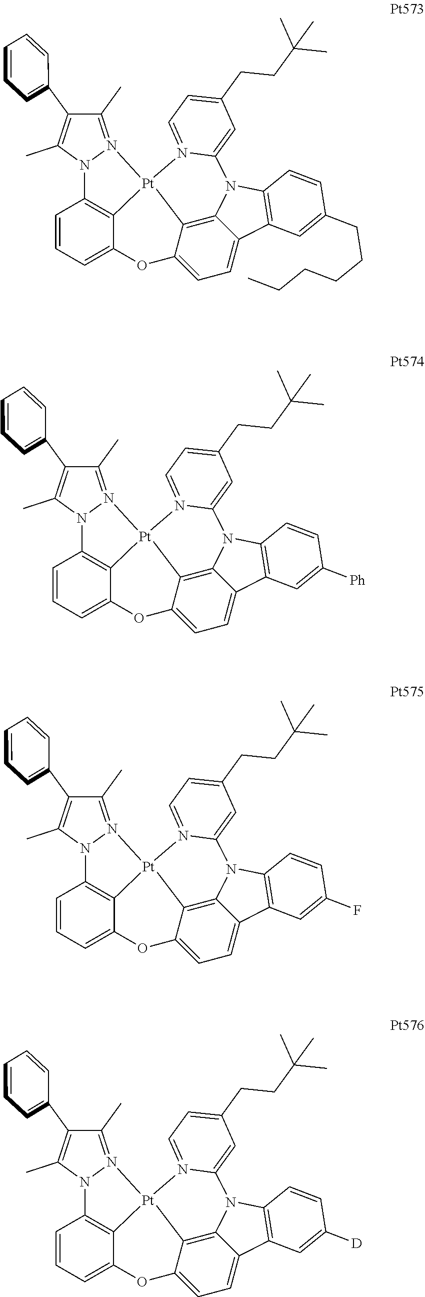

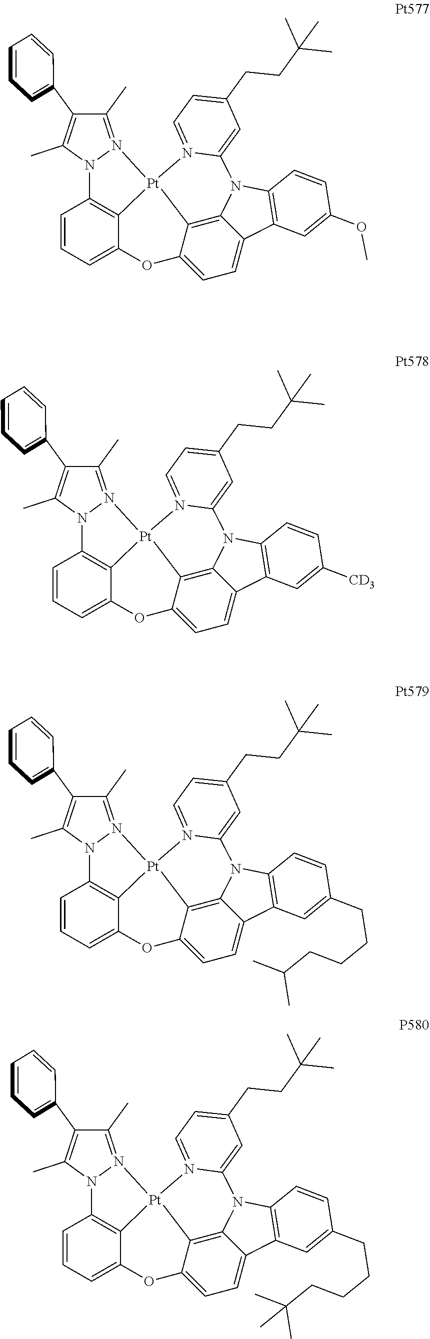

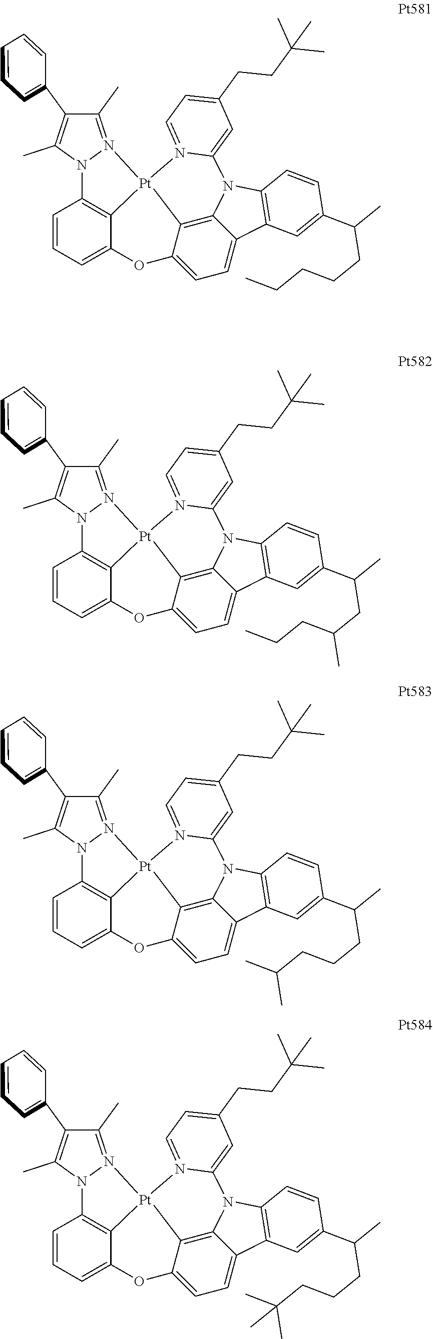

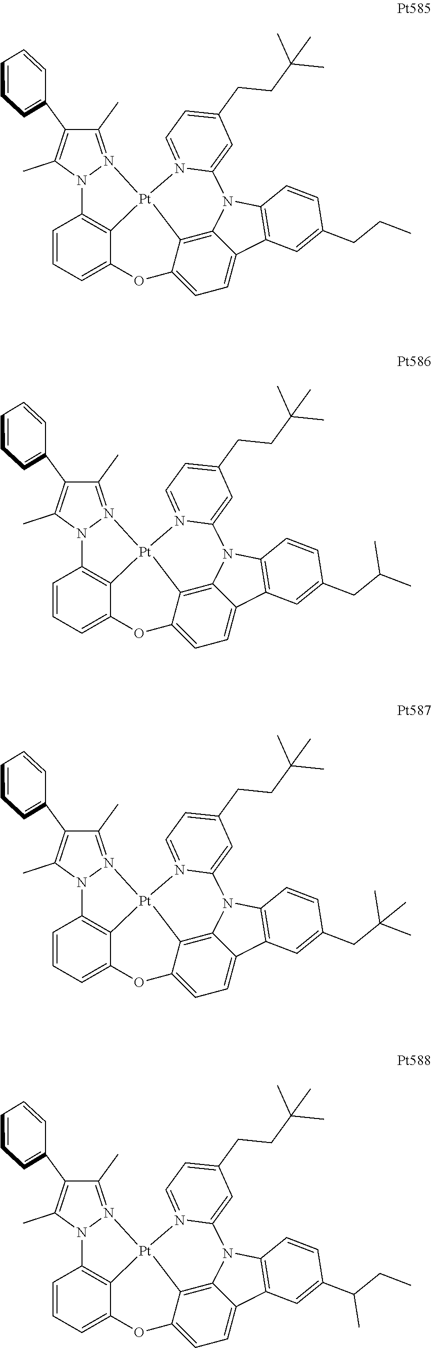

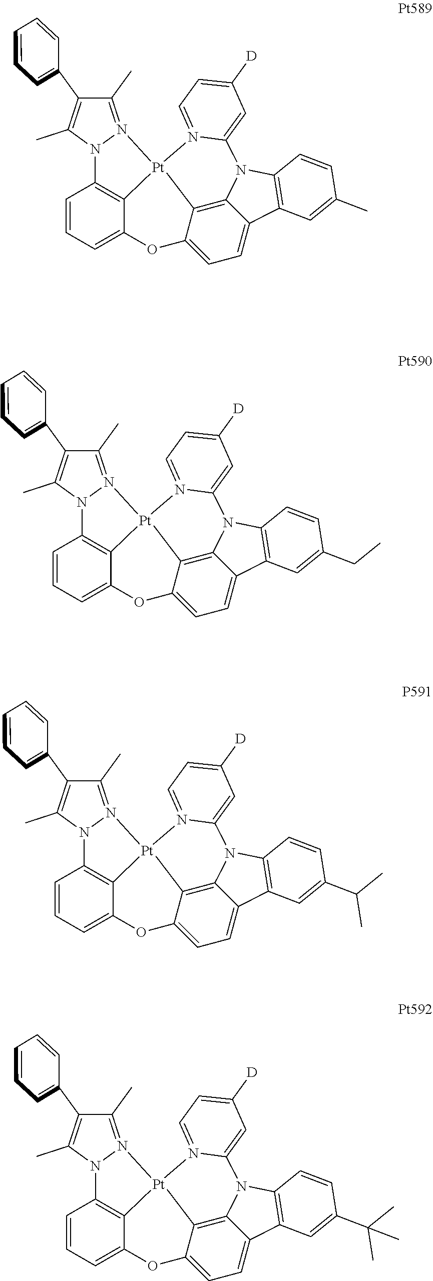

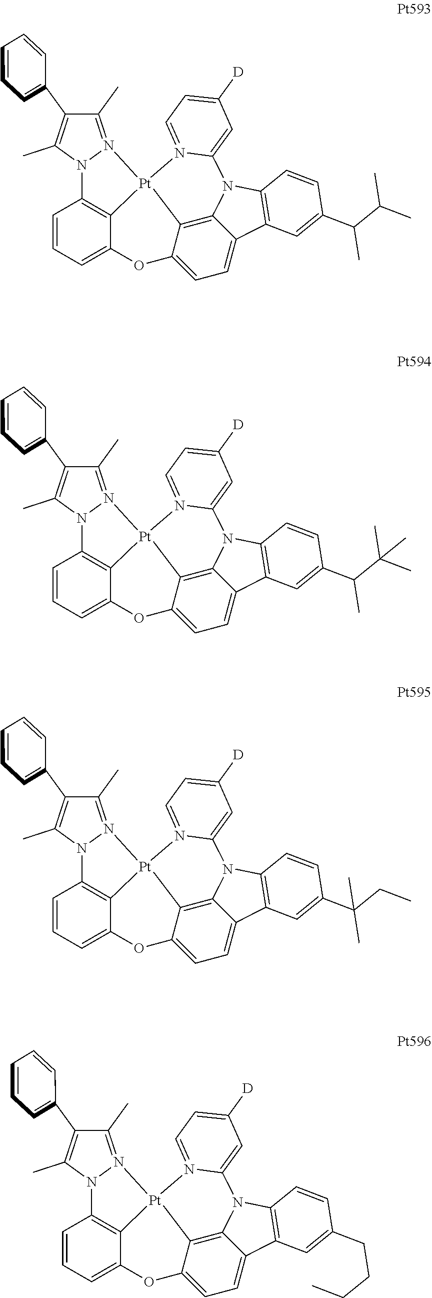

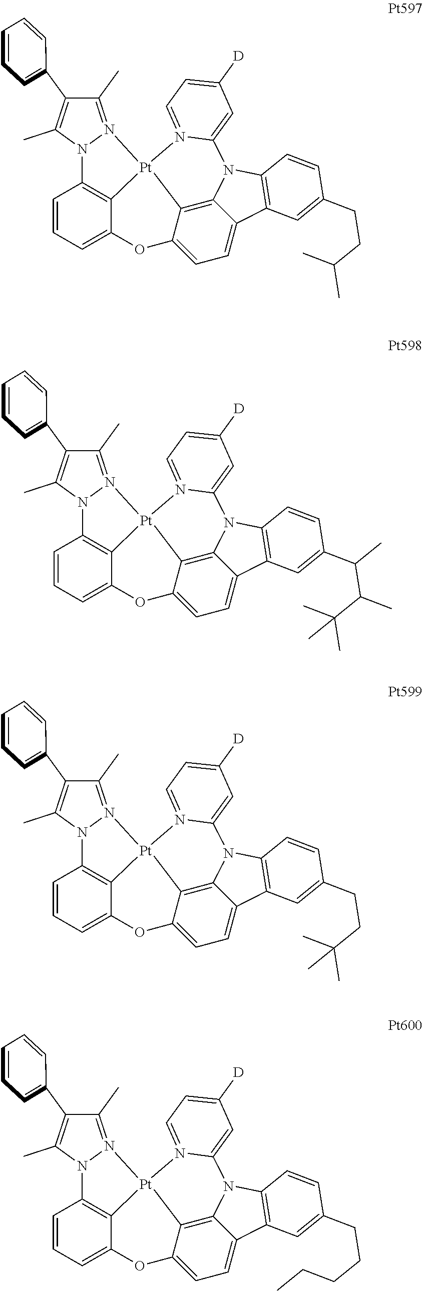

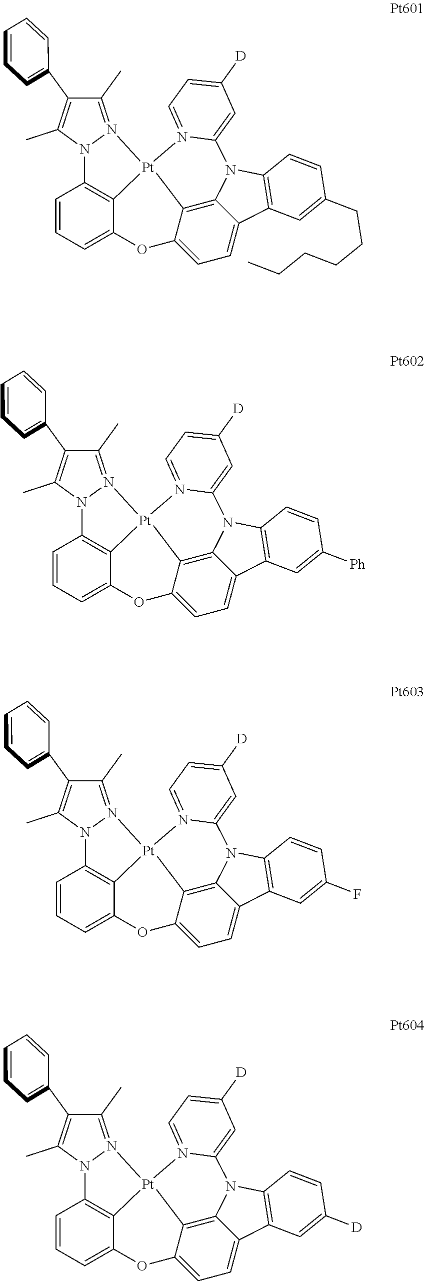

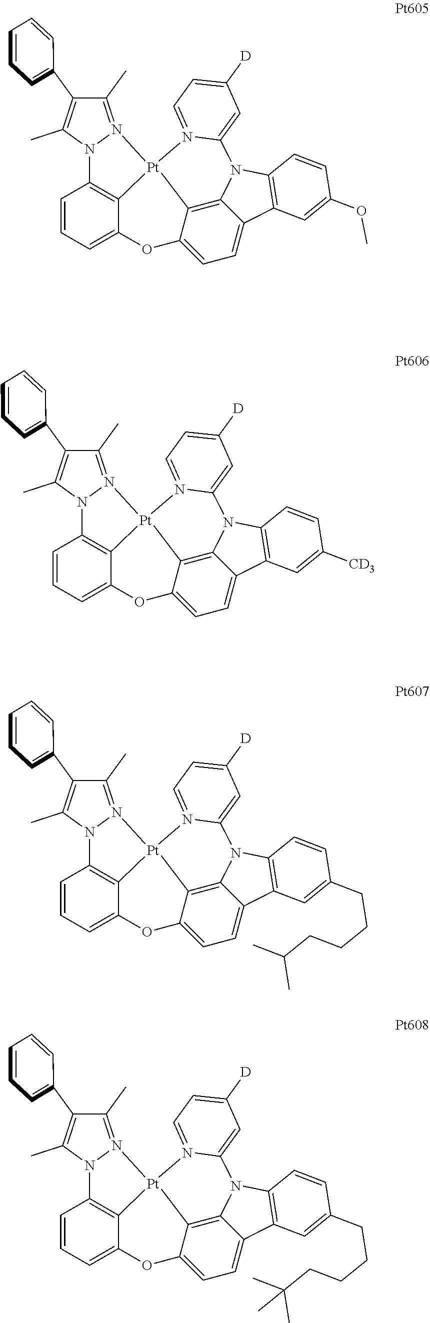

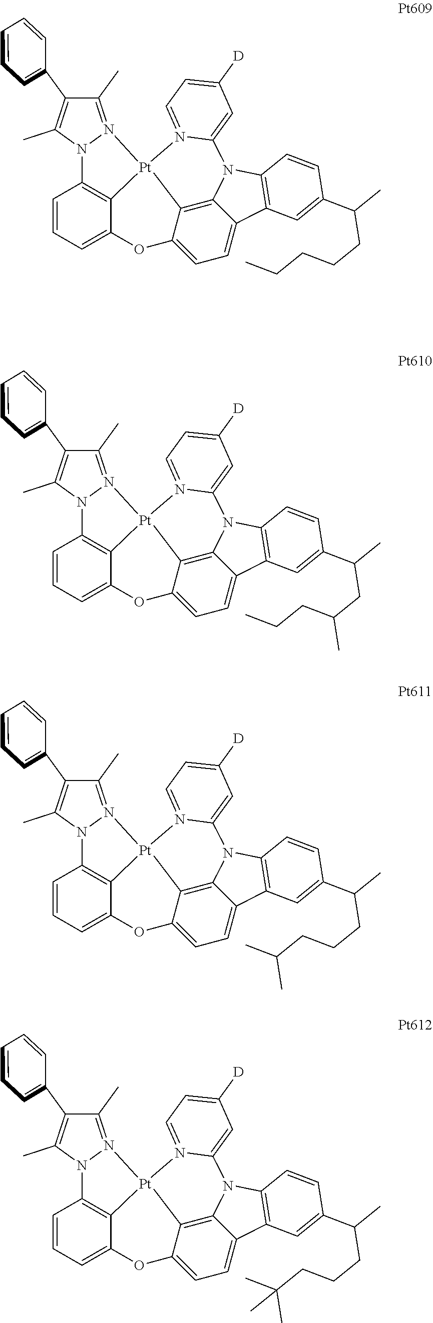

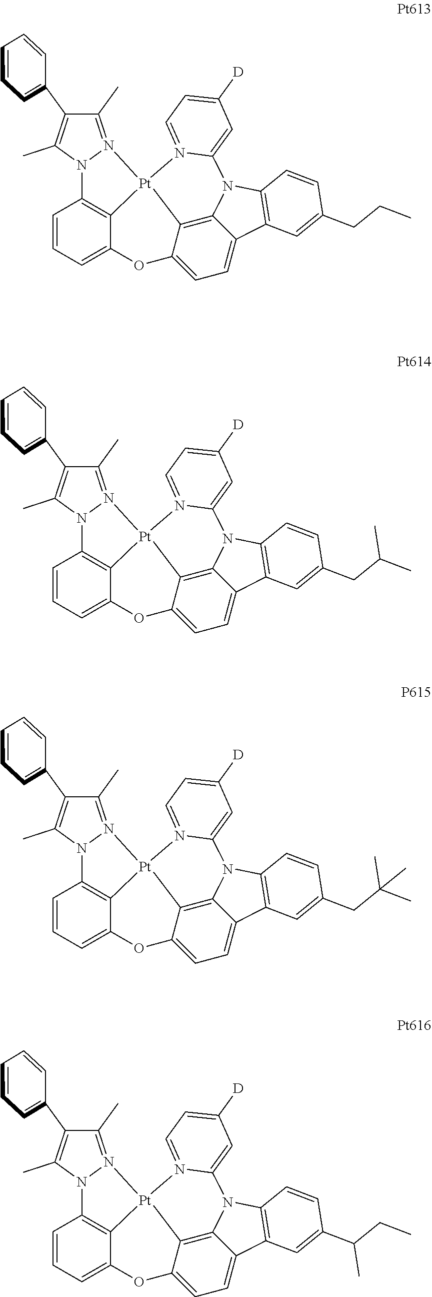

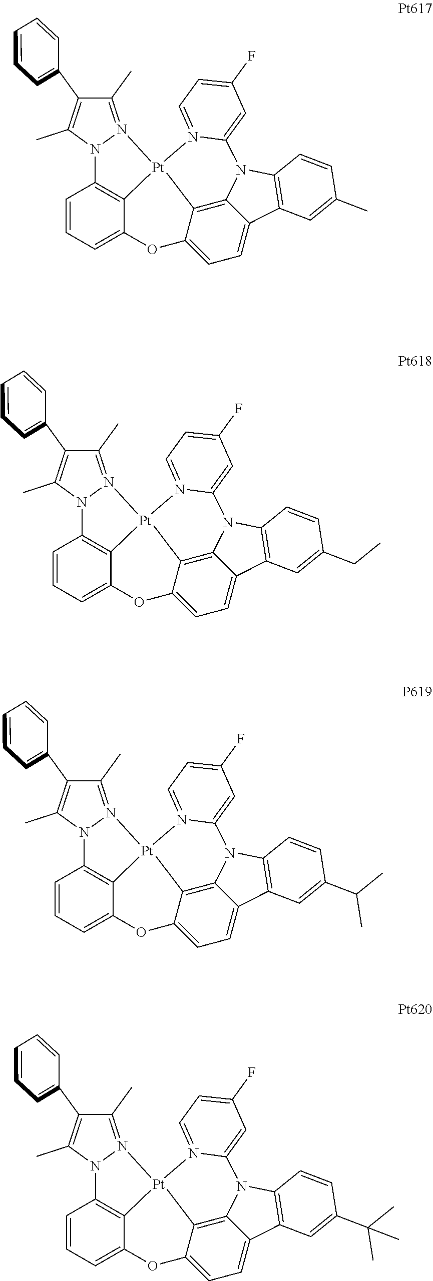

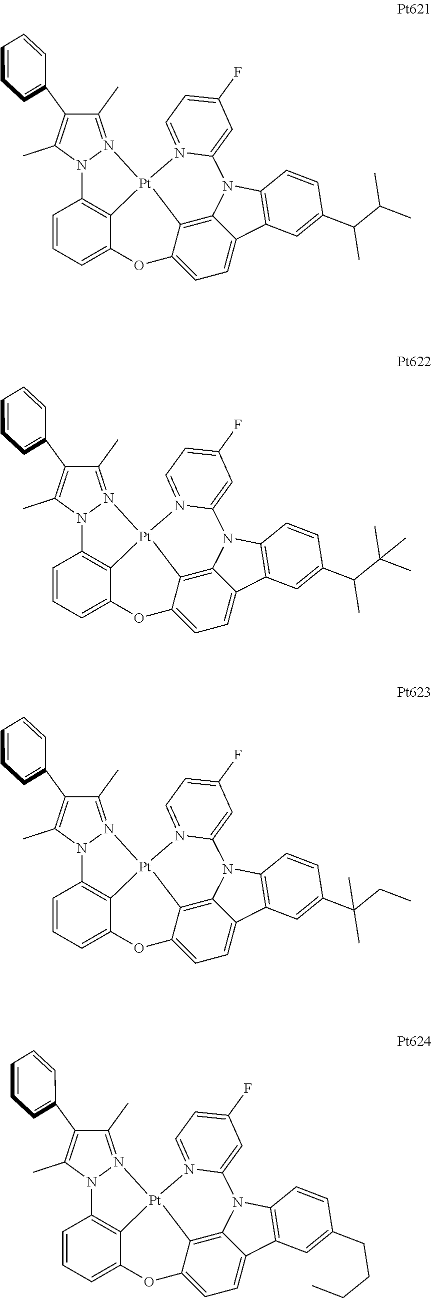

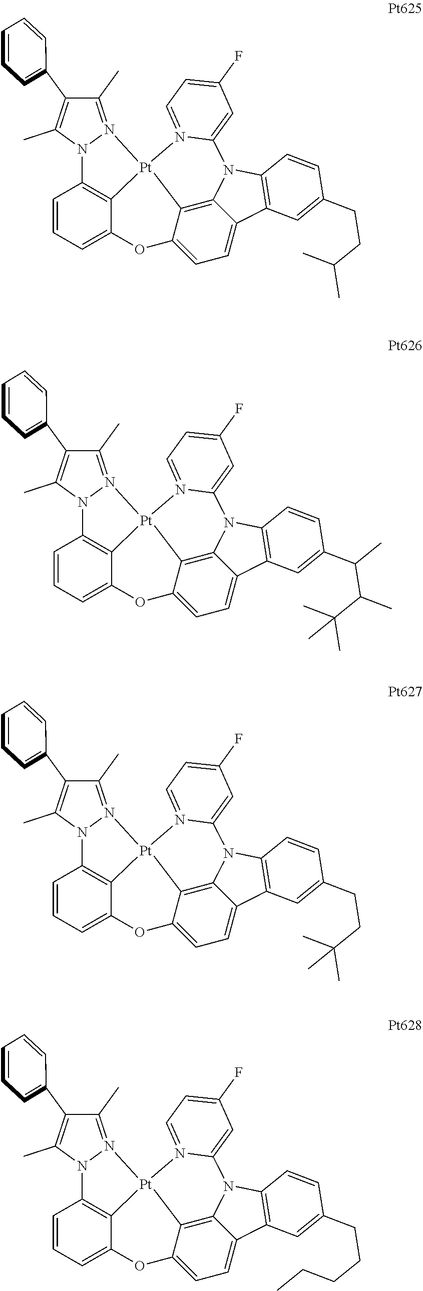

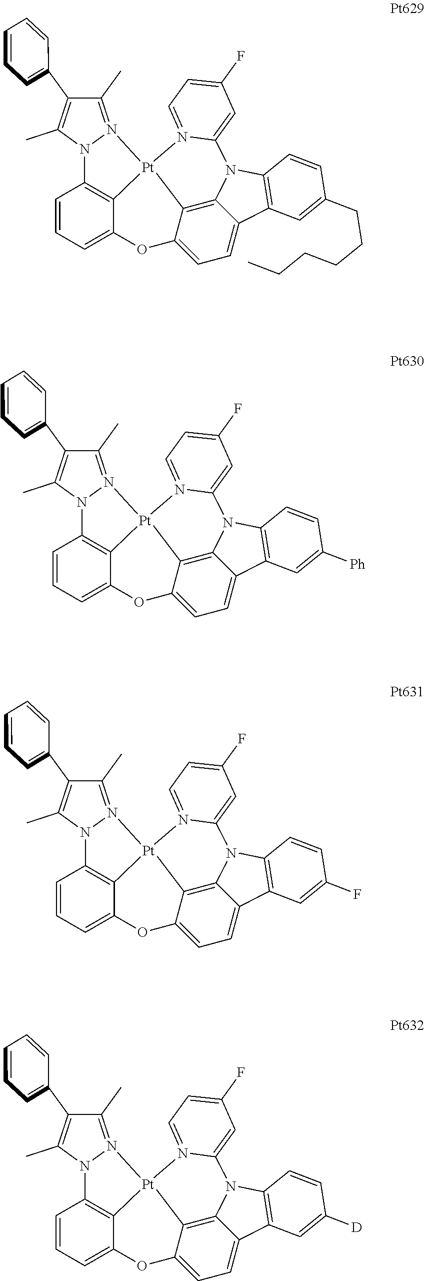

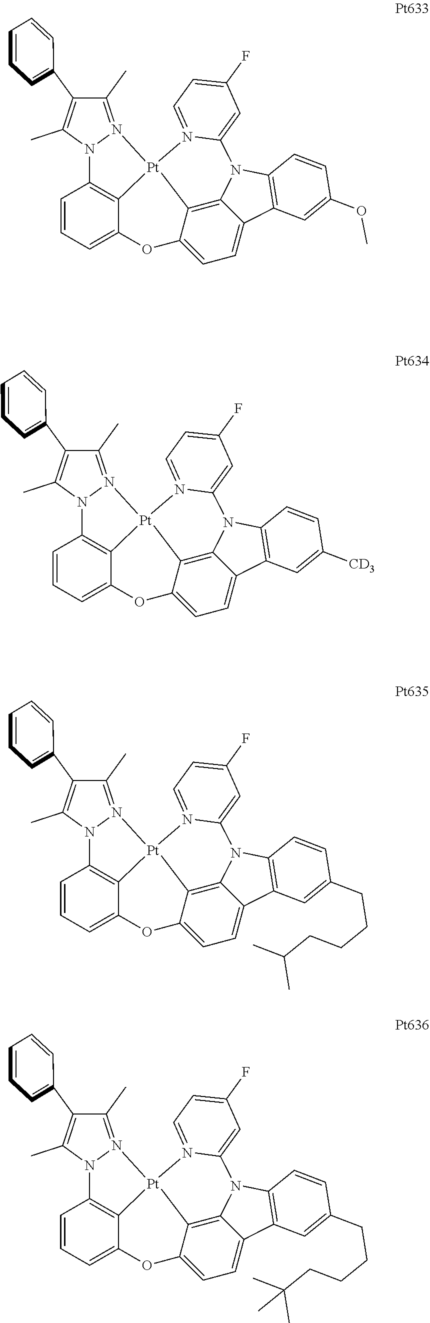

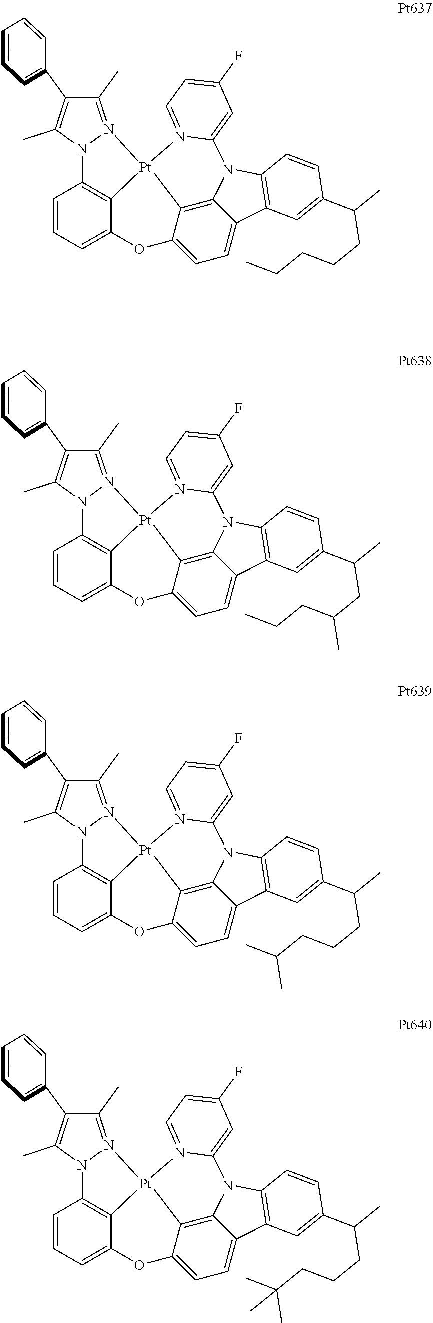

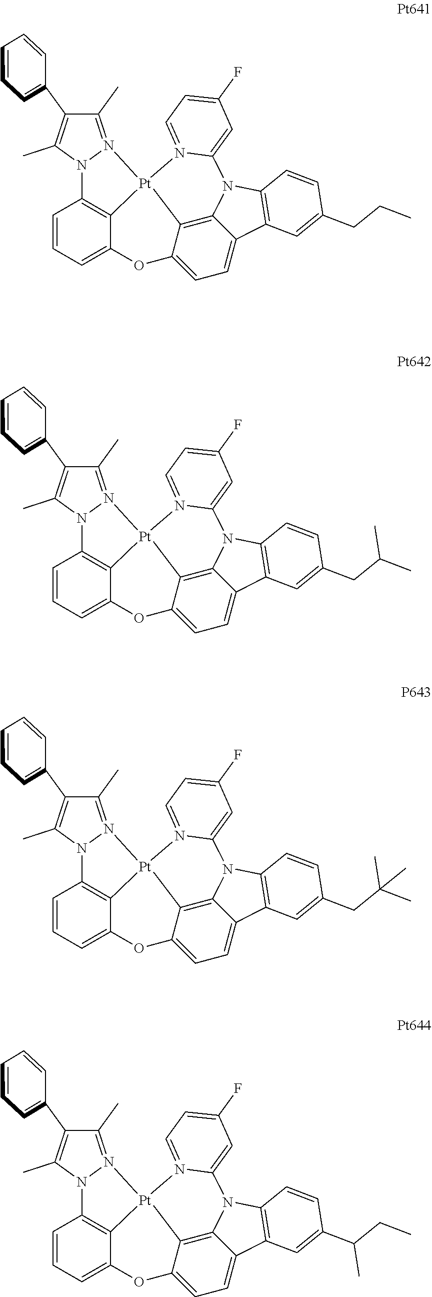

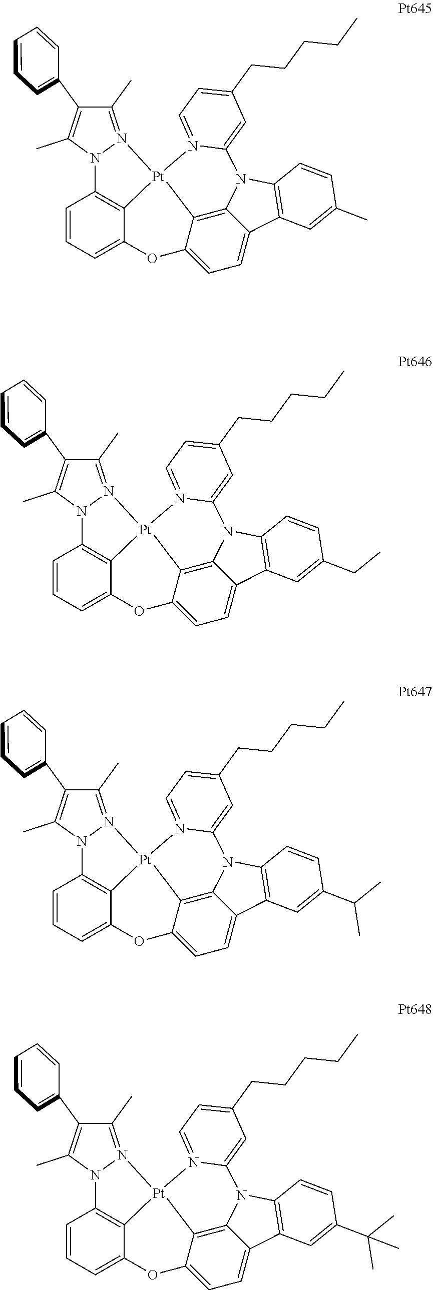

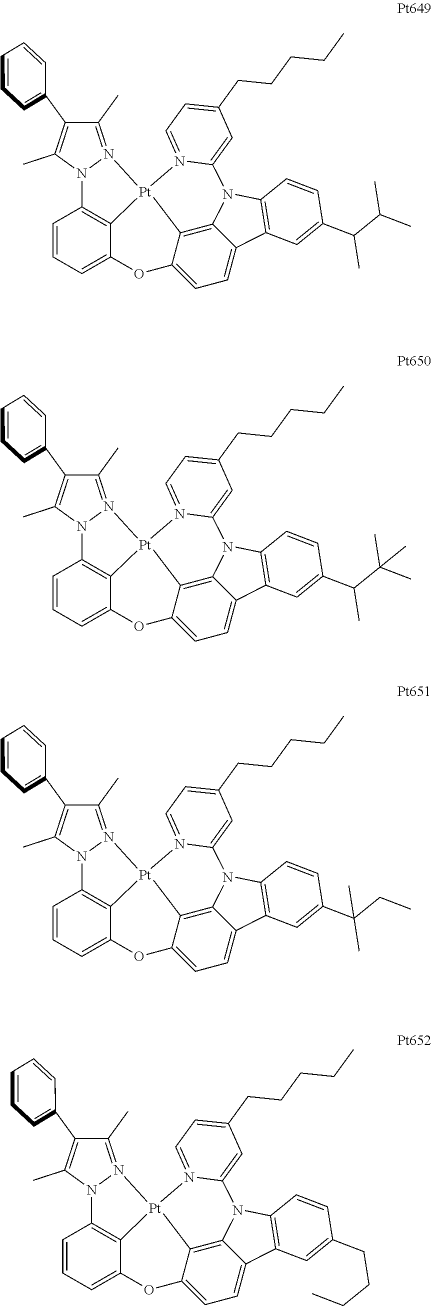

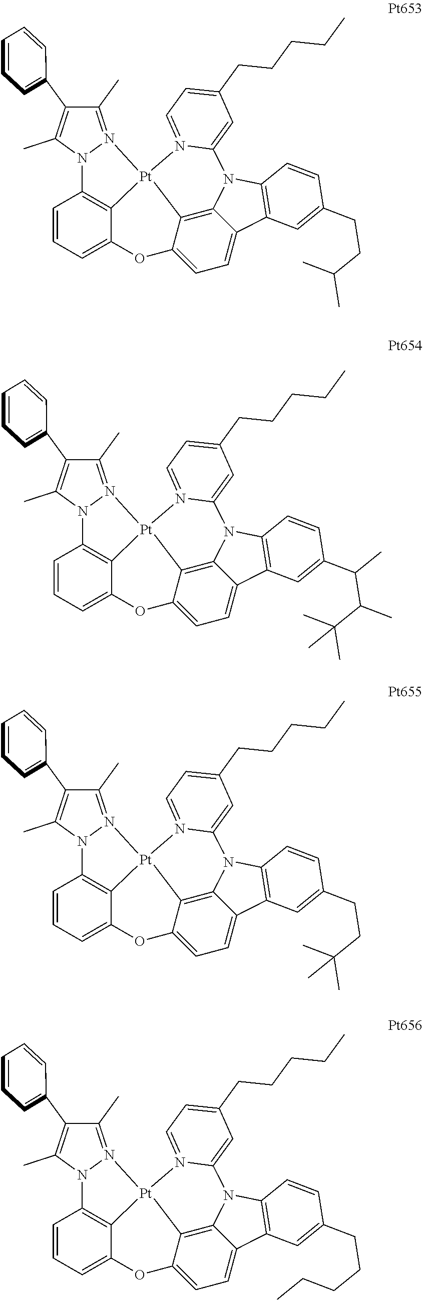

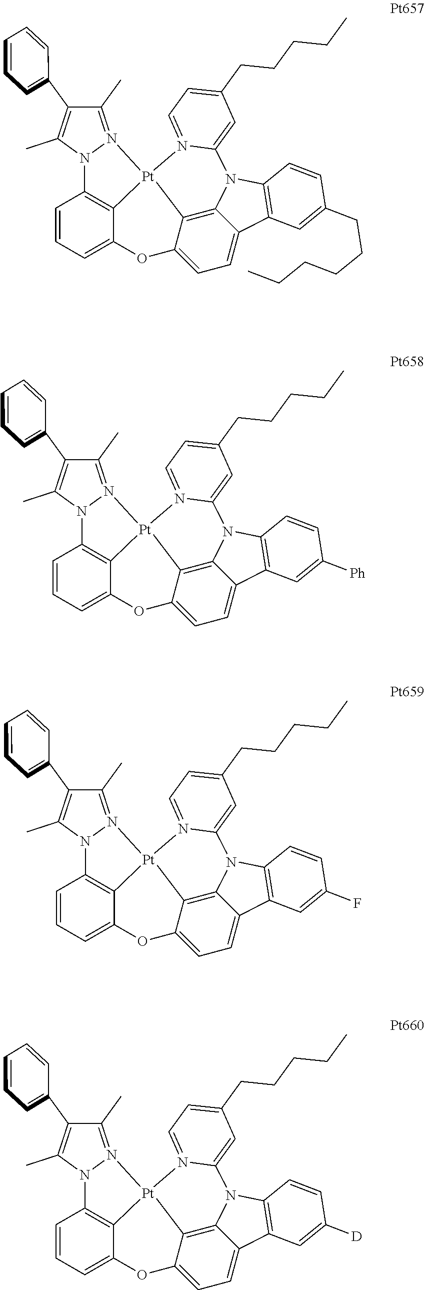

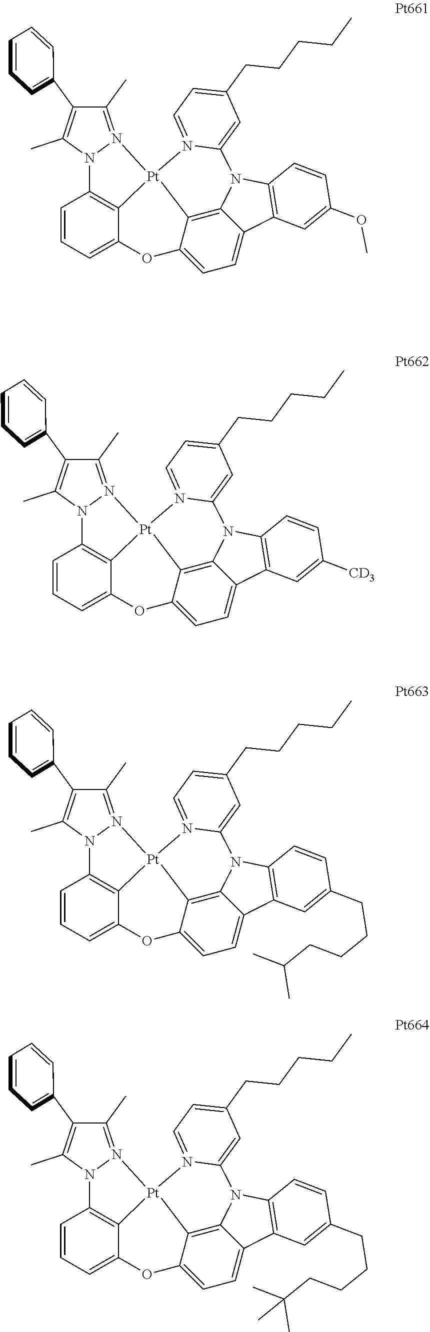

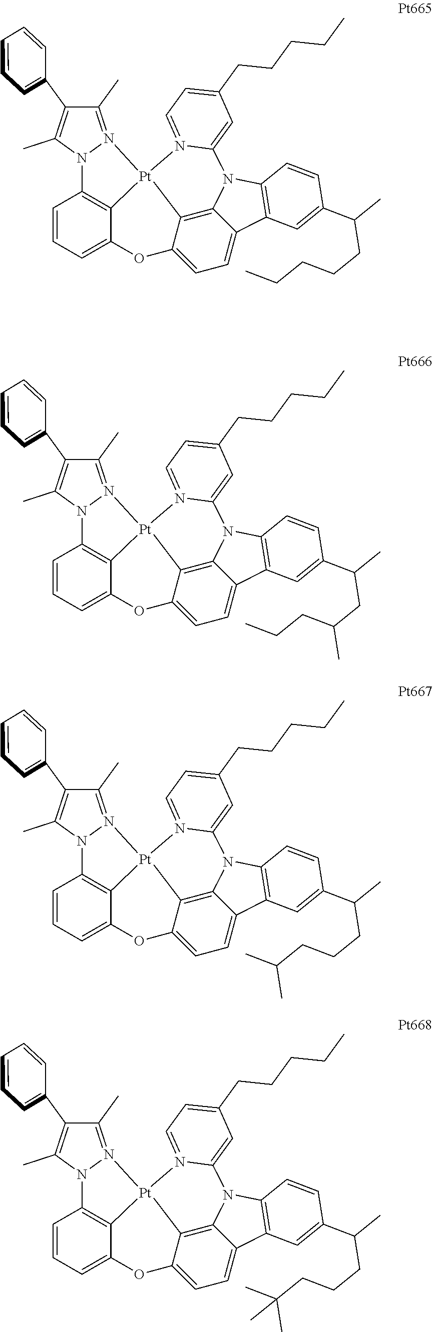

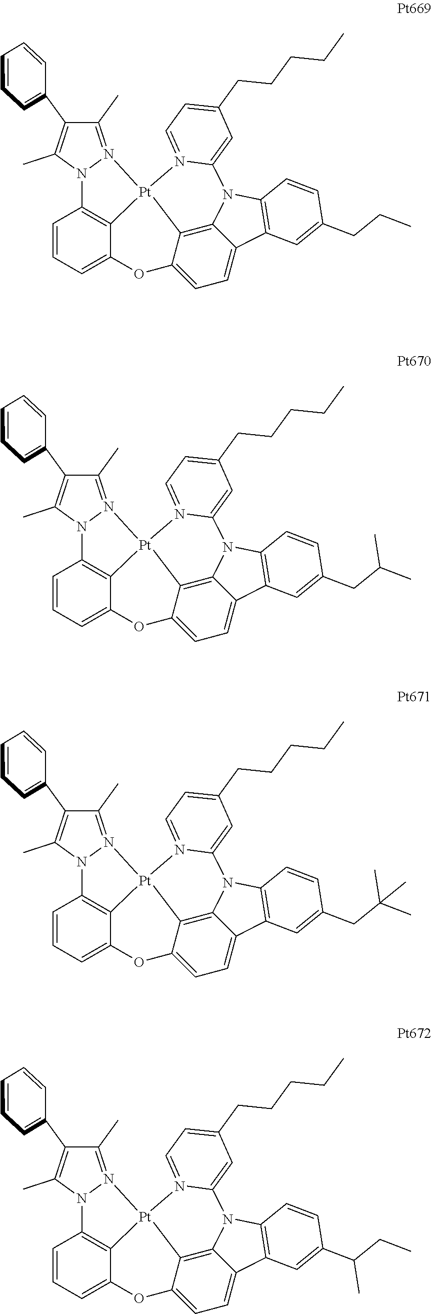

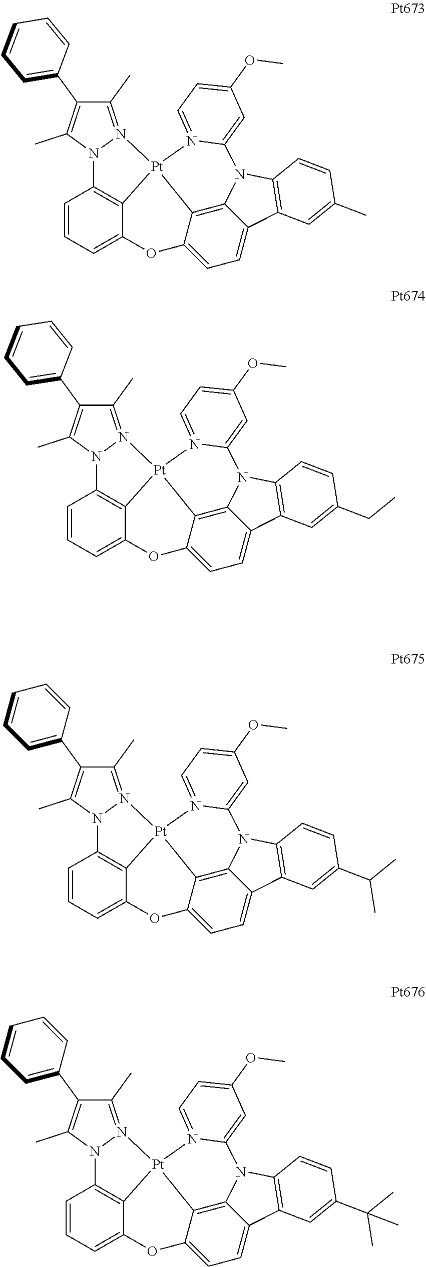

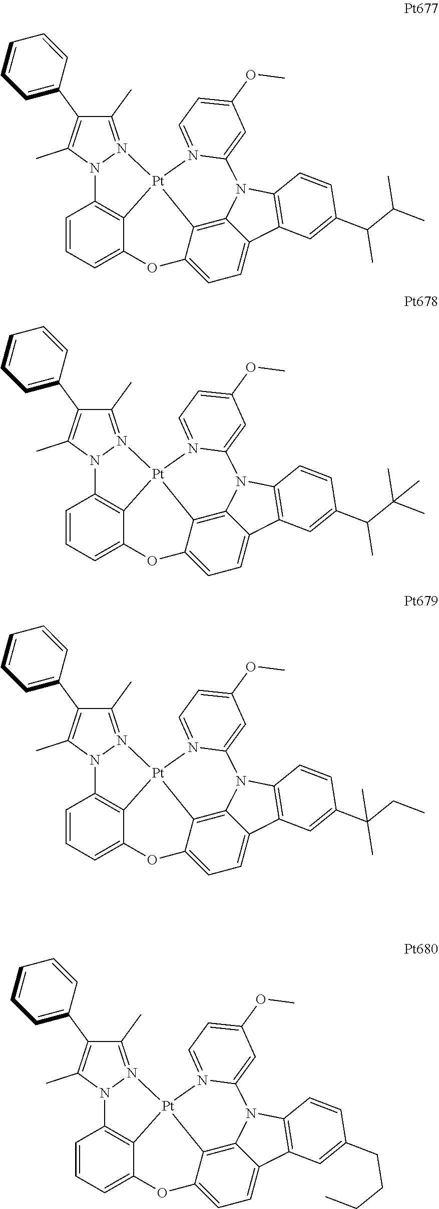

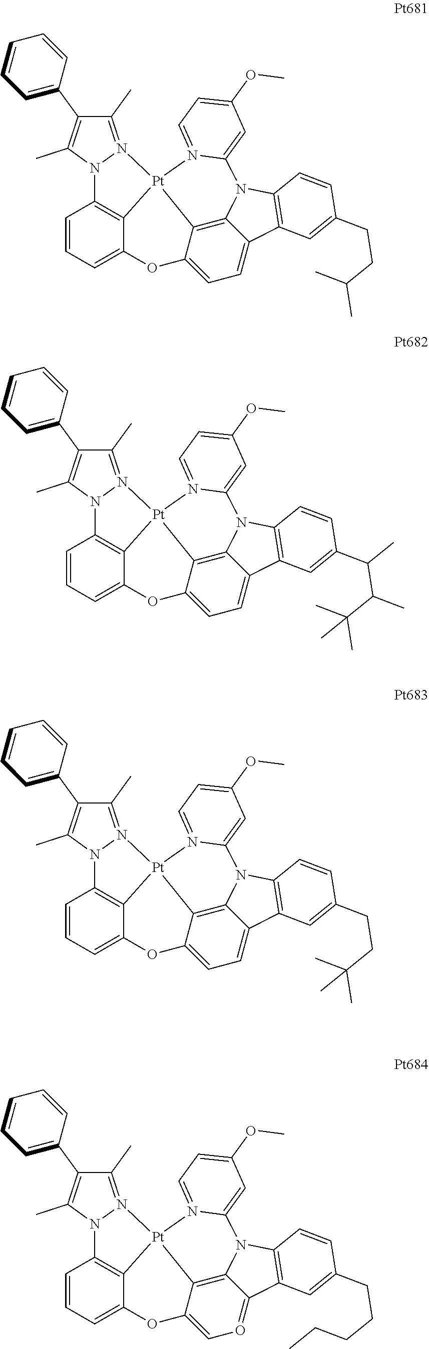

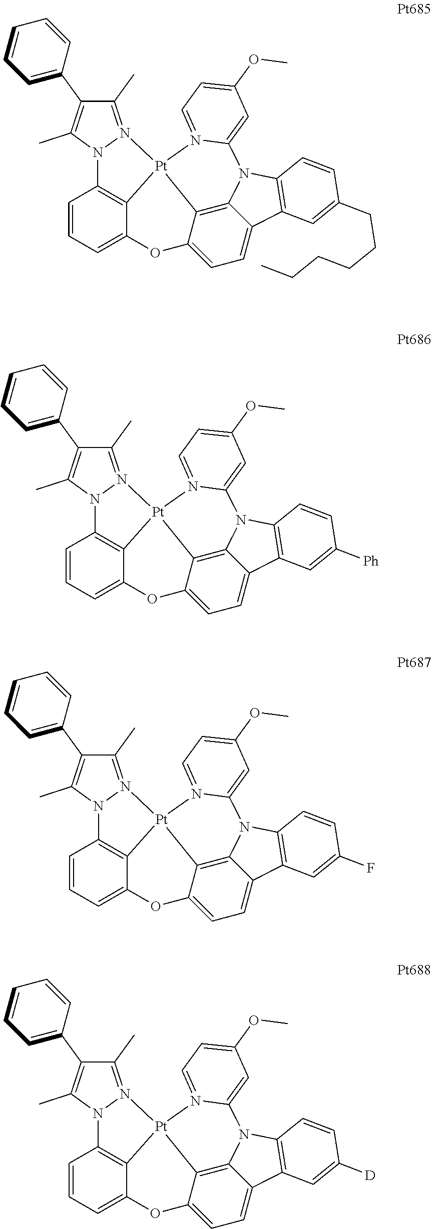

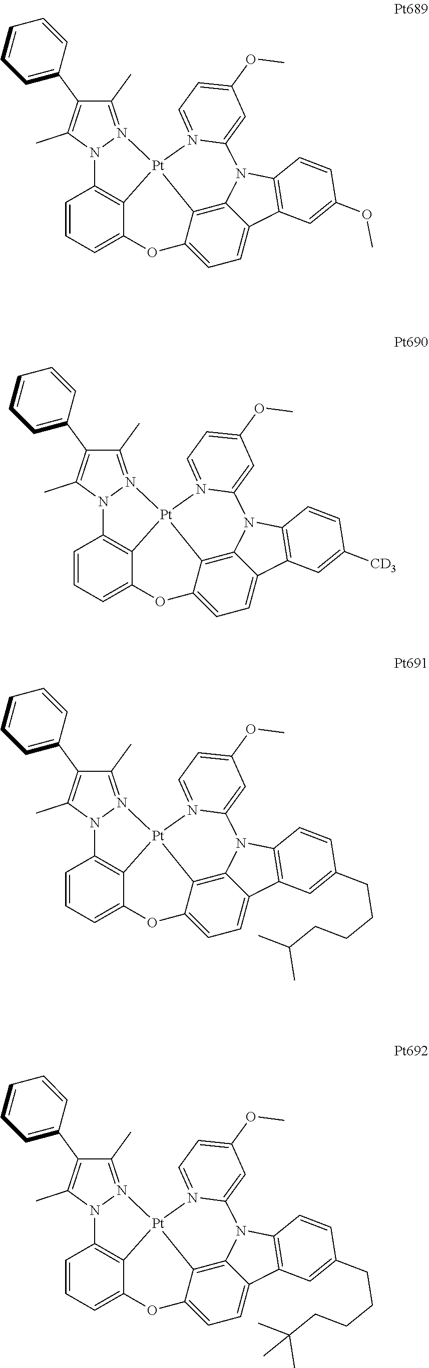

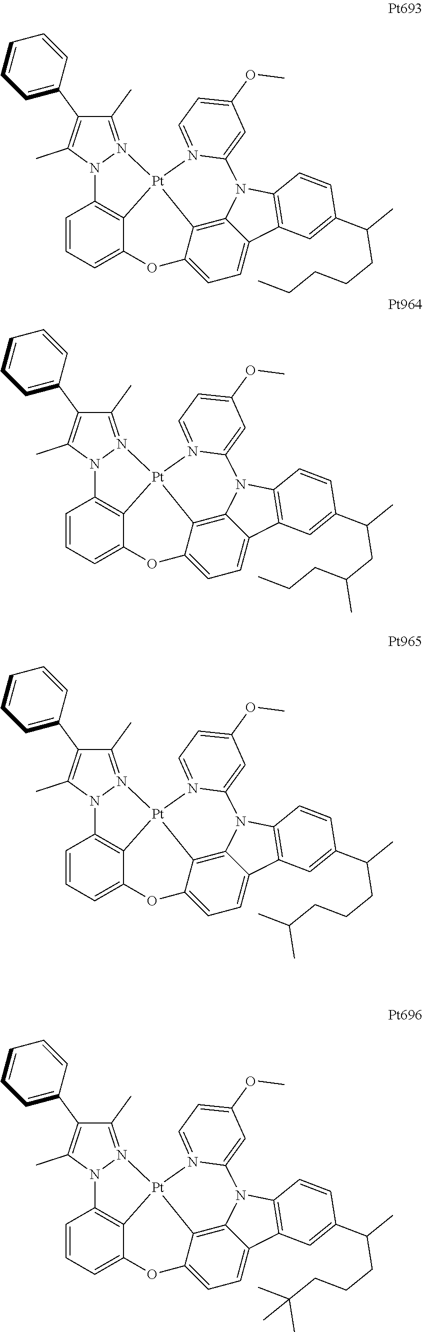

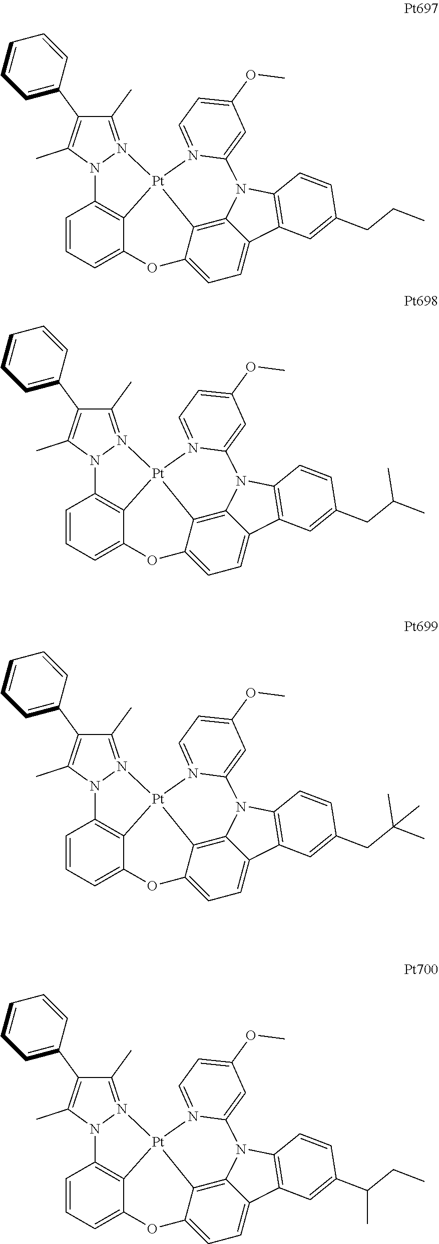

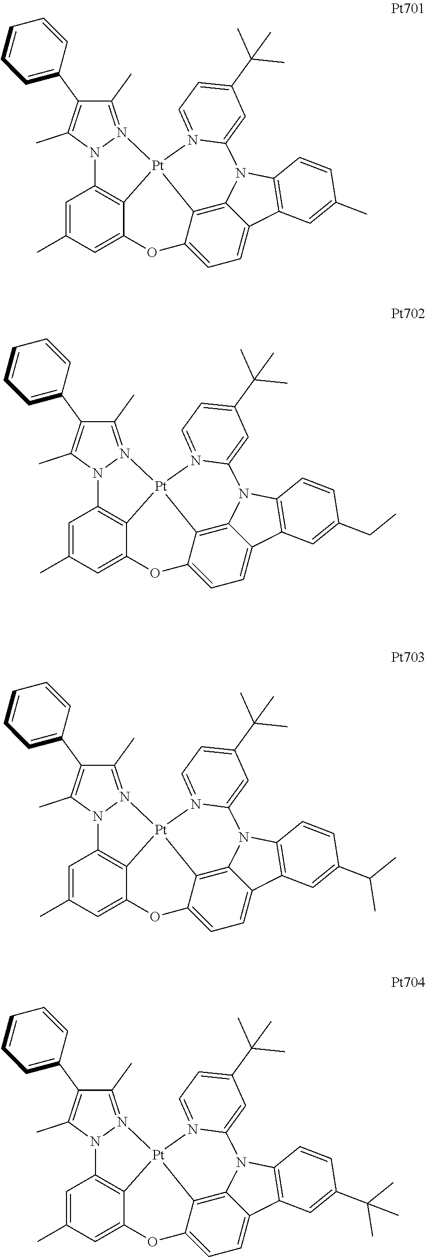

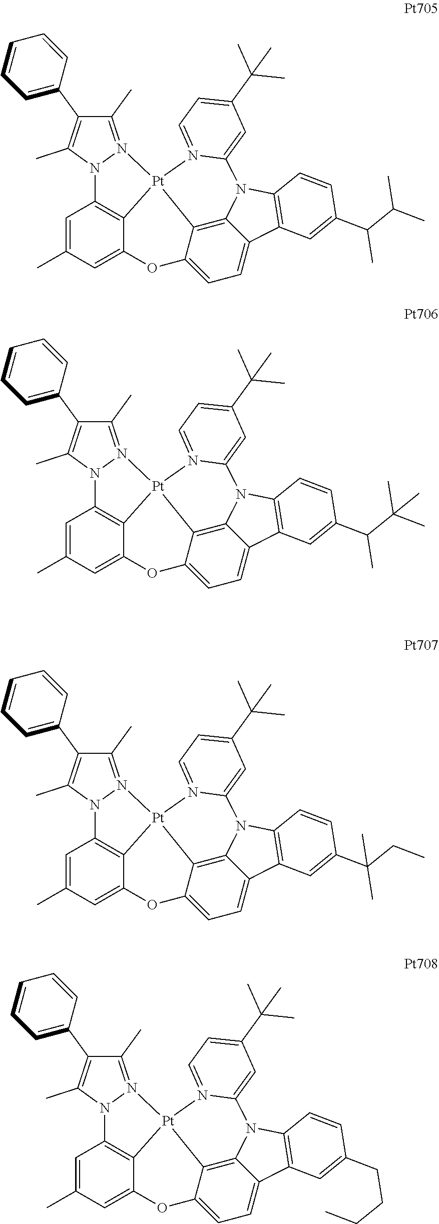

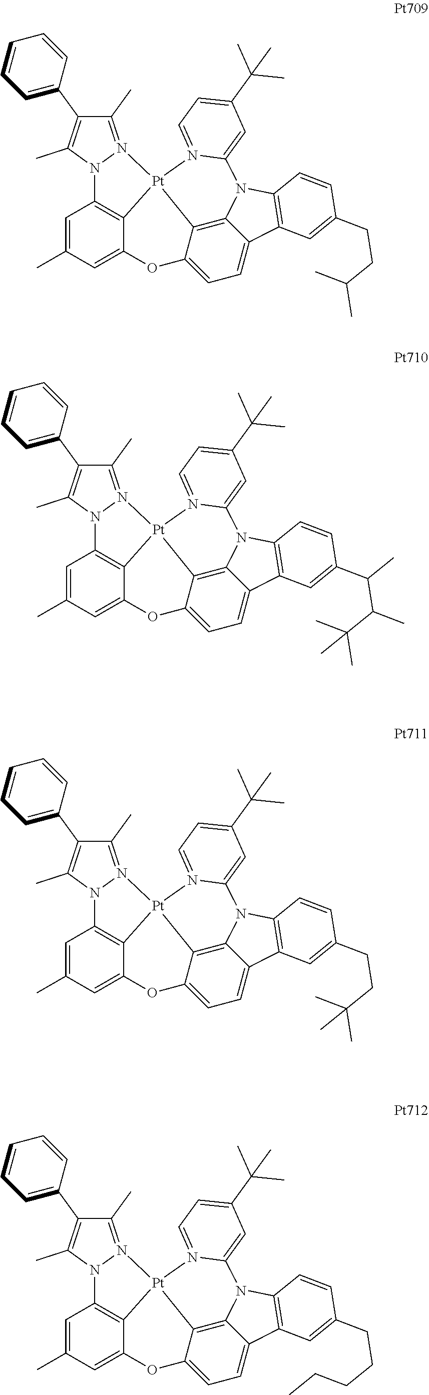

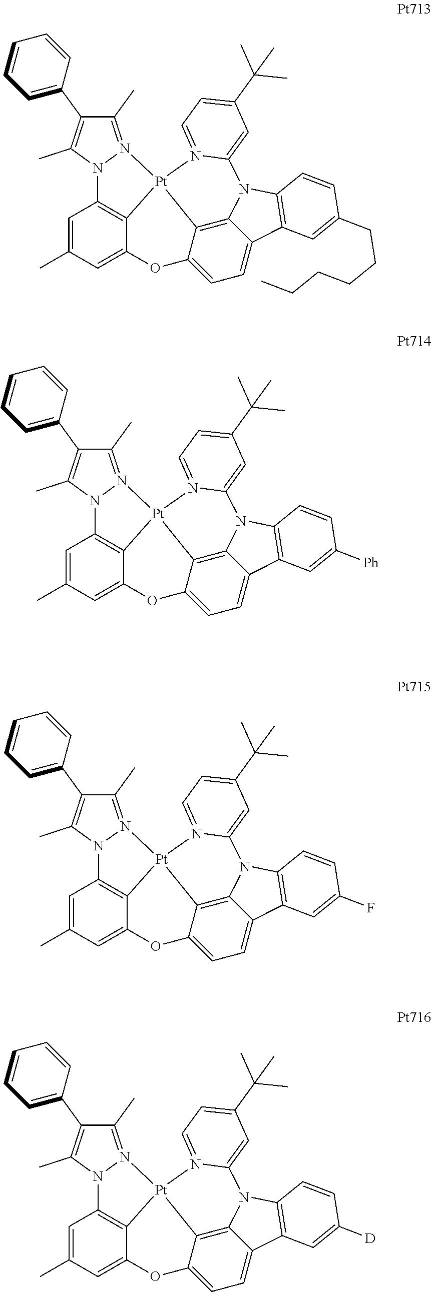

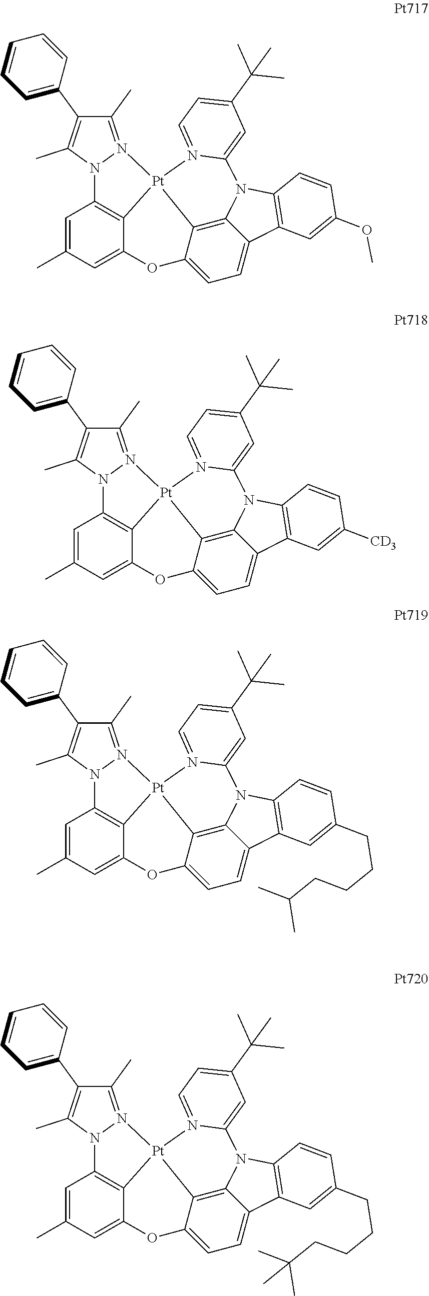

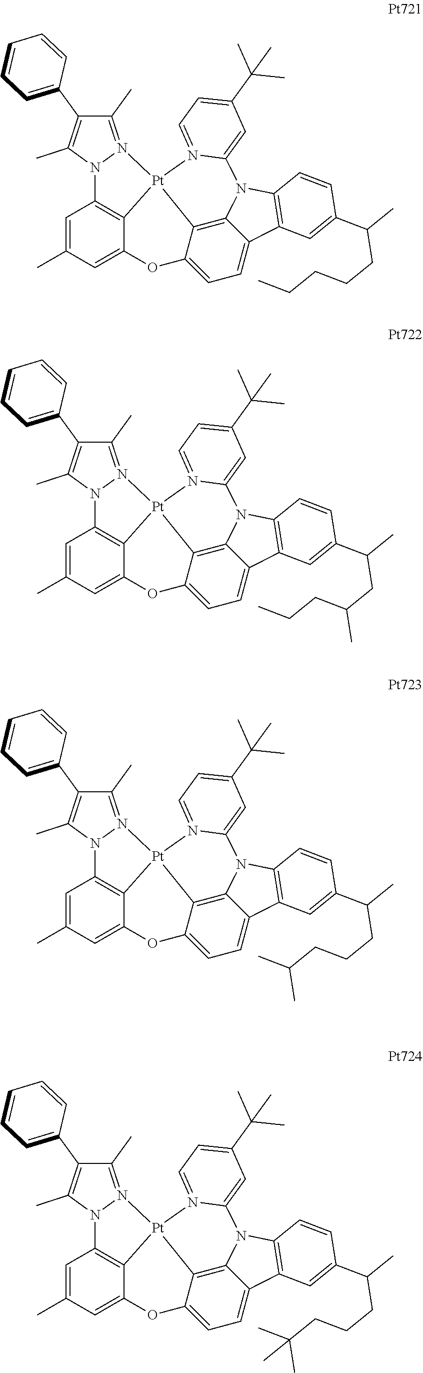

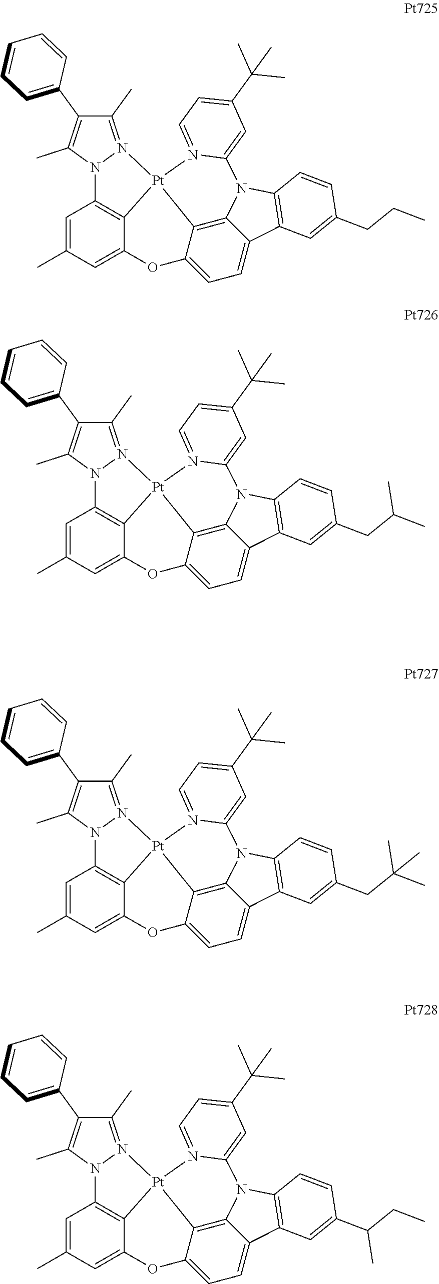

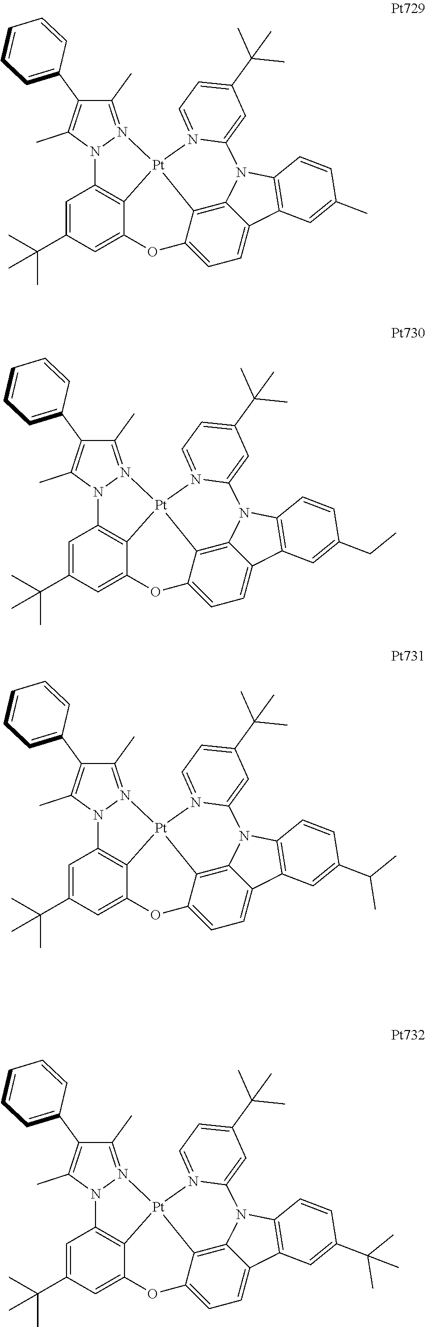

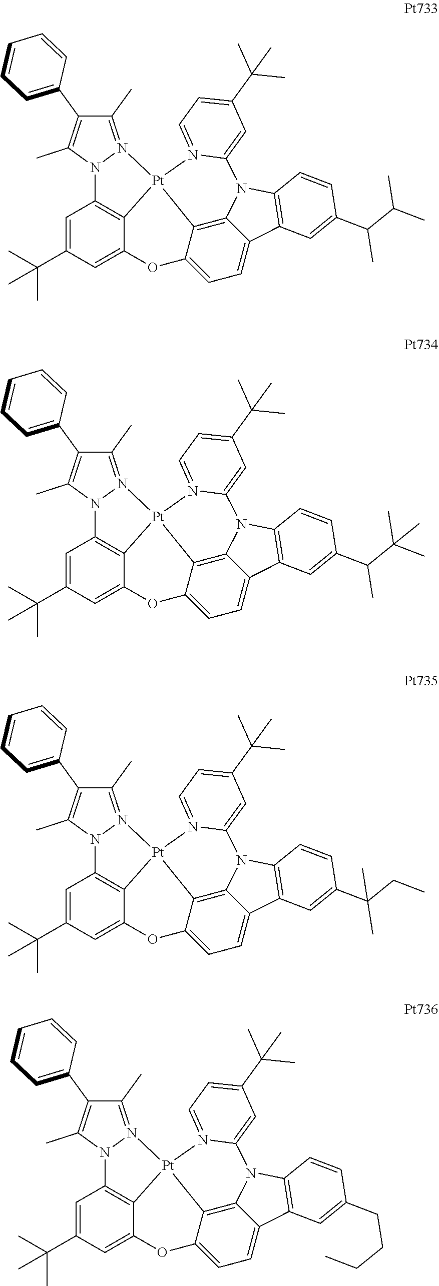

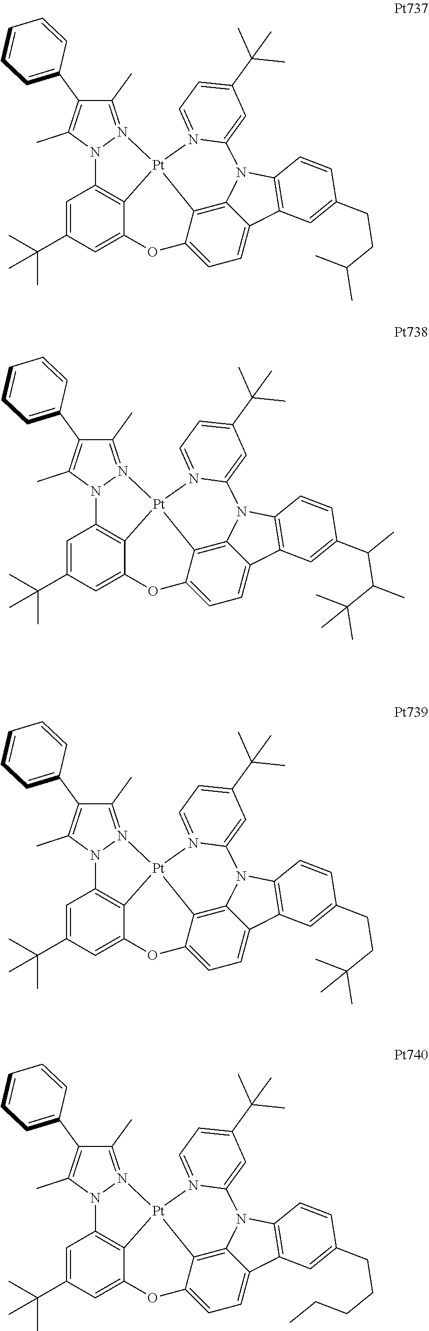

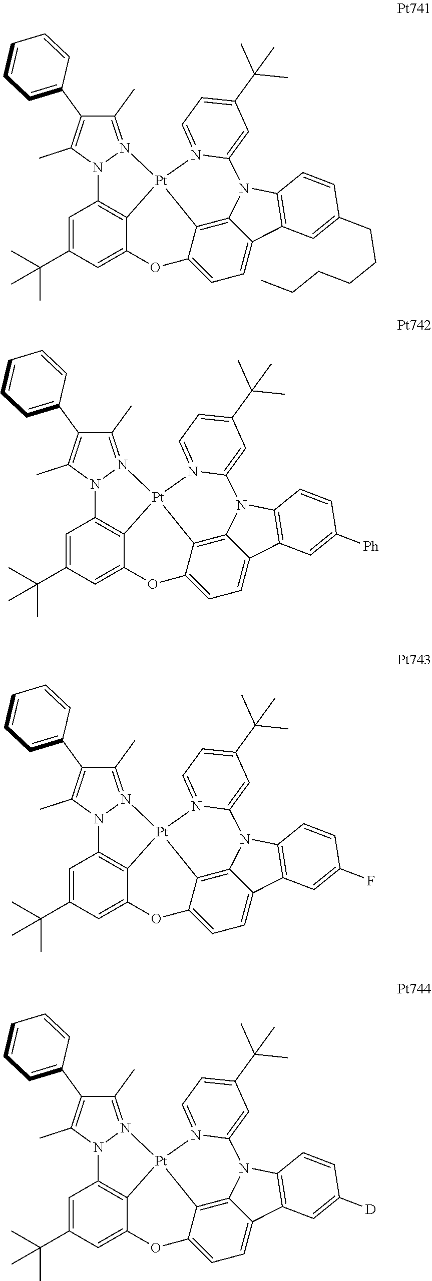

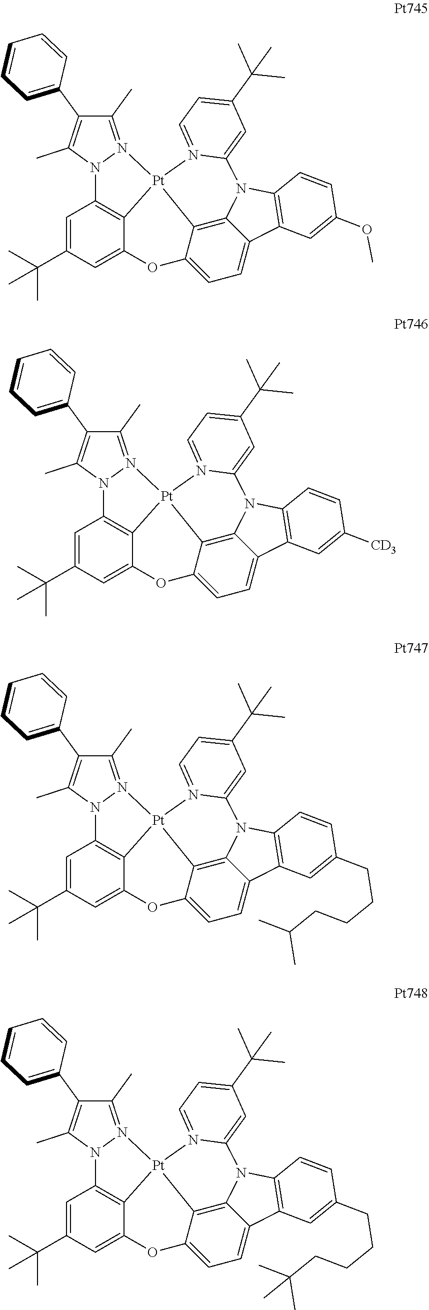

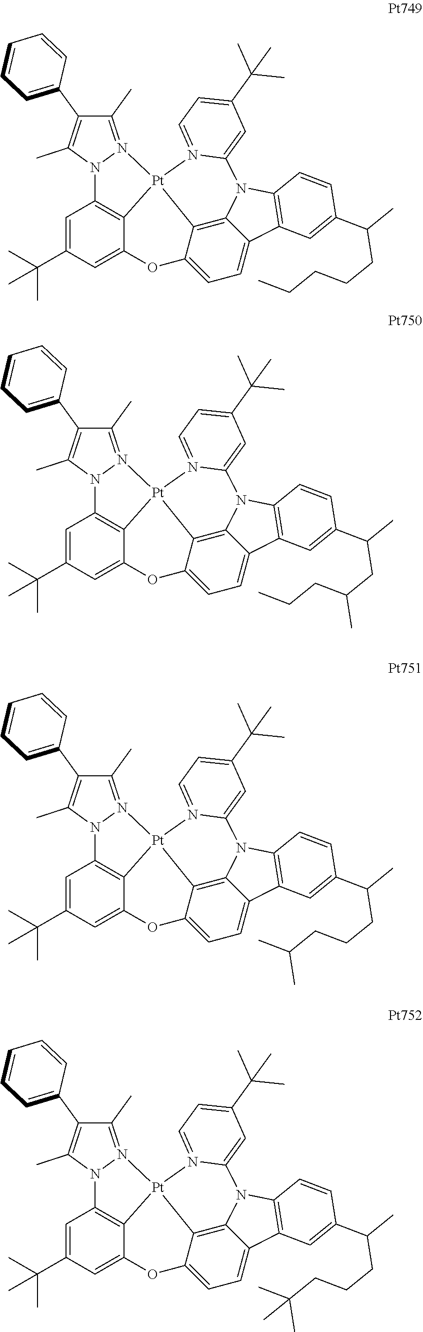

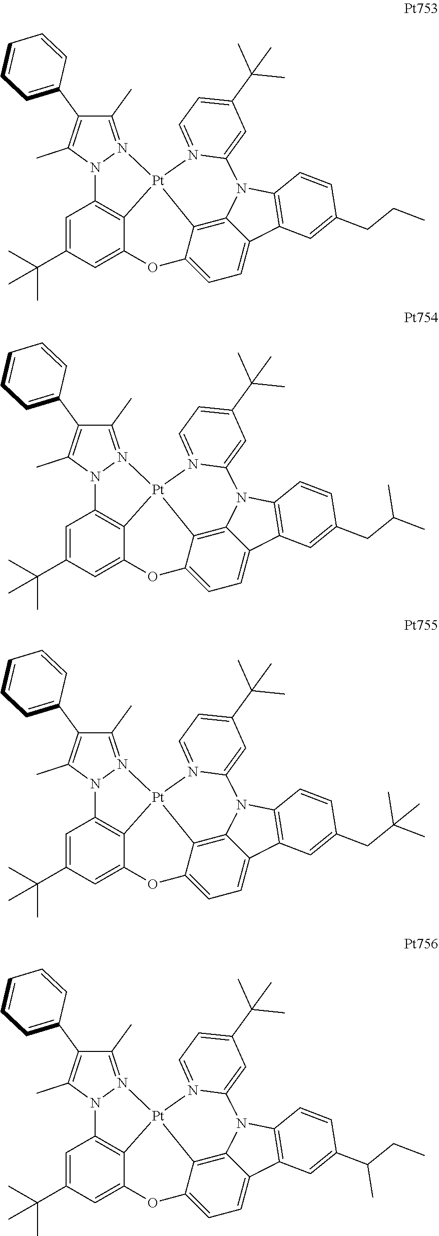

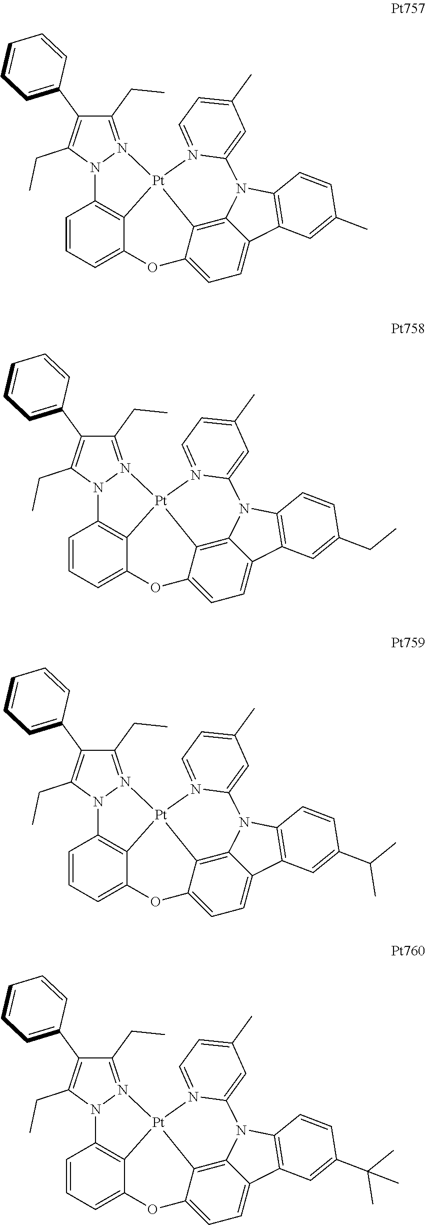

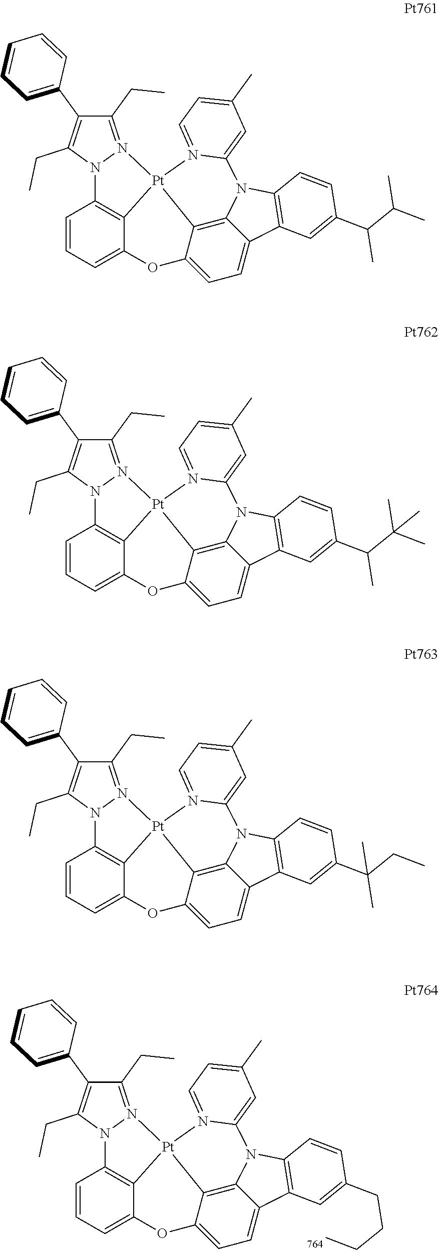

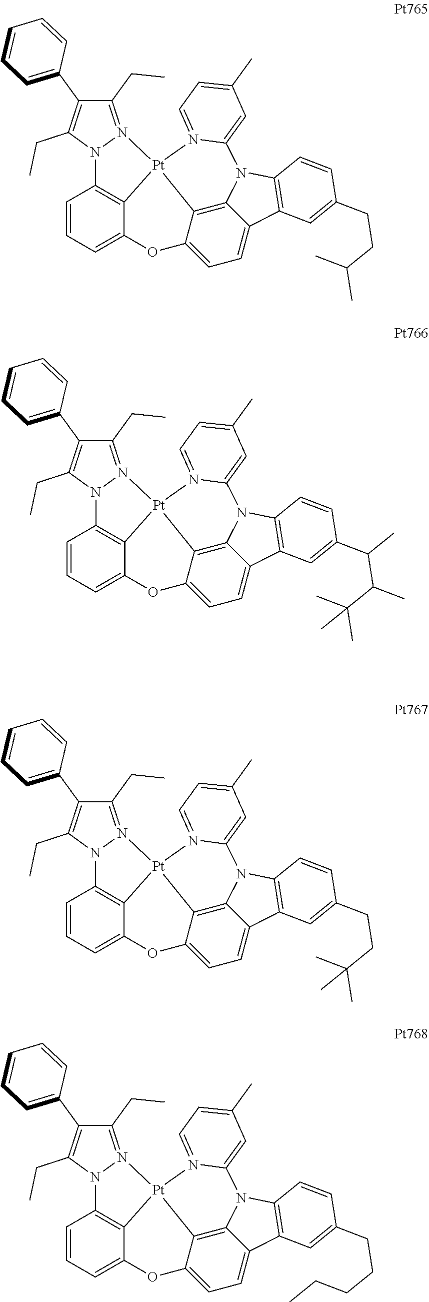

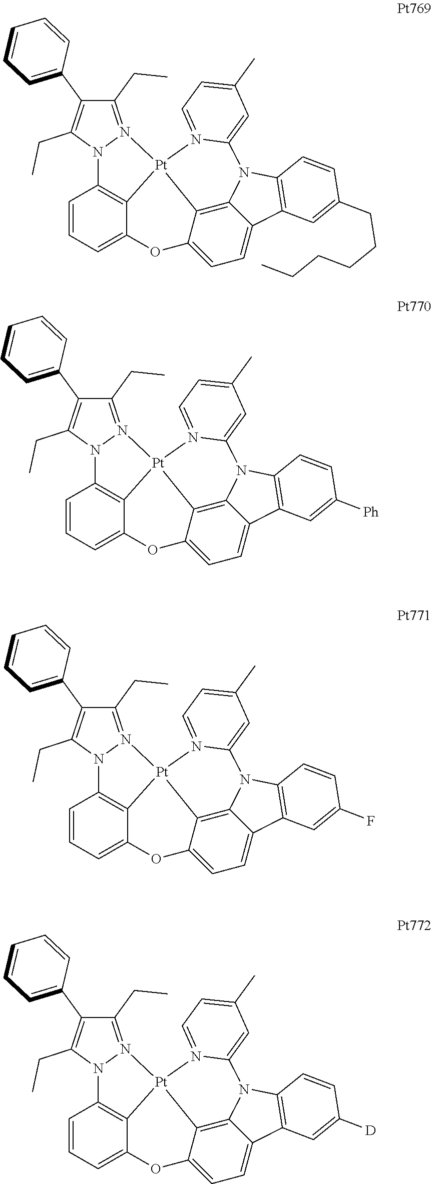

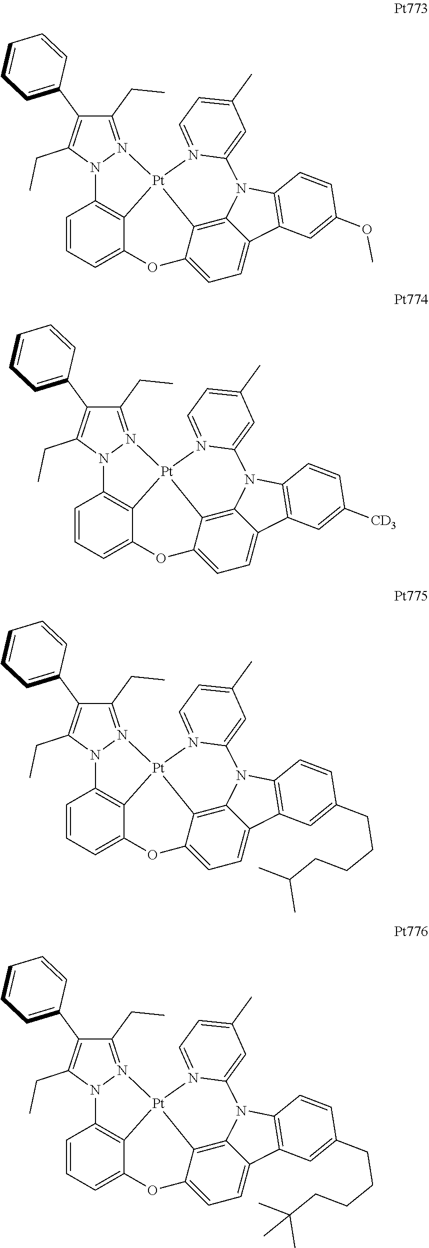

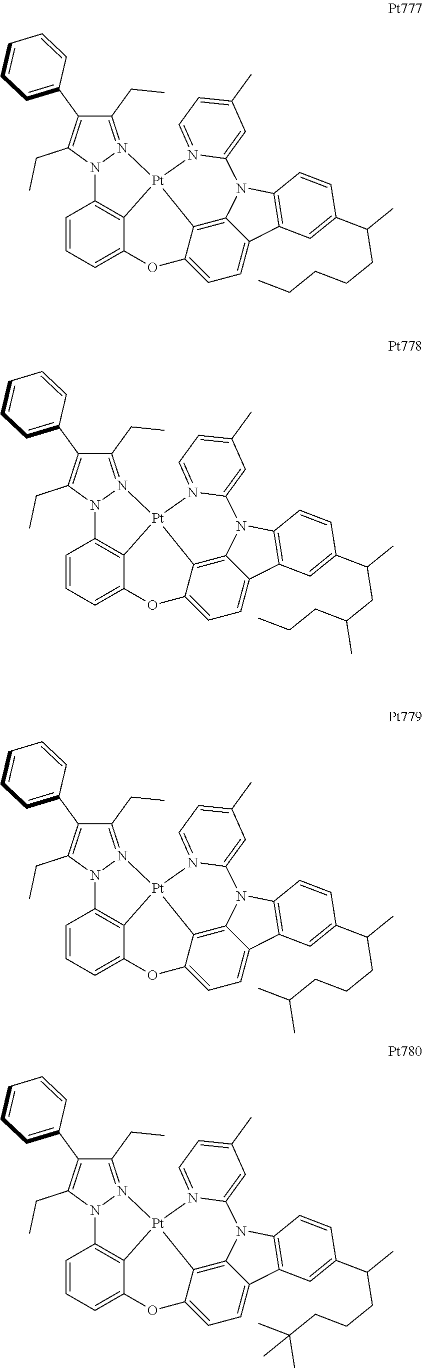

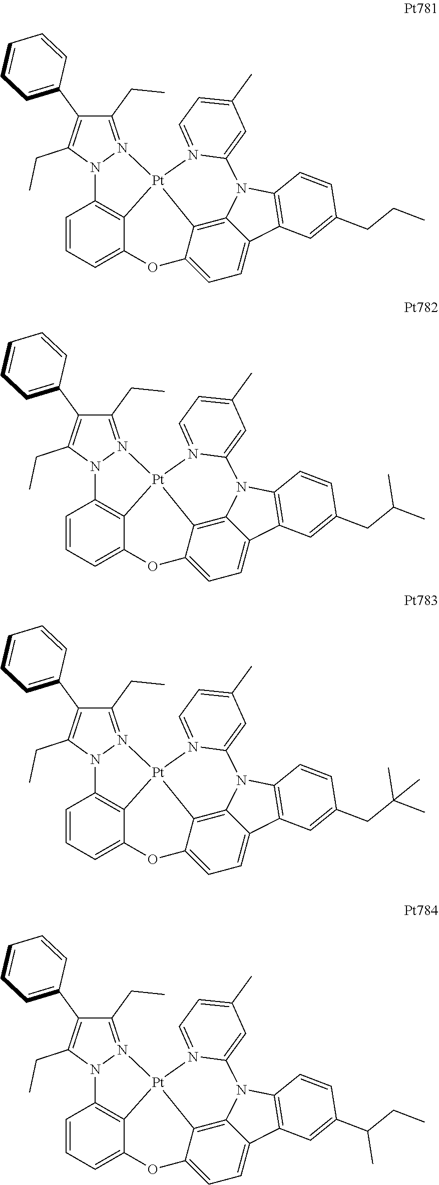

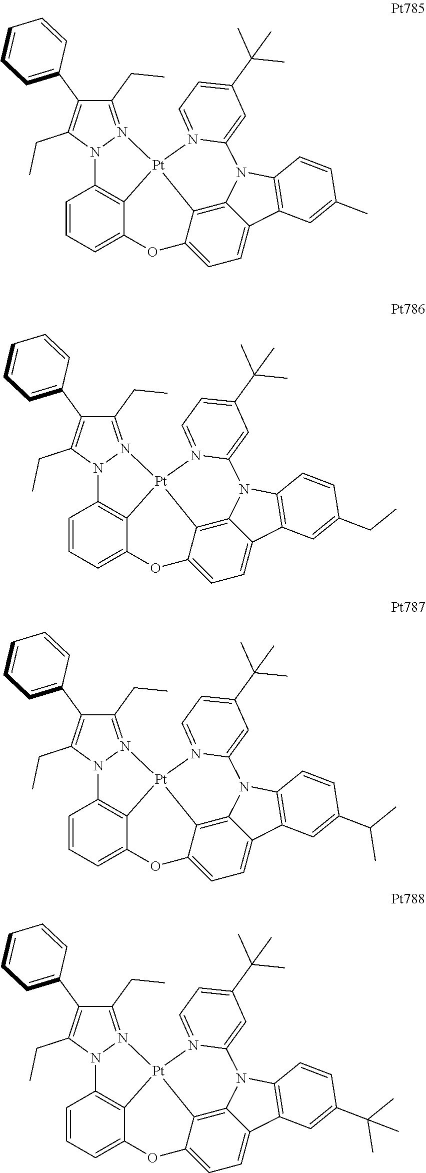

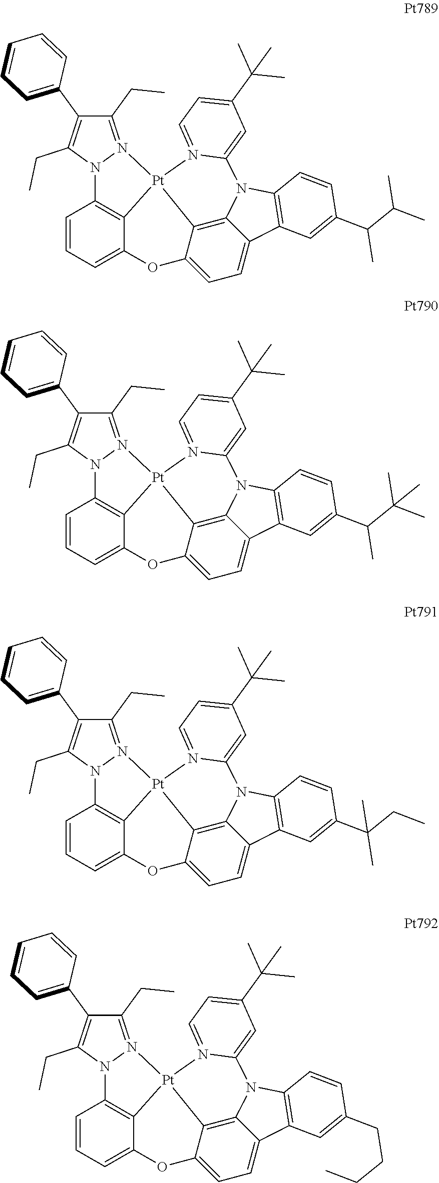

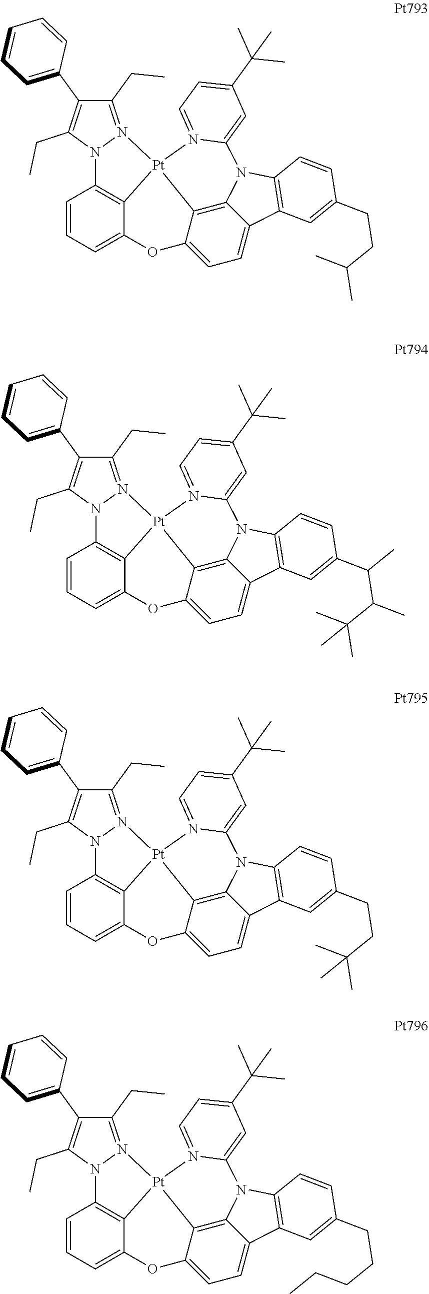

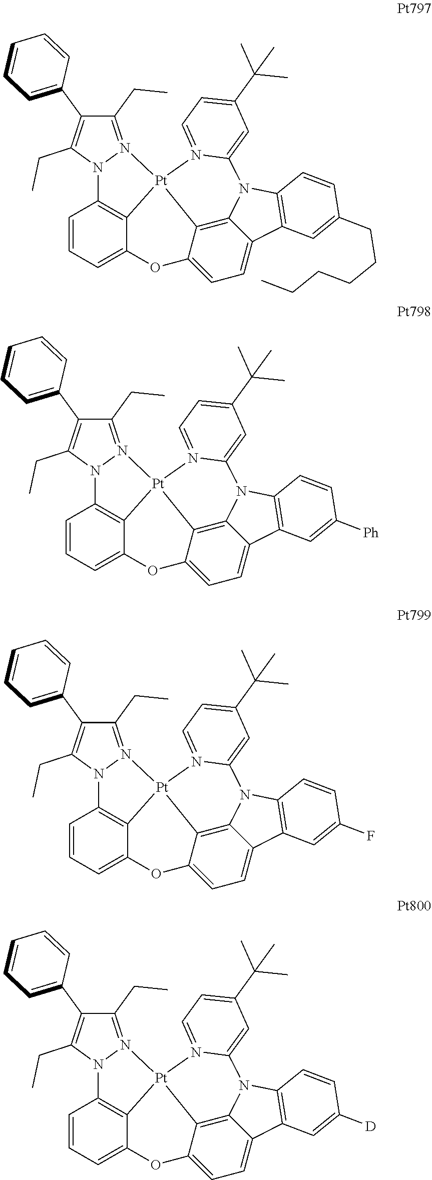

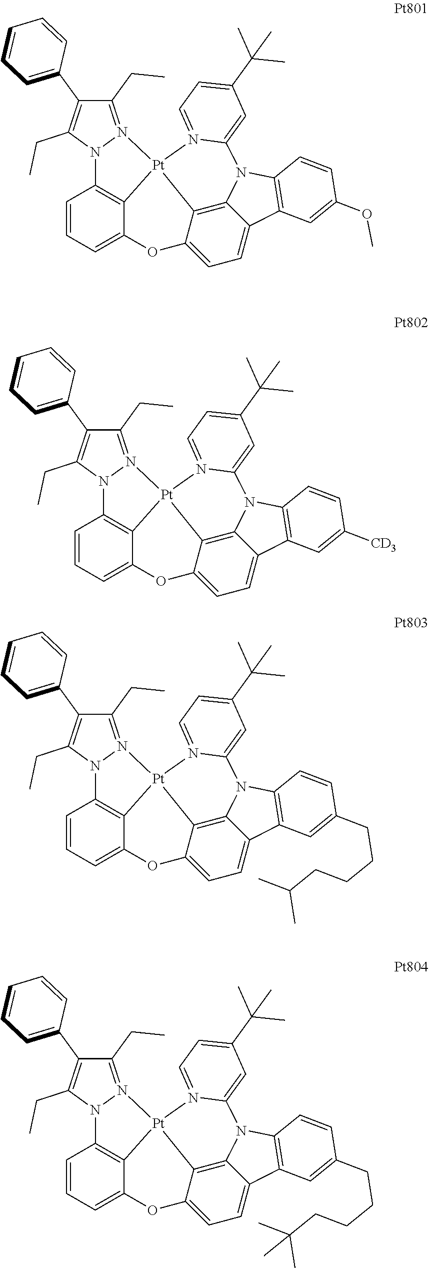

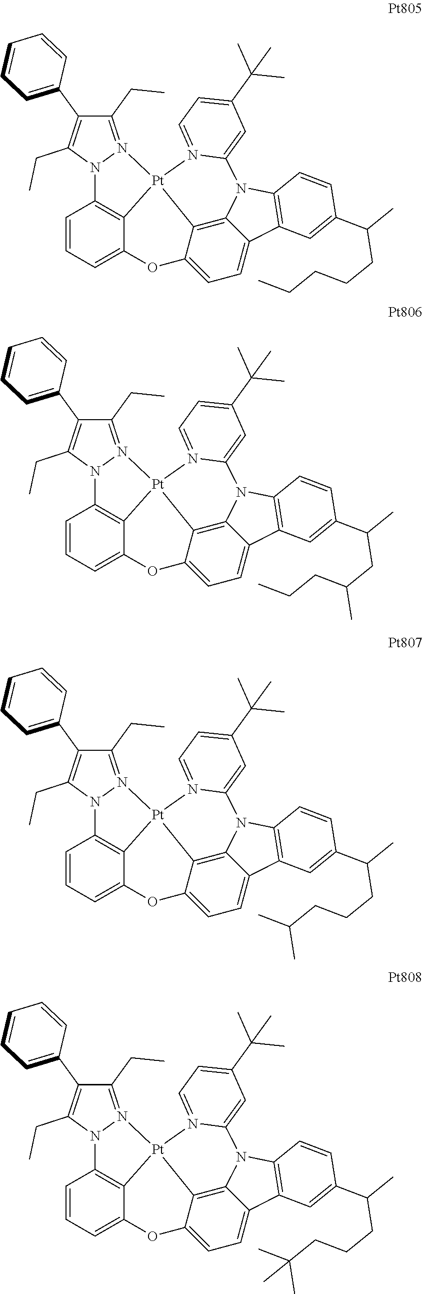

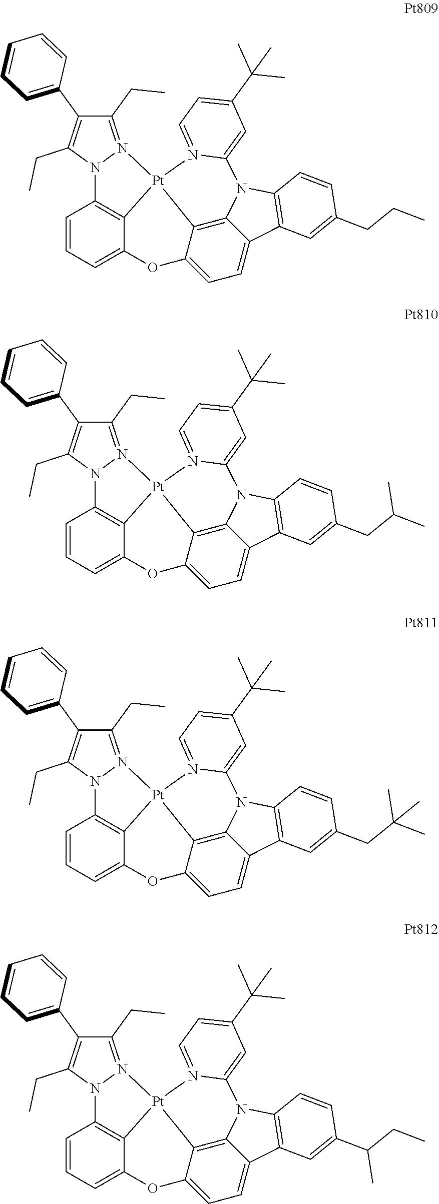

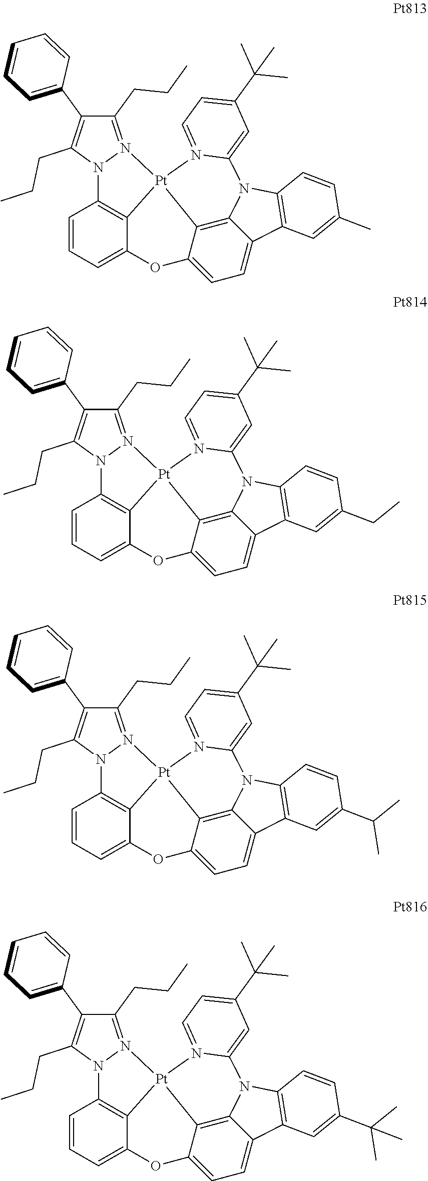

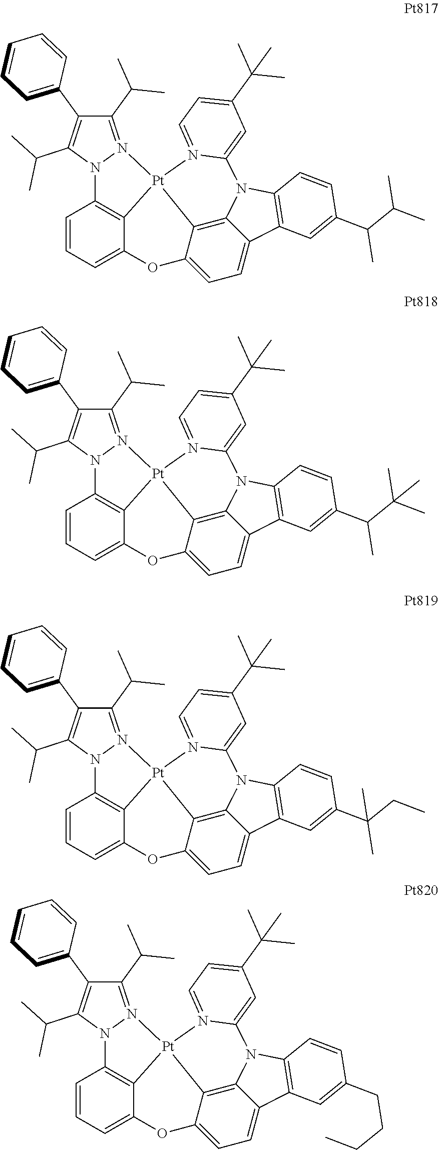

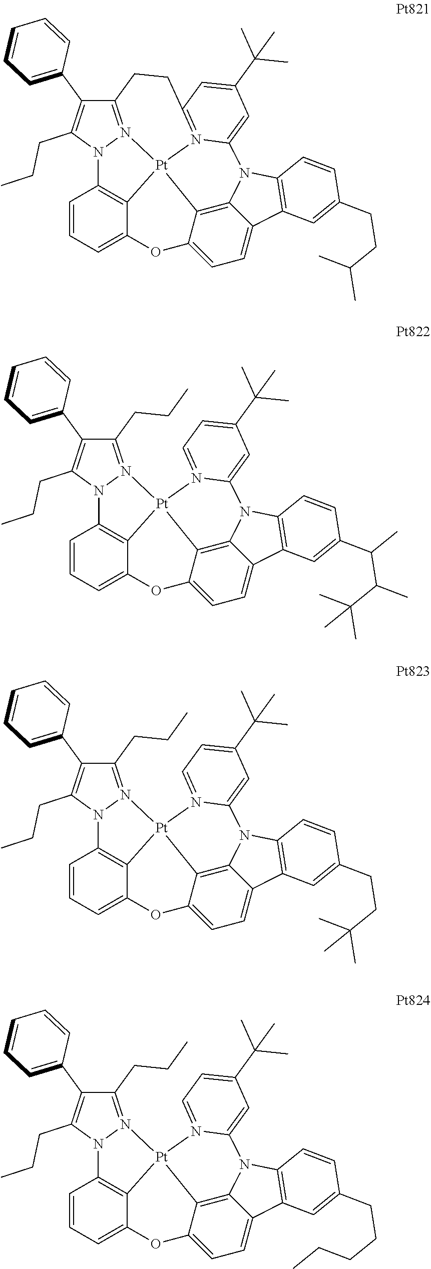

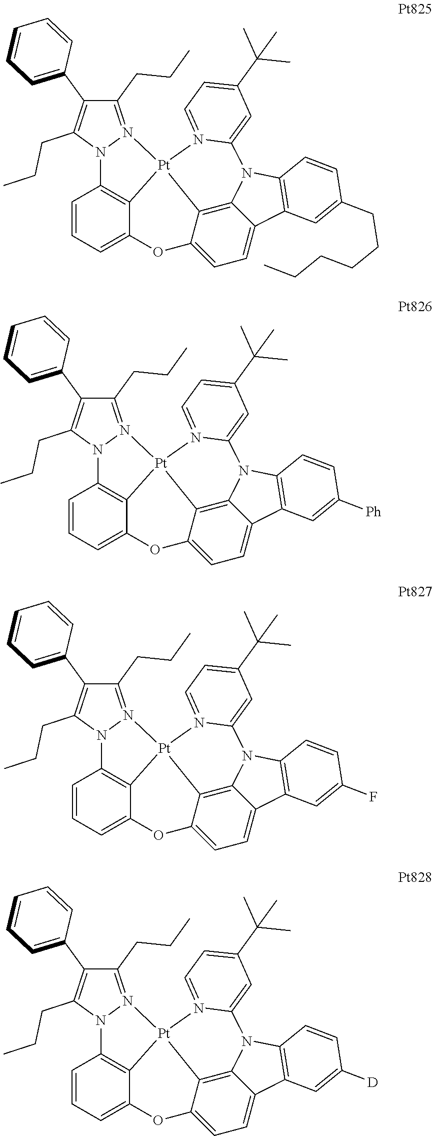

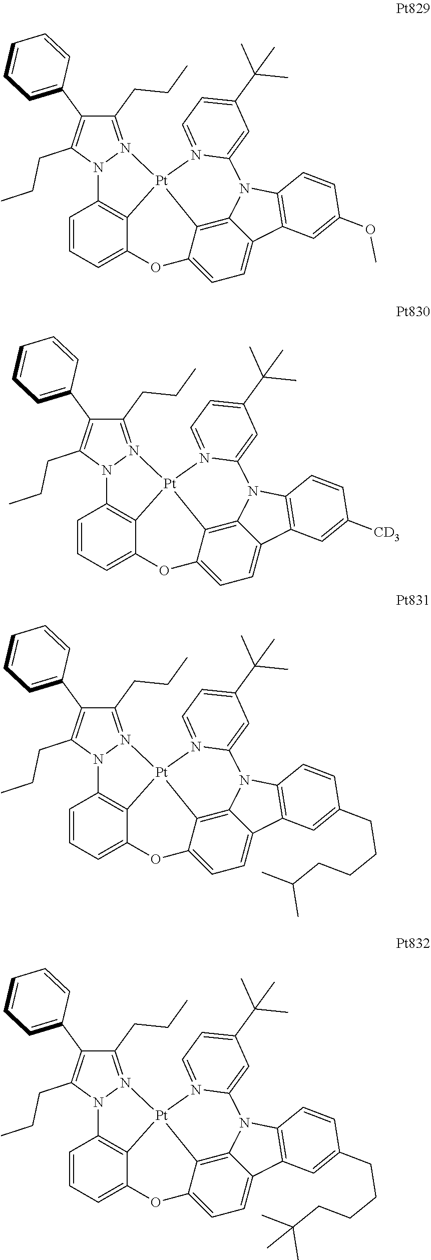

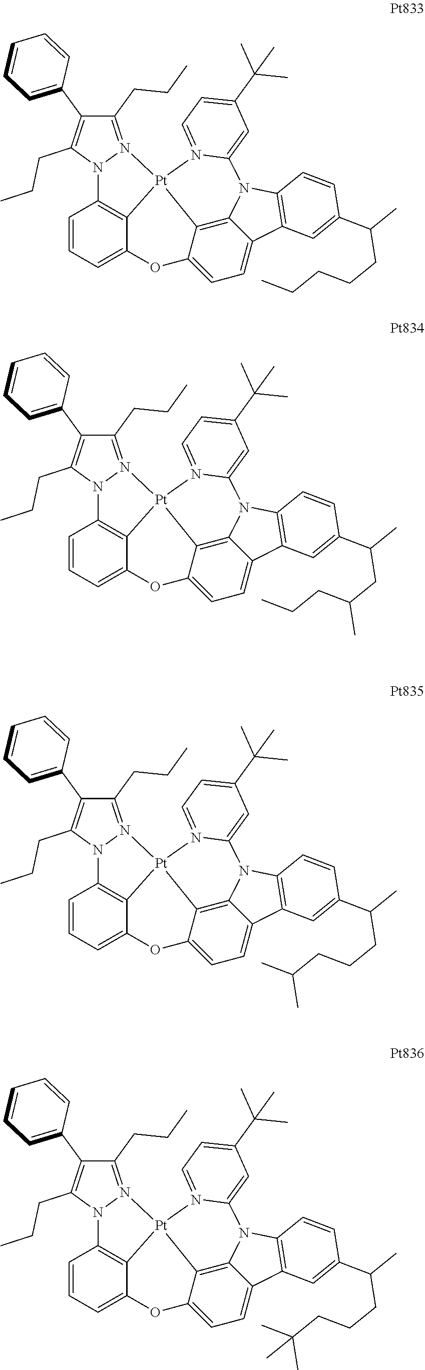

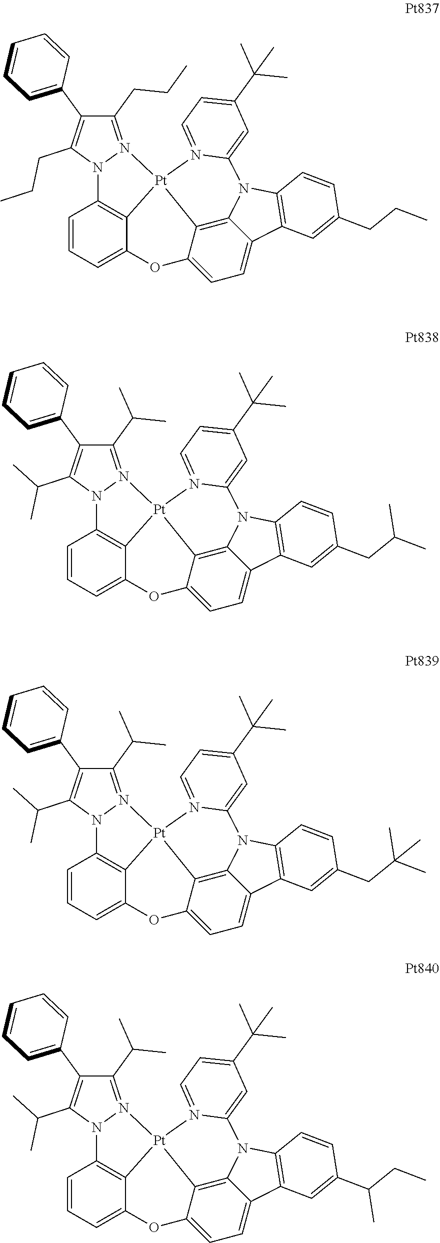

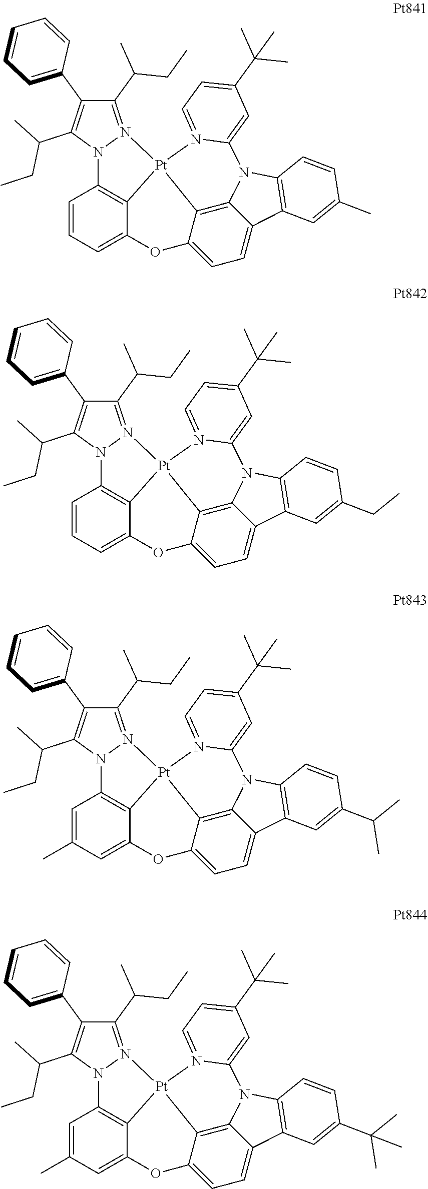

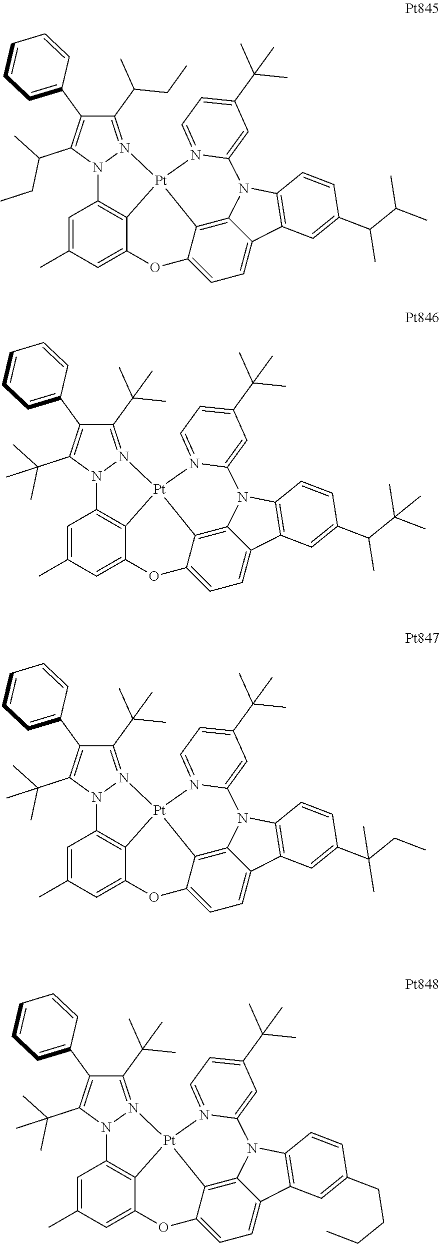

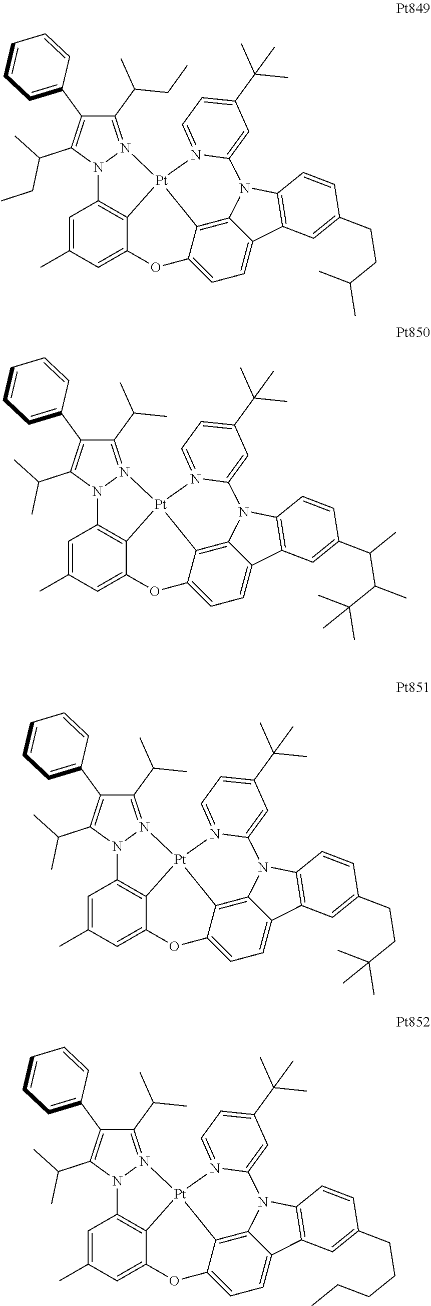

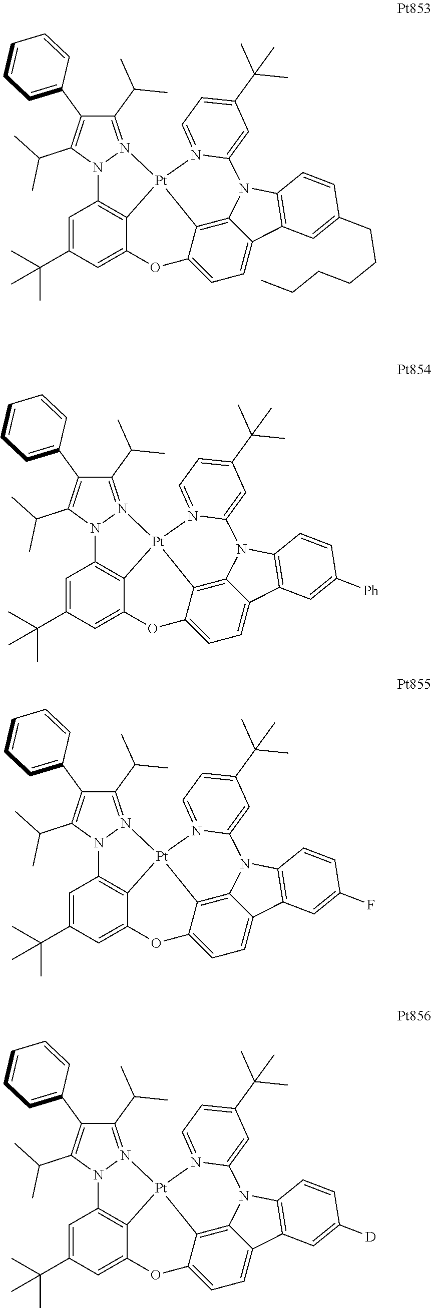

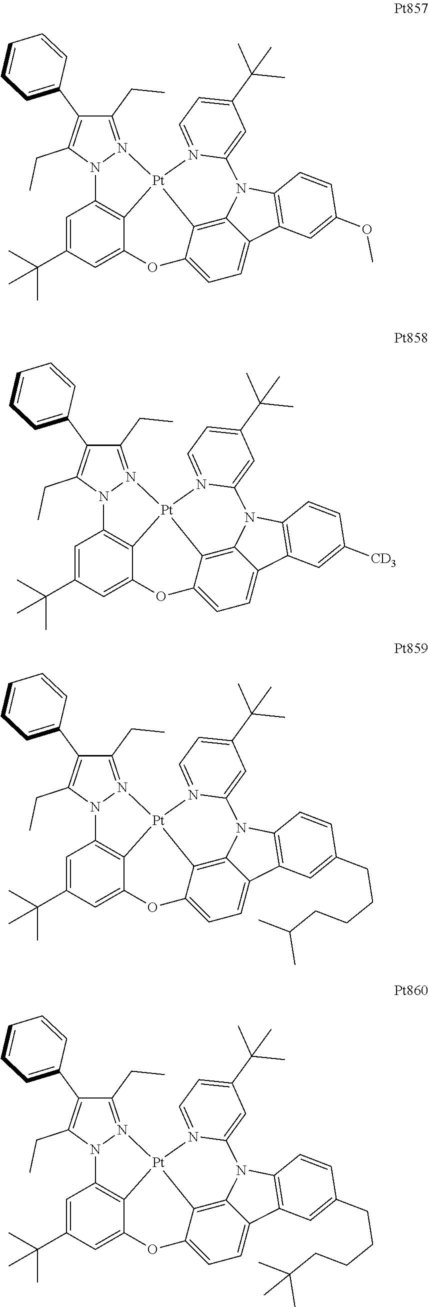

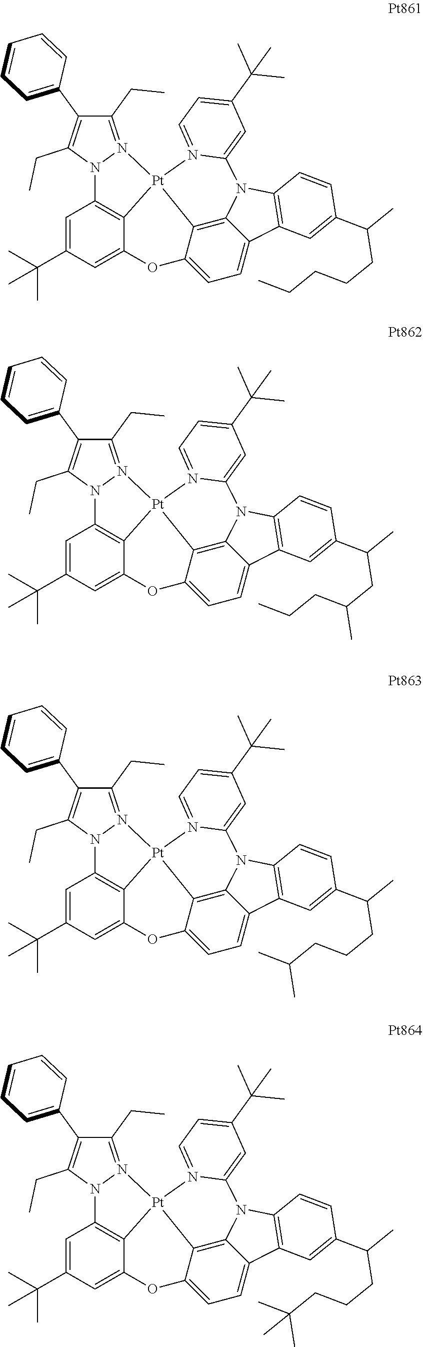

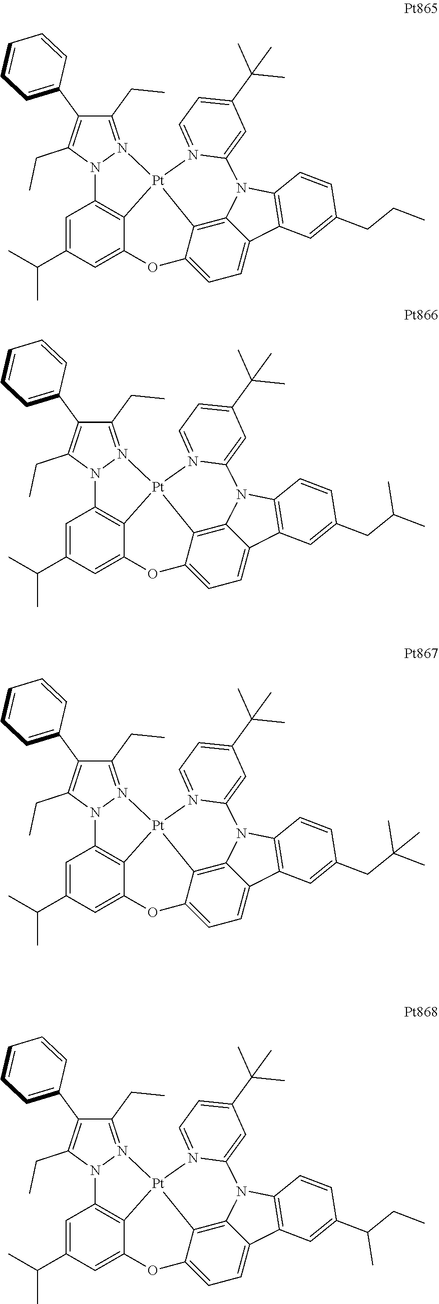

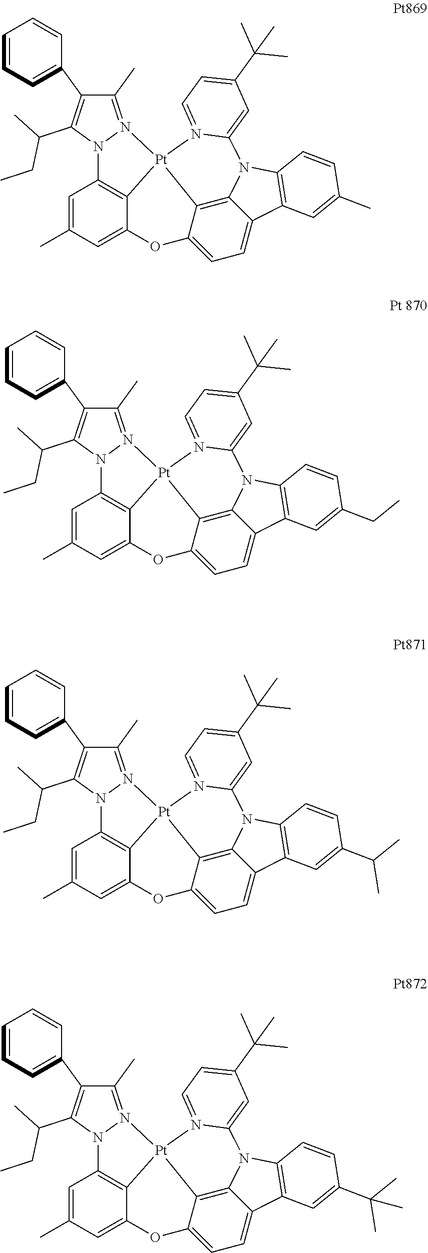

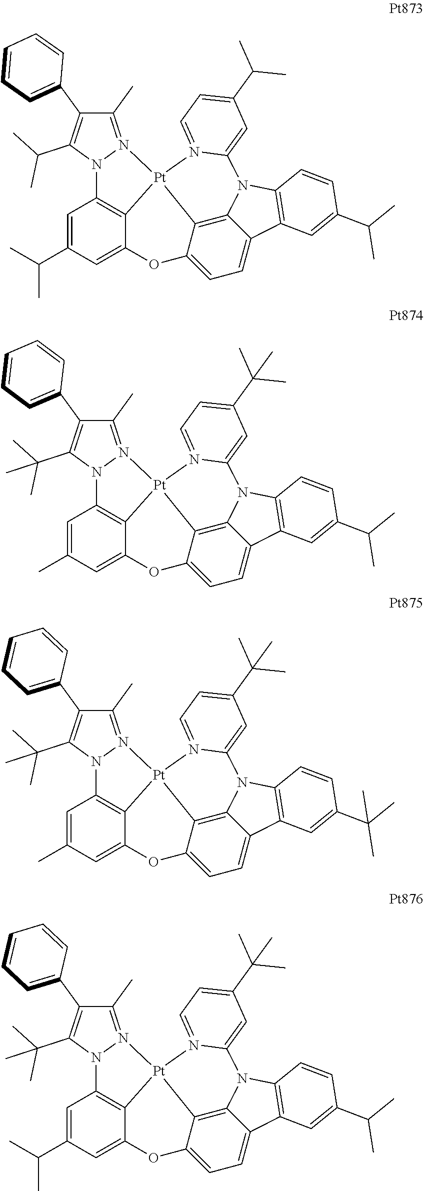

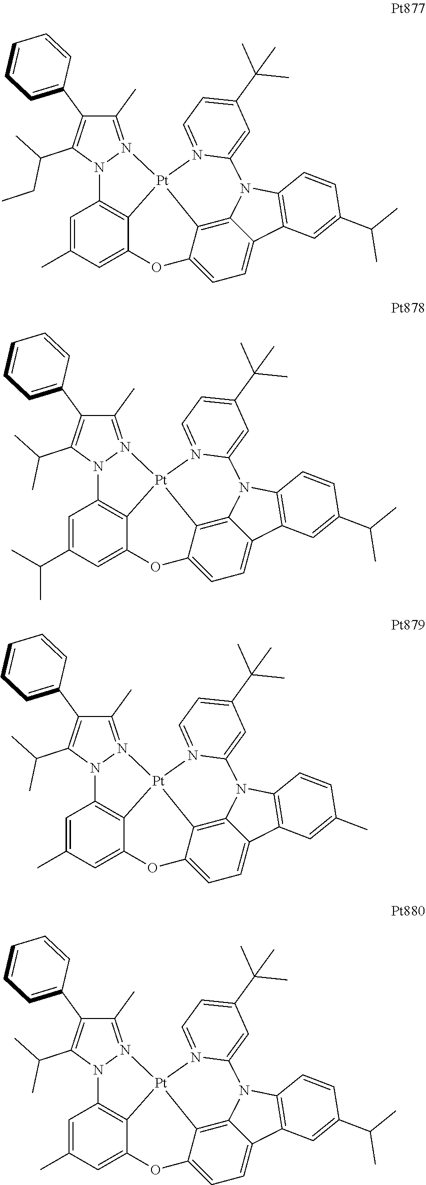

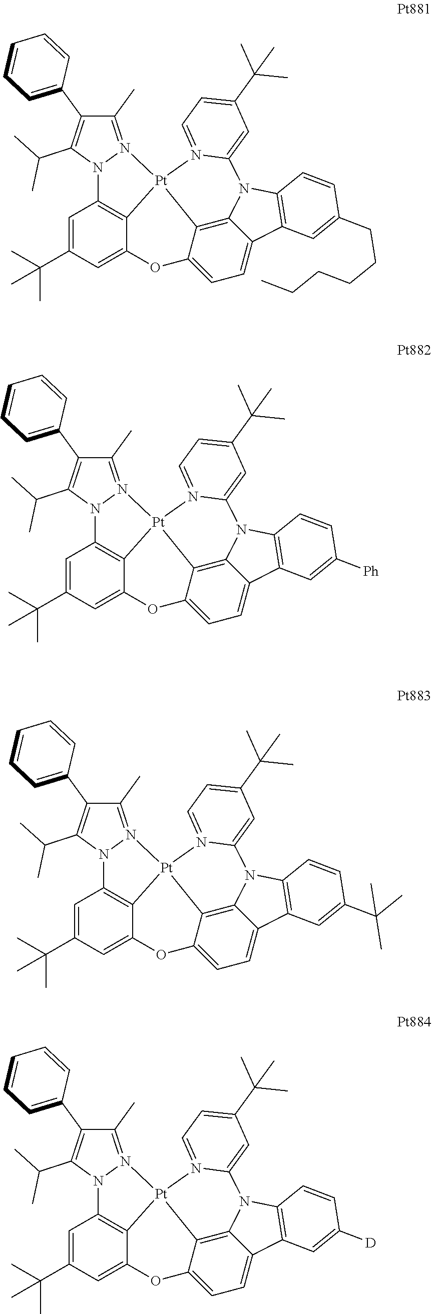

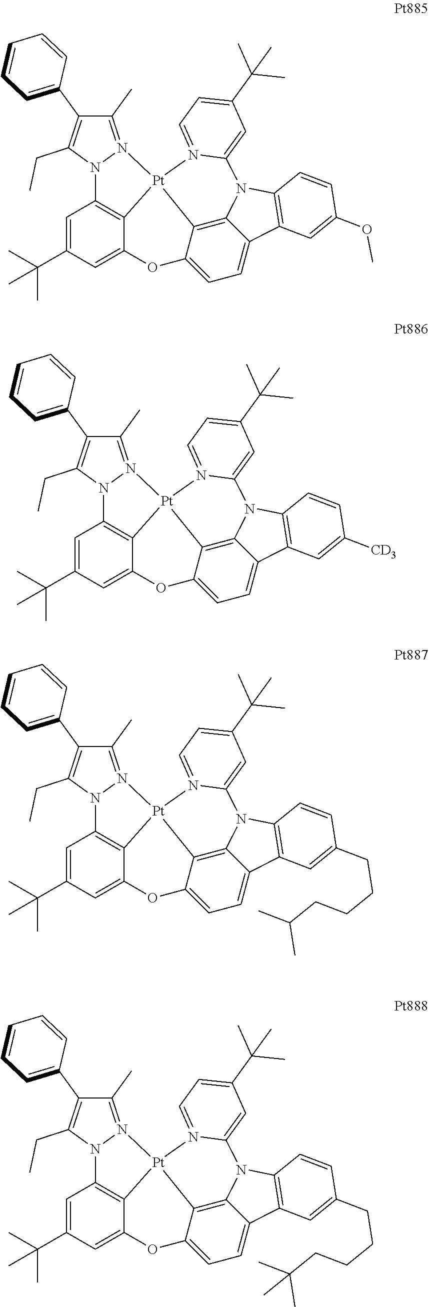

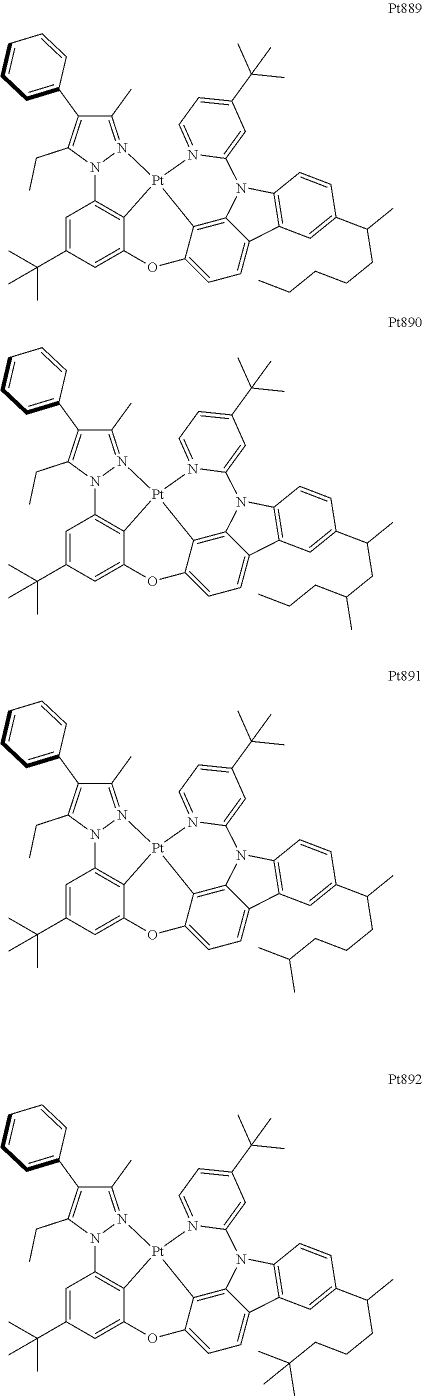

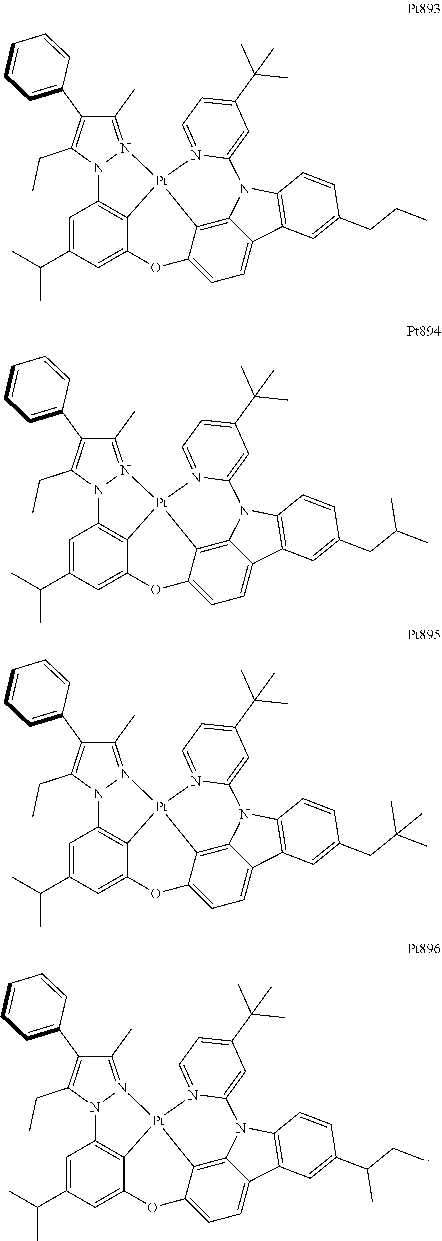

Preferably, the tetradentate cyclic-metal platinum complex comprising 6-substituted carbazole provided in some embodiments of the present disclosure is electrically neutral.

An embodiment of the present disclosure also provides a method for preparing a tetradentate cyclic-metal platinum complex comprising 6-substituted carbazole, the complex is synthesized by using the following chemical reaction steps:

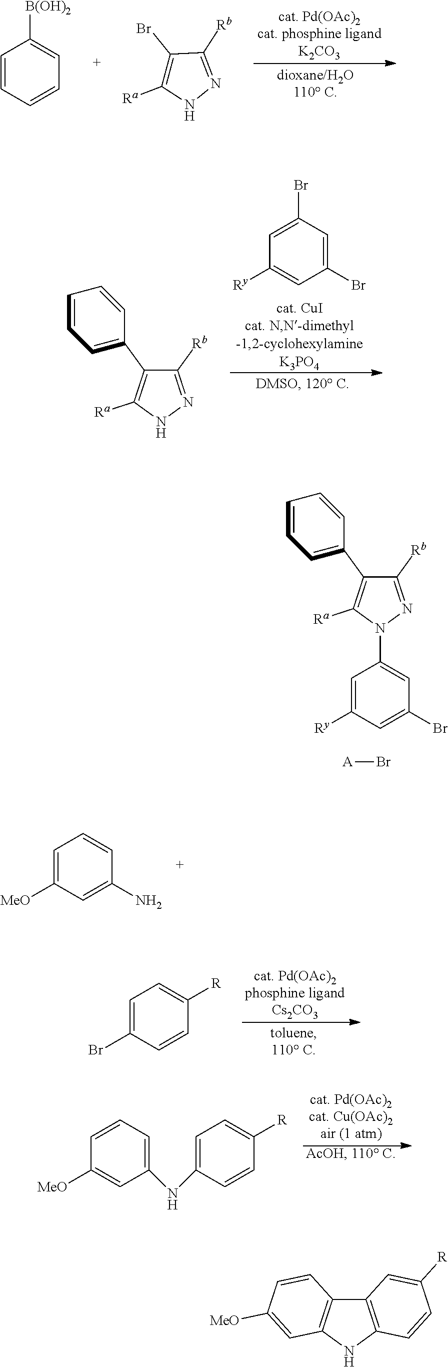

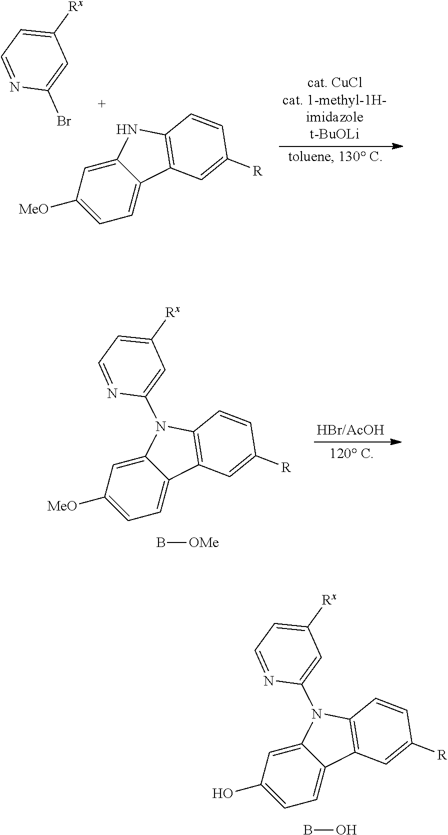

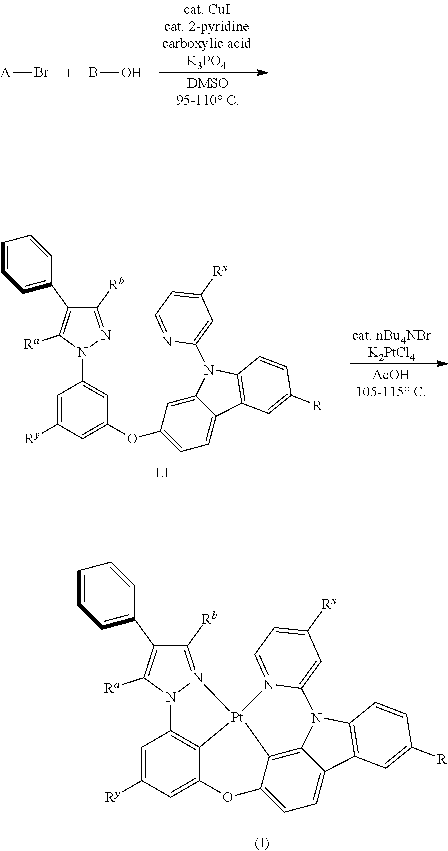

An embodiment of the present disclosure also provides the tetradentate cyclic-metal platinum complex comprising 6-substituted carbazole for using in the organic electroluminescent materials.

An embodiment of the present disclosure also provides an optical or electro-optical device, which comprises one or more tetradentate cycli-metal platinum complex comprising 6-substituted carbazole described above.

Preferably, the optical or electrical-optical device provided by some embodiments of the present disclosure comprises a light absorbing unit (such as solar device or photosensing device), an organic light emitting diodes (OLED), a light emitting device or a device that is capable of light-absorbing and light-emitting.

Preferably, the tetradentate cycli-metal platinum complex comprising 6-substituted carbazole provided by some embodiments of the present disclosure has 100% of internal quantum efficiency in the optical or electrical-optical device.

An embodiment of the present disclosure also provides an OLED device, wherein luminescent material or host material in the OLED device comprises one or more tetradentate cyclic-metal platinum complex comprising 6-substituted carbazole. The complex provided by some embodiments of the present disclosure can be used as either host material for OLED devices, such as in panchromatic display etc; or luminescent material for OLED devices, such as light-emitting device and display etc.

With respect to the prior art, the present disclosure provides a blue phosphorescent material based on 6-substited carbazole tetradentate cyclic-metal platinum complex, which may be delayed fluorescence and/or phosphorescent emitter. The complex provided by some embodiments of the present disclosure has the following characteristics: 1) the 6-substituent in the carbazole ring has never reported in the literature. Due to the HOMO orbital of the whole molecule are focused on carbazole and benzene ring connected to the metal platinum, the introduction of a substituent at the 6-position on the carbazole ring can effectively regulate the HOMO orbital energy level of the molecule, thereby regulating the triplet energy level and light physical property of the molecule;

2), the thermal stability of the molecule is greatly improved by introducing substituents at 3,4,5-position of the pyrazole; the electron donating substituent at 6-position of the carbazole ring can enhance the coordination ability of the ligand, and further improve the stability of the complex; The thermal decomposition temperatures are all above 400° C., which is much higher than the thermal evaporation temperature of the material during producing the device (generally no higher than 300° C.), and is beneficial to the commercial application of materials; 3), by introducing a large sterically hindered substituent other than a hydrogen atom at 3,5-position of the pyrazole, the conjugation between the pyrazole ring and its 4-position benzene ring is weakened, so that the whole light-emitting molecule has a higher minimum triplet energy level, make it has blue light emitting; At the same time, it can enhance molecular rigidity, effectively reduce the energy consumed by the molecular vibration, and improve the quantum efficiency of the luminescent material; 4), by controlling the position and type of substituent on the pyridine ring, the emitting light has a narrow emission spectrum, and the maximum wavelength of the emitting light is between 440-450 nm, which is a deep blue phosphorescent luminescent material. Therefore, such phosphorescent materials have great application prospects in the field of blue light, especially deep blue phosphorescent material, the design provides a new way for the development of blue and deep blue phosphorescent materials, and is of great significant for the development and application of deep blue phosphorescent materials.

### BRIEF DESCRIPTION OF THE DRAWINGS

FIG. 1 shows the emission spectrum of the complex Pt29 in dichloromethane solution at room temperature and in 2-methyl tetrahydrofuran 77K;

FIG. 2 shows the original spectrum of thermogravimetric analysis of the complex Pt29;

FIG. 3 shows the emission spectrum of the complex Pt393 in dichloromethane solution at room temperature and in 2-methyl tetrahydrofuran 77K;

FIG. 4 shows the original spectrum of thermogravimetric analysis of the complex Pt393;

FIG. 5 shows the emission spectrum of the complex Pt116 in dichloromethane solution at room temperature and in 2-methyl tetrahydrofuran 77K;

FIG. 6 shows the original spectrum of thermogravimetric analysis of the complex Pt116;

FIG. 7 shows the emission spectrum of the complex Pt732 in dichloromethane solution at room temperature and in 2-methyl tetrahydrofuran 77K;

FIG. 8 shows the original spectrum of thermogravimetric analysis of the complex Pt732.

### DETAILED DESCRIPTION OF THE EXEMPLARY EMBODIMENTS

The present disclosure can be more easily understood by reference to the following detailed description and examples contained therein. Before the complexes, devices, and/or methods of the present disclosure are disclosed and described, it should be understood that they are not limited to a specific synthesis method (unless otherwise stated), or a specific reagent (unless otherwise stated), as this of course can be changed. It should also to be understood that the terms used in the present disclosure is for the purpose of describing a particular aspect, and is not intended to be limiting. Although any methods and materials similar or equivalent to those described herein can be used in the practice or experiment, the exemplary methods and materials are described below.

As used in the specification and the appended claims, the singular forms of “a”, “an”, and “the” include the plural referents, unless the context clearly indicated. Thus, for example, when referring to “components”, it means a mixture that may include two or more components.

As used herein, the terms “optional” or “optionally” means that the subsequently described event or circumstance may or may not occur, and that the description includes instances where the event or circumstance occurs and it does not occur.

The components that can be used to prepare the compositions of the present disclosure are disclosed, as well as the compositions themselves to be used in the methods disclosed in the present disclosure. These and other materials are disclosed in the present disclosure, and it should be understood that when the combination, subset, interaction, group and the like of these materials are disclosed, it is not specifically disclose each of the various individual and total combination and replacement of these complex, each is specifically intended and described in the present disclosure. For example, if specific complex are disclosed and discussed, and many modifications that can be made to many molecules comprising the complex are discussed, then various and every combinations and substitution of the complex are specifically contemplated and may be modified, and the modification may be performed, otherwise it will be specifically stated to the contrary.

Thus, if an example of a class of molecules A, B, and C, and a class of molecules D, E, and F, and a combination molecule A-D are disclosed, then even if each is not recorded separately, it also considered to disclose each individual and total expected meaning combination, A-E, A-F, B-D, B-E, B-F, C-D, C-E, and C-F. Likewise, any subset or combination of these is also disclosed. Thus, for example, it should consider and disclosure of groups A-E, B-F, and C-E. These concepts apply to all aspects of the disclosure, including but not limited to the steps of the method of preparing and using the complex. Therefore, if there are various additional steps that can be performed, it should be understood that, each of these additional steps can be performed in a specific embodiment of the method or a combination of the embodiments.

The linking atoms used in the present disclosure can connect two atoms, for example, N and

C groups. The linking atoms can optionally have other (if the bond allows) attached chemical moieties. For example, on the one hand, oxygen does not have any other chemical group attached, because once bonded to two atoms (i.e., N or C) valences have been satisfied. On the other hand, when carbon is a connecting atom, two additional chemical moieties can be attached to the carbon atom. Suitable chemical moieties include, but are not limited to, hydrogen, hydroxy, alkyl, alkoxy, ═O, halogen, nitro, amine, amide, mercapto, aryl, heteroaryl, cycloalkyl, and heterocyclyl.

The term “cyclic structure” or similar terms used herein means that any cyclic chemical structure, including but not limited to aryl, heteroaryl, cycloalkyl, cycloalkenyl, heterocyclyl, carbene, and N-heterocyclic carbene.

The term “substituted” as used herein is intended to encompass all allowable substituent of organic compounds. In a broad aspect, the allowable substituents include non-cyclic and cyclic, branched and unbranched, carbocyclic and heterocyclic, and aromatic and non-aromatic substituents of organic compounds. Illustrative substituents include, for example, those described below. For a suitable organic compound, the allowable substituent may be one or more, the same or different. For the purposes of the present disclosure, a heteroatom (e.g., nitrogen) can have a hydrogen substituent and/or any allowable substituent of organic compound according to the disclosure, which satisfies the valence bond of the heteroatom. The disclosure is not intended to impose any restrictions in any way on the use of substituents allowed by organic compounds. Likewise, the term “substitute” or “substituted” includes the implicit condition that such substitution is consistent with the atoms of the substituent and allowed valences of the substituent, and that the substitution results in a stable complex (e.g., the compound that will not be transformed spontaneously (such as by rearrangement, cyclization, elimination etc.)). It also contemplated that, in some aspects, individual substituents can be further optionally substituted (i.e., further substituted or unsubstituted), unless explicitly stated otherwise.

In defining various terms, “R¹”, “R²”, “R³” and “R⁴” are used as general symbols in the present disclosure to indicate various specific substituents. These symbols can be any substituent, not limited to those disclosed herein, and they are limited to some substituents in one case, they may be limited to other substituents in other cases.

The term “alkyl” as used herein is a branched or unbranched 1 to 24 carbon atoms of saturated hydrocarbon, such as methyl, ethyl, n-propyl, isopropyl, n-butyl, isobutyl, sec-butyl, tert-butyl, n-pentyl, isopentyl, sec-amyl, neopentyl, hexyl, heptyl, hemiyl, nonyl, decyl, dodecyl, tetradecyl, hexadecyl, eicosyl, tetracosyl, etc. the alkyl can be cyclic or noncyclic. The alkyl may be branched or unbranched. The alkyl can also be substituted or unsubstituted. For example, the alkyl may be substituted with one or more groups, including but not limited to, optionally substituted herein alkyl, cycloalkyl, alkoxy, amino, ether, halogen, hydroxy, nitro, silyl, sulfo-OXO, or thiol. “a lower alkyl” means an alkyl containing 1 to 6 (e.g., 1 to 4) carbon atoms.

Throughout the specification, “alkyl” is usually used to refer to both unsubstituted alkyl and substituted alkyl; however, substituted alkyl is also specifically mentioned in the present disclosure by determining the specific substituent on the alkyl. For example, the term “halogenated alkyl” or “haloalkyl” specifically refers to an alkyl substituted with one or more halogens (e.g., fluorine, chlorine, bromine, or iodine). The term “alkoxyalkyl” specifically refers to an alkyl substituted with one or more alkoxy, as described below. The term “alkylamino” specifically refers to an alkyl substituted with one or more amino, as described below, and the like. When “alkyl” is used in one instance and a specific term such as “alkyl alcohol” is used in another instance, it is not meant to imply that the term “alkyl” does not refer to specific term such as “alkyl alcohols” and the like.

This practice is also applied to other groups described in the present disclosure. That is, when a term such as “cycloalkyl” refers to both unsubstituted and substituted cycloalkyl moieties, the substituted moieties may be determined additionally in the present disclosure; for example, a specifically substituted cycloalkyl may be called “alkylcycloalkyl”. Similarly, substituted alkoxy may be specifically referred to as, for example, “halogenated alkoxy”, and a specific substituted alkenyl may be “enol” etc. Likewise, the practice of using general terms such as “cycloalkyl” and specific terms such as “alkylcycloalkyl” is not intended to imply that the general term does not include the specific term at the same time.

The term “cycloalkyl” as used herein, is a non-aromatic carbon-based ring consisting of at least three carbon atoms. Examples of cycloalkyl include, but ar not limited to, cyclopropyl, cyclobutyl, cyclopentyl, cyclohexyl, cyclononyl, and the like. The term “heterocycloalkyl” is a kind of cycloalkyl as defined above, and is included in the meaning of the term “cycloalkyl”, wherein at least one ring carbon atom is a heteroatom such as, but not limited to, nitrogen, oxygen, sulfur, or phosphorus substitution. The cycloalkyl and heterocycloalkyl may be substituted or unsubstituted. The cycloalkyl and heterocycloalkyl may be substituted with one or more groups, including but not limited to, as described herein alkyl, cycloalkyl, alkoxy, amino, ether, halogen, hydroxy, nitro, silyl, sulfo-OXO, or thiol.

The term “alkoxy” and “alkoxy group” are used herein to refer to an alkyl or cycloalkyl bonded through an ether linkage; i.e., “alkoxy” may be defined as —OR¹, wherein R¹ is an alkyl or cycloalkyl as defined above. “alkoxy” also includes a polymer of the alkoxy just described; i.e., an alkoxy can be a polyether such as —OR¹OR² or —OR¹—(OR²)ₐ—OR³, wherein “a” is an integer from 1 to 200, and R¹, R², and R³ each are alkyl, cycloalkyl, independently, or a combination thereof.

As used herein, the term “alkenyl” is a hydrocarbyl of 2 to 24 carbon atoms, whose structural formula contains at least one carbon-carbon double bond. Asymmetric structures such as (R¹R²)C═C(R³R⁴) are intended to contain the E and Z isomers. It can be presumed that in structural formula of the present disclosure, there is an asymmetric olefin, or it can be explicitly expressed by the bond symbol C═C. The alkenyl may be substituted with one or more groups, including but not limited to, as described herein alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxyl, ketone, azide, nitro, silyl, sulfo-OXO, or thiol.

The term “cycloalkenyl” as used herein, is a non-aromatic carbon-based ring that consists of at least 3 carbon atoms, and contains at least one carbon-carbon double bond, i.e., C══C. Examples of cycloalkenyl include, but not limited to, cyclopropenyl, cyclobutenyl, cyclopentenyl, cyclopentadienyl, cyclohexenyl, cyclohexadienyl, norbornenyl etc. The term “heterocycloalkenyl” is a cycloalkenyl as defined above, and in included in the meaning of the term “cycloalkenyl”, wherein at least one of the carbon atoms of the ring is heteroatom such as but not limited to nitrogen, oxygen, sulfur, or phosphorus replace. Cycloalkenyl and heterocycloalkenyl may be substituted or unsubstituted. The cycloalkenyl and heterocycloalkyl may be substituted with one or more groups, including but not limited to, alkyl, cycloalkyl, alkoxy, alkenyl, cycloalkenyl, alkyne, cycloalkynyl, aryl, heteroaryl, aldehyde, amino, carboxylic acid, ester, ether, halogen, hydroxy, ketone, azide, nitro, silyl, sulfo-OXO, or thiol, as described herein.

As used herein, the term “alkynyl” is a hydrocarbon radical having 2 to 24 carbon atoms, which has a structure containing at least one carbon-carbon triple bond. An alkynyl can be unsubstituted or substituted with one or more groups, including but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxy, ketone, azide, nitro, silyl, sulfo-OXO, or thiol, as described herein.

The term “cycloalkynyl” as used herein, is a non-aromatic carbon-based ring that contains at least seven carbon atoms and contains at least one carbon-carbon triple bond. Examples of cycloalkynyl include but not limited to, cycloheptynyl, cyclooctynyl, cyclodecynyl, and the like.

The term “heterocycloalkynyl” is a cycloalkenyl as defined above, and included in the meaning of the term “cycloalkynyl” wherein at least one of the carbon atoms of the ring is replaced by heteroatom, the heteroatom such as but not limited to nitrogen, oxygen, sulfur, or phosphorus replace. Cycloalkenyl and heterocycloalkenyl may be substituted or unsubstituted. The cycloalkenyl and heterocycloalkyl may be substituted with one or more groups, including but not limited to, alkyl, cycloalkyl, alkoxy, alkenyl, cycloalkenyl, alkyne, cycloalkynyl, aryl, heteroaryl, aldehyde, amino, carboxylic acid, ester, ether, halogen, hydroxy, ketone, azide, nitro, silyl, sulfo-OXO, or thiol, as described herein.

The term “aryl” as used herein, is a group that contains any carbon-based aromatic group, including but not limited to, benzene, naphthalene, phenyl, biphenyl, phenoxy benzene, and so on.

The term “aryl” also includes “heteroaryl”, which is defined as a group containing an aromatic group having at least one heteroatom introduced into the ring of an aromatic group. Examples of heteroatoms include but are not limited to, nitrogen, oxygen, sulfur and phosphorous. The term “non-heteroaryl” (which is also included in the term “aryl”) defines an aromatic group, which does not contain a heteroatom. The aryl may be substituted or unsubstituted. An aryl may be substituted with one or more groups including but not limited to, as described herein, alkyl, cycloalkyl, alkoxy, alkenyl, cycloalkenyl, alkynyl, cycloalkynyl, aryl, heteroaryl, aldehyde, amino, carboxyl, ester, ether, halogen, hydroxy, keto, azide, nitro, silyl, thio-oxo, or sulfydryl. The term “biaryl” is a specific type of aryl and in included in the definition of “aryl”. Biaryl refers to two aryl bonded together via a fused ring structure, as in naphthalene, or two aryl linked via one or more carbon-carbon bonds, as in biphenyl in the same way.

The term “amine” or “amino” as used herein, is represented by the formula —NR¹R², wherein R¹ and R² can be independently selected from hydrogen, alkyl, cycloalkyl, alkenyl, cycloalkenyl, alkynyl, cycloalkyne, aryl or heteroaryl.

The term “alkylamino” as used herein is represented by the formula —NH(-alkyl), wherein alkyl is as described herein. Representative examples including but not limited to, methylamino, ethylamino, propylamino, isopropylamino, butylamino, isobutylamino, (sec-butyl) amino, (tert-butyl)amino, amylamino, isoamylamino, (tert-armyl)amino, hexylamino, and the like.

The term “dialkylamino” as used herein is represented by the formula —NH(-alkyl)₂, wherein alkyl is as described herein. Representative examples including but not limited to, dimethylamino, diethylamino, dipropylamino, diisopropylamino, dibutylamino, diisobutylamino, di(sec-butyl)amino, di(tert-butyl)amino, dipentylamino, diisoamylamino, di(tert-amyl)amino, dihexylamino, N-ethyl-N-methylamino, N-methyl-N-propylamino, N-ethyl-N-propylamino, and the like.

The term “ether” as used herein is represented by the formula R¹OR², wherein R¹ and R² can be independently alkyl, cycloalkyl, alkenyl, cycloalkenyl, alkynyl, cycloalkynyl, aryl, or heteroaryl, as decribed herein. The term “polyether” as used herein is represented by the formula —(R¹O—R²O)ₐ—, wherein R¹ and R² can be independently alkyl, cycloalkyl, alkenyl, cycloalkenyl, alkynyl, cycloalkynyl, aryl, or heteroaryl, and “a” is an integer from 1 to 500. Examples of polyether groups include polyoxyethylene, polyoxypropylene, and polyoxybutylene.

The term “halogen” as used herein refers to halogen, for example fluoride, chlorine, bromine, and iodine.

The term “heterocyclyl” as used herein refers to both monocyclic and polycyclic non-aromatic ring systems, and “heteroaryl” as used herein refers to monocyclic and polycyclic aromatic ring system: wherein at least one of the ring members is not carbon. The term includes azetidinyl, dioxanyl, furyl, imidazolyl, isothiazolyl, isoxazolyl, morpholinyl, oxazolyl, oxazolyl including 1,2,3-oxazolyl, 1,2,5-oxadiazolyl and 1,3,4-oxadiazolyl, piperazinyl, piperidinyl, pyrazinyl, pyrazolyl, pyrazolyl, pyridazinyl, pyrindine, pyridinyl, pyrrolyl, pyrrolidinyl, tetrahydrofuranyl, tetrahydropyranyl, tetrazine including 1,2,4,5-tetrazinyl, tetrazolyl including 1,2,3,4-tetrazolyl and 1,2,4,5-tetrazolyl, thiadiazolyl including 1,2,3-thiadiazolyl, 1,2,5-thiadiazolyl and 1,2,5-thiadiazolyl, thiadiazolyl, thiazolyl, triazinyl including 1,3,5-triazinyl and 1,2,4-triazinyl, triazolyl including 1,2,3-triazolyl and 1,3,4-triazolyl, and so on.

The term “hydroxy” as used herein, is represented by the formula —OH.

The term “ketone” as used herein is represented by the formula R¹C(O)R², wherein R¹ and R² can be independently alkyl, cycloalkyl, alkenyl, cycloalkenyl, alkynyl, cycloalkynyl, aryl, or heteroaryl, as described herein.

The term “azido” as used herein is represented by the formula —N₃.

The term “nitro” as used herein is represented by the formula —NO₂.

The term “nitrile” as used herein is represented by the formula —CN.

The term “silyl” as used herein is represented by the formula —SiR¹R²R³, wherein R¹, R² and R³ can be independently hydrogen, or alkyl, cycloalkyl, alkoxy, alkenyl, cycloalkenyl, alkynyl, cycloalkynyl, aryl, or heteroaryl, as described herein.

The term “sulfur-oxo group” as used herein is represented by the formula —S(O)R¹, —S(O)₂R¹, —OS(O)₂R¹ or —OS(O)₂OR¹, wherein R¹ can be hydrogen, or alkyl, cycloalkyl, alkenyl, cycloalkenyl, alkynyl, cycloalkynyl, aryl, or heteroaryl, as described herein. Throughout this specification, “S(O)” is shorthand for S═O. The term “sulfonyl” as used herein refers to a sulfur-oxygen group represented by the formula —S(O)₂R¹, wherein R¹ may be alkyl, cycloalkyl, alkenyl, cycloalkenyl, alkyne, alkynyl, cycloalkynyl, aryl, or heteroaryl. The term “sulphone” as used herein is represented by the formula R¹S(O)₂R², wherein R¹ and R² can be independently alkyl, cycloalkyl, alkenyl, cycloalkenyl, alkynyl, cycloalkynyl, aryl, or heteroaryl, as decribed herein. The term “sulfoxide” as used herein is represented by the formula R'S(O)R², wherein R¹ and R² can be independently alkyl, cycloalkyl, alkenyl, cycloalkenyl, alkynyl, cycloalkynyl, aryl, or heteroaryl, as described herein.

The term “sulfydryl” used herein is represented by the formula —SH.

As used herein, “R′,” “R²,” “R³,” “Rⁿ” (wherein n is an integer) may independently have one or more of radicals listed above. For example, if R¹ is a linear alkyl, one of the hydrogen atoms of the alkyl may be optionally substituted with hydroxy, alkoxy, alkyl, halogen, and the like.

Depending on the selected group, the first group can be bound to the second group, or the first group can be pendant (i.e., attached) to the second group. For example. For the phrase “alkyl containing amino”, the amino may be incorporated within the backbone of the alkyl. Alternatively, amino can be connected to the backbone of the alkyl. The nature of the selected group will determine whether the first group is embedded or attached to the second group.

The complex described herein may contain “optionally substituted” moieties. In general, the term “substituted” (whether or not the term “optionally” precedes) means that the indicated portion of one or more hydrogens is replaced by a suitable substituent. Unless otherwise specified, an “optionally substituted” group may have a suitable substituent at each substitutable position of the group, and more than one may be substituted when there is more than one position in any given structure, when selected from the group of substituents, the substituents at each position may be the same or different. Combinations of substituents envisioned by the present disclosure are preferably those that form stable or chemically feasible complex. In certain aspects, unless clearly indicated to the contrary, it is also encompassed that each substituent may be further optionally substituted (i.e., further substituted or unsubstituted).

The structure of the complex can be represented by the following formula:

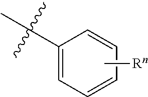

It is understood to be equivalent to the following formula:

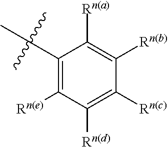

Wherein n is usually an integer. That is, Rⁿ is understood to represent five individual substituents R^{n(a)}, R^{n(b)}, R^{n(c)}, R^{n(d)}, R^{n(e)}. “Individual substituent” means each R may be independently defined. For example, if R^{n(a)} is halogen in one case, R^{n(b)} is not necessarily halogen in this case.

R¹, R², R³, R⁴, R⁵, R⁶ etc are mentioned several times in the chemical structures and moieties disclosed and described herein. Any description of R¹, R², R³, R⁴, R⁵, R⁶ etc in the specification is applicable to any structure or moieties cited R¹, R², R³, R⁴, R⁵, R⁶ etc, respectively, unless otherwise specified.

For many reasons, the use of organic materials of optoelectronic devices has become more and more urgent. Many of the materials used to make such devices are relatively inexpensive, so organic optoelectronic devices have the potential for cost advantages over inorganic devices. In addition, the inherent properties of organic materials, such as their flexibility, can make them very suitable for special applications such as manufacturing on flexible substrates. Examples of organic optoelectronic devices include organic light emitting devices (OLED), organic phototransistors, organic photovoltaic cells and organic photodetectors. For OLED, organic materials may have performance advantages over conventional materials. For example, the wavelength of light emitted by an organic light emitting layer can usually be easily tuned with a suitable dopant.

Excitons decay from a singlet excited state to a ground state to produce instant luminescence, which is fluorescence. If the exciton decays from the triplet excited state to the ground state to generate light emission, this is phosphorescent. Because of the spin-orbit coupling of heavey metal atoms between the singlet state and the triplet excited state, which effectively enhances intersystem crossing(ISC), phosphorescent metal complexes (e.g., platinum complexes) have shown their simultaneous using the potential of singlet and triplet excitons, 100% of internal quantum efficiency is achieved. Therefore, phosphorescent metal complexes are a good candidates for dopants in the emission layer of organic light emitting devices (OLED), and have received great attention in academic and industrial fields. In the past decade, it have made many achievements, resulting in a profitable commercialization of the technology, for example, OLED has been used for advanced displays of smart phones, a senior display of television and digital camera.

However, blue electroluminescent devices are still the most challenging areas of the technology by far, and the stability of blue devices is a big problem. It has been demonstrated that the choice of host material is very important for the stability of blue devices. However, the lowest energy of the triplet excited state (Ti) of the blue luminescent material is very high, which means that the lowest energy of the triplet excited state (Ti) of the host material of the blue device should be higher. This has led to an increased difficulty in the development of the host material of the blue device.

The metal complexes of the present disclosure can be customized or tuned to specific application that are expected to have specific emission or absorption characteristics. The optical properties of the metal complex in the disclosure can be adjusted by changing the structure of the ligand surrounding the metal center or changing the structure of the fluorescent light emitter on the ligand. For example, in emission and absorption spectra, metal complexes or electron withdrawing substituents having ligands that donate electrons can generally exhibit different optical properties. The color of the metal complex can be adjusted by modifying the conjugated group on the fluorescent emitter and the ligand.

The emission of such complex according to the present disclosure can be adjusted, for example, by changing the structure of the ligand or the fluorescence emitter, for example from ultraviolet to near infrared. Fluorescent light emitters are a group of atoms in organic molecules that can absorb energy to produce singlet excited state, and singlet excitons decay rapidly to produce immediate luminescence. On the one hand, the complexes of the present disclosure can provide emission of most visible spectrum. In a specific example, the complexes of the present disclosure can emit light in the range of about 400 nm to 700 nm. On the other hand, the complexes of the present disclosure have improved stability and efficiency compared with the traditional emission complexes. In addition, the complexes of the present disclosure can be used as a luminescent marker of emitters, or a combination thereof in such as biological application, an anticancer agent, an emitter in an organic light emitting diode (OLED). In another aspect, the complexes of the present disclosure may be used in light emitting devices, such as compact fluorescent lamps (CFL), light emitting diodes (LED), incandescent lamps and combinations thereof.

The disclosure discloses a platinum-containing compounds or complexes. The term compound or complex may be used interchangeably herein.

The complexes disclosed herein may exhibit desired properties and have emission and/or absorption spectra that can be modulated by selecting suitable ligands. In another aspect, the present disclosure may exclude any one or more of complexes, structures or moieties thereof specifically described herein.

The complexes of the present disclosure may be prepared by a variety of methods, including but not limited to those described in the examples provided herein.

The complexes disclosed herein may be delayed fluorescence and/or phosphorescent emitters. On the one hand, the complexes disclosed herein may be a delayed fluorescence emitter. On the other hand, the complexes disclosed herein may be a phosphorescent emitter. On the other hand, the complexes disclosed herein may be a fluorescence emitter and a phosphorescent emitter.

In one embodiment of the present disclosure, a tetradentate cyclic-metal platinum complex comprising 6-substituted carbazole is disclosed, the structure of the complex is shown in formula (I):

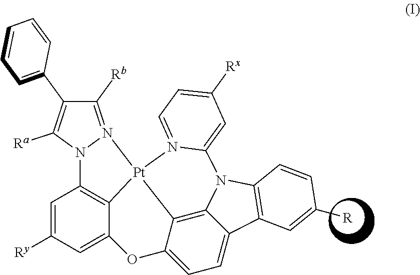

Wherein, R is alkyl, alkoxy, cycloalkyl, ether, heterocyclyl, aryl, heteroaryl, aryloxy, halogen, mono- or di-alkylamino, mono- or di-arylamino;

R^{a}, R^{b} each are alkyl, alkoxy, cycloalkyl, ether, heterocyclyl, hydroxy, aryl, heteroaryl, aryloxy, mono- or di-alkylamino, mono- or di-arylamino, halogen, sulfydryl, cyano independently and combination thereof;

R^{x} is alkyl, alkoxy, cycloalkyl, heterocyclyl, ether, mono- or di-alkylamino, mono- or di-arylamino, halogen, or combination thereof;

R^{y} is H, deuterium, alkyl, alkoxy, cycloalkyl, heterocyclyl, ether, mono- or di-alkylamino, mono- or di-arylamino, halogen, or combination thereof.

In one embodiment of the present disclosure, the structural unit

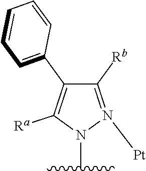

may independently represent the following structures, but are not limited to the following structures:

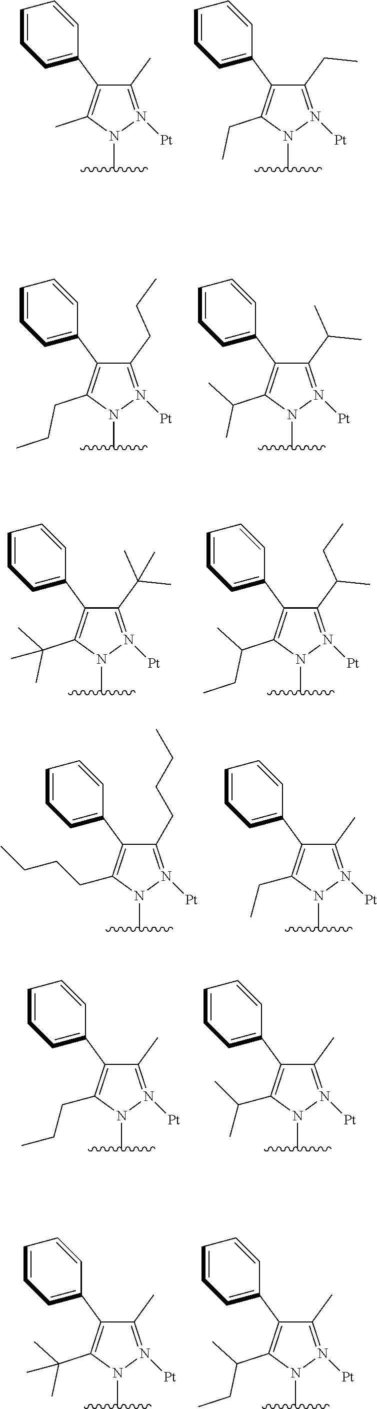

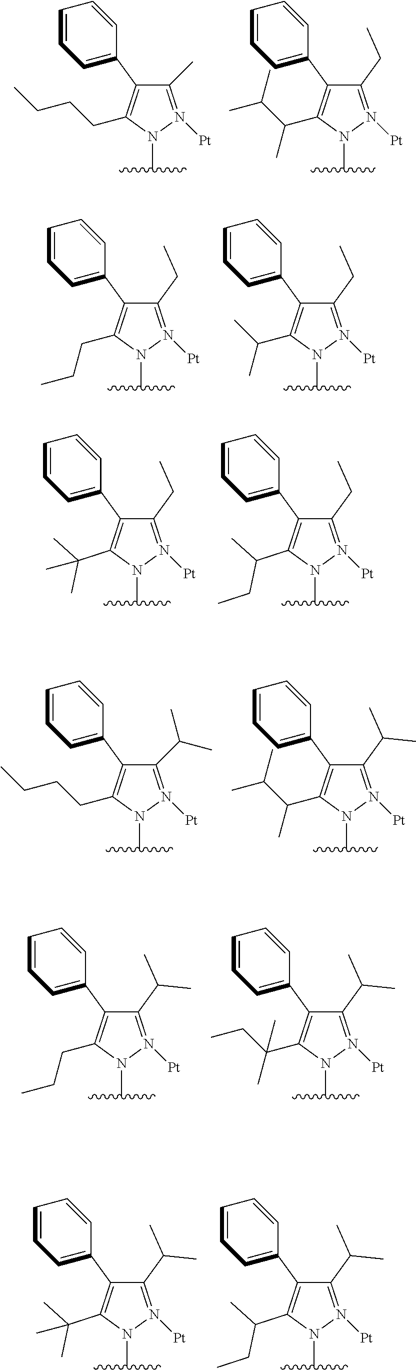

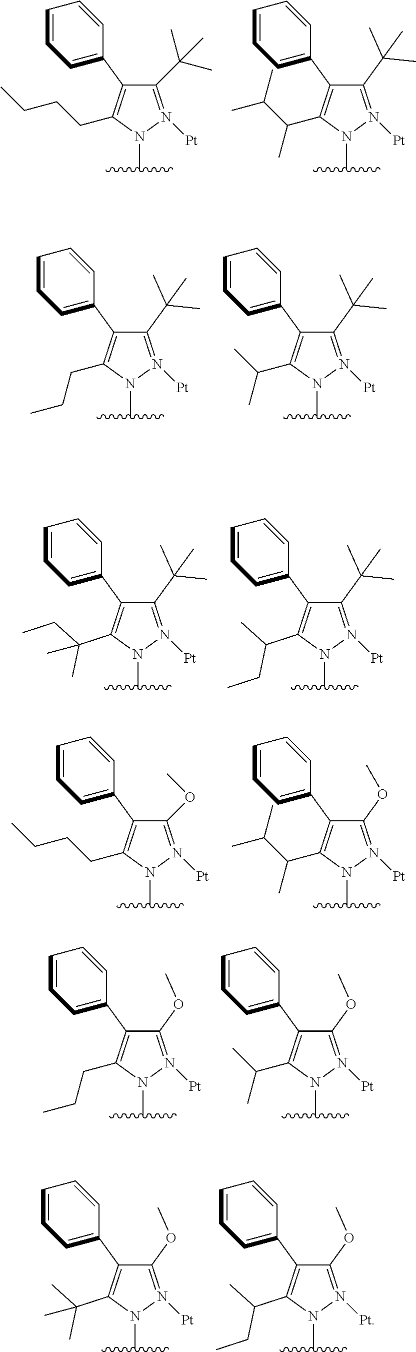

In one embodiment of the present disclosure, the tetradentate cyclic-metal platinum complex comprising 6-substituted carbazole disclosed has a structure selected from one of the followings:

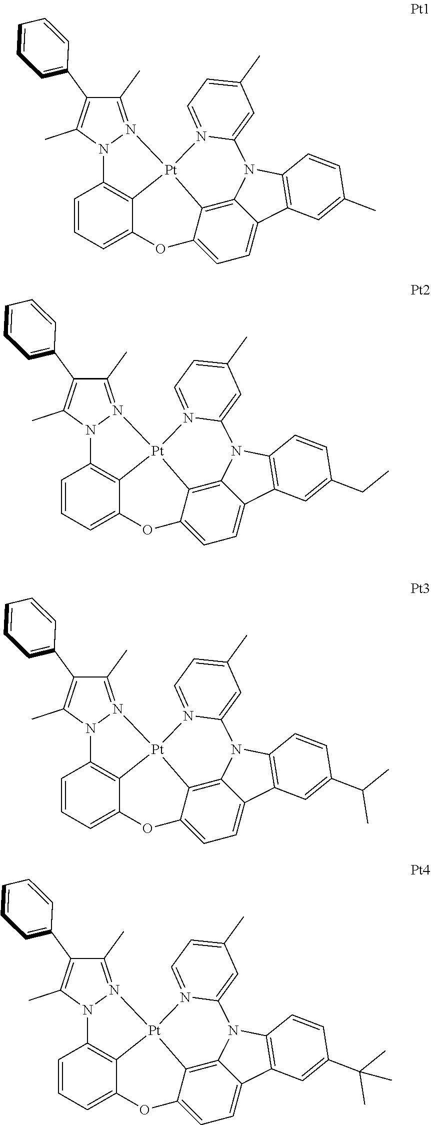

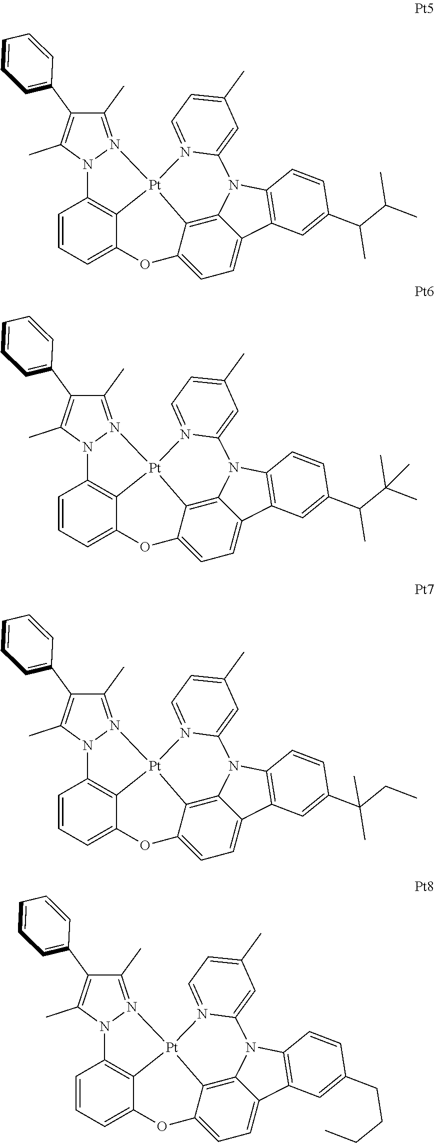

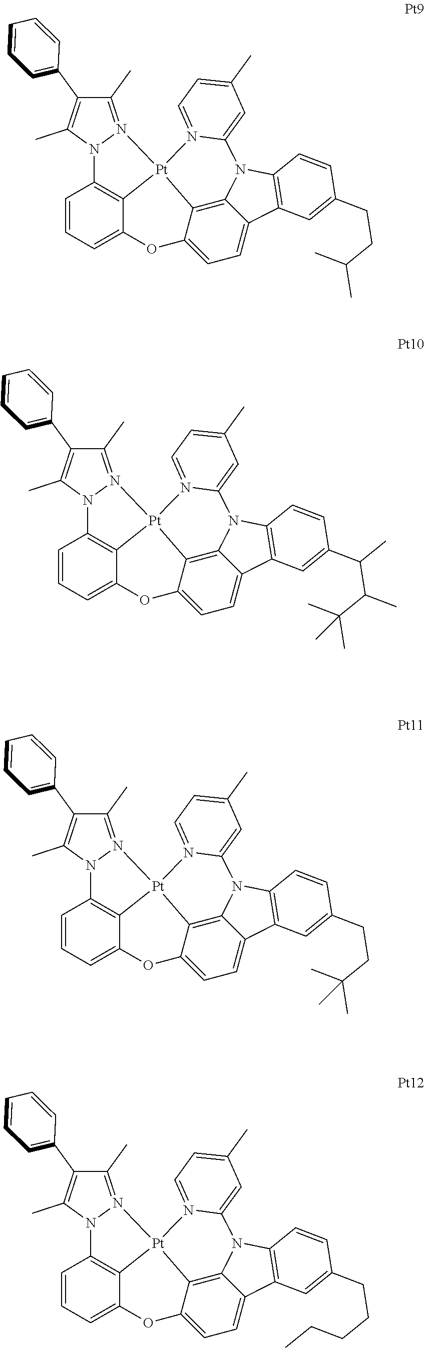

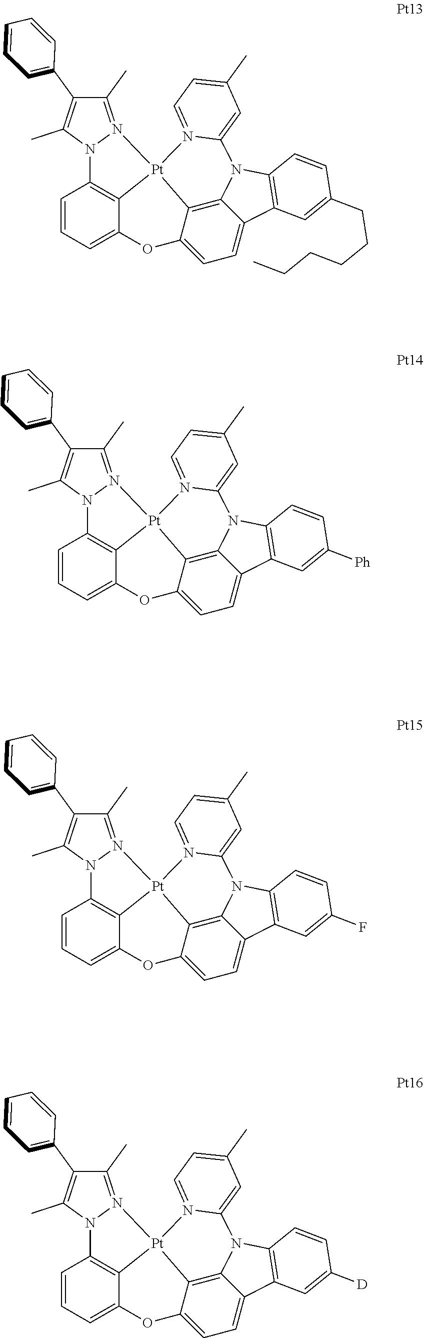

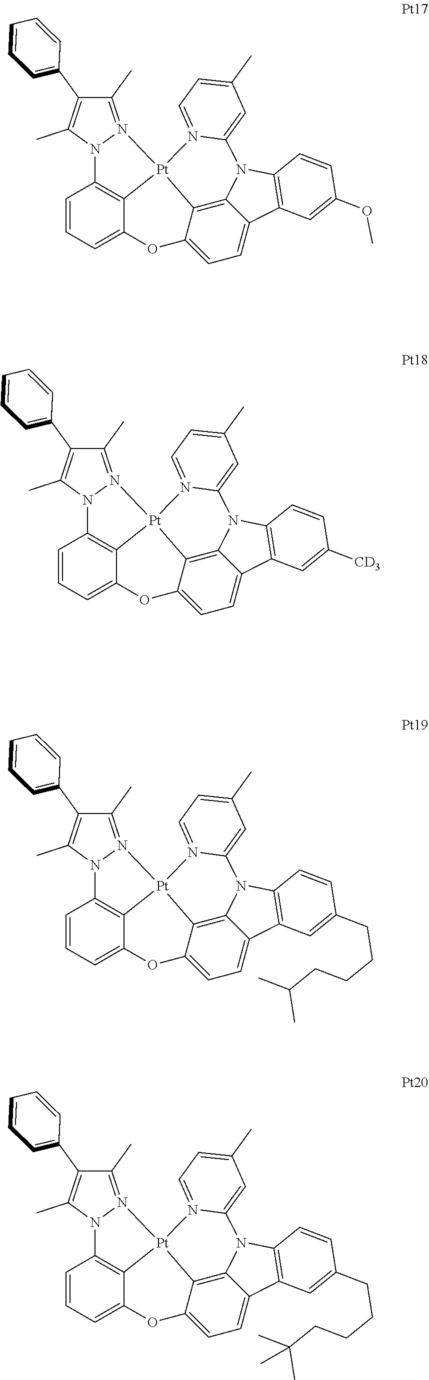

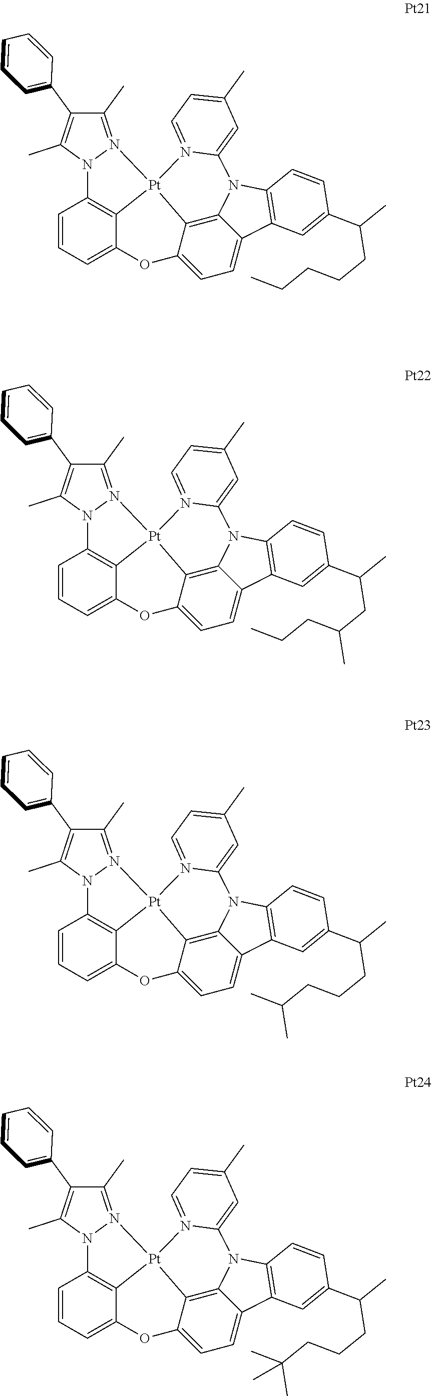

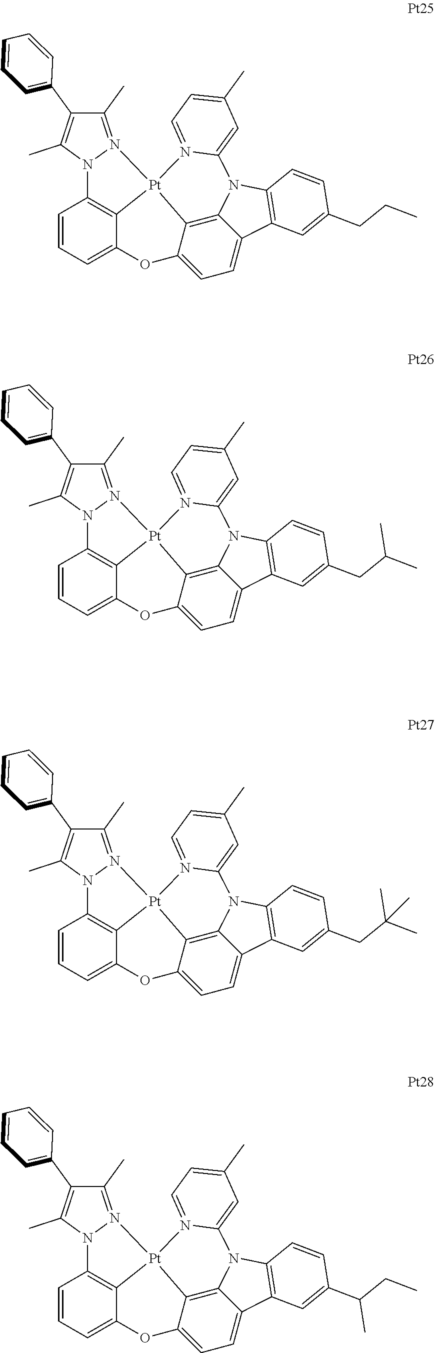

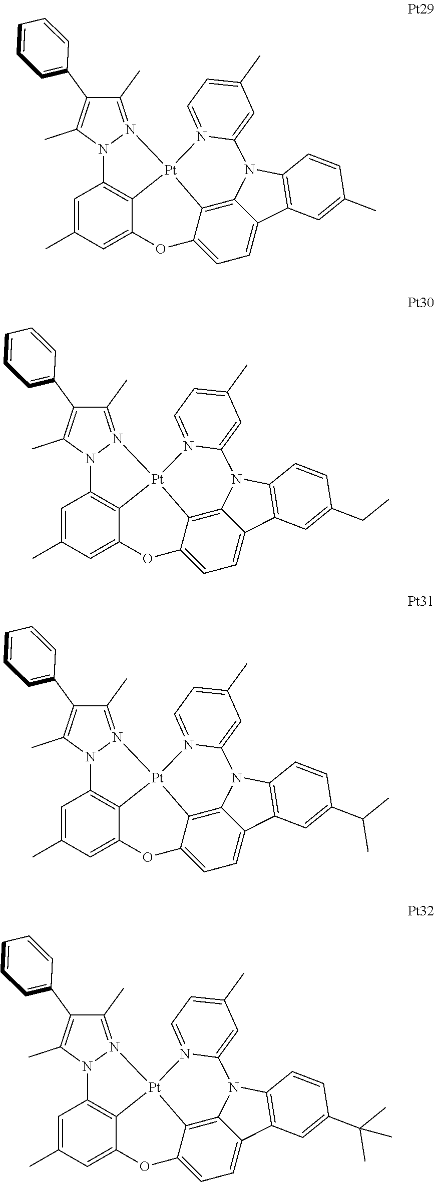

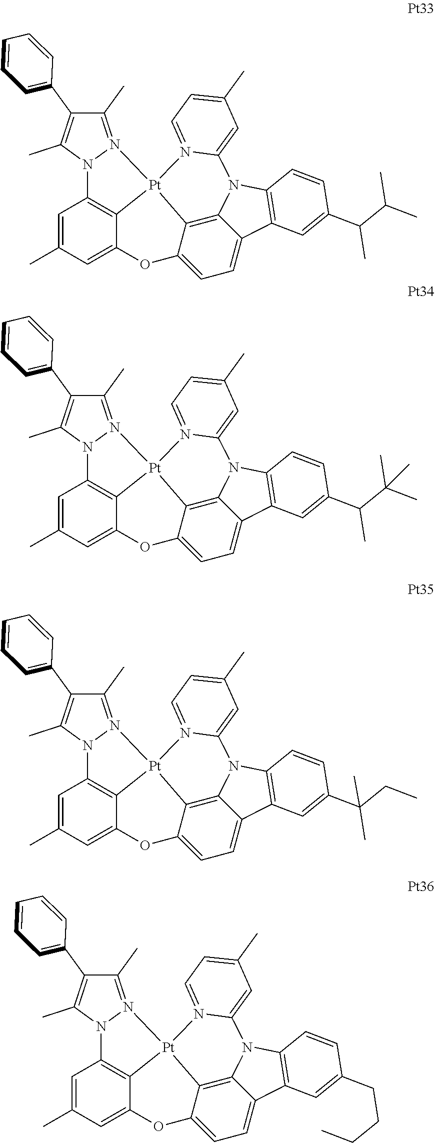

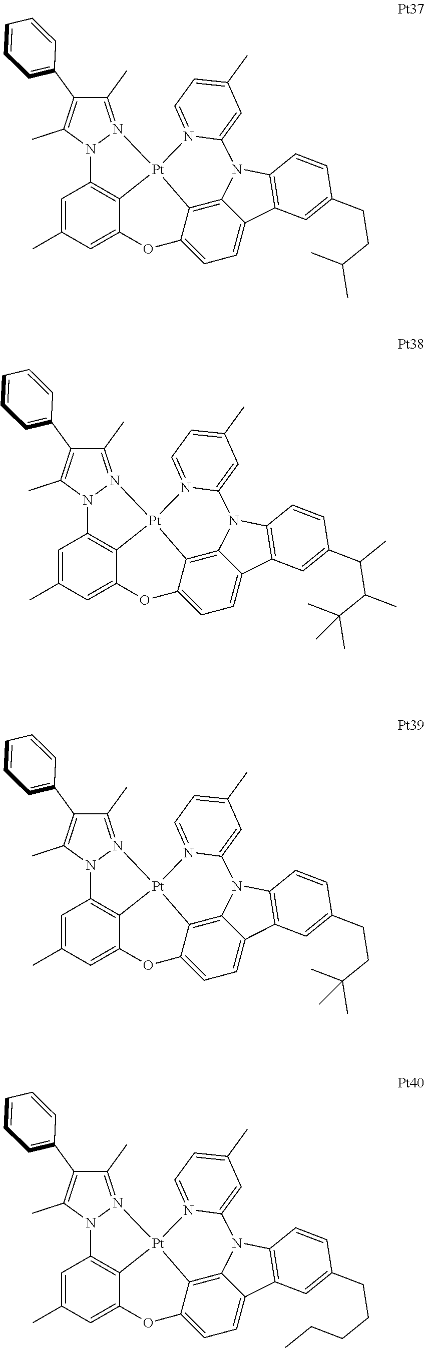

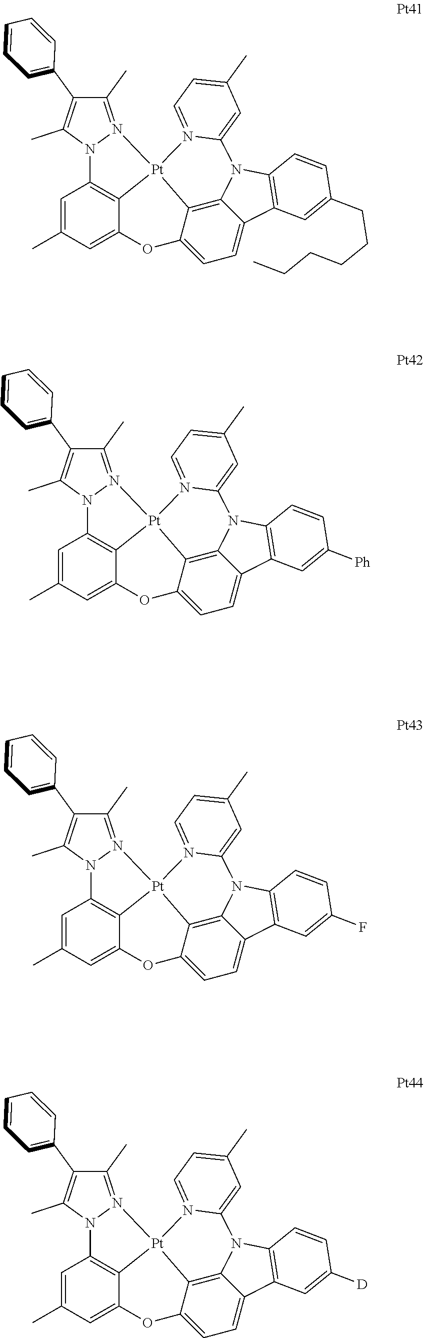

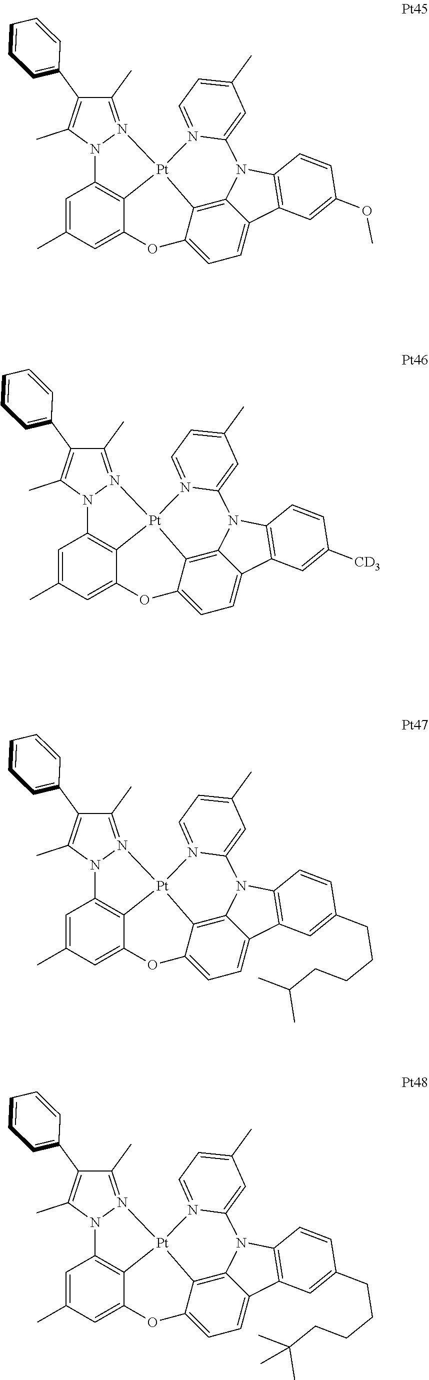

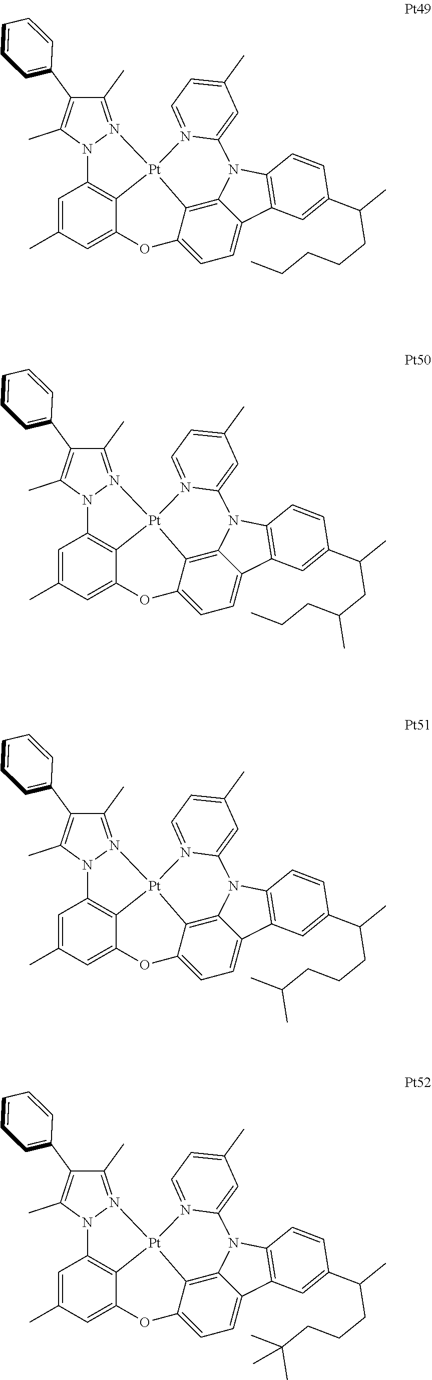

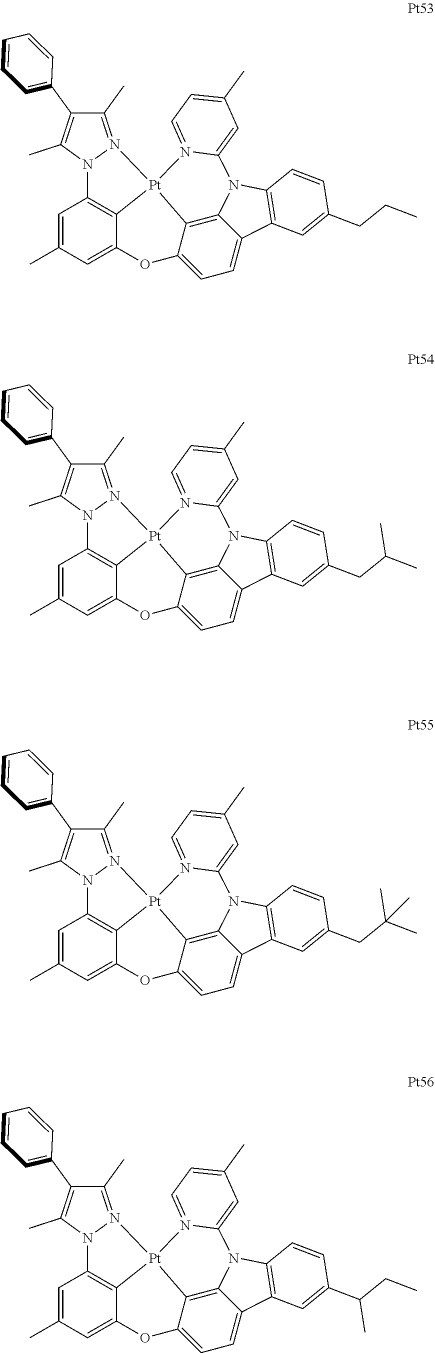

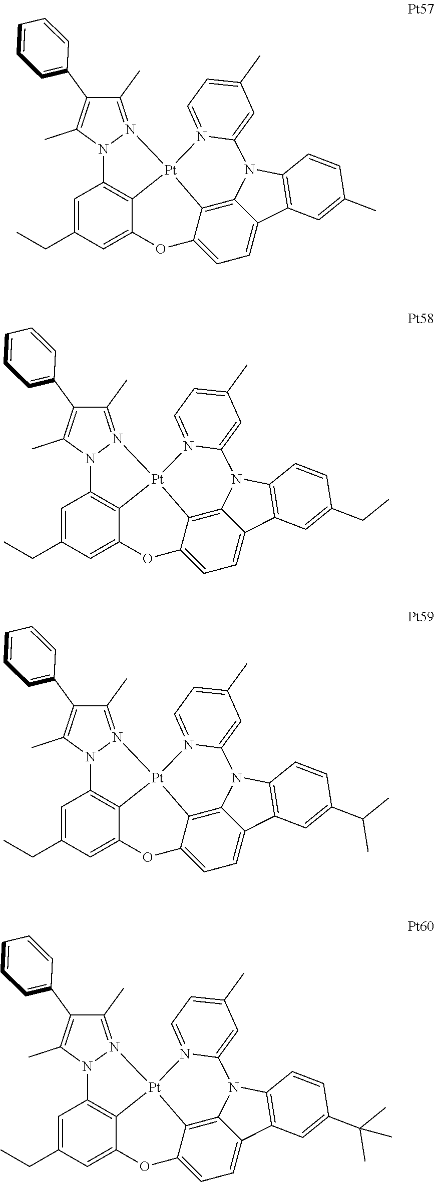

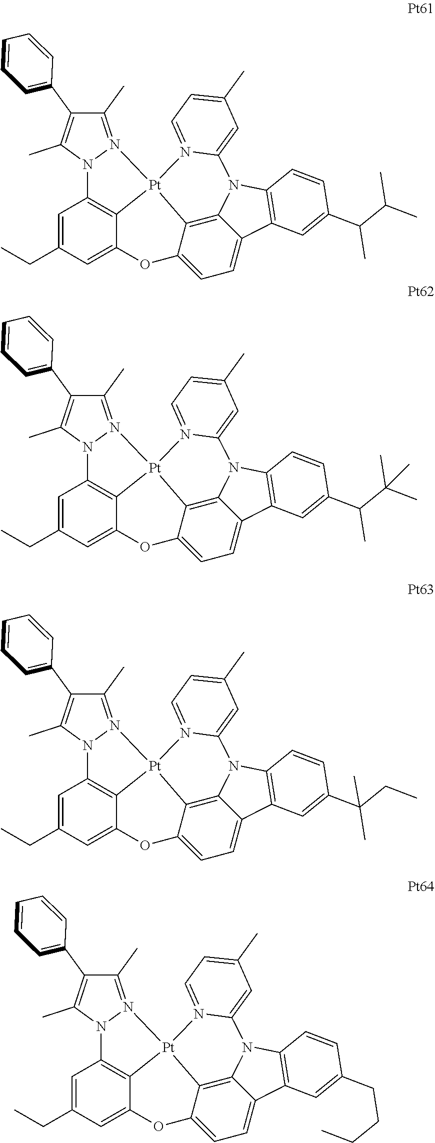

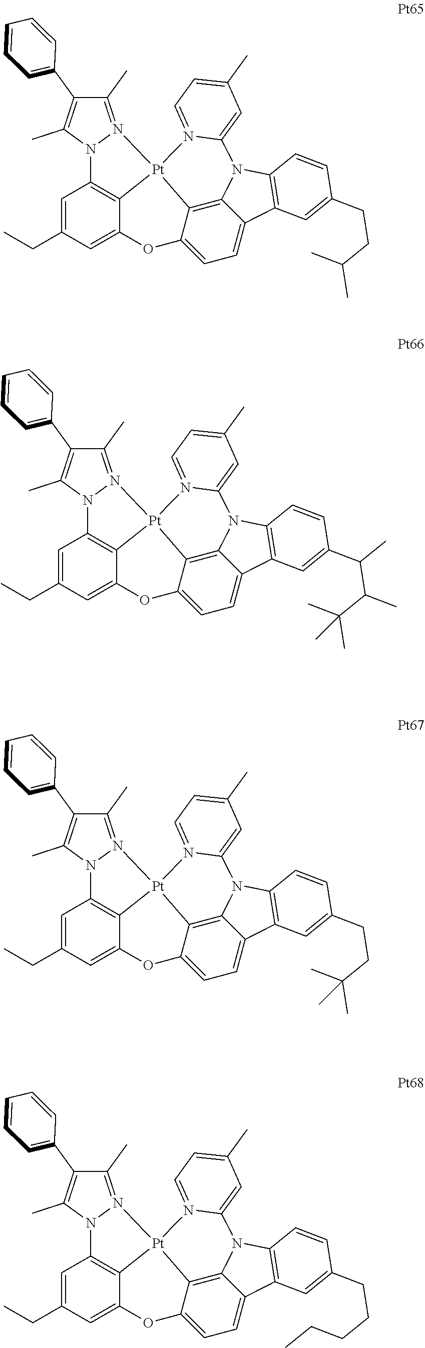

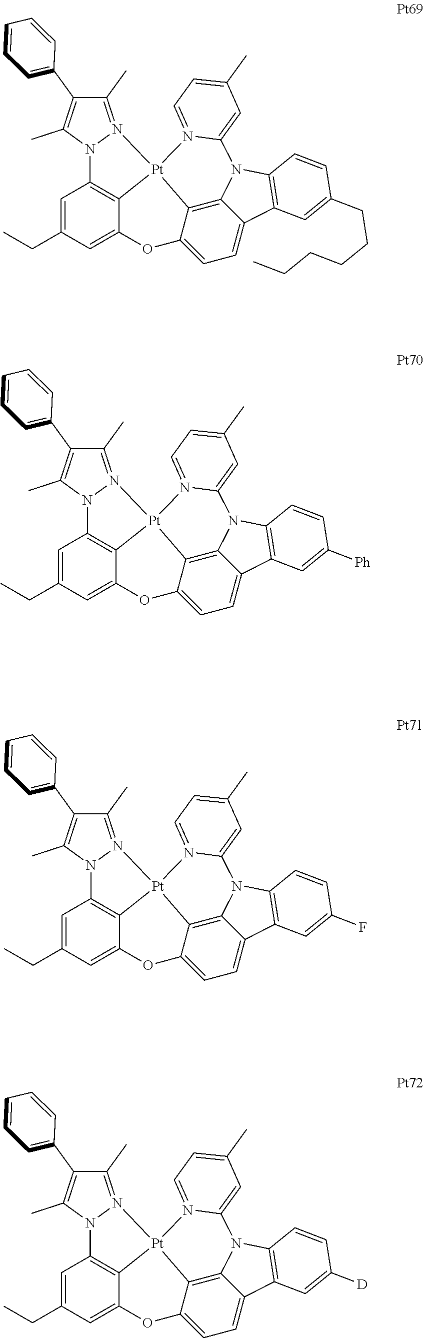

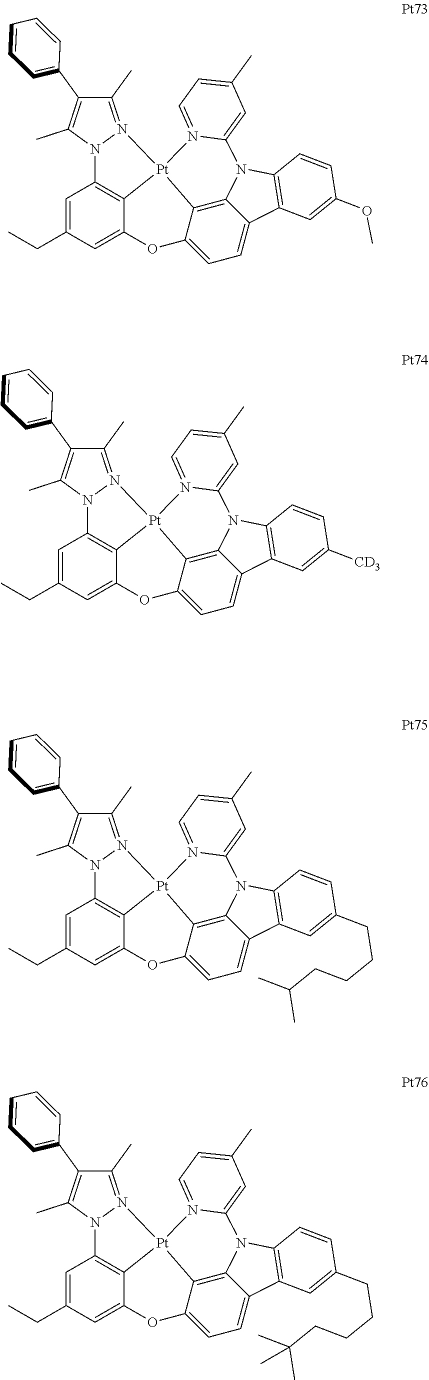

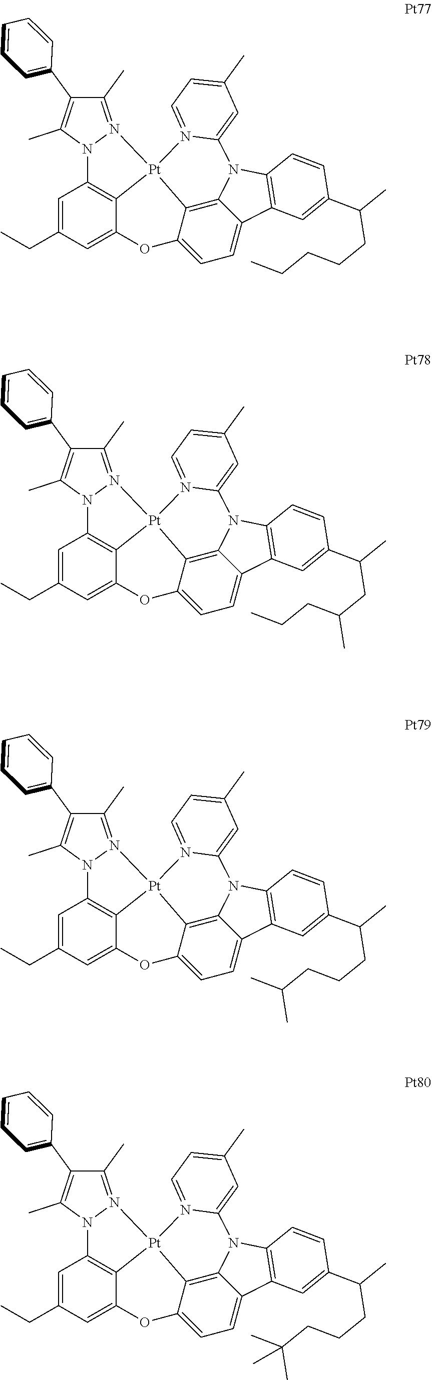

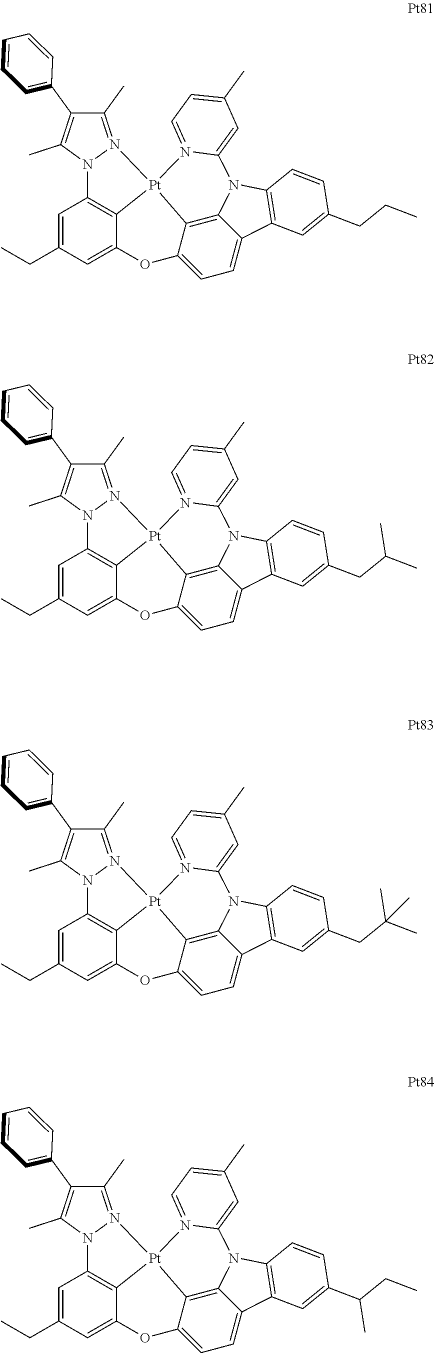

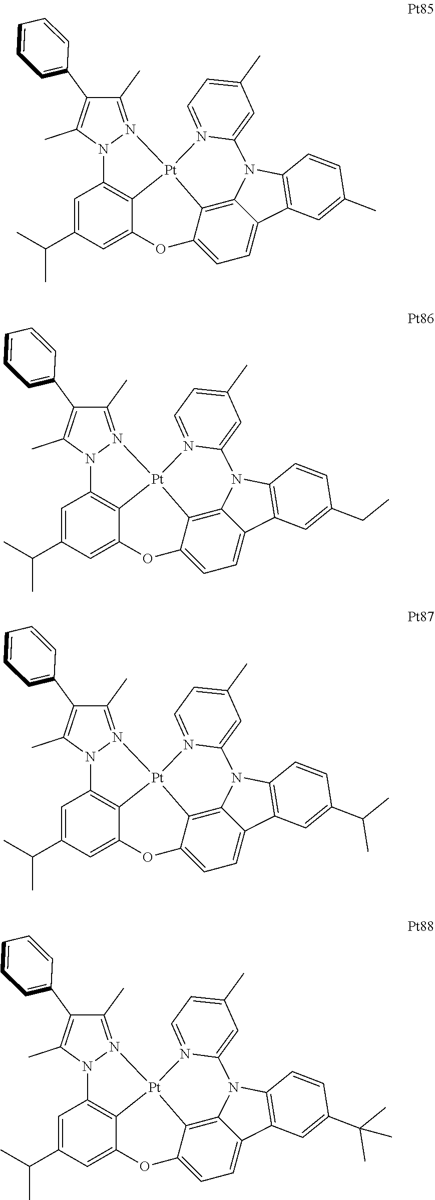

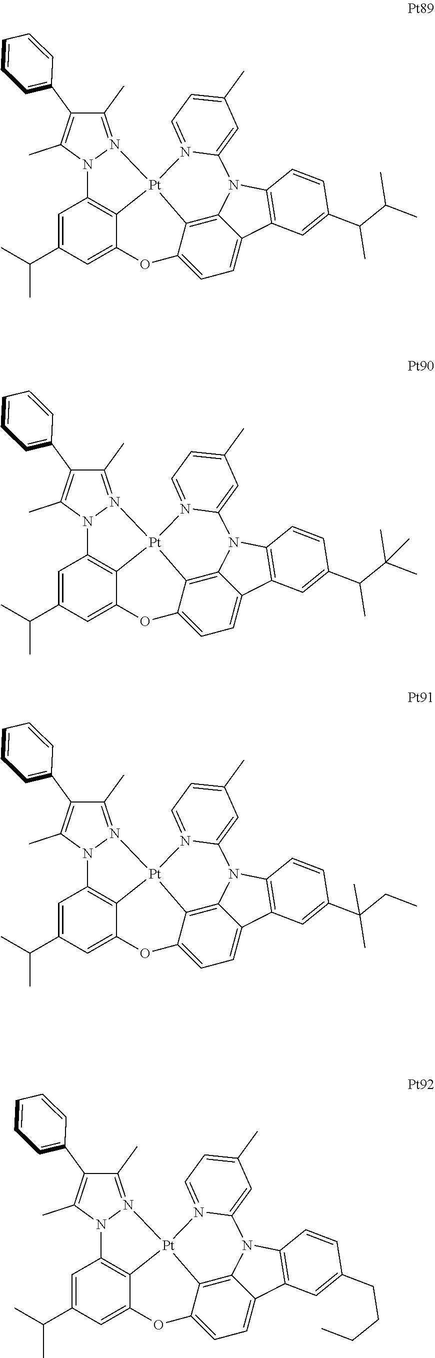

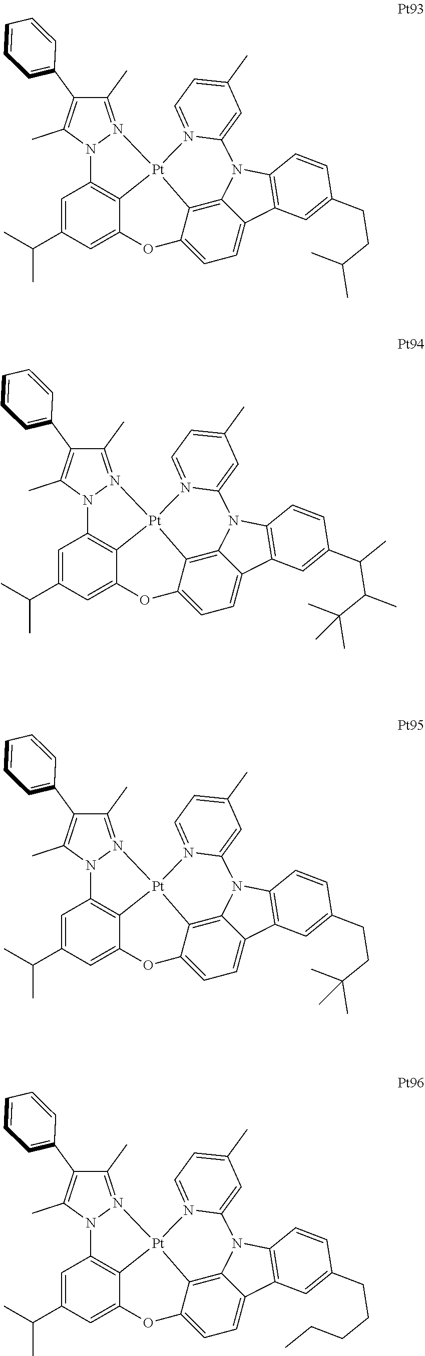

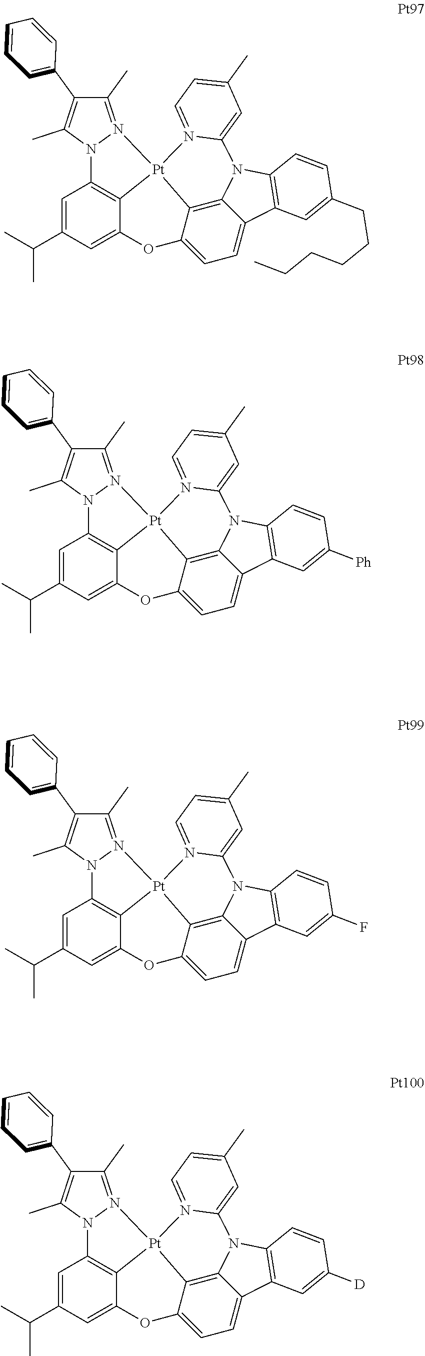

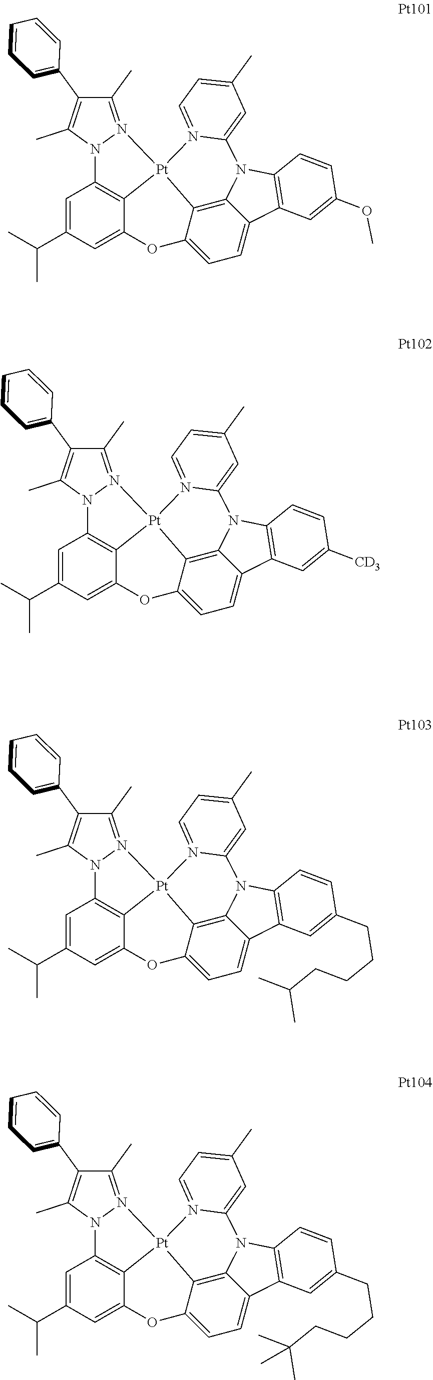

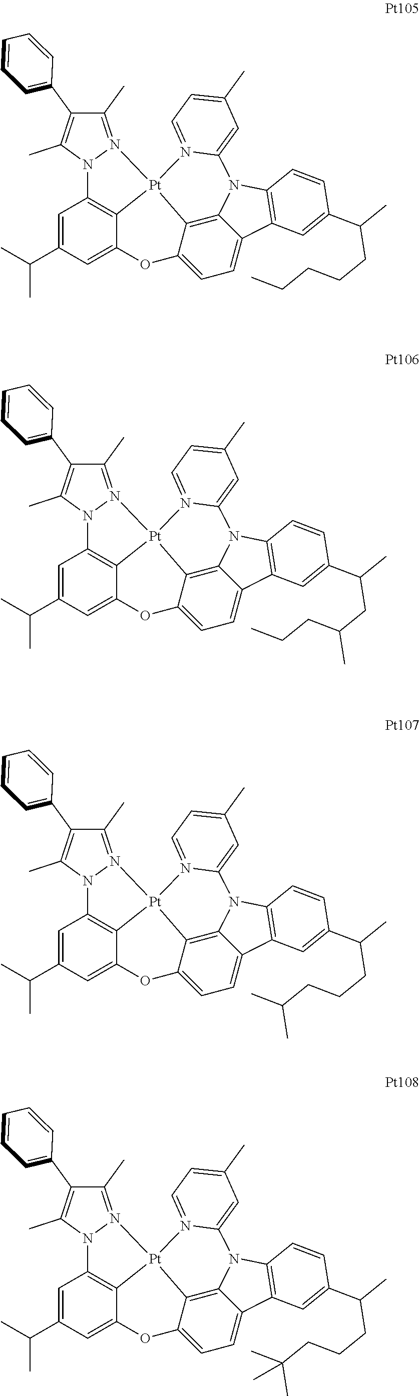

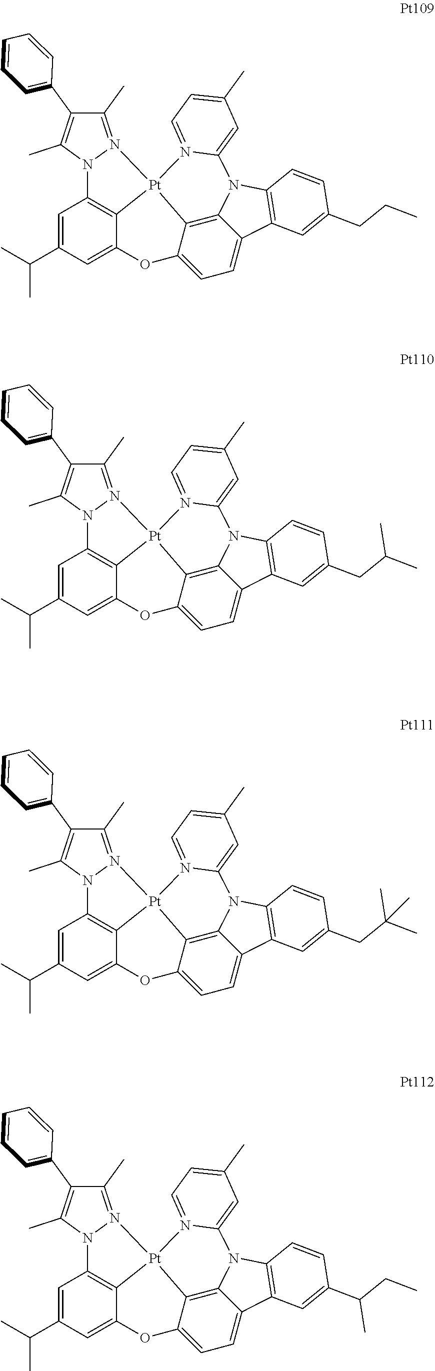

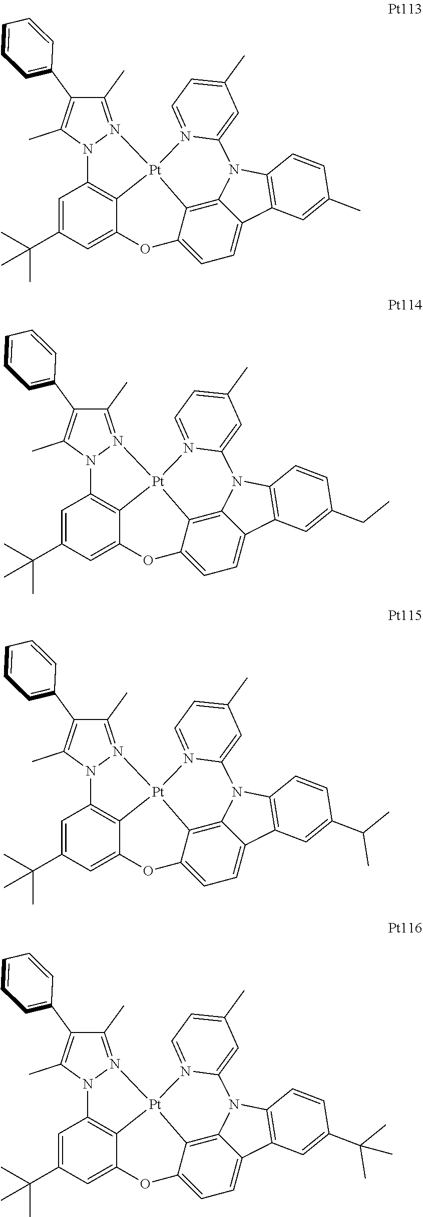

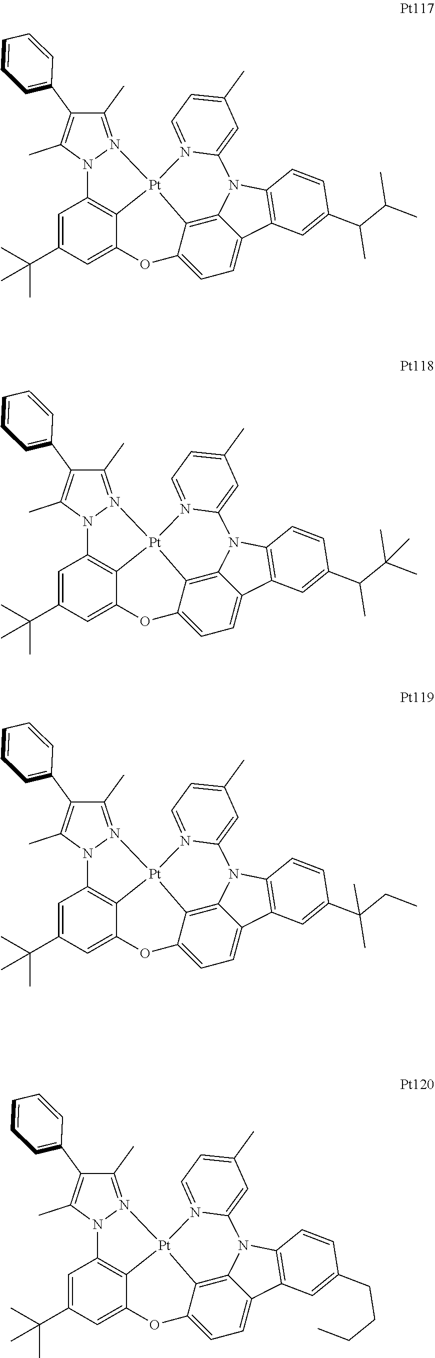

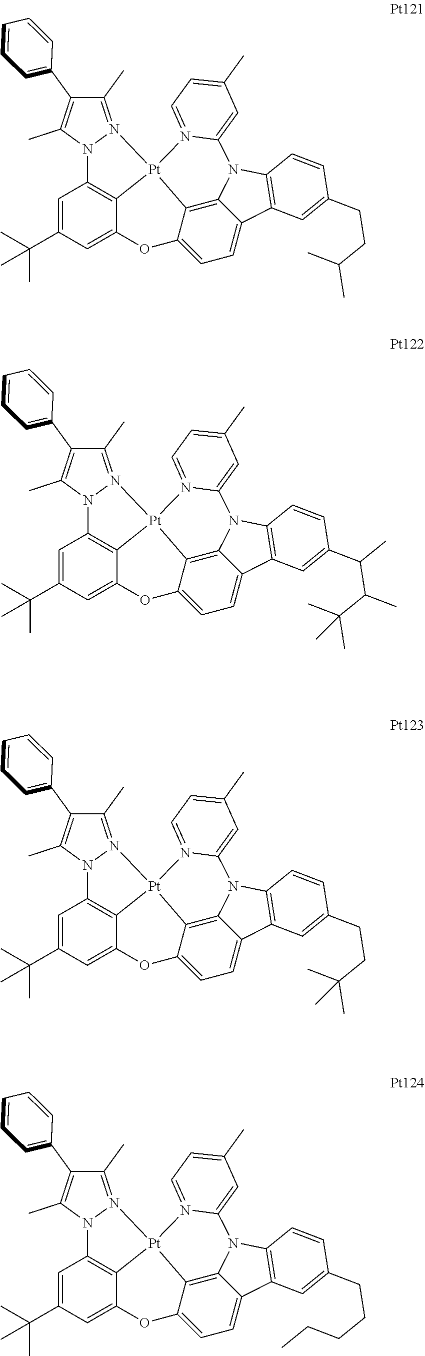

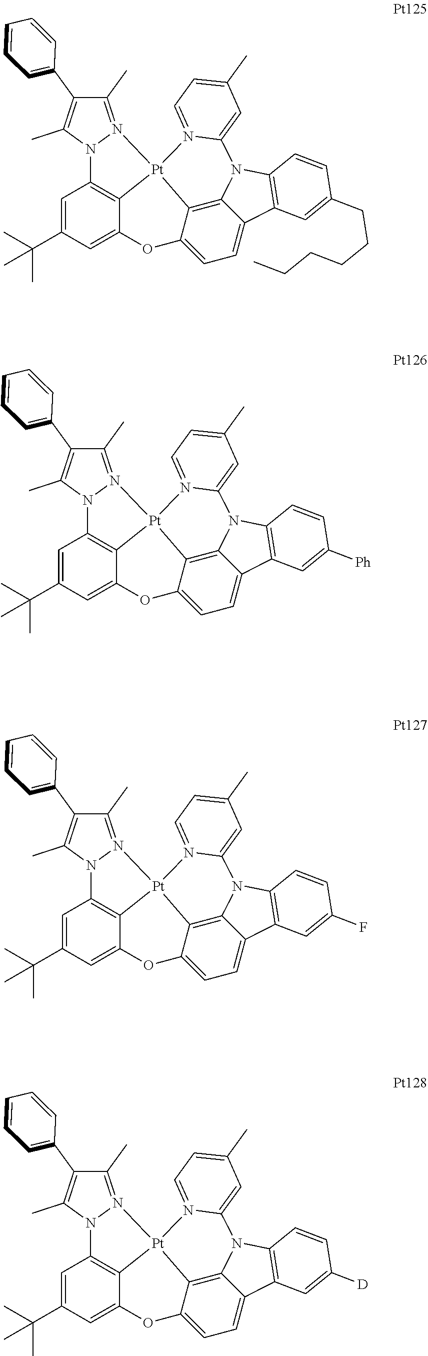

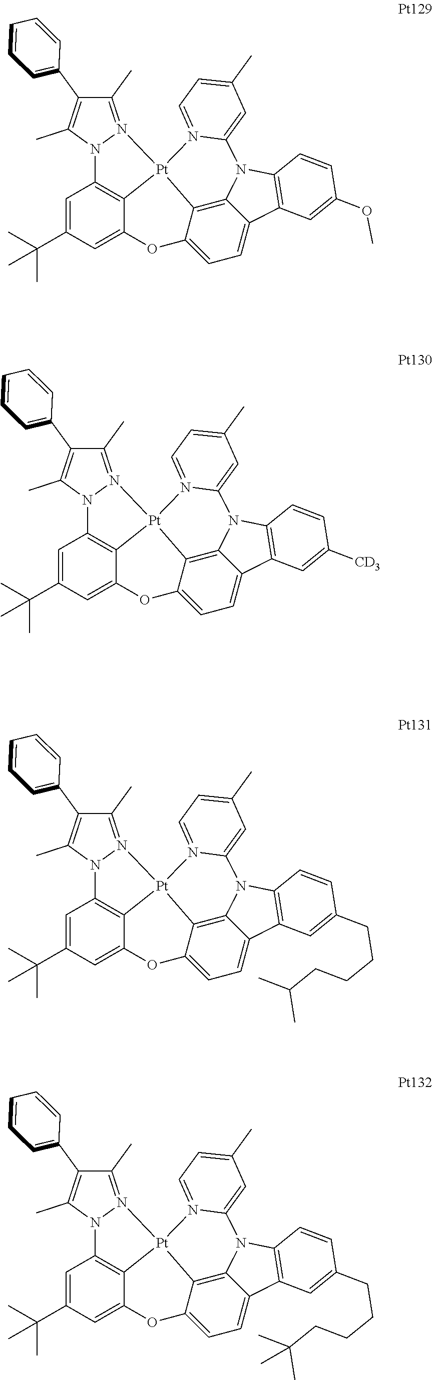

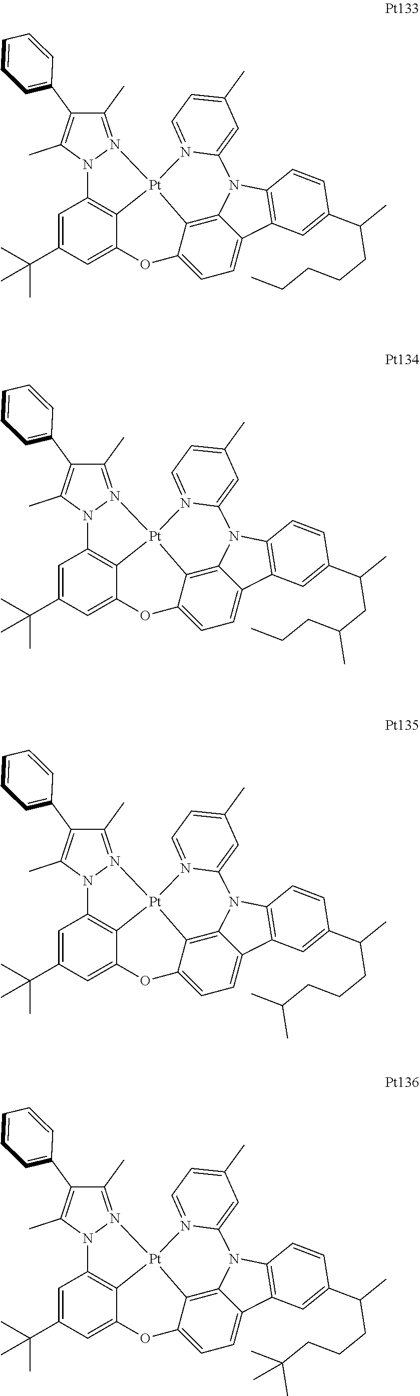

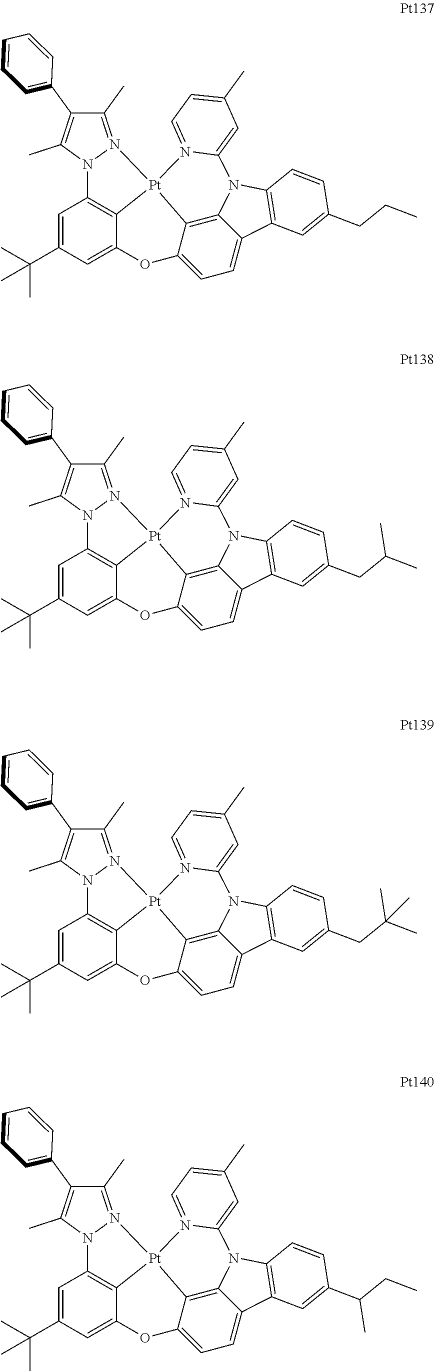

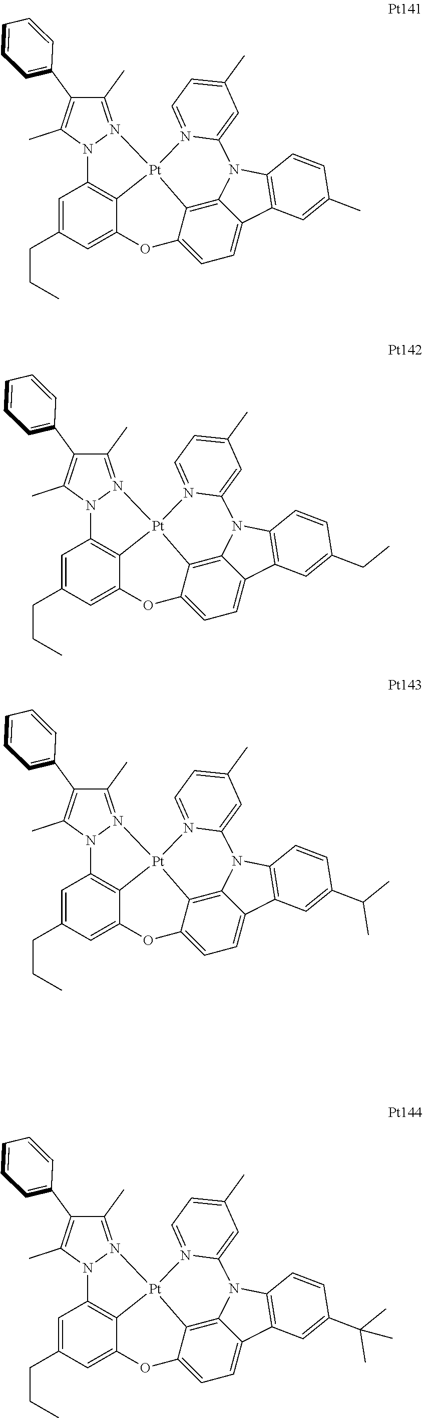

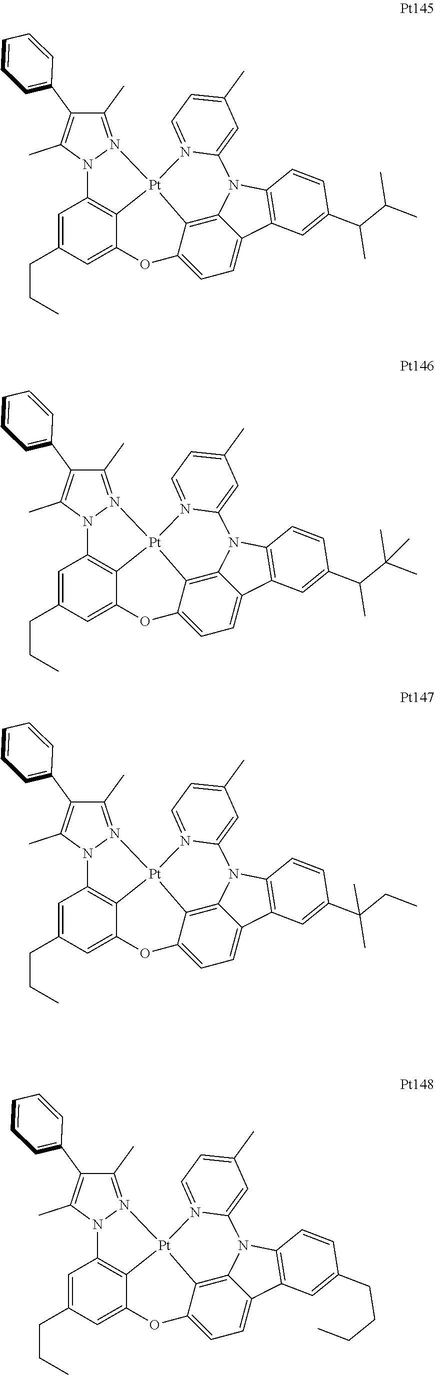

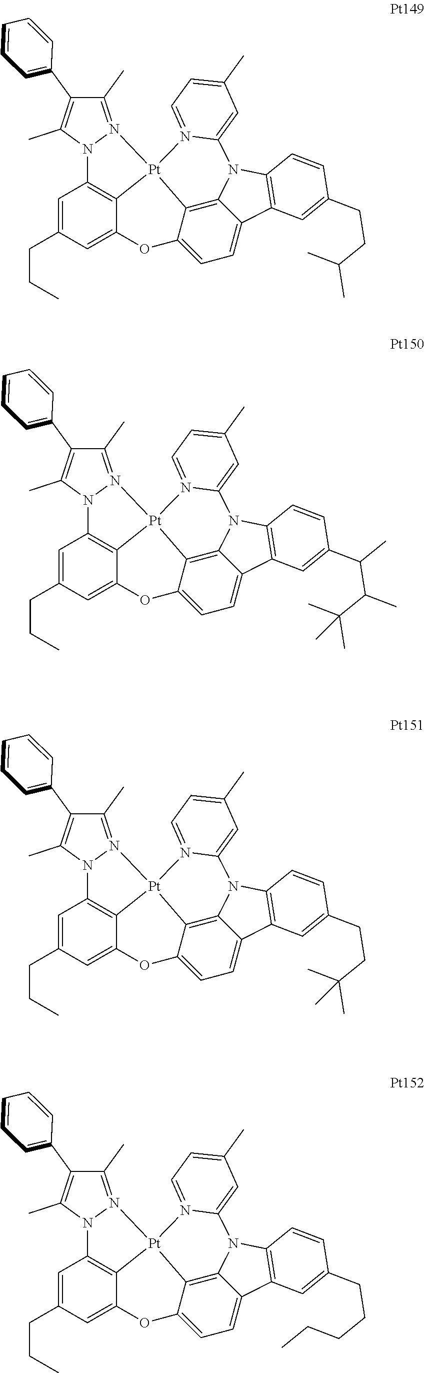

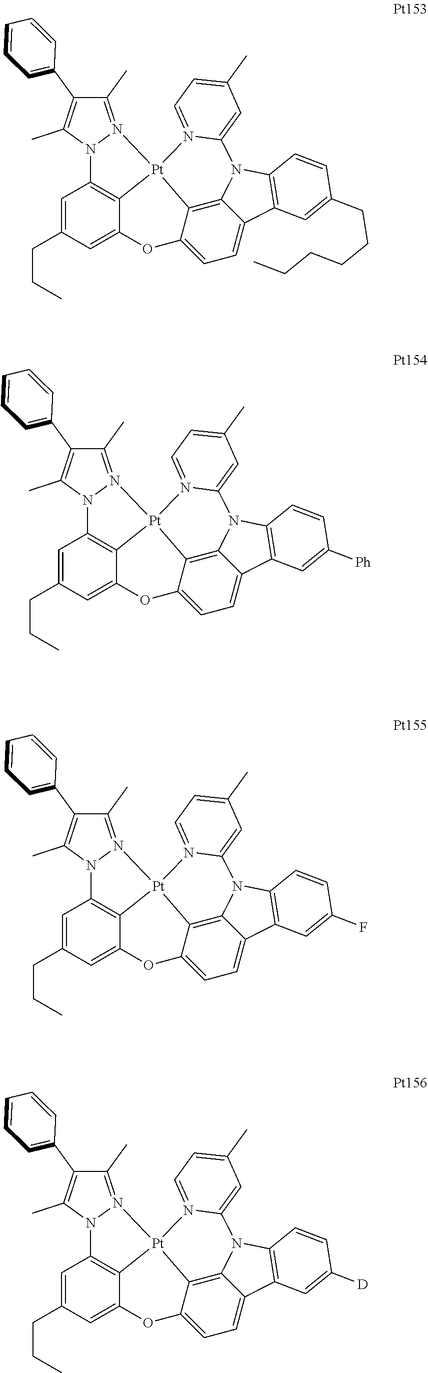

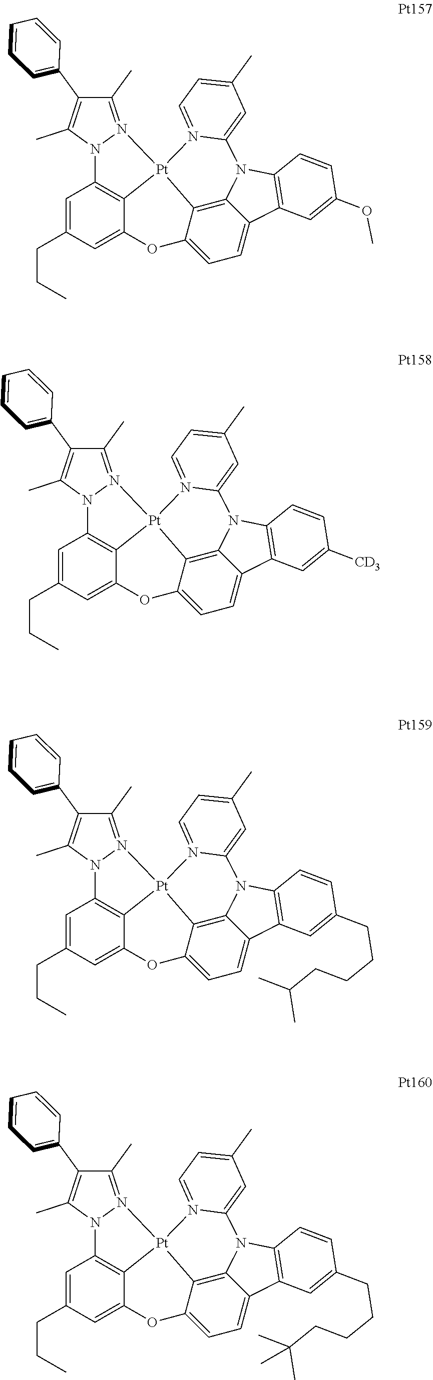

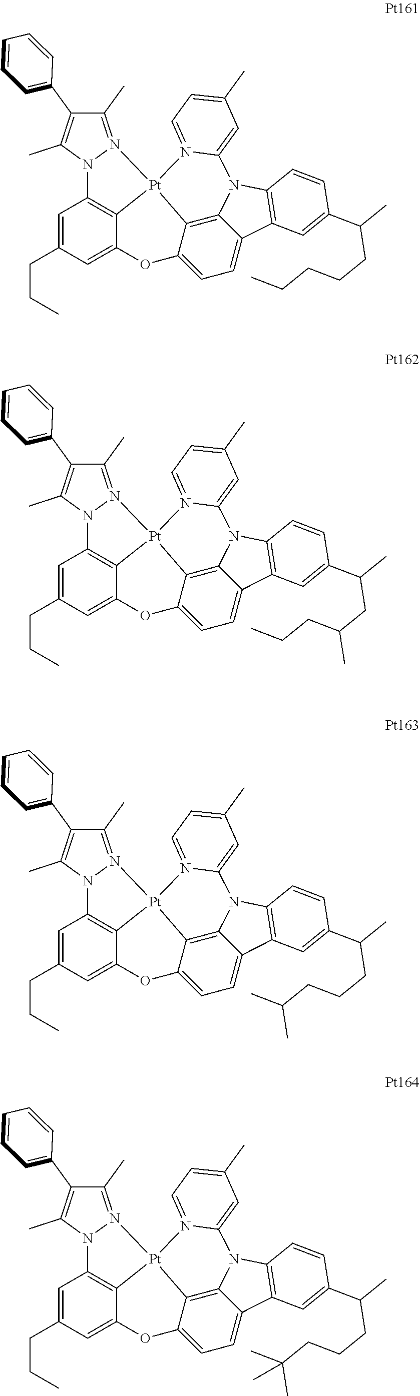

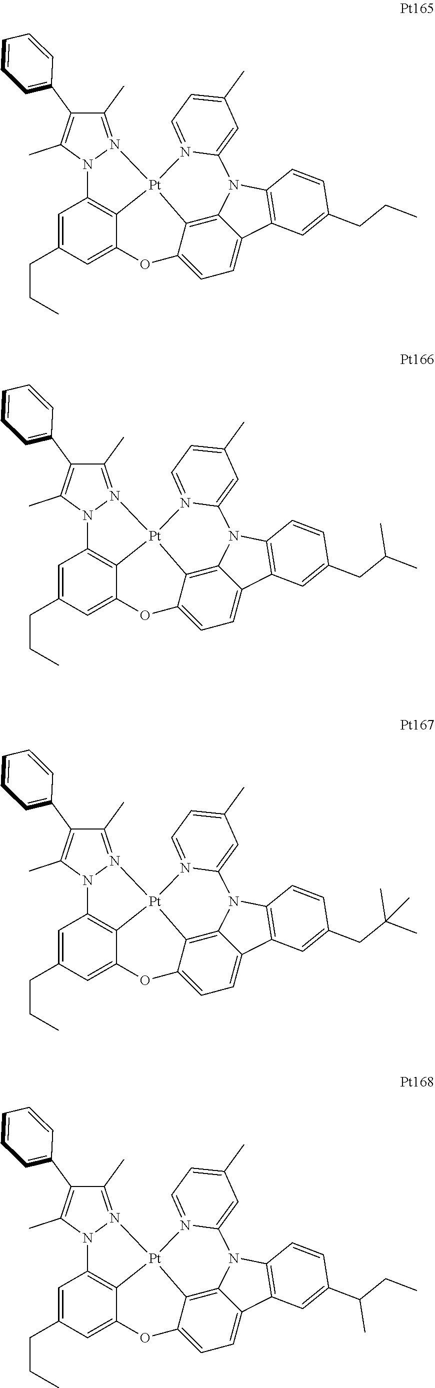

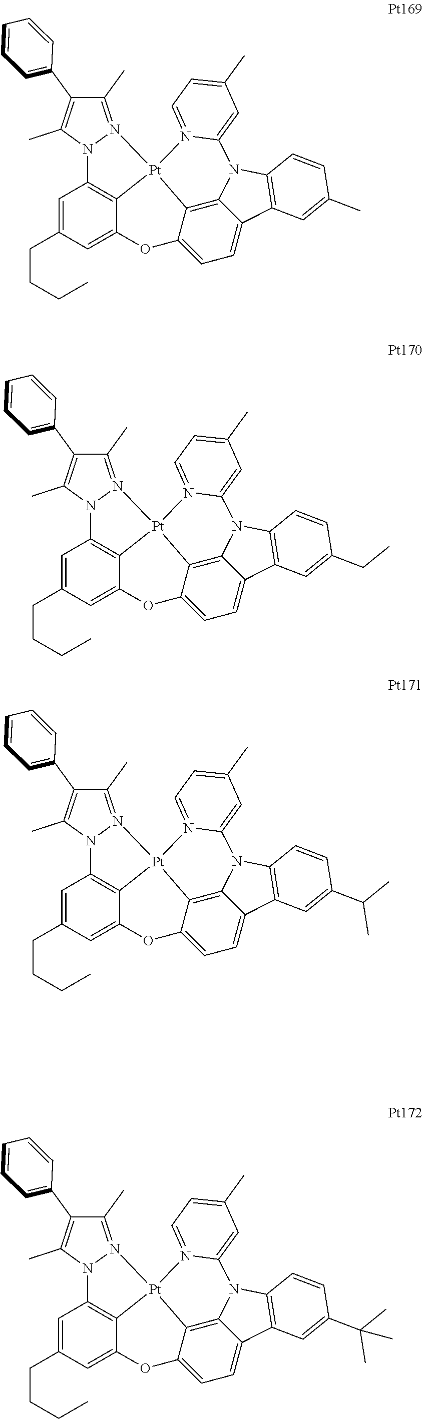

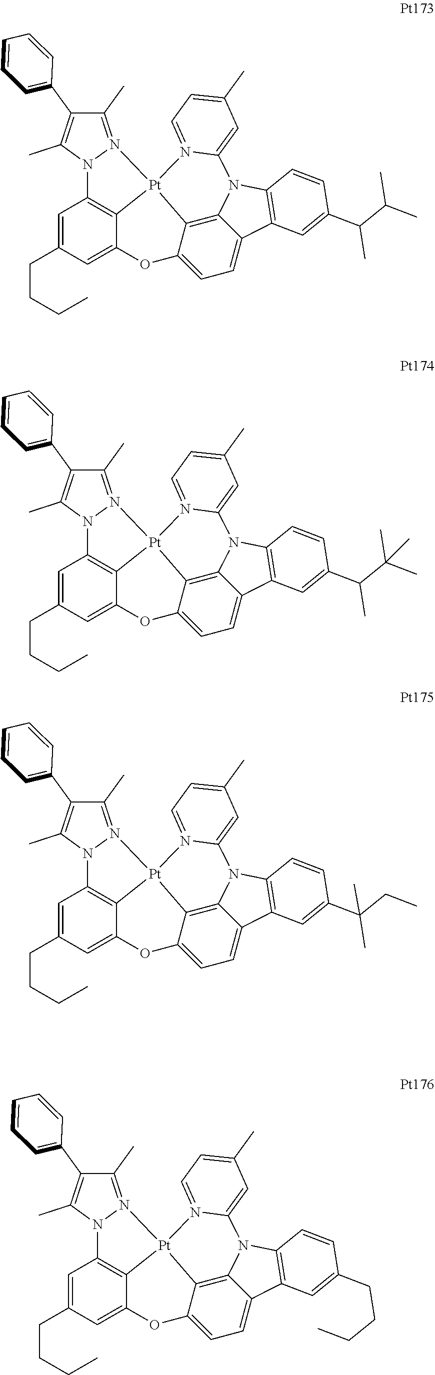

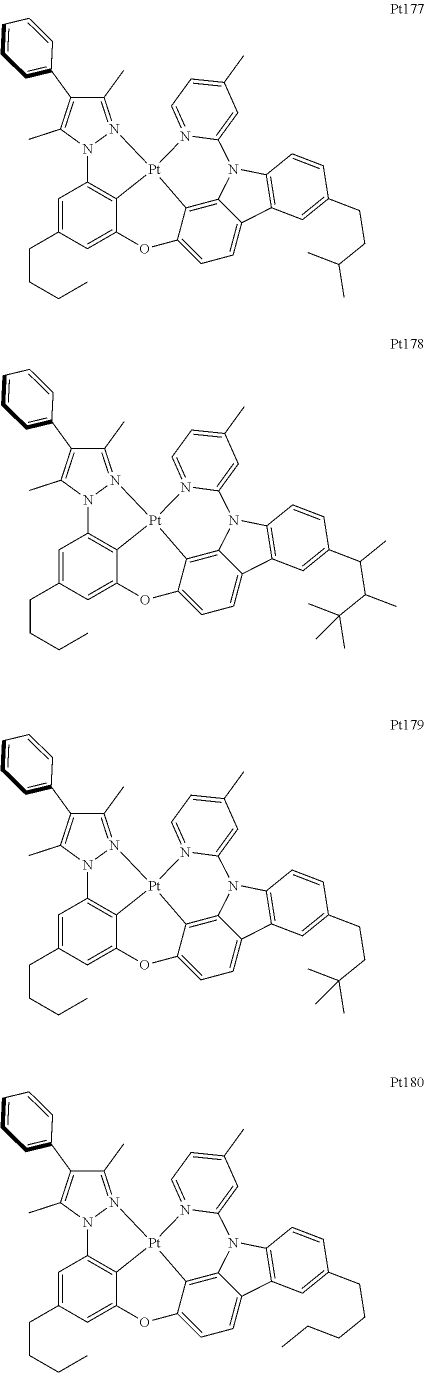

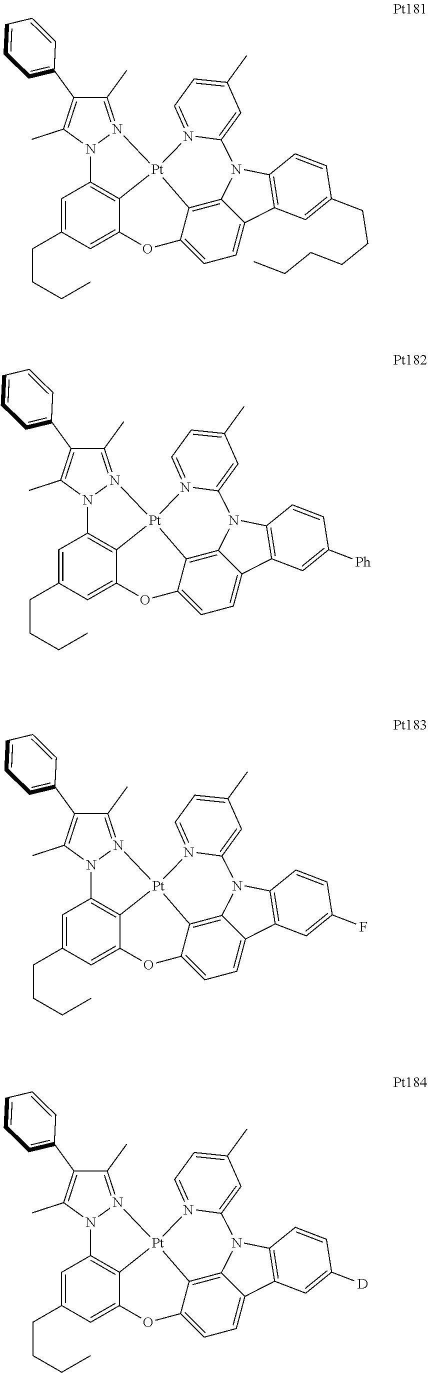

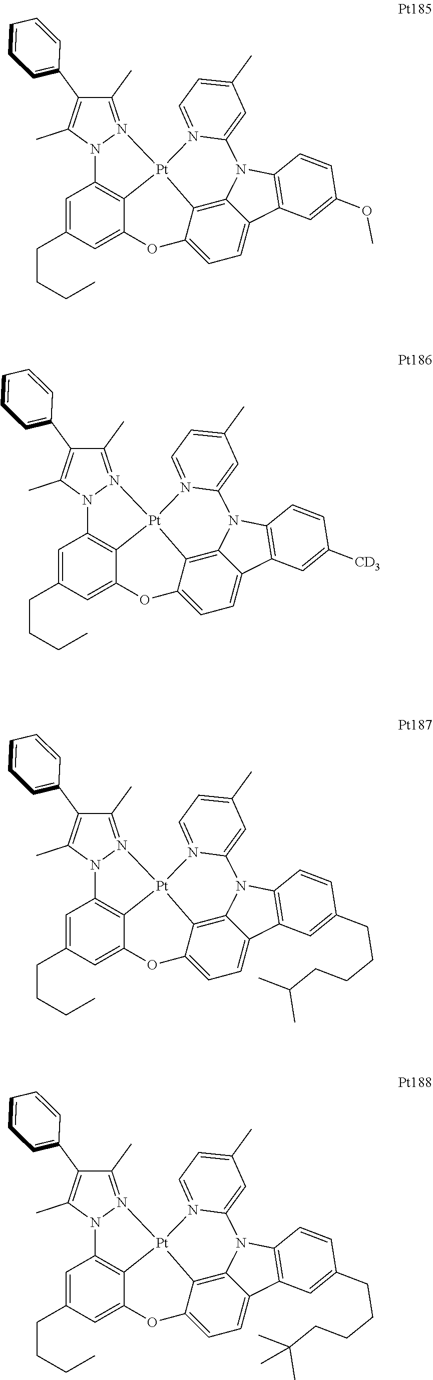

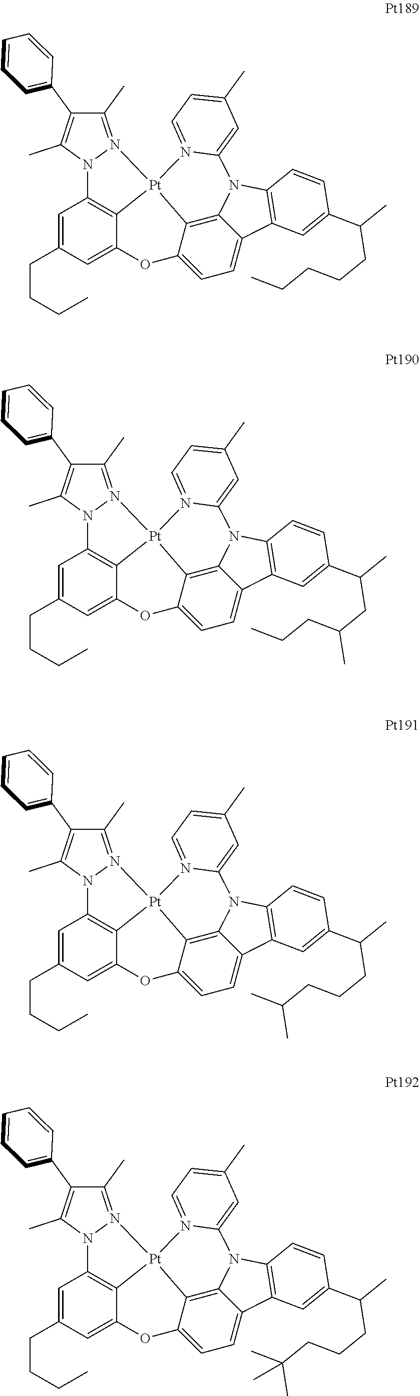

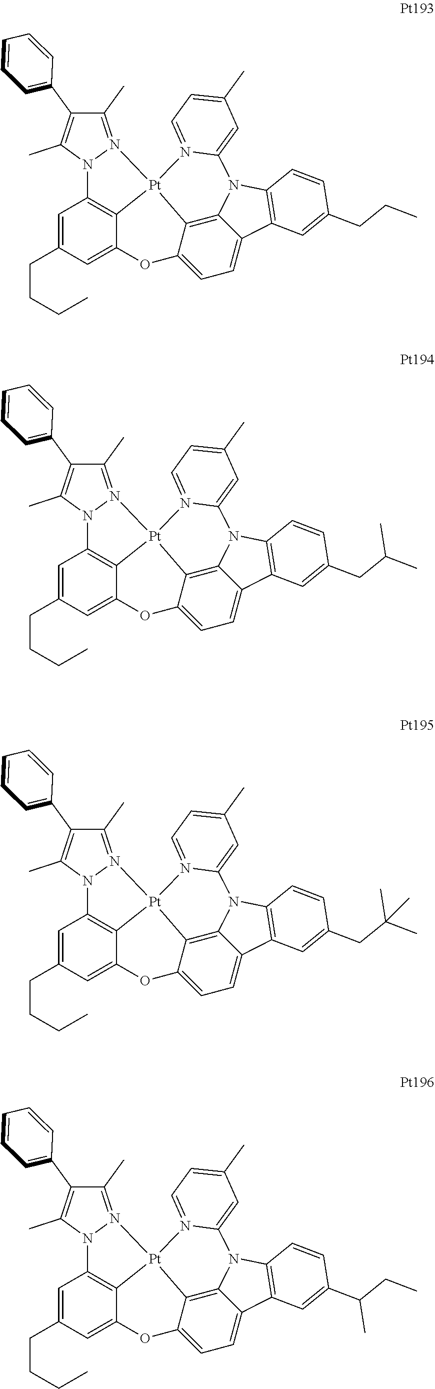

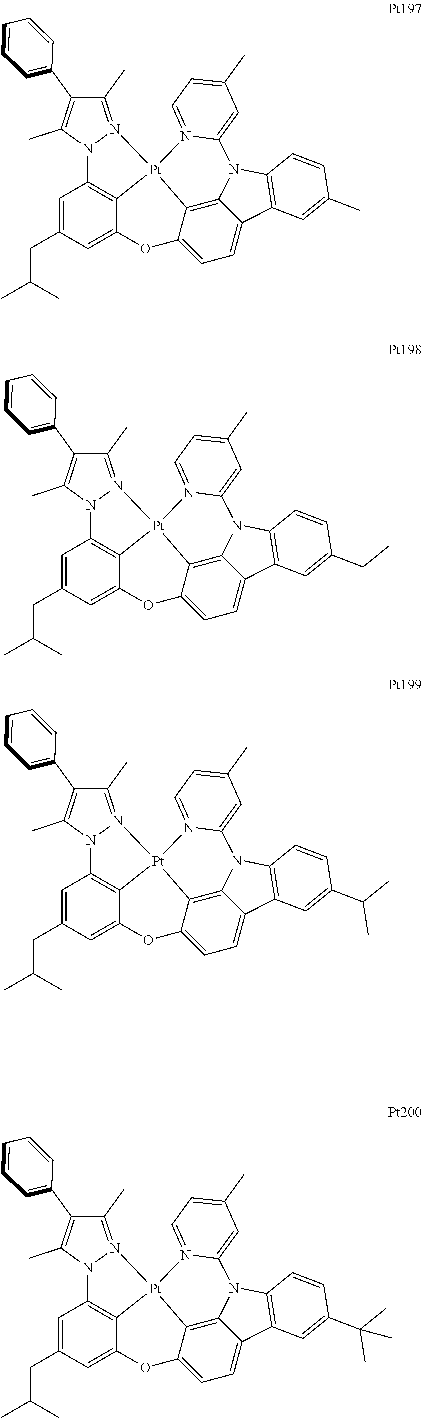

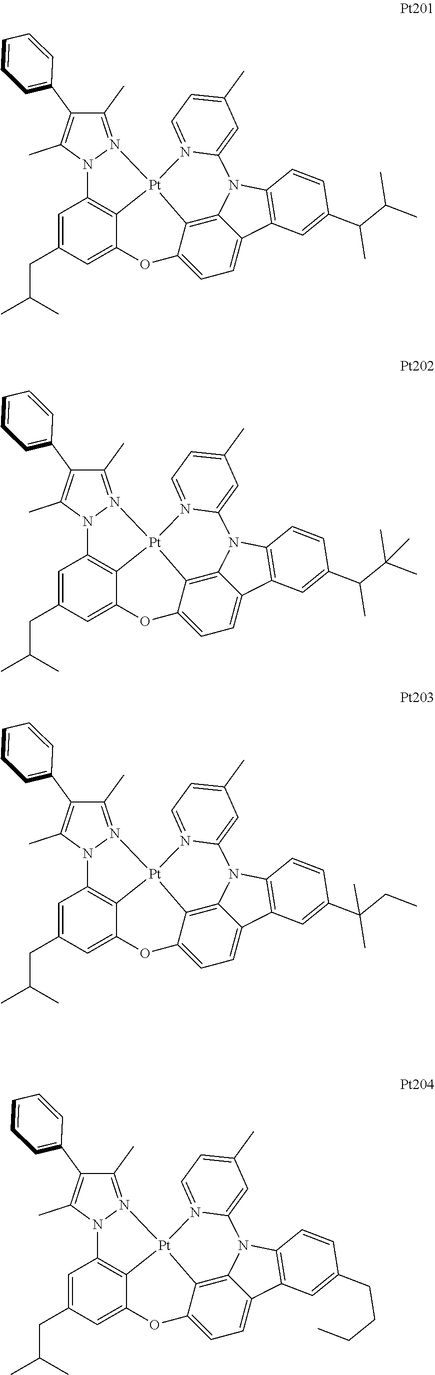

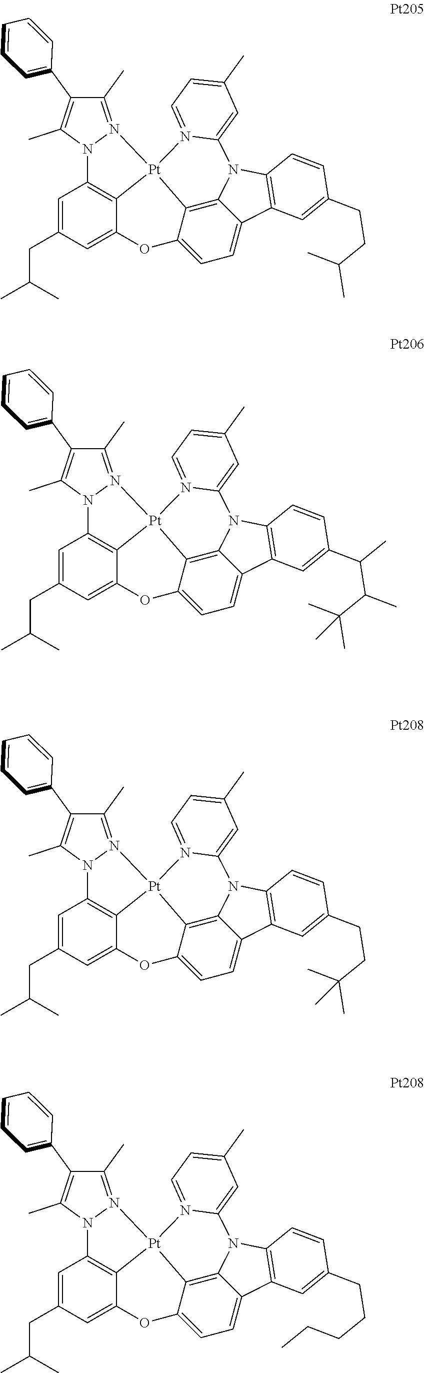

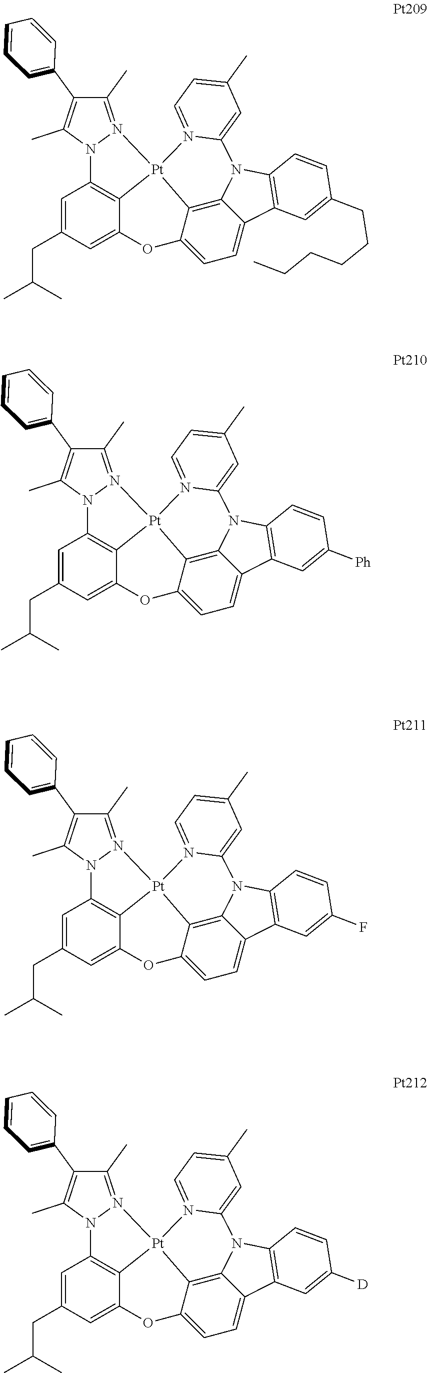

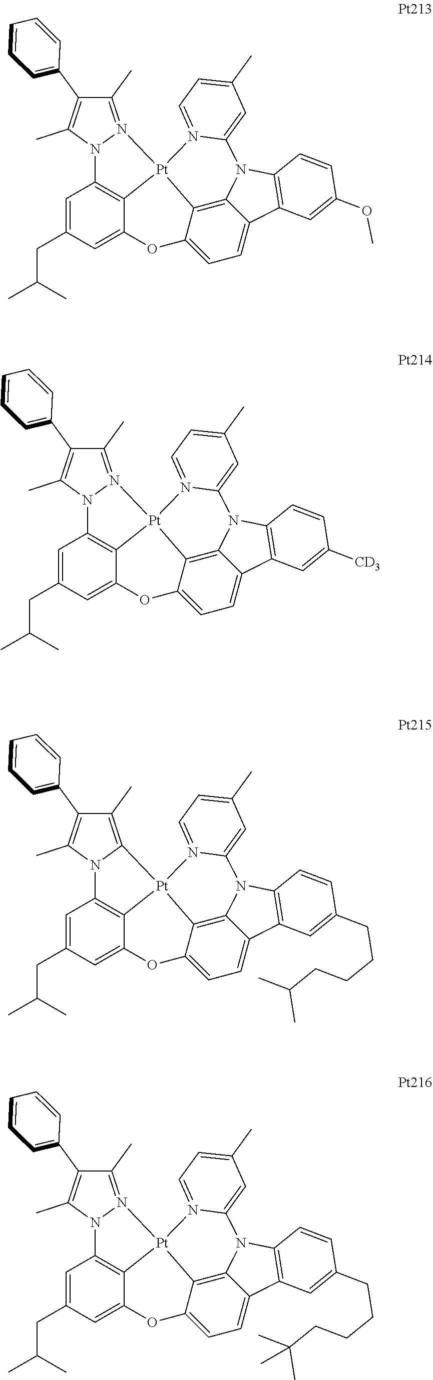

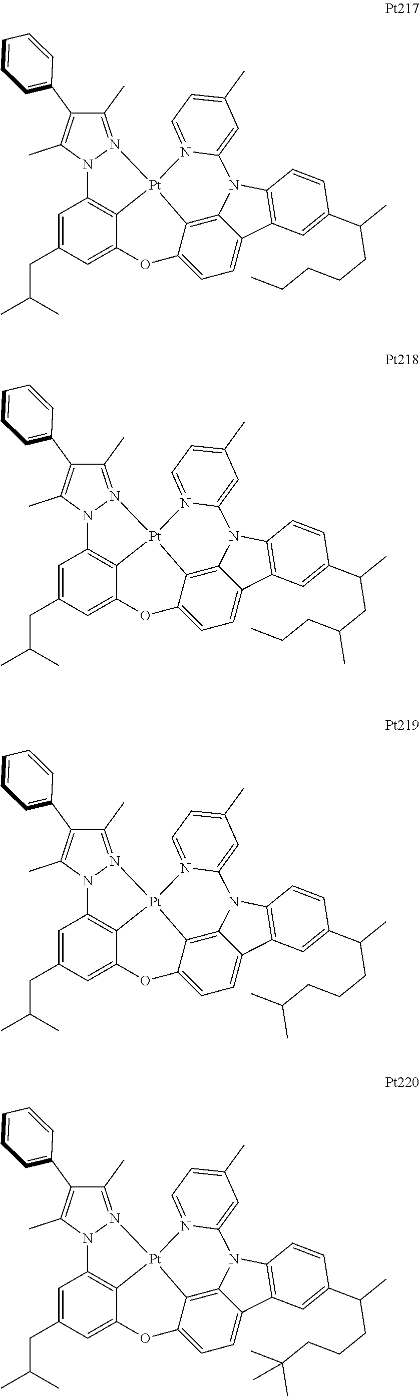

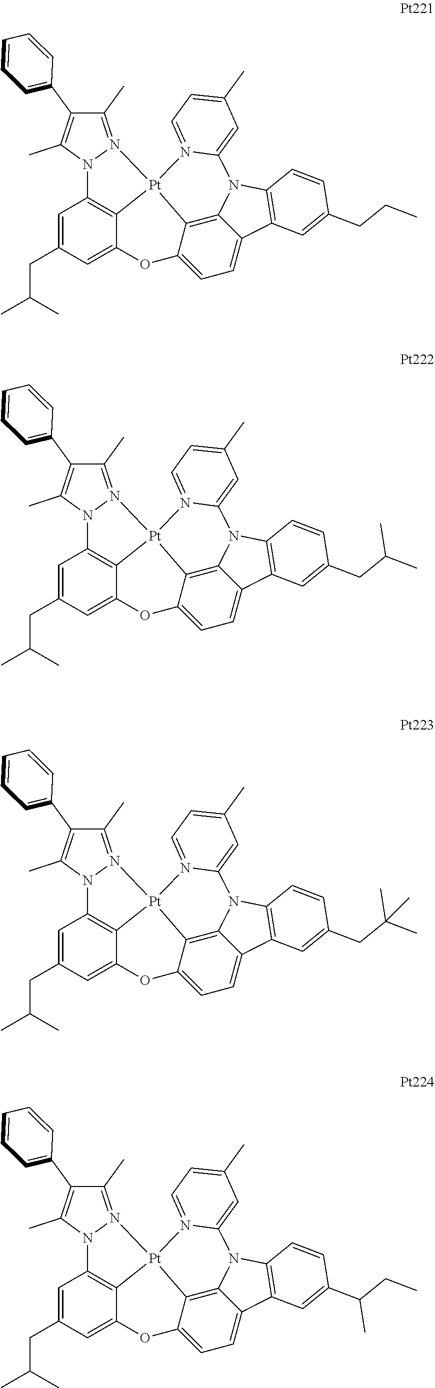

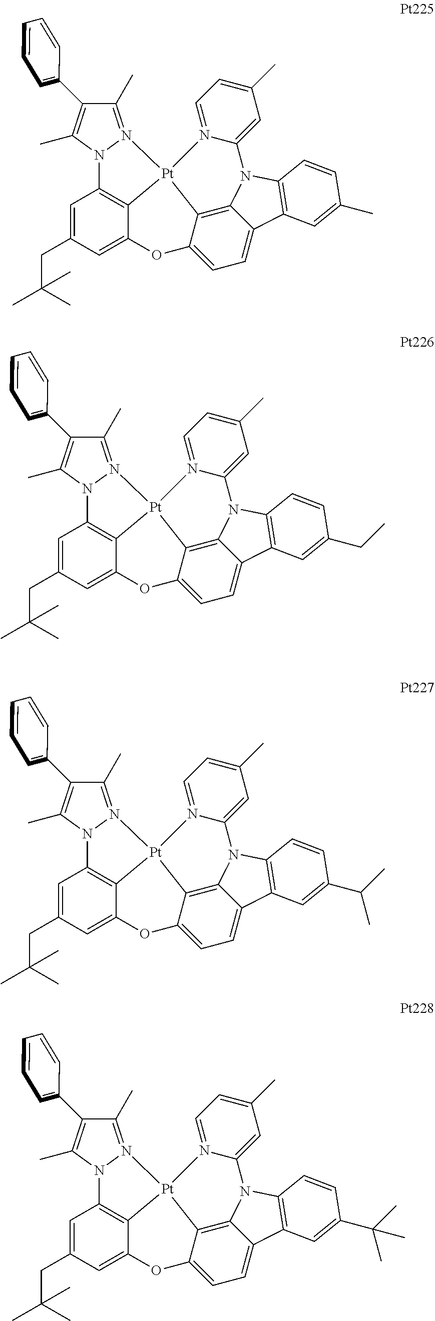

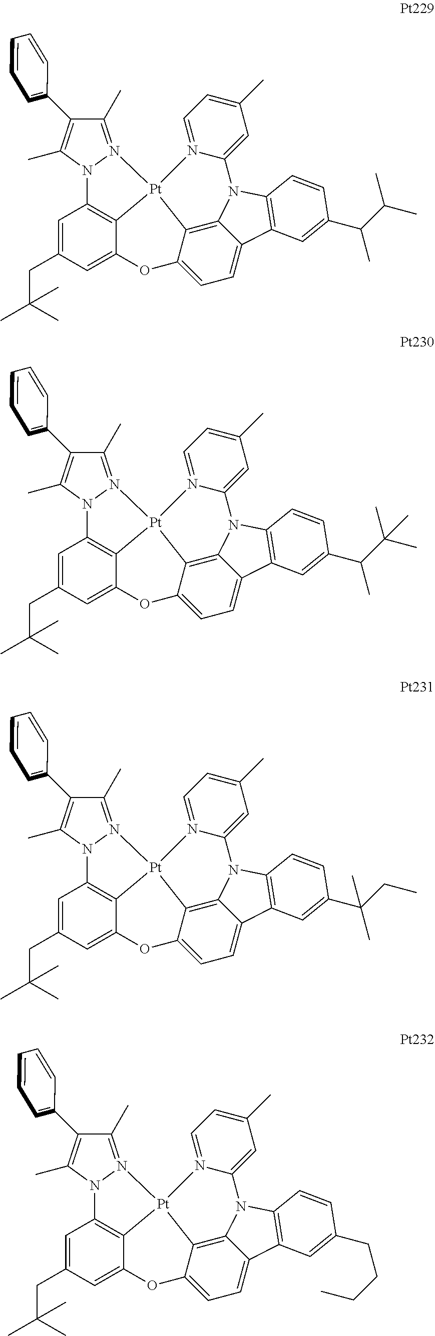

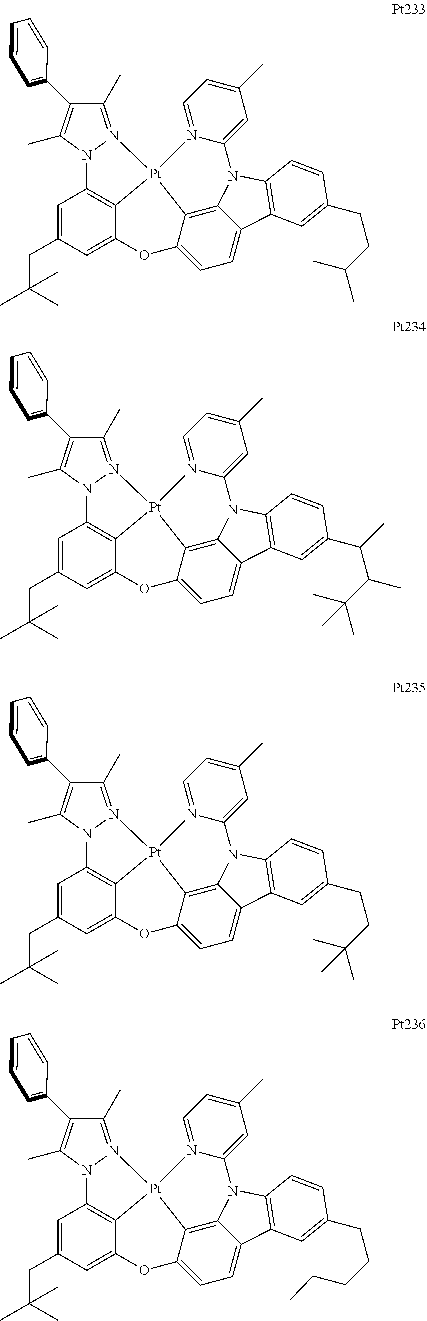

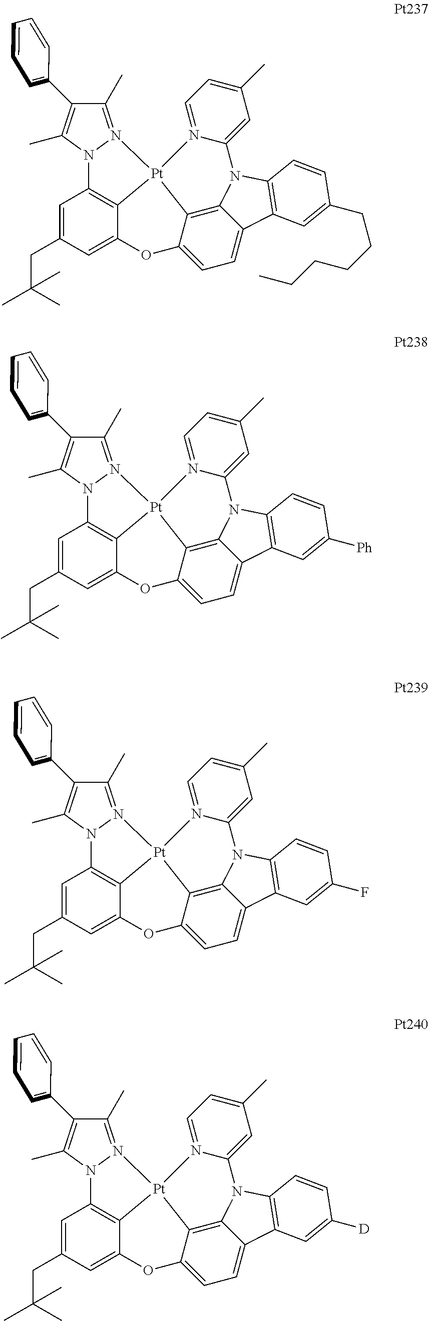

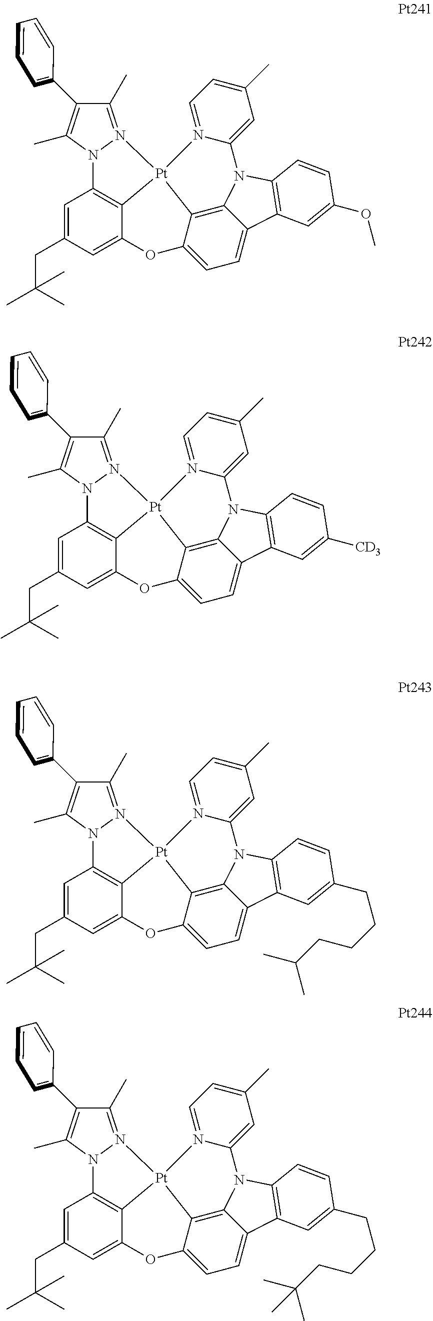

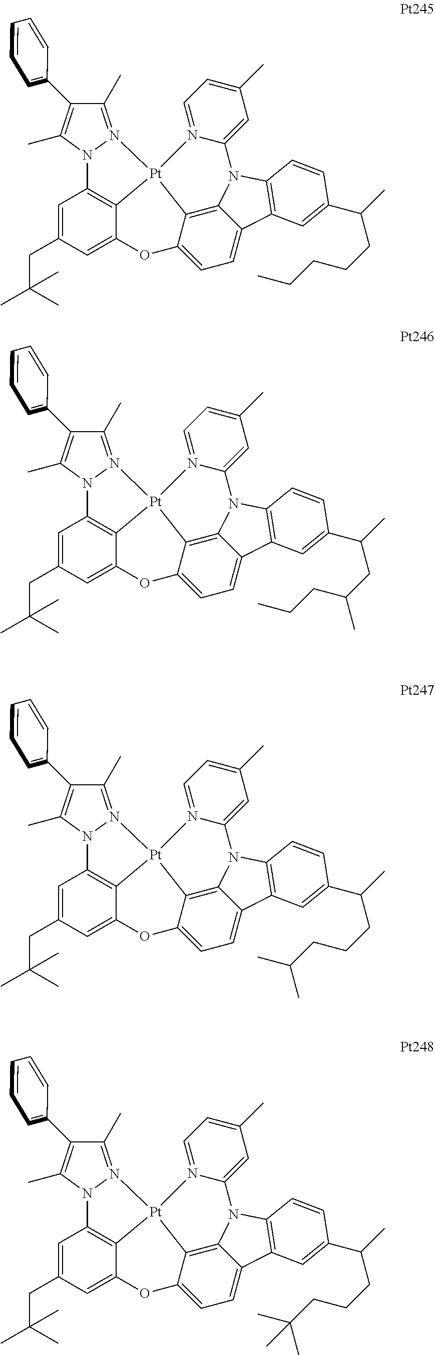

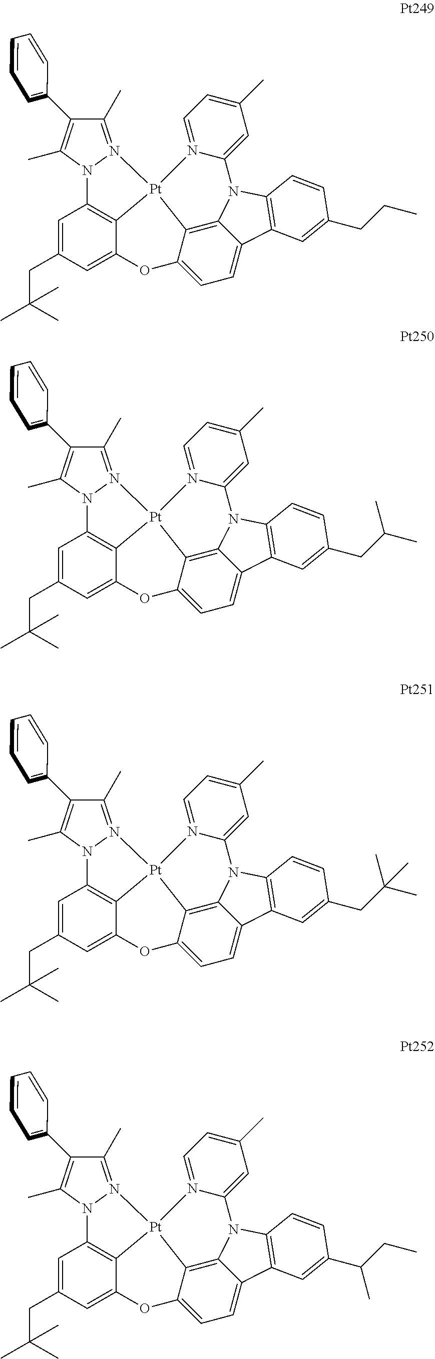

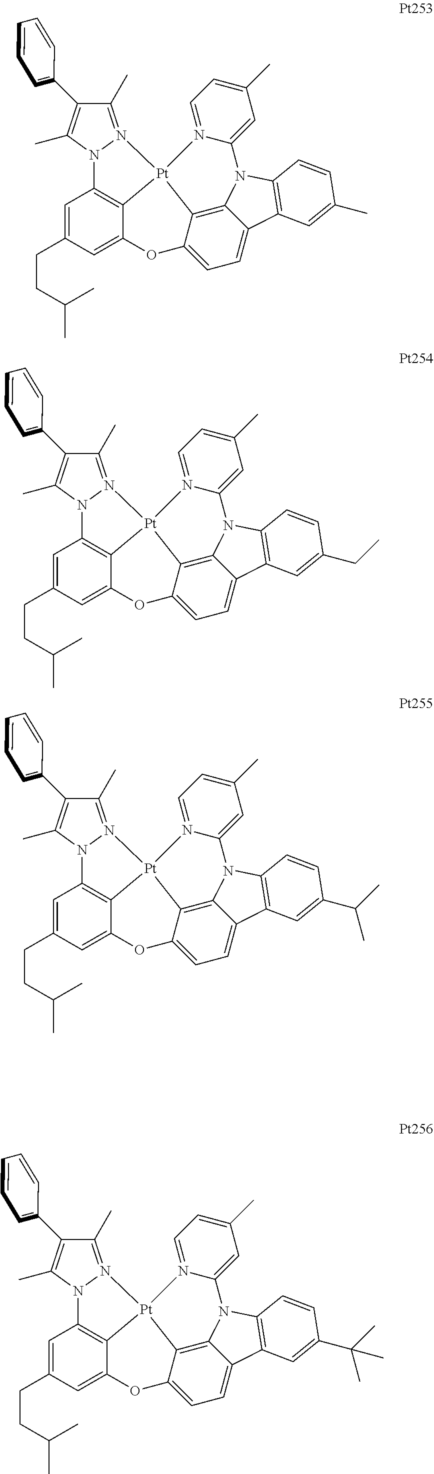

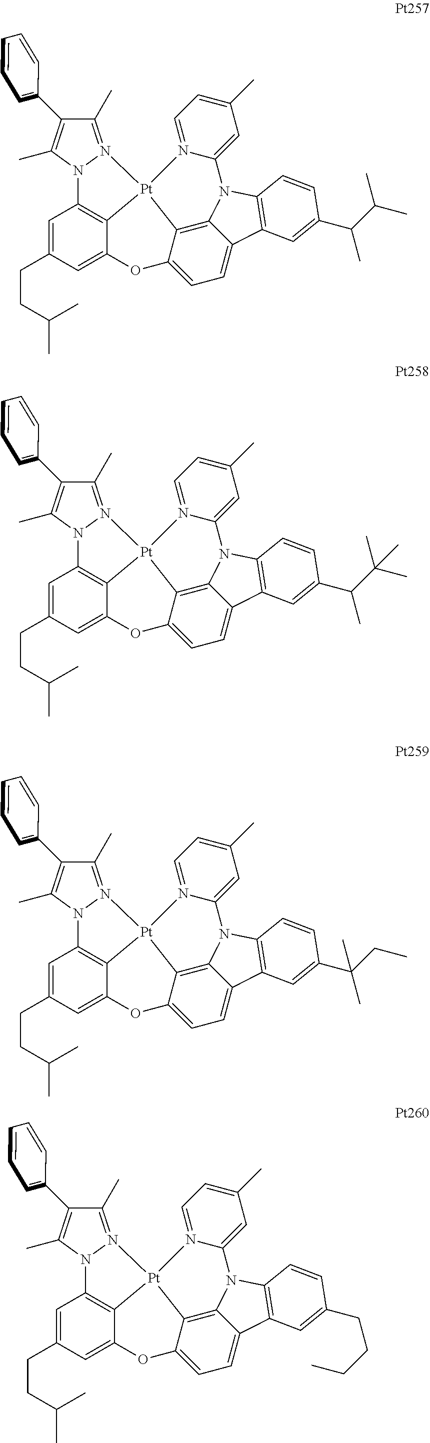

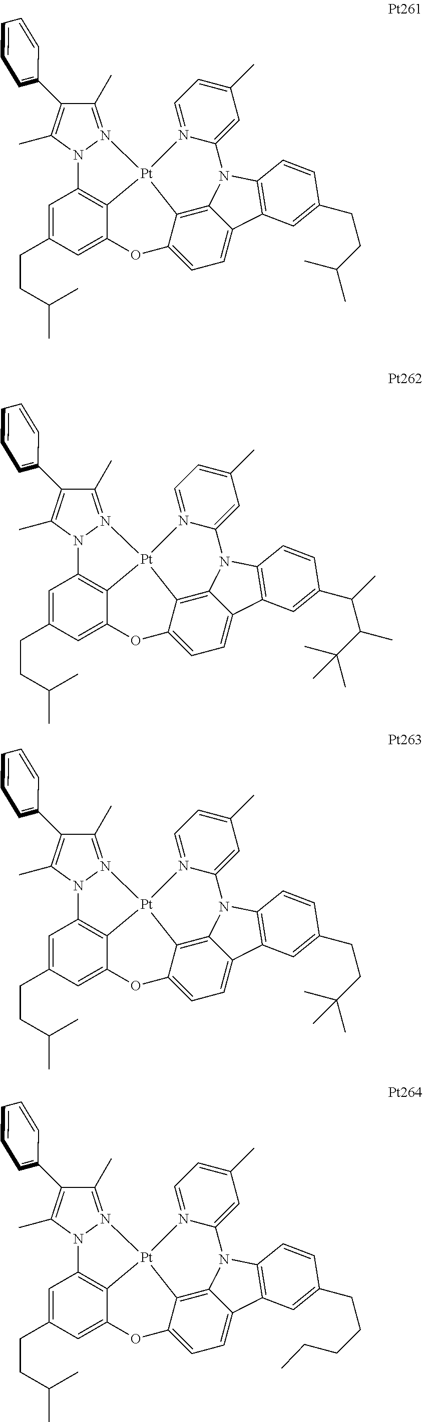

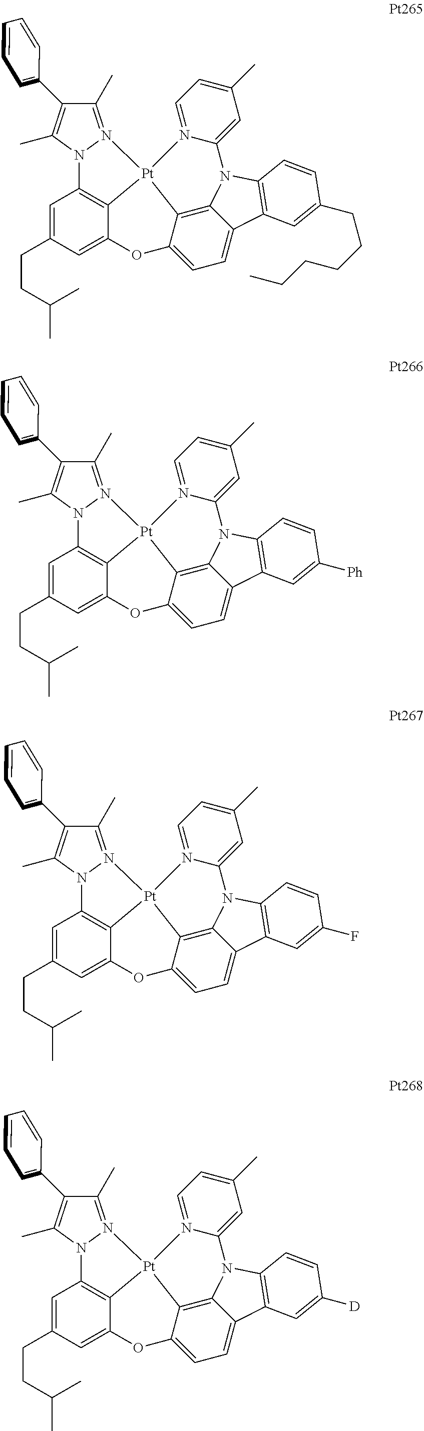

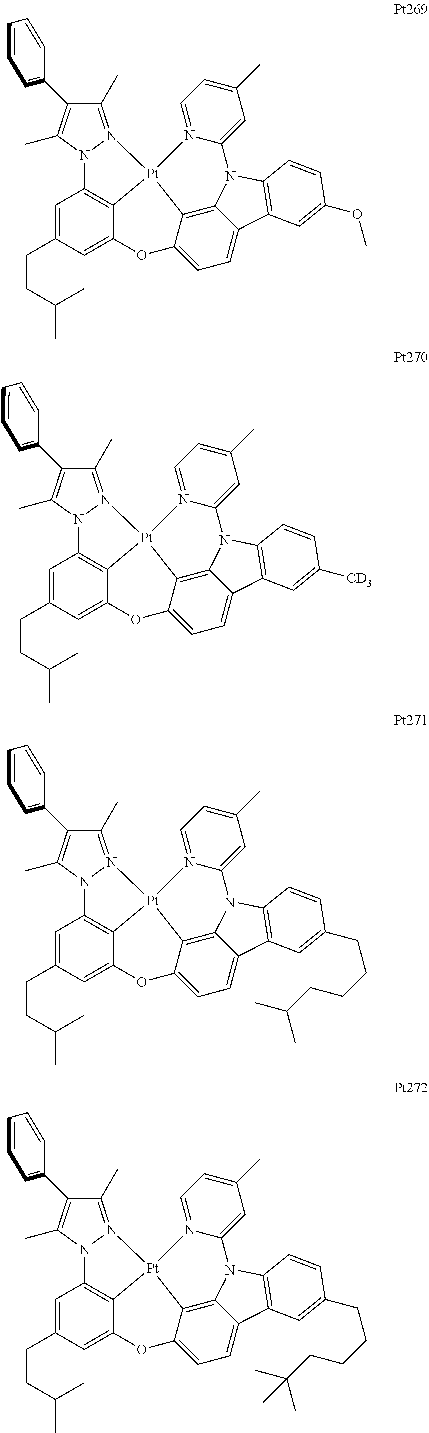

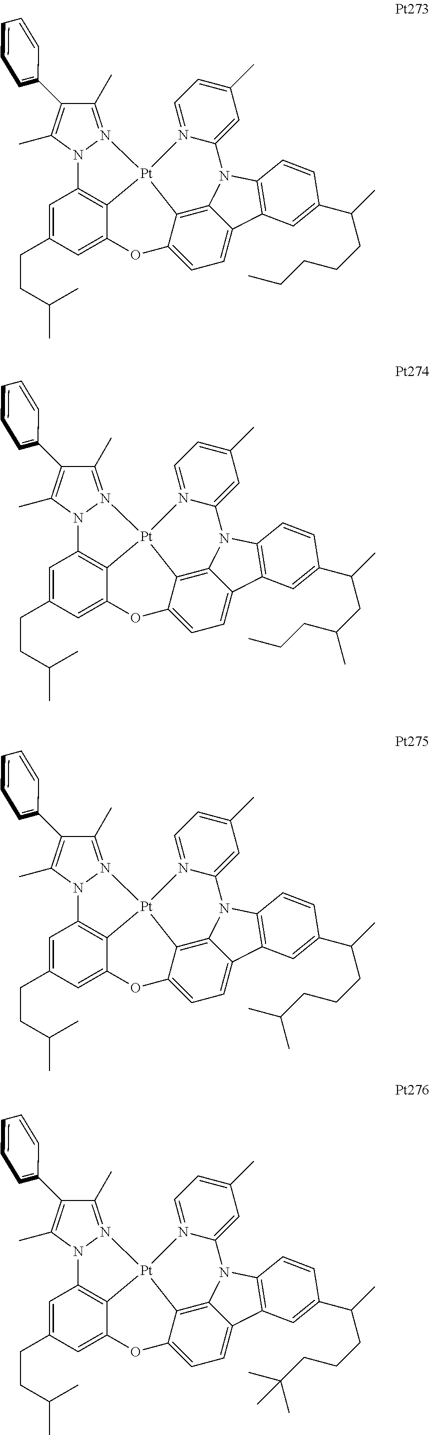

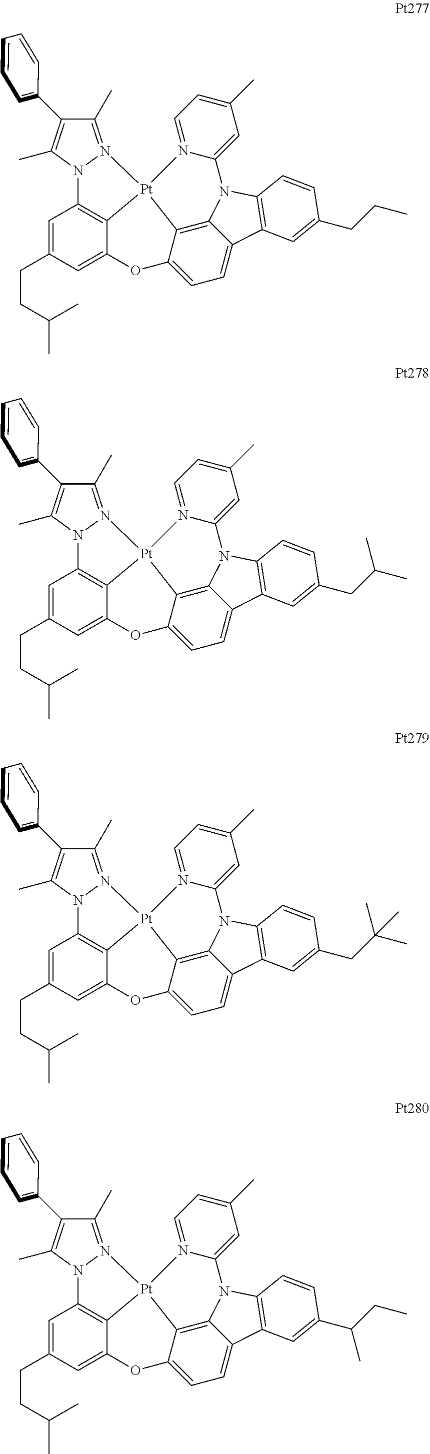

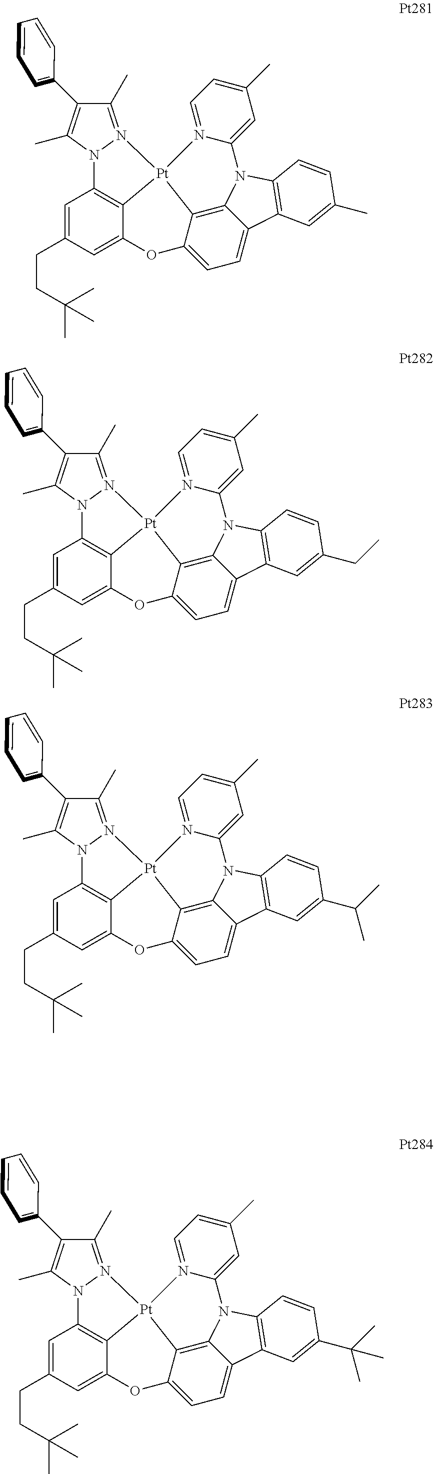

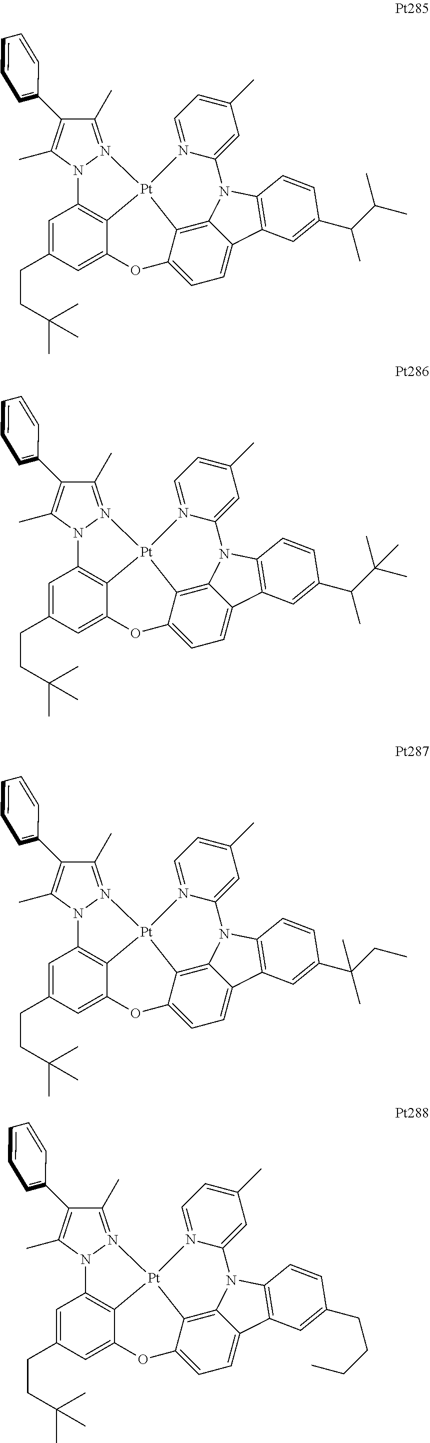

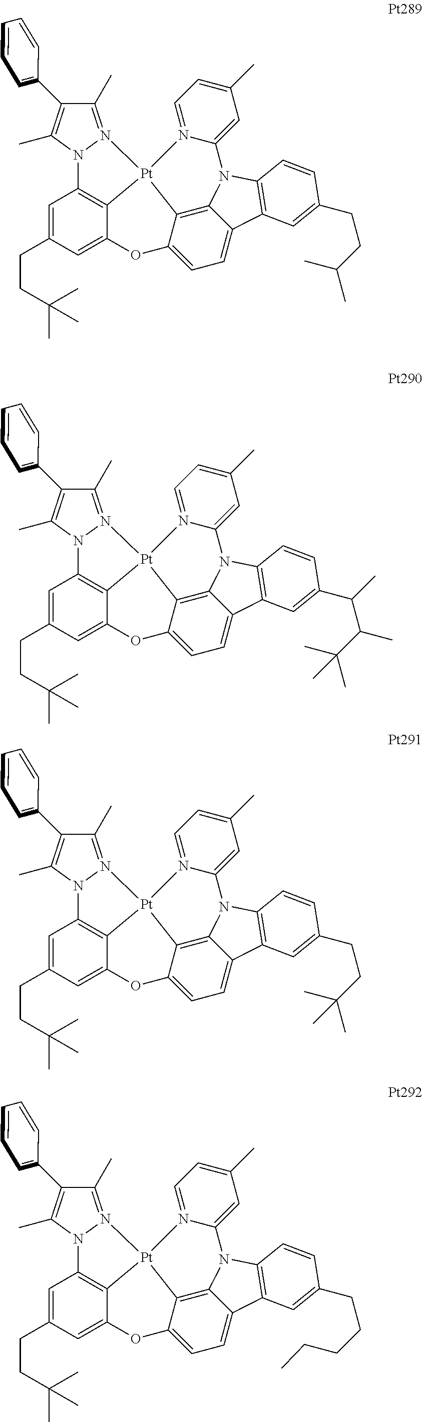

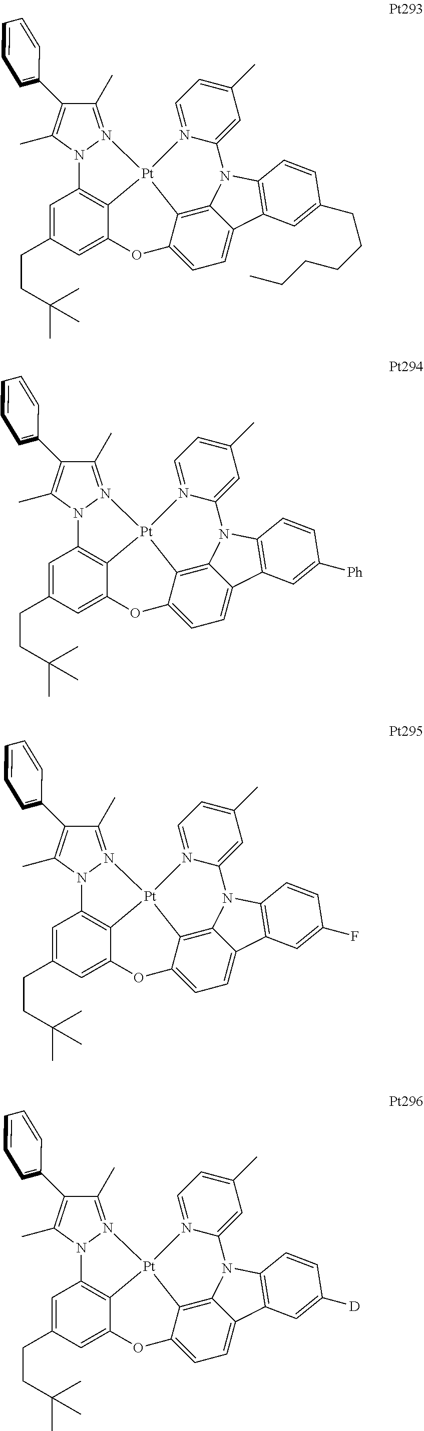

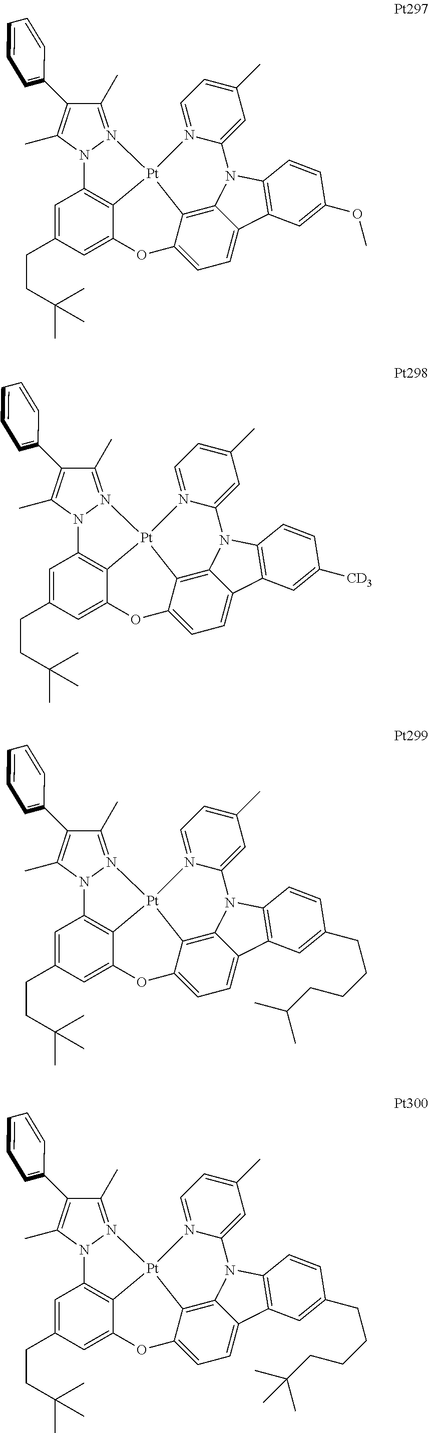

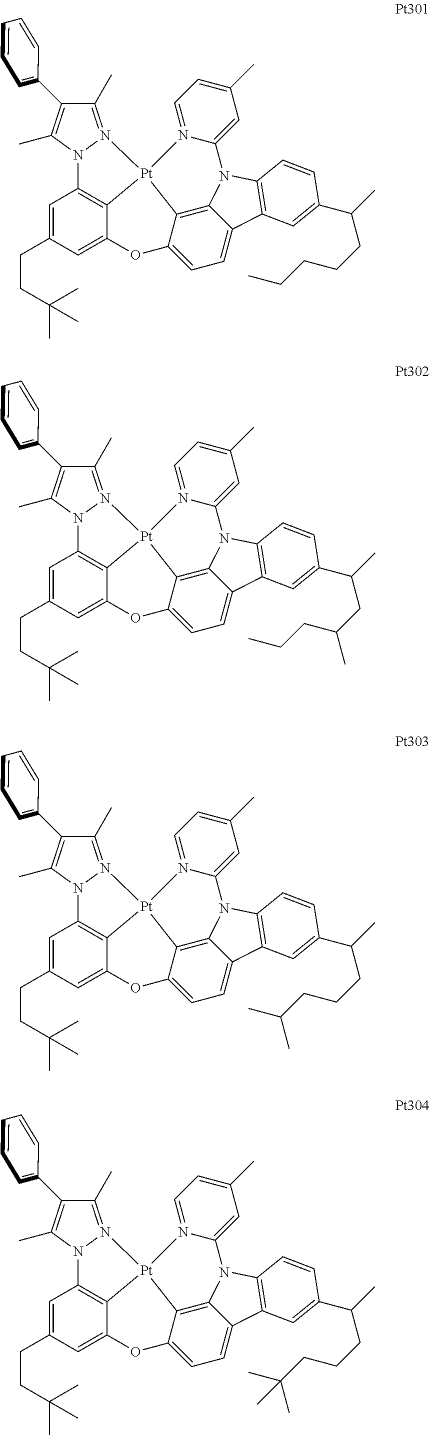

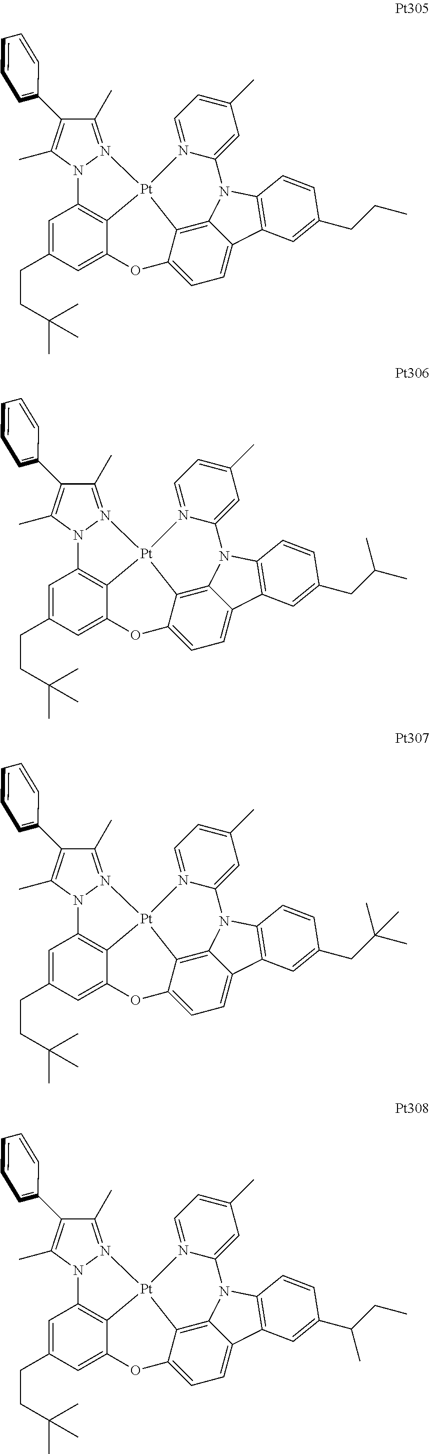

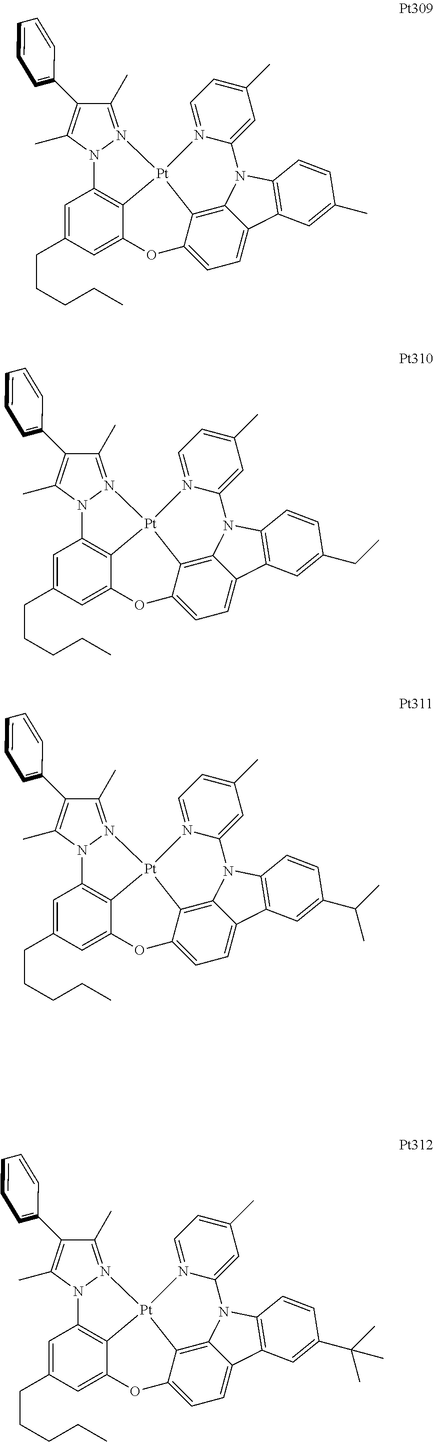

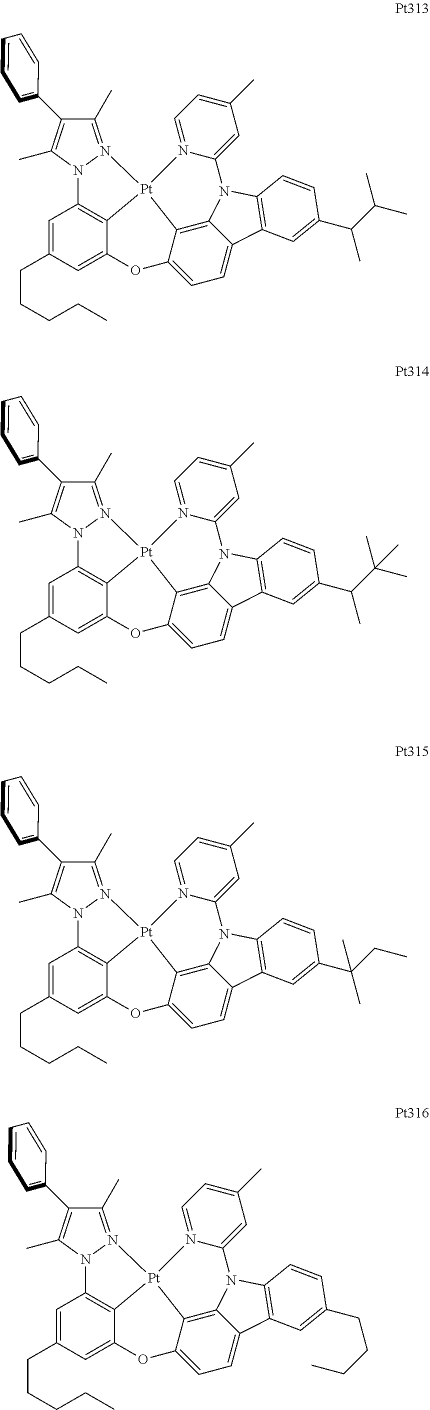

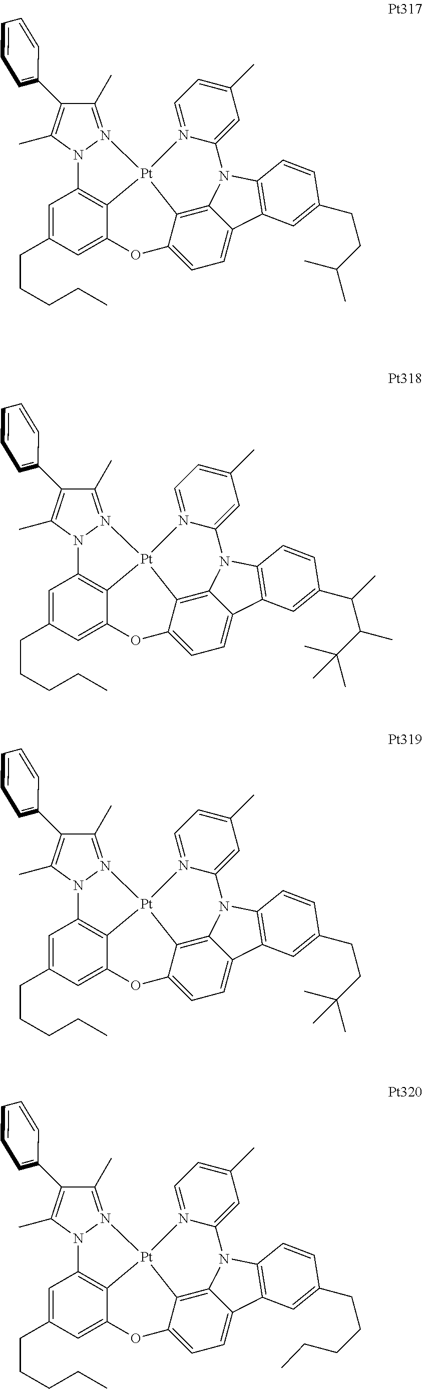

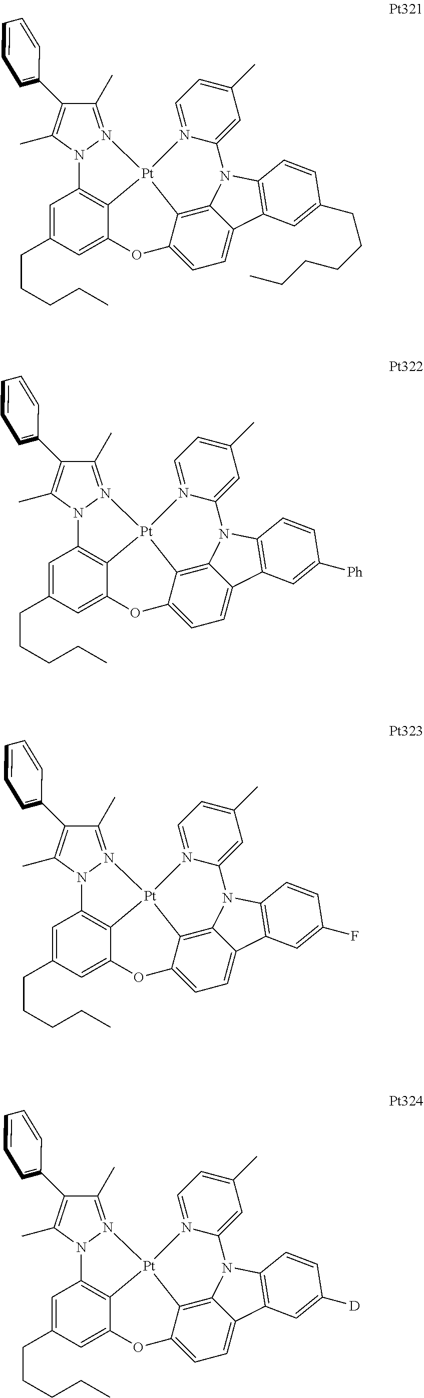

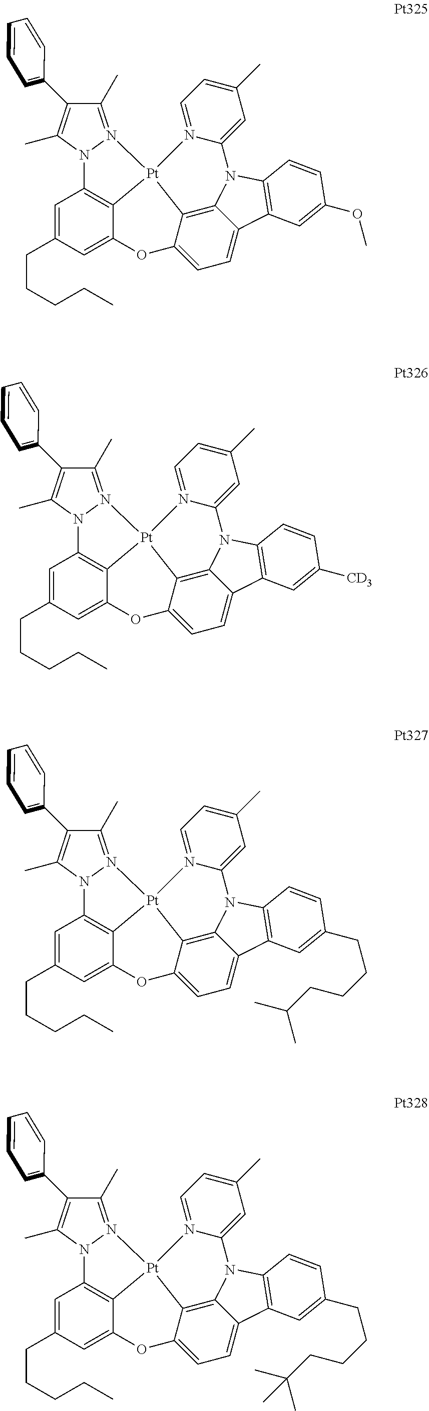

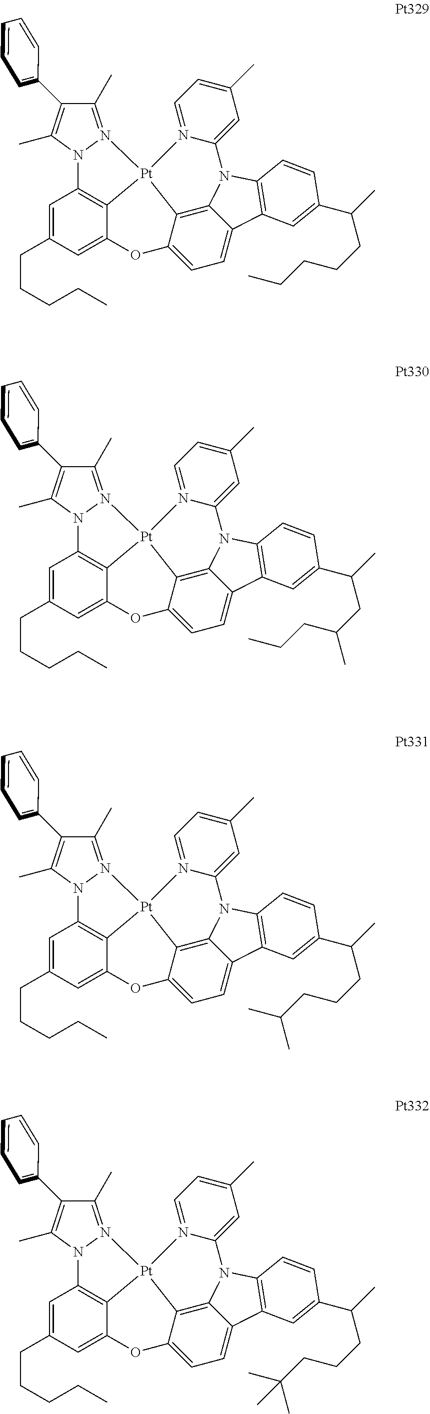

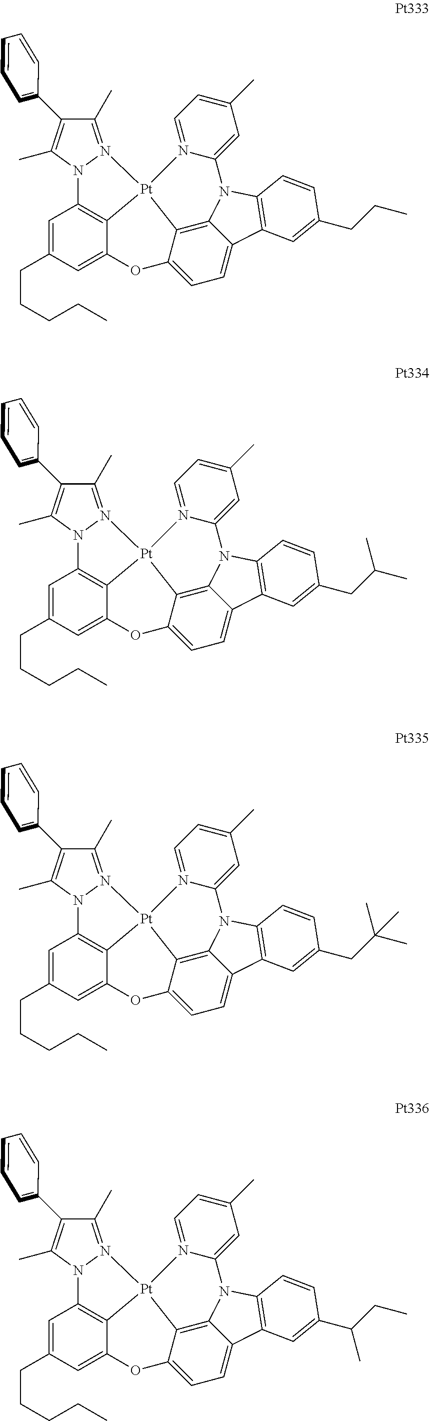

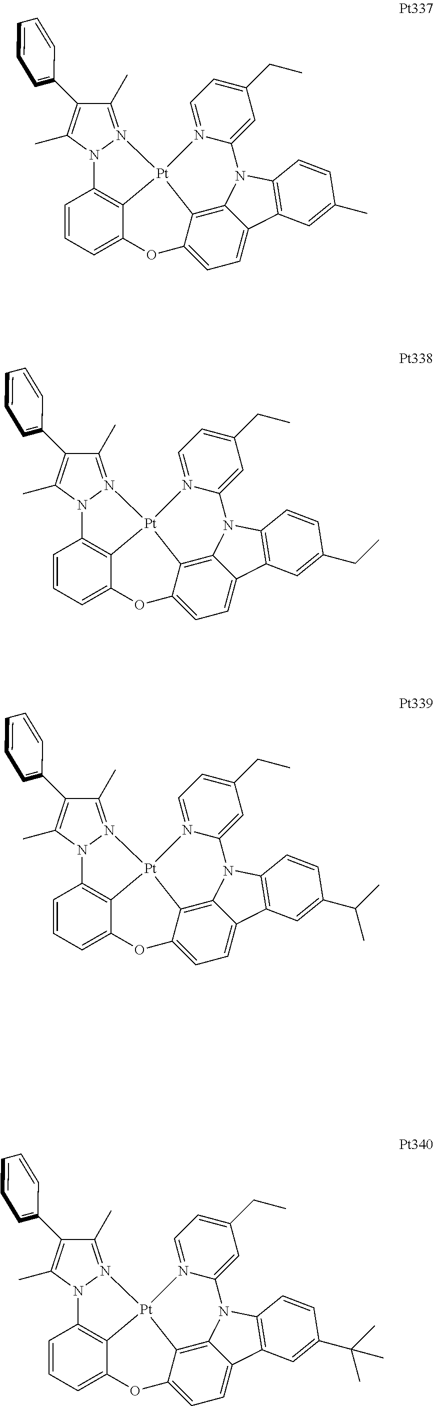

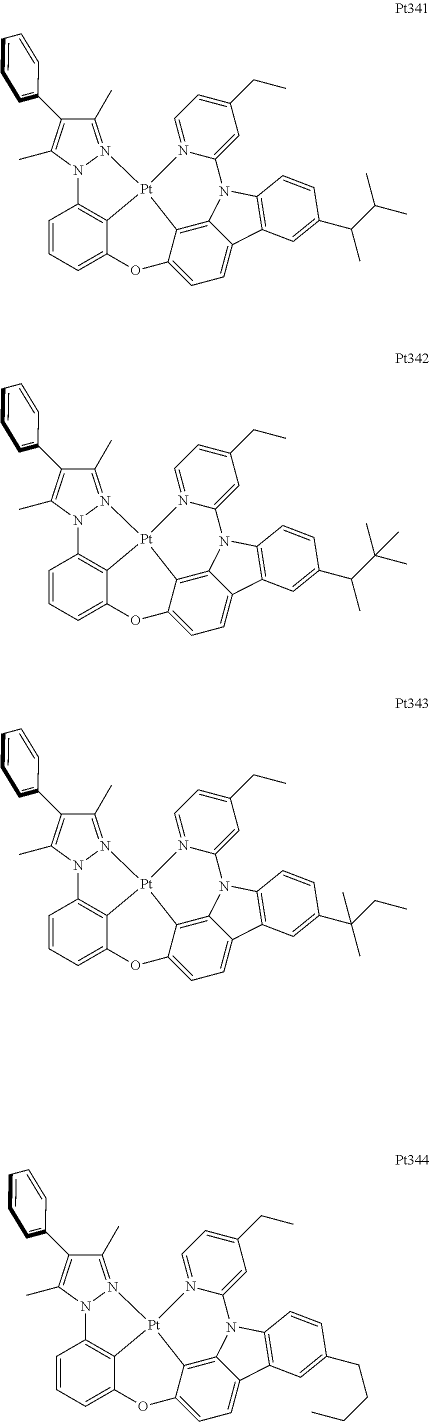

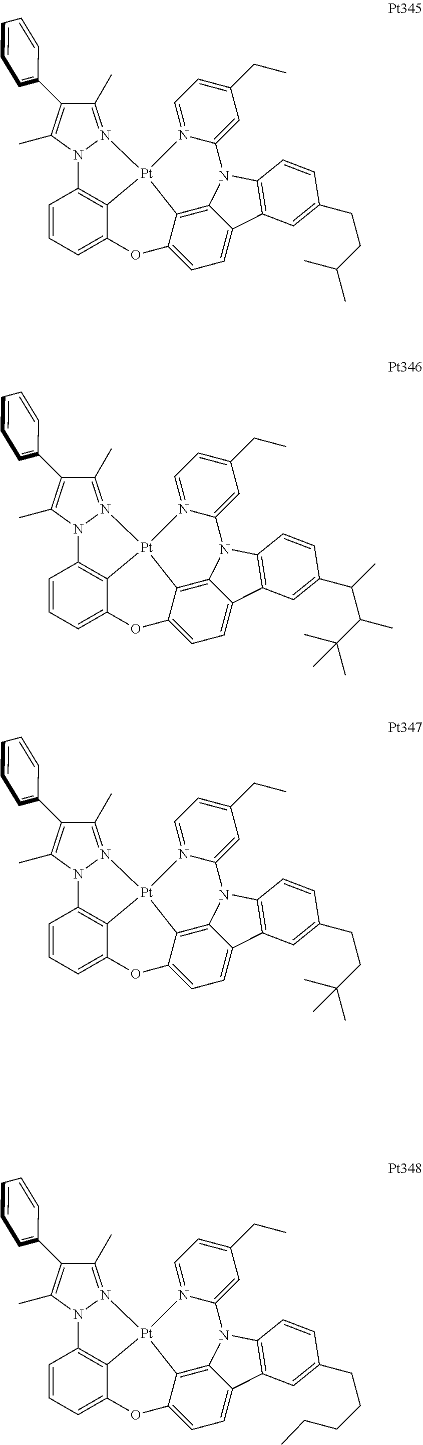

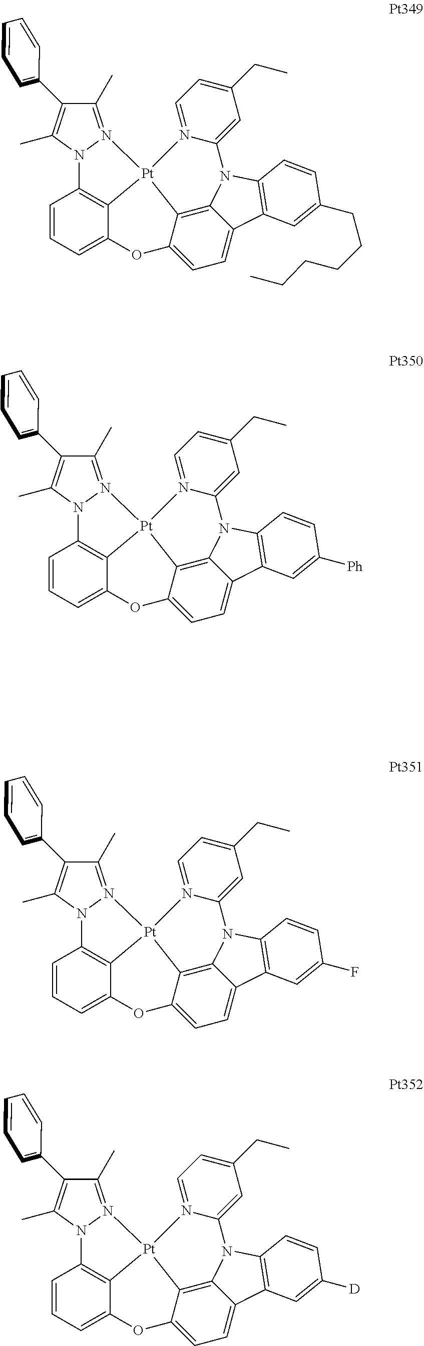

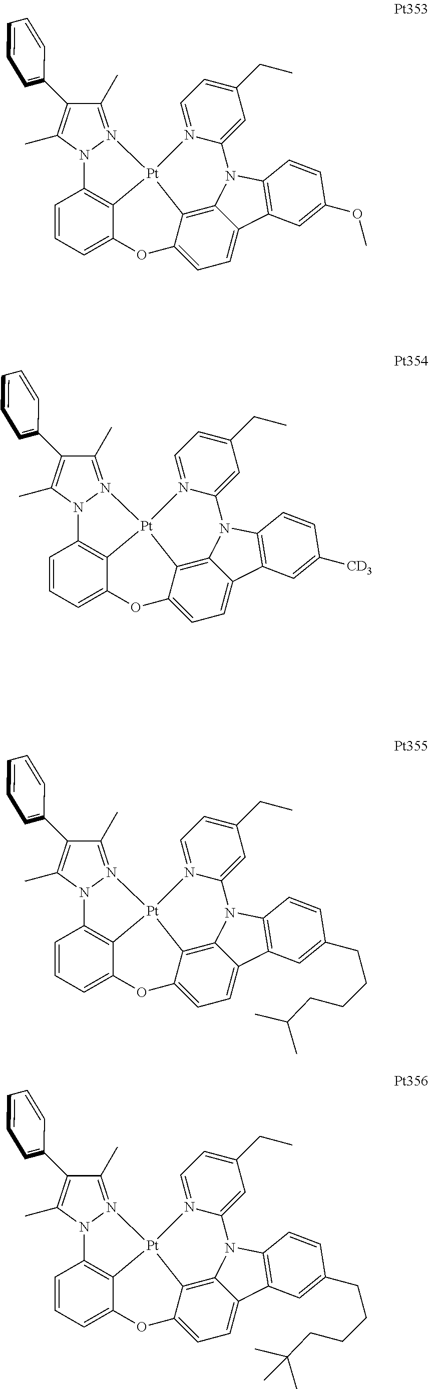

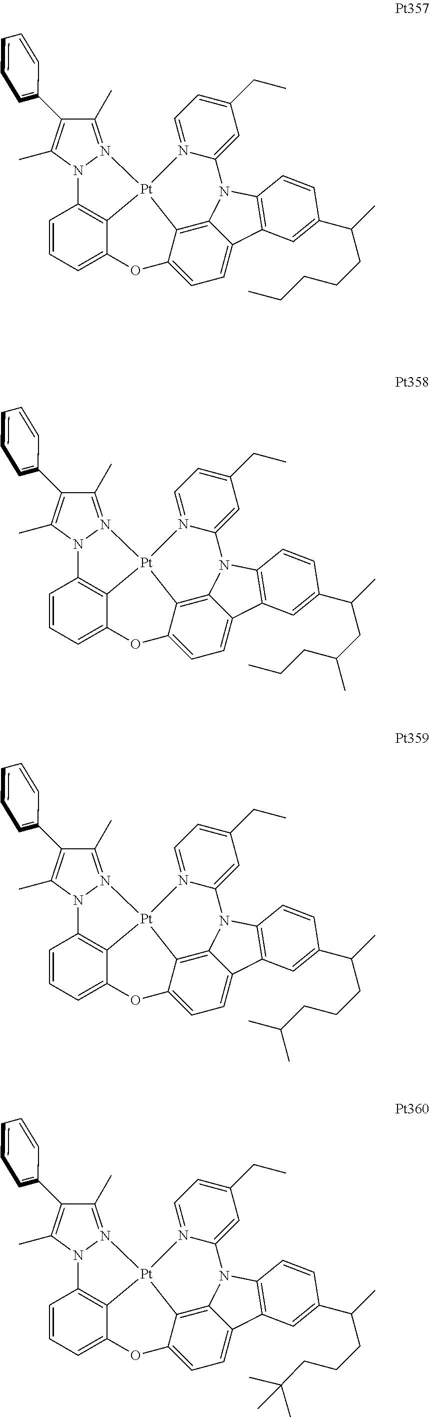

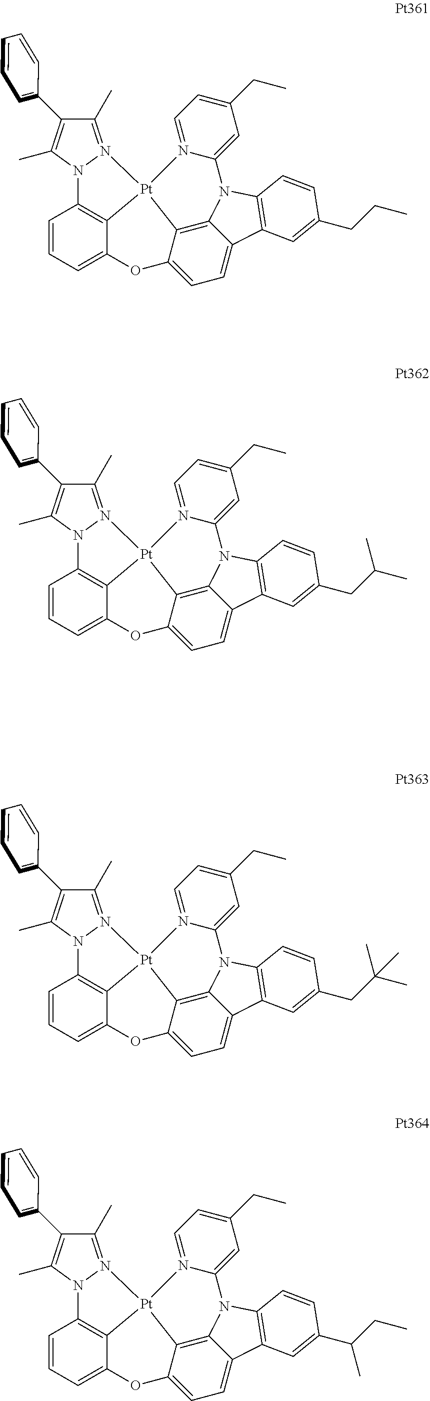

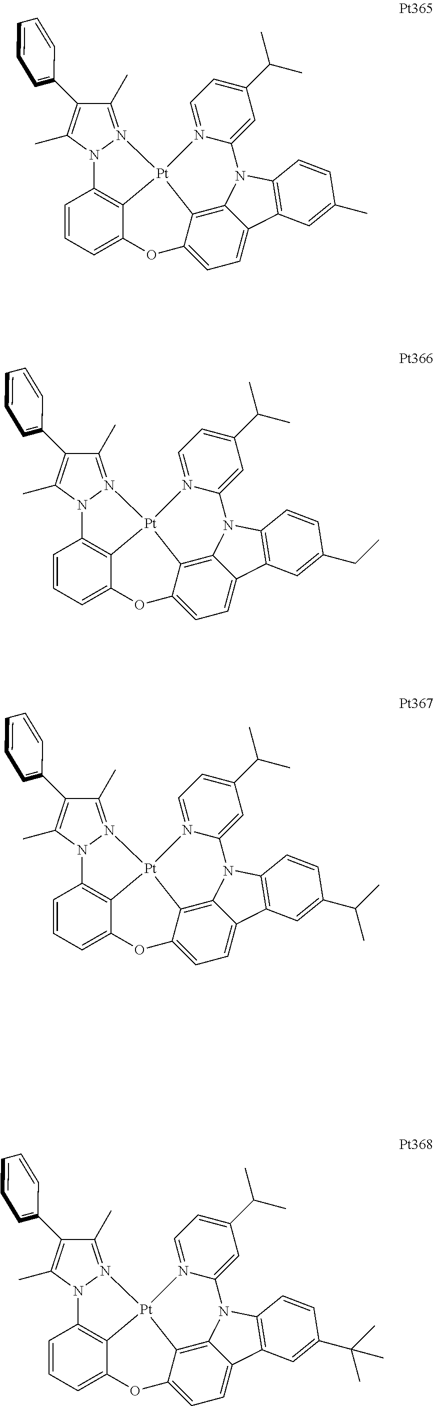

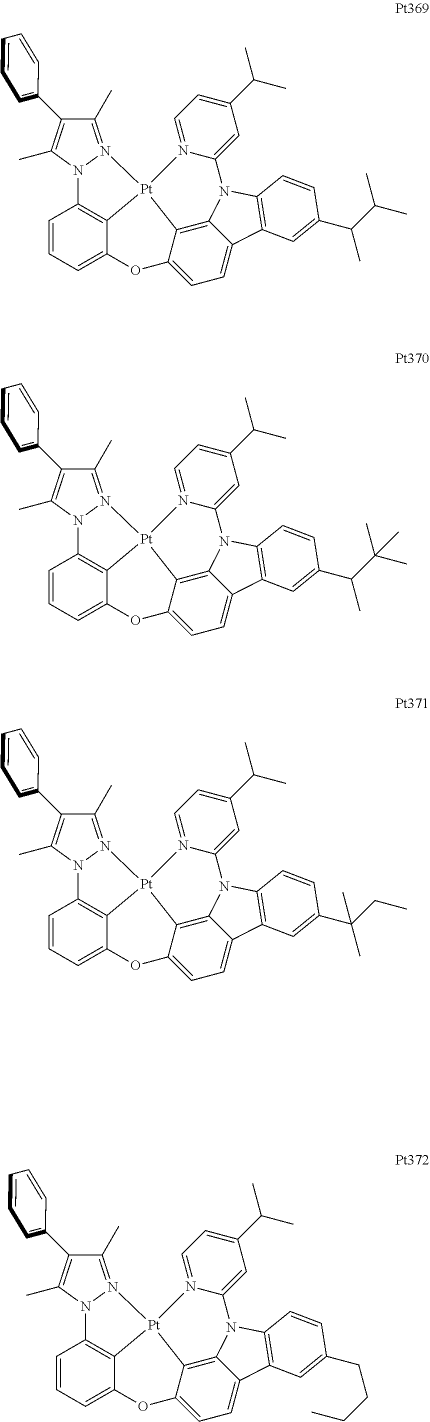

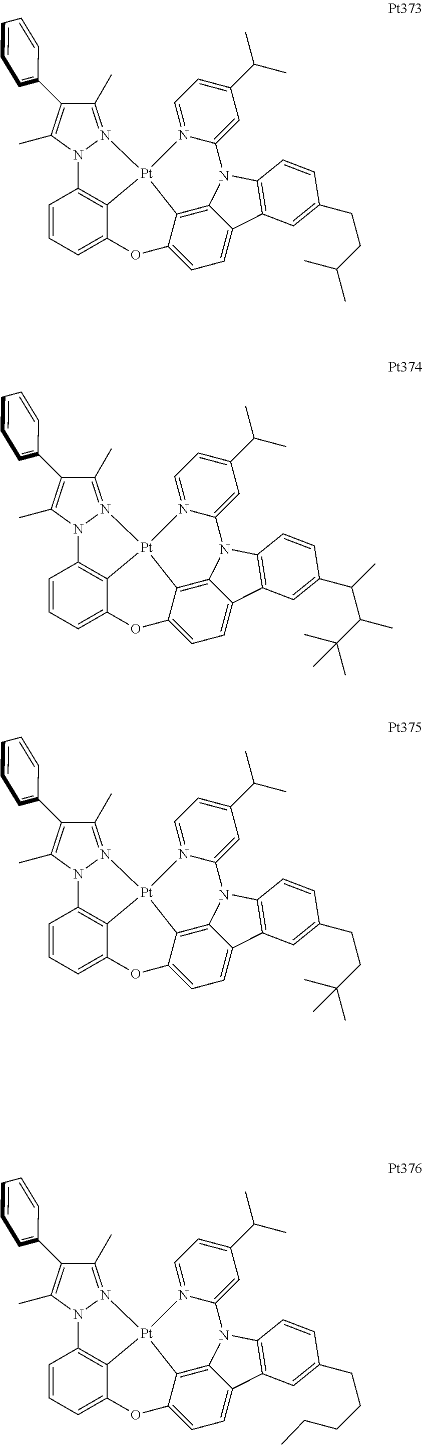

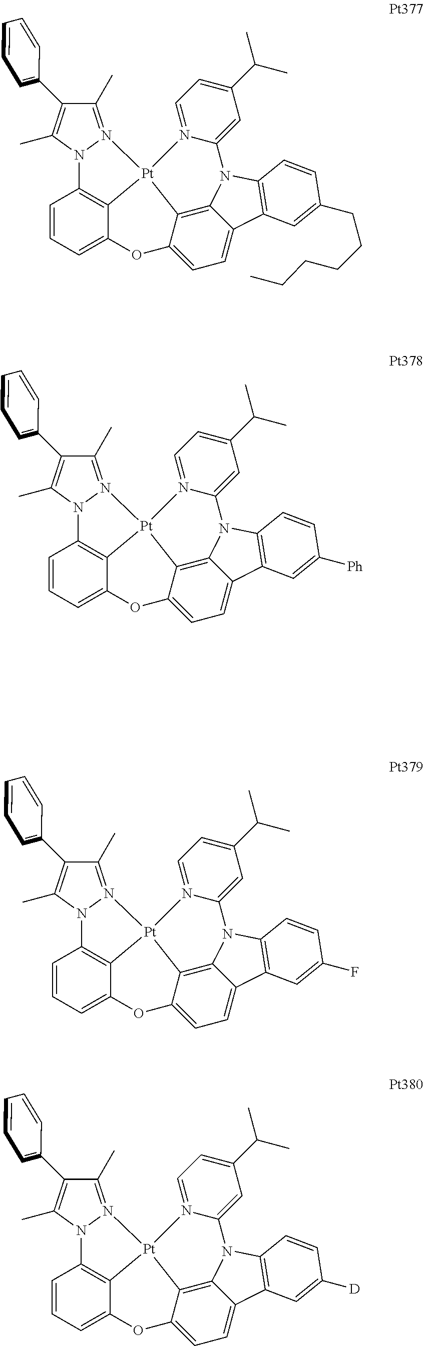

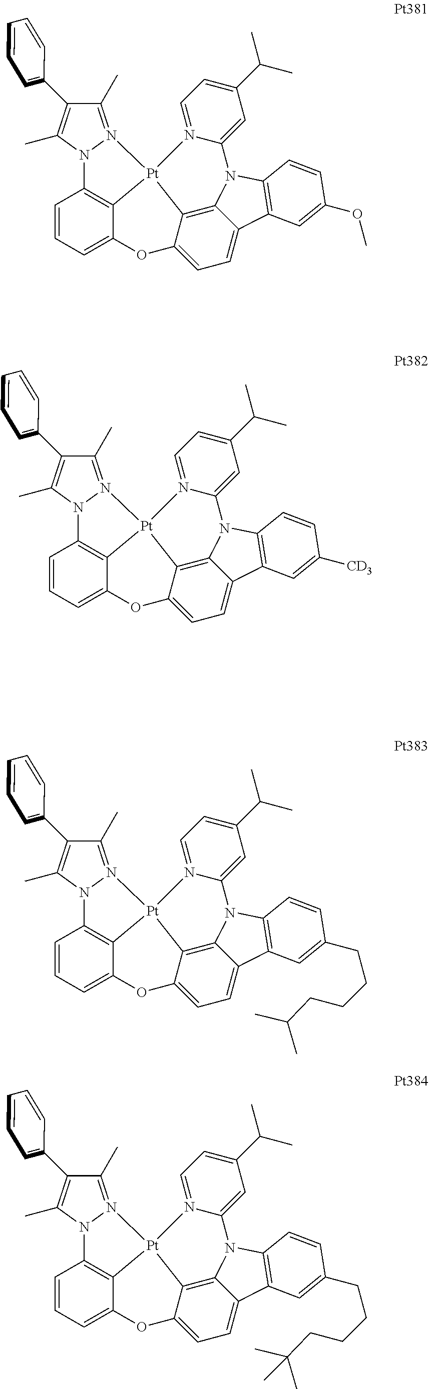

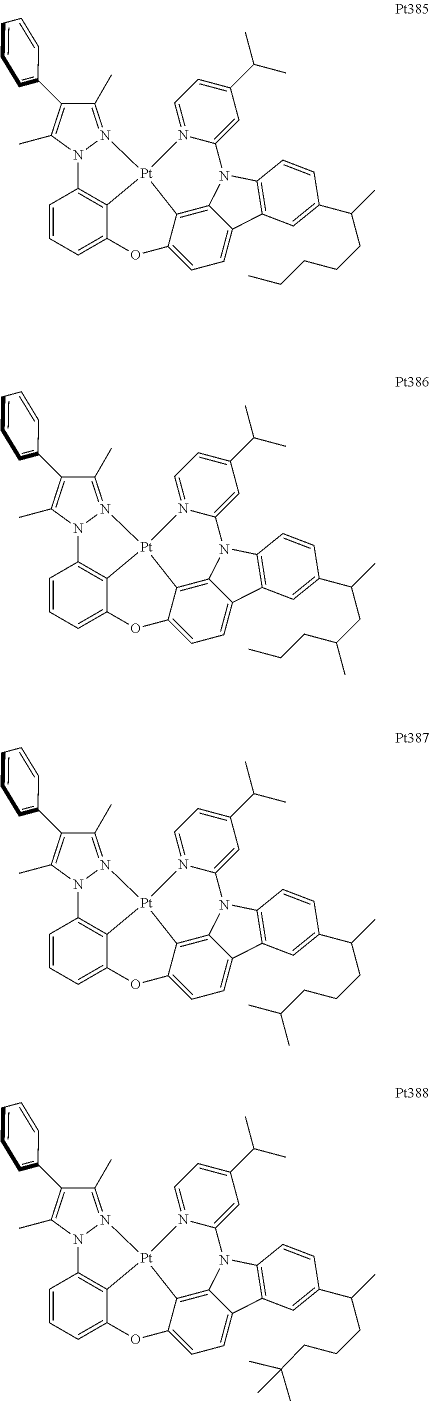

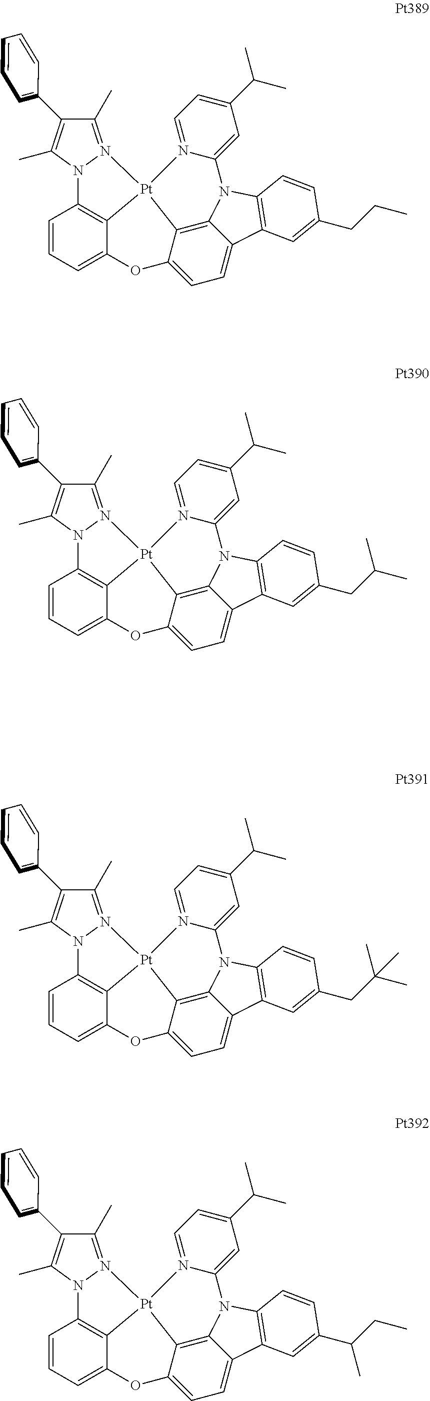

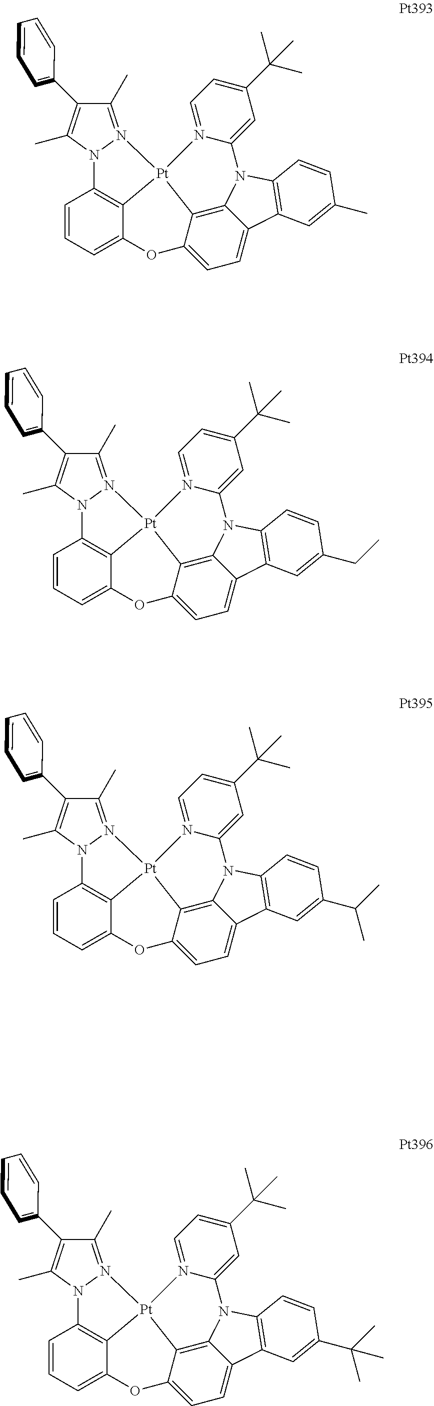

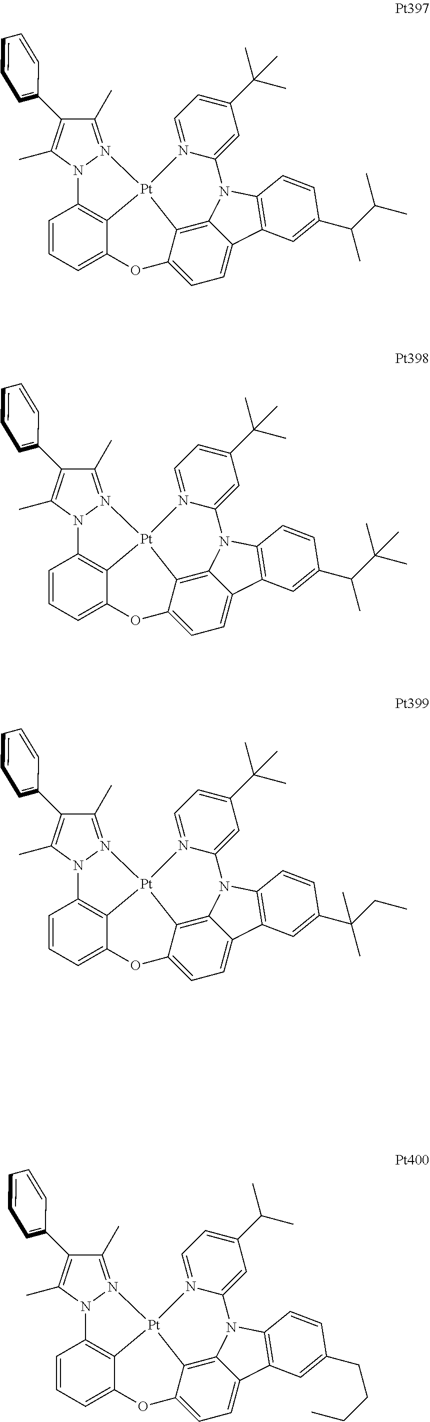

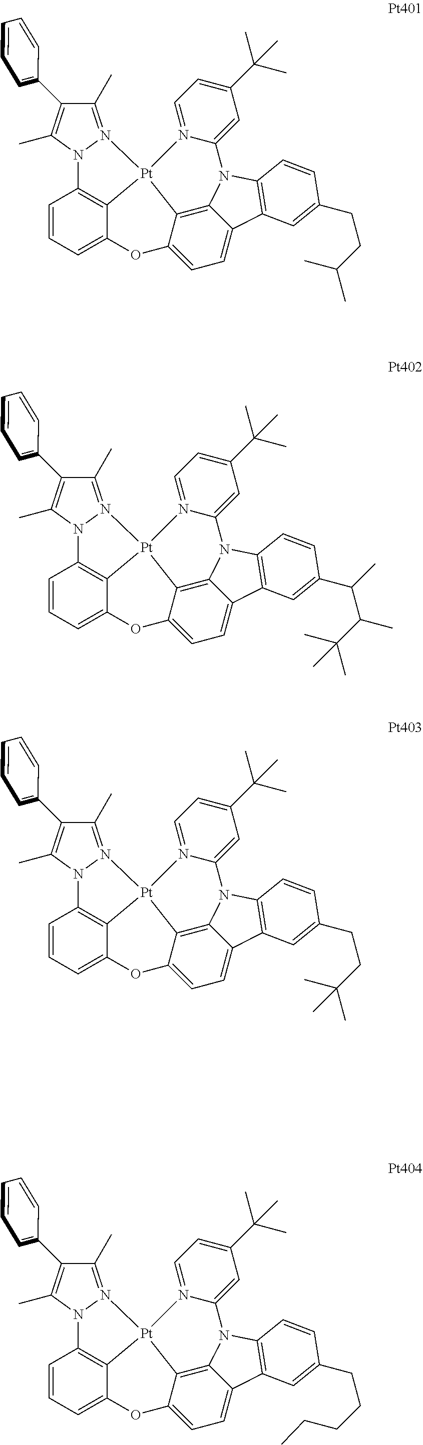

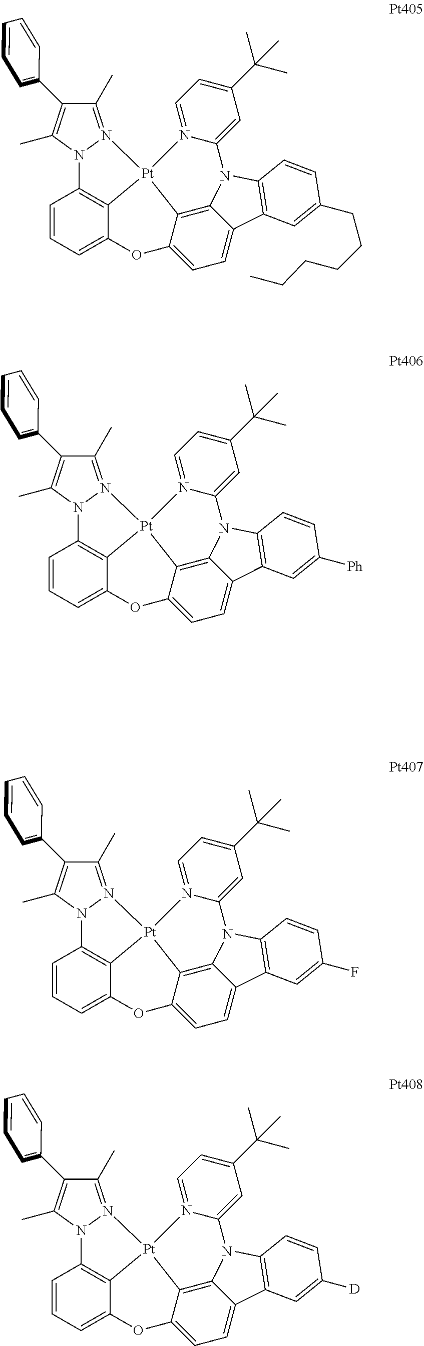

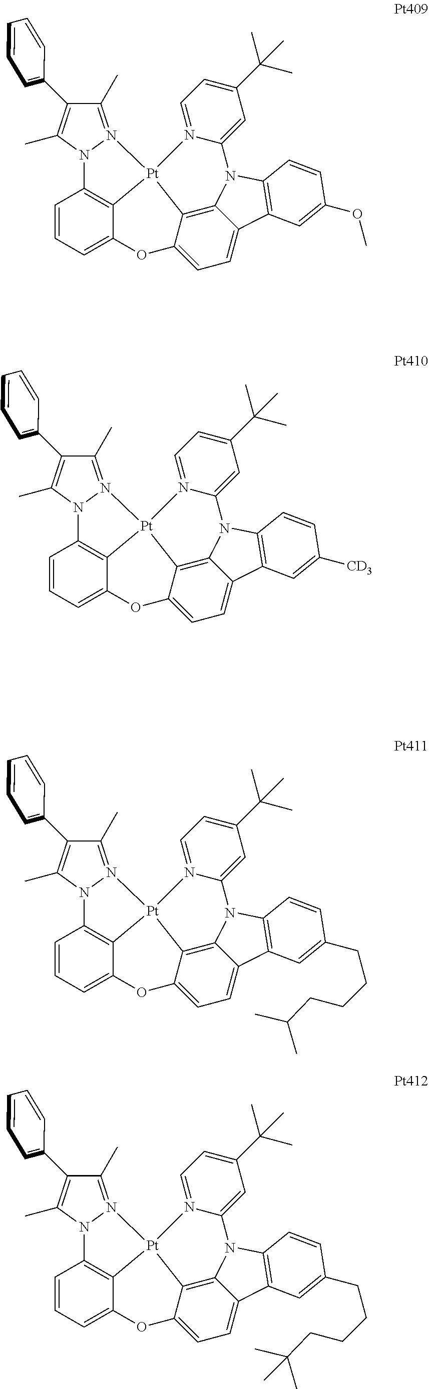

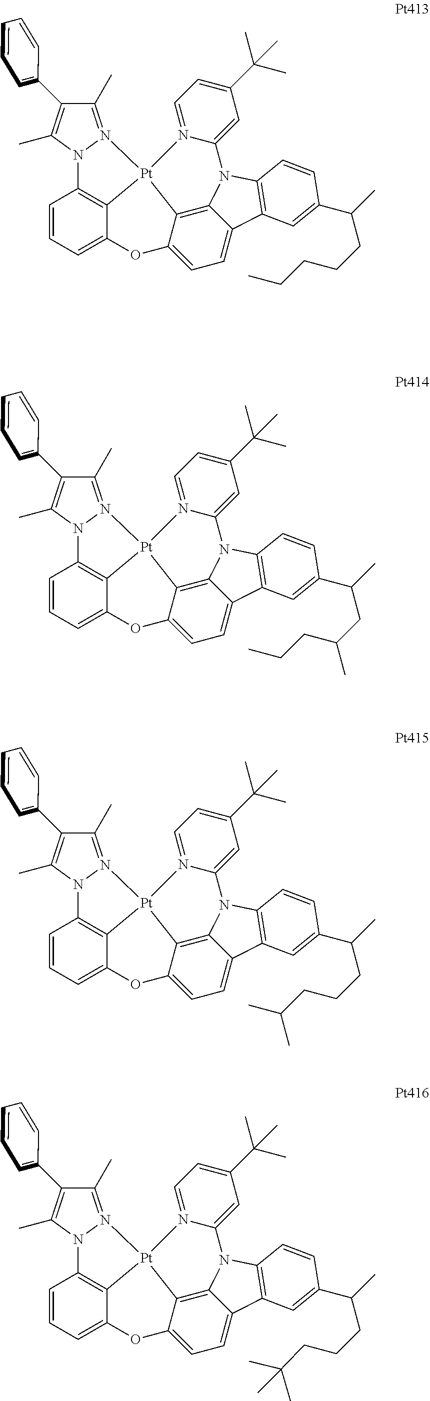

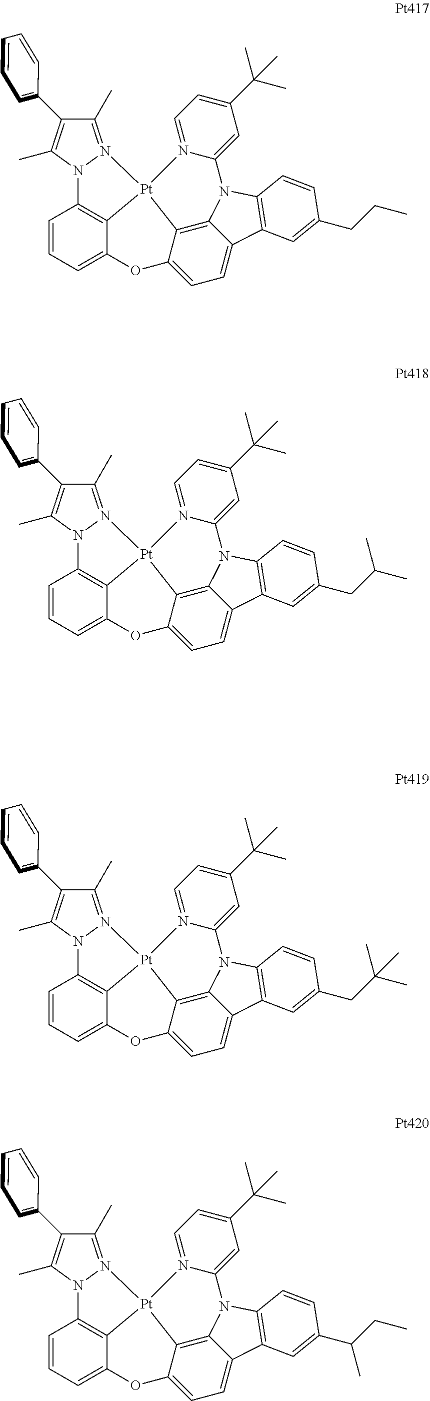

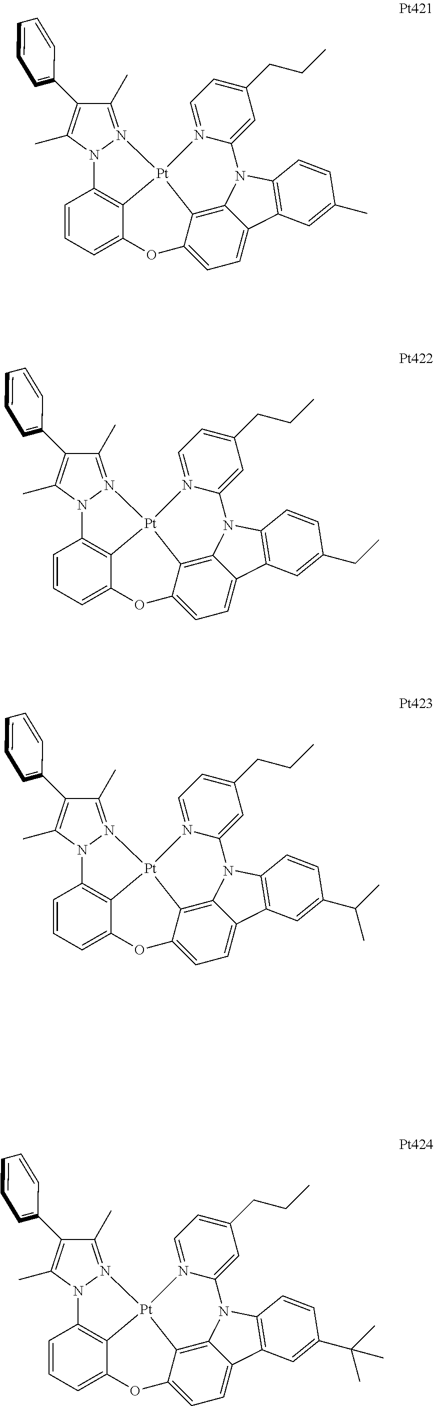

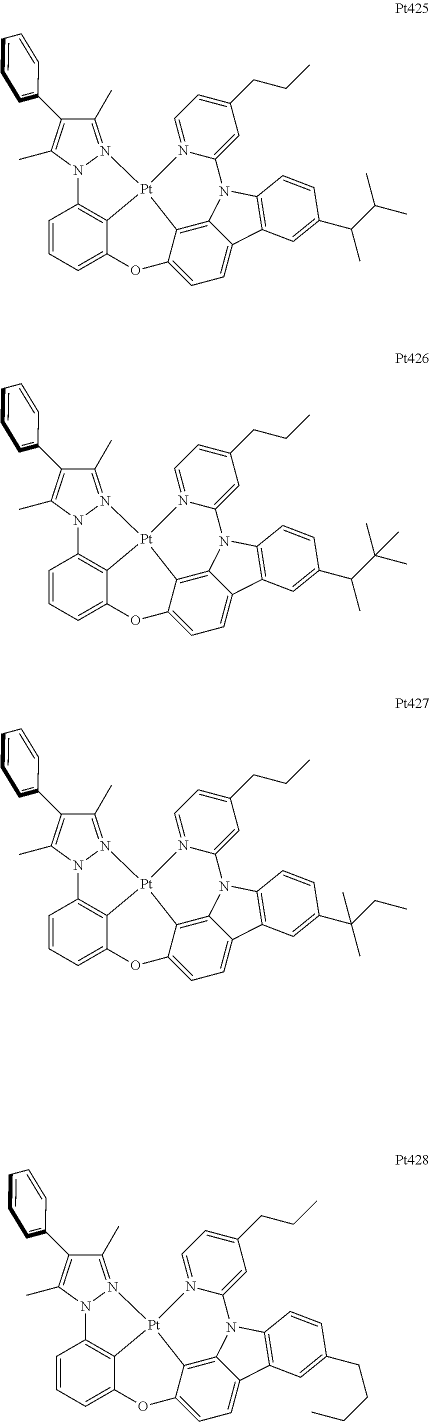

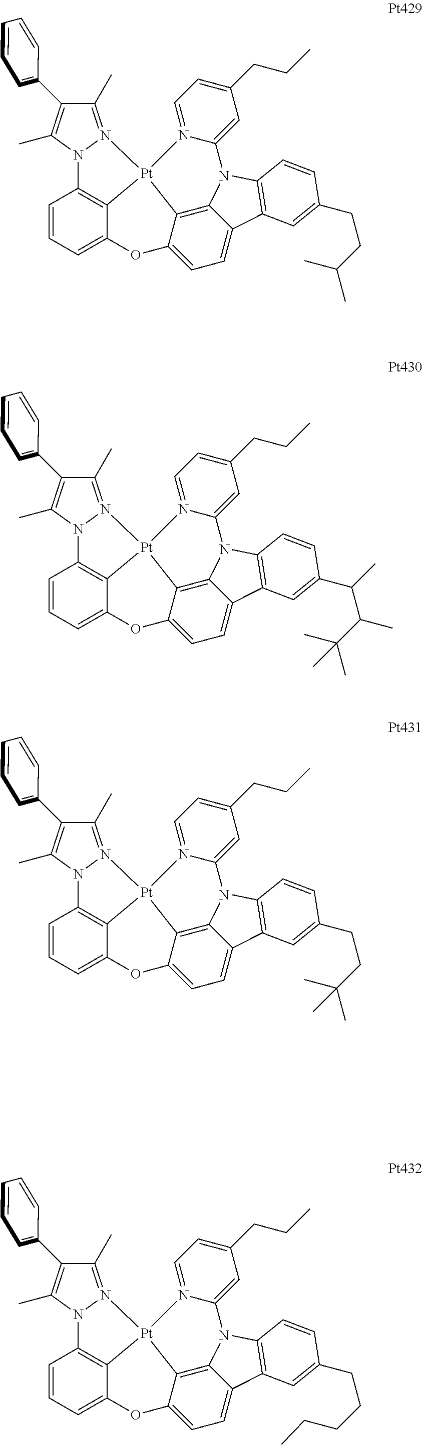

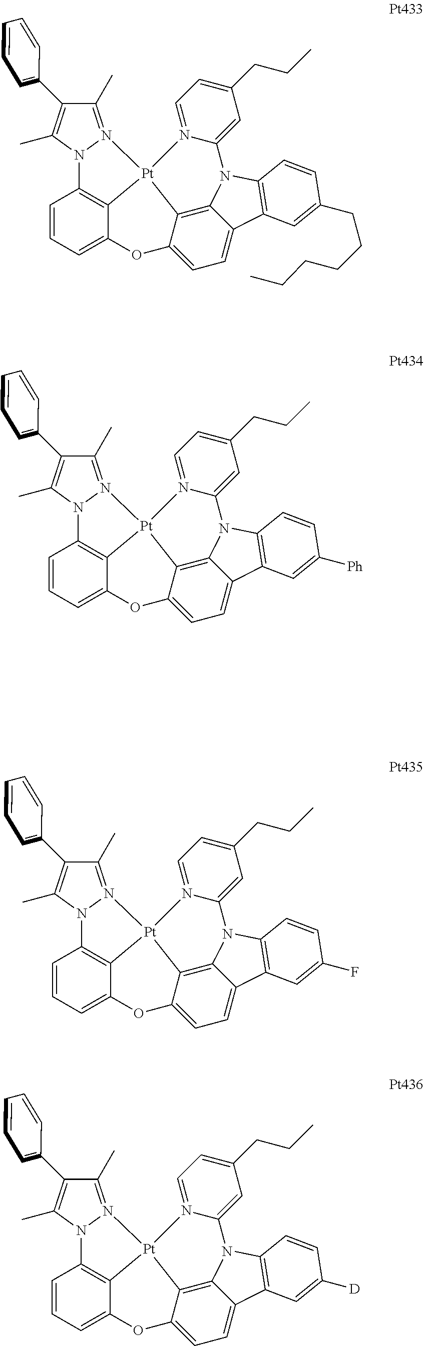

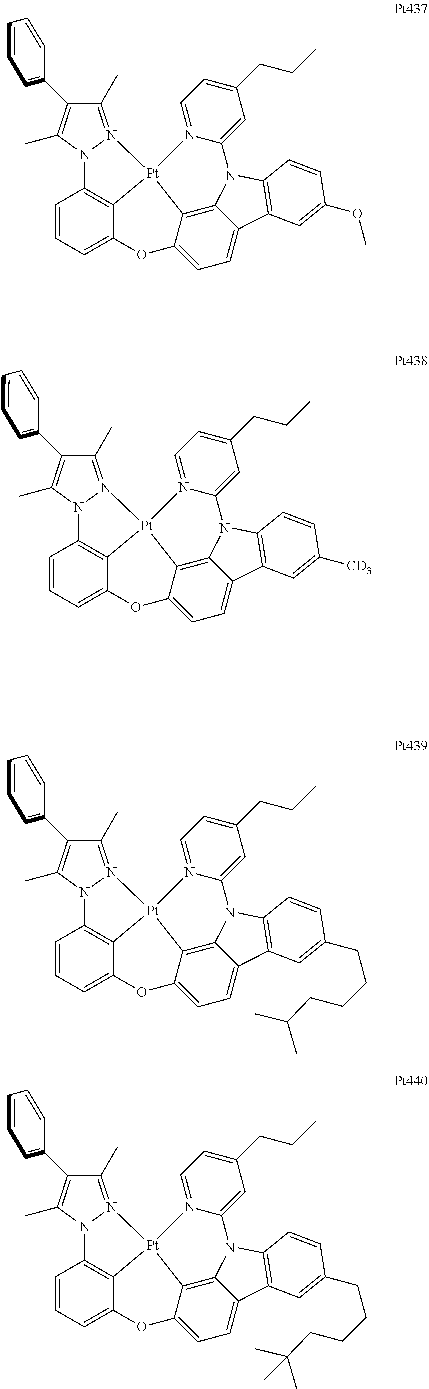

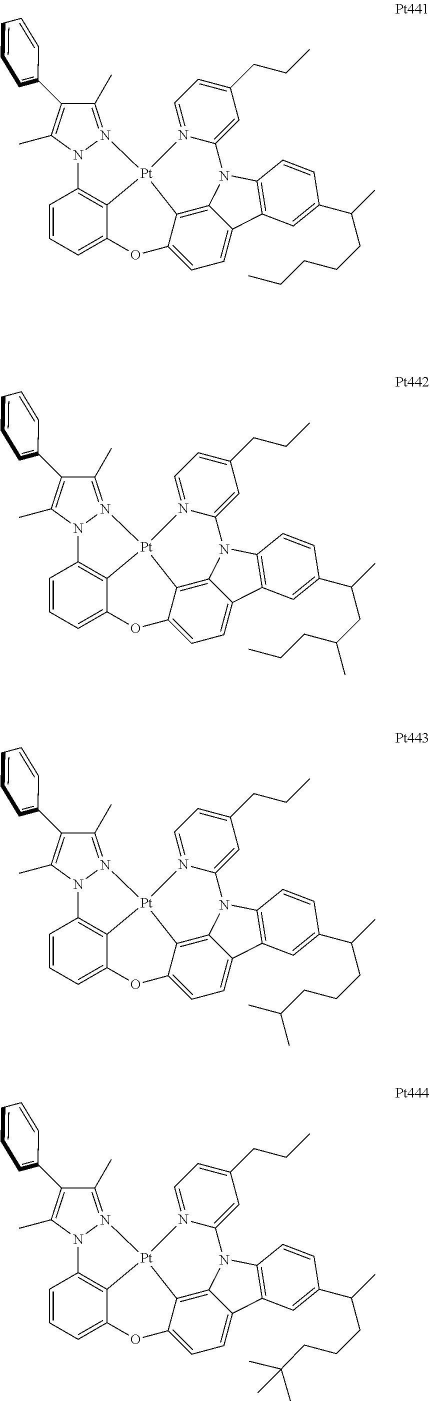

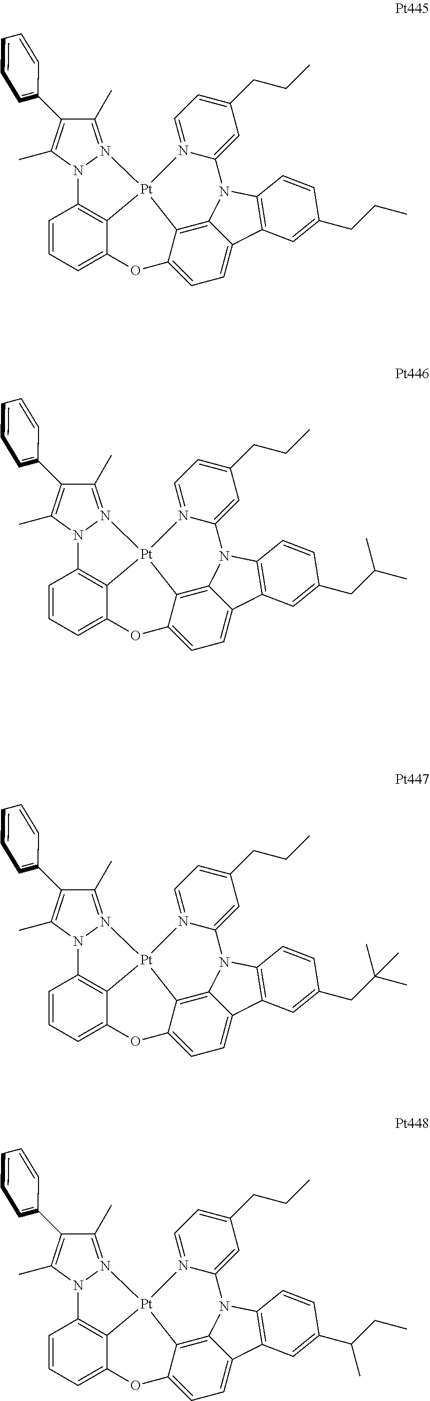

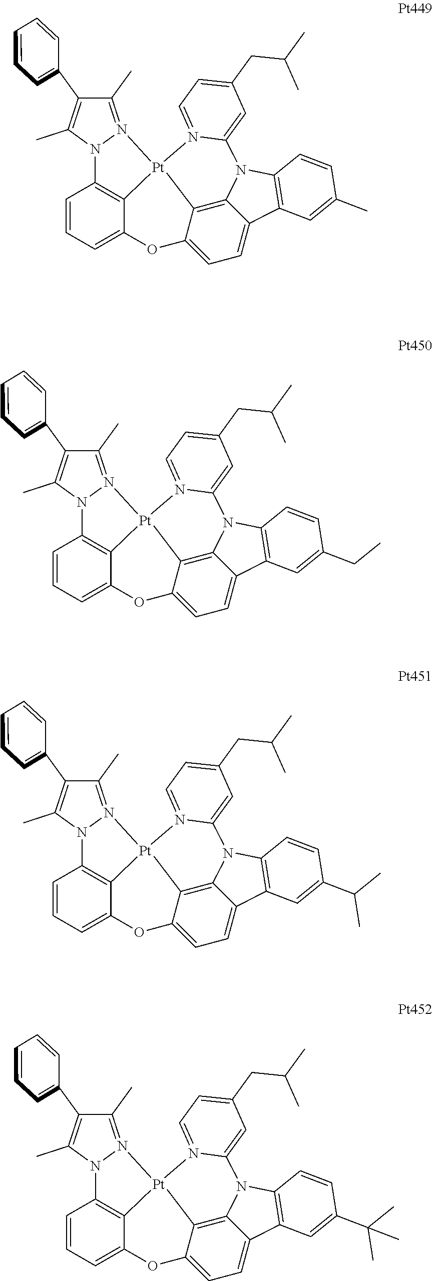

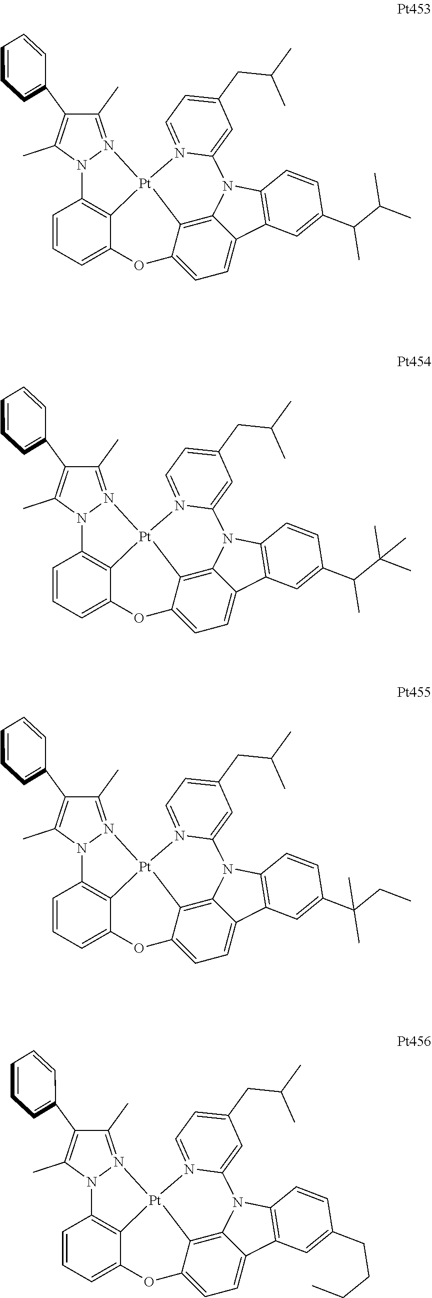

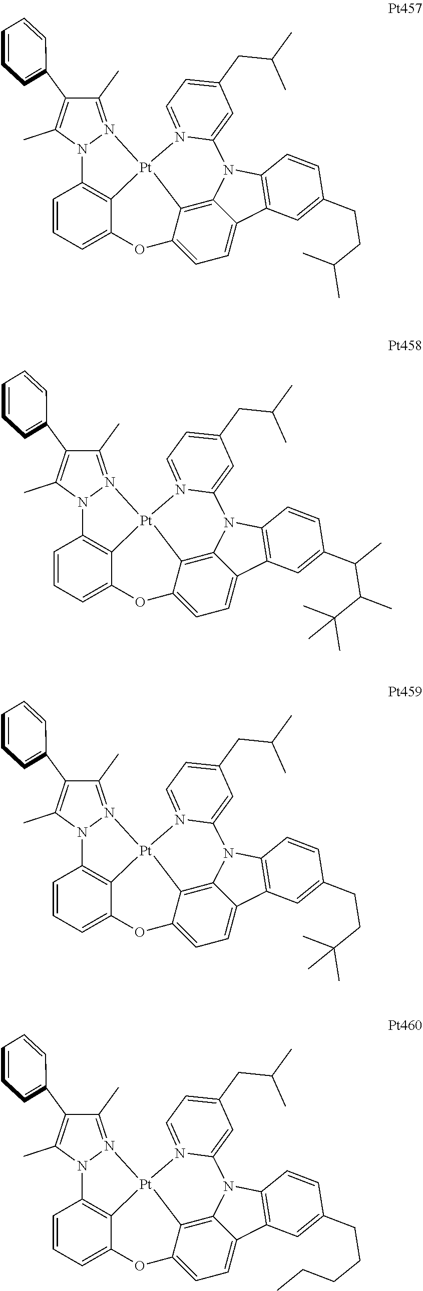

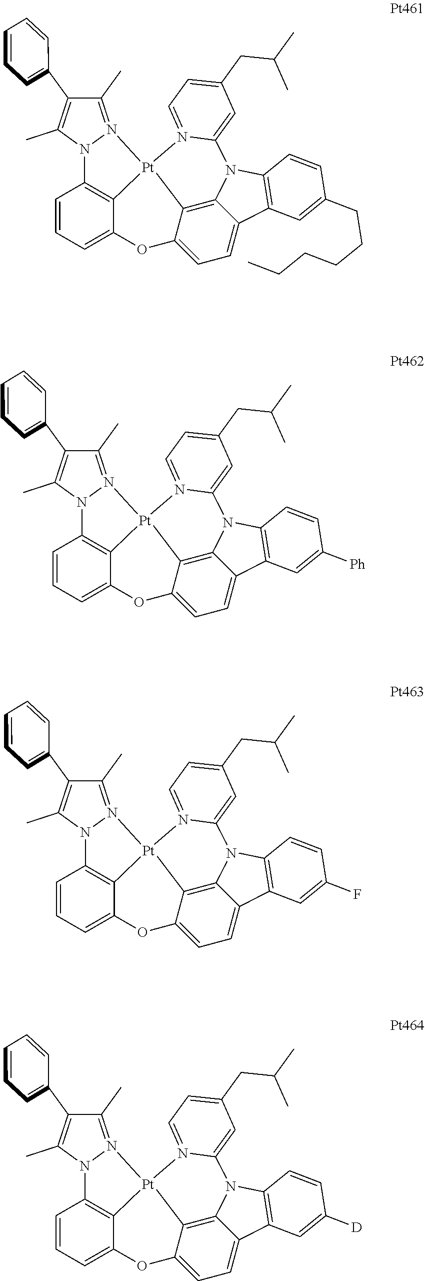

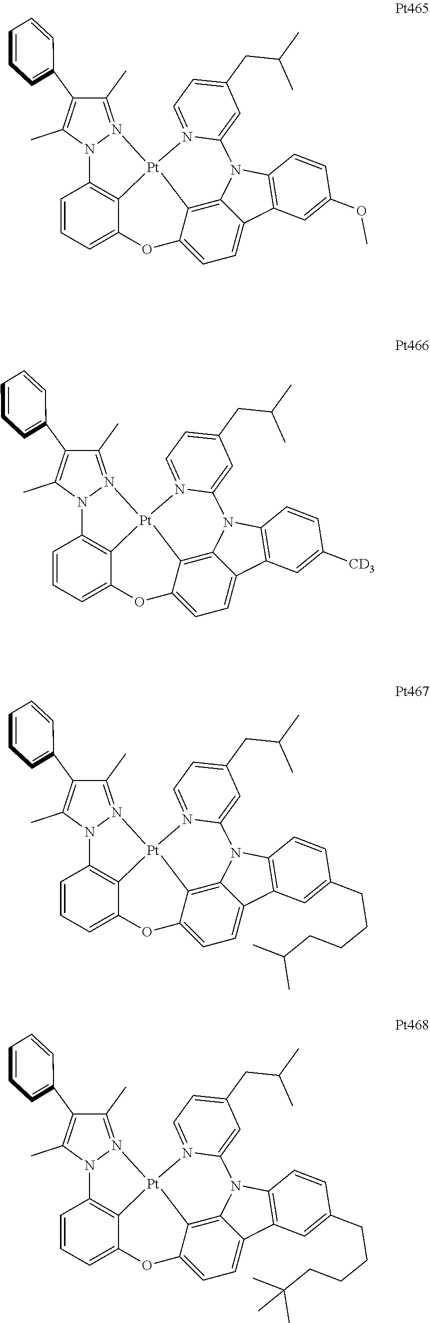

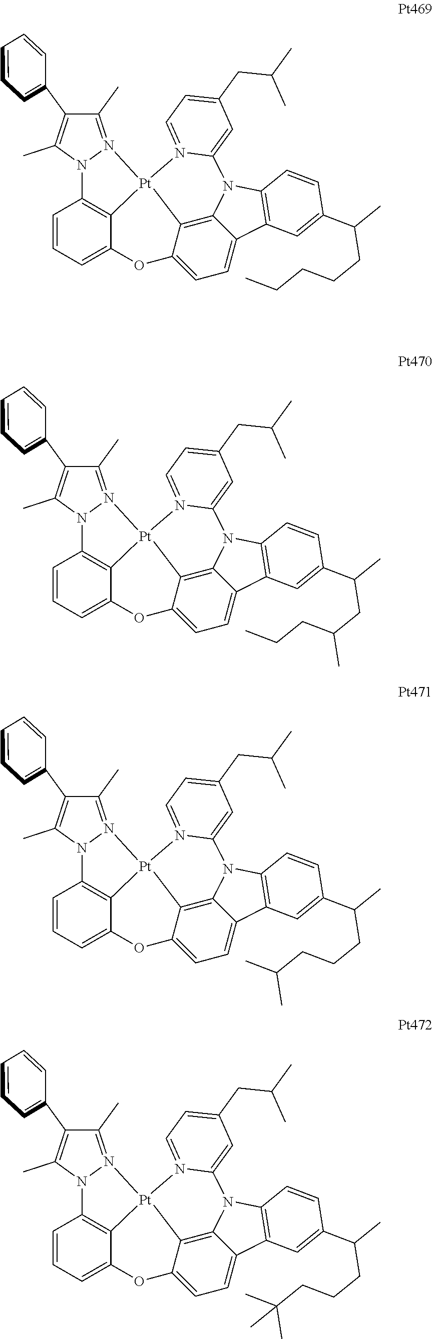

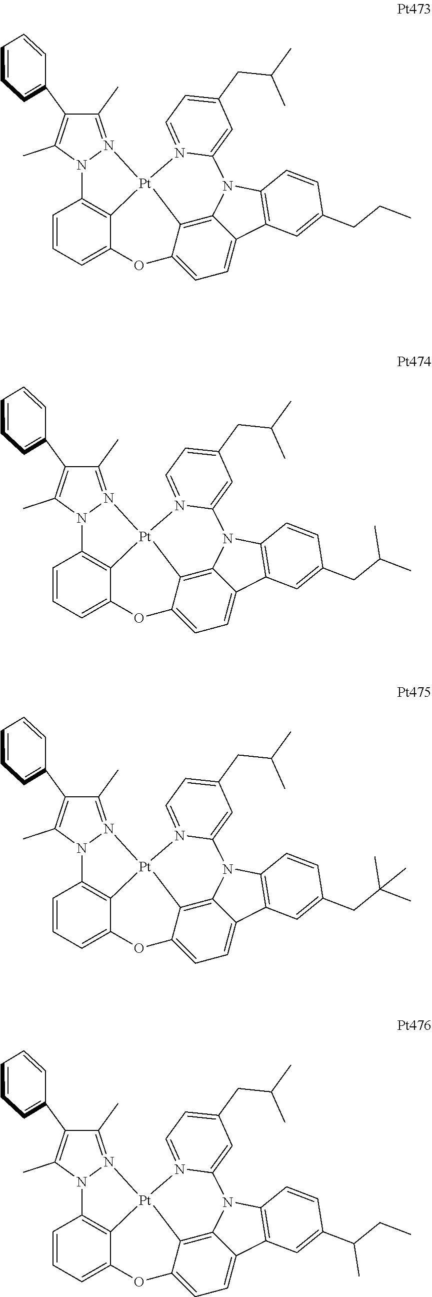

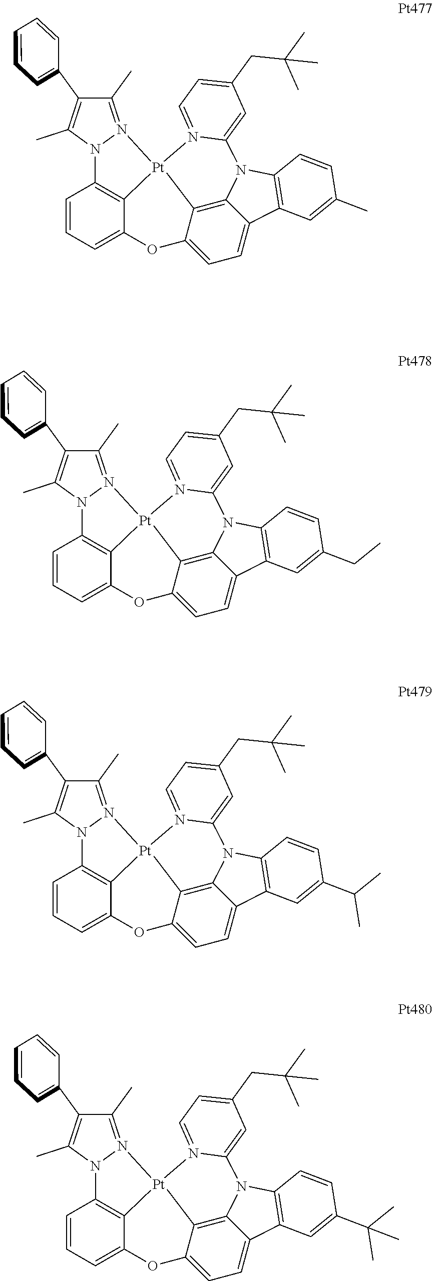

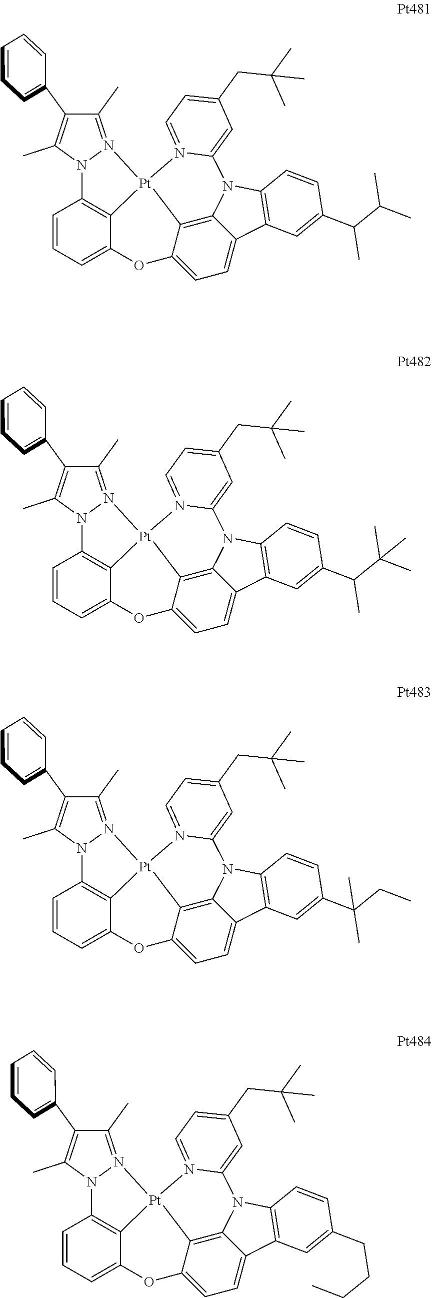

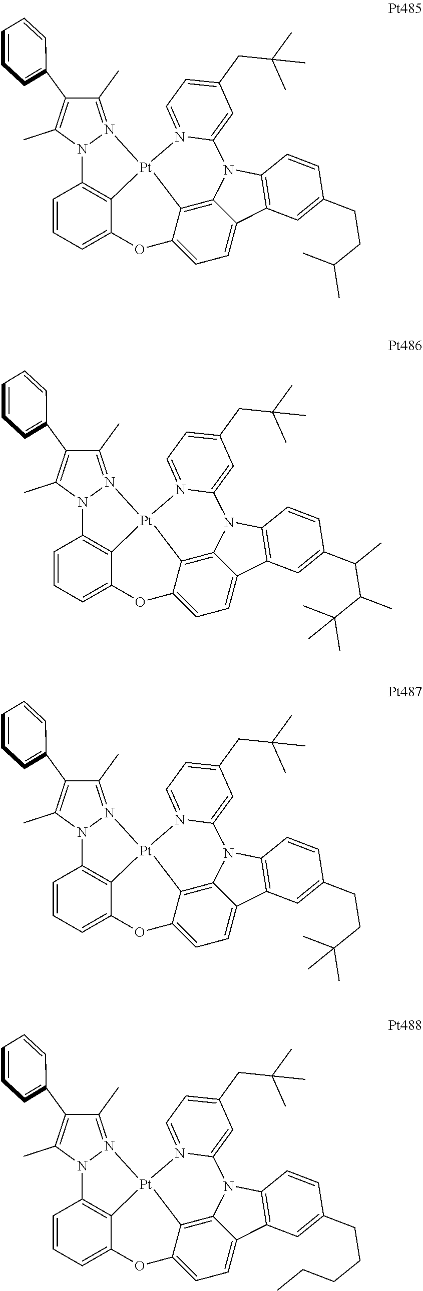

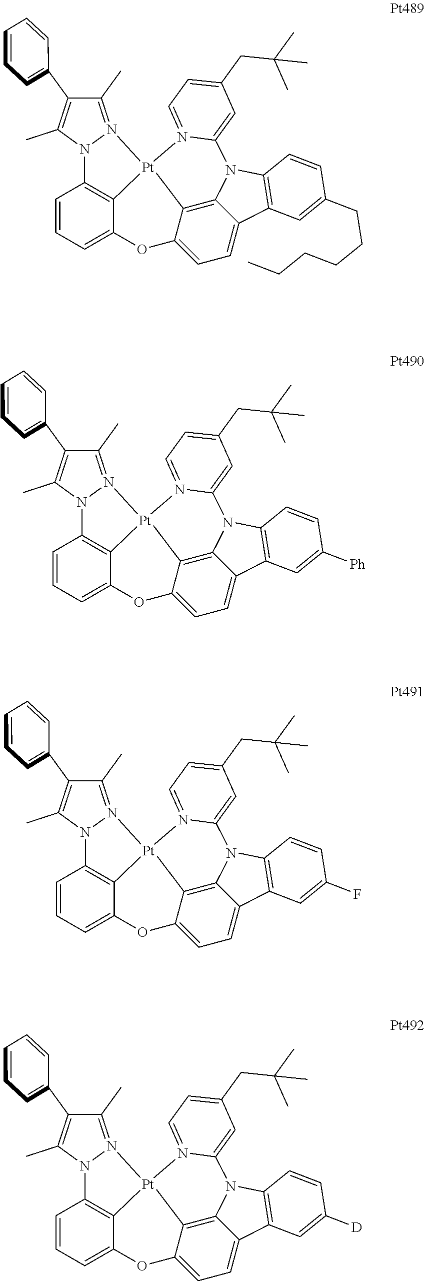

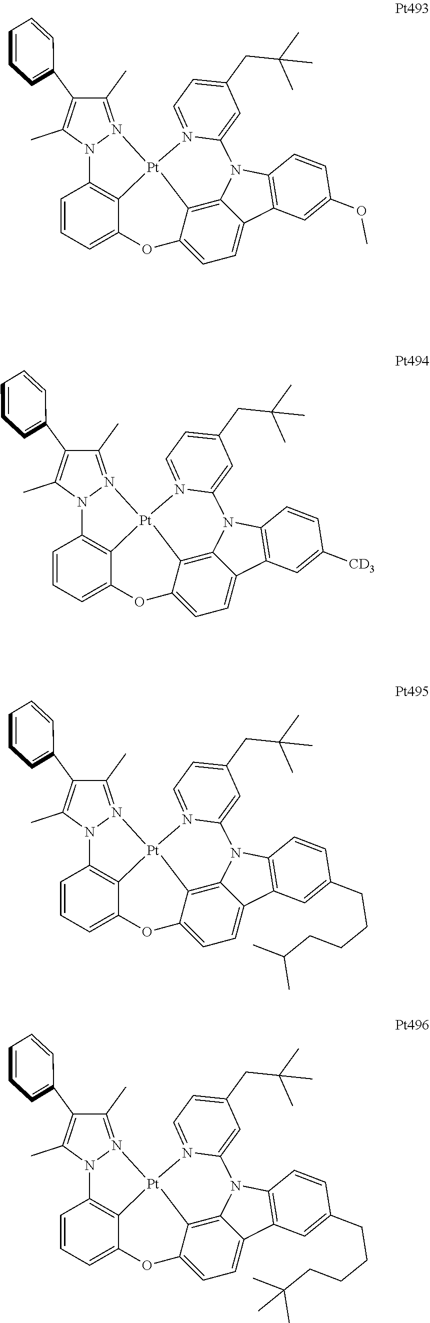

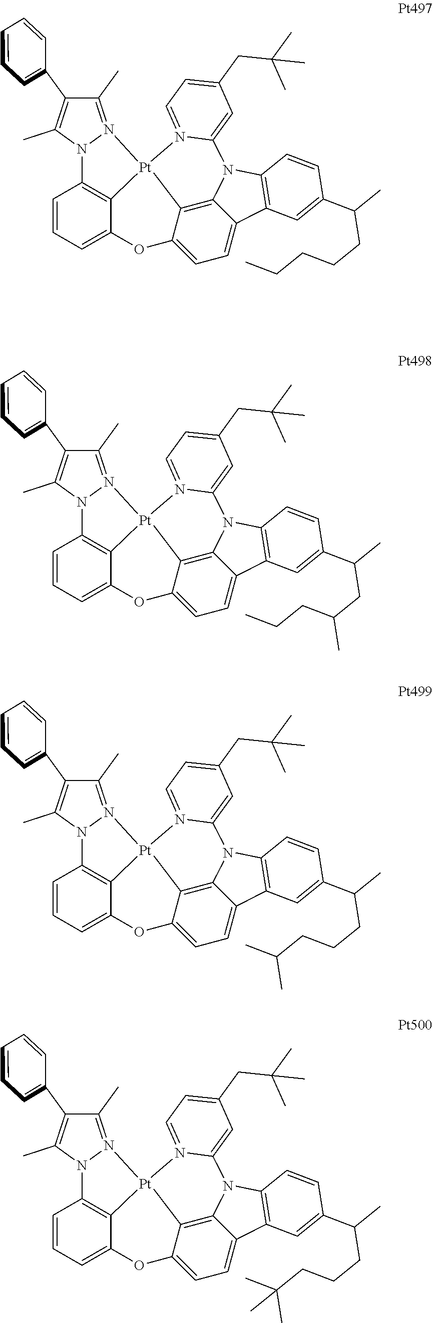

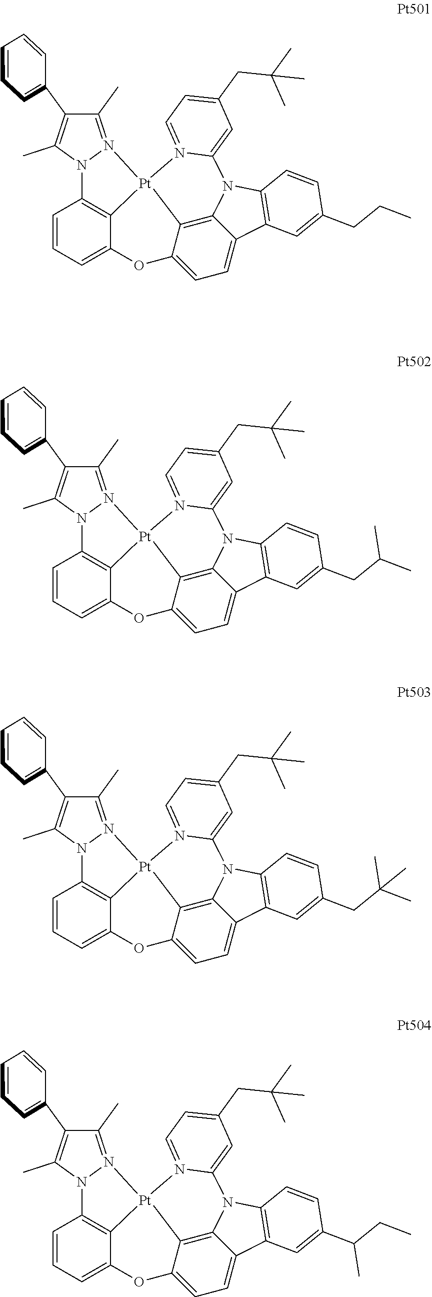

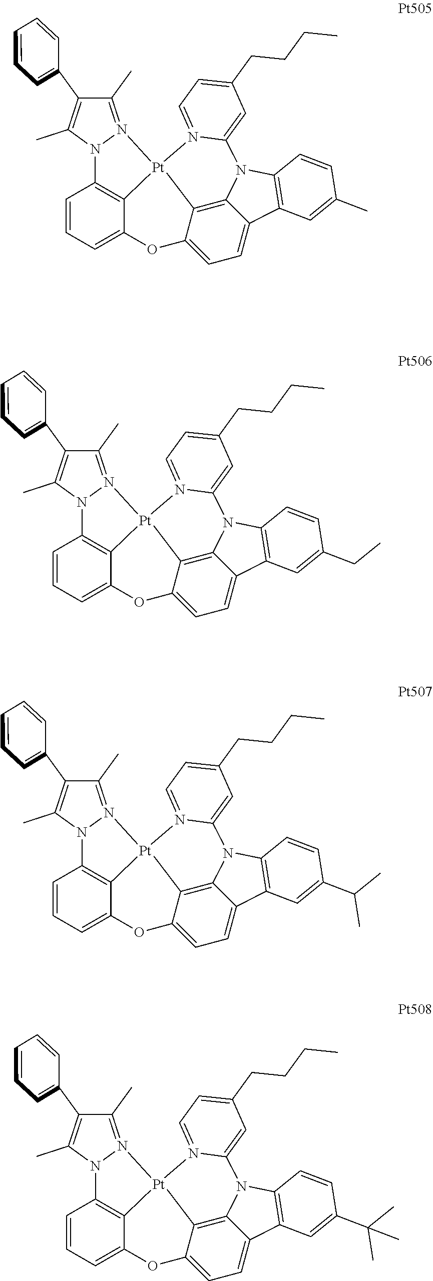

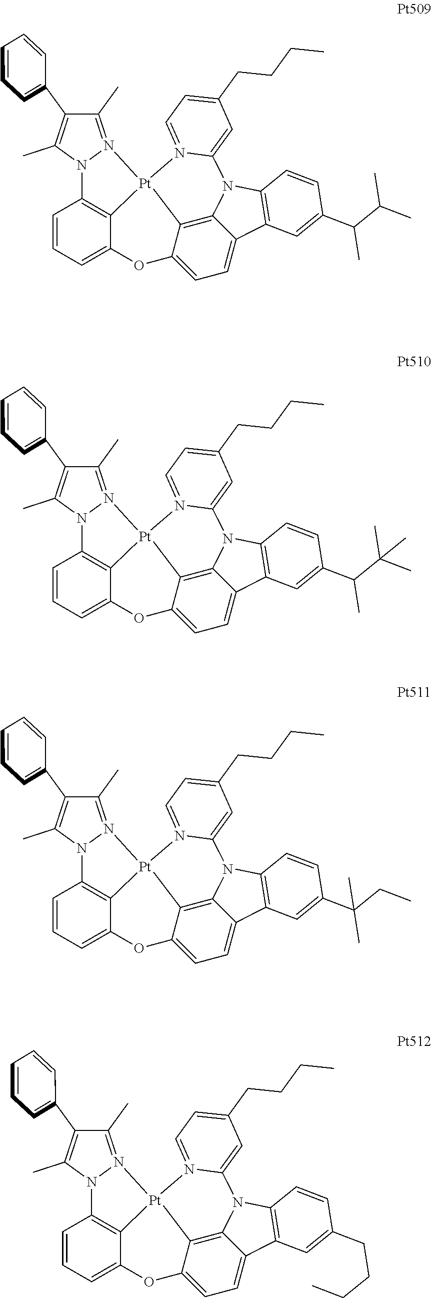

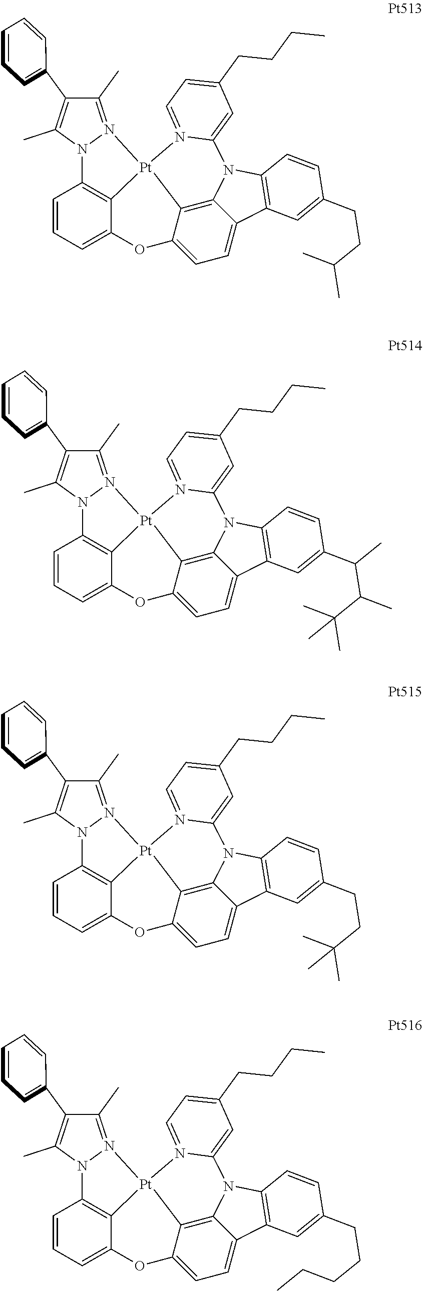

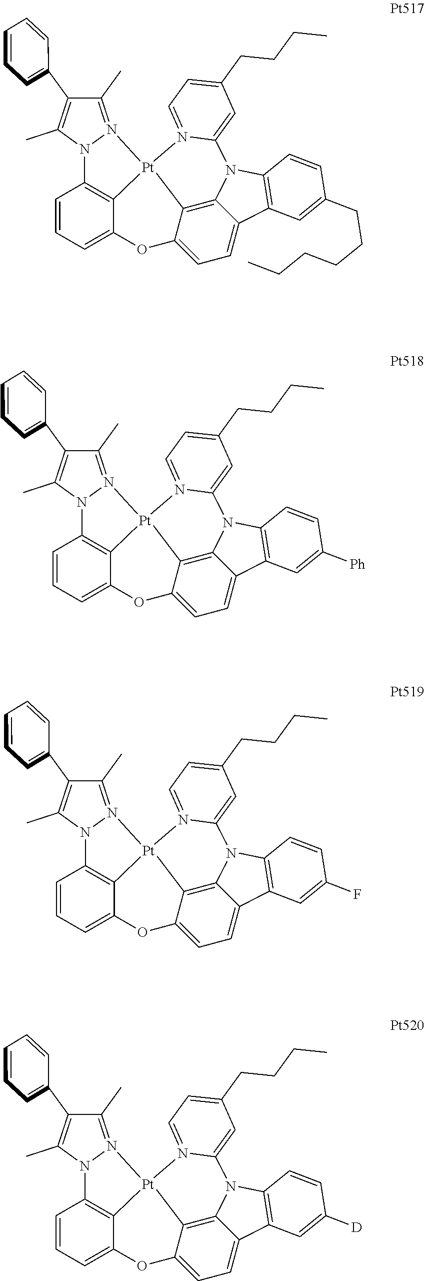

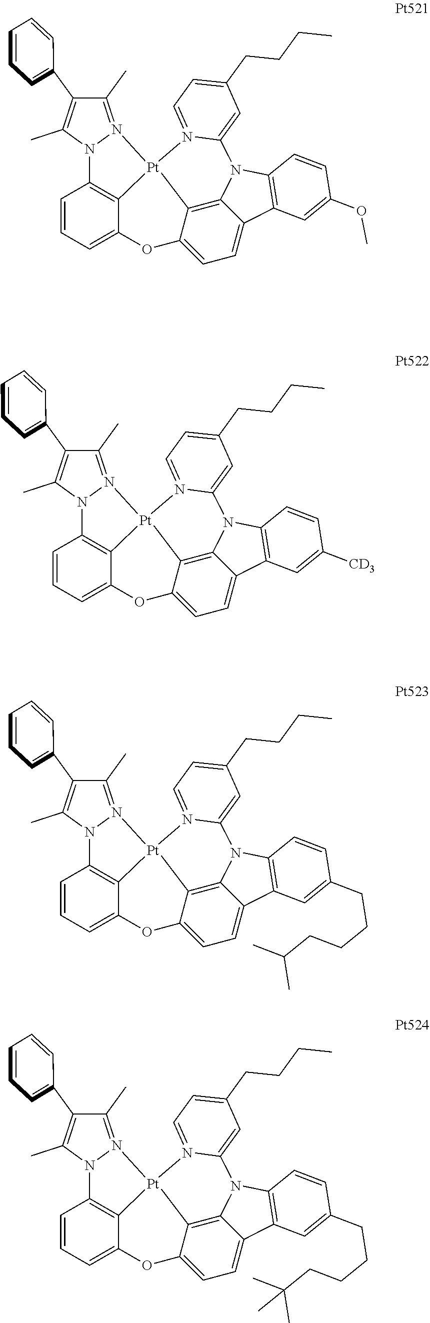

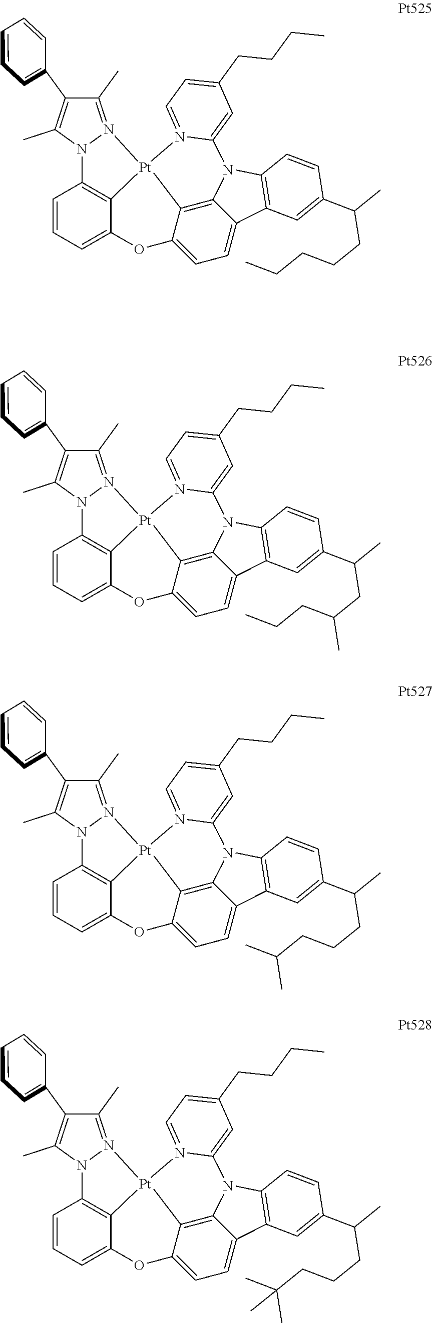

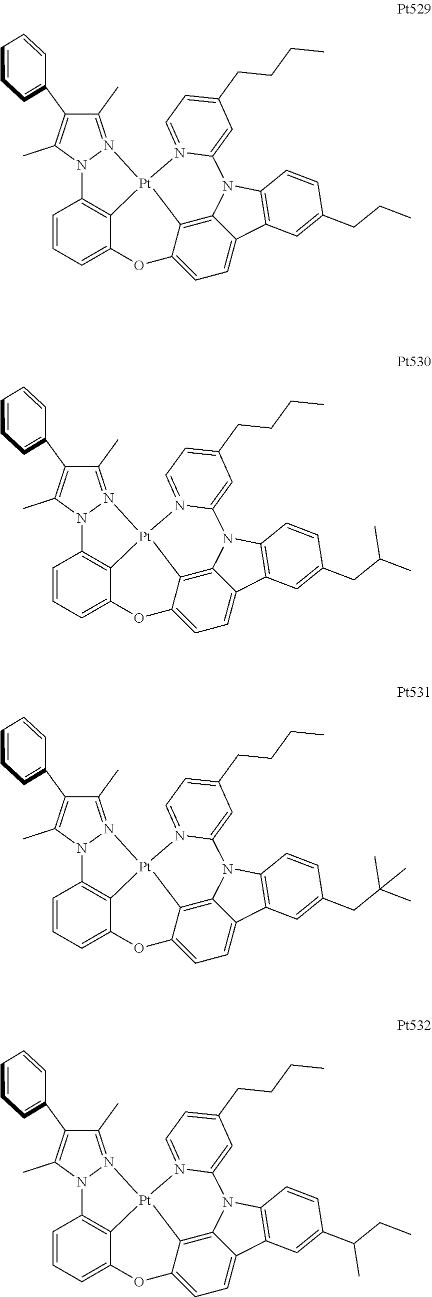

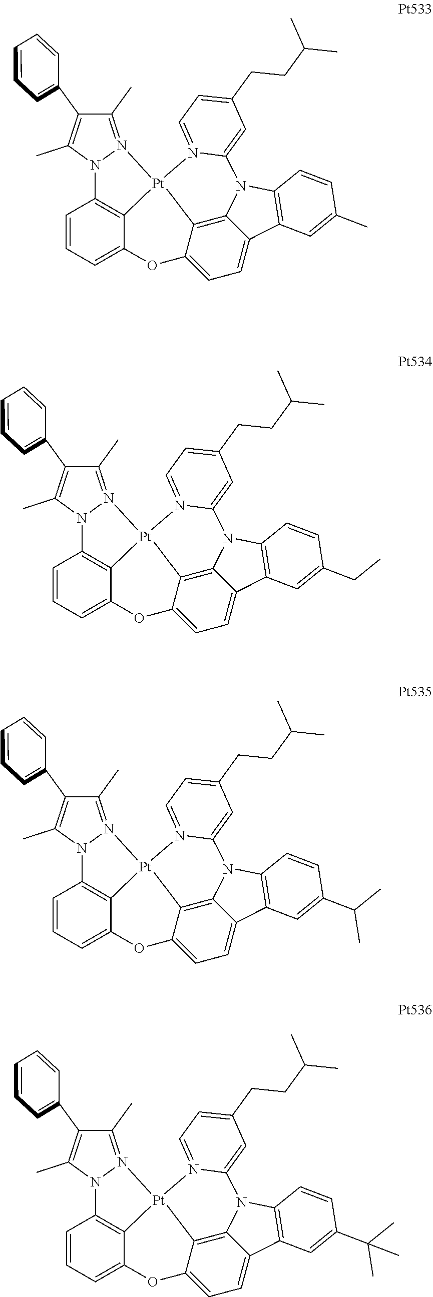

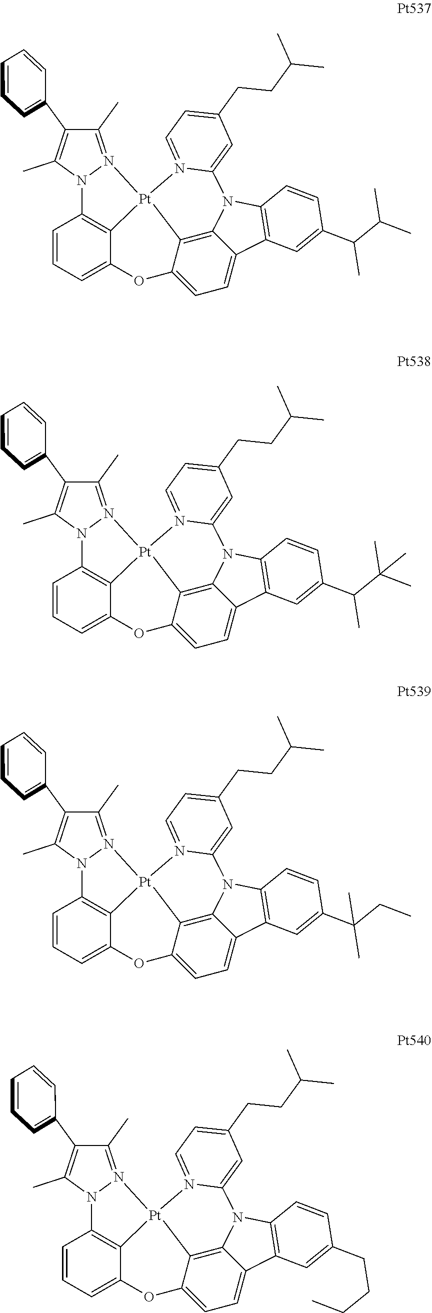

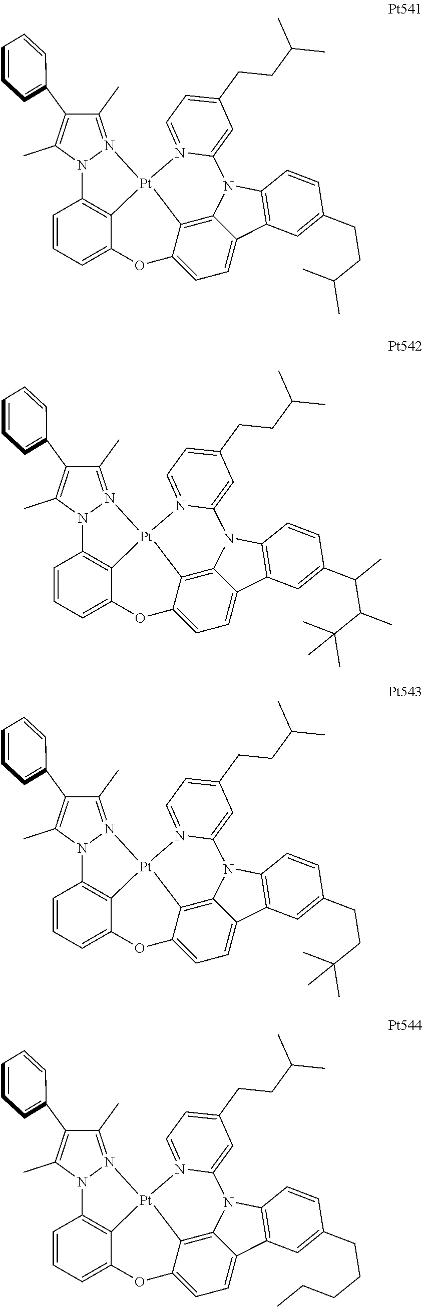

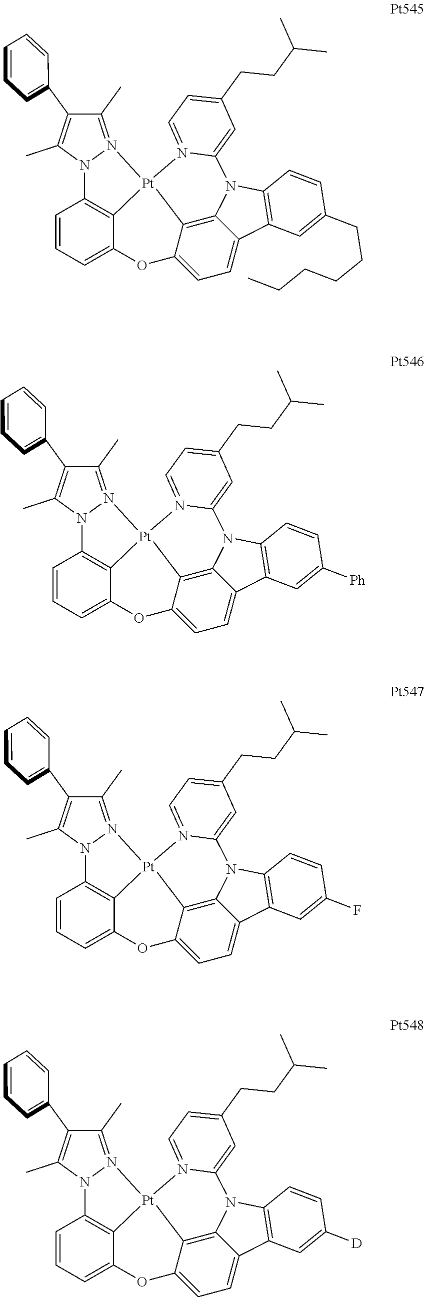

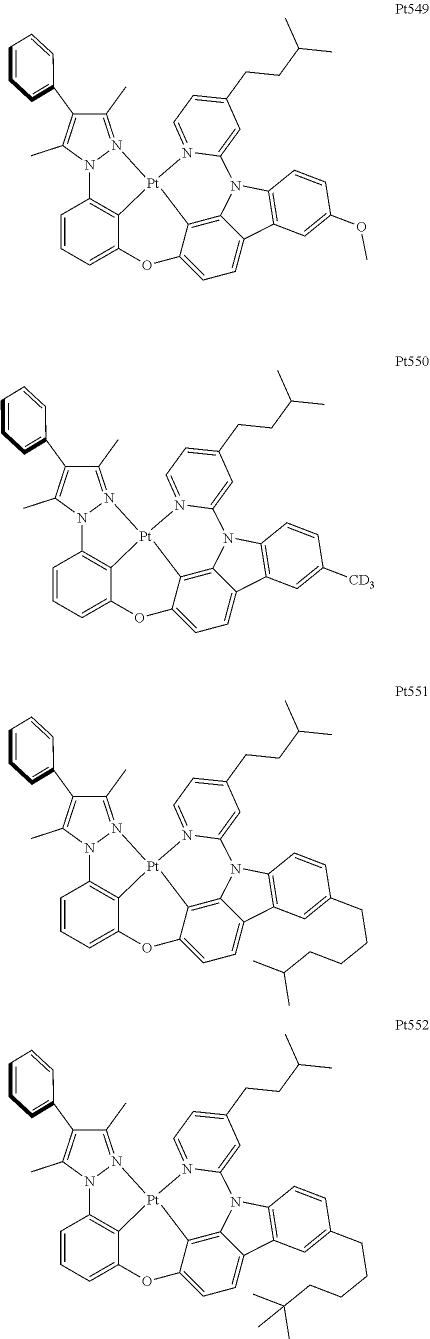

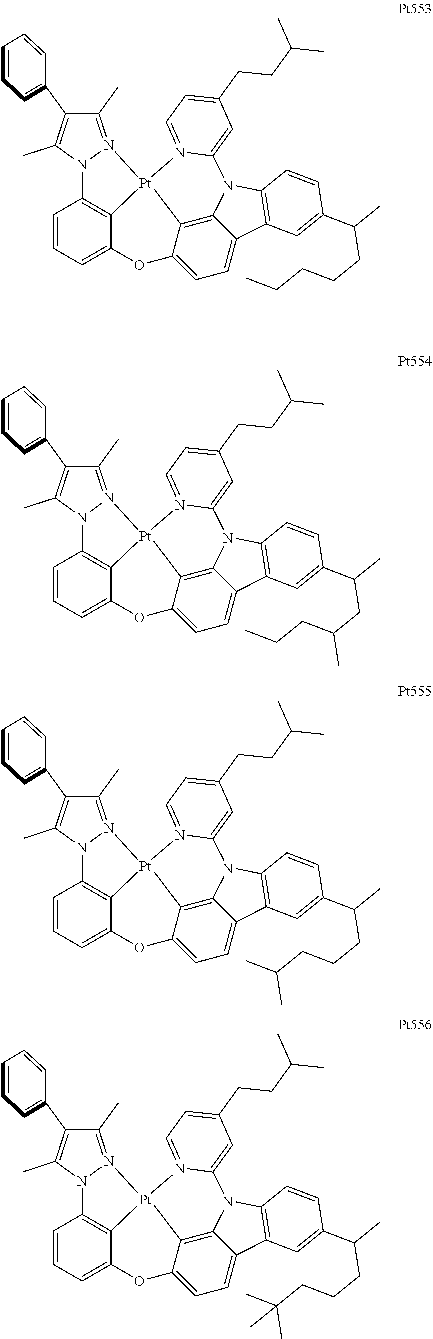

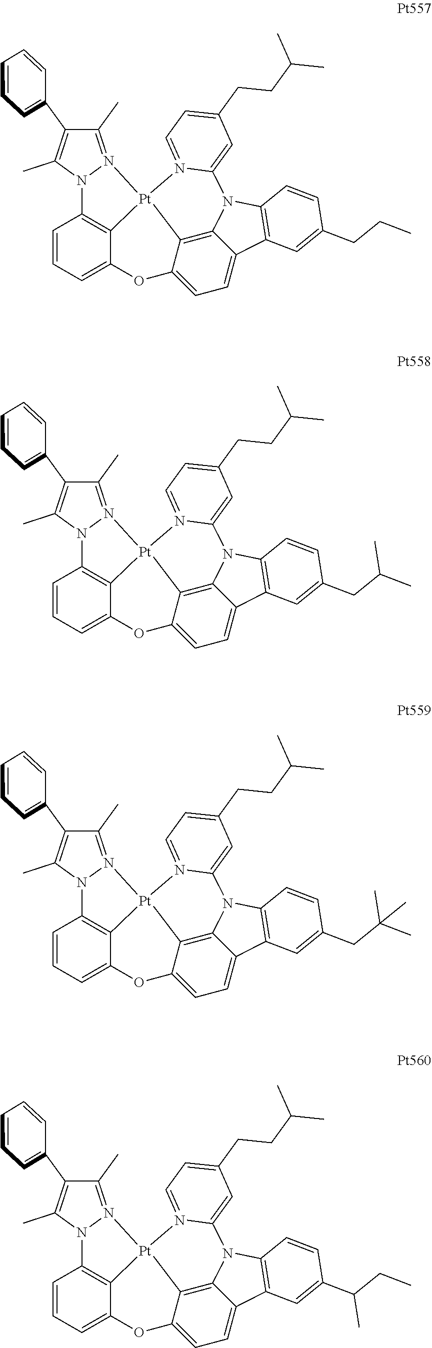

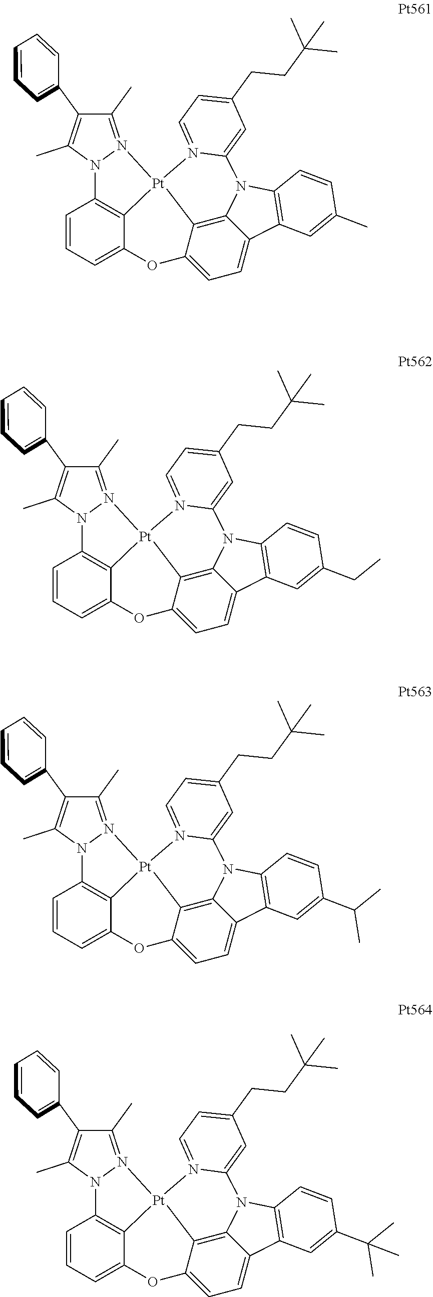

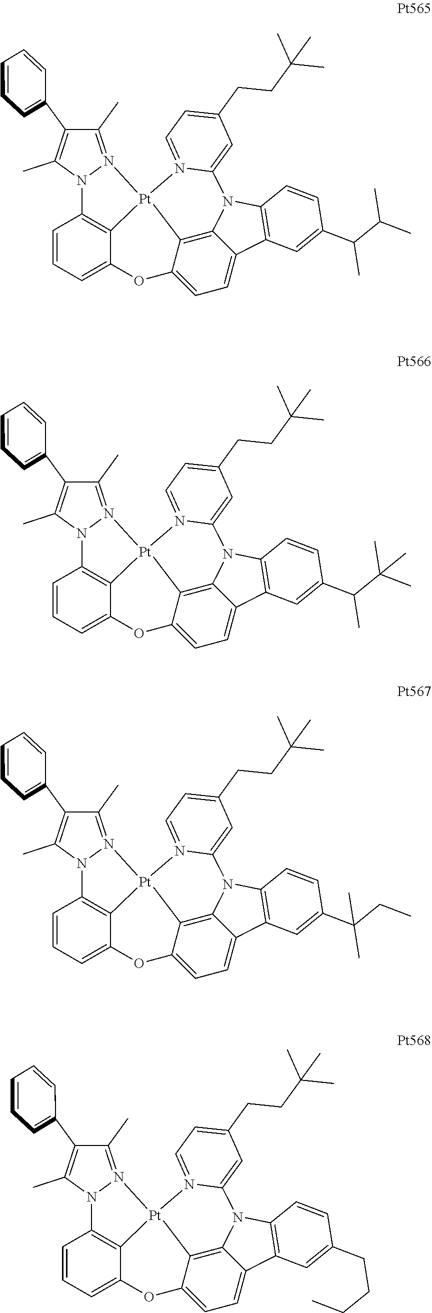

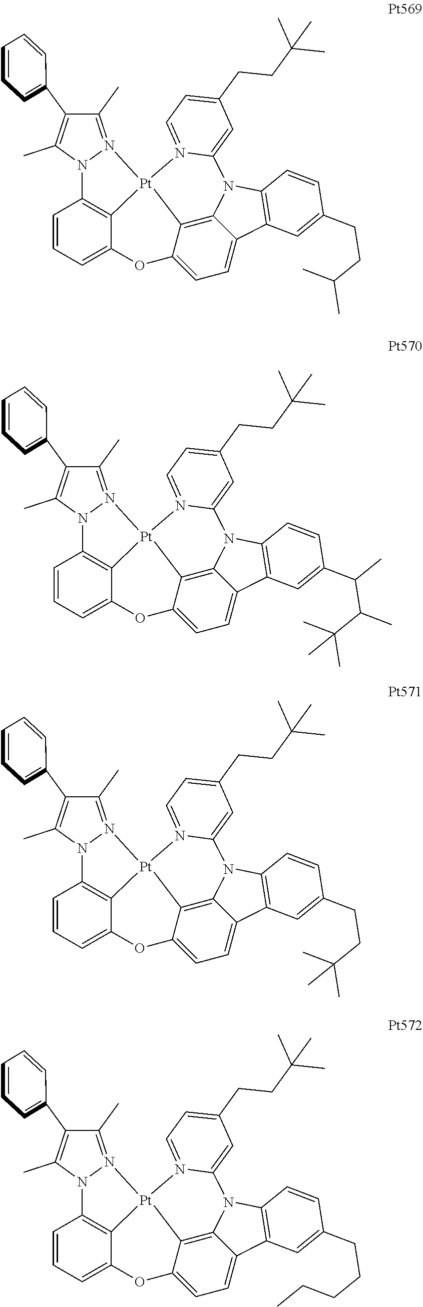

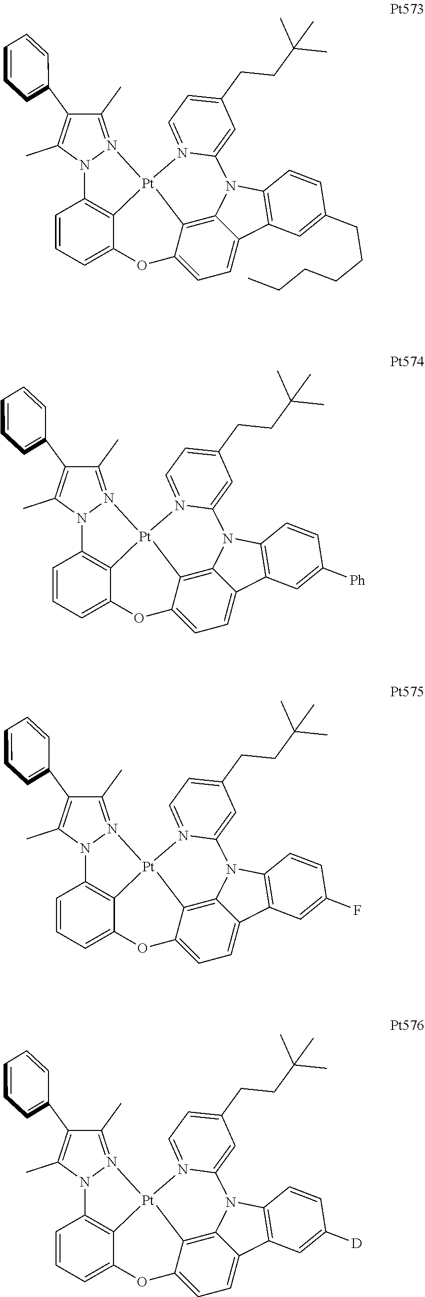

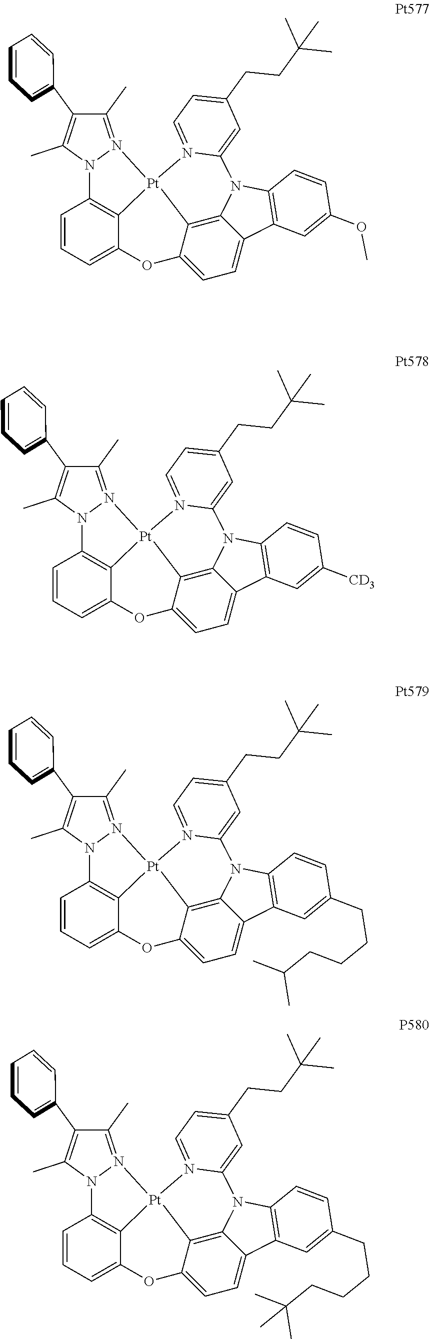

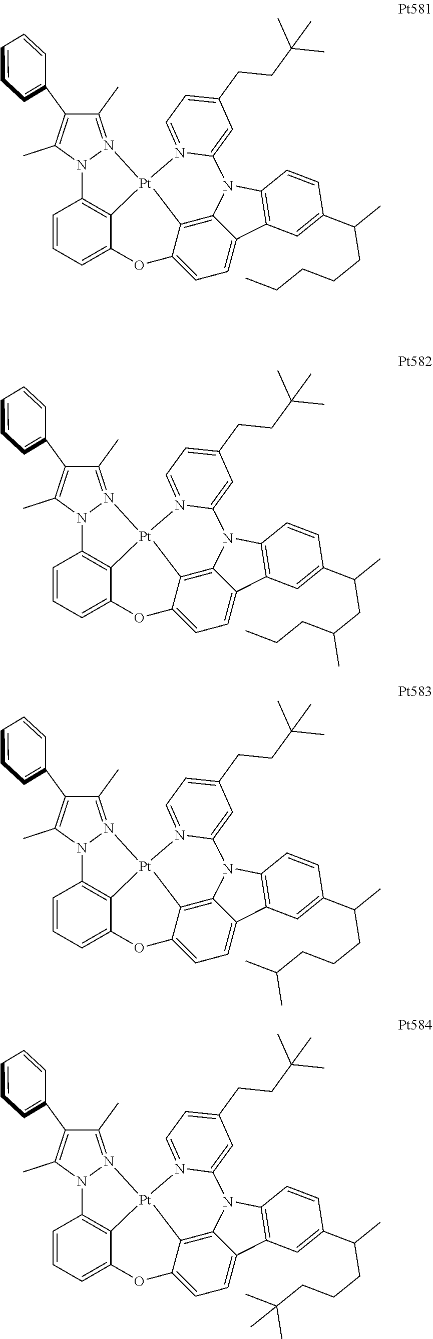

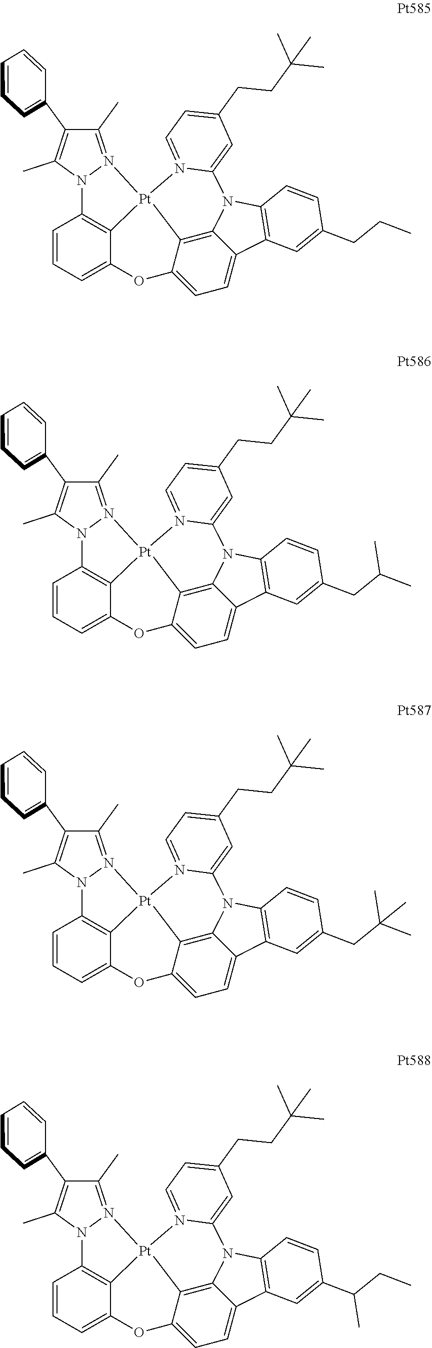

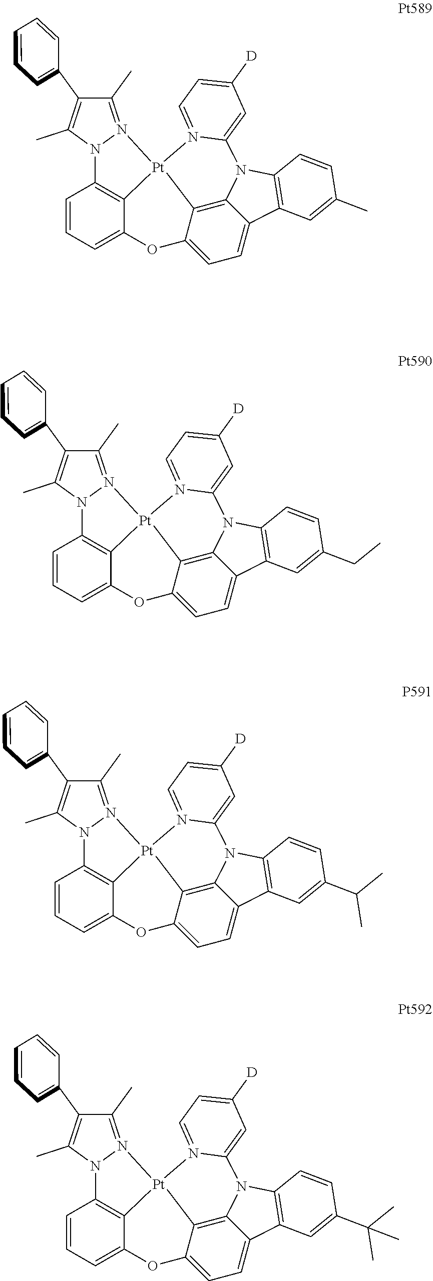

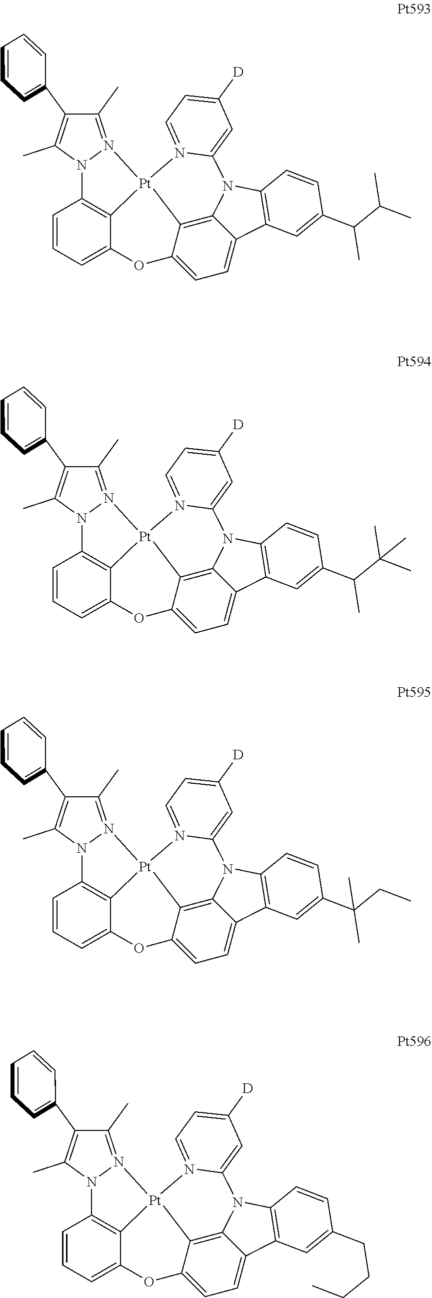

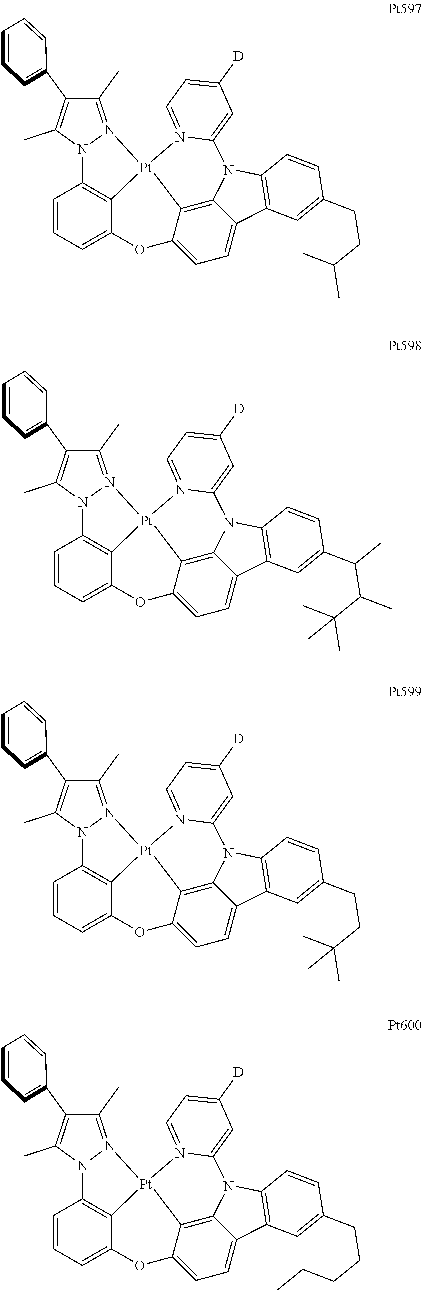

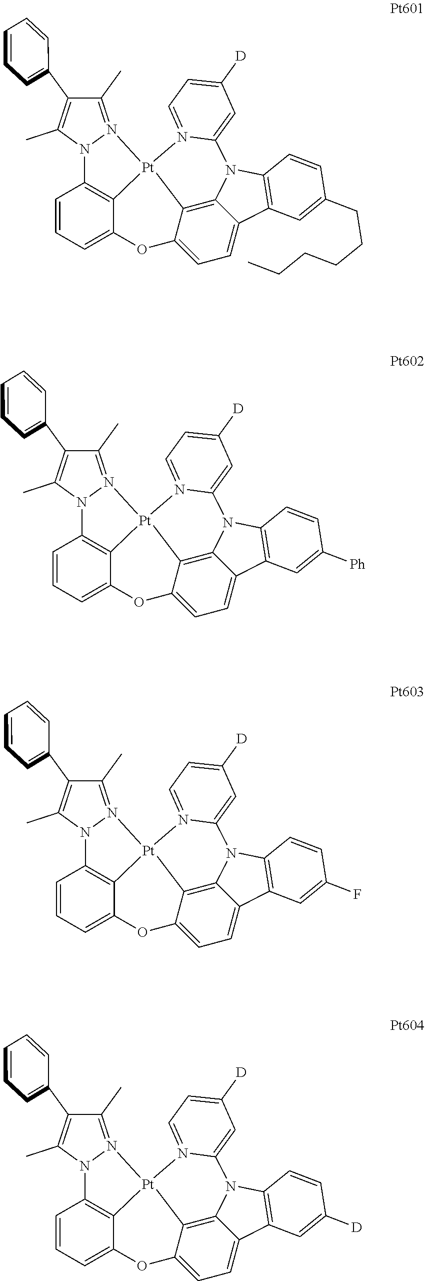

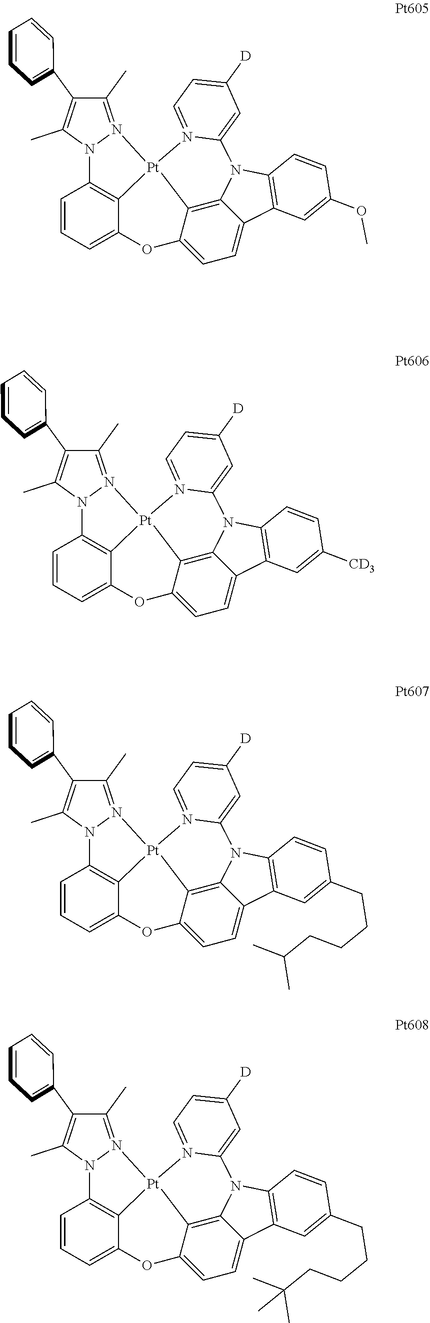

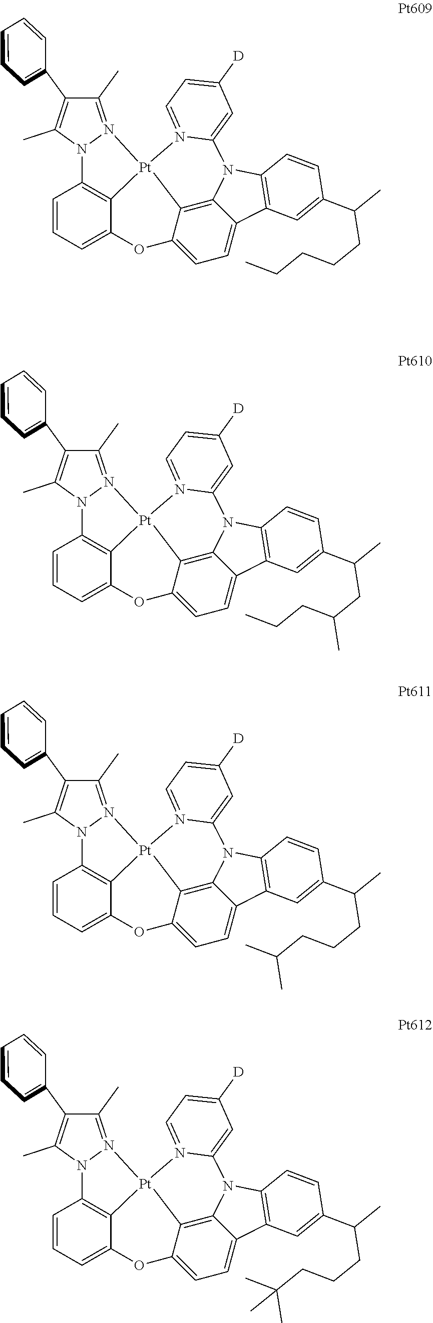

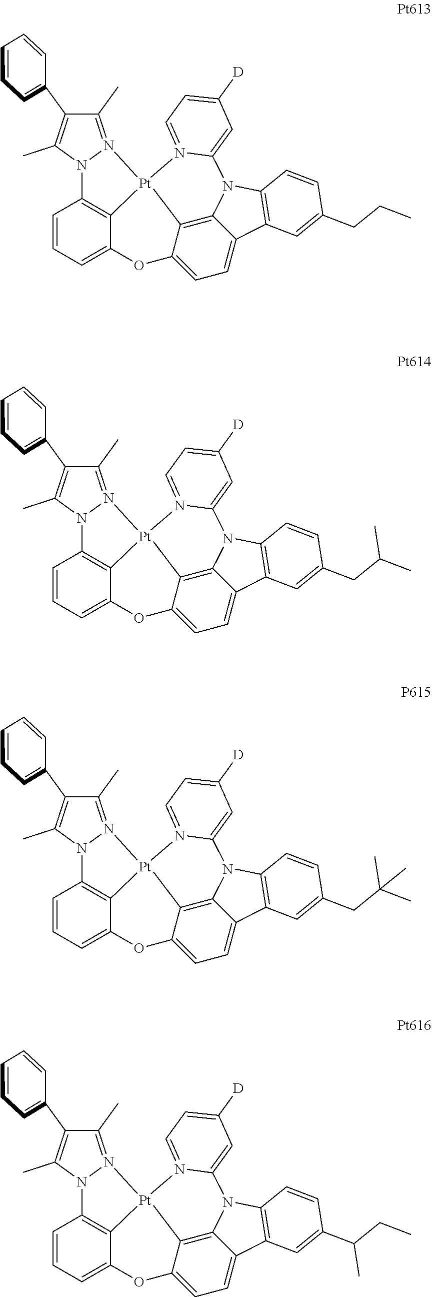

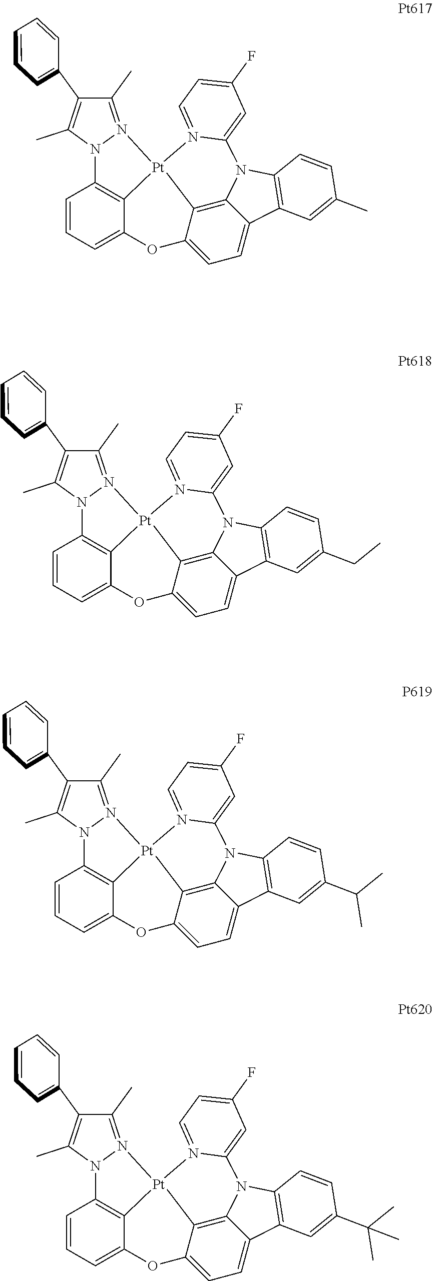

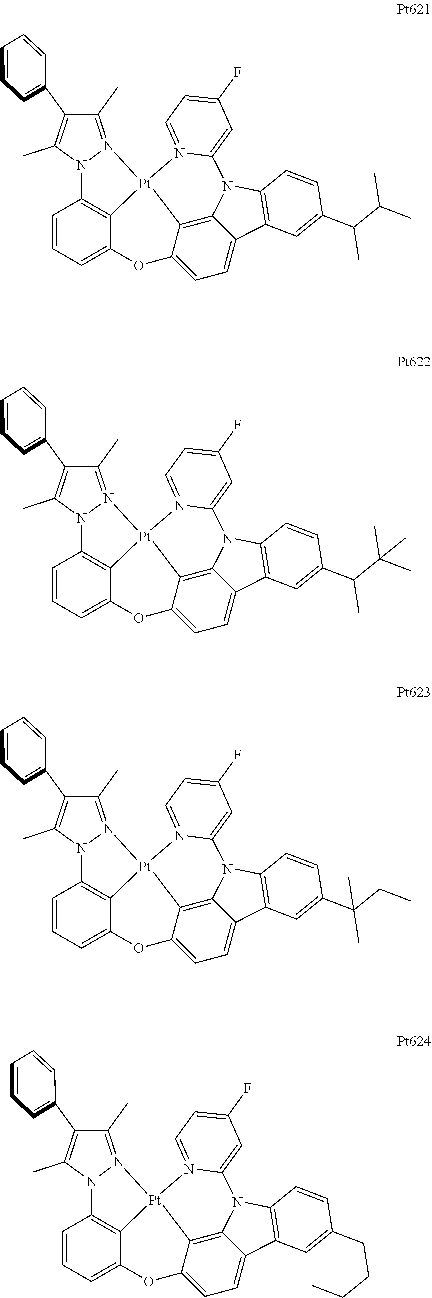

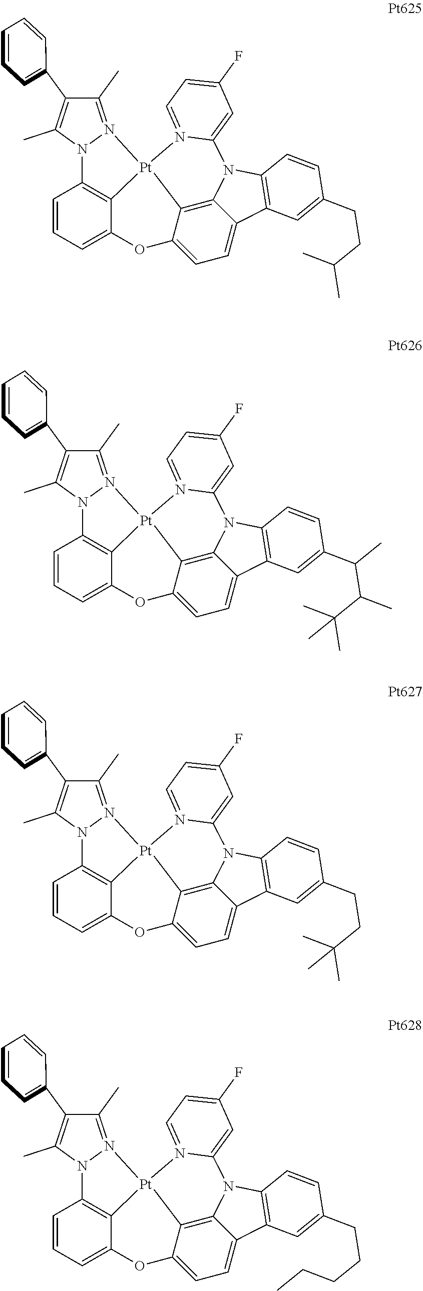

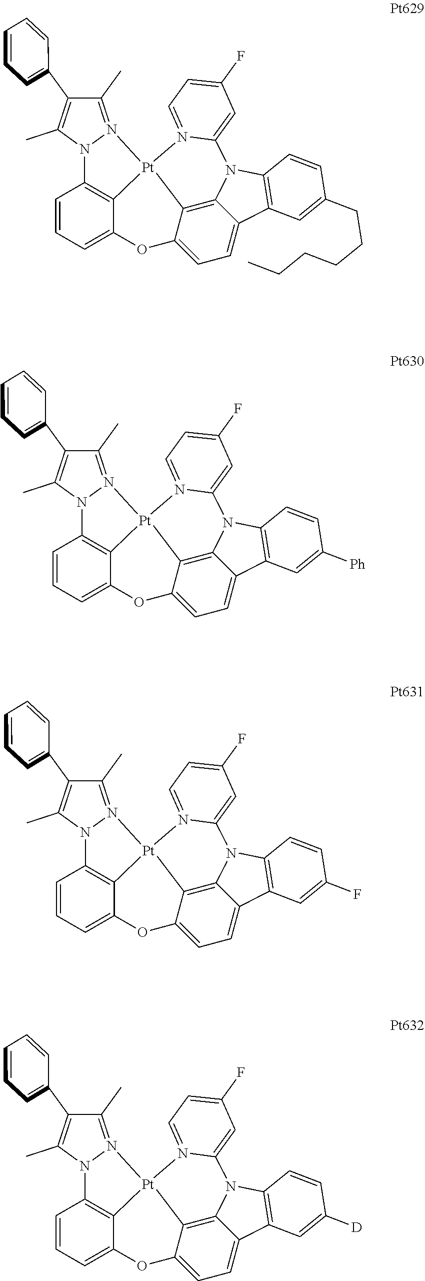

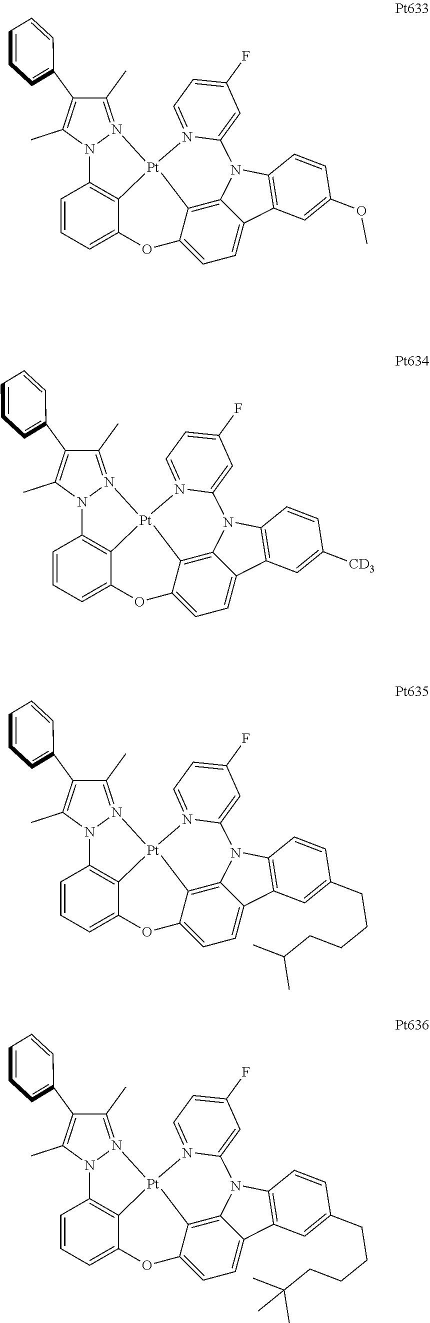

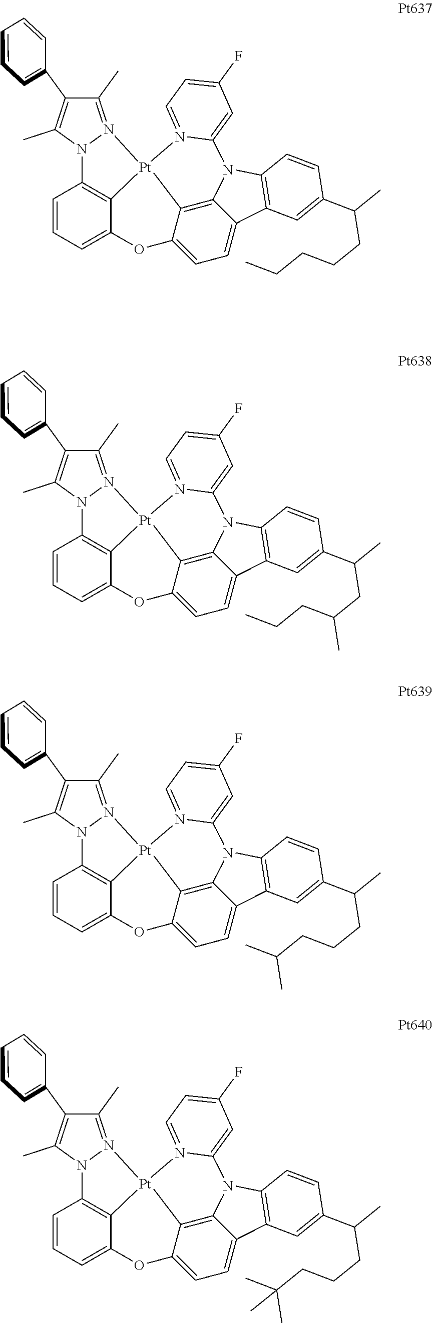

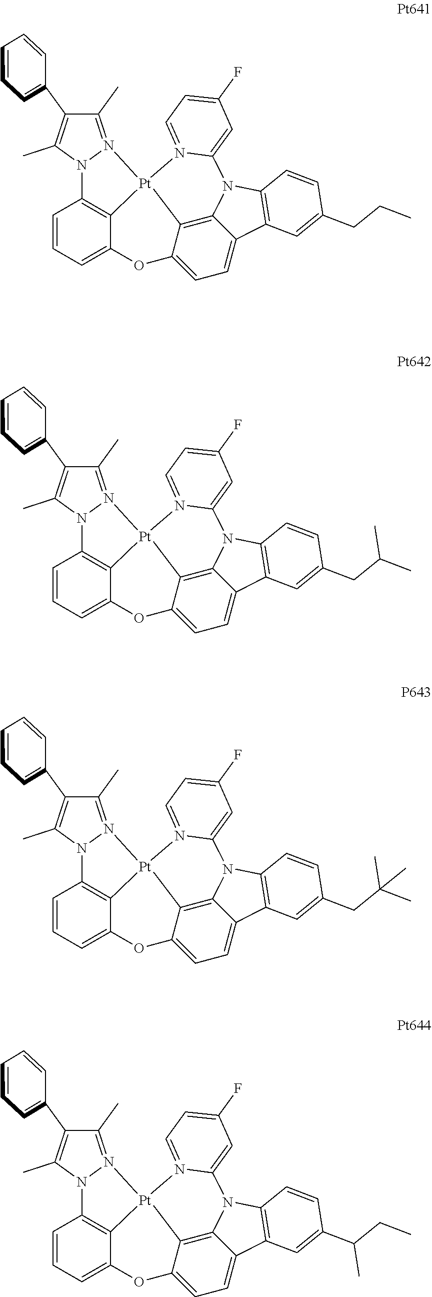

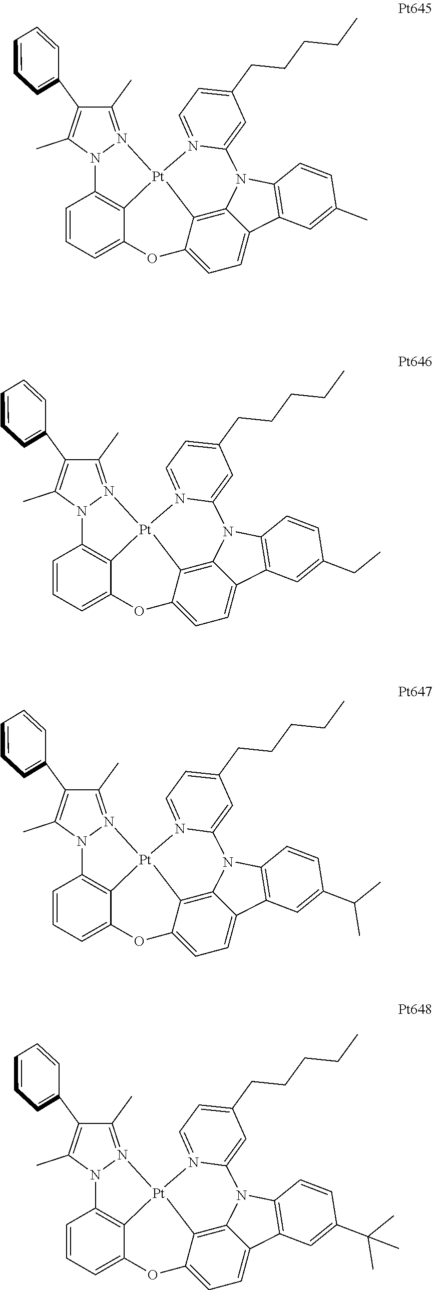

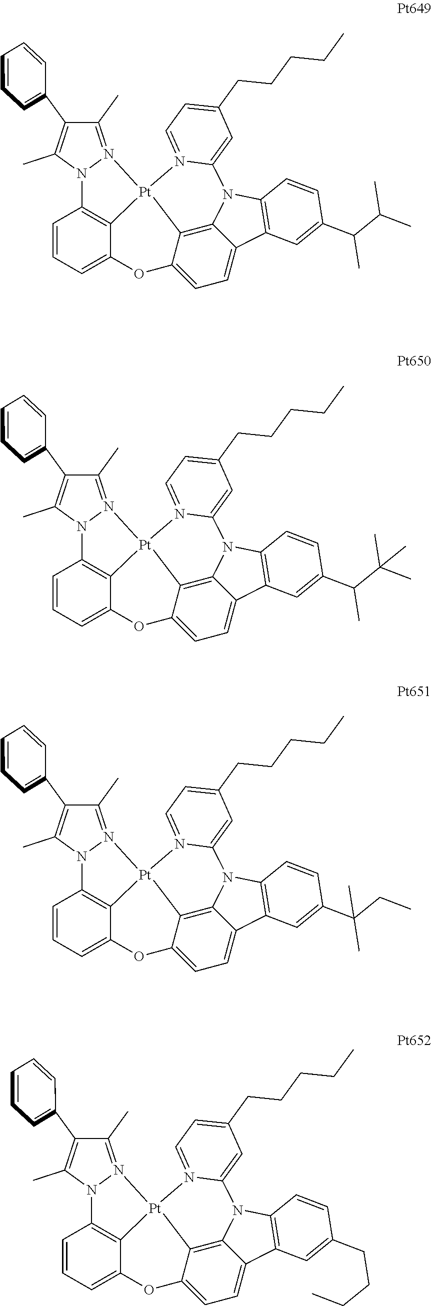

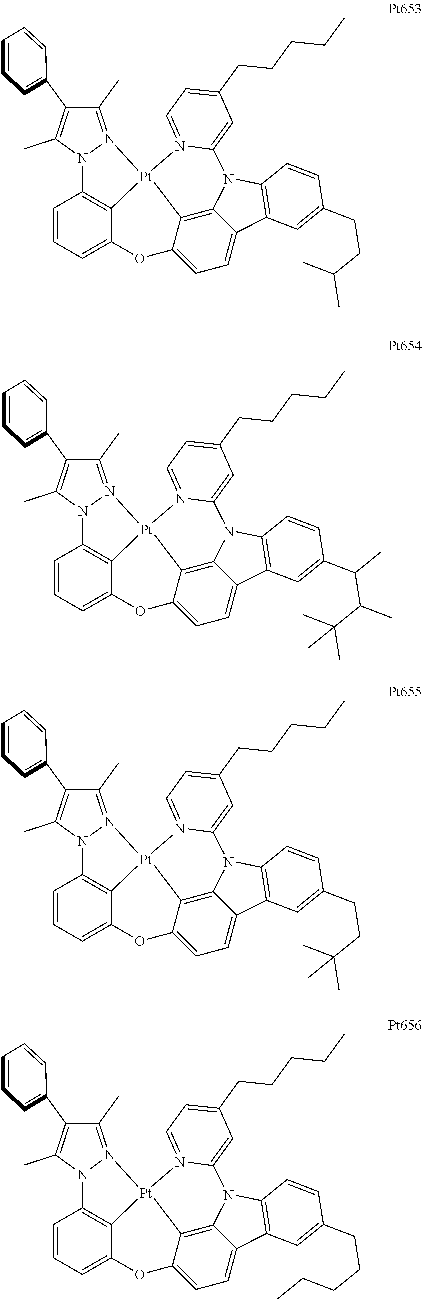

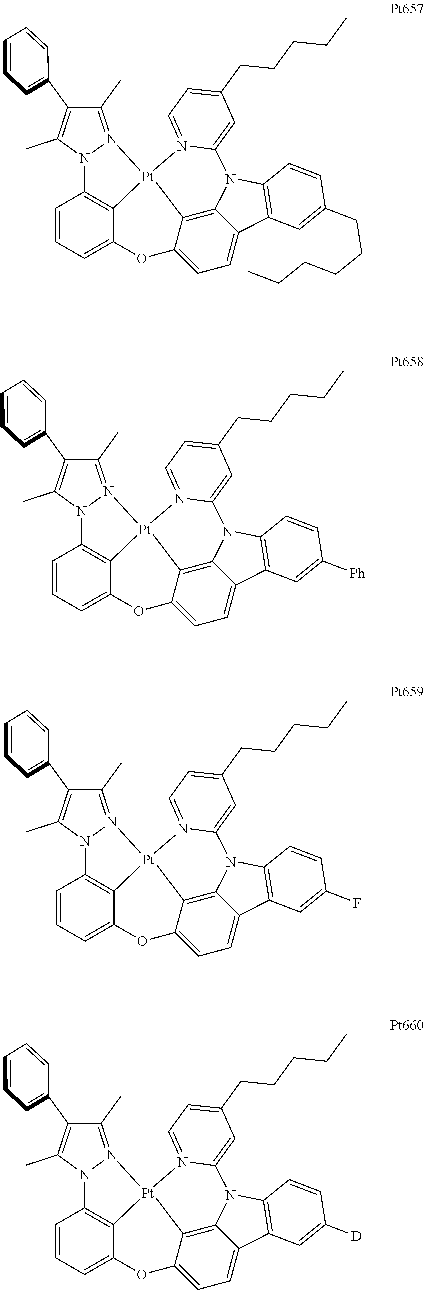

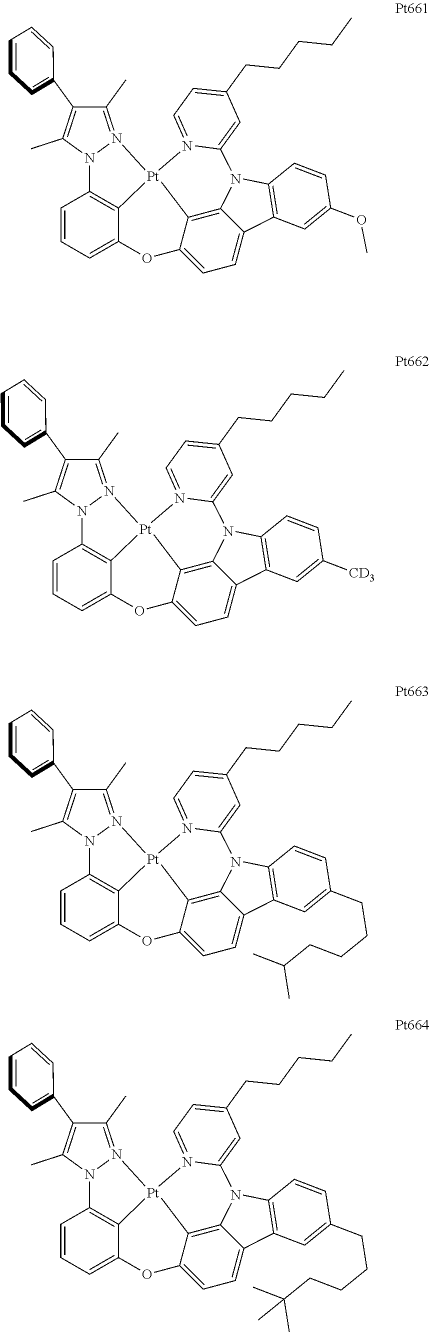

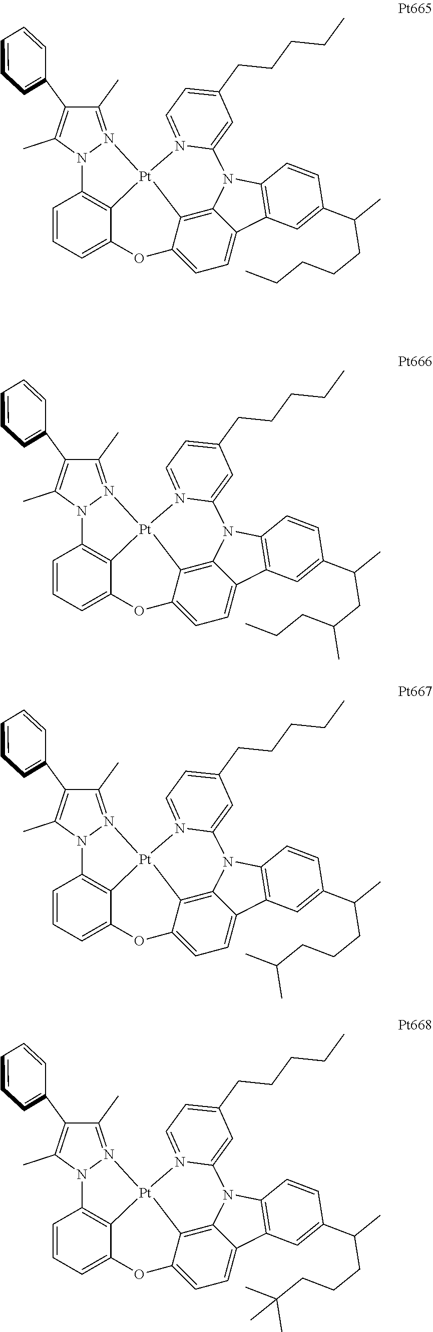

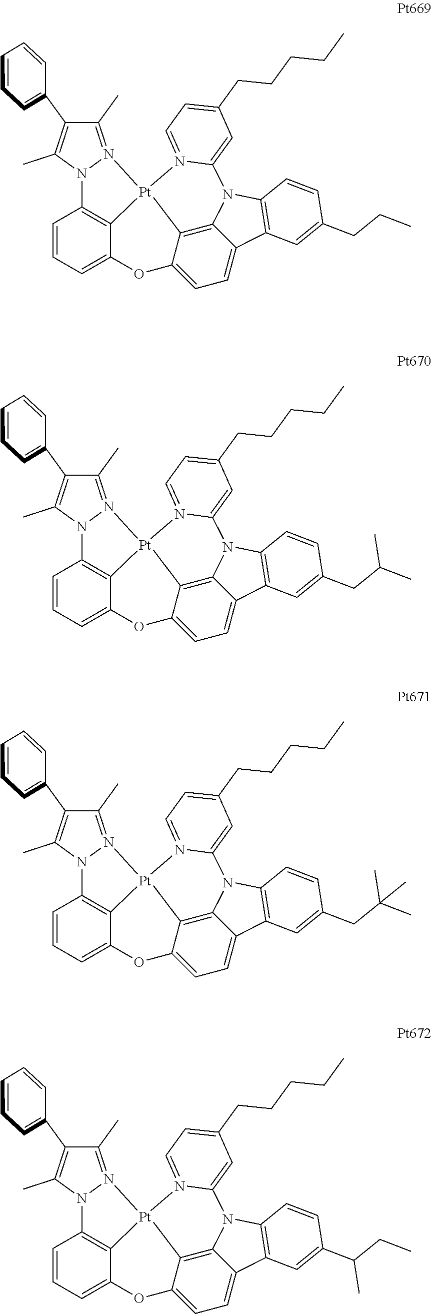

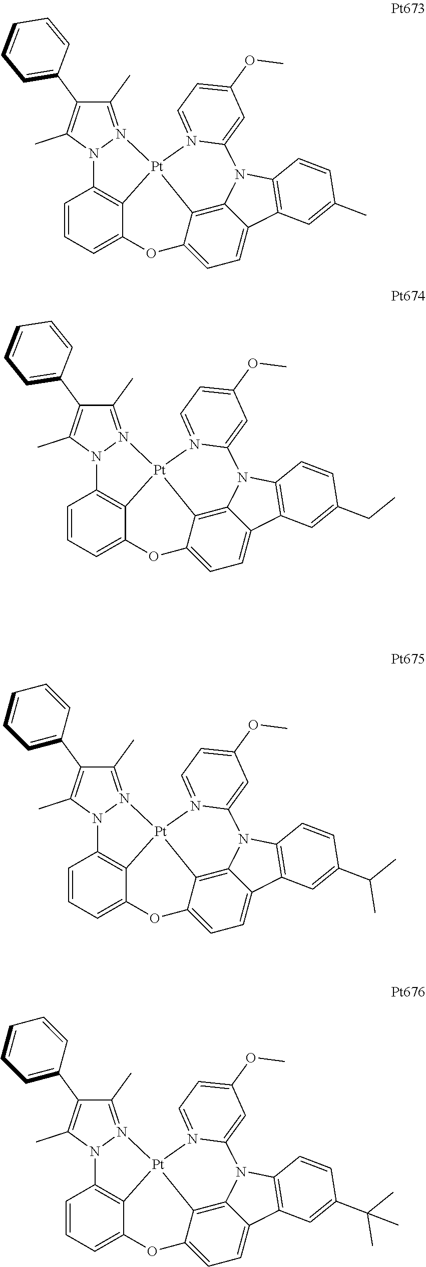

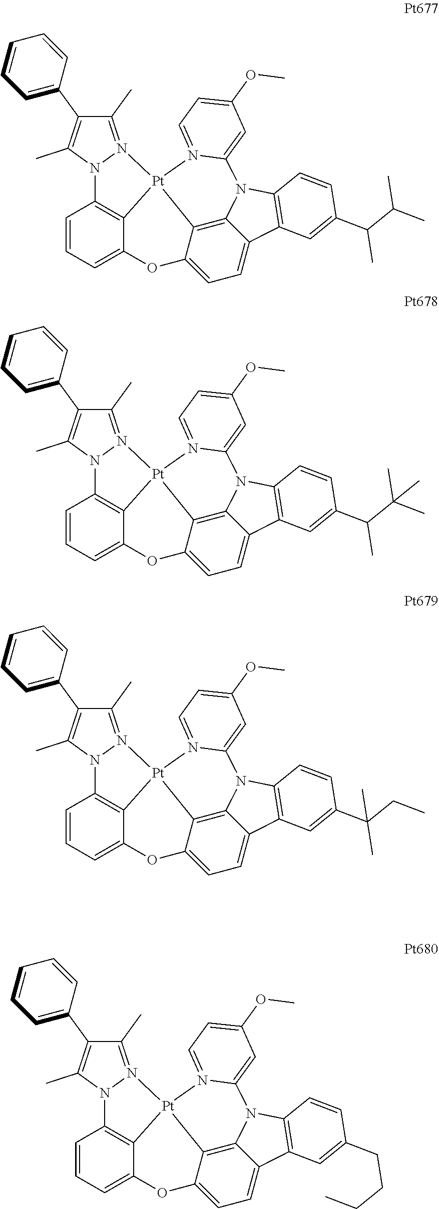

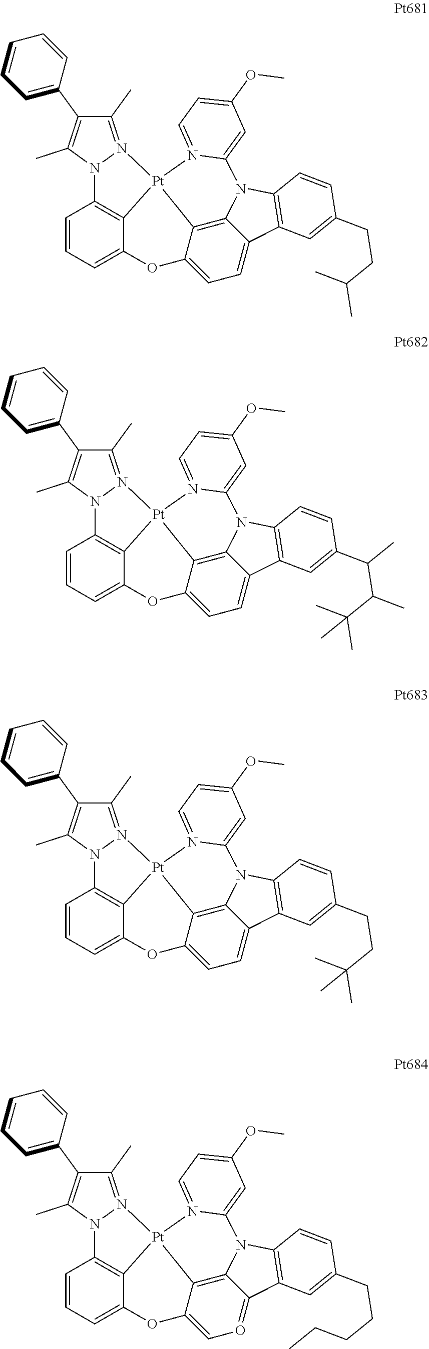

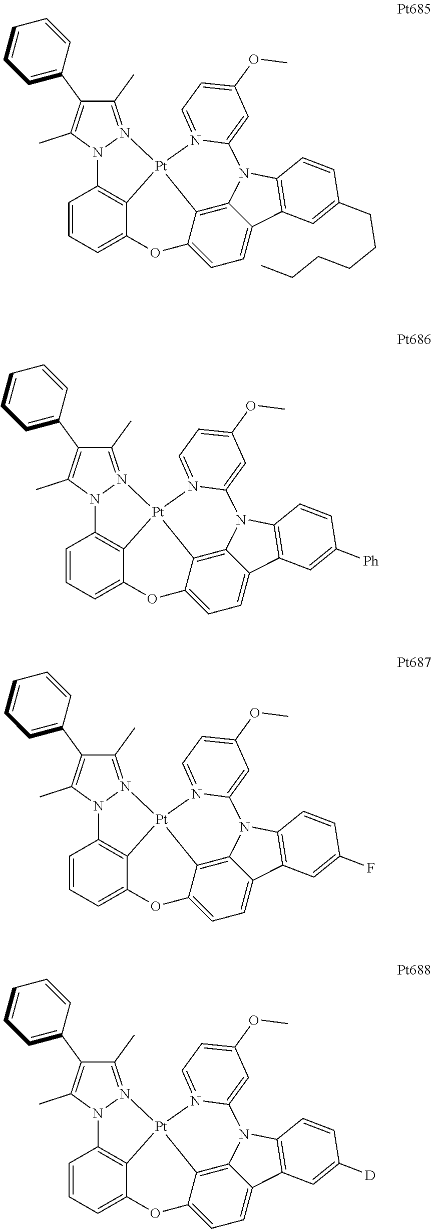

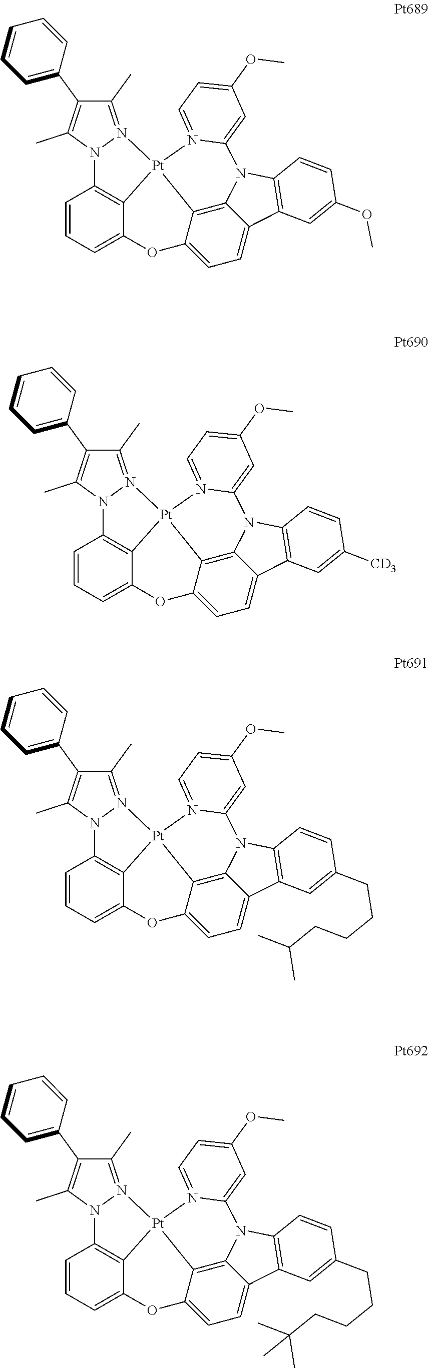

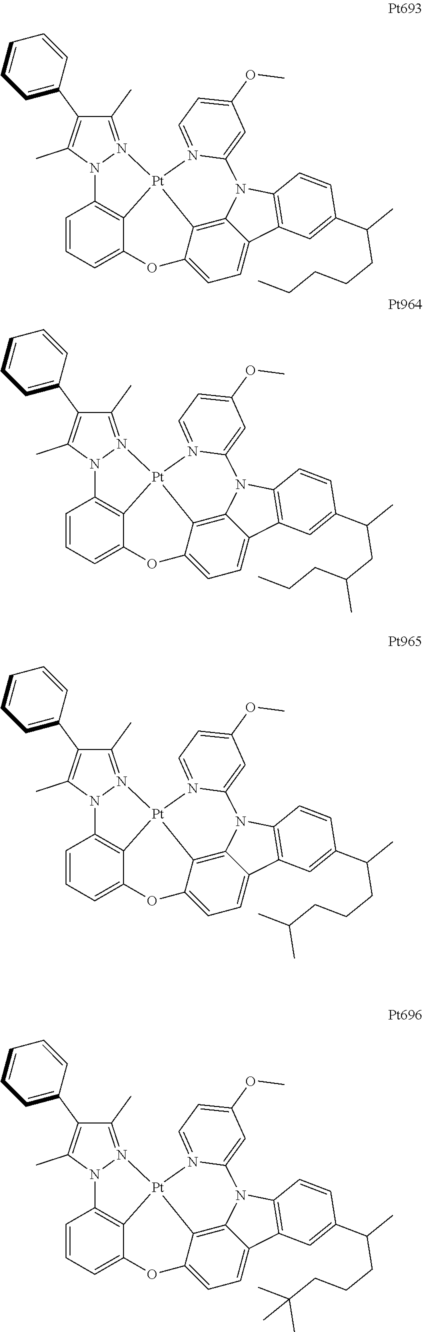

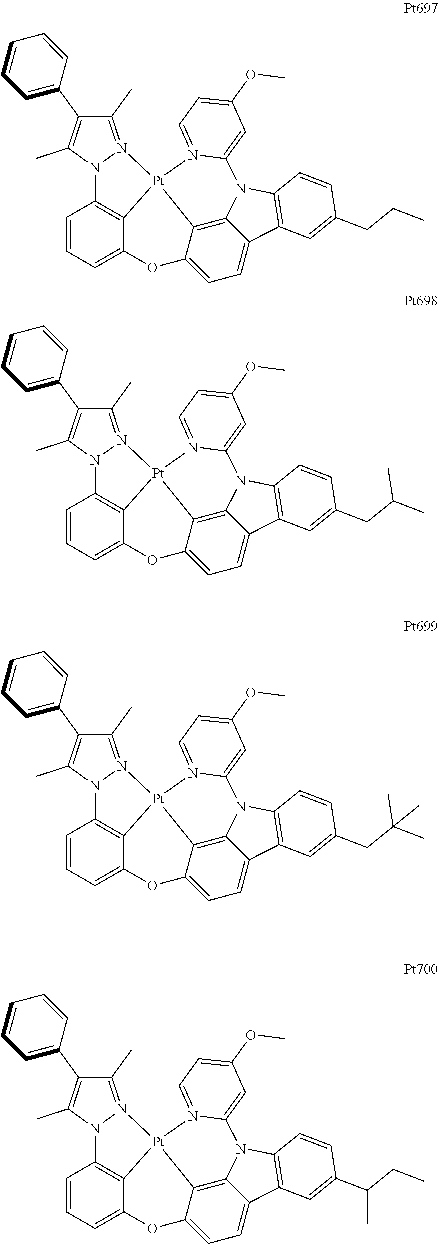

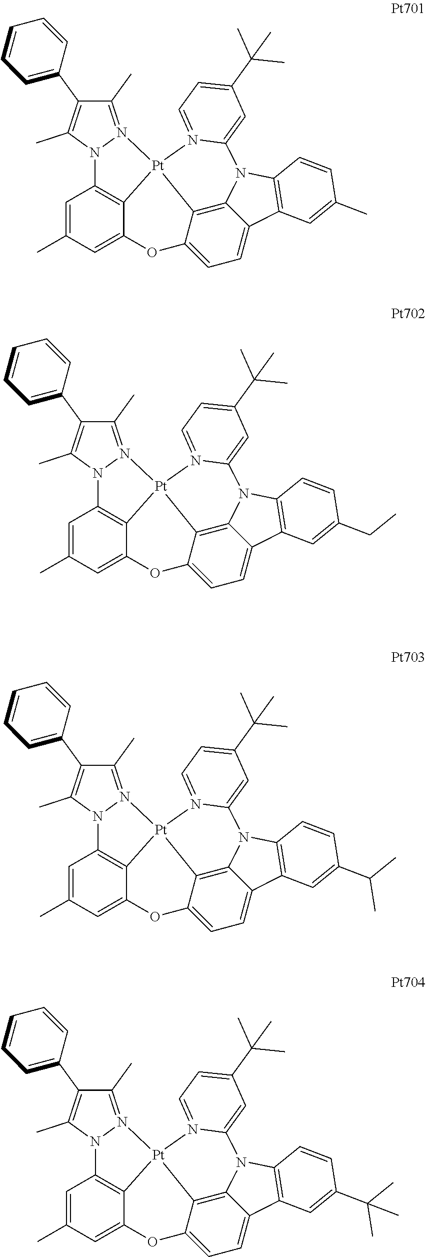

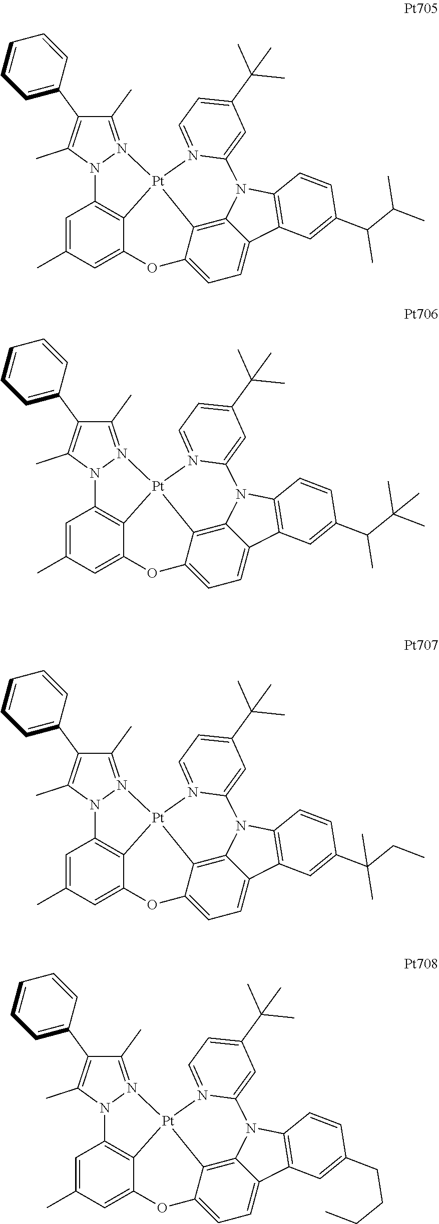

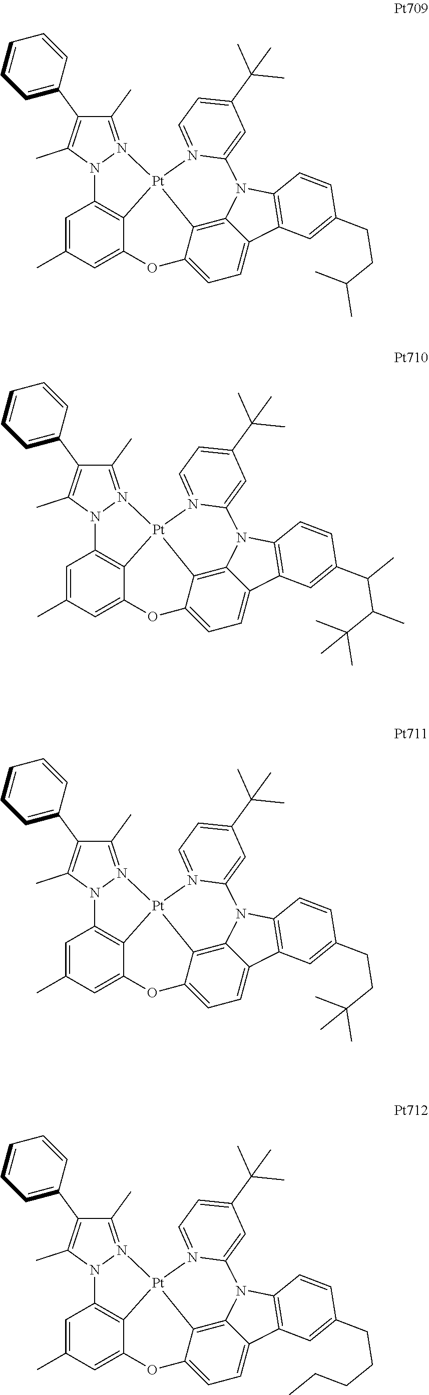

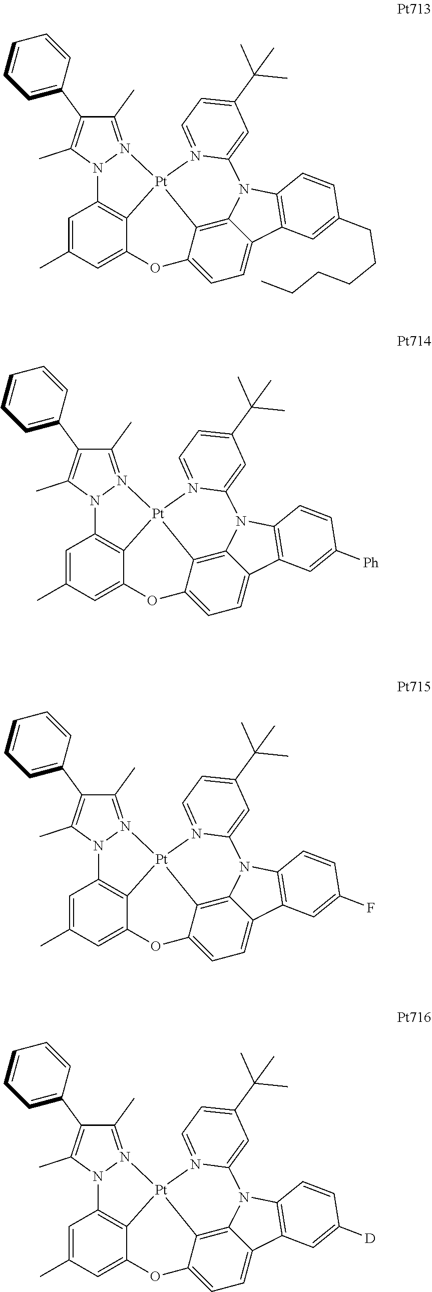

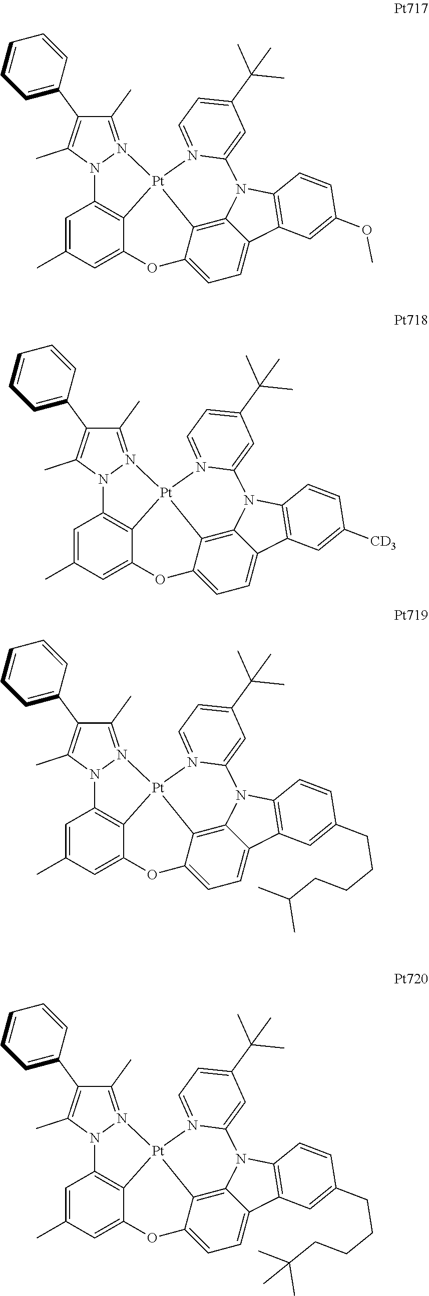

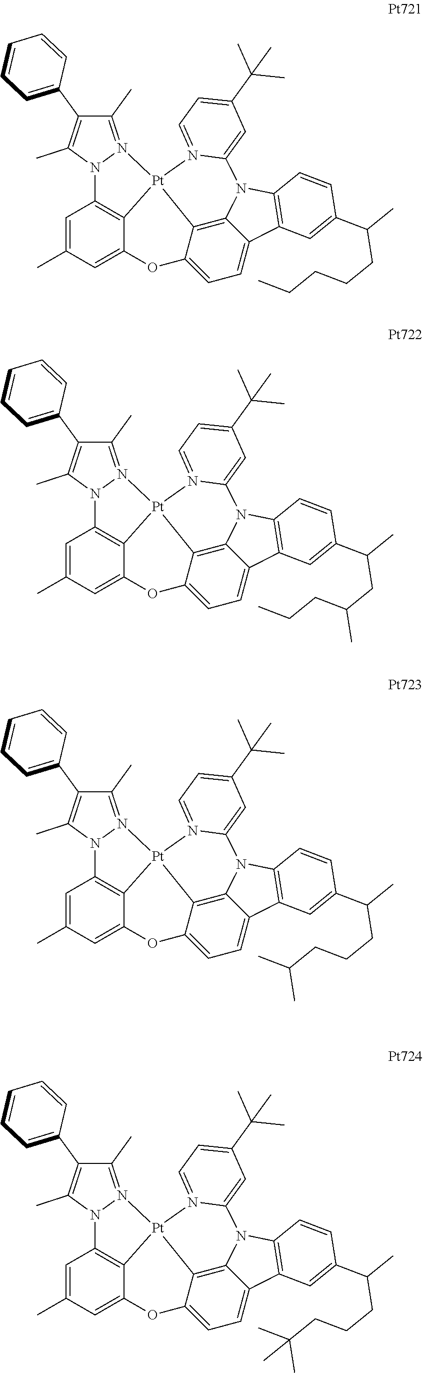

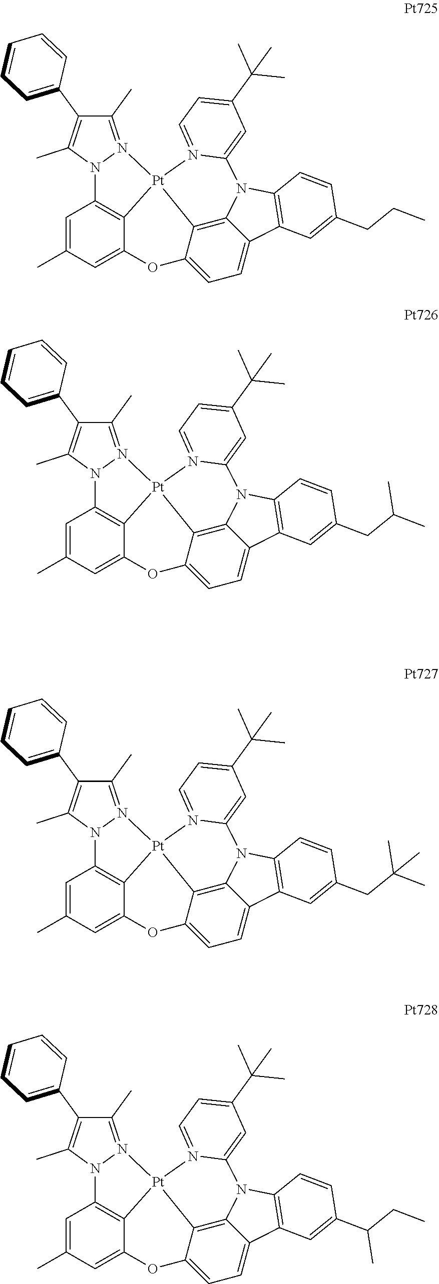

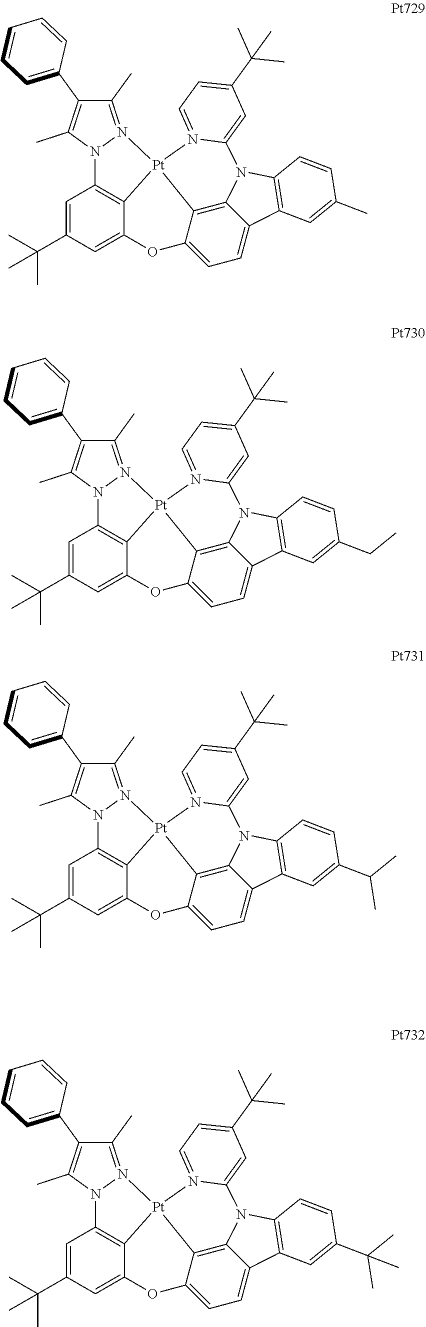

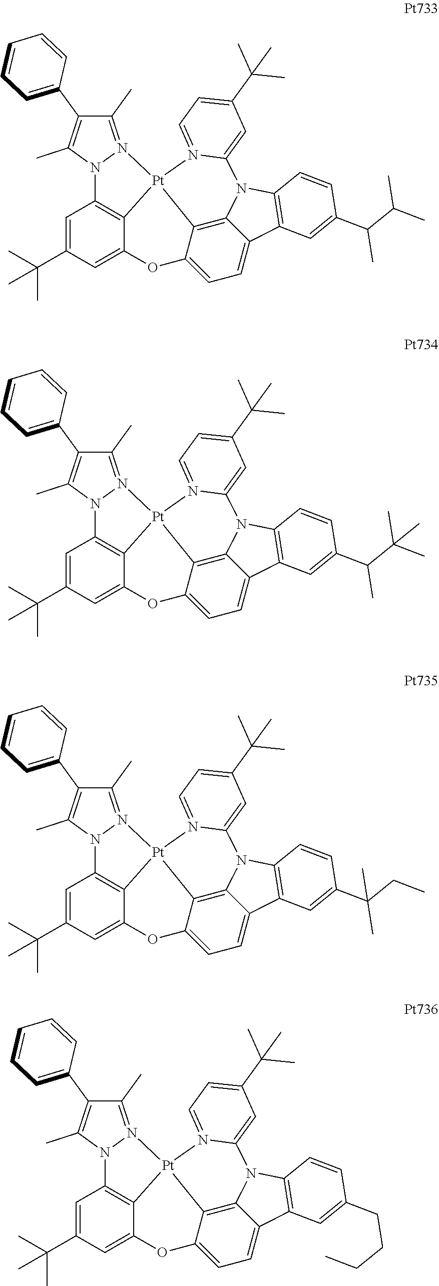

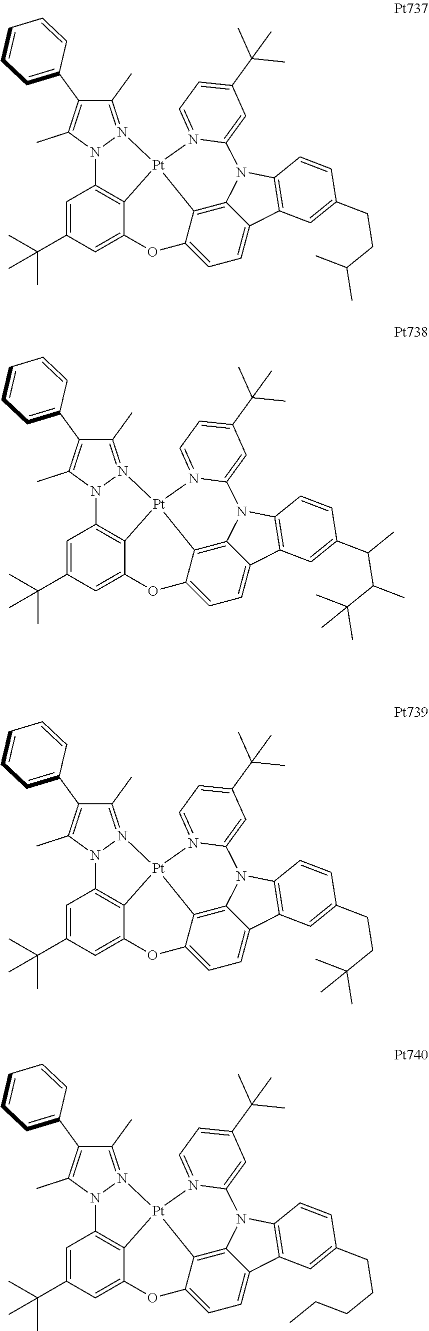

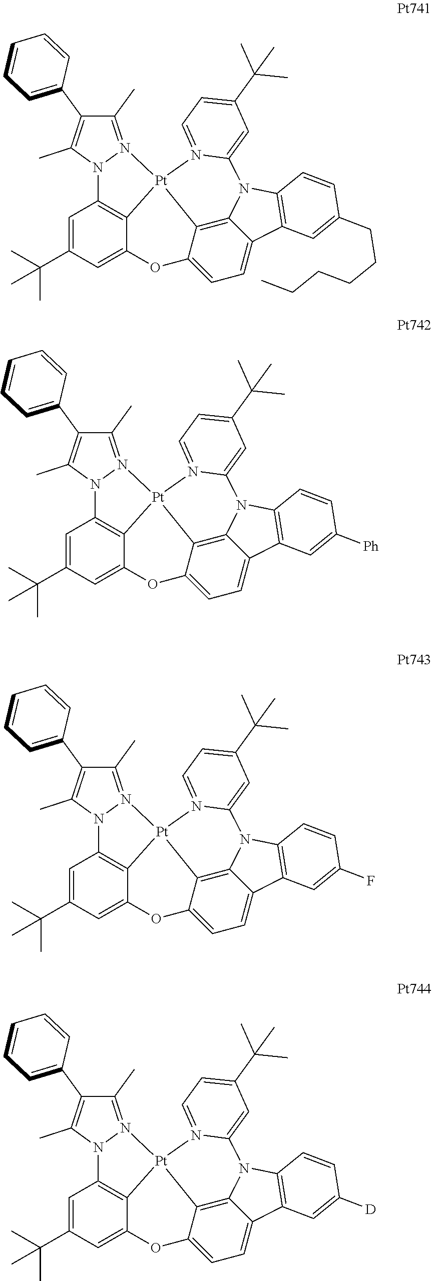

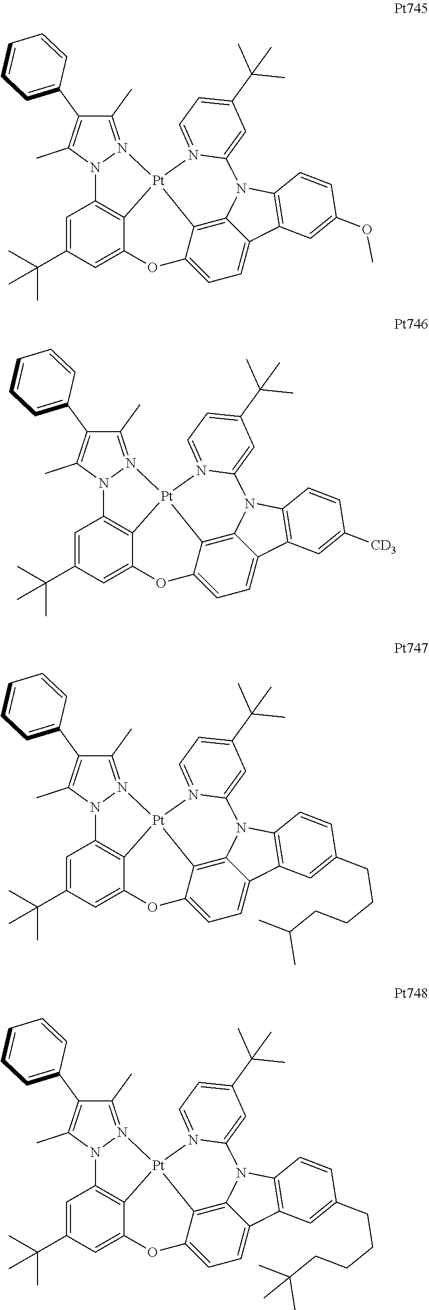

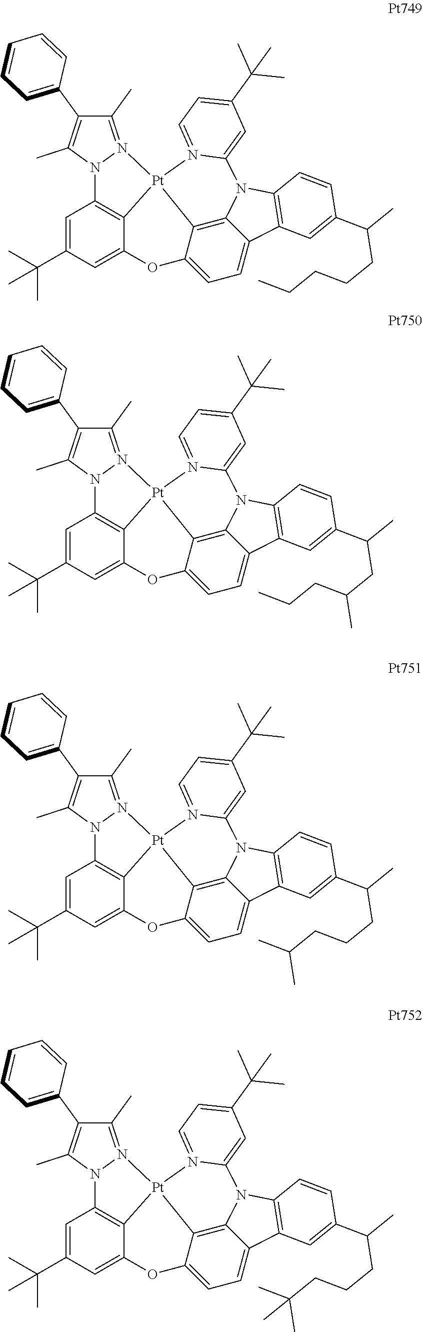

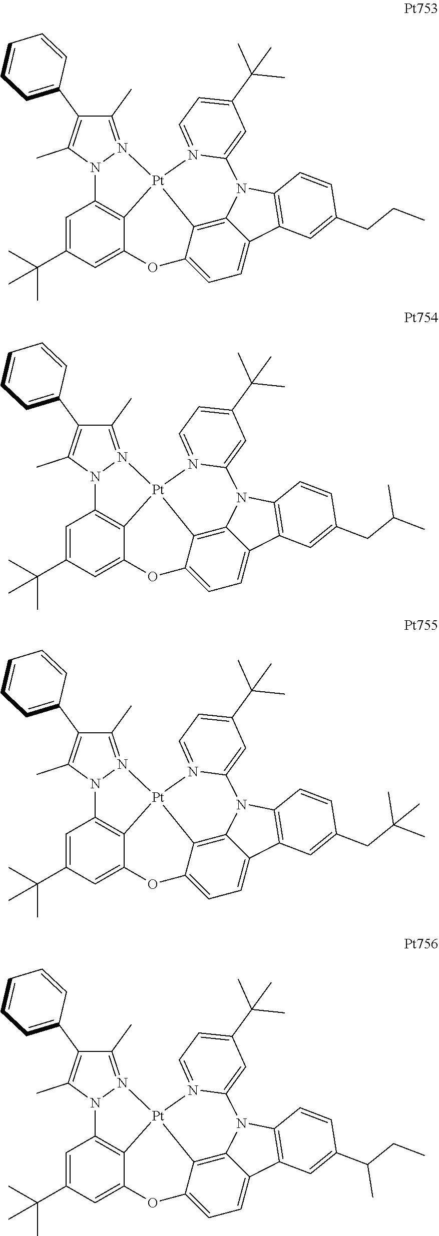

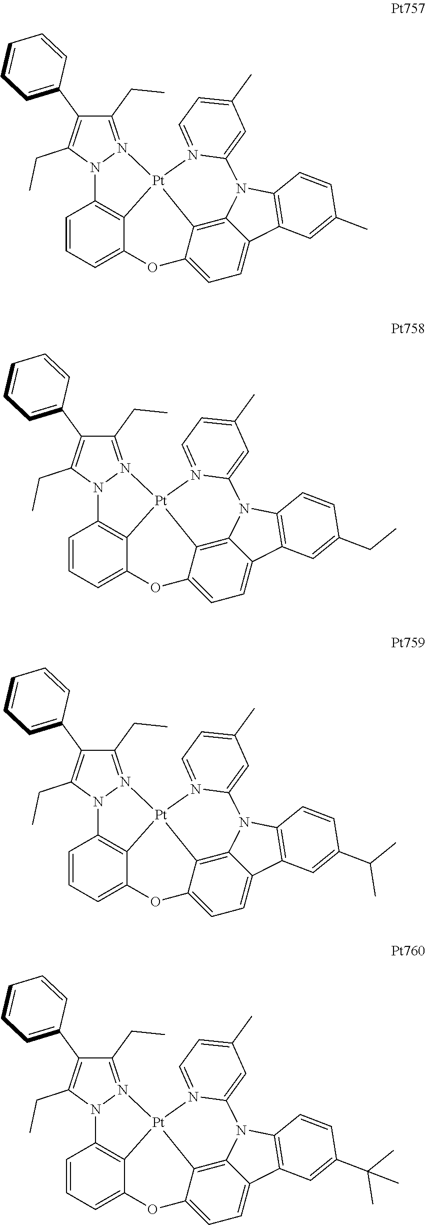

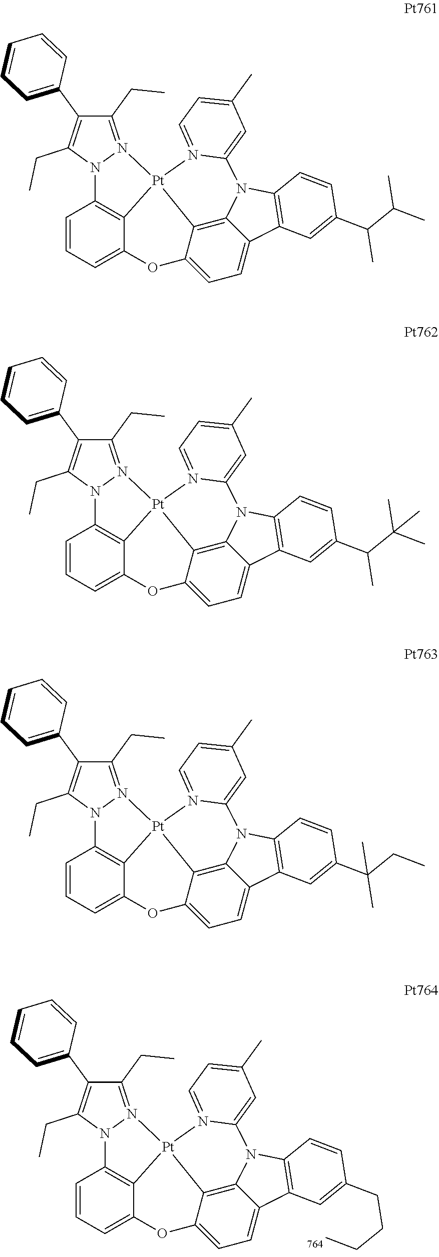

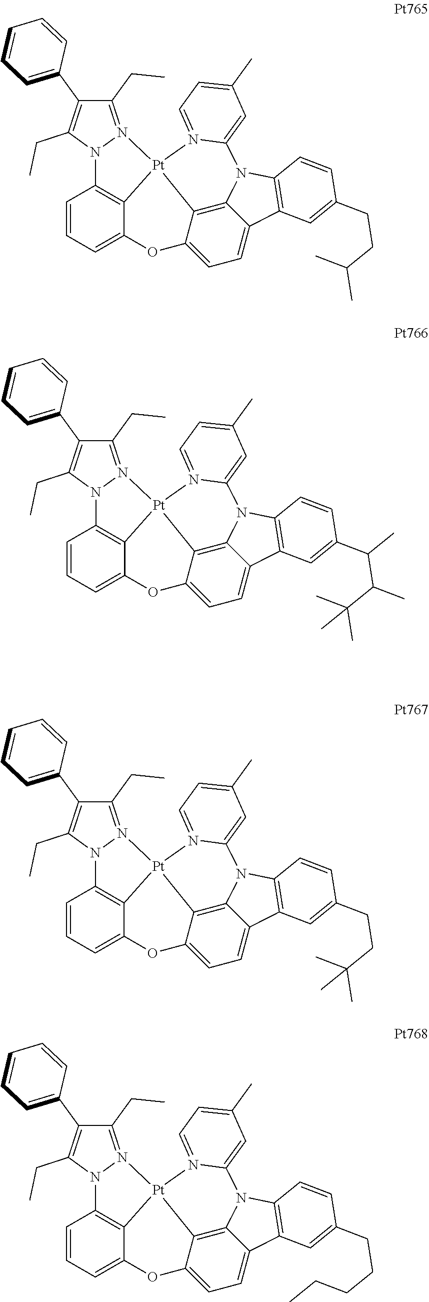

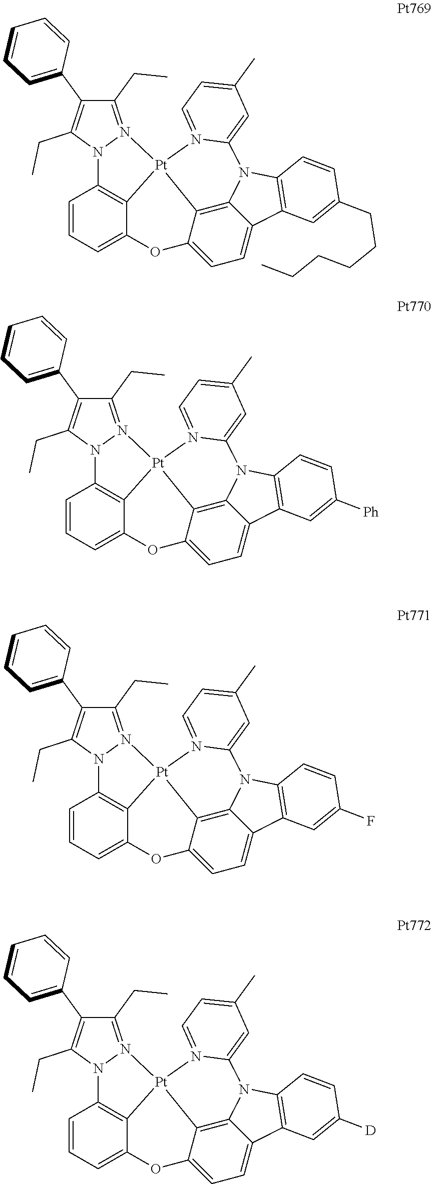

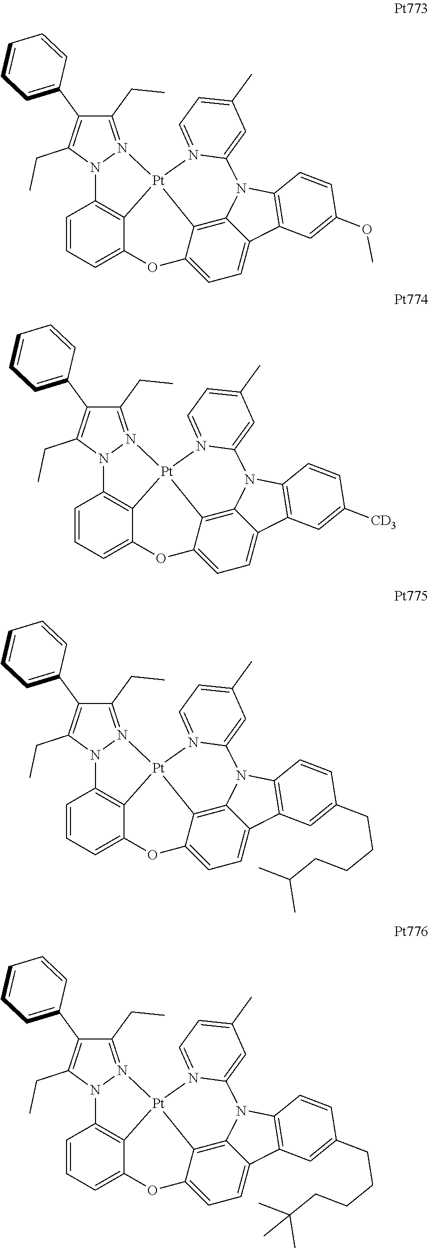

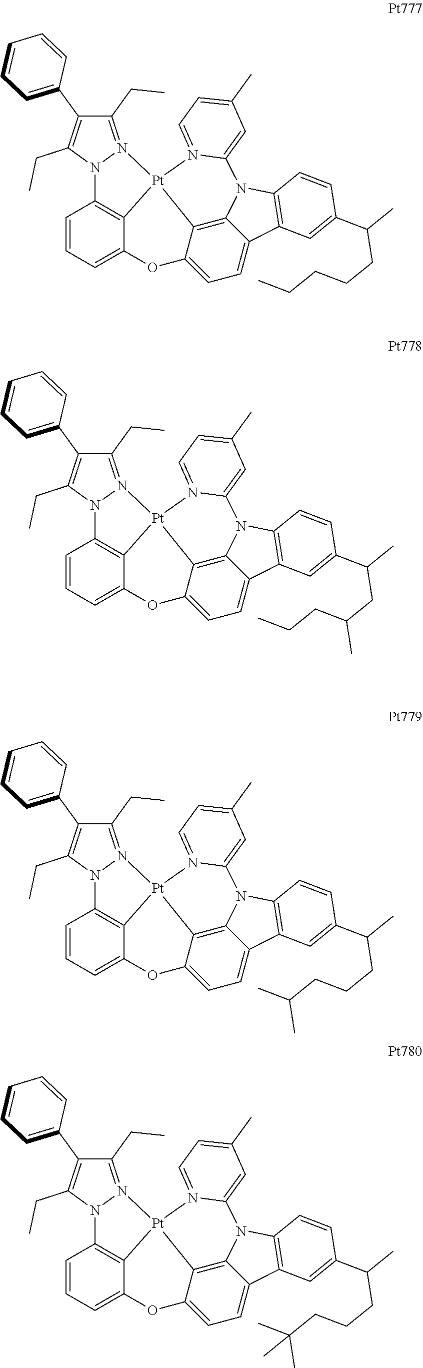

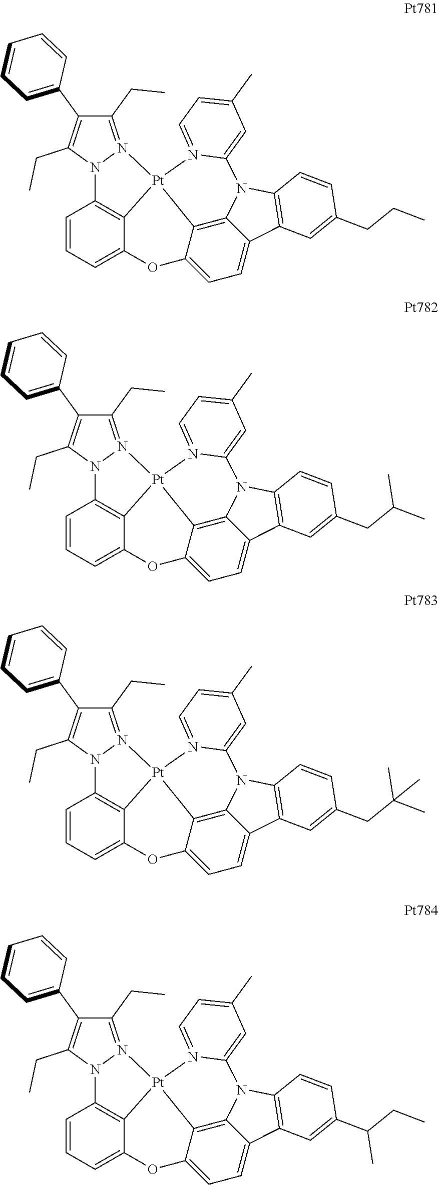

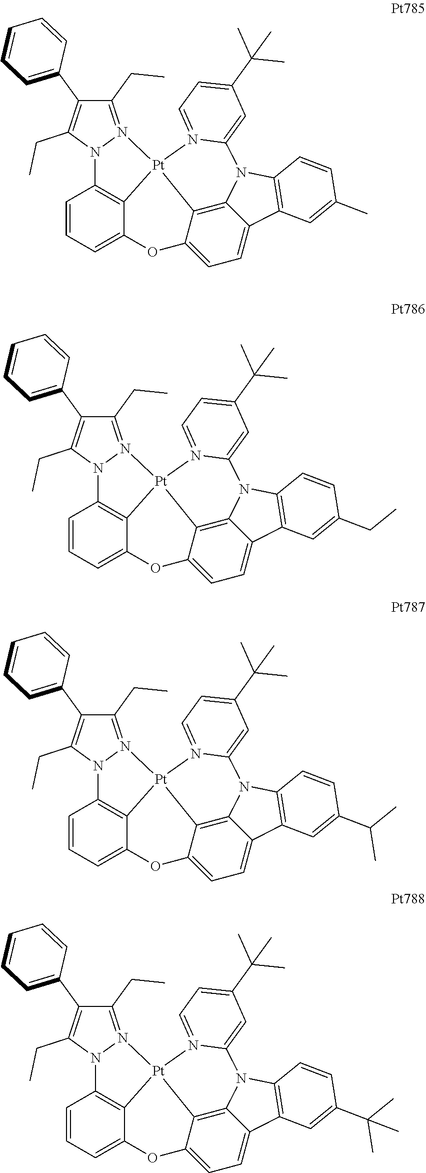

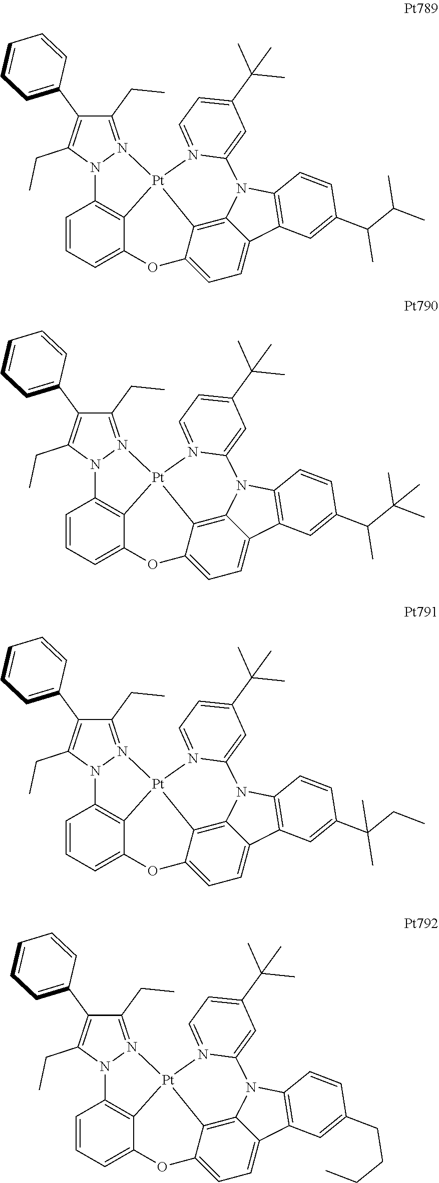

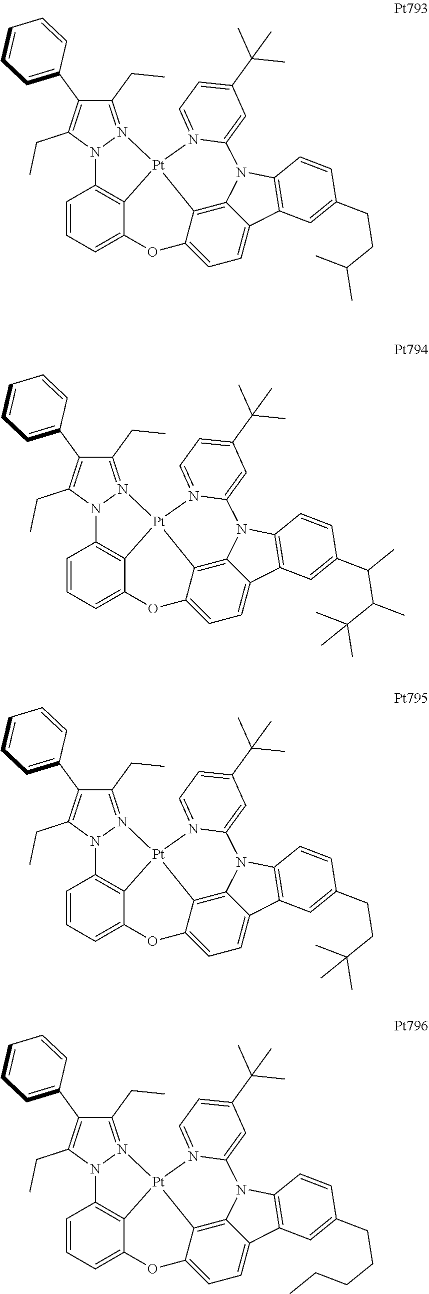

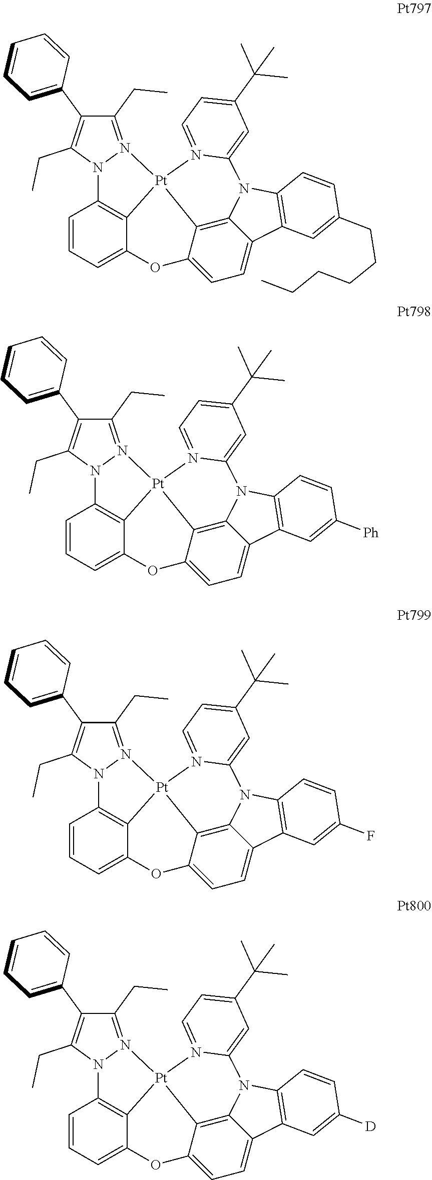

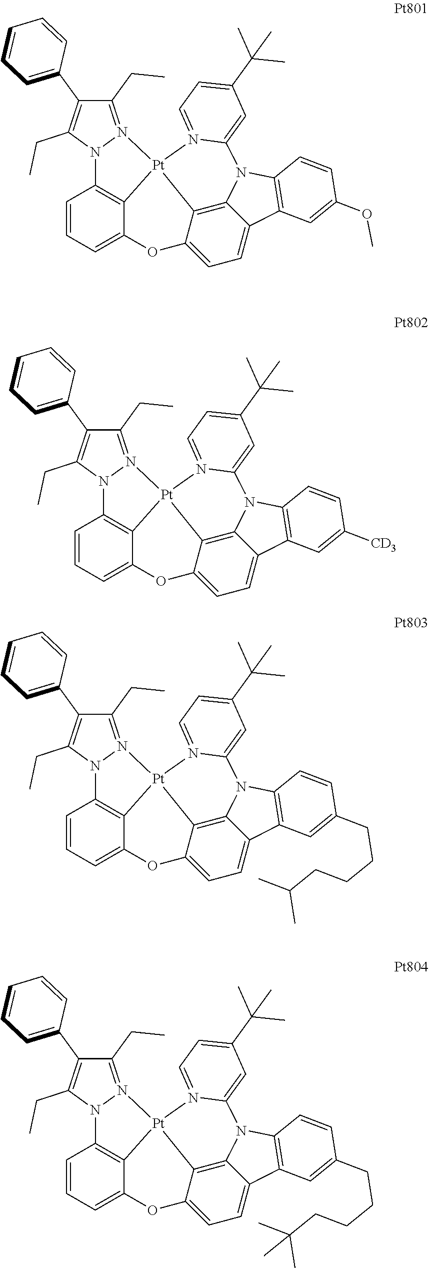

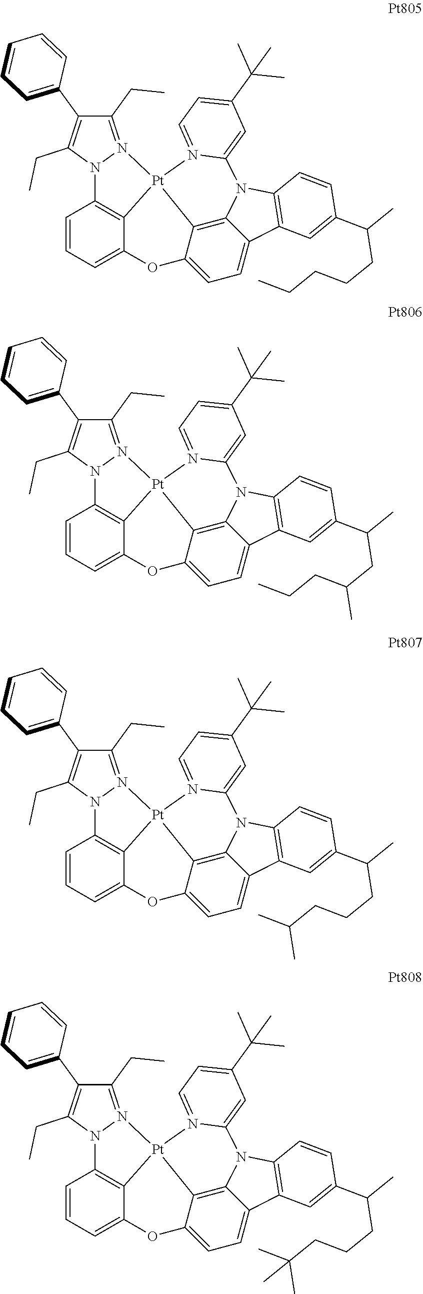

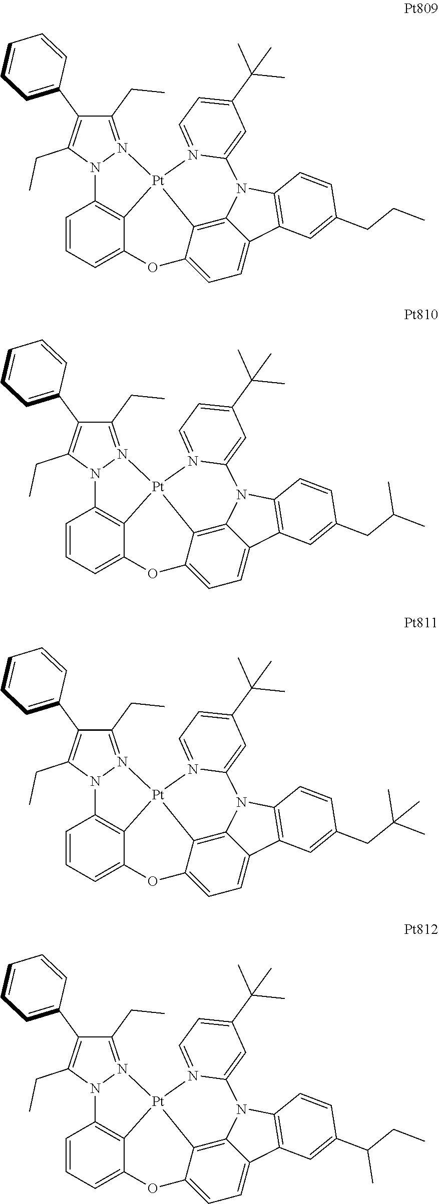

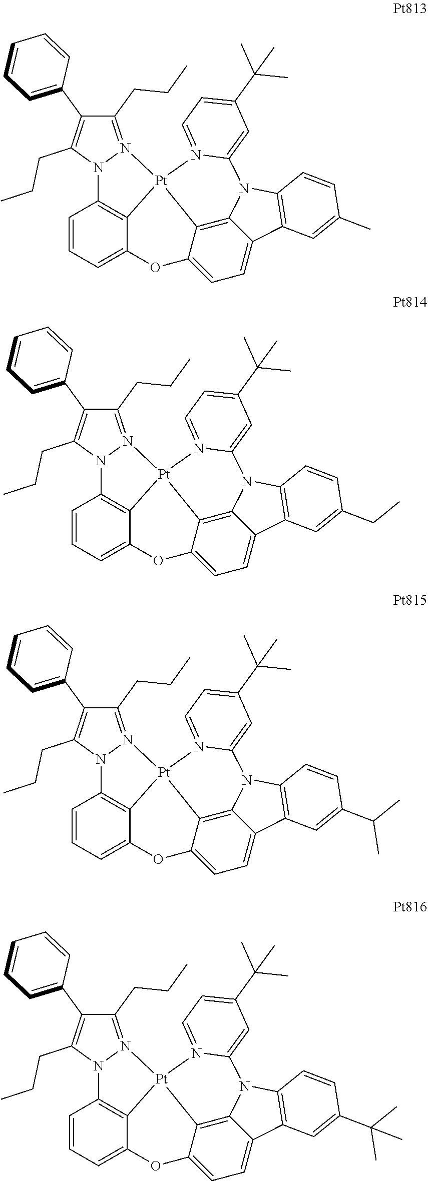

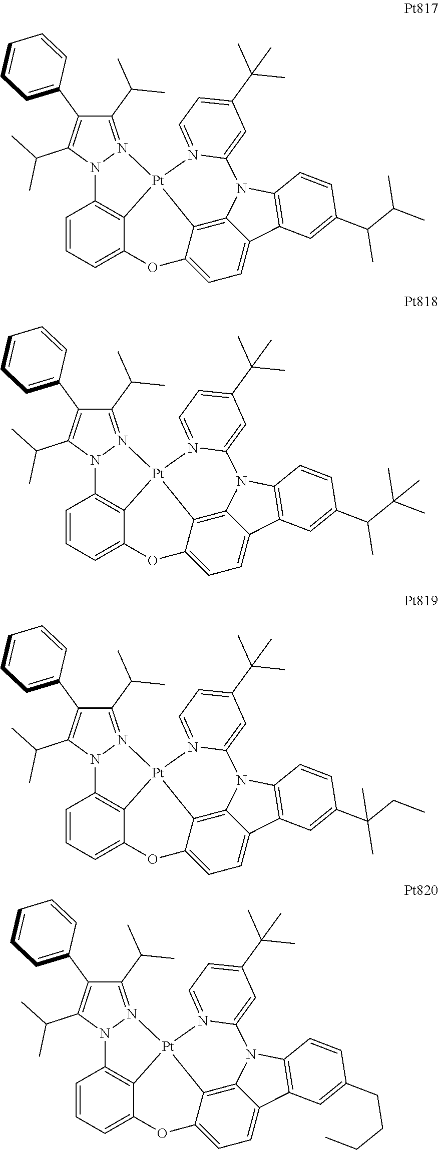

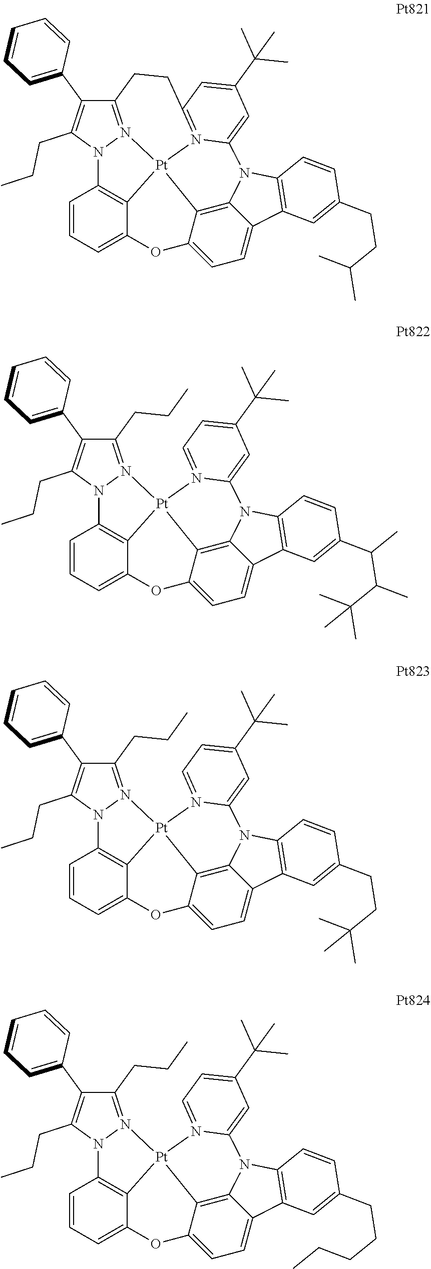

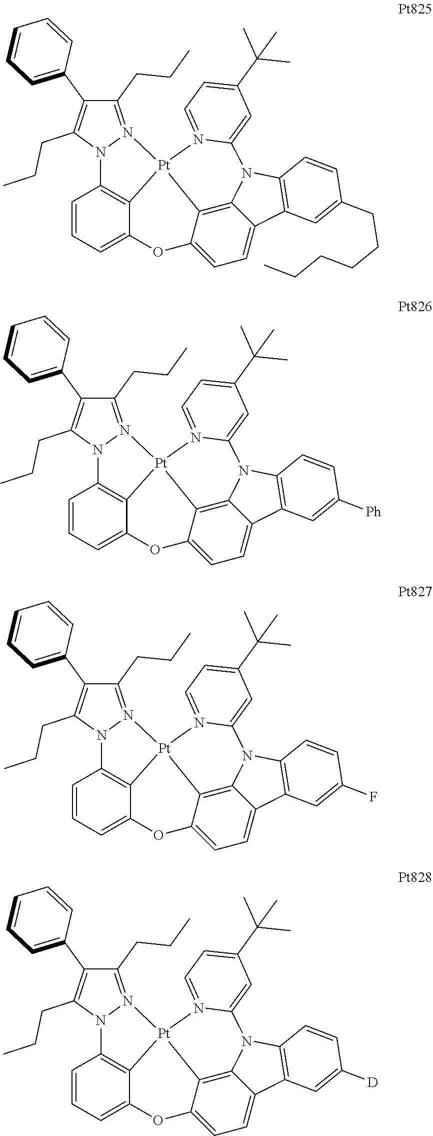

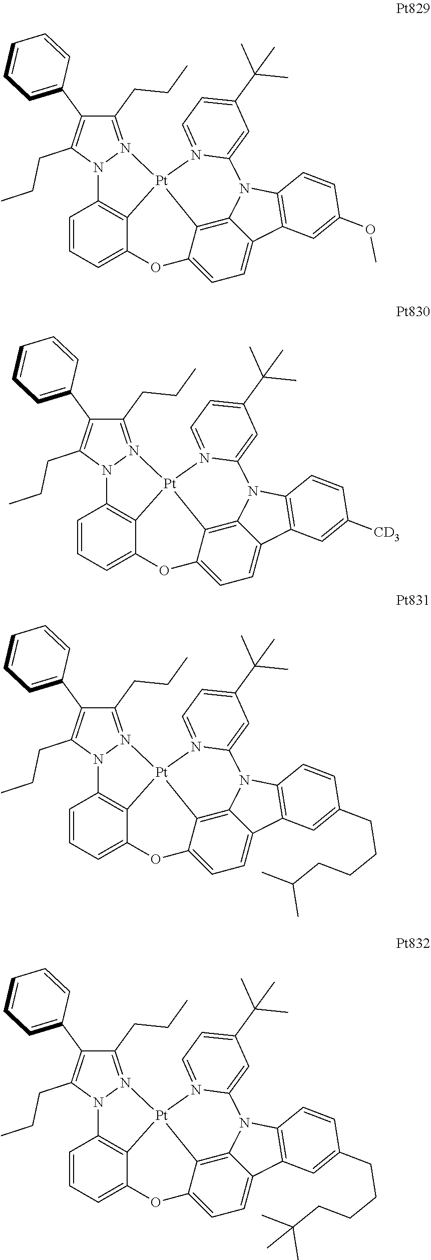

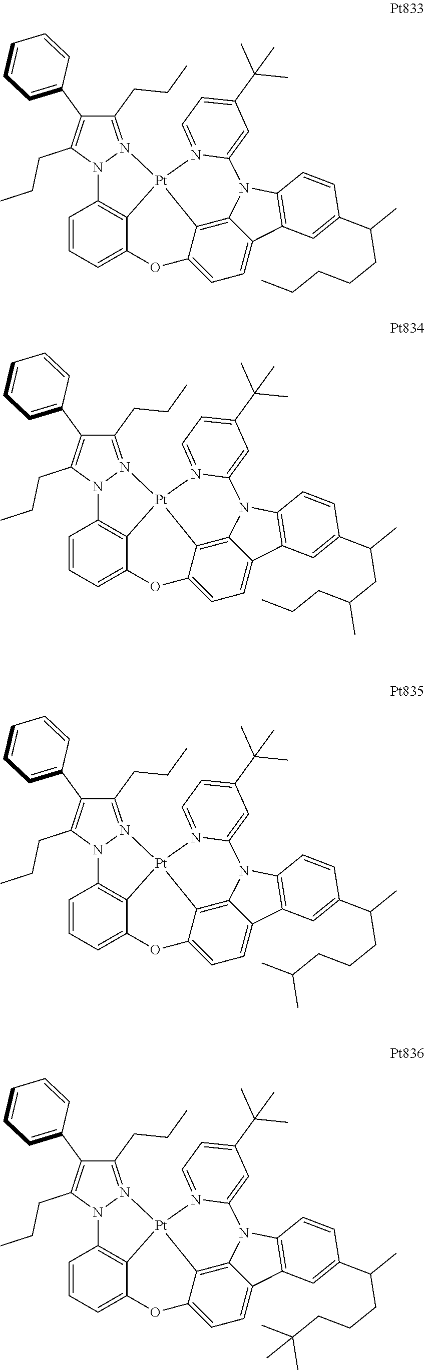

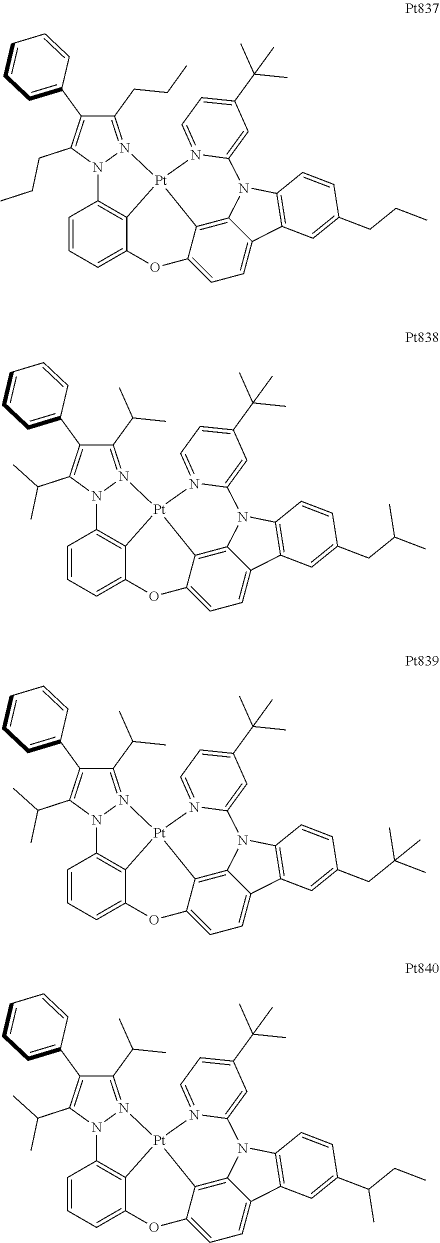

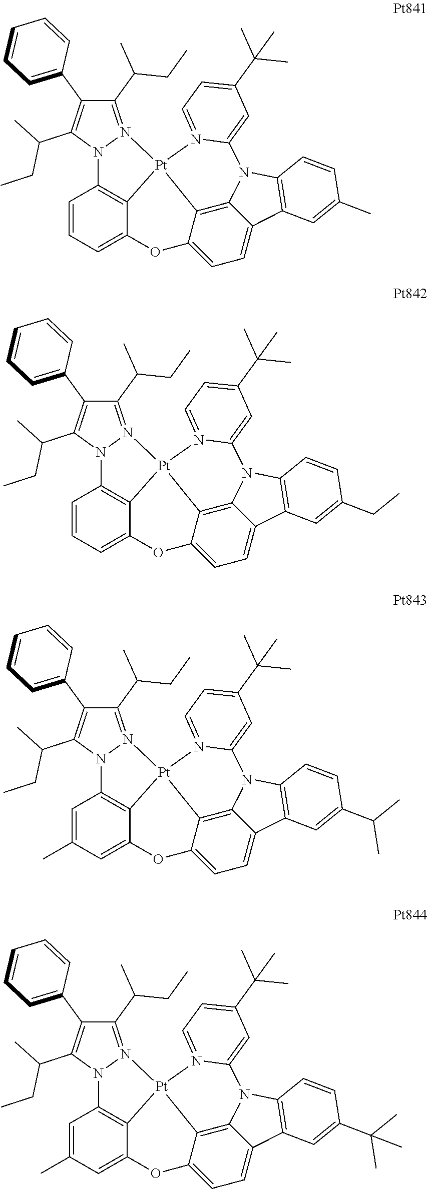

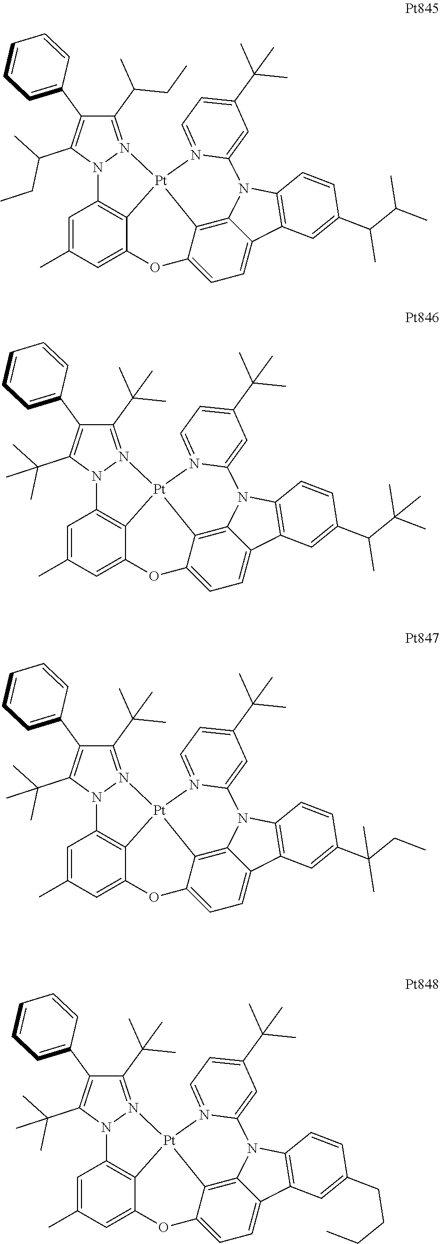

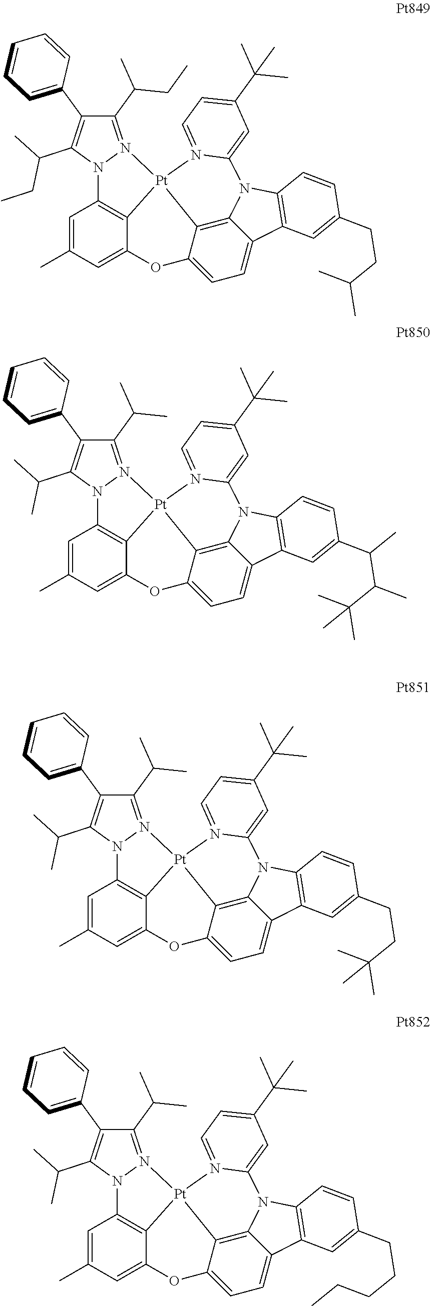

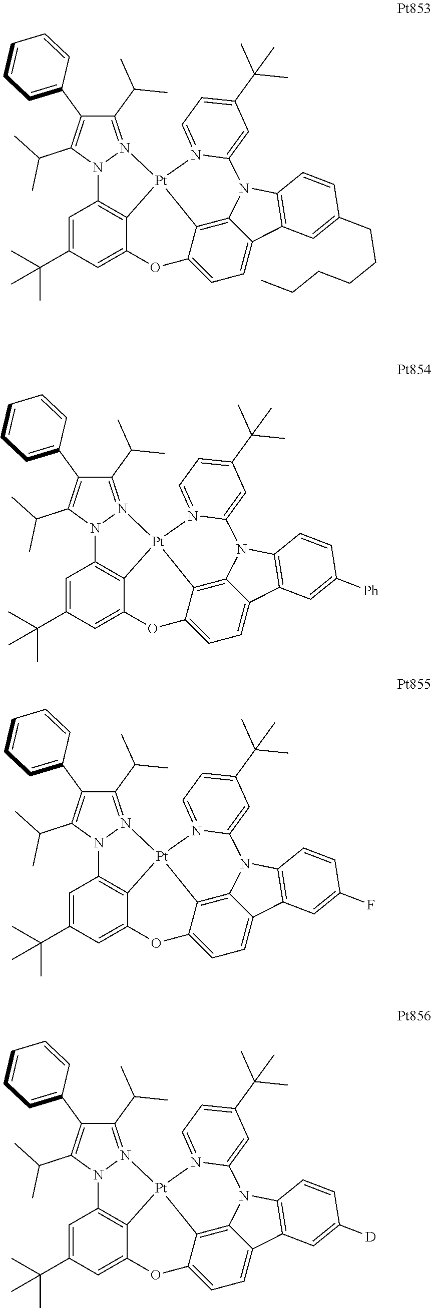

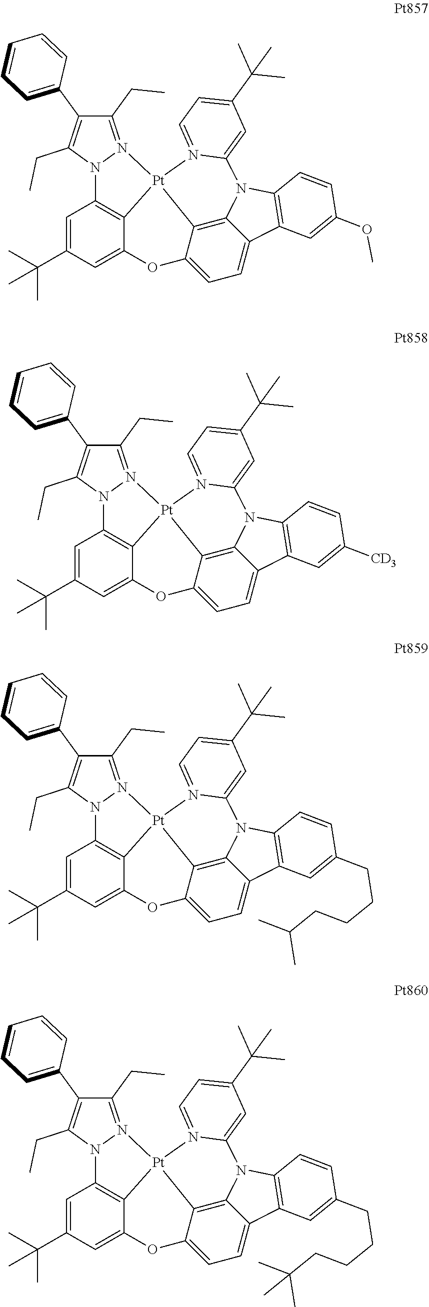

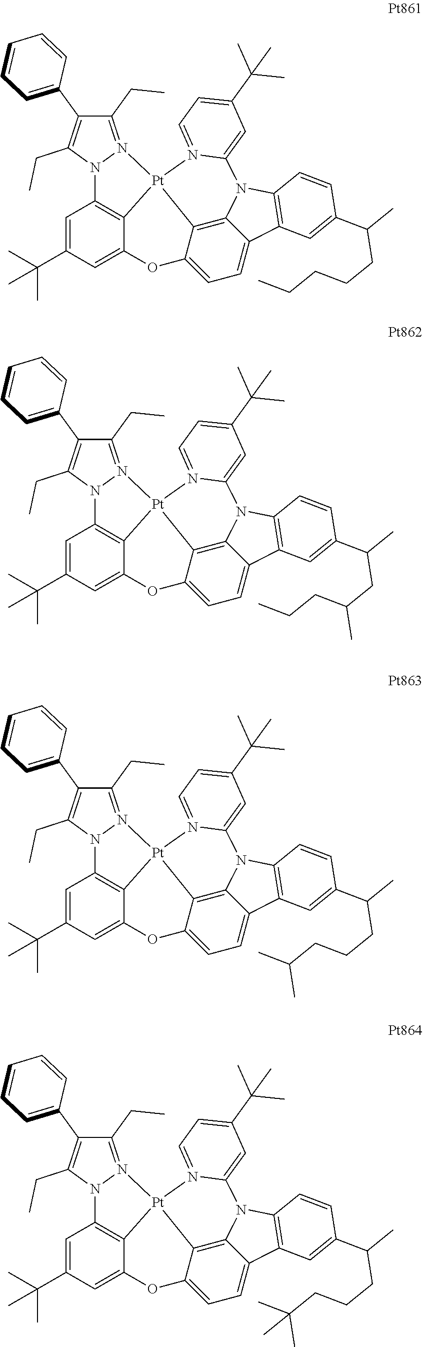

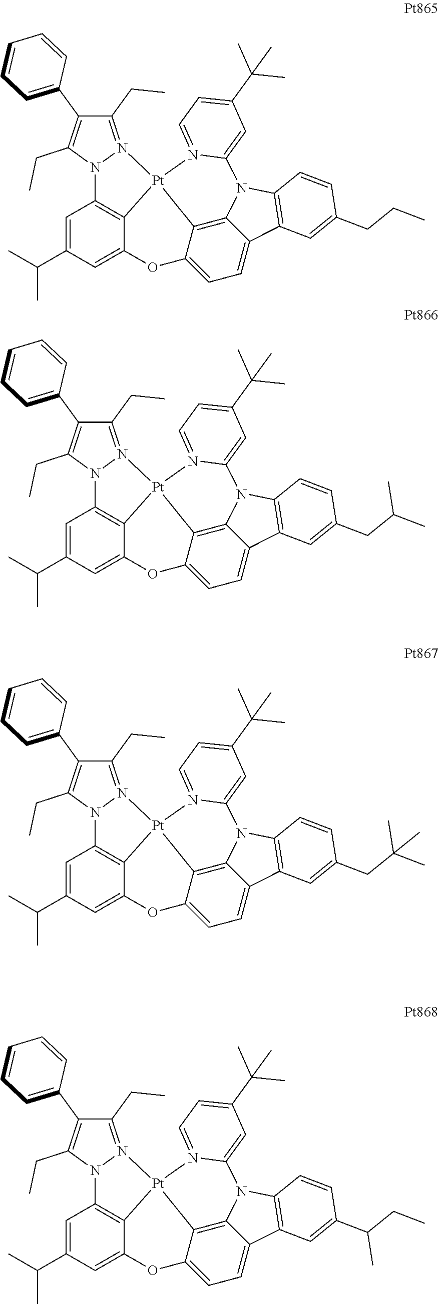

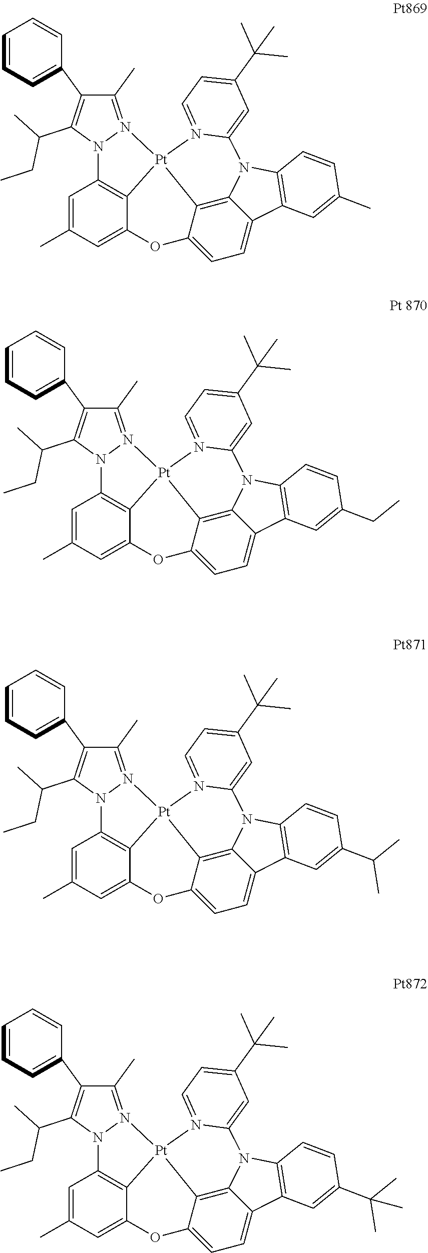

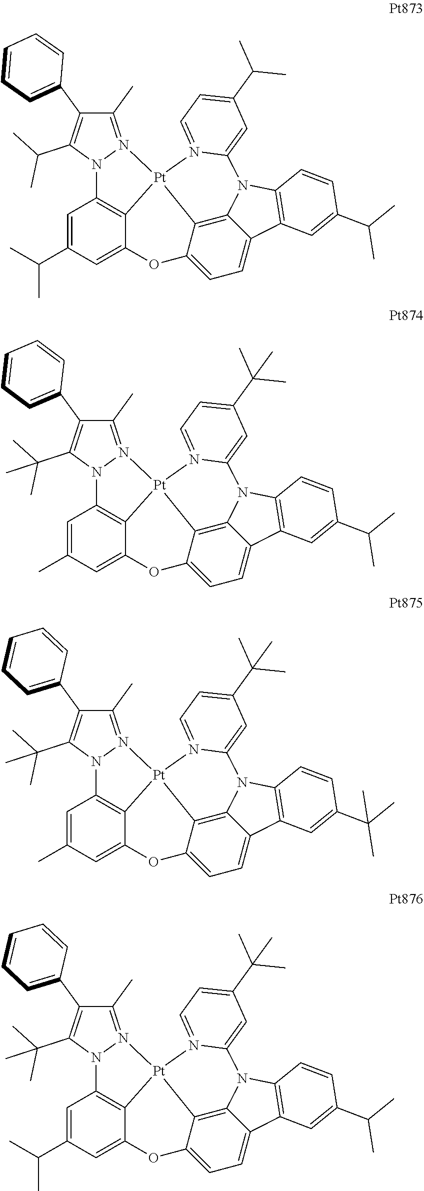

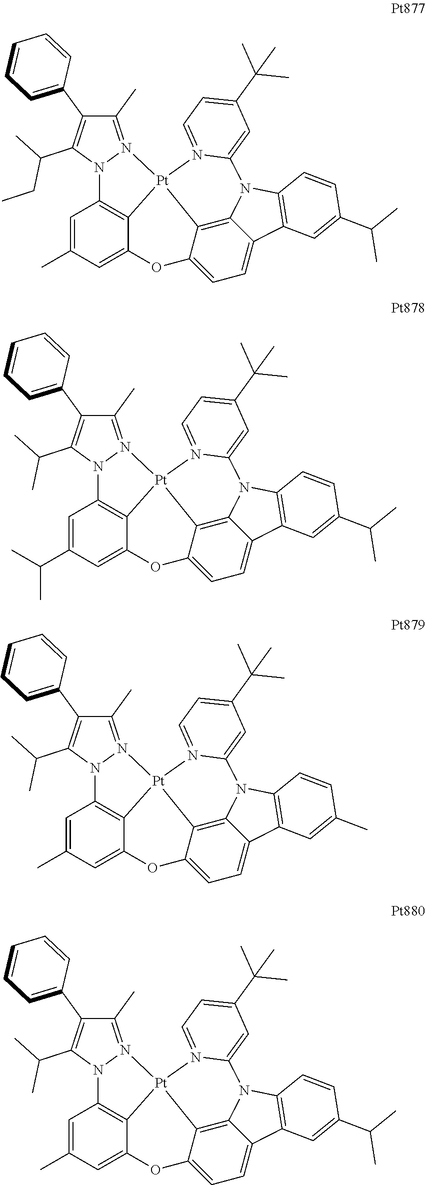

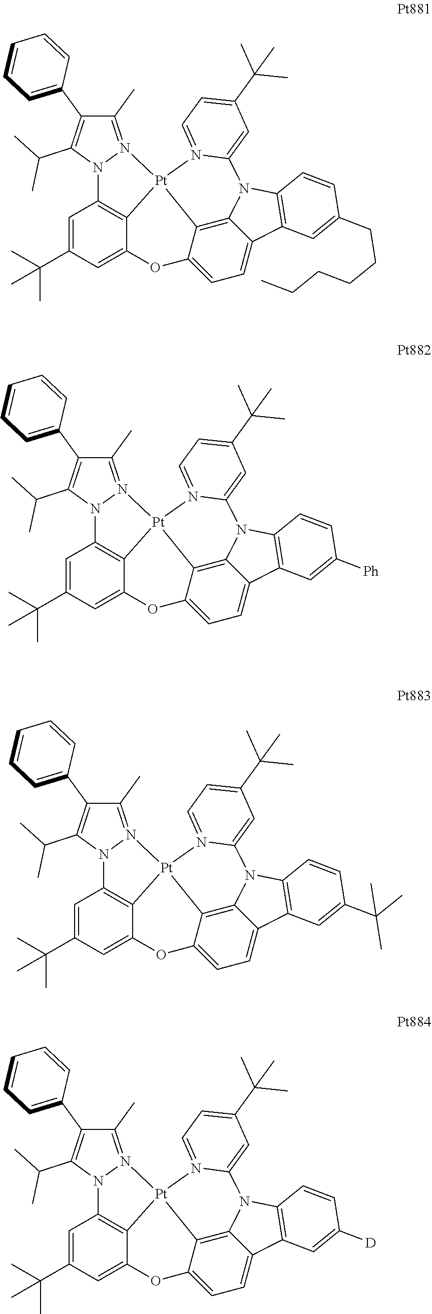

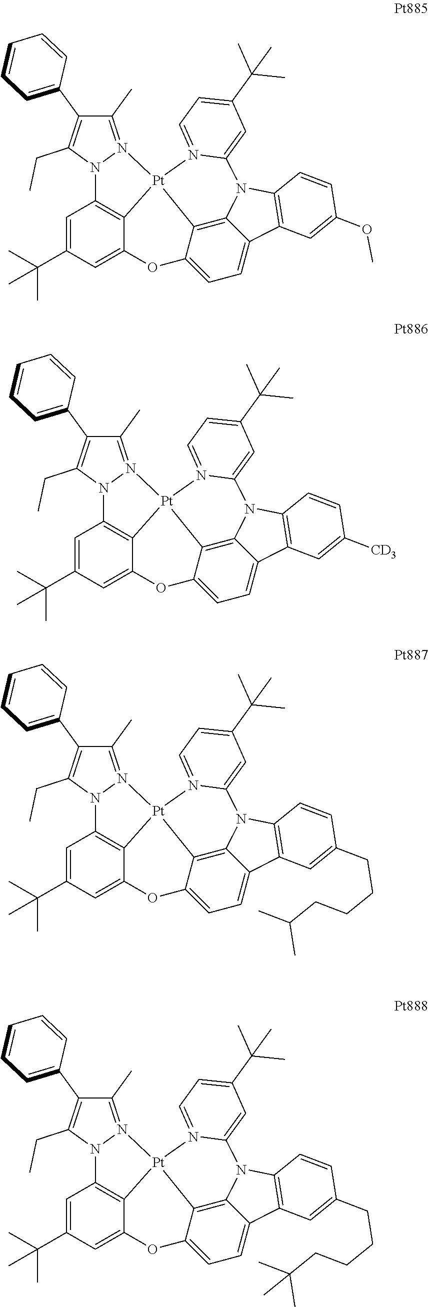

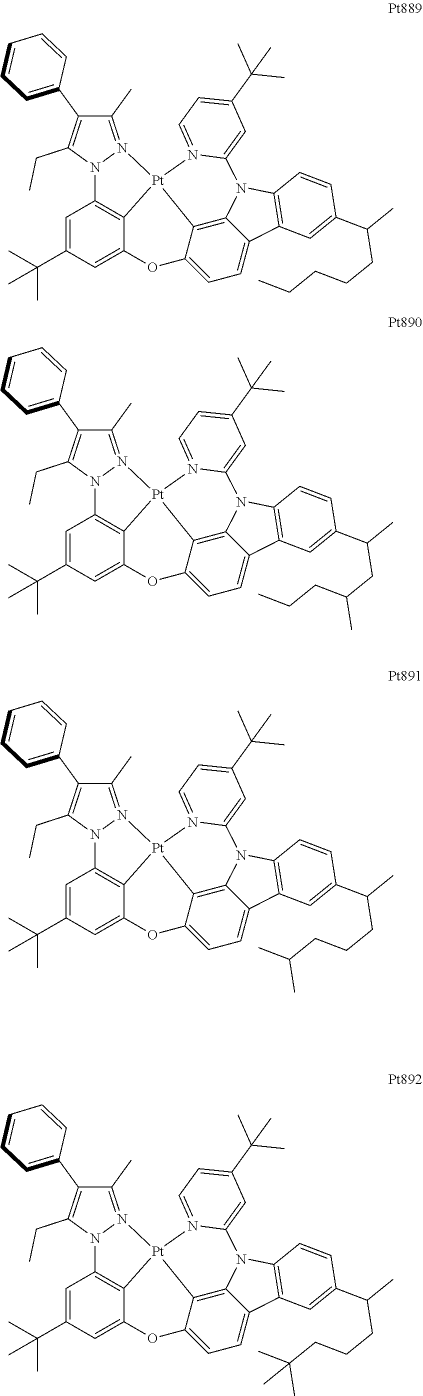

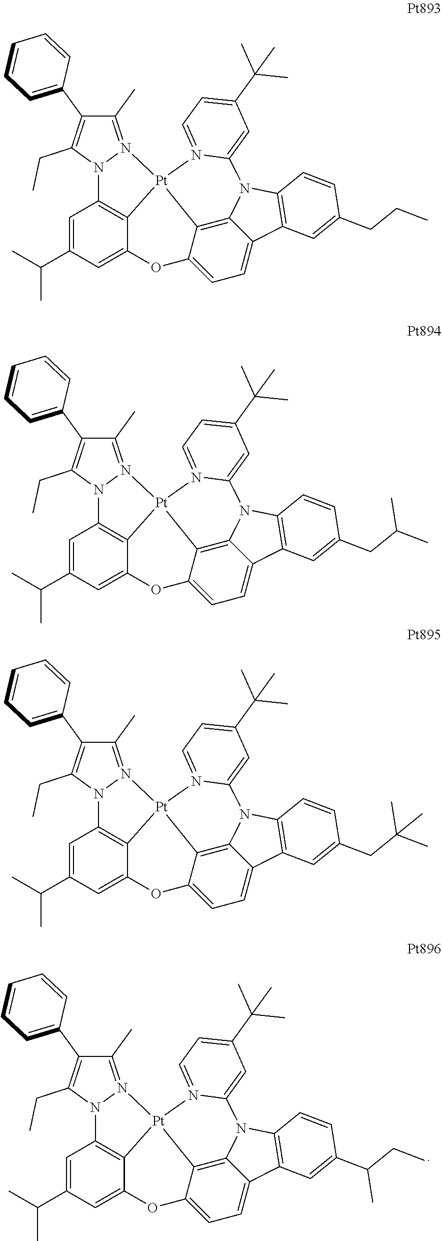

In some embodiments of the present disclosure, the tetradentate cyclic-metal platinum complex comprising 6-substituted carbazole provided is electrically neutral.

Some embodiments of the present disclosure also provide the use of the tetradentate cyclic-metal platinum complex comprising 6-substituted carbazole in the organic electroluminescent materials.

Some embodiments of the present disclosure also provide an optical or electro-optical device, which comprises one or more tetradentate cycli-metal platinum complex comprising 6-substituted carbazole described above.

In some embodiments of the present disclosure, the optical or electrical-optical device provided includes a light absorbing device (such as solar device or photosensing device), an organic light emitting diodes (OLED), a light emitting device or a device that is capable of light-absorbing and light-emitting.

In some embodiments of the present disclosure, the tetradentate cycli-metal platinum complex comprising 6-substituted carbazole has 100% of internal quantum efficiency in the optical or electrical-optical device.

Some embodiments of the present disclosure also provide an OLED device, the luminescent material or host material in the OLED device comprises one or more of the above-mentioned tetradentate cyclic-metal platinum complex comprising 6-substituted carbazole.

In some specific embodiments of the present disclosure, the complexes provided can be used as either host materials for OLED devices, such as in panchromatic display etc.; or luminescent material for OLED devices, such as light emitting devices and display and so on.

### Preparation and Performance Evaluation Examples

The examples are set forth below to provide those of ordinary skill in the art with complete disclosure and description of how to make and evaluate the complexes, compositions, articles, devices and/or methods described herein, and are intended to be only illustrative of the disclosure and not intended to limit the scope. Although efforts have been made to ensure accuracy with respect to numerical values (e.g., amounts, temperature, etc.), some errors and deviations should be taken into account. Unless otherwise indicated, parts are parts by weight, temperature is in ° C. or at ambient temperature, and pressure is at or near atmospheric pressure.

Various methods for preparing the complexes disclose herein are described in the examples. These methods are provided to illustrate various preparation methods, but the disclosure is not intended to be limited to any of the methods described herein. Accordingly, the person skilled in the art to which the disclosure pertains can easily modify the described methods or utilize different methods to prepare one or more of the disclosed complexes. The following aspects are only exemplary and are not intended to limit the scope of the disclosure. Temperatures, catalysts, concentrations, reactant compositions, and other process conditions may vary, and for the desired complexes, one skilled in the art of the disclosure can readily select suitable reactants and conditions.

The ¹H spectrum was recorded at 400 MHz in a CDCl₃ or DMSO-d₆ solution on a Varian Liquid State NMR instrument, and ¹³C NMR spectrum was recorded at 100 MHz with the chemical shifts referenced to the residual protiated solvent. If CDCl₃ is used as a solvent, ¹H NMR spectrum is recorded using tetramethysilane (δ=0.00 ppm) as an internal standard; ¹³C NMR spectrum is recorded using DMSO-d₆ (δ=77.00 ppm) as an internal standard. If H₂O (6=3.33 ppm) is used as a solvent, ¹H NMR spectrum is recorded using tresidual H₂O (δ=3.33 ppm) as an internal standard; ¹³C NMR spectrum is recorded using DMSO-d₆ (δ=39.52 ppm) as an internal standard. The following abbreviations (or combinations thereof) are used to explain the multiplicity of ¹H NMR: s=singlet, d=double, t=triplet, q=fourfold, P=fivefold, m=multiplex, br=broad.

### General Synthetic Route

The general synthesis route for the complexes disclosed in the present disclosure is as follows:

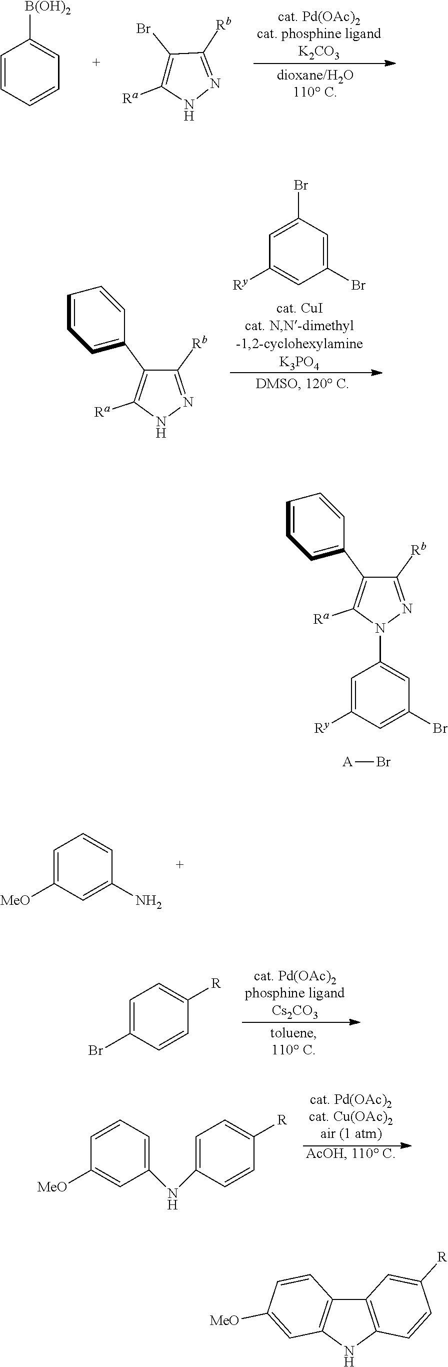

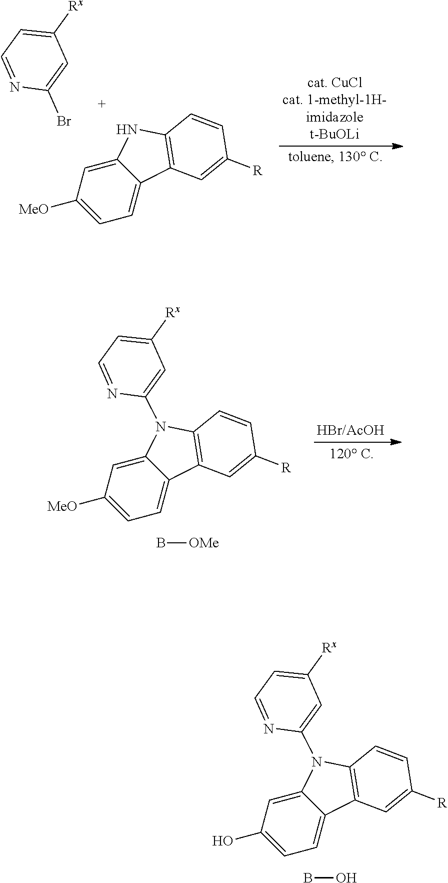

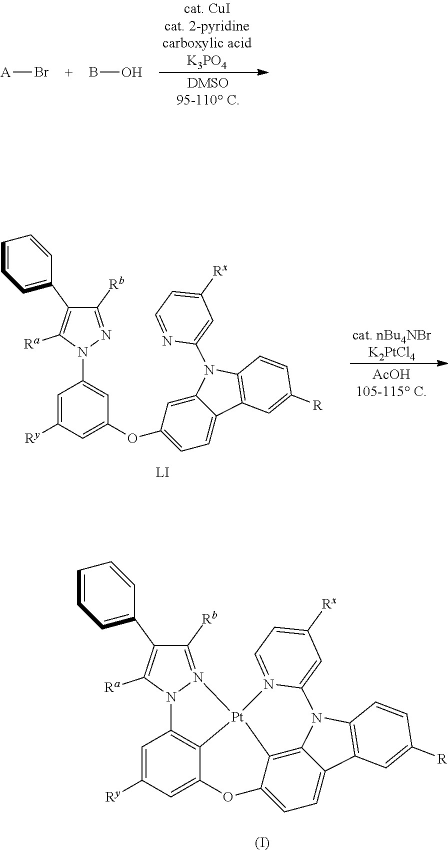

### Preparation Examples

### Example 1: Synthesis of the Complex Pt29

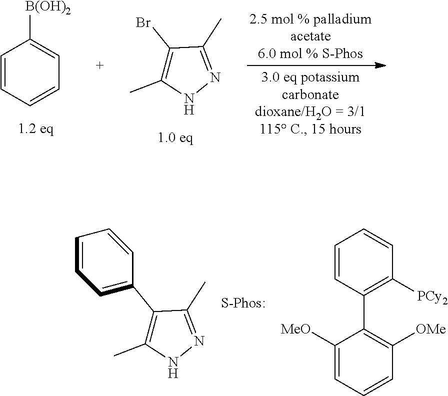

To a dry three-necked flask with a magnetic rotor, 4-bromo-3,5-dimethylpyrazole (3.5714 g, 20 mmol, 98%, 1.0 eq), phenylboronic acid (2.9552 g, 24 mmol, 99%, 1.2 eq), palladium acetate (0.1123 g, 0.5 mmol, 0.025 eq), ligand S-Phos (0.5027 g, 1.2 mmol, 98%, 0.06 eq), 1,4-dioxane (60 mL) and 20 mL of aqueous potassium carbonate (8.2920 g, 60 mmol, 3.0 eq) were added in order. Nitrogen was bubbled for 15 minutes and then the reaction flask was placed in a 115° C. oil bath. After stirring for 15 hours, the thin layer chromatography (TLC) monitoring reaction was completed. Cool to room temperature and extract with dichloromethane (20 mL×3). All the organic phases were combined and dried over anhydrous sodium sulfate. Filtration, concentration, and purification of the obtained crude product by flash silica gel column chromatography (eluent: petroleum ether/ethyl acetate=3/1˜1/2), get 3,5-dimethyl-4-phenyl-1H-imidazole, white solid 3.0773 g, 89% yield. ¹H NMR (500 MHz, DMSO-d₆): δ 2.18 (s, 3H), 2.21 (s, 3H), 7.21-7.32 (m, 3H), 7.36-7.44 (m, 2H), 12.30 (s, 1H).

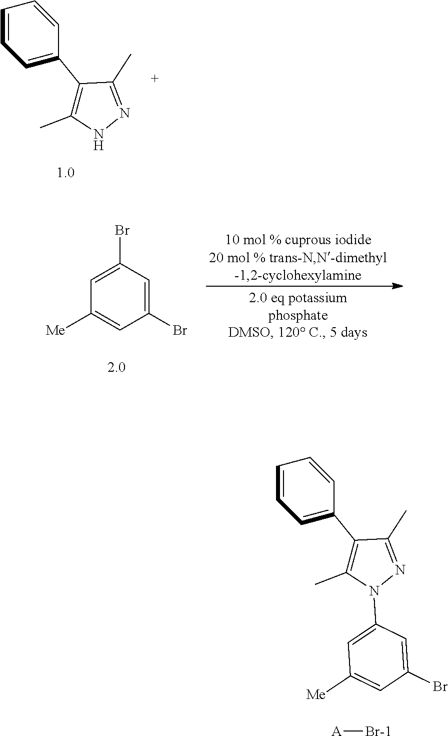

To a dry sealed tube with a magnetic rotor, 3,5-dimethyl-4-phenyl-1H-imidazole (0.3446 g, 2.0 mmol, 1.0 eq), 3,5-dibromotoluene (1.0201 g, 4.0 mmol, 98%, 2.0 eq), cuprous iodide (0.0381 g, 0.2 mmol, 0.1 eq), potassium phosphate (0.8492 g, 4 mmol, 2.0 eq) and trans-N,N′-dimethyl-1,2-cyclohexanediamine (0.0581 g, 0.4 mmol, 98%, 0.2 eq) were added in order. Nitrogen was purged three times and then dimethyl sulfoxide (3 mL) was added under nitrogen protection. Then the tube was placed in a 120° C. oil bath. After stirring for 5 days, cool to room temperature and add ethyl acetate (30 mL) and brine (15 mL×2). Combine the aqueous phases and extract with ethyl acetate (10 mL×2). Combine all the organic phases and dry over anhydrous sodium sulfate. Filtration, concentration, and purification of the obtained crude product by flash silica gel column chromatography (eluent: petroleum ether/ethyl acetate=15/1), get A-Br-1, white solid 0.5590 g, yield 82%. ¹H NMR (500 MHz, DMSO-d₆): δ 2.22 (s, 3H), 2.30 (s, 3H), 2.39 (s, 3H), 7.29-7.38 (m, 3H), 7.42 (s, 1H), 7.43-7.50 (m, 3H), 7.57 (s, 1H).

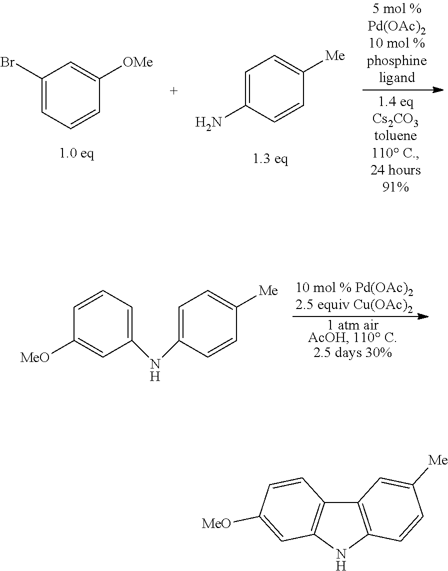 [SMILES: COc1cccc(Br)c1 ; Cc1ccc(N)cc1 ; COc1cccc(Nc2ccc(C)cc2)c1 ; "1 atm airAcOH, 110° C.2.5 days 30%" ; COc1ccc2c(c1)[nH]c1ccc(C)cc12]

To a dry three-necked flask with a magnetic rotor, p-toluidine (4.2230 g, 39 mmol, >99%, 1.3 eq), Pd(OAc)₂ (0.3368 g, 1.5 mmol, 0.05 eq), phosphine ligand S-Phos (1.2566 g, 3.0 mmol, 98%, 0.1 eq) and Cs₂CO₃ (13.8218 g, 42 mmol, 99%, 1.4 eq) were added in order. After nitrogen was purged three times, toluene (15 mL) was added at room temperature, then the reaction flask was placed in a 110° C. oil bath and a toluene solution (54 mL) of m-bromoanisole (5.7245 g, 30 mmol, 98%, 1.0 eq) was added dropwise under nitrogen protection over 1 hour. After stirring for 24 hours, the TLC monitoring reaction was completed. Cool to room temperature, diatomaceous earth was filtered, and insoluble matter was thoroughly washed with dichloromethane (30 mL×3). Concentrate, the resulting crude product was purified by flash silica gel column chromatography (eluent: petroleum ether/dichloromethane/triethylamine=200/10/1) to obtain N-p-tolyl-3-methoxy aniline, white solid 5.8199 g, yield 91%, directly into the next reaction.

To a dry one-necked flask with a magnetic rotor, N-p-tolyl-3-methoxyaniline (1.5239 g, 7.1 mmol, 1.0 eq), Pd(OAc)₂ (0.1599 g, 0.71 mmol, 0.1 eq), Cu(OAc)₂ (3.2989 g, 17.8 mmol, 98%, 2.5 eq) and AcOH (35 mL) were added in order, then the reaction flask was placed in a 110° C. oil bath. After stirring for 2.5 days, the TLC monitoring reaction was completed. Cool to room temperature, diatomaceous earth was filtered, and insoluble matter was thoroughly washed with ethyl acetate (30 mL×3). Filtration, concentration, and purification of the obtained crude product by flash silica gel column chromatography (eluent: petroleum ether/ethyl acetate=10/1˜5/1), get 6-dimethyl-2-methoxy carbazole, pale solid 0.4521 g, 30% yield. ¹H NMR (500 MHz, acetone-d₆): δ 2.50 (s, 3H), 3.89 (s, 3H), 6.81 (dd, J₁=8.5 Hz, J₂=2.2 Hz, 1H), 7.03 (d, J=2.2 Hz, 1H), 7.15 (dd, J₁=8.2 Hz, J₂=1.3 Hz, 1H), 7.36 (d, J=8.2 Hz, 1H), 7.79-7.86 (m, 1H), 7.96 (d, J=8.5 Hz, 1H), 10.08 (br s, 1H).

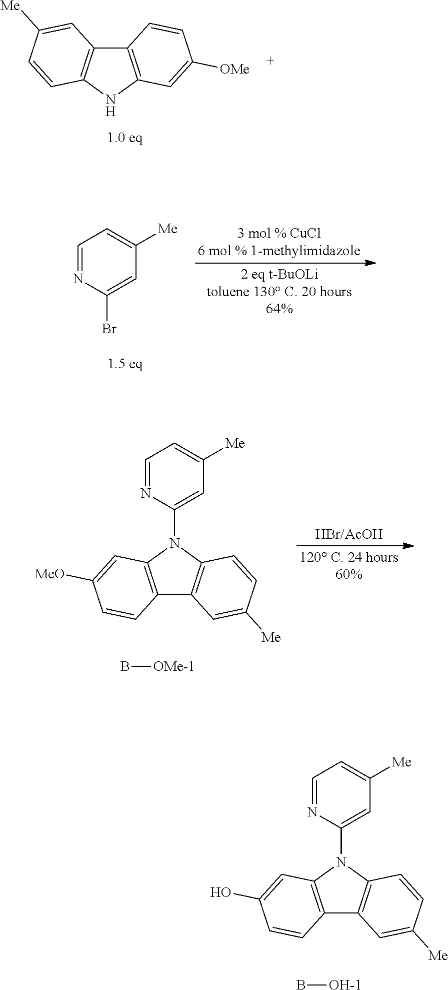

To a dry three-necked flask with a magnetic rotor, 6-methyl-2-methoxy carbazole (0.5009 g, 2.36 mmol, 1.0 eq), CuCl (0.0070 g, 0.07 mmol, 99%, 0.03 eq) and t-BuOLi (0.3821 g, 4.73 mmol, 99%, 2.0 eq) were added in order. Nitrogen was purged three times and then 2-bromo-4-methyl pyridine (0.6220 g, 3.54 mmol, 98%, 1.5 eq), 1-methyl imidazole (11.5 μL, 0.14 mmol, 99%, 0.06 eq) and toluene (9 mL) were add under nitrogen protection. The reaction flask was then placed in a 130° C. oil bath. After stirring for 20 hours, the thin layer chromatography (TLC) monitoring reaction was completed. Cool to room temperature, filtration, concentration, and purification of the obtained crude product by flash silica gel column chromatography (eluent: petroleum ether/ethyl acetate=10/1˜5/1), get B—OMe-1, pale yellow oil 0.4582 g, 64% yield, directly to the next step.

Under nitrogen protection, to a dry one-neck flask with magnetic rotor add B—OMe-1 (0.3657 g, 1.2 mmol, 1.0 eq), AcOH (7 mL) and HBr (9 mL, 48% aqueous solution). The reaction flask was then placed in a 120° C. oil bath. After stirring for 24 hours, the TLC monitoring reaction was completed. Cool to room temperature, concentrate, add ethyl acetate (20 mL), then add saturated sodium bicarbonate solution until no bubbles are generated. The organic phase was separated and the aqueous phase was extracted with ethyl acetate (10 mL×2). Combine all organic phases and dry over anhydrous sodium sulfate. Filtration, concentration, and purification of the obtained crude product by flash silica gel column chromatography (eluent: petroleum ether/ethyl acetate=2/1˜1/1), get B—OH-1, light brown 0.2098 g, 60% yield, directly to the next step.

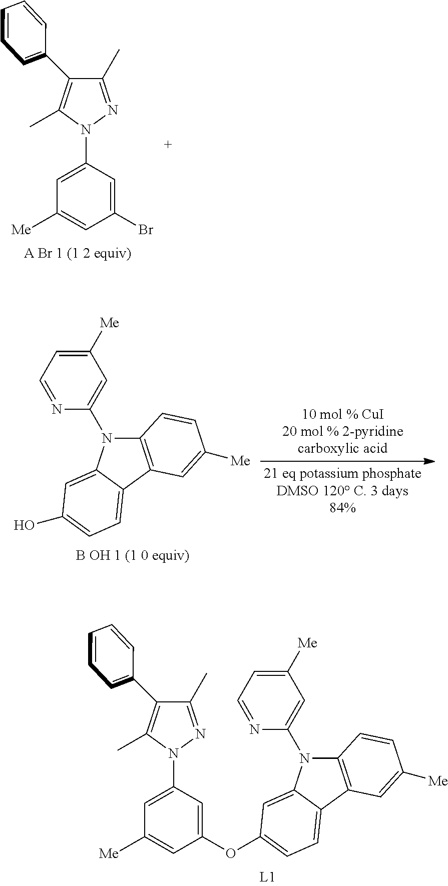

To a dry sealed tube with a magnetic rotor, A-Br-1 (0.2011 g, 0.59 mmol, 1.2 eq), B—OH-1 (0.1419 g, 0.50 mmol, 1.0 eq), CuI (0.0094 g, 0.05 mmol, 0.1 eq), 2-pyridine carboxylate (0.0122 g, 0.10 mmol, 99%, 0.2 eq) and potassium phosphate (0.2189 g, 1.03 mmol, 2.1 eq) were added in order. Nitrogen was purged three times and then dimethyl sulfoxide (5 mL) was added under nitrogen protection. The sealed tube was then placed in a 120° C. oil bath. After stirring for 3 days, the thin layer chromatography (TLC) monitoring reaction was completed. Cool to room temperature and add ethyl acetate (20 mL) and brine (10 mL×2). Combine the aqueous phases and extract with ethyl acetate (10 mL×2). Combine all organic phases and dry over anhydrous sodium sulfate. Filtration, concentration, and purification of the obtained crude product by flash silica gel column chromatography (eluent: petroleum ether/ethyl acetate=10/1), get L1, white solid 0.2258 g, yield 84%. ¹H NMR (400 MHz, DMSO-d₆): δ 2.18 (s, 3H), 2.23 (s, 3H), 2.36 (s, 3H), 2.44 (s, 3H), 2.50 (s, 3H), 6.90-6.97 (m, 2H), 7.07 (dd, J₁=8.4 Hz, J₂=2.0 Hz, 1H), 7.14 (s, 1H), 7.24-7.29 (m, 2H), 7.29-7.34 (m, 3H), 7.43 (t, J=7.6 Hz, 2H), 7.53 (d, J=2.0 Hz, 1H), 7.58 (s, 1H), 7.68 (d, J=8.4 Hz, 1H), 8.02 (s, 1H), 8.23 (d, J=8.4 Hz, 1H), 8.51 (d, J=4.8 Hz, 1H).

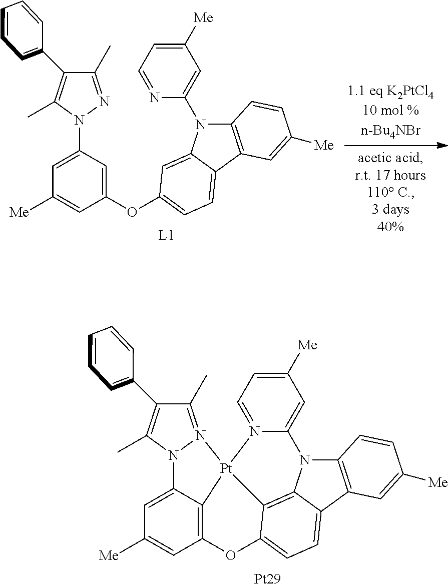

To a dry sealed tube with a magnetic rotor, L1 (0.2086 g, 0.38 mmol, 1.0 eq), K₂PtCl₄ (0.1735 g, 0.418 mmol, 1.1 eq) and n-Bu₄NBr (0.0124 g, 0.038 mmol, 0.1 eq) were added in order. Nitrogen was purged three times and then acetic acid (22.8 mL) was added under nitrogen protection. Nitrogen was bubbled for 30 minutes and stirred at room temperature for 17 hours, then the reaction flask was placed in a 110° C. oil bath. After stirring for 3 days, cool to room temperature, concentration, and purification of the obtained crude product by flash silica gel column chromatography (eluent: petroleum ether/ethyl acetate/dichloromethane=40:2:3), get Pt29, pale yellow solid 0.1116 g, yield 40%. ¹H NMR (400 MHz, DMSO-d₆): δ 2.38 (s, 3H), 2.39 (s, 6H), 2.50 (s, 3H), 2.72 (s, 3H), 6.82 (s, 1H), 7.08-7.17 (m, 2H), 7.20 (s, 1H), 7.28 (d, J=8.0 Hz, 1H), 7.39-7.49 (m, 3H), 7.53 (t, J=7.6 Hz, 2H), 7.80 (d, J=8.4 Hz, 1H), 7.94 (s, 2H), 8.00 (d, J=8.4 Hz, 1H), 9.14 (d, J=6.0 Hz, 1H).

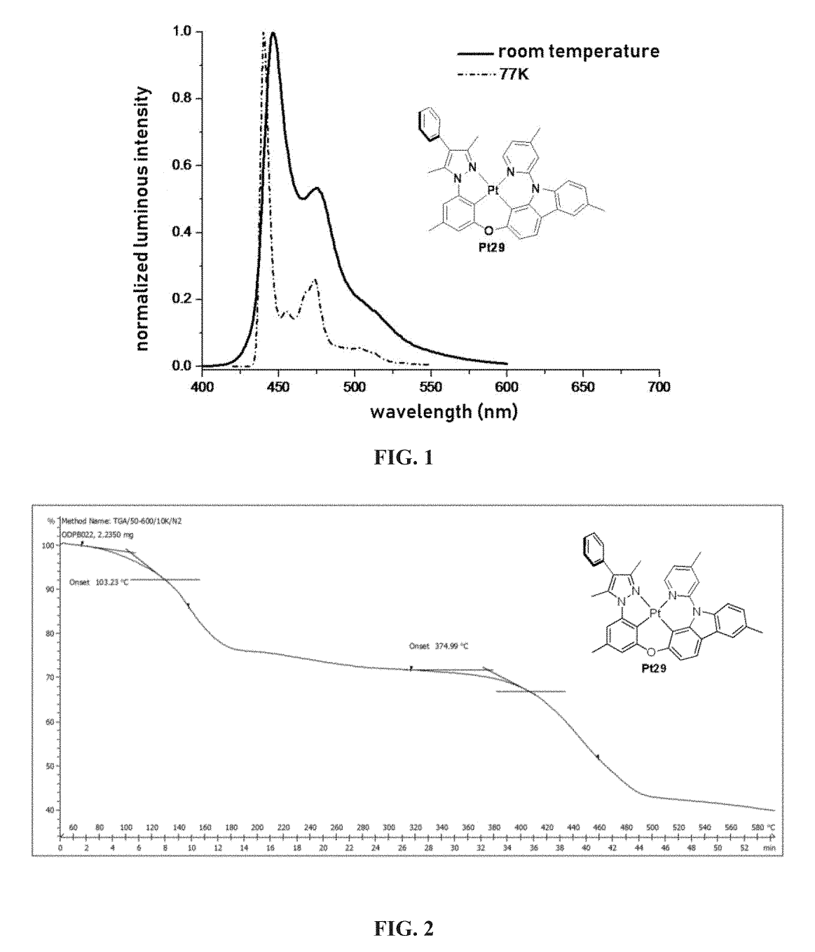

FIG. 1 shows a emission spectrum of the complex Pt29 in dichloromethane solution at room temperature; FIG. 2 shows a thermogravimetric analysis (TGA) curve of the complex Pt29.

### Example 2: Synthesis of the Complex Pt393

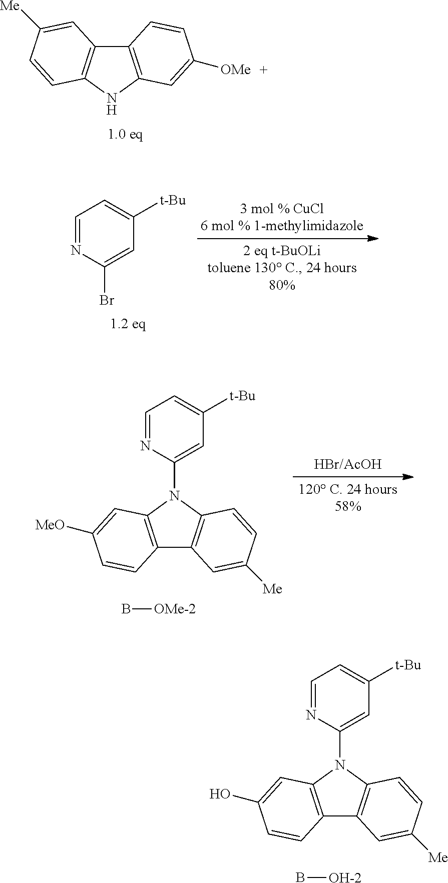

To a dry three-necked flask with a magnetic rotor, 6-methyl-2-methoxy carbazole (0.3085 g, 1.46 mmol, 1.0 eq), CuCl (0.0044 g, 0.044 mmol, 99%, 0.03 eq) and t-BuOLi (0.2367 g, 2.91 mmol, 99%, 2.0 eq) were added in order. Nitrogen was purged three times and then 2-bromo-4-tert butyl pyridine (0.3737 g, 1.75 mmol, 1.2 eq), 1-methyl imidazole (7.0 μL, 0.087 mmol, 99%, 0.06 eq) and toluene (6 mL) were add under nitrogen protection. Then the reaction flask was placed in a 130° C. oil bath. After stirring for 24 hours, the TLC monitoring reaction was completed. Cool to room temperature, filtration, concentration, and purification of the obtained crude product by flash silica gel column chromatography (eluent: petroleum ether/ethyl acetate=15/1˜10/1), get B—OMe-2, pale yellow oil 0.4017 g, 80% yield, directly to the next step.

Under nitrogen protection, to a dry one-necked flask with a magnetic rotor, B—OMe-2 (0.3814 g, 1.1 mmol, 1.0 eq), AcOH (7 mL) and HBr (9 mL, 48% aqueous solution) were added in order. The reaction flask was then placed in a 120° C. oil bath. After stirring for 24 hours, the TLC monitoring reaction was completed. Cool to room temperature, concentrate, add ethyl acetate (20 mL), then add saturated sodium bicarbonate solution until no bubbles are generated. The organic phase was separated and the aqueous phase was extracted with ethyl acetate (10 mL×2). Combine all organic phases and dry over anhydrous sodium sulfate. Filtration, concentration, and purification of the obtained crude product by flash silica gel column chromatography (eluent: petroleum ether/ethyl acetate=4/1˜2/1), get B—OH-2, pale yellow solid 0.2104 g, 58% yield, directly to the next step.

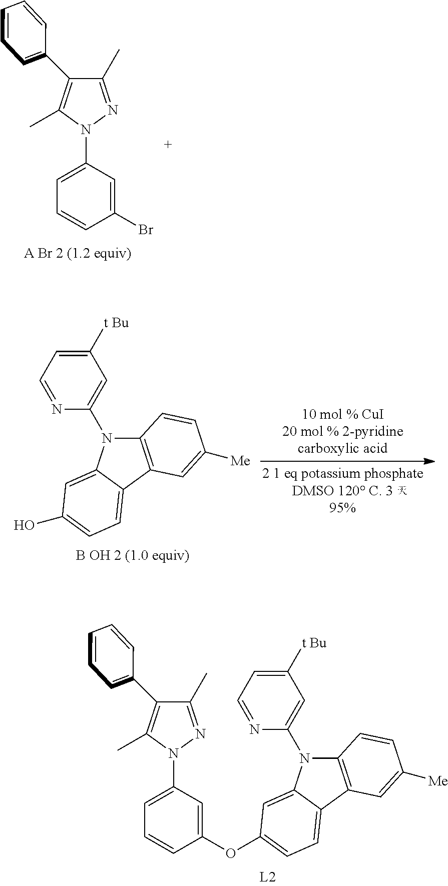

To a dry sealed tube with a magnetic rotor, A-Br-2 (0.2423 g, 0.74 mmol, 1.2 eq), B—OH-2 (0.2044 g, 0.62 mmol, 1.0 eq), CuI (0.0118 g, 0.06 mmol, 0.1 eq), 2-pyridine carboxylate (0.0154 g, 0.12 mmol, 99%, 0.2 eq) and potassium phosphate (0.2753 g, 1.30 mmol, 2.1 eq) were added in order. Nitrogen was purged three times and then dimethyle sulfoxide (5 mL) was added under nitrogen protection. The sealed tube was then placed in a 120° C. oil bath. After stirring for 3 days, the thin layer chromatography (TLC) monitoring reaction was completed. Cool to room temperature and add ethyl acetate (20 mL) and brine (10 mL×2). Combine the aqueous phases and extract with ethyl acetate (10 mL). Combine all organic phases and dry over anhydrous sodium sulfate. Filtration, concentration, and purification of the obtained crude product by flash silica gel column chromatography (eluent: petroleum ether/ethyl acetate=15/1˜10/1), get L2, white solid 0.3393 g, yield 95%. ¹H NMR (400 MHz, DMSO-d₆): δ 1.28 (s, 9H), 2.18 (s, 3H), 2.21 (s, 3H), 2.50 (s, 3H), 7.13 (td, J₁=8.0 Hz, J₂=2.0 Hz, 2H), 7.20 (t, J=2.2 Hz, 1H), 7.25-7.35 (m, 5H), 7.40-7.46 (m, 4H), 7.53 (d, J=8.0 Hz, 1H), 7.62 (d, J=0.8 Hz, 1H), 7.66 (d, J=8.4 Hz, 1H), 8.03 (s, 1H), 8.24 (d, J=8.4 Hz, 1H), 8.55 (d, J=5.2 Hz, 1H).

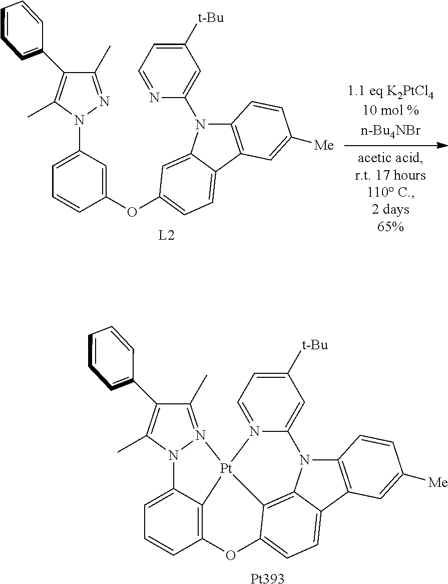

To a dry sealed tube with a magnetic rotor, L2 (0.3177 g, 0.55 mmol, 1.0 eq), K₂PtCl₄ (0.2514 g, 0.61 mmol, 1.1 eq) and n-Bu₄NBr (0.0179 g, 0.055 mmol, 0.1 eq) were added in order. Nitrogen was purged three times and then acetic acid (33 mL) was added under nitrogen protection. Nitrogen was bubbled for 30 minutes and stirred at room temperature for 17 hours, then the reaction flask was placed in a 110° C. oil bath. After stirring 2 days, cool to room temperature, concentration, and purification of the obtained crude product by flash silica gel column chromatography (eluent: petroleum ether/ethyl acetate/dichloromethane=50:2:3), get Pt393, pale yellow solid 0.2751 g, yield 65%. ¹H NMR (400 MHz, DMSO-d₆): δ 1.32 (s, 9H), 2.41 (s, 3H), 2.52 (s, 3H), 2.73 (s, 3H), 6.98 (d, J=8.0 Hz, 1H), 7.17 (d, J=8.4 Hz, 1H), 7.24 (t, J=8.0 Hz, 1H), 7.31 (d, J=7.2 Hz, 1H), 7.34 (dd, J₁=6.4 Hz, J₂=2.0 Hz, 1H), 7.38 (d, J=8.0 Hz, 1H), 7.41-7.50 (m, 3H), 7.54 (t, J=7.4 Hz, 2H), 7.83 (d, J=8.0 Hz, 1H), 7.96 (s, 1H), 8.00 (d, J=8.4 Hz, 1H), 8.03 (d, J=1.6 Hz, 1H), 9.17 (d, J=6.4 Hz, 1H).

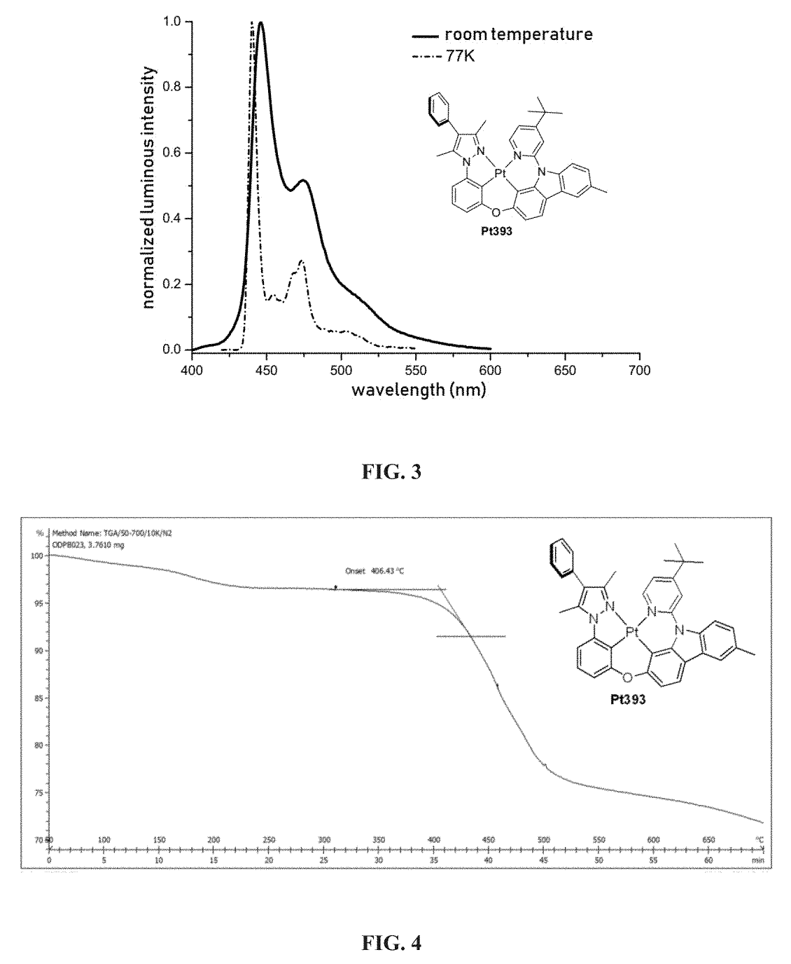

FIG. 3 shows a emission spectrum of the complex Pt393 in dichloromethane solution at room temperature; FIG. 4 shows a thermogravimetric analysis (TGA) curve of the complex Pt393.

### Example 3: Synthesis of the Complex Pt116

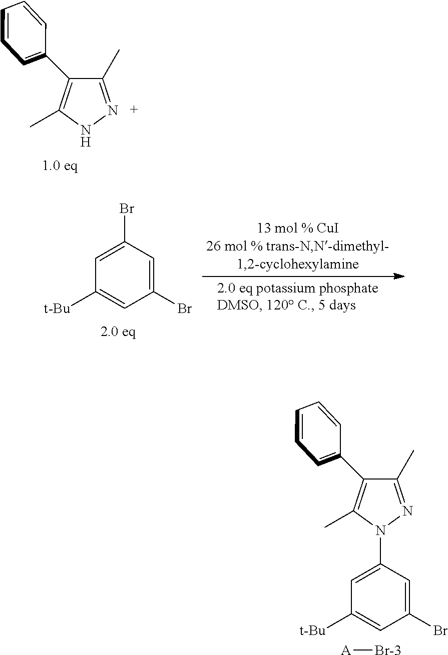

To a dry three-necked flask with a magnetic rotor, 3,5-dimethyl-4-phenyl-1H-imidazole (2.0680 g, 12 mmol, 1.0 eq), 1.3-dibromo-5-tert butyl benzene (7.1513 g, 24 mmol, 98%, 2.0 eq), cuprous iodide (0.2971 g, 1.56 mmol, 0.13 eq), potassium phosphate (5.0945 g, 24 mmol, 2.0 eq) and trans-N,N′-dimethyl-1,2-cyclohexanediamine (0.4528 g, 3.12 mmol, 98%, 0.26 eq) were added in order. Nitrogen was purged three times and then dimethyl sulfoxide (18 mL) was added under nitrogen protection. Then the tube was placed in a 120° C. oil bath. After stirring 5 days, cool to room temperature, diatomaceous earth was filtered, and insoluble matter was thoroughly washed with ethyl acetate (30 mL×3). The resulting filtrate was washed with brine (20 mL×2), combined aqueous phases and extracted with ethyl acetate (10 mL×2). Combine all organic phases and dry over anhydrous sodium sulfate. Filtration, concentration, and purification of the obtained crude product by flash silica gel column chromatography (eluent: petroleum ether/ethyl acetate=30/1˜15/1), get A-Br-3, pale yellow oil 2.5293 g, 55% yield. ¹H NMR (500 MHz, DMSO-d₆): δ 1.33 (s, 9H), 2.23 (s, 3H), 2.31 (s, 3H), 7.30-7.40 (m, 3H), 7.44-7.50 (m, 2H), 7.55 (t, J=1.8 Hz, 1H), 7.57-7.60 (m, 2H).

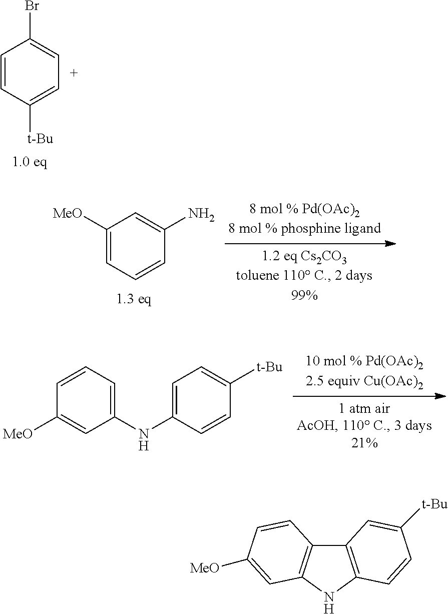 [SMILES: CC(C)(C)c1ccc(Br)cc1 ; COc1cccc(N)c1 ; COc1cccc(Nc2ccc(C(C)(C)C)cc2)c1 ; COc1ccc2c(c1)[nH]c1ccc(C(C)(C)C)cc12]

To a dry three-necked flask with a magnetic rotor, Pd(OAc)₂ (0.5388 g, 2.4 mmol, 0.08 eq), phosphine ligand BINAP (1.5250 g, 2.4 mmol, 98%, 0.08 eq) and Cs₂CO₃ (11.8473 g, 36 mmol, 99%, 1.2 eq) were added in order. After the nitrogen was purged three times, added m-methoxy aniline (4.9009 g, 39 mmol, 98%, 1.3 eq) and toluene (15 mL) at room temperature, and then the reaction flask was placed in a 110° C. oil bath, a solution of 4-tert-butyl bromobenzene (6.5235 g, 30 mmol, 98%, 1.0 eq) in toluene (54 mL) was added dropwise under nitrogen and completed over 1 hour. After stirring for 2 days, the thin layer chromatography (TLC) monitoring reaction was completed. Cool to room temperature, diatomaceous earth was filtered, and insoluble matter was thoroughly washed with dichloromethane (30 mL×3). Concentration, and purification of the obtained crude product by flash silica gel column chromatography (eluent: petroleum ether/dichloromethane/ethyl acetate=10/5/1), get N-(4-tert-butyl phenyl)-3-methoxy aniline, colourless liquid 7.5483 g, 99% yield, directly to the next step.

To a dry one-necked flask with a magnetic rotor, N-(4-tert-butyl phenyl)-3-methoxyaniline (2.0081 g, 7.8 mmol, 1.0 eq), Pd(OAc)₂ (0.1761 g, 0.78 mmol, 0.1 eq), Cu(OAc)₂ (3.6339 g, 19.6 mmol, 98%, 2.5 eq) and AcOH (35 mL) were added in order, then the reaction flask was placed in a 110° C. oil bath. After stirring for 3 days, the thin layer chromatography (TLC) monitoring reaction was completed. Cool to room temperature, diatomaceous earth was filtered, and insoluble matter was thoroughly washed with ethyl acetate (30 mL×3). concentration, and purification of the obtained crude product by flash silica gel column chromatography (eluent: petroleum ether/ethyl acetate=10/1˜5/1), get 6-tert-butyl-2-methoxy carbazole, pale yellow solid 0.4104 g, 21% yield. ¹H NMR (400 MHz, DMSO-d₆): δ 1.38 (s, 9H), 3.83 (s, 3H), 6.73 (dd, J₁=8.4 Hz, J₂=2.0 Hz, 1H), 6.93 (d, J=2.0 Hz, 1H), 7.29-7.39 (m, 2H), 7.93-8.01 (m, 2H), 10.95 (br s, 1H).

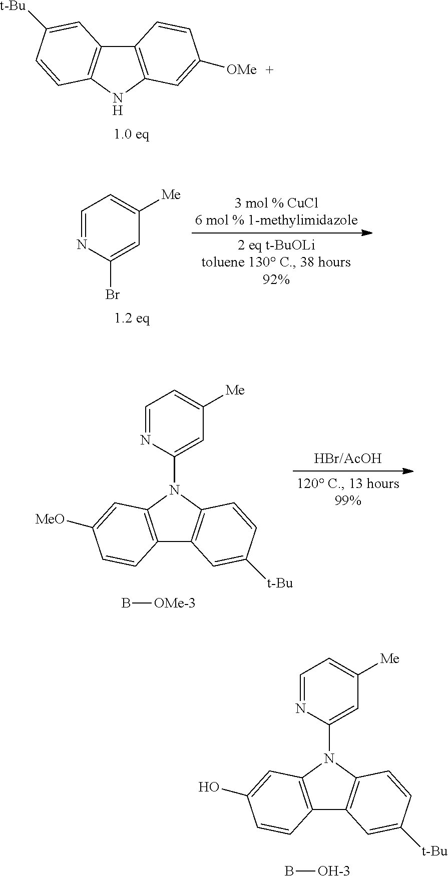

To a dry three-necked flask with a magnetic rotor, 6-tert-butyl-2-methoxy carbazole (0.3111 g, 1.22 mmol, 1.0 eq), CuCl (0.0037 g, 0.037 mmol, 99%, 0.03 eq) and t-BuOLi (0.1991 g, 2.45 mmol, 99%, 2.0 eq) were added in order. Nitrogen was purged three times and then 2-bromo-4-methyl pyridine (0.3223 g, 1.84 mmol, 98%, 1.5 eq), 1-methyl imidazole (5.9 μL, 0.073 mmol, 99%, 0.06 eq) and toluene (5 mL) were add under nitrogen protection. The reaction flask was then placed in a 130° C. oil bath. After stirring for 38 hours, the TLC monitoring reaction was completed. Cool to room temperature, concentration, and purification of the obtained crude product by flash silica gel column chromatography (eluent: petroleum ether/ethyl acetate=15/1˜10/1), get B—OMe-3, pale yellow oil 0.3881 g, 92% yield, directly to the next step.

Under nitrogen protection, to a dry one-necked flask with a magnetic rotor, B—OMe-3 (0.3780 g, 1.1 mmol, 1.0 eq), AcOH (10 mL) and HBr (5 mL, 48% aqueous solution) were added in order. The reaction flask was then placed in a 120° C. oil bath. After stirring for 13 hours, the TLC monitoring reaction was completed. Cool to room temperature, concentrate, add ethyl acetate (20 mL), then add saturated sodium bicarbonate solution until no bubbles are generated. The organic phase was separated and the aqueous phase was extracted with ethyl acetate (10 mL×2). Combine all organic phases and dry over anhydrous sodium sulfate. Filtration, concentration, and purification of the obtained crude product by flash silica gel column chromatography (eluent: petroleum ether/ethyl acetate=4/1˜2/1), get B—OH-3, gray solid 0.3592 g, 99% yield, directly to the next step.

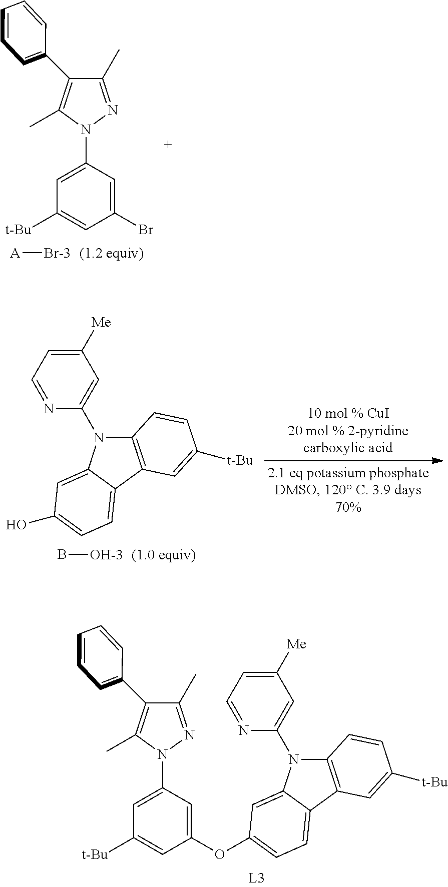

To a dry sealed tube with a magnetic rotor, A-Br-3 (0.4988 g, 1.30 mmol, 1.2 eq), B—OH-3 (0.3592 g, 1.09 mmol, 1.0 eq), Cut (0.0207 g, 0.11 mmol, 0.1 eq), 2-pyridine carboxylate (0.0270 g, 0.22 mmol, 99%, 0.2 eq) and potassium phosphate (0.4838 g, 2.28 mmol, 2.1 eq) were added in order. Nitrogen was purged three times and then dimethyl sulfoxide (7 mL) was added under nitrogen protection. The sealed tube was then placed in a 120° C. oil bath. After stirring for 3.9 days, the TLC monitoring reaction was completed. Cool to room temperature and add ethyl acetate (30 mL) and brine (20 mL×2). Combine the aqueous phases and extract with ethyl acetate (10 mL). Combine all organic phases and dry over anhydrous sodium sulfate. Filtration, concentration, and purification of the obtained crude product by flash silica gel column chromatography (eluent: petroleum ether/ethyl acetate=15/1), get L3, white solid 0.4803 g, yield 70%. ¹H NMR (400 MHz, DMSO-d₆): δ 1.32 (s, 9H), 1.42 (s, 9H), 2.17 (s, 3H), 2.22 (s, 3H), 2.43 (s, 3H), 6.89 (t, J=2.0 Hz, 1H), 7.09 (dd, J₁=8.4 Hz, J₂=2.0 Hz, 1H), 7.17 (t, J=1.8 Hz, 1H), 7.24-7.34 (m, 5H), 7.42 (t, J=7.6 Hz, 2H), 7.51 (dd, J₁=8.8 Hz, J₂=2.0 Hz, 1H), 7.56 (d, J=1.2 Hz, 1H), 7.58 (s, 1H), 7.69 (d, J=8.4 Hz, 1H), 8.23 (d, J=1.6 Hz, 1H), 8.31 (d, J=8.4 Hz, 1H), 8.49 (d, J=4.8 Hz, 1H).

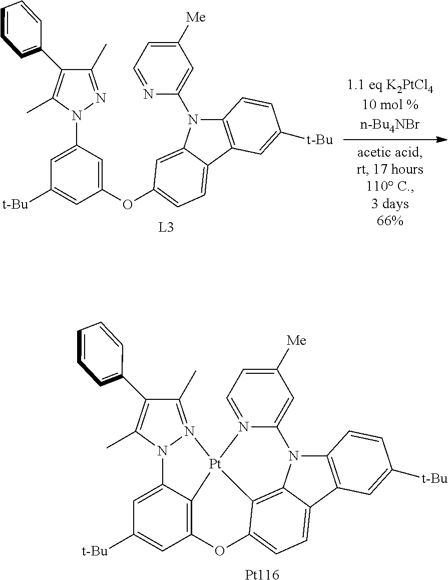

To a dry sealed tube with a magnetic rotor, L3 (0.4106 g, 0.65 mmol, 1.0 eq), K₂PtCl₄ (0.2962 g, 0.71 mmol, 1.1 eq) and n-Bu₄NBr (0.0211 g, 0.065 mmol, 0.1 eq) were added in order. Nitrogen was purged three times and then acetic acid (39 mL) was added under nitrogen protection. Nitrogen was bubbled for 30 minutes and stirred at room temperature for 17 hours, then the reaction flask was placed in a 110° C. oil bath. After stirring 3 days, cool to room temperature, concentration, and purification of the obtained crude product by flash silica gel column chromatography (eluent: petroleum ether/ethyl acetate/dichloromethane=60:2:3), get Pt116, pale yellow solid 0.3510 g, yield 66%. ¹H NMR (400 MHz, DMSO-d₆): δ 1.39 (s, 9H), 1.44 (s, 9H), 2.39 (s, 6H), 2.75 (s, 3H), 6.98 (d, J=1.2 Hz, 1H), 7.12 (d, J=6.4 Hz, 1H), 7.16 (d, J=8.4 Hz, 1H), 7.34 (d, J=1.2 Hz, 1H), 7.40-7.49 (m, 3H), 7.49-7.57 (m, 3H), 7.88 (d, J=8.4 Hz, 1H), 7.98 (s, 1H), 8.03 (d, J=8.8 Hz, 1H), 8.14 (d, J=2.0 Hz, 1H), 9.12 (d, J=6.0 Hz, 1H).

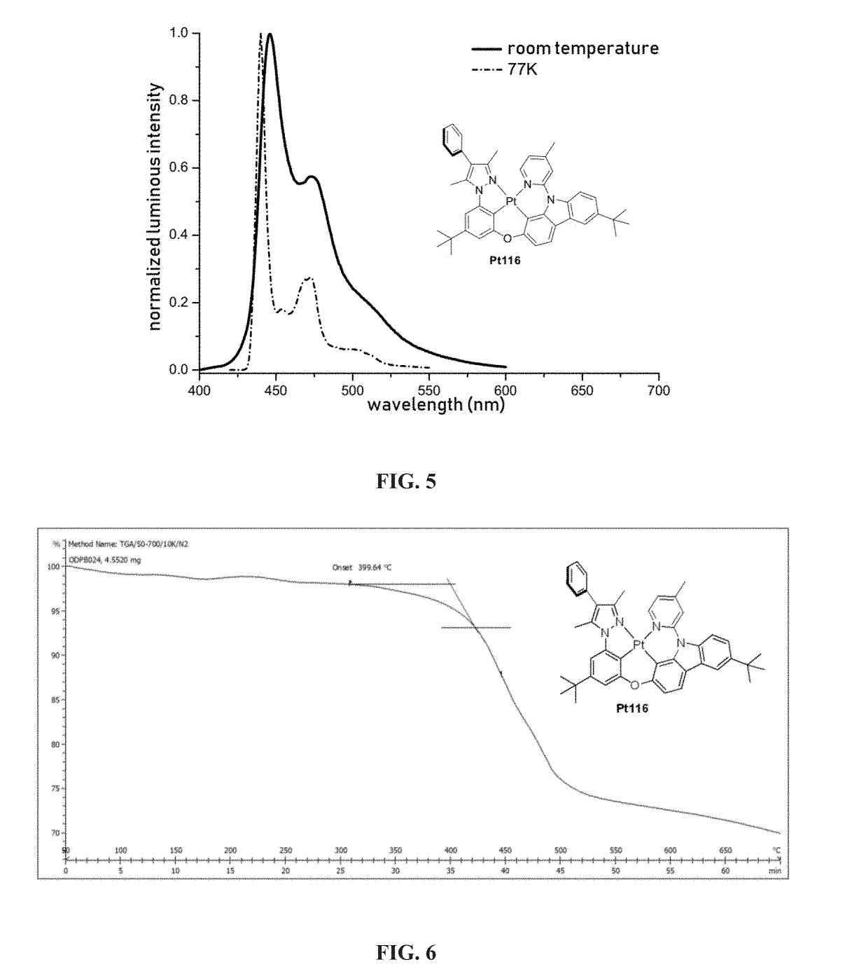

FIG. 5 shows an emission spectrum of the complex Pt116 in dichloromethane solution at room temperature; FIG. 6 shows a thermogravimetric analysis (TGA) curve of the complex Pt116.

### Example 4: Synthesis of the Complex Pt732

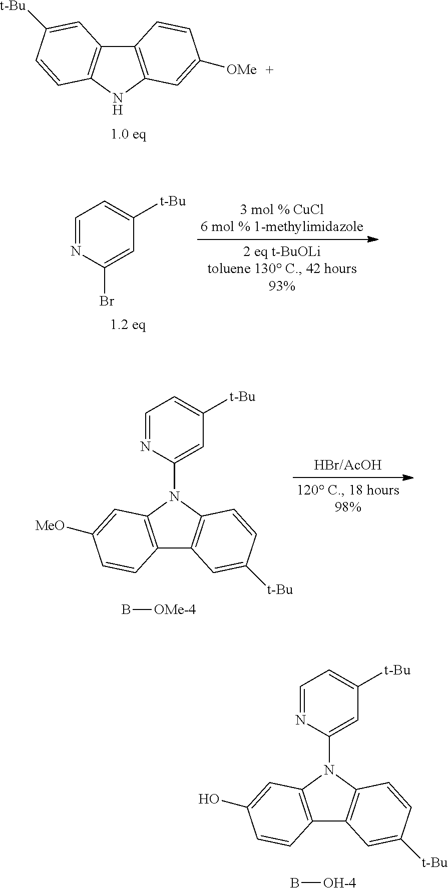

To a dry three-necked flask with a magnetic rotor, 6-tert-butyl-2-methoxy carbazole (0.3097 g, 1.22 mmol, 1.0 eq), CuCl (0.0037 g, 0.037 mmol, 99%, 0.03 eq) and t-BuOLi (0.1982 g, 2.44 mmol, 99%, 2.0 eq) were added in order. Nitrogen was purged three times and then 2-bromo-4-tert butyl pyridine (0.3131 g, 1.75 mmol, 1.2 eq), 1-methyl imidazole (5.9 μL, 0.073 mmol, 99%, 0.06 eq) and toluene (7 mL) were added under nitrogen protection. The reaction flask was then placed in a 130° C. oil bath. After stirring for 42 hours, the TLC monitoring reaction was completed. Cool to room temperature, concentration, and purification of the obtained crude product by flash silica gel column chromatography (eluent: petroleum ether/ethyl acetate=20/1˜15/1), get B—OMe-4, white oil 0.4382 g, 93% yield, directly to the next step.

Under nitrogen protection, to a dry one-neck flask with magnetic rotor add B—OMe-4 (0.4258 g, 1.1 mmol, 1.0 eq), AcOH (10 mL) and HBr (5 mL, 48% aqueous solution). The reaction flask was then placed in a 120° C. oil bath. After stirring for 18 hours, the TLC monitoring reaction was completed. Cool to room temperature, concentrate, add ethyl acetate (20 mL), then add saturated sodium bicarbonate solution until no bubbles are generated. The organic phase was separated and the aqueous phase was extracted with ethyl acetate (10 mL×2). Combine all organic phases and dry over anhydrous sodium sulfate. Filtration, concentration, and purification of the obtained crude product by flash silica gel column chromatography (eluent: petroleum ether/ethyl acetate=5/1˜3/1), get B—OH-4, white solid 0.4024 g, 98% yield, directly to the next step.

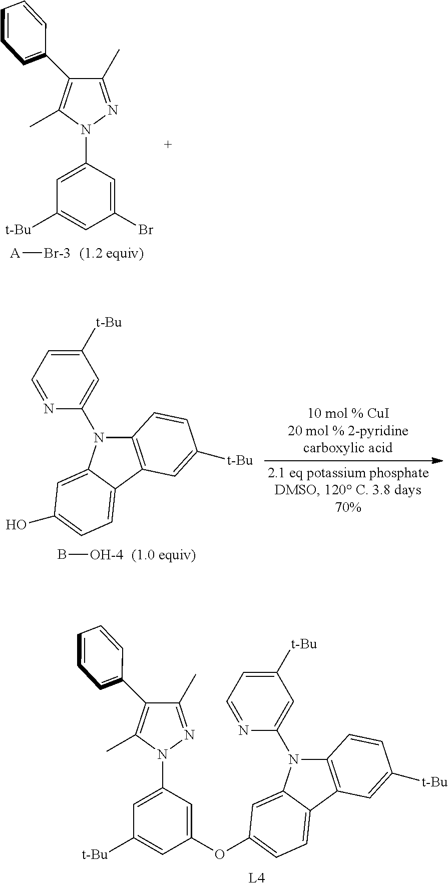

To a dry sealed tube with a magnetic rotor, A-Br-3 (0.4958 g, 1.29 mmol, 1.2 eq), B—OH-4 (0.4024 g, 1.08 mmol, 1.0 eq), Cut (0.0205 g, 0.11 mmol, 0.1 eq), 2-pyridine carboxylate (0.0268 g, 0.22 mmol, 99%, 0.2 eq) and potassium phosphate (0.4810 g, 2.27 mmol, 2.1 eq) were added in order. Nitrogen was purged three times and then dimethyl sulfoxide (7 mL) was added under nitrogen protection. The sealed tube was then placed in a 120° C. oil bath. After stirring for 3 days, the thin layer chromatography (TLC) monitoring reaction was completed. Cool to room temperature and add ethyl acetate (30 mL) and brine (10 mL×2). Combine the aqueous phases and extract with ethyl acetate (10 mL). Combine all organic phases and dry over anhydrous sodium sulfate. Filtration, concentration, and purification of the obtained crude product by flash silica gel column chromatography (eluent: petroleum ether/ethyl acetate=20/1), get L4, white solid 0.5096 g, yield 70%. ¹H NMR (400 MHz, DMSO-d₆): δ 1.28 (s, 9H), 1.31 (s, 9H), 1.42 (s, 9H), 2.166 (s, 3H), 2.172 (s, 3H), 6.92 (t, J=2.0 Hz, 1H), 7.11 (dd, J₁=8.4 Hz, J₂=2.0 Hz, 1H), 7.19 (t, J=1.8 Hz, 1H), 7.26-7.33 (m, 4H), 7.39-7.45 (m, 3H), 7.48 (d, J=2.0 Hz, 1H), 7.52 (dd, J₁=8.8 Hz, J₂=2.0 Hz, 1H), 7.63 (d, J=0.8 Hz, 1H), 7.66 (d, J=8.8 Hz, 1H), 8.24 (d, J=1.6 Hz, 1H), 8.32 (d, J=8.8 Hz, 1H), 8.54 (d, J=5.2 Hz, 1H).

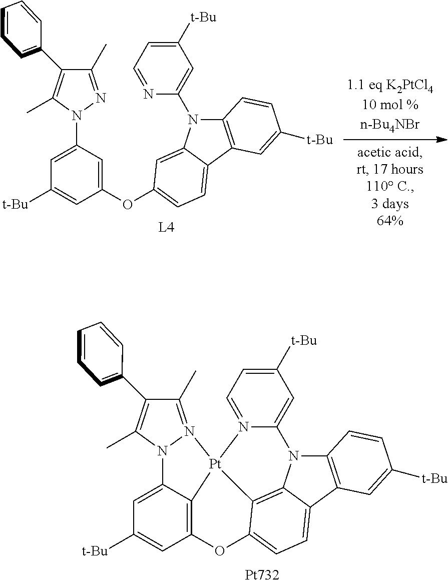

To a dry sealed tube with a magnetic rotor, L4 (0.3638 g, 0.54 mmol, 1.0 eq), K₂PtCl₄ (0.2461 g, 0.59 mmol, 1.1 eq) and n-Bu₄NBr (0.0176 g, 0.054 mmol, 0.1 eq) were added in order. Nitrogen was purged three times and then acetic acid (32 mL) was added under nitrogen protection. Nitrogen was bubbled for 30 minutes and stirred at room temperature for 17 hours, then the reaction flask was placed in a 110° C. oil bath. After stirring 3 days, cool to room temperature, concentration, and purification of the obtained crude product by flash silica gel column chromatography (eluent: petroleum ether/ethyl acetate/dichloromethane=75:2:3), get Pt732, pale yellow solid 0.2827 g, yield 64%. ¹H NMR (400 MHz, DMSO-d₆): δ 1.33 (s, 9H), 1.39 (s, 9H), 1.45 (s, 9H), 2.41 (s, 3H), 2.76 (s, 3H), 6.99 (d, J=1.6 Hz, 1H), 7.17 (d, J=8.0 Hz, 1H), 7.31-7.37 (m, 2H), 7.40-7.50 (m, 3H), 7.50-7.58 (m, 3H), 7.90 (d, J=8.0 Hz, 1H), 8.03 (d, J=8.4 Hz, 1H), 8.06 (d, J=1.6 Hz, 1H), 8.17 (d, J=1.6 Hz, 1H), 9.16 (d, J=6.4 Hz, 1H).

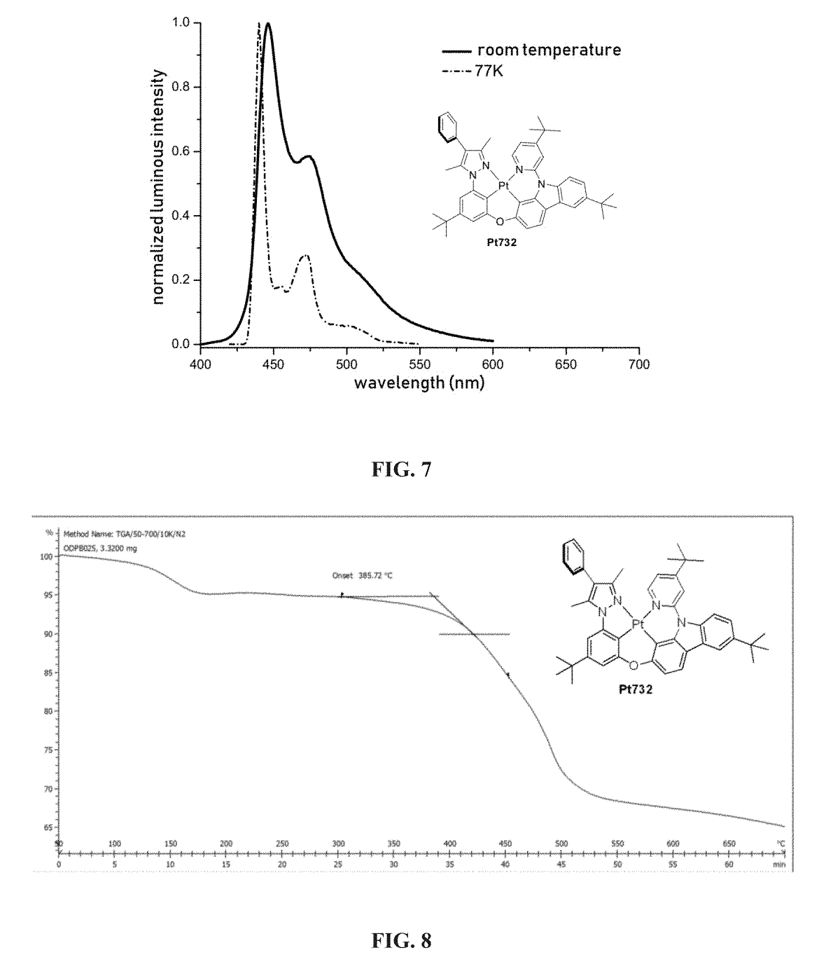

FIG. 7 shows an emission spectrum of the complex Pt732 in dichloromethane solution at room temperature; FIG. 8 shows a thermogravimetric analysis (TGA) curve of the complex Pt732.

### Performance Evaluation Examples

Photophysical, electrochemical and thermogravimetric analysis of the complexes prepared in the above examples of the present disclosure are described below:

Photophysical analysis: phosphorescence emission spectra and triplet lifetimes were all tested on a HORIBA FL3-11 spectrometer. Test conditions: at room temperature emission spectra, all of samples were dilute solutions of dichloromethane (chromatographic grade) (10⁻⁵-10⁻⁶ M), and the samples were all prepared in glove box, and were purged with nitrogen for 5 minutes; In the low temperature (77K) emission spectrum, all of samples were preliminarily prepared as 2-methyl tetrahydrofuran (chromatographic grade) dilute solution (10⁻⁵-10⁻⁶ M), and then placed in liquid nitrogen until the sample was completely cured and measured; The triplet lifetime detection is measured at the strongest peak of the sample emission spectrum.

Electrochemical analysis: cyclic voltammetry was used to test on CH670E electrochemical workstation. 0.1 M solution of tetra-n-butyl ammonium hexafluorophosphate (ⁿBu₄NPF₆) in N,N-dimethyl acetamide (DMF) serves as the electrolyte solution; The metal platinum electrode is a positive electrode; graphite is a negative electrode; Metal silver serves as a reference electrode; ferrocene is a reference internal standard and its redox potential is set to zero.

Thermogravimetric analysis: the thermogravimetric analysis curves were all performed on a TGA2(SF) thermogravimetric analysis. The TGA test conditions: the test temperature is 50-700° C.; the heating rate is 20 K/min; the tantalum material is aluminum trioxide; and the testing is completed under the nitrogen atmosphere; the sample quality is generally 2-5 mg.

TABLE 1
Photophysical, electrochemical and thermogravimetric analysis of the
metal complexes luminescent materials

| Platinum | Room temperature | | | 77 K | | |
|---|---|---|---|---|---|---|
| complex | peak/nm | τ/μs | PLQE | peak/nm | τ/μs | T_{d}/° C. |
| Pt29 | 446 | 7.8 | 94% | 440 | 10.5 | 375 |
| Pt393 | 446 | 7.9 | 91% | 440 | 10.8 | 406 |
| Pt116 | 446 | 6.1 | 95% | 440 | 10.2 | 400 |
| Pt732 | 446 | 6.6 | 91% | 440 | 9.4 | 386 |

As can be seen from the data in table 1, the platinum metal complexes provided by the examples of the present disclosure are all deep blue phosphorescent luminescent material, its maximum emission peak is 446 nm; the triplet lifetime of the solution is in microseconds (10's) grade; phosphorescence quantum efficiency is above 90%, all have strong phosphorescence emission; more important is the thermal decomposition temperature is above 370° C., much higher than the materials thermal evaporation when producing device (usually not higher than 300° C.). Therefore, such phosphorescent materials have great application prospects in the fields of blue light, especially deep blue phosphorescent materials, and are of great significant for the development and application of deep blue phosphorescent materials.

The ordinary skilled in the art can understand that the above examples are specific embodiments for implementing the present disclosure, and in practical applications, various changes in form and detail can be made without departing from the spirit and the scope of the present disclosure.

What is claimed is:

1. A tetradentate cyclic-metal platinum complex comprising 6-substituted carbazole, wherein a structure of the complex is shown in formula (I): 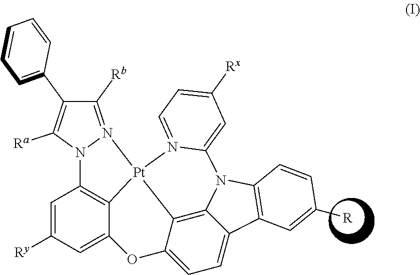
wherein
R is alkyl, alkoxy, cycloalkyl, ether, heterocyclyl, aryl, heteroaryl, aryloxy, mono- or di-alkylamino, mono- or di-arylamino;
R^{a}, R^{b} each are alkyl, alkoxy, cycloalkyl, ether, heterocyclyl, hydroxy, aryl, heteroaryl, aryloxy, mono- or di-alkylamino, mono- or di-arylamino, halogen, sulfydryl, cyano, independently, or combination thereof;
R^{x} is alkyl, alkoxy, cycloalkyl, heterocyclyl, ether, mono- or di-alkylamino, mono- or di-arylamino, halogen, or combination thereof,
R^{y} is H, deuterium, alkyl, alkoxy, cycloalkyl, heterocyclyl, ether, mono- or di-alkylamino, mono- or di-arylamino, halogen, or combination thereof.

2. The complex according to claim 1, wherein the 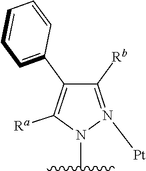
has a structure selected from one of the following structures:

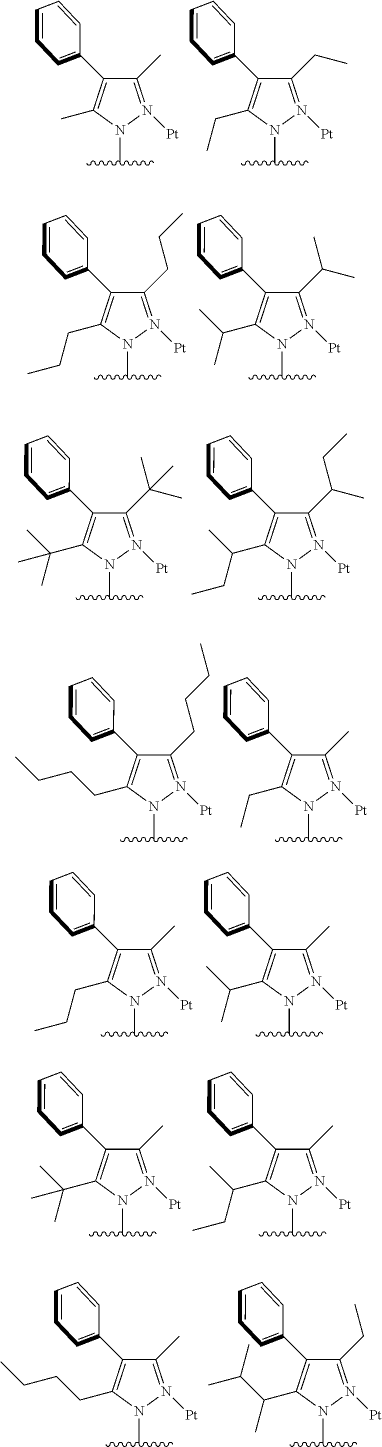

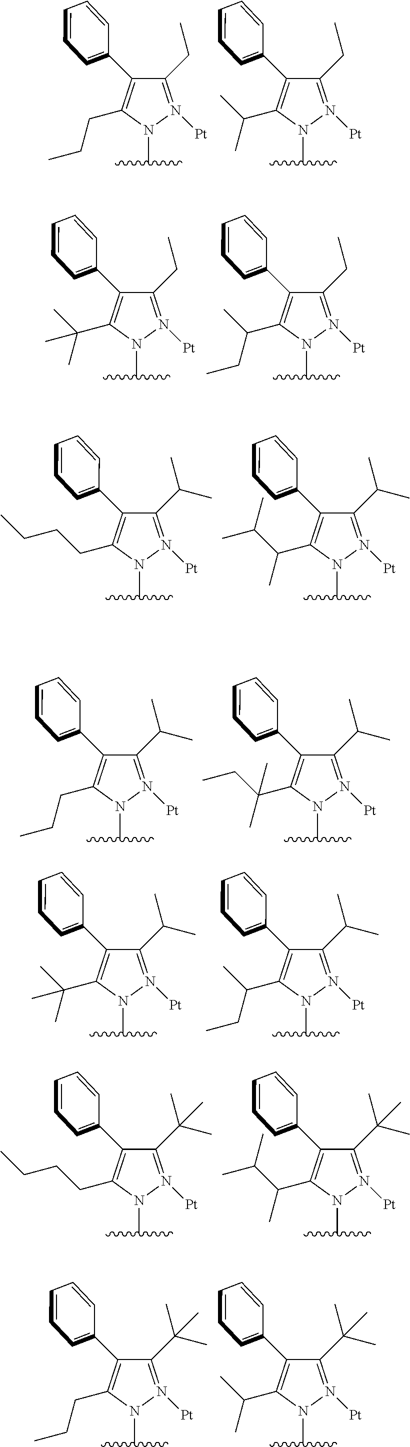

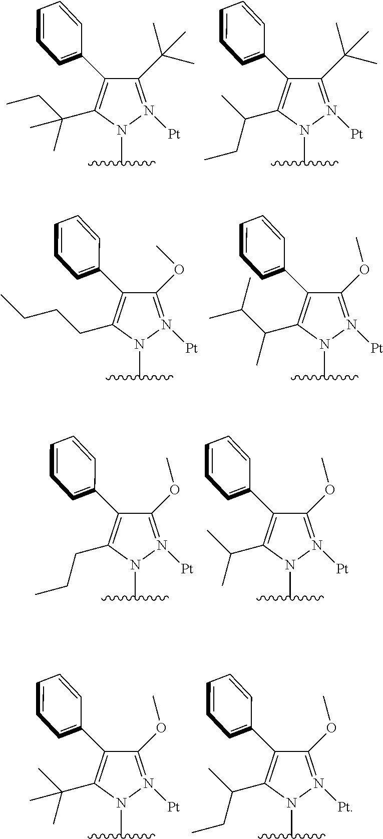

3. The complex according to claim 1, wherein the complex has a structure selected from one of the following structures:

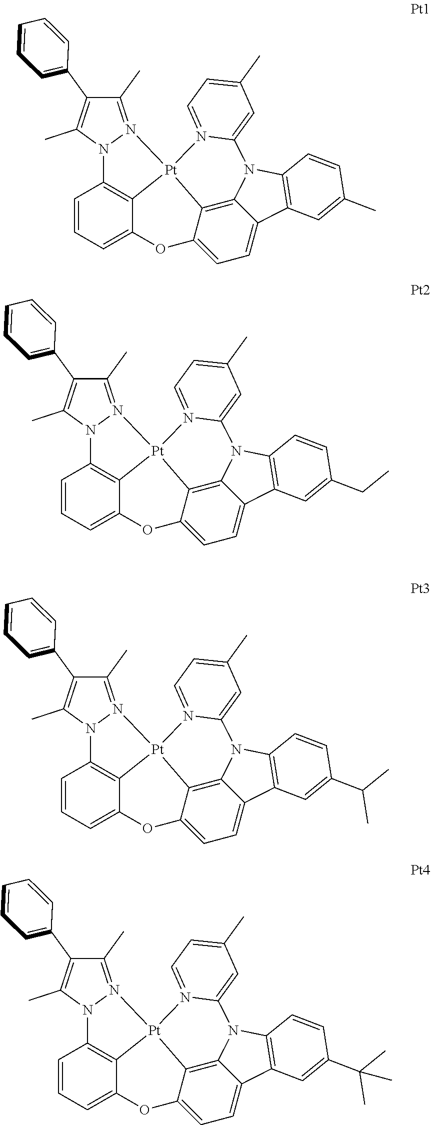

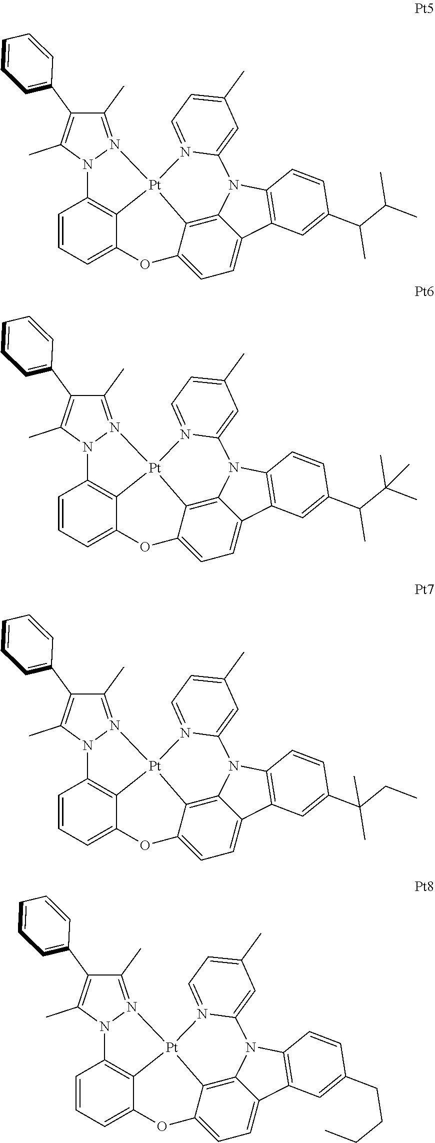

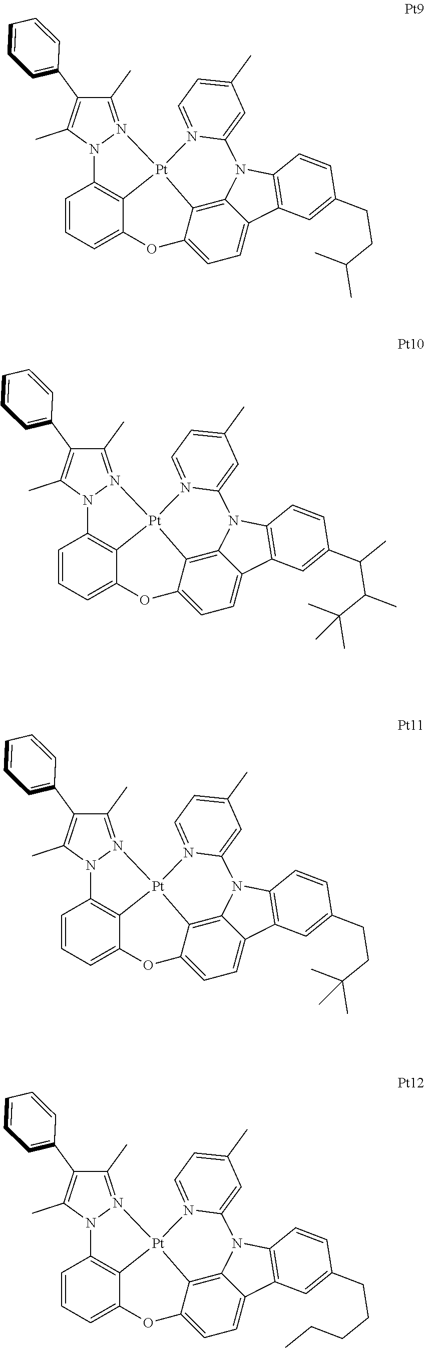

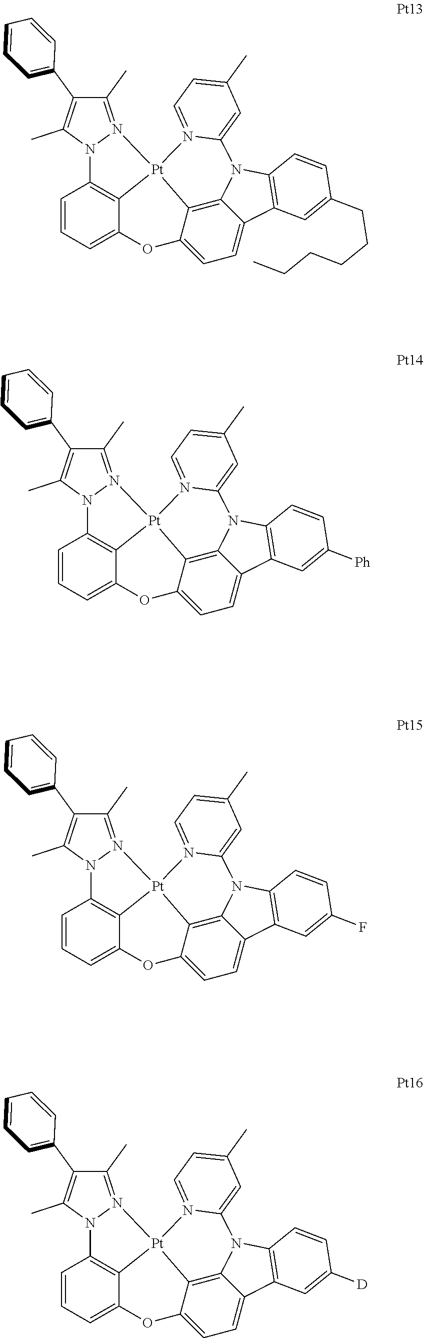

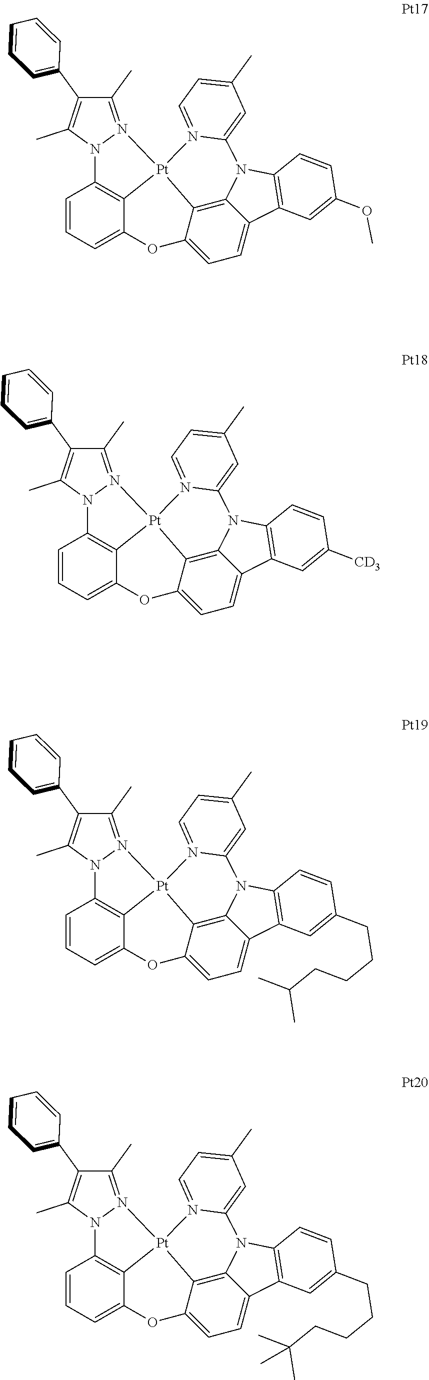

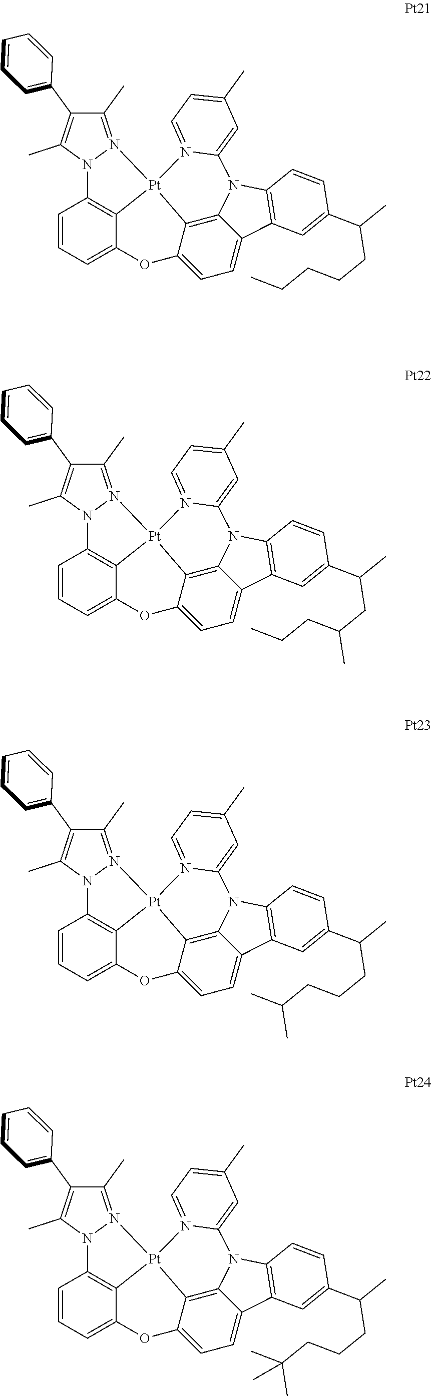

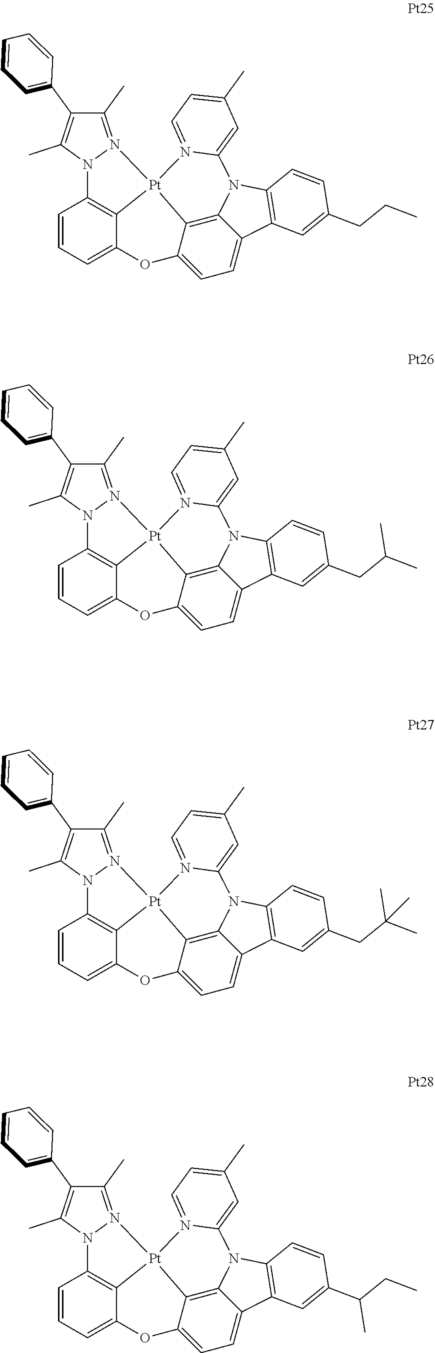

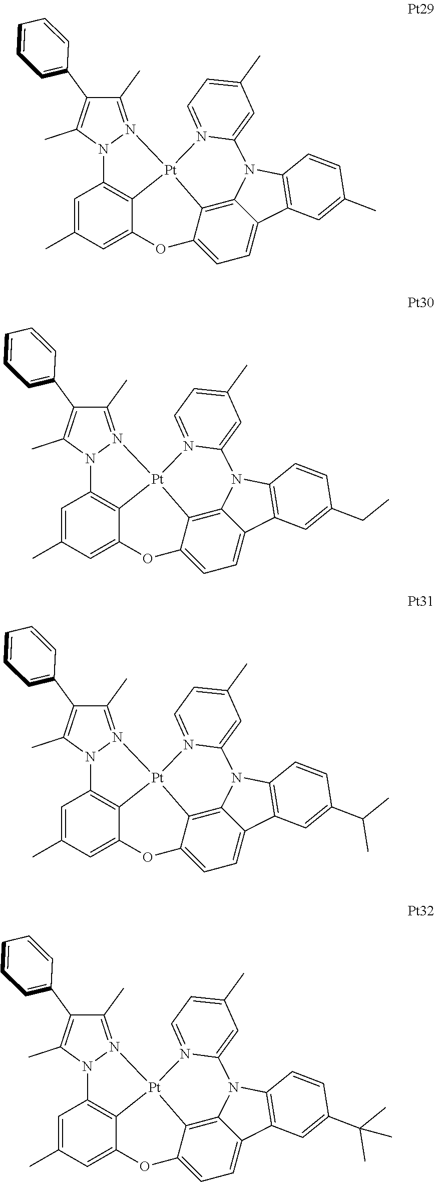

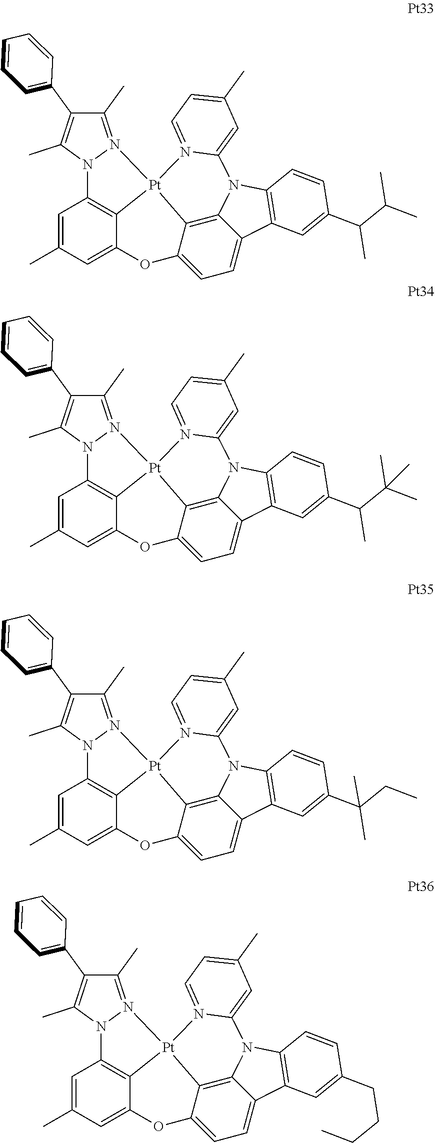

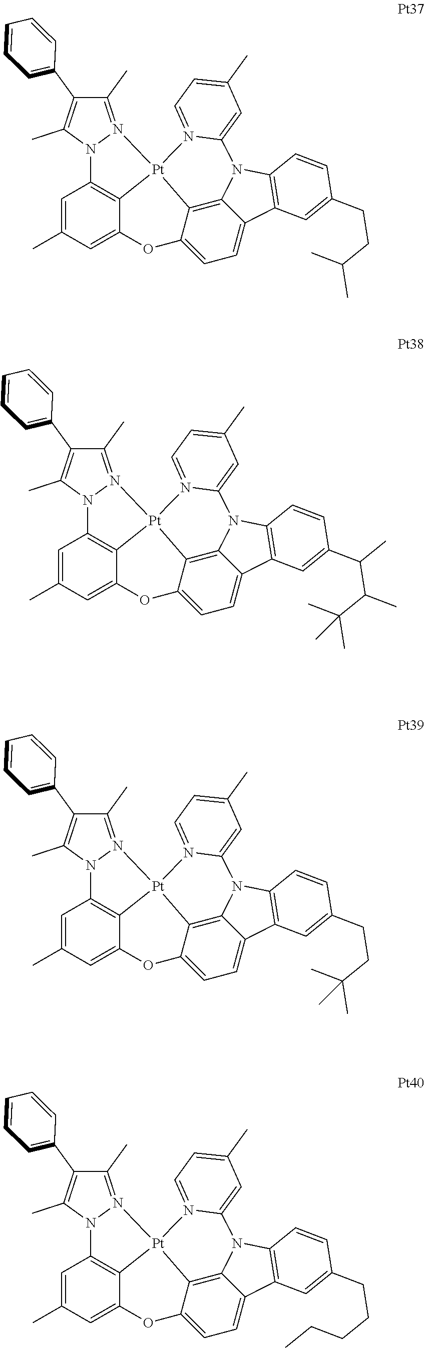

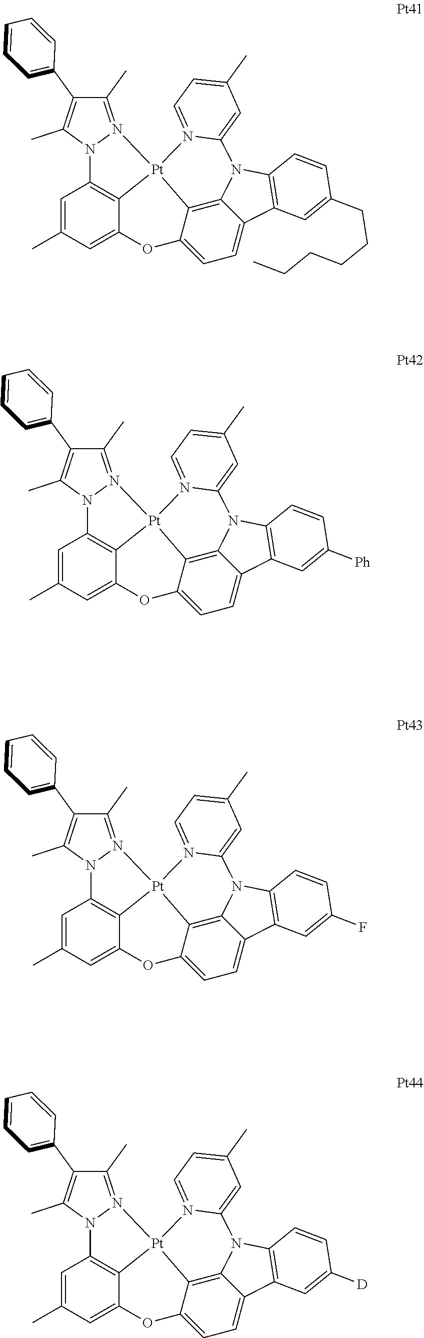

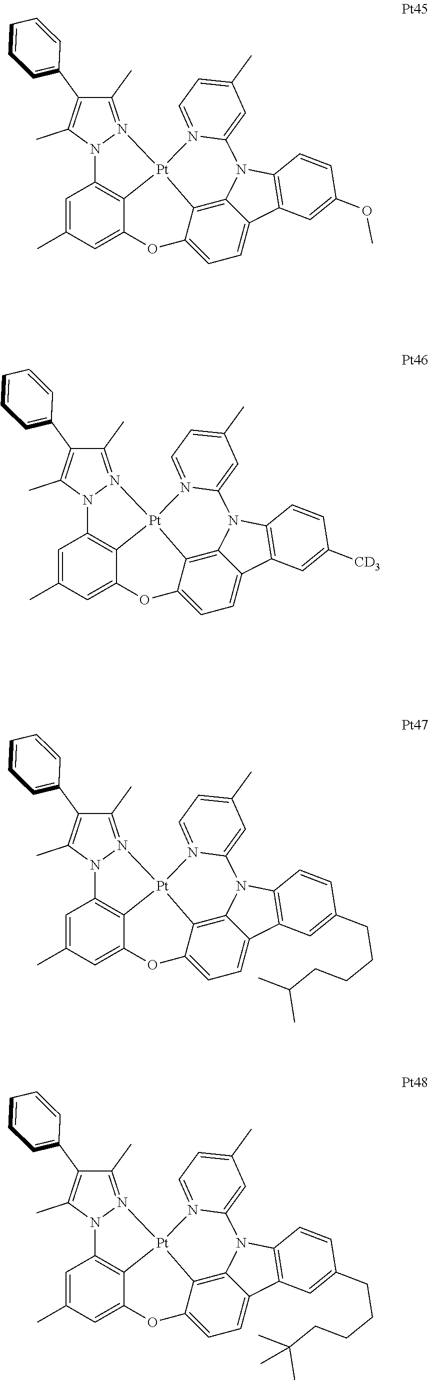

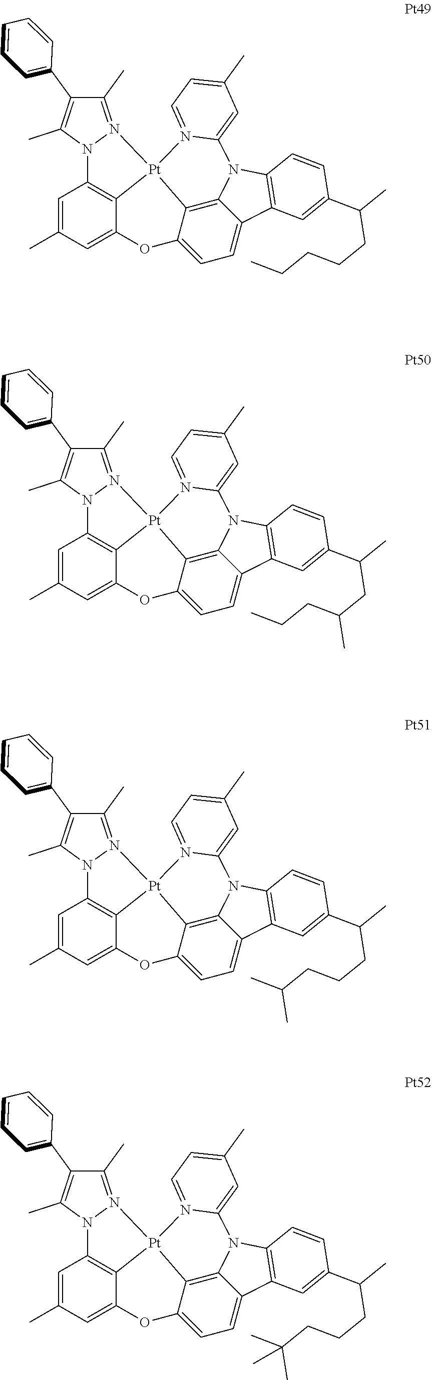

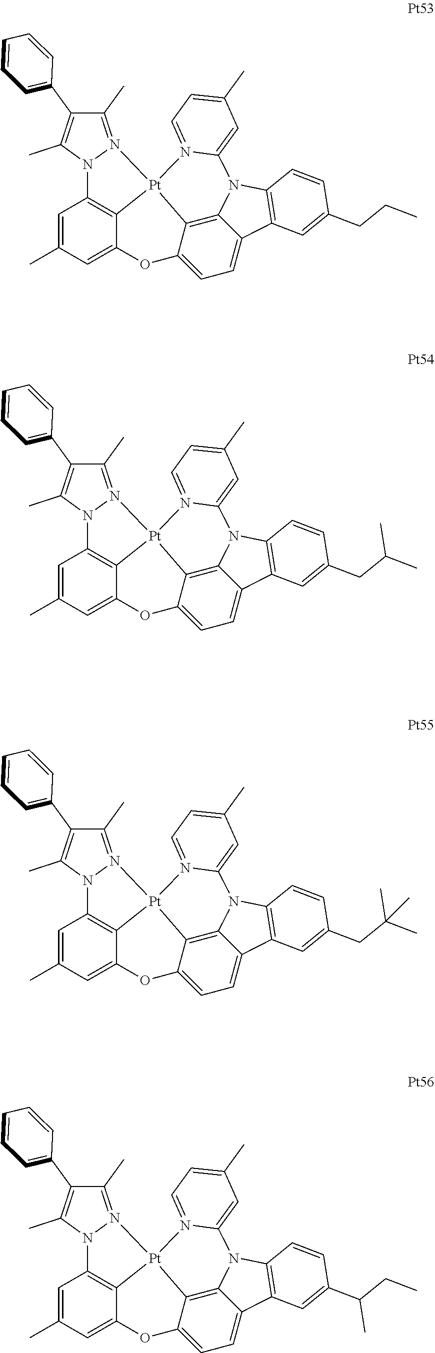

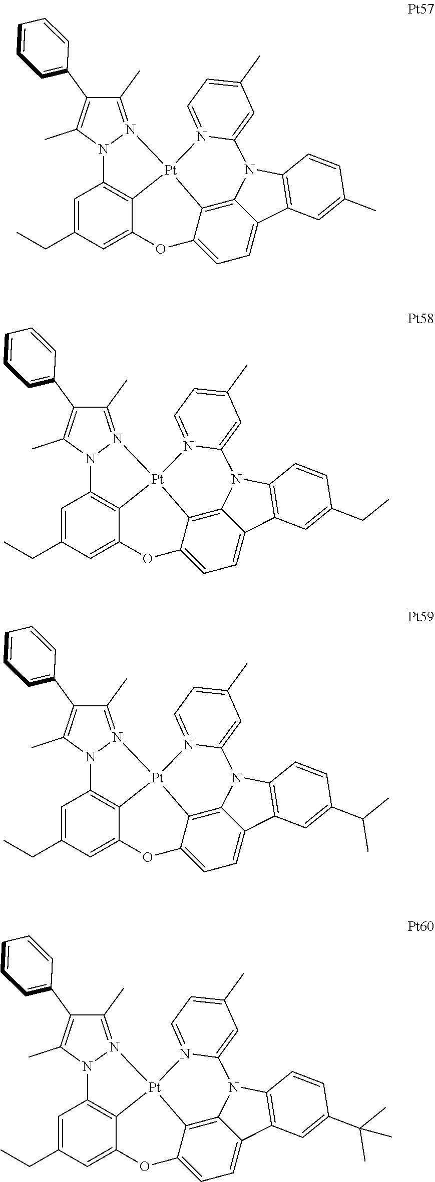

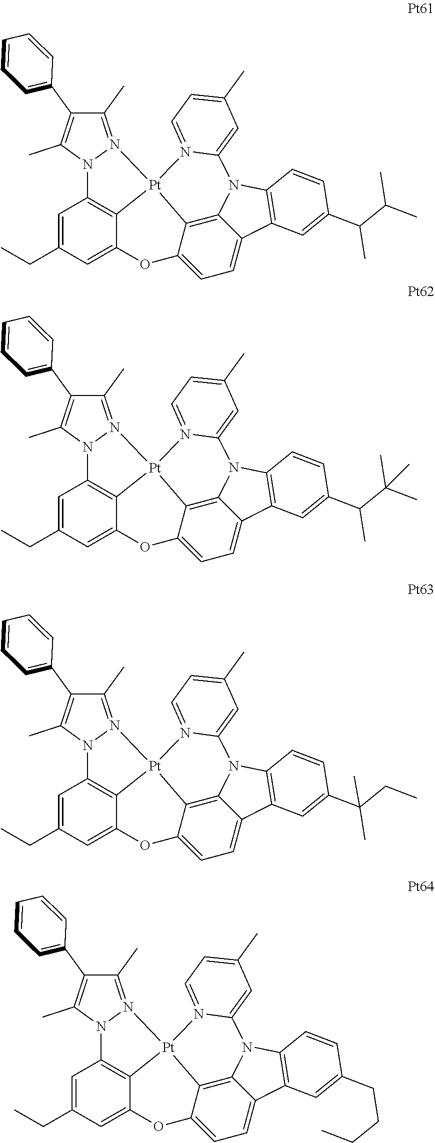

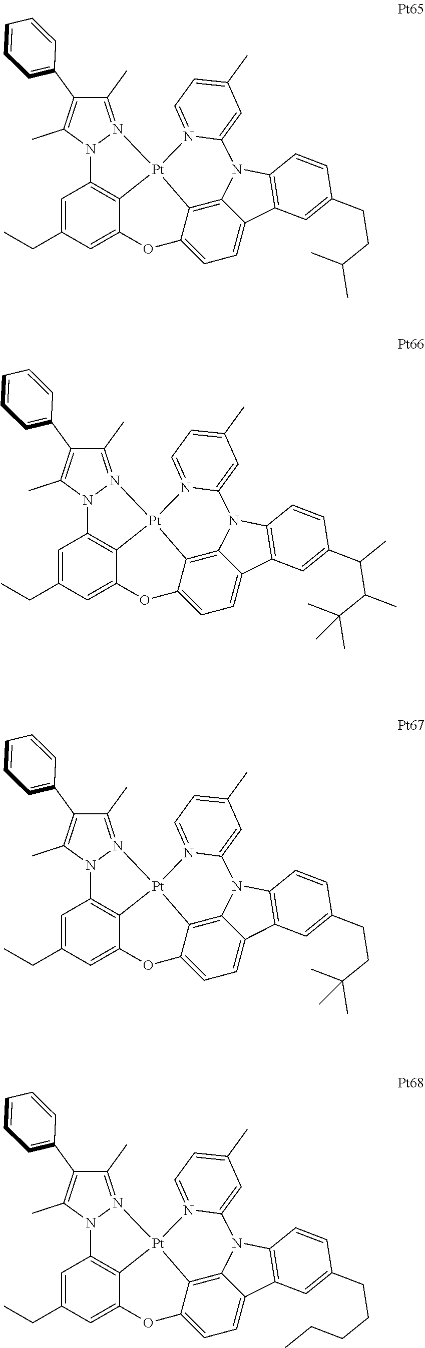

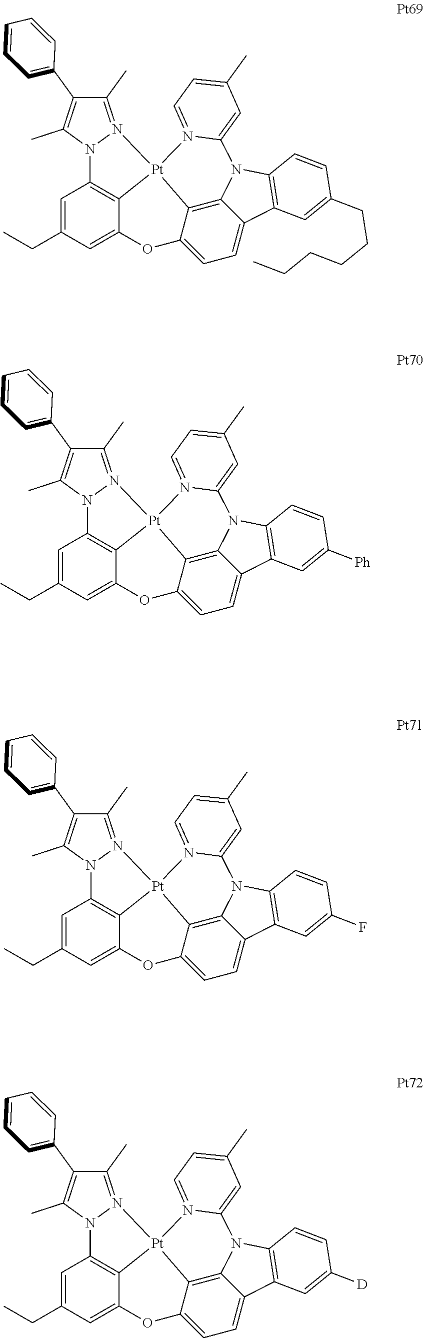

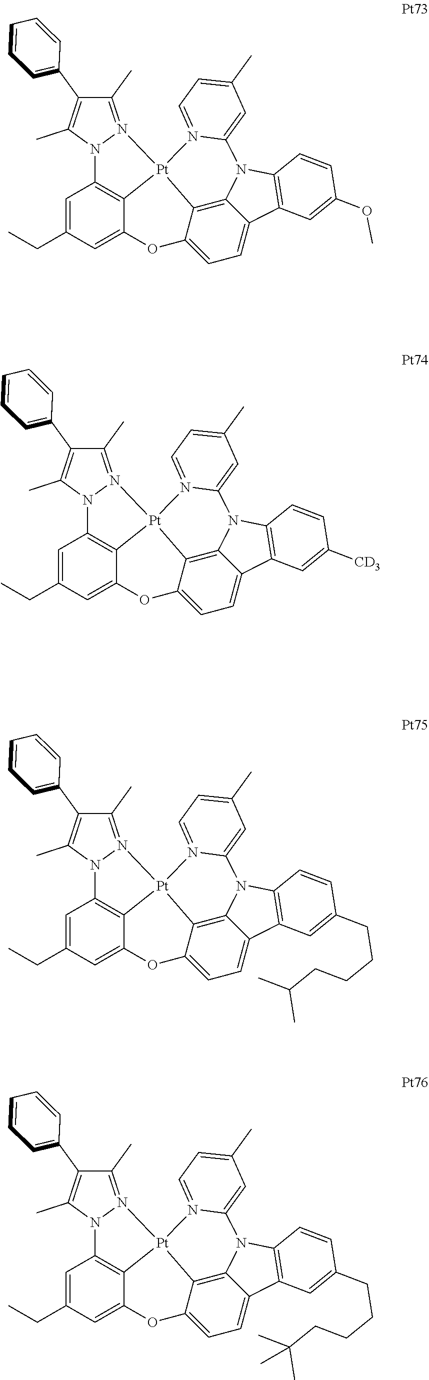

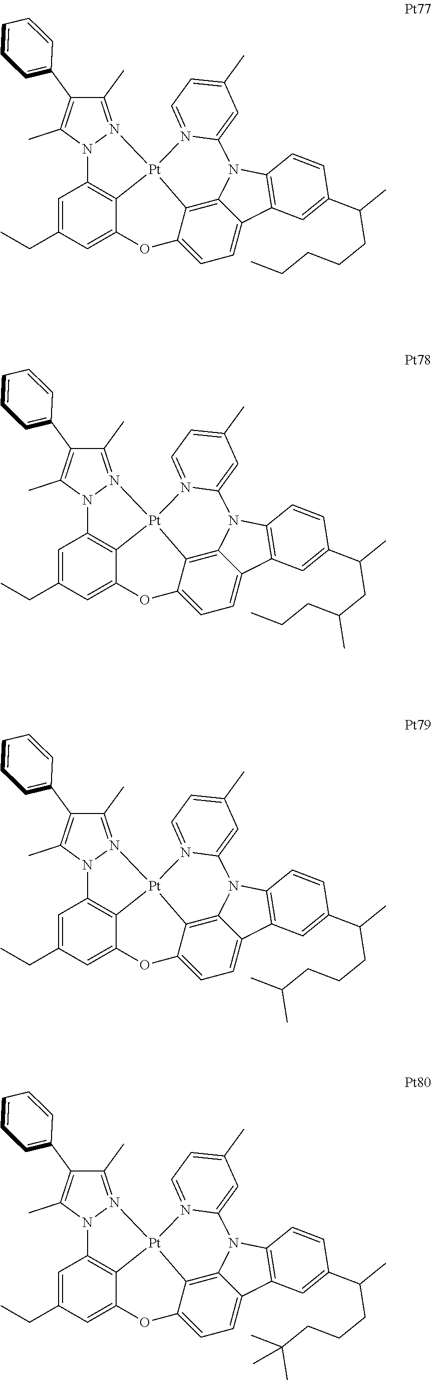

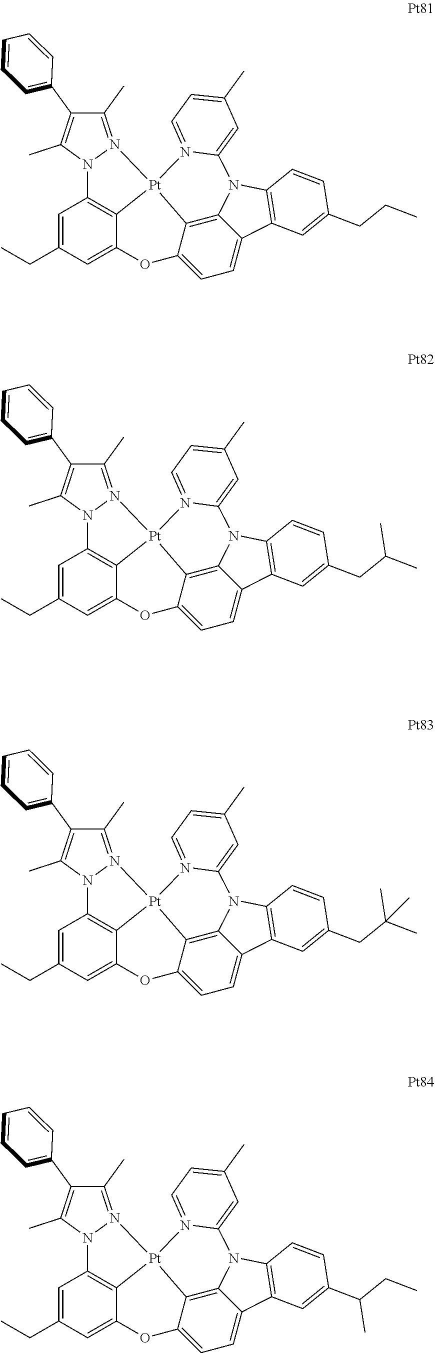

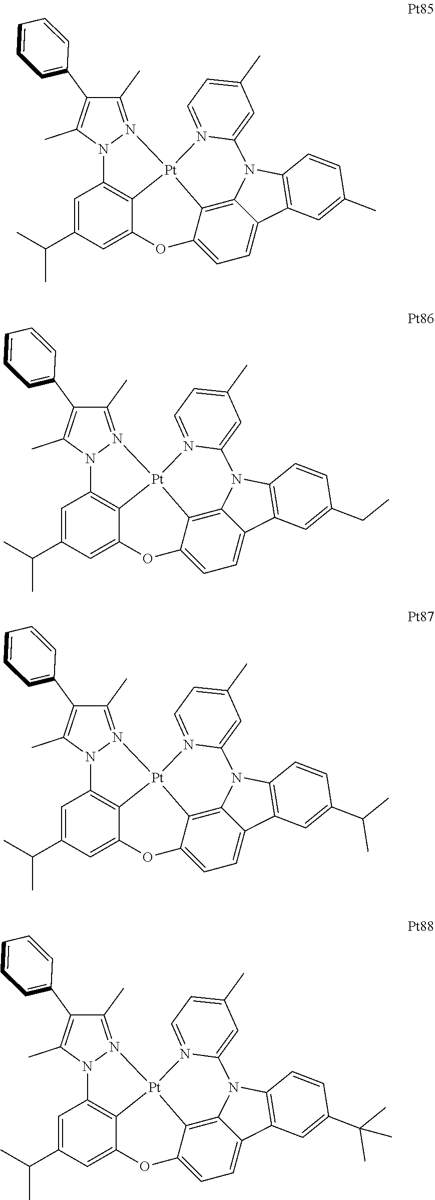

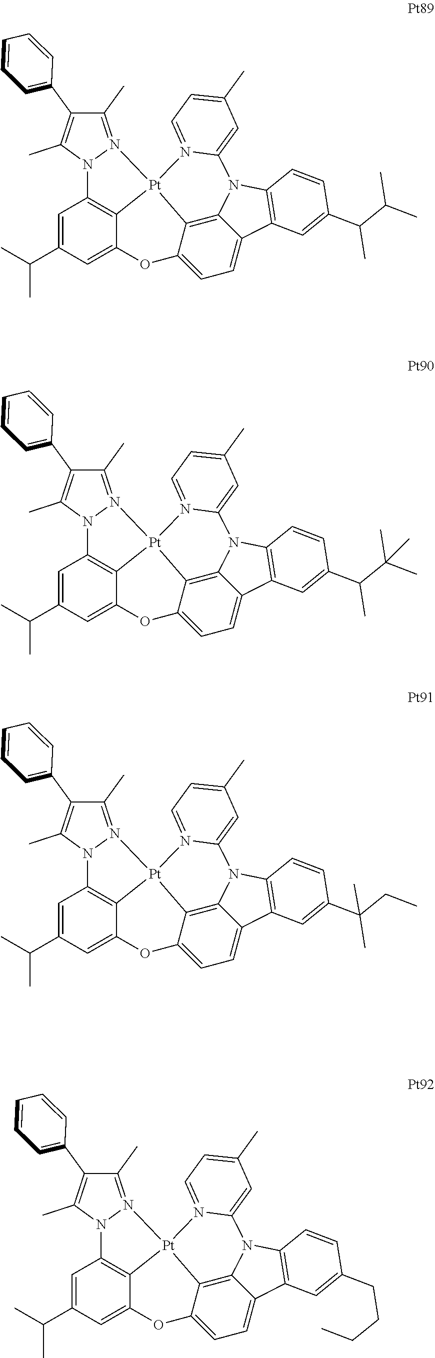

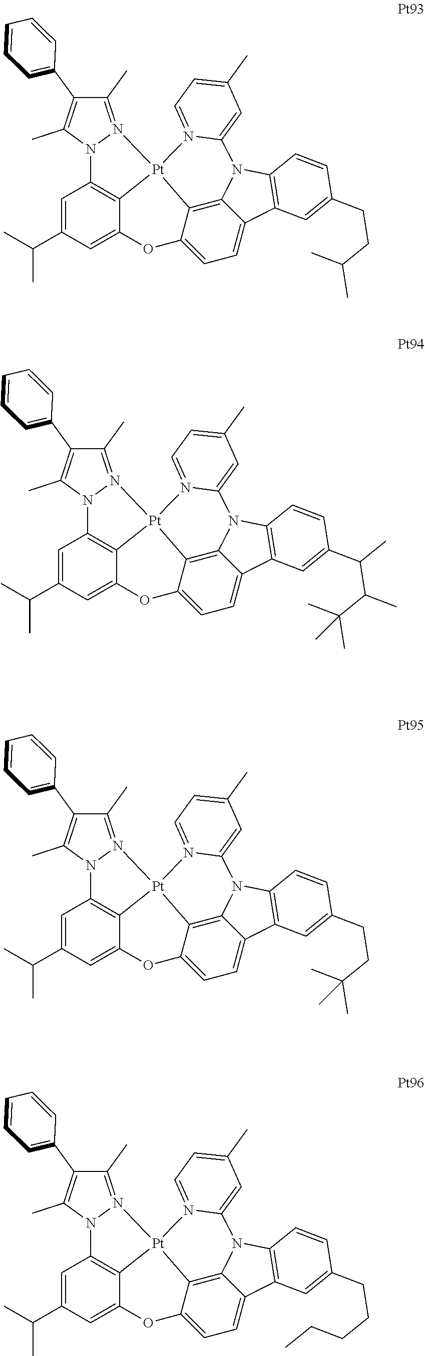

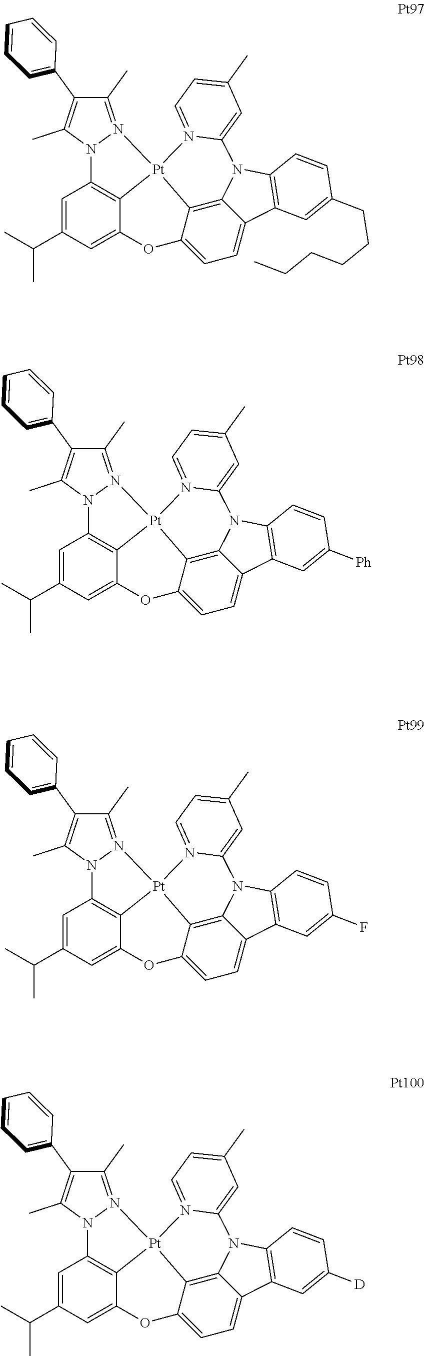

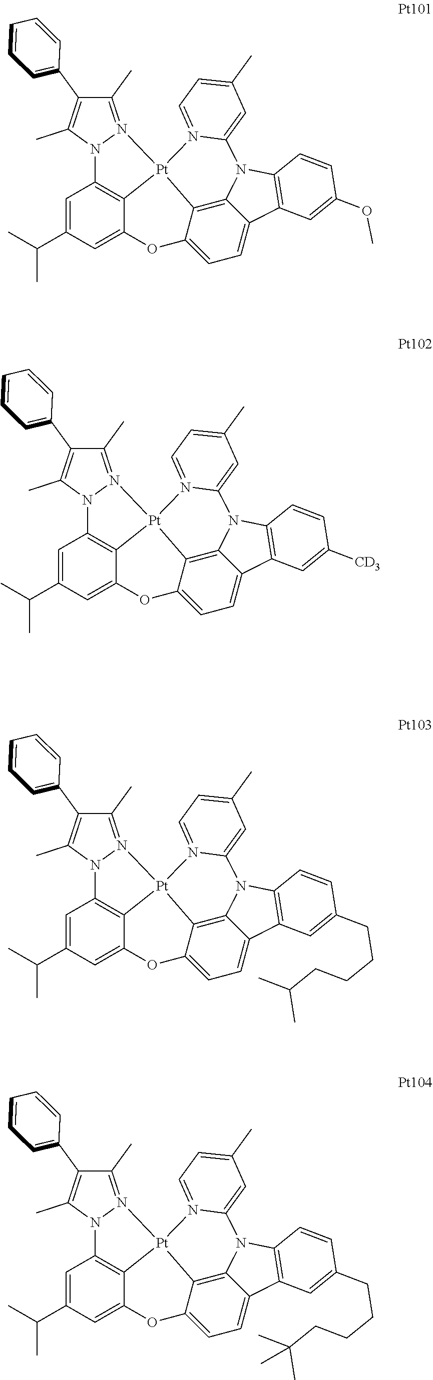

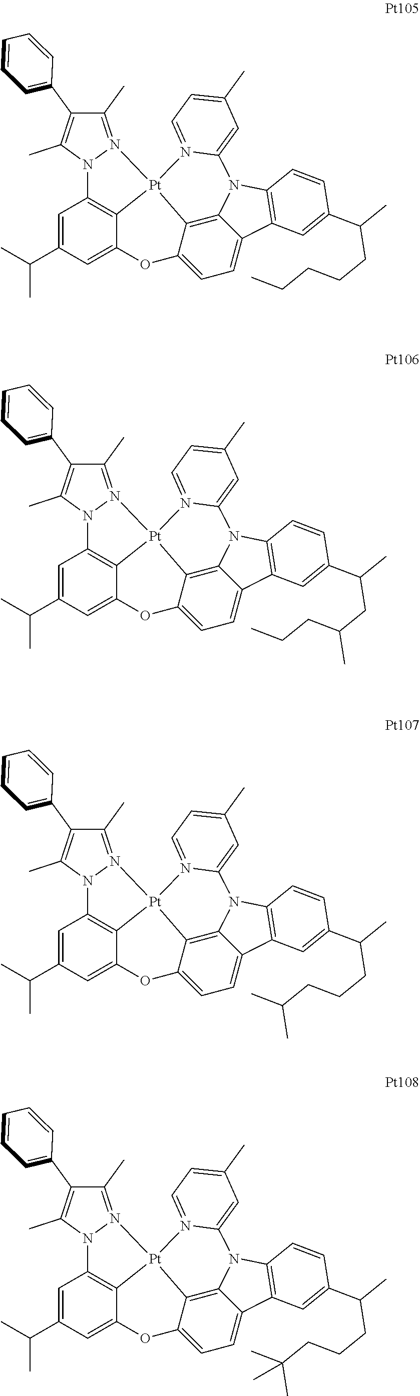

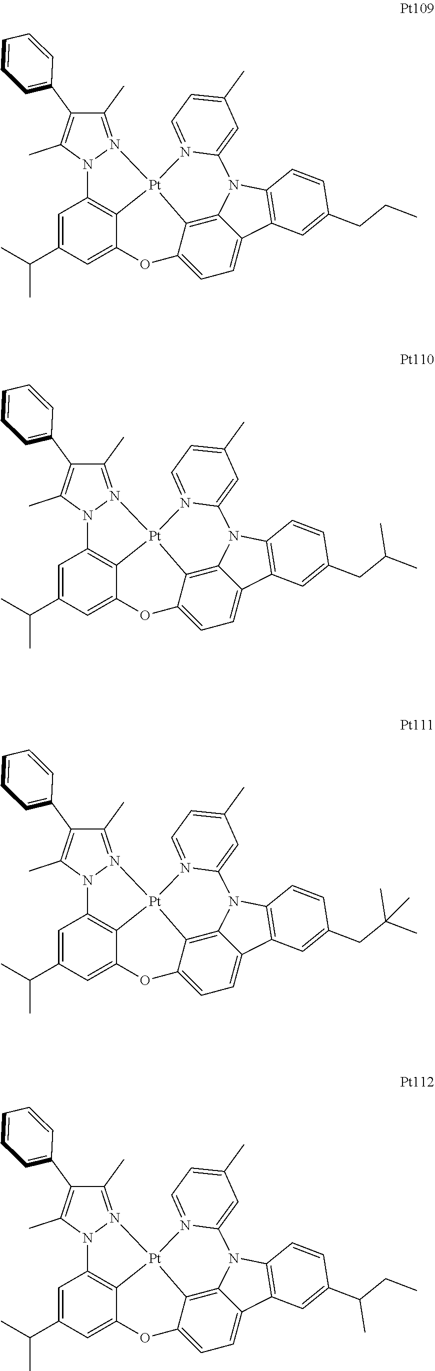

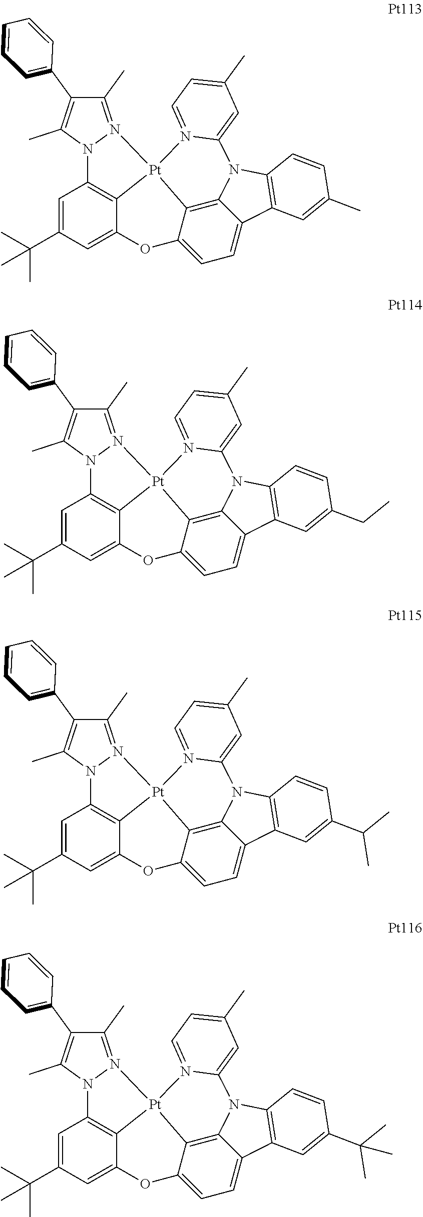

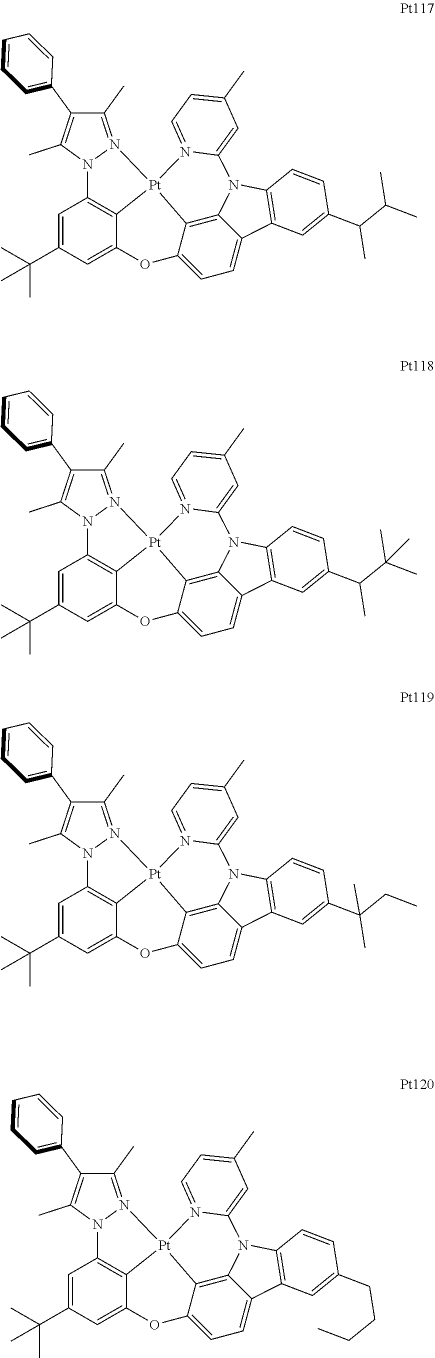

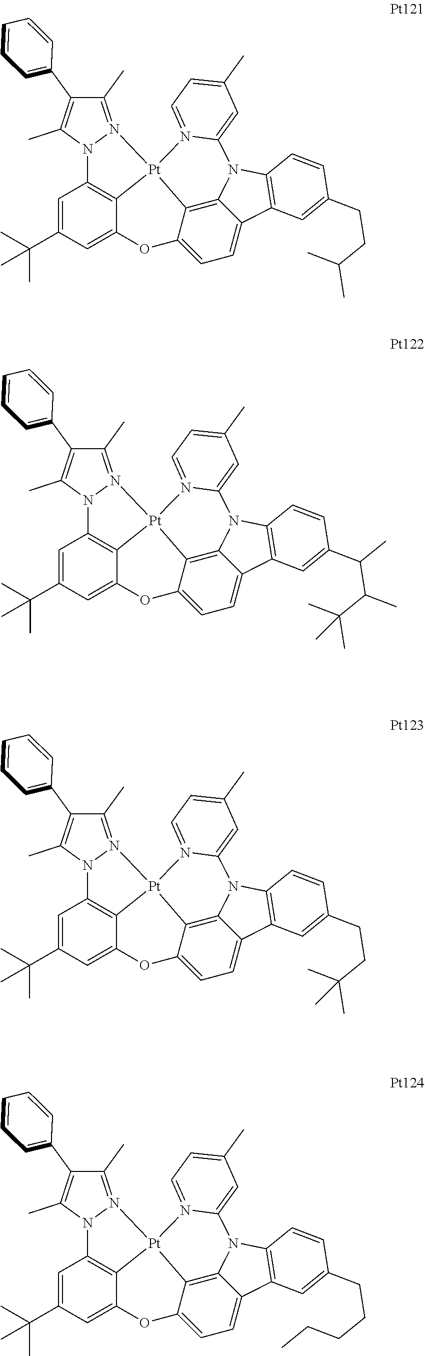

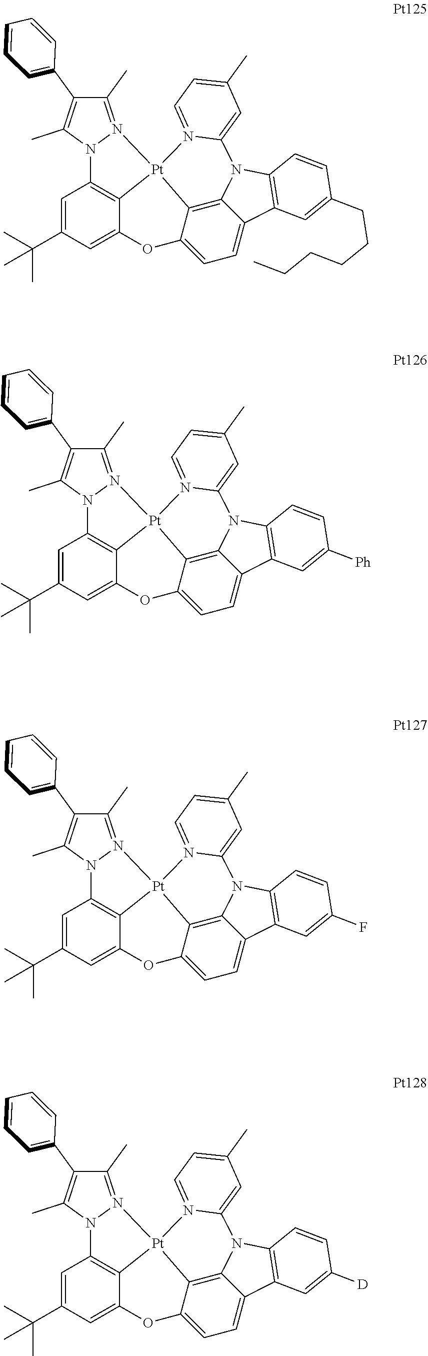

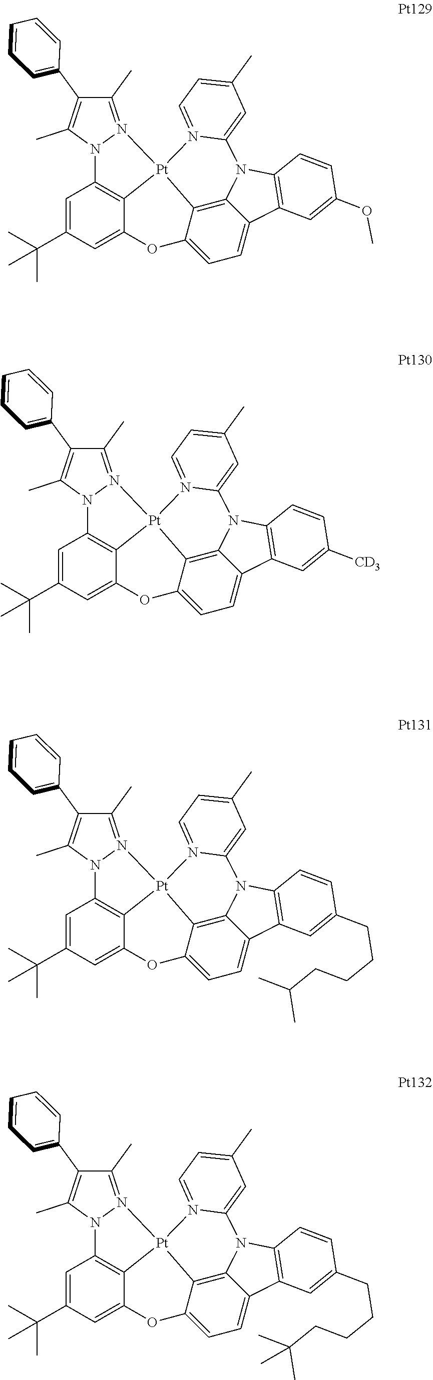

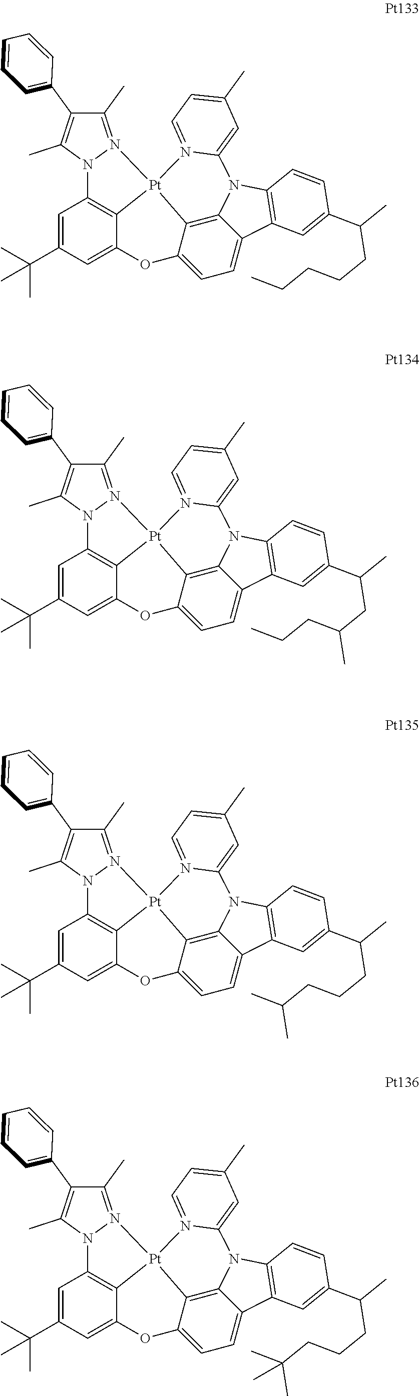

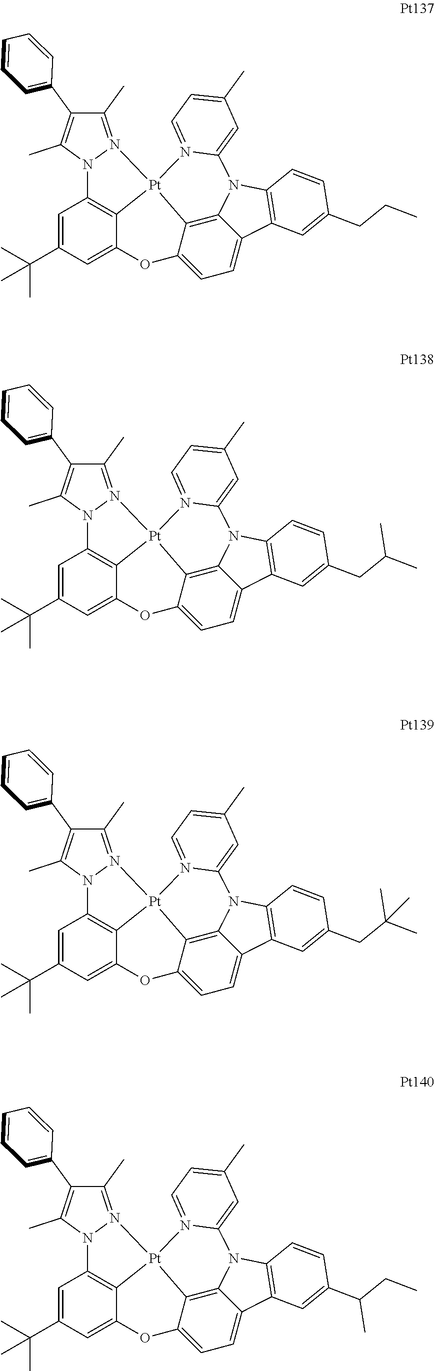

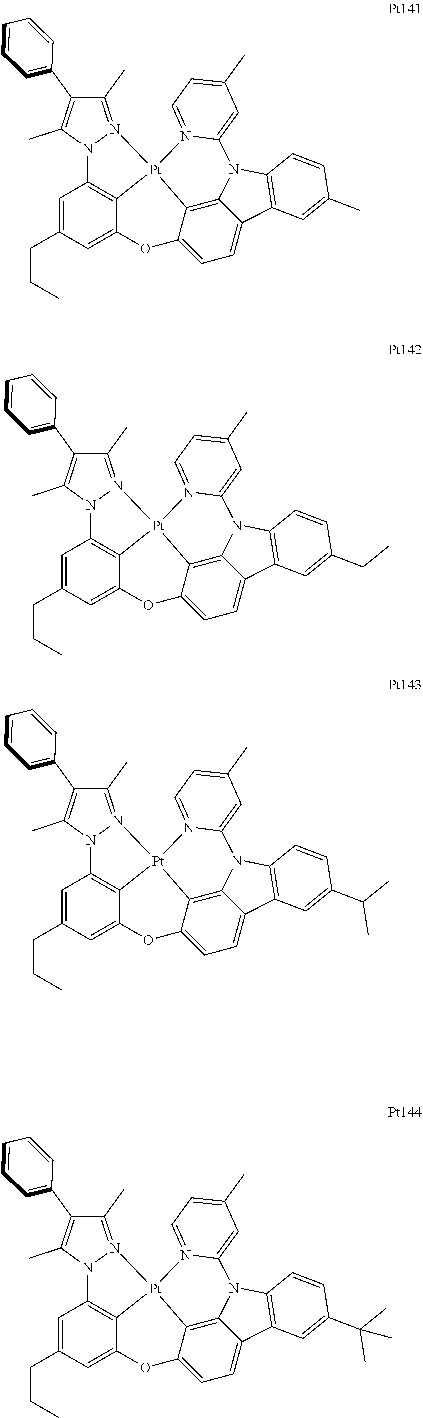

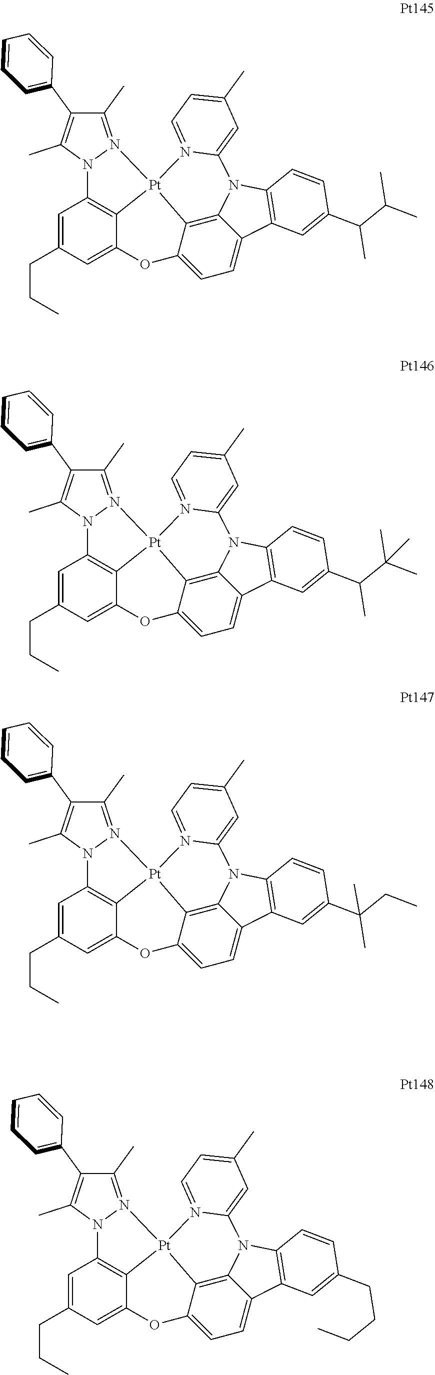

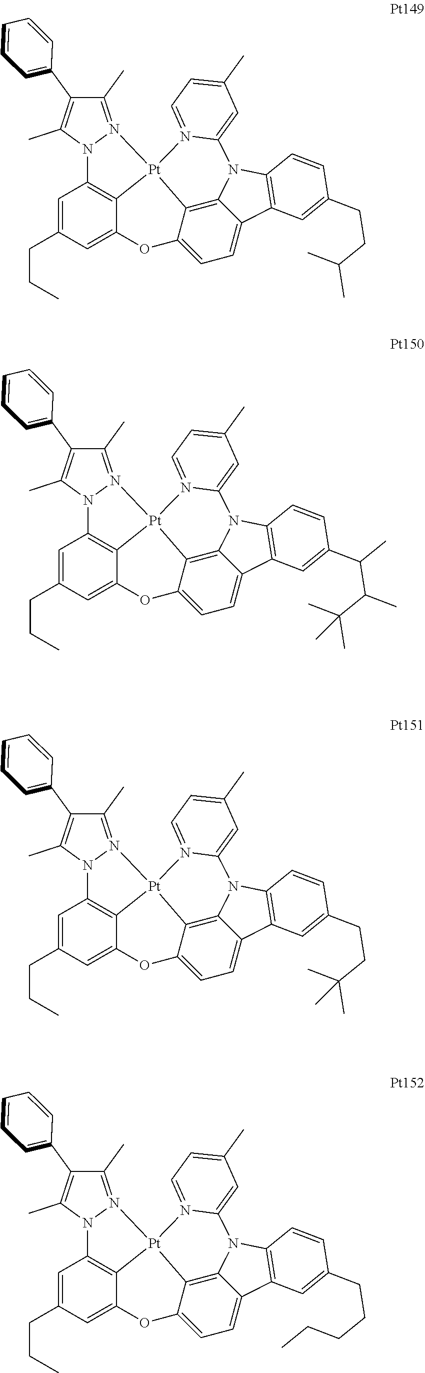

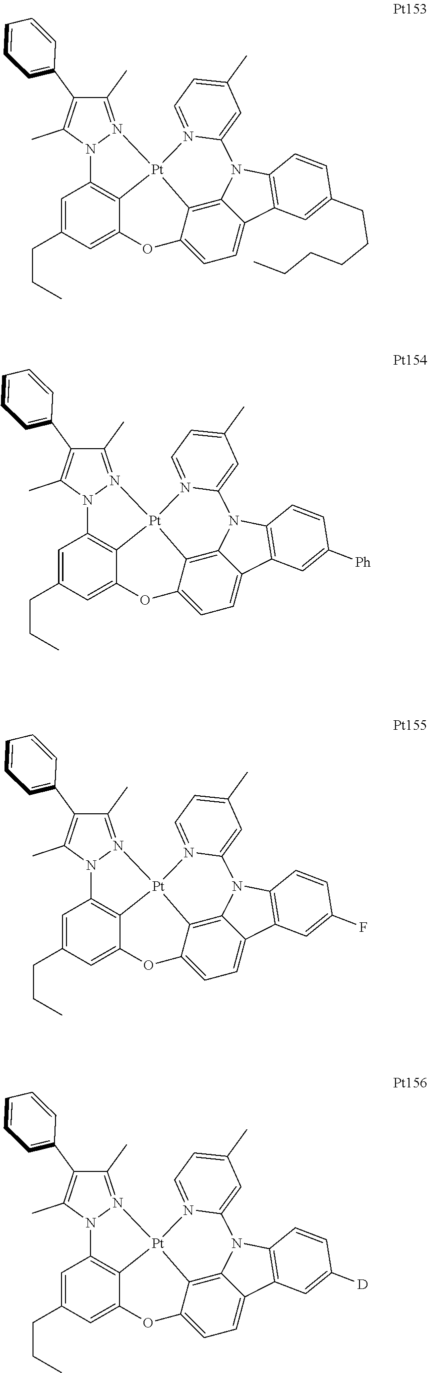

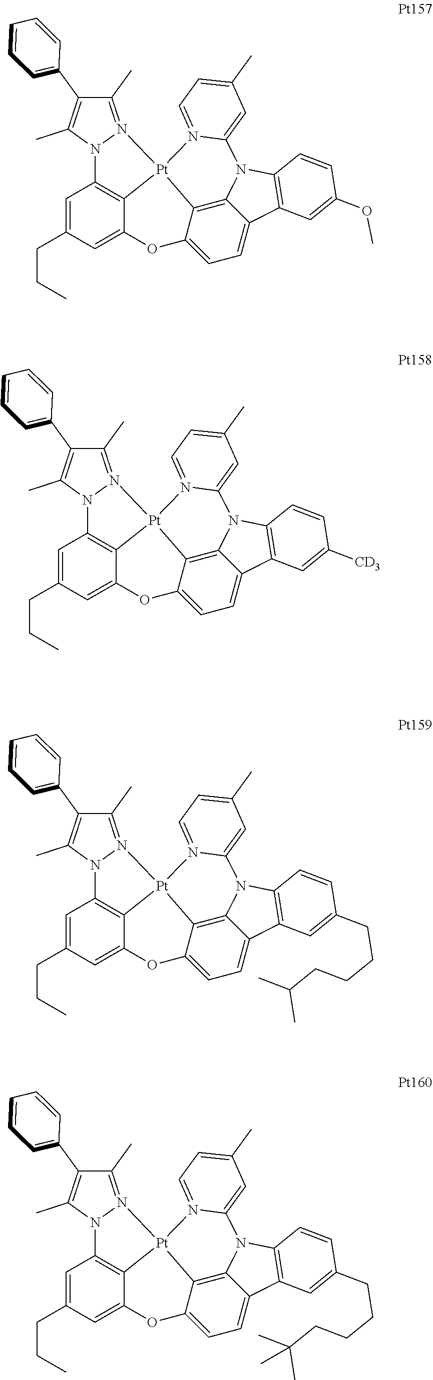

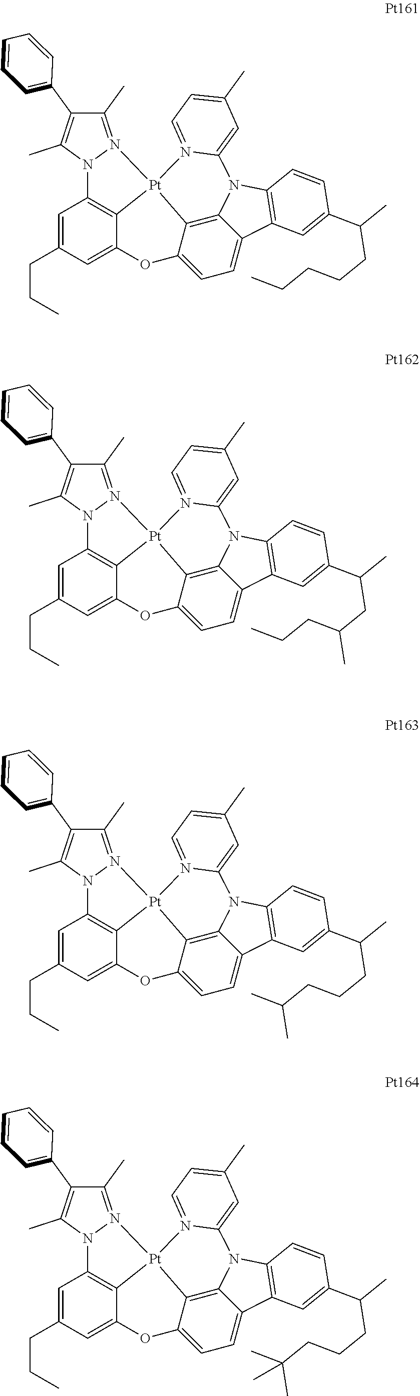

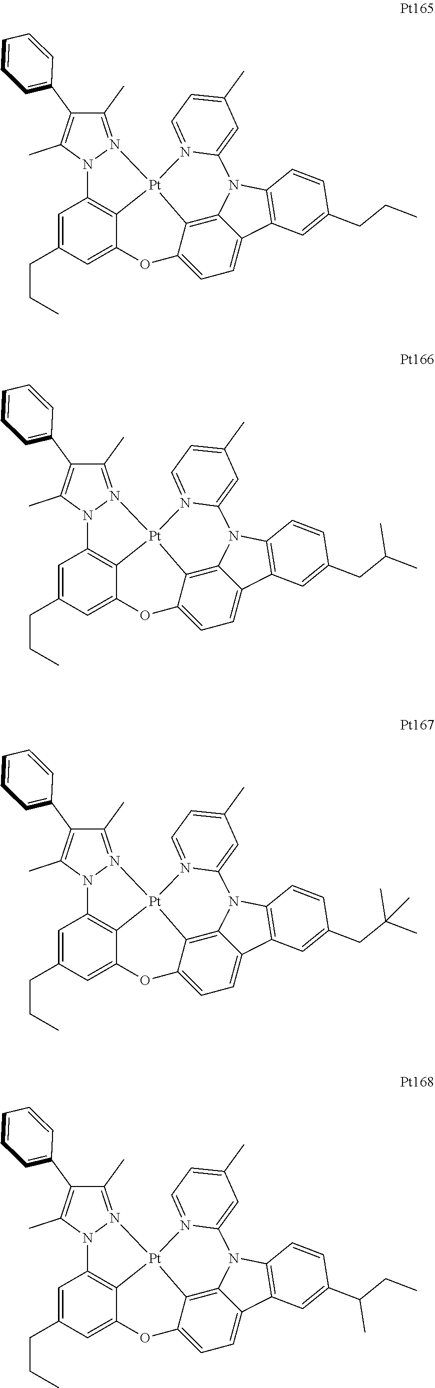

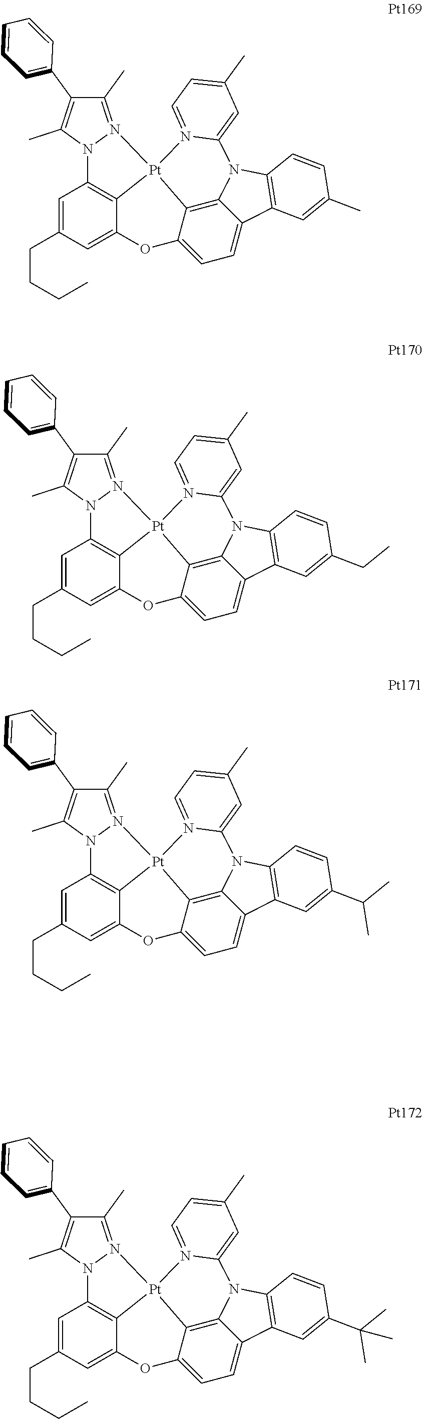

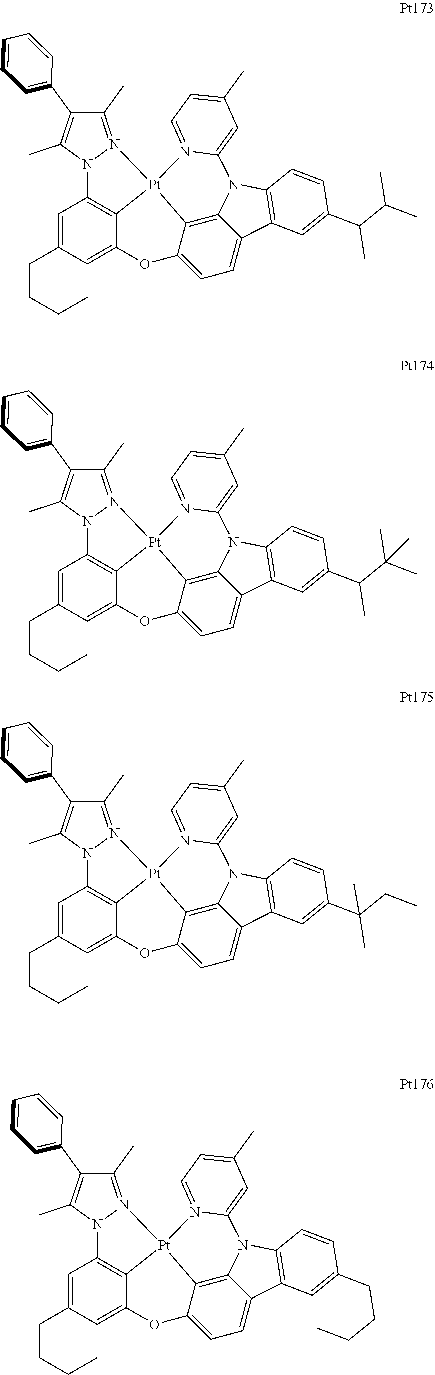

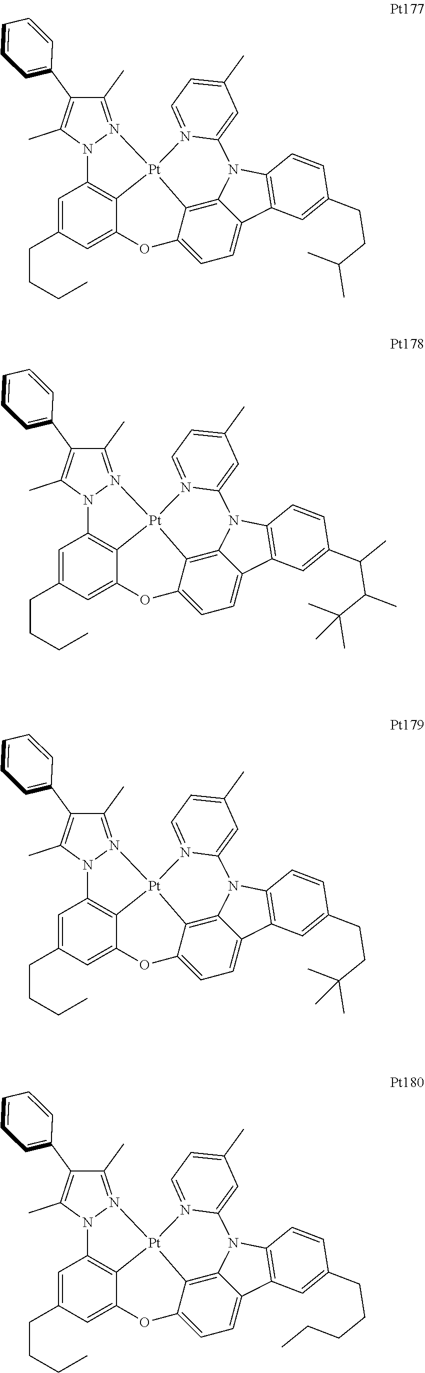

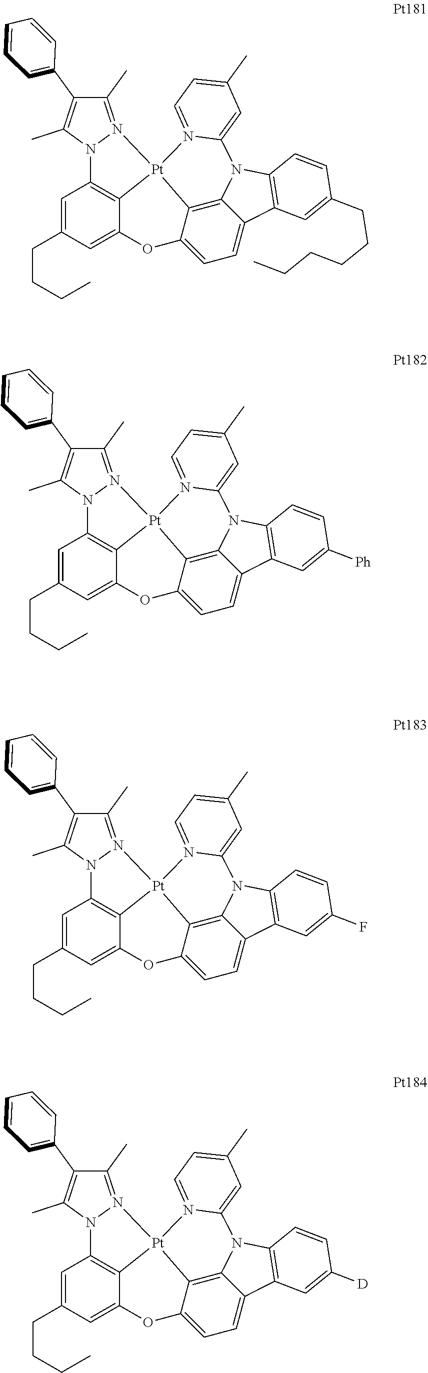

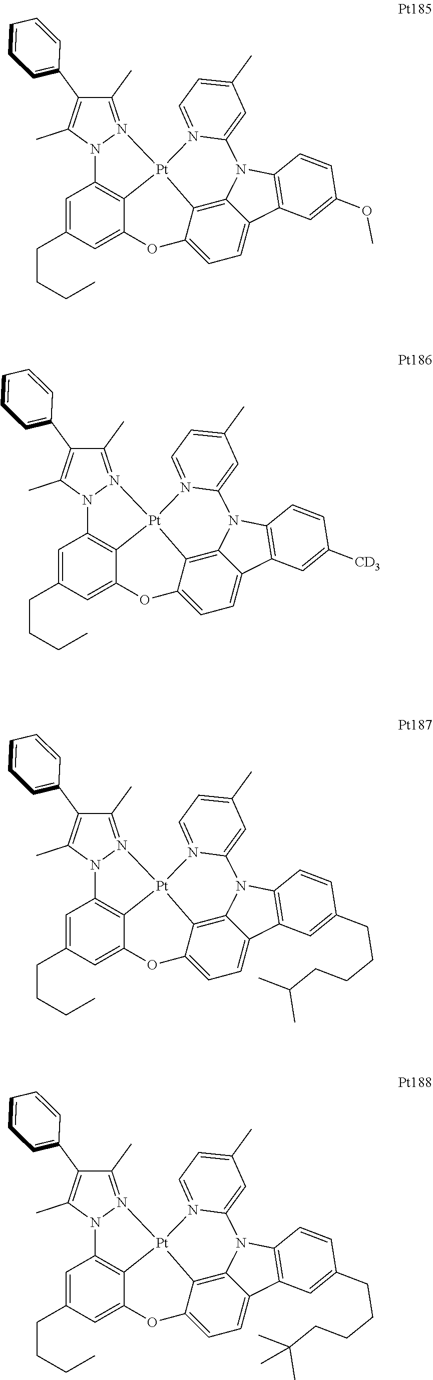

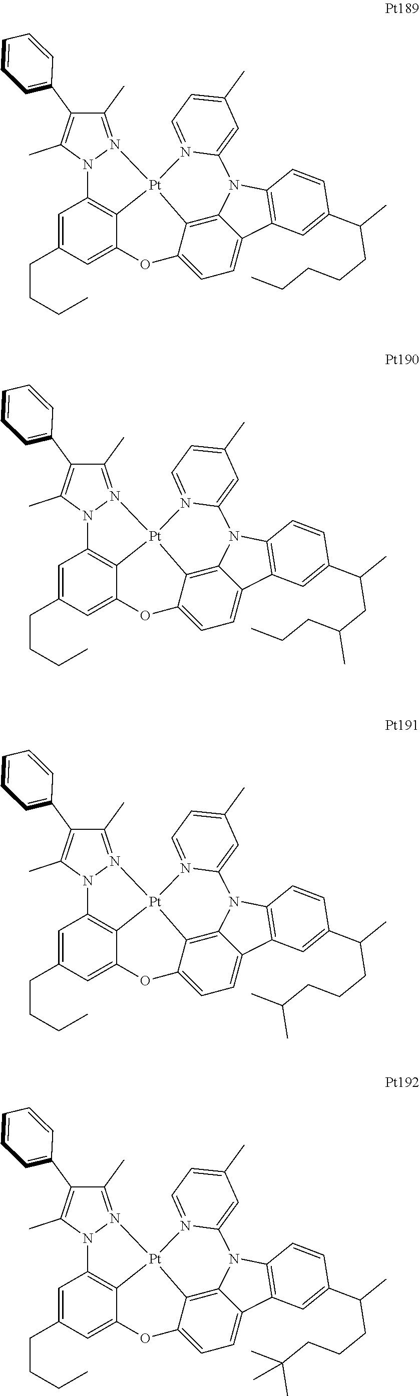

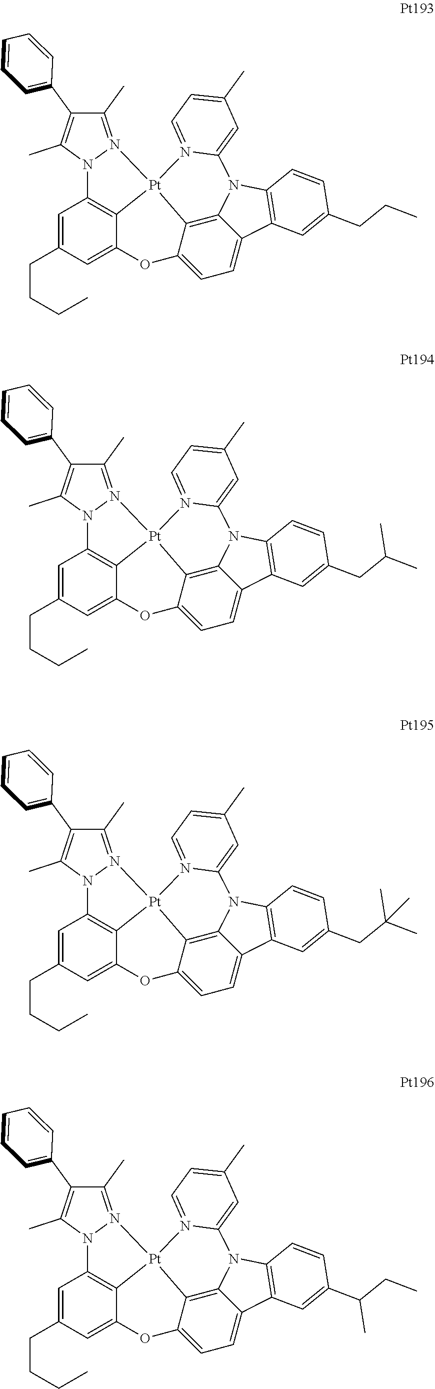

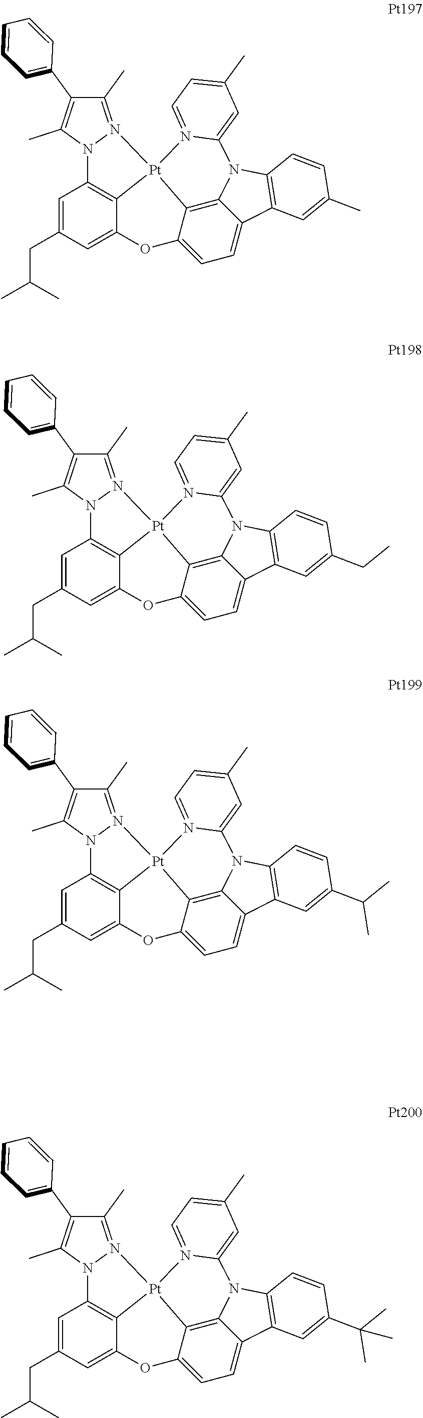

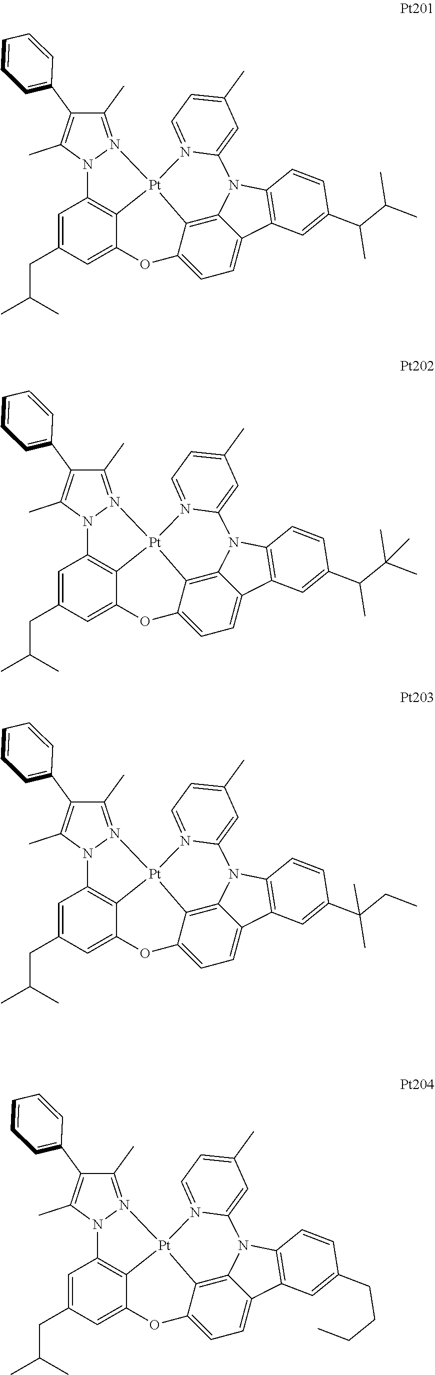

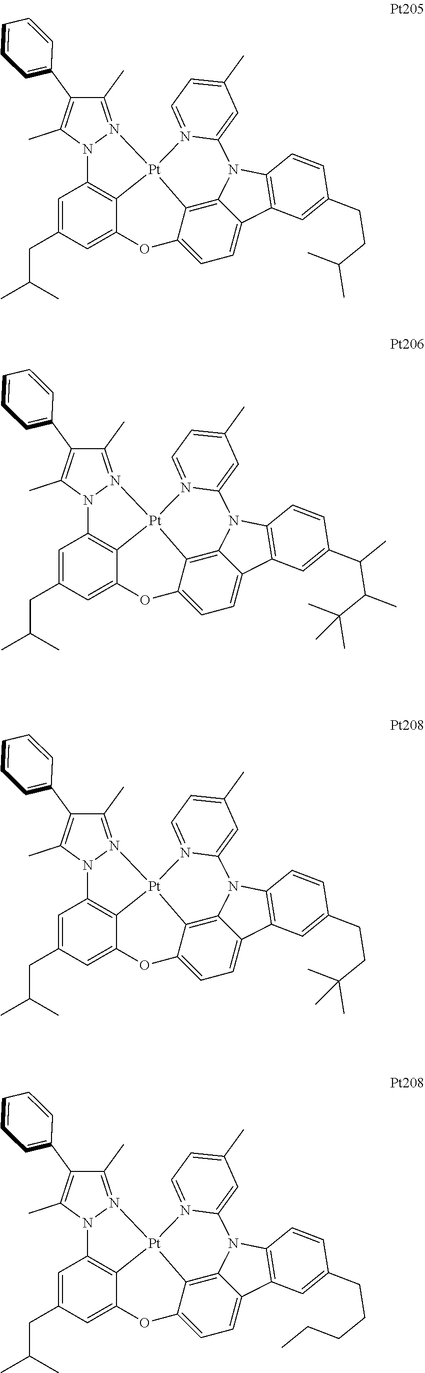

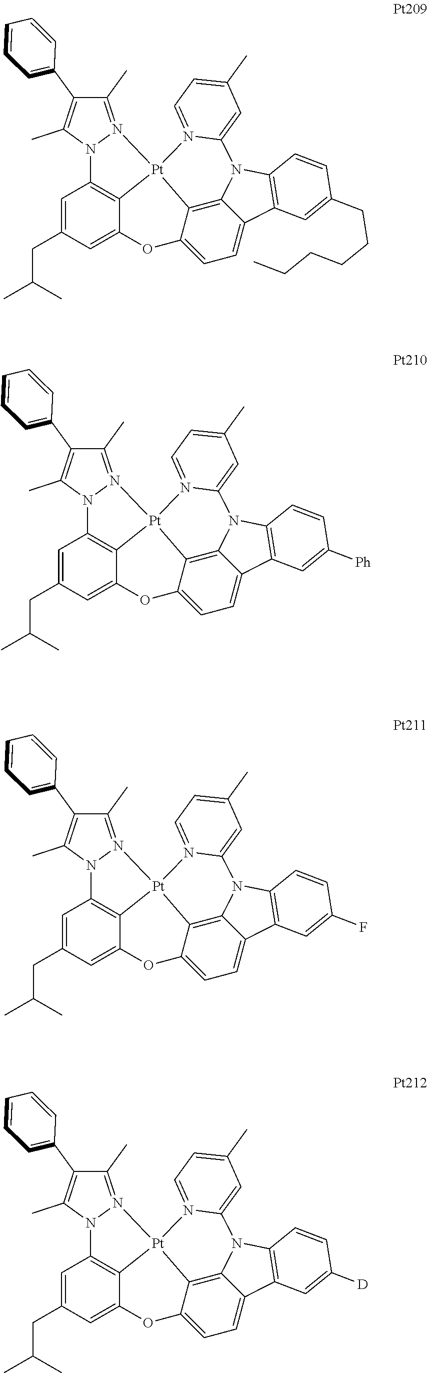

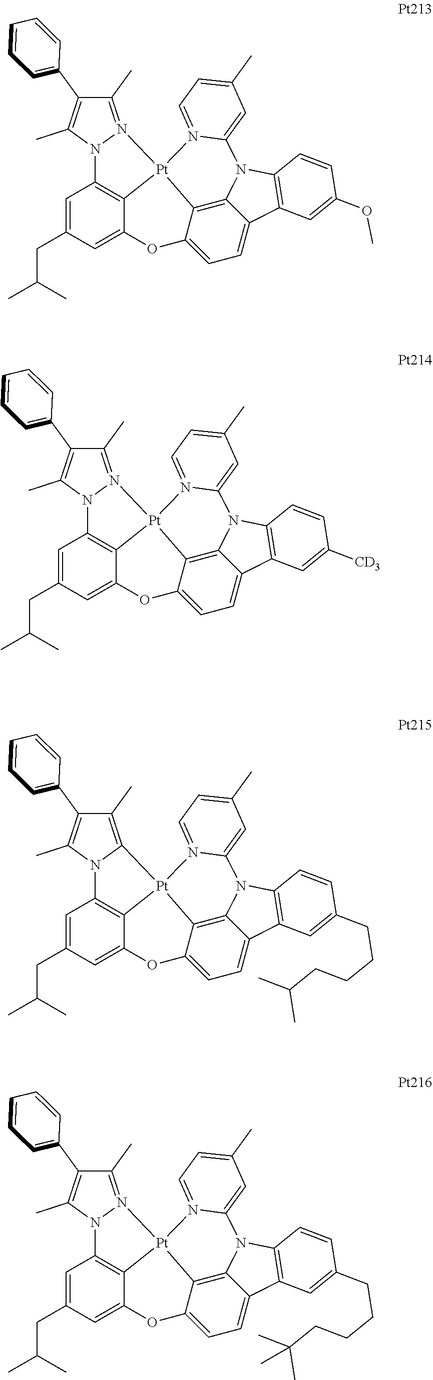

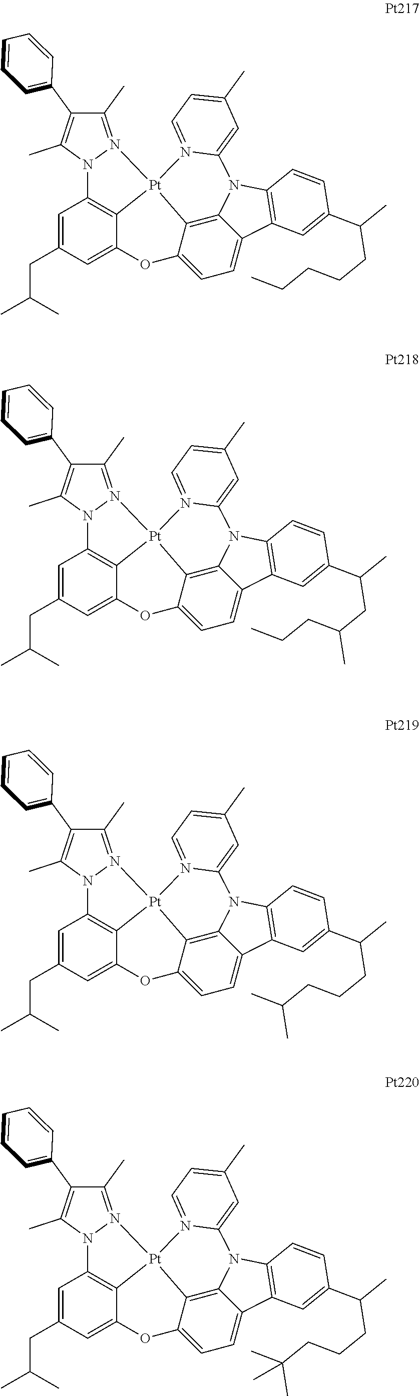

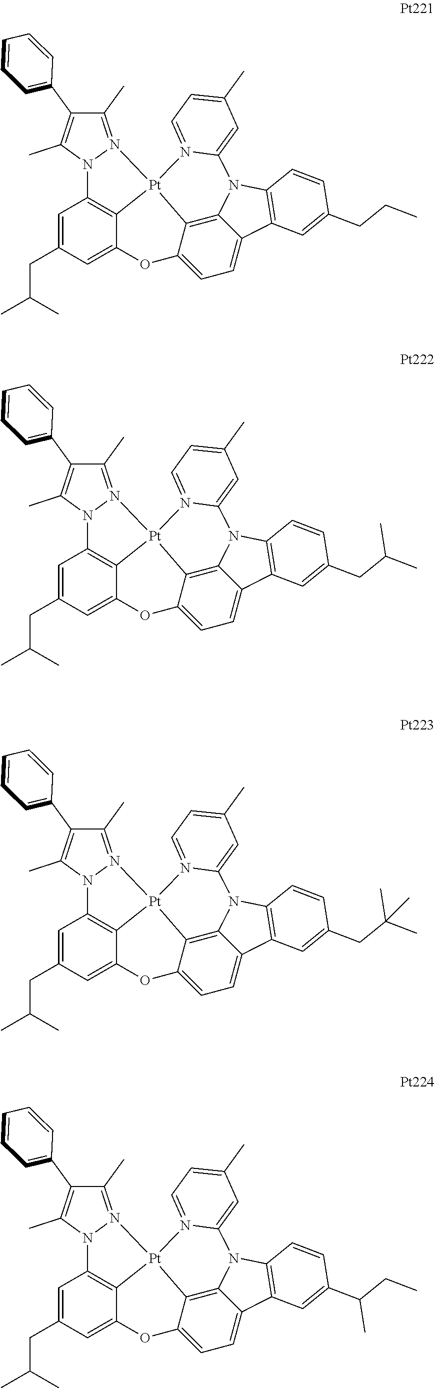

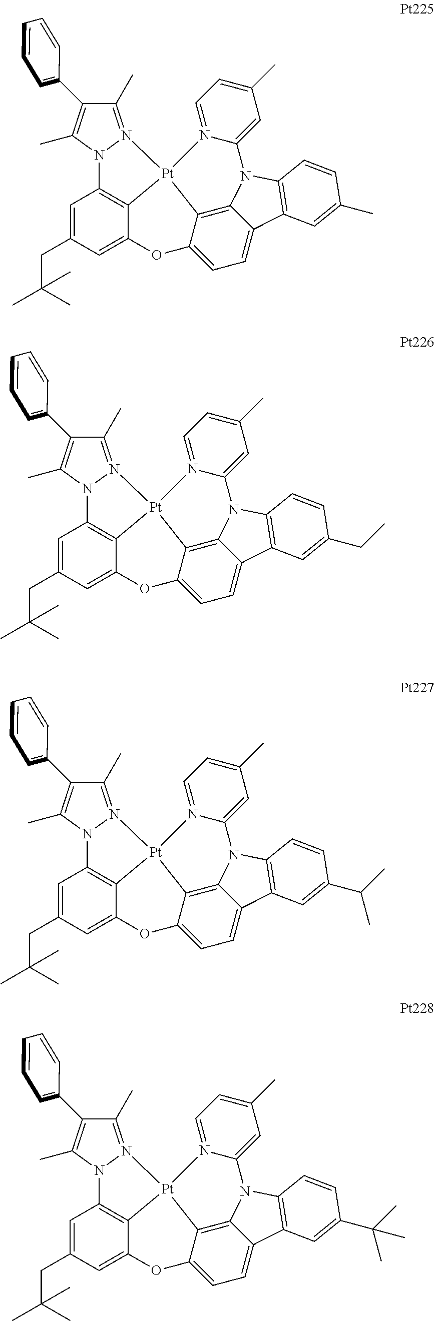

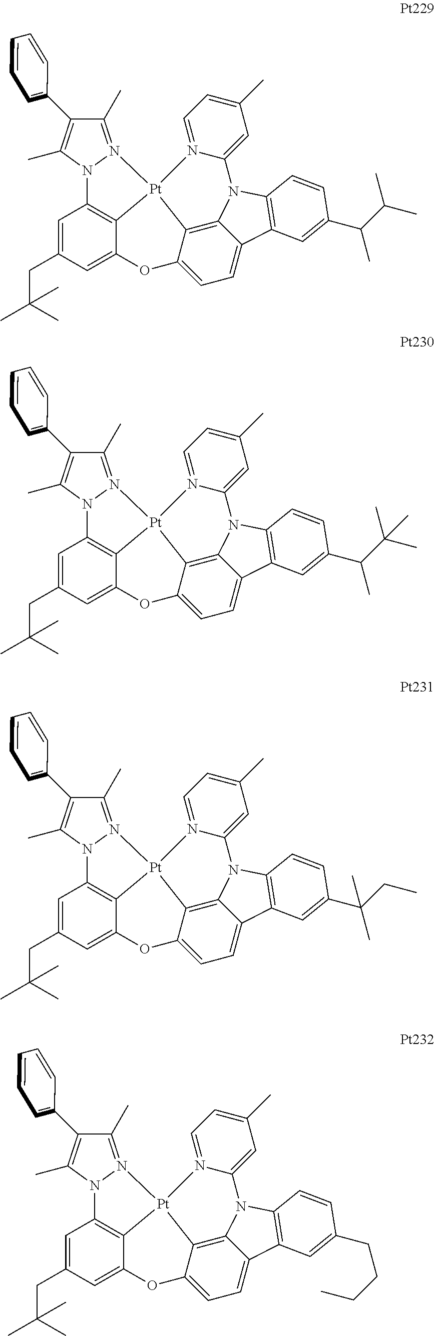

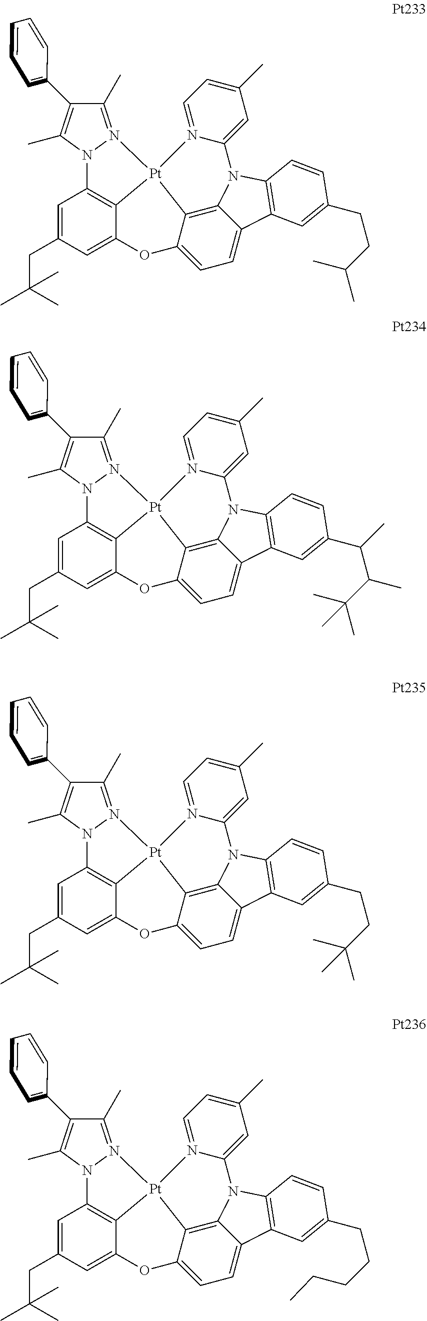

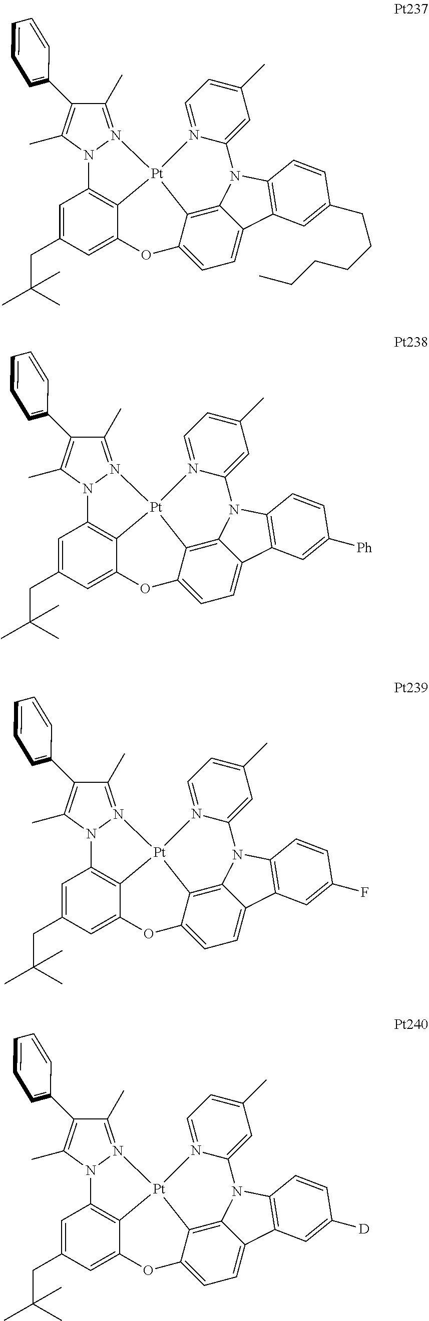

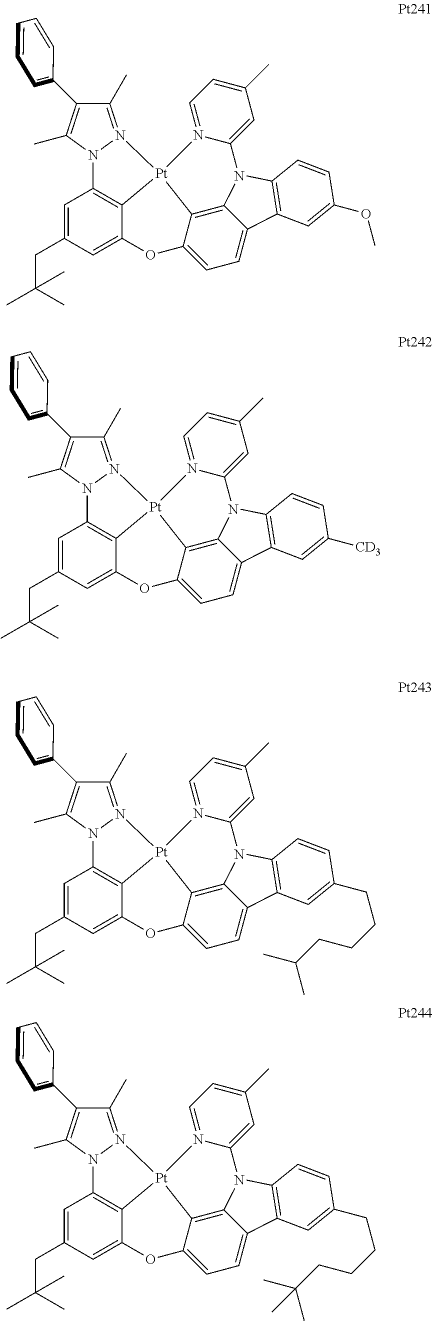

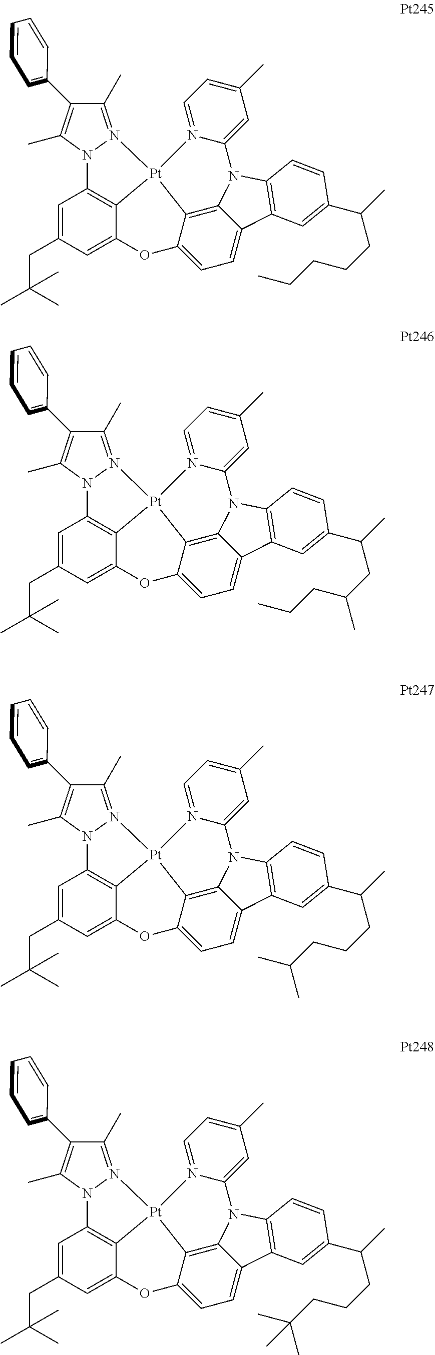

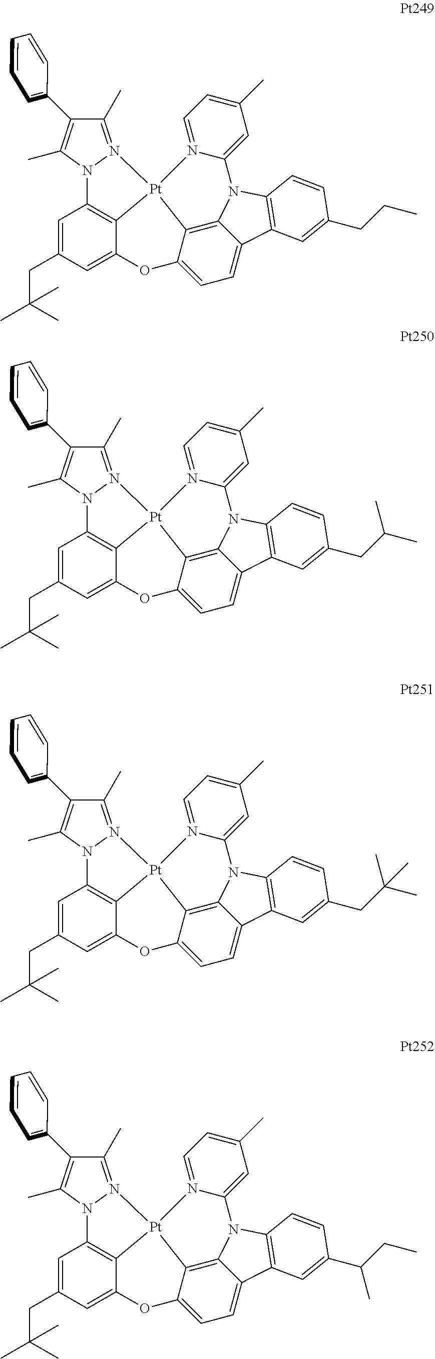

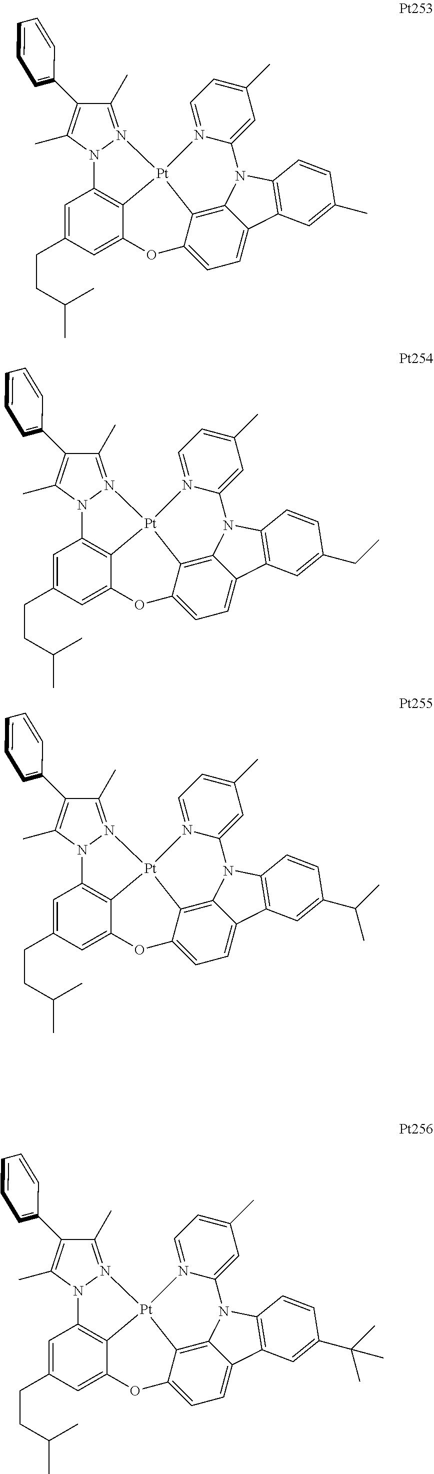

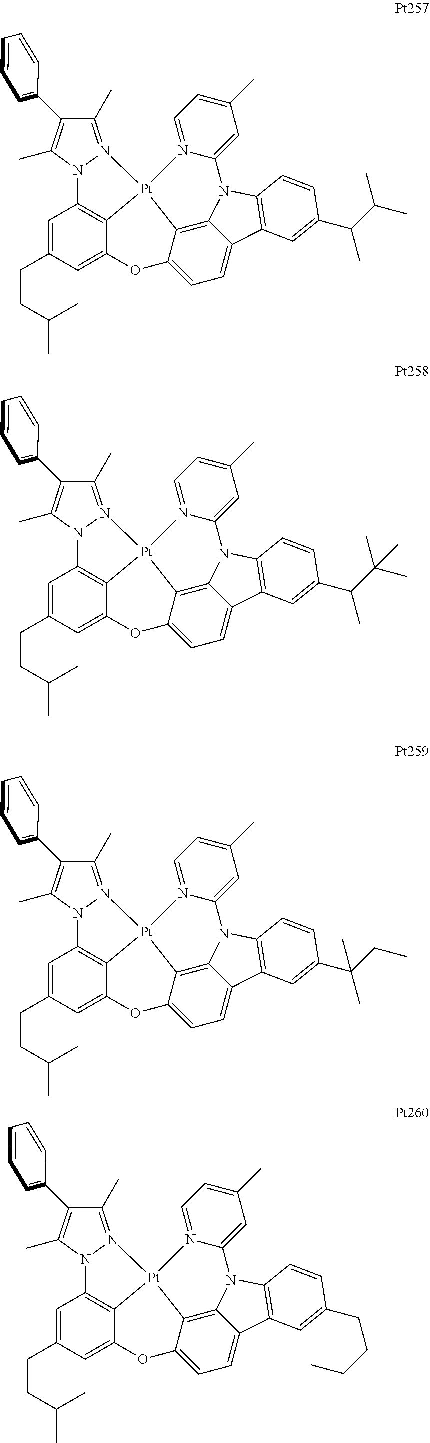

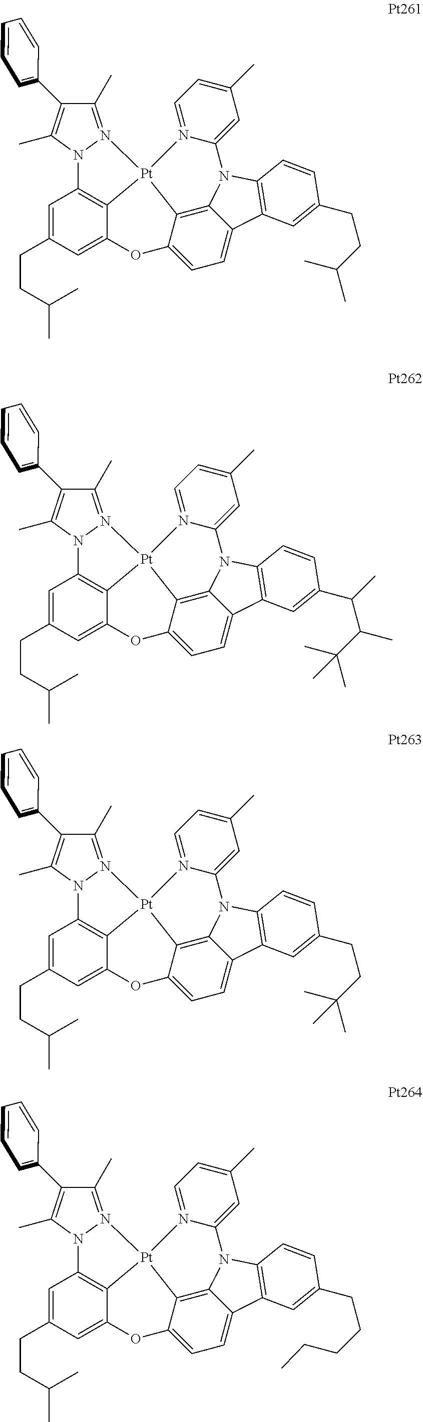

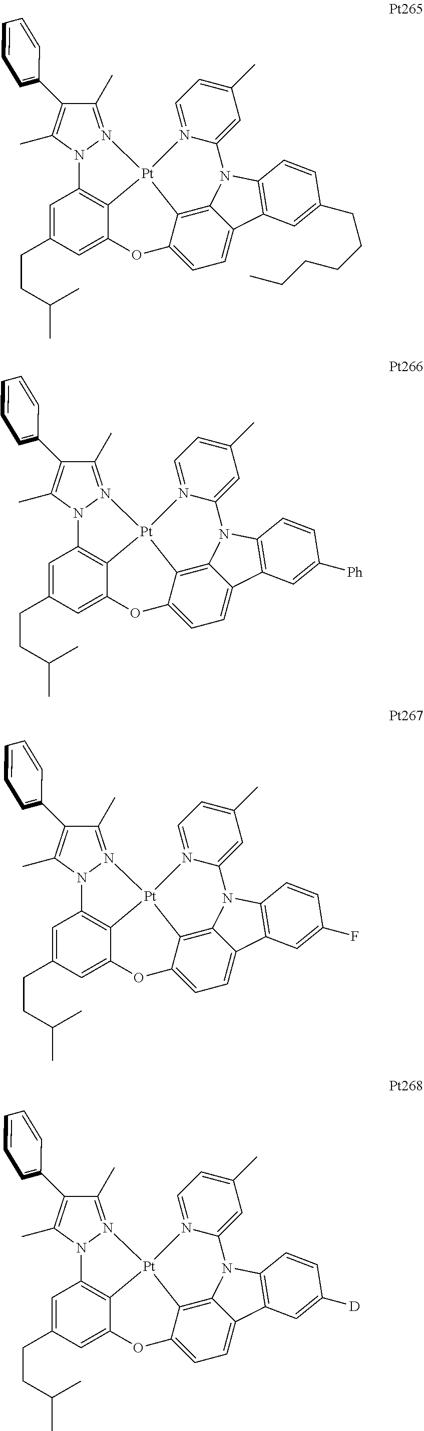

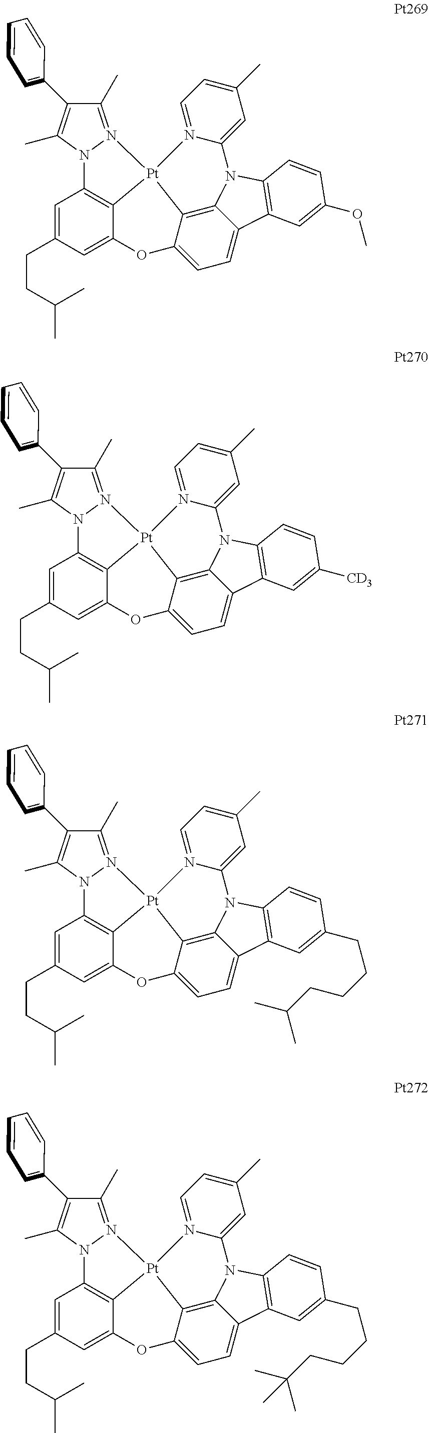

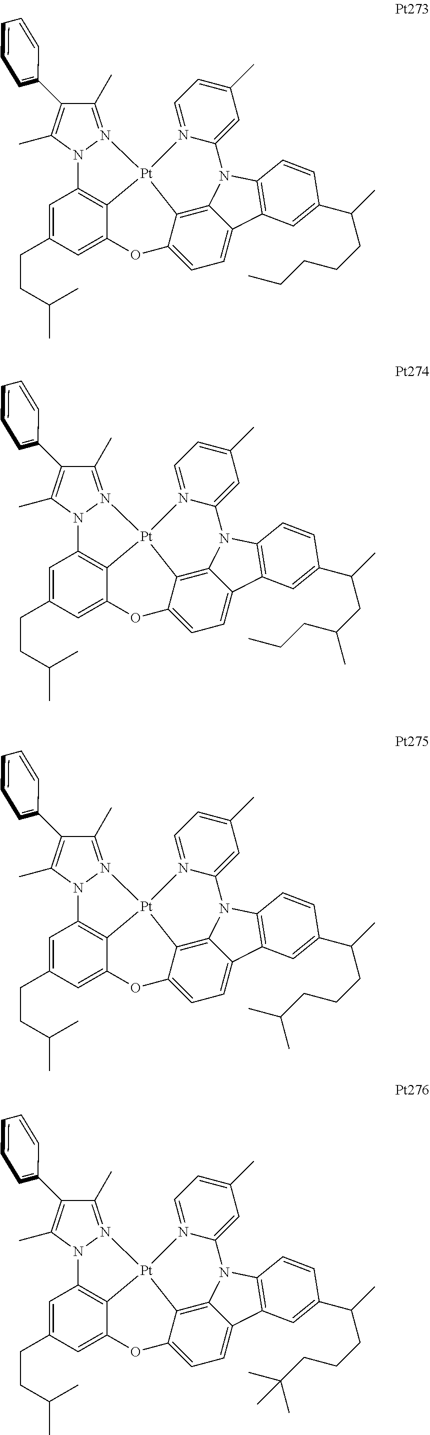

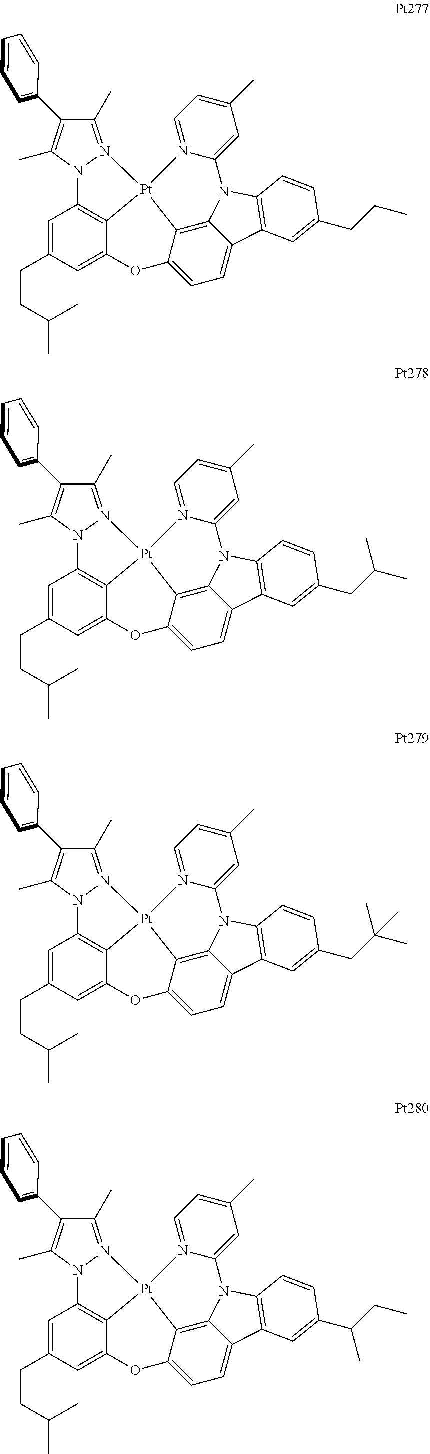

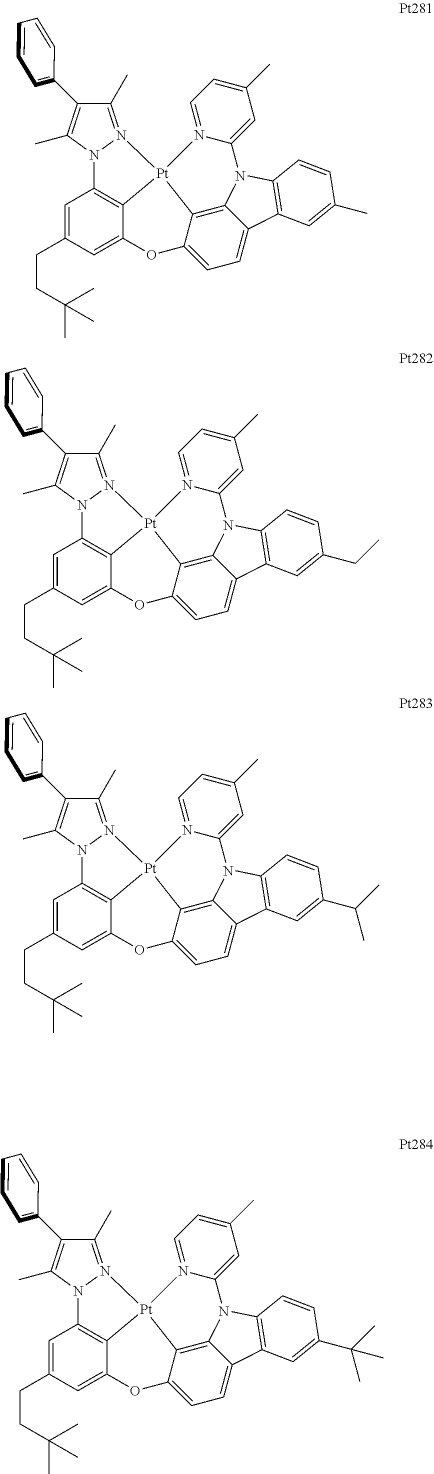

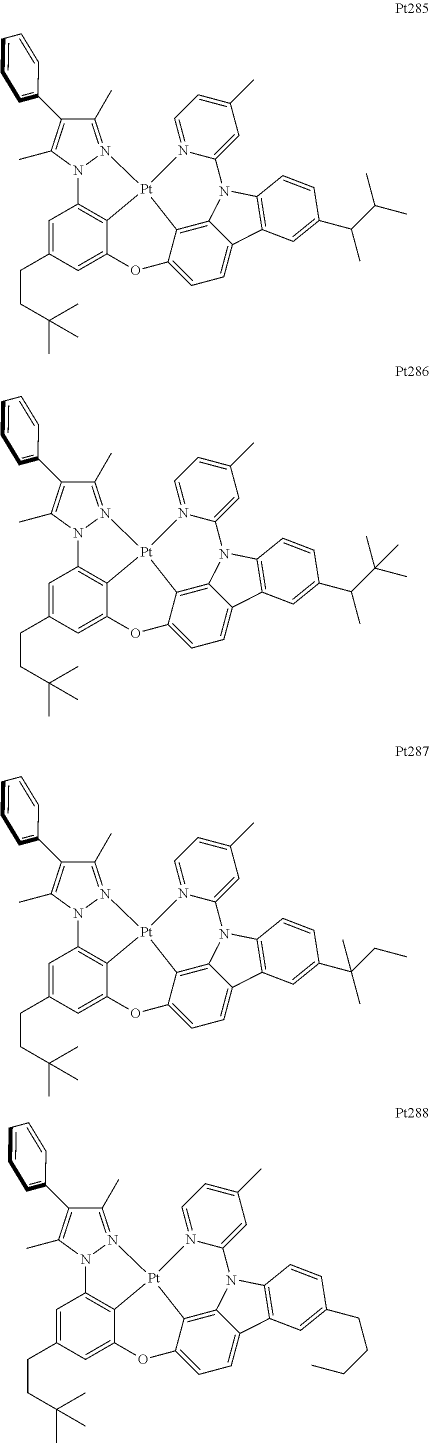

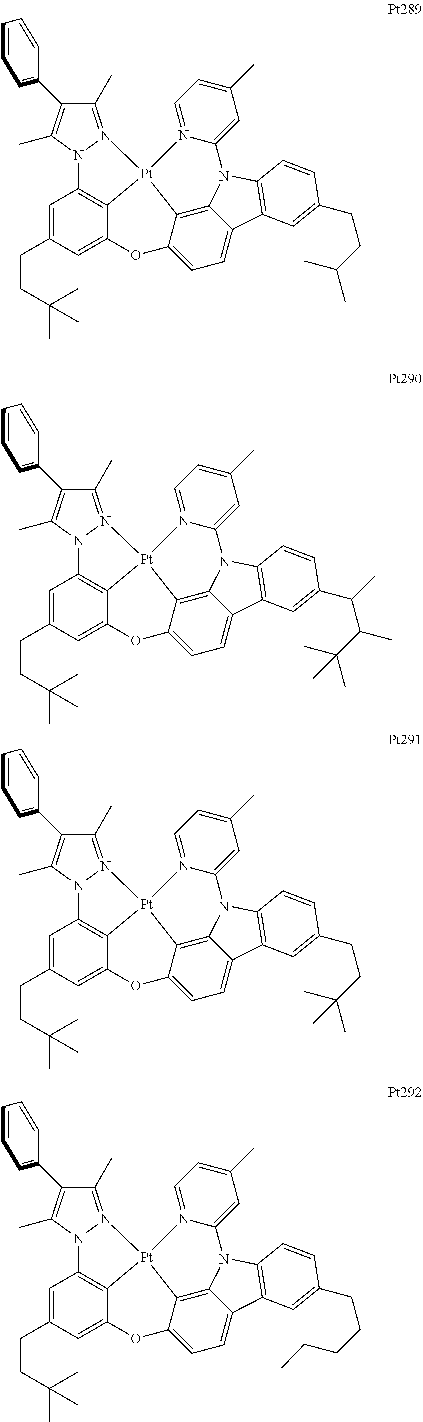

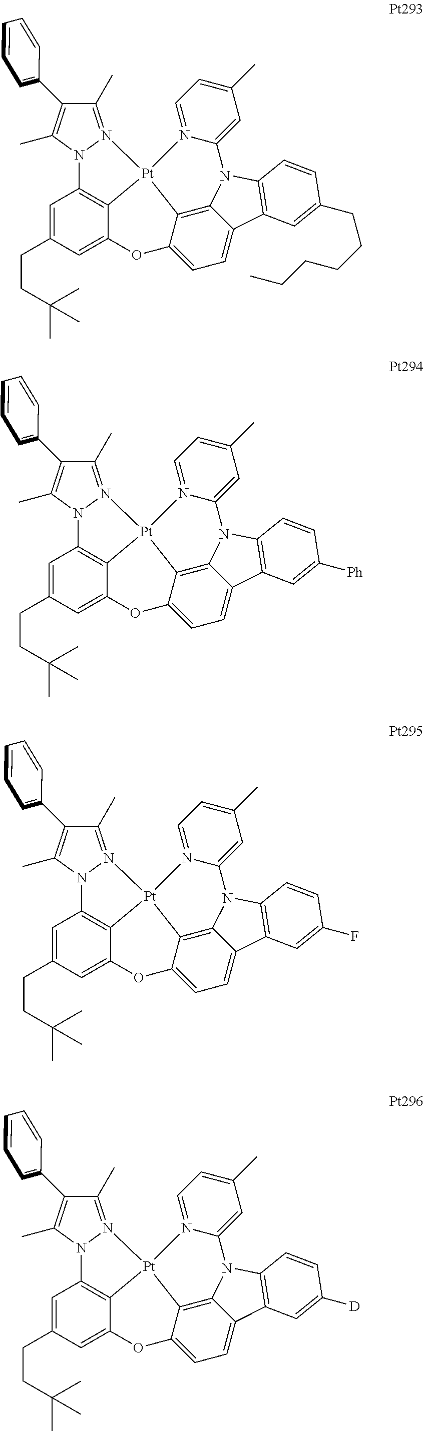

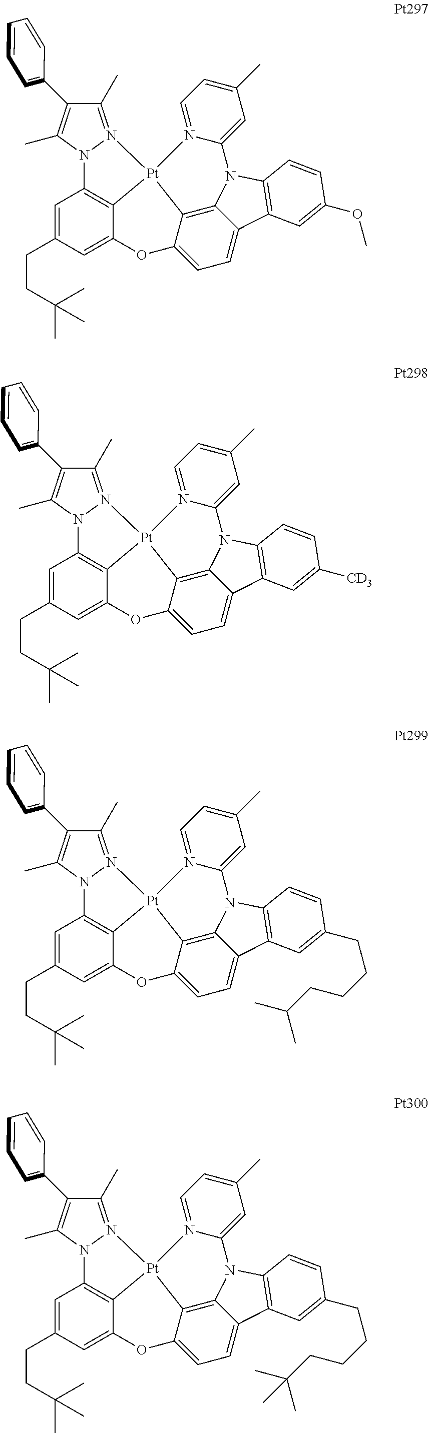

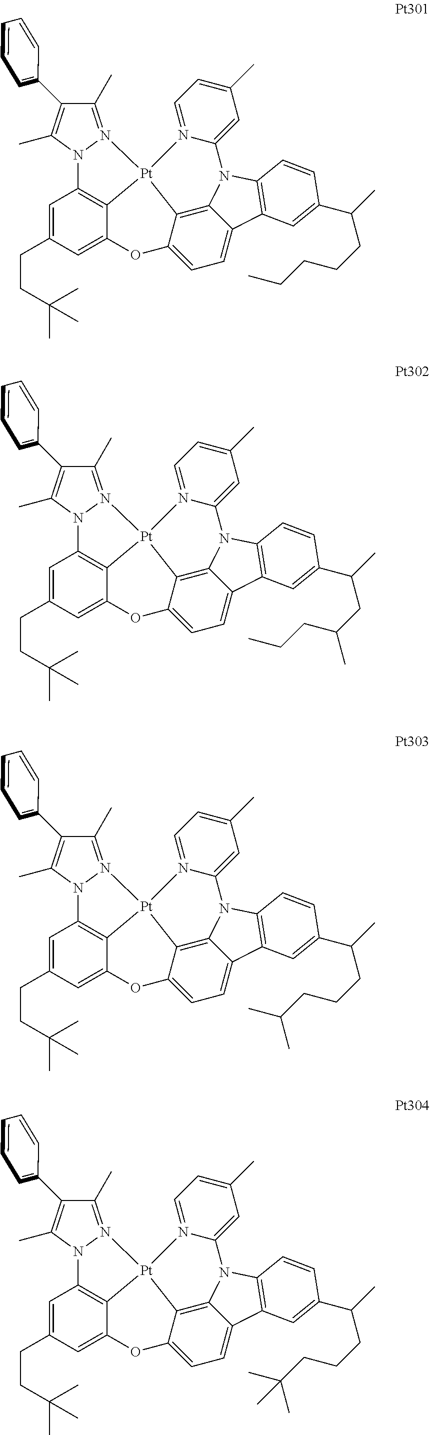

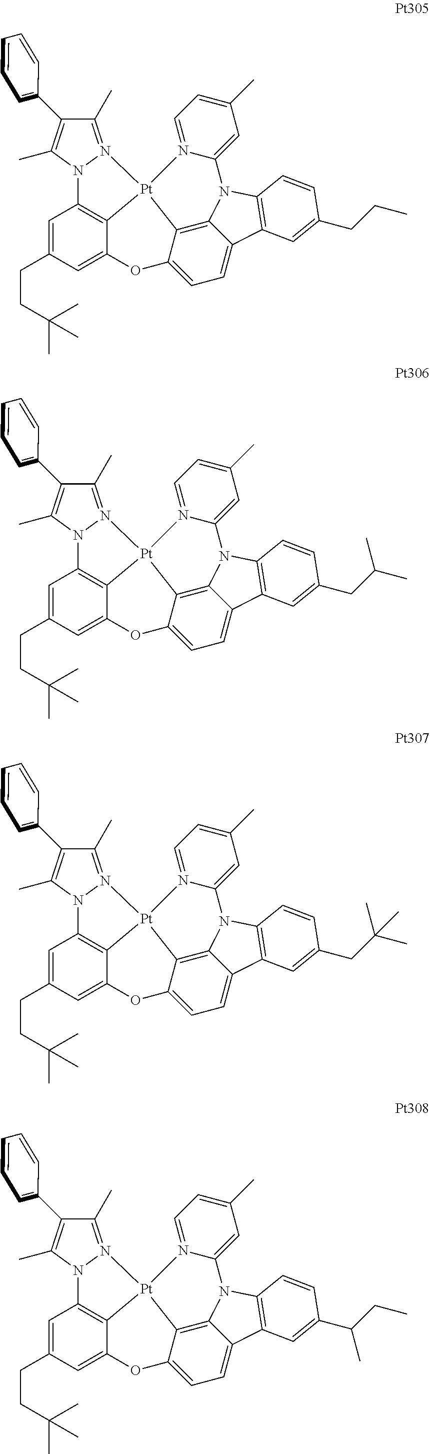

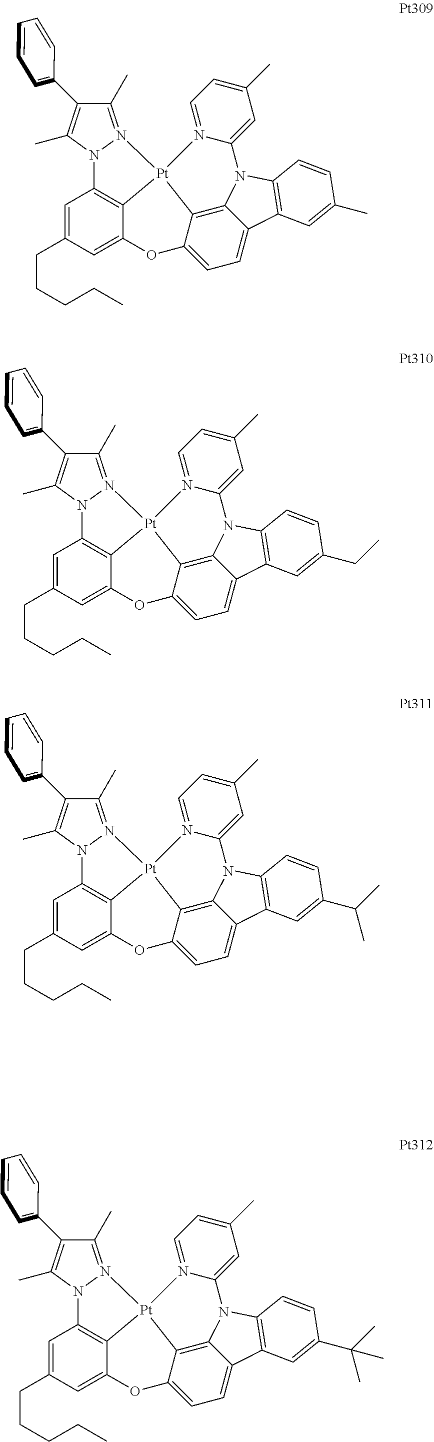

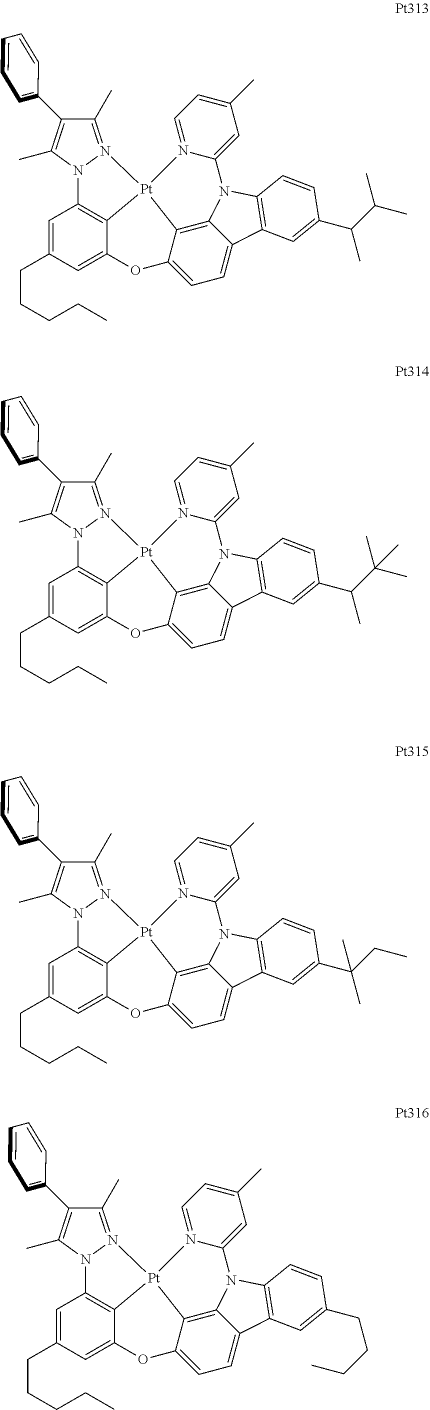

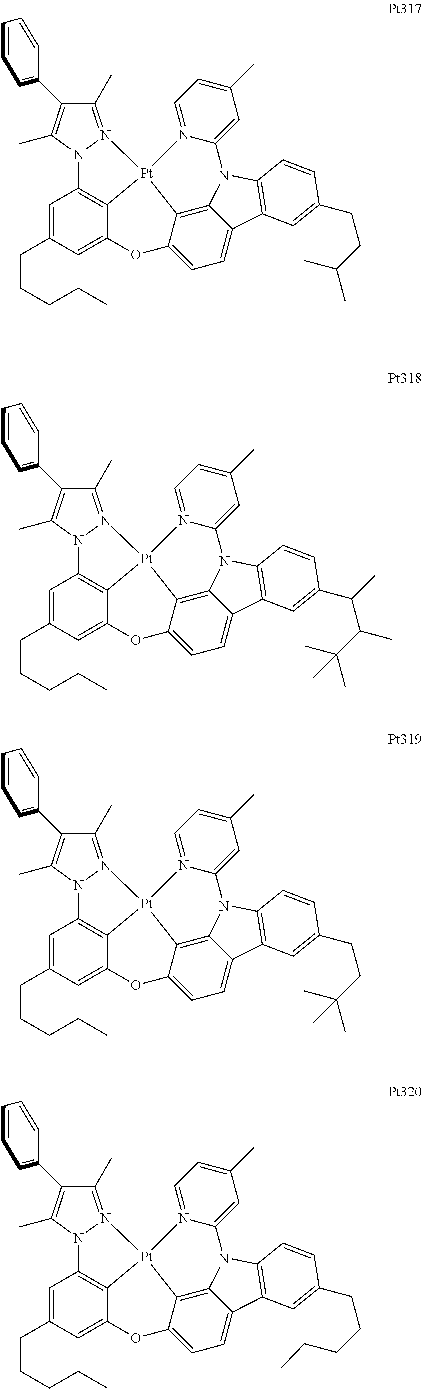

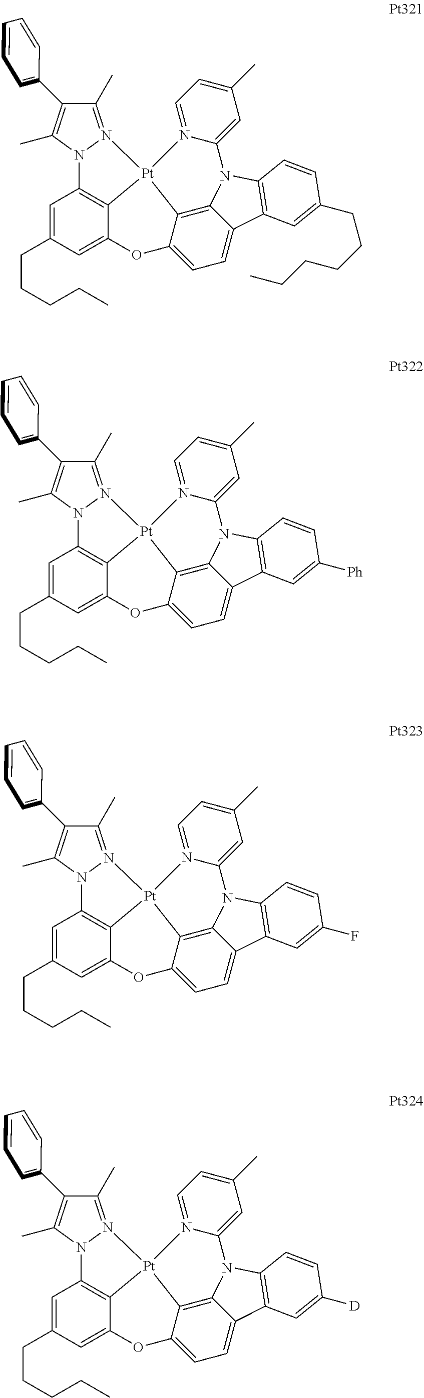

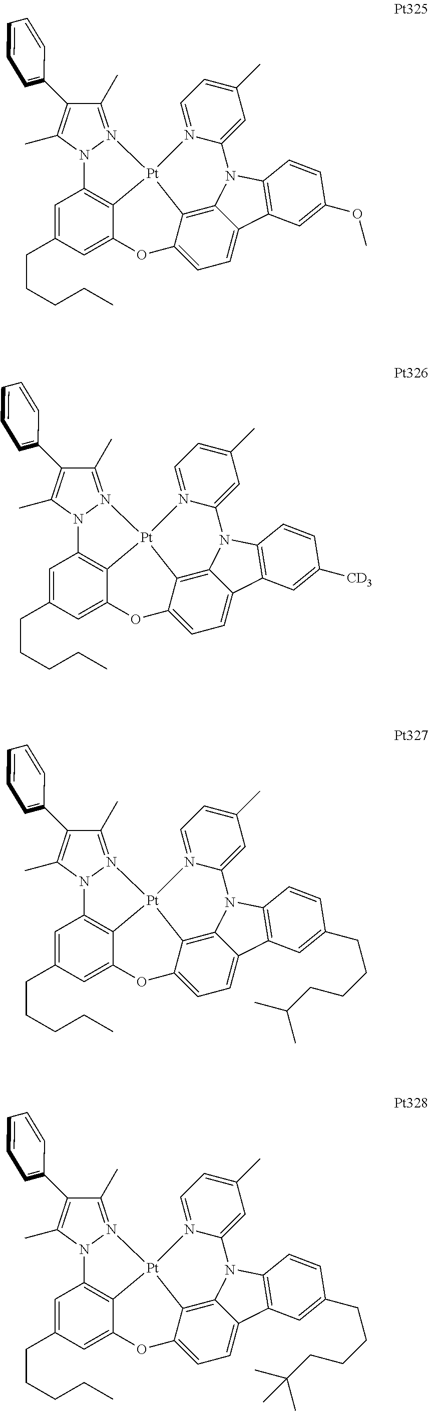

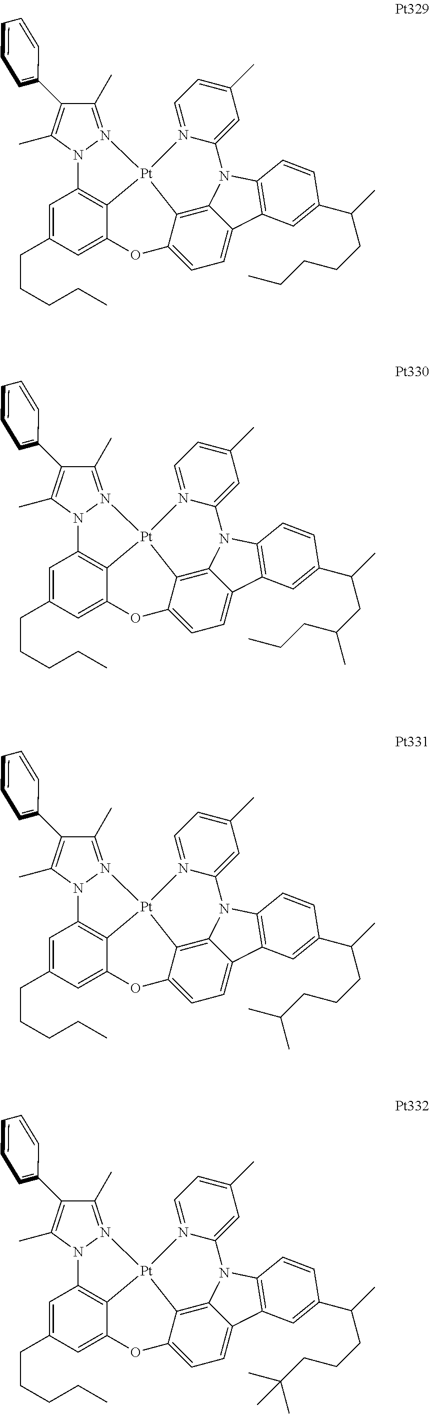

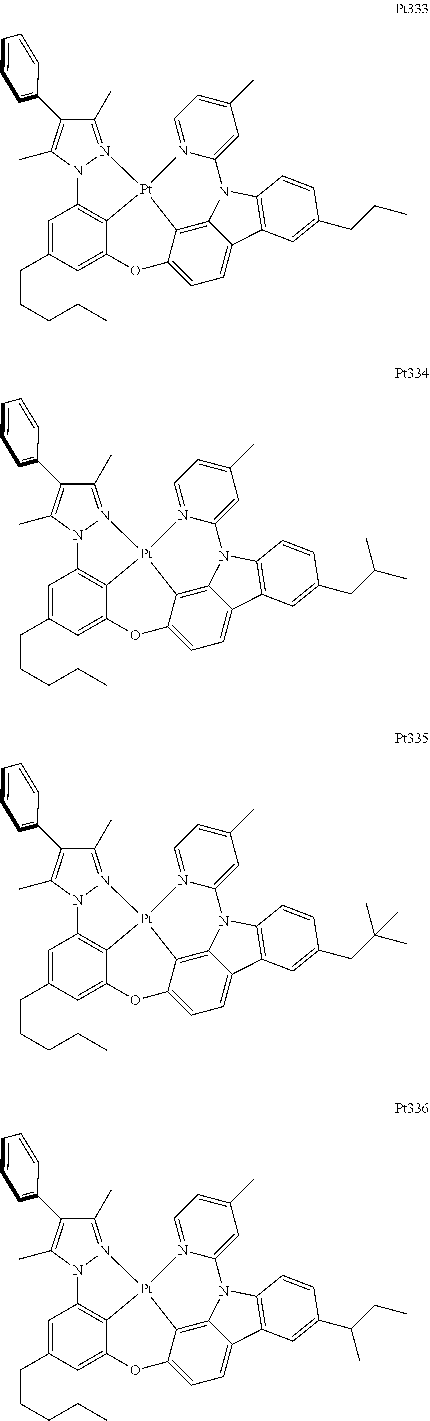

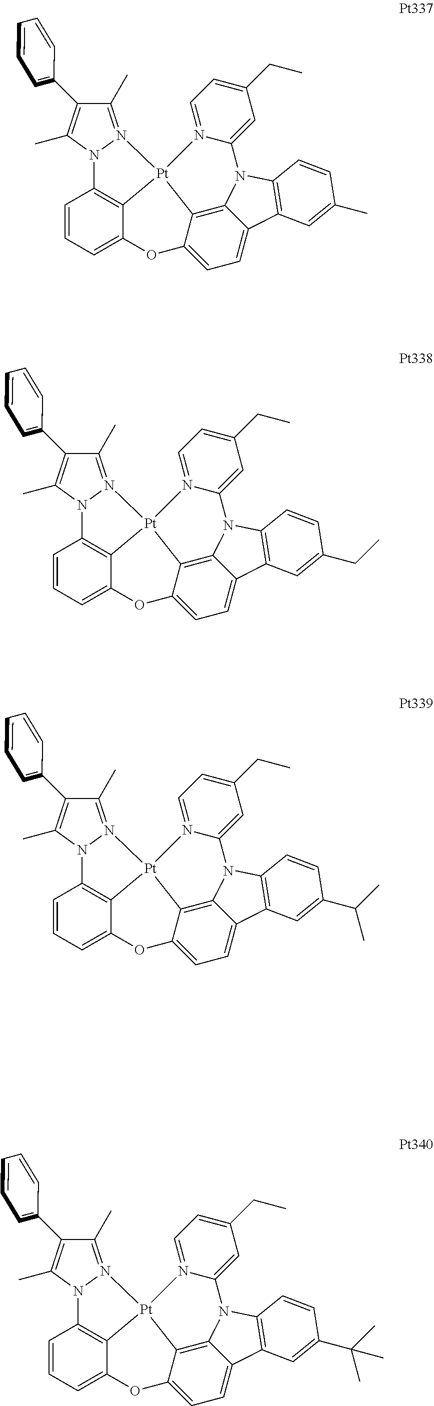

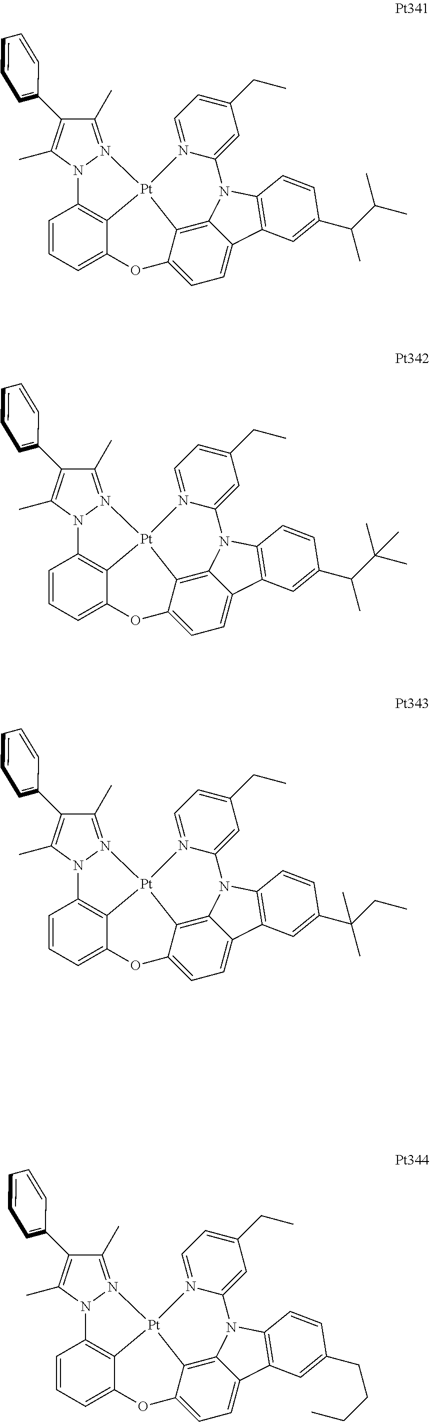

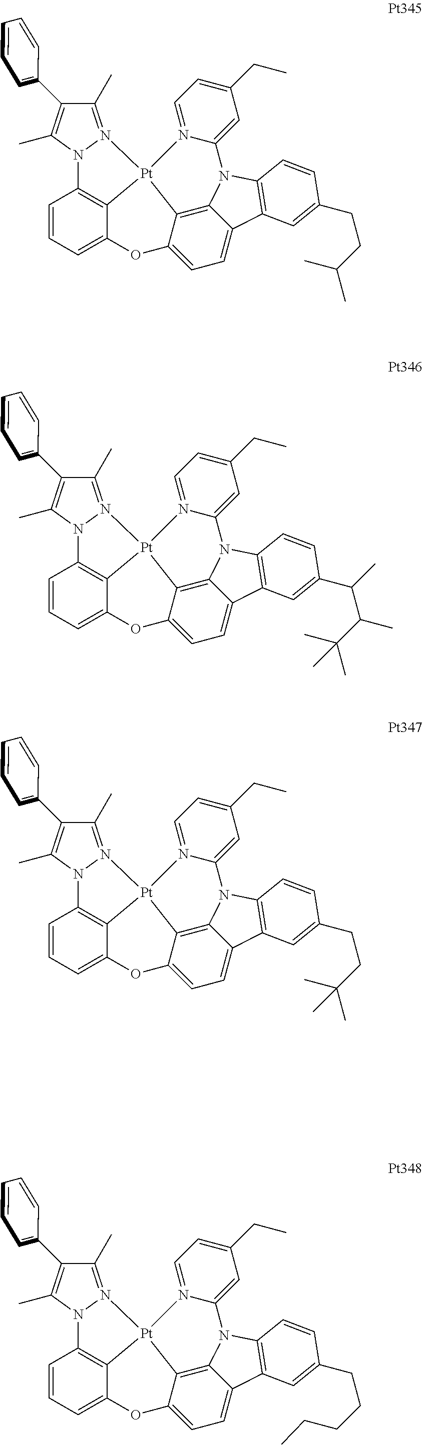

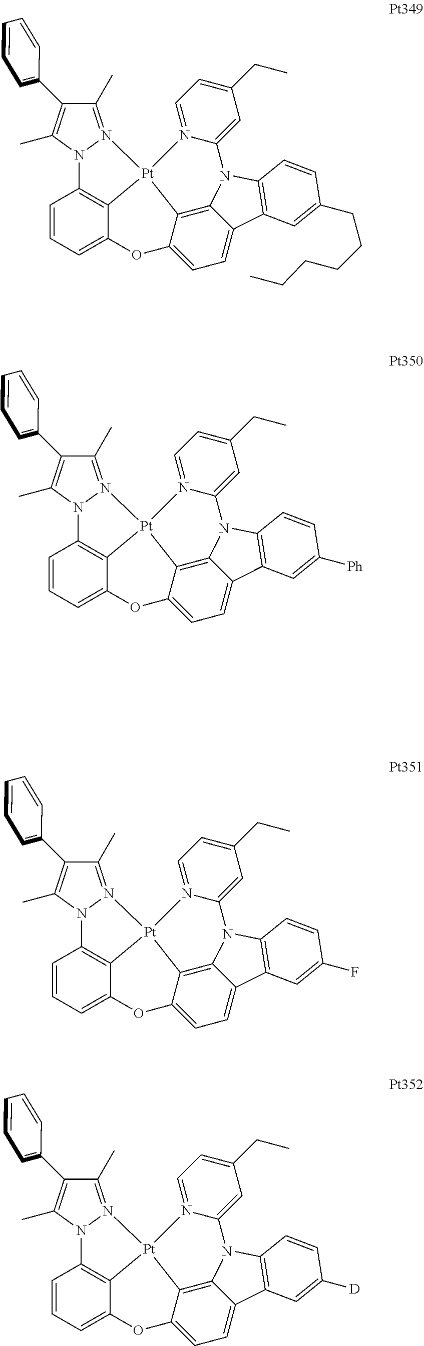

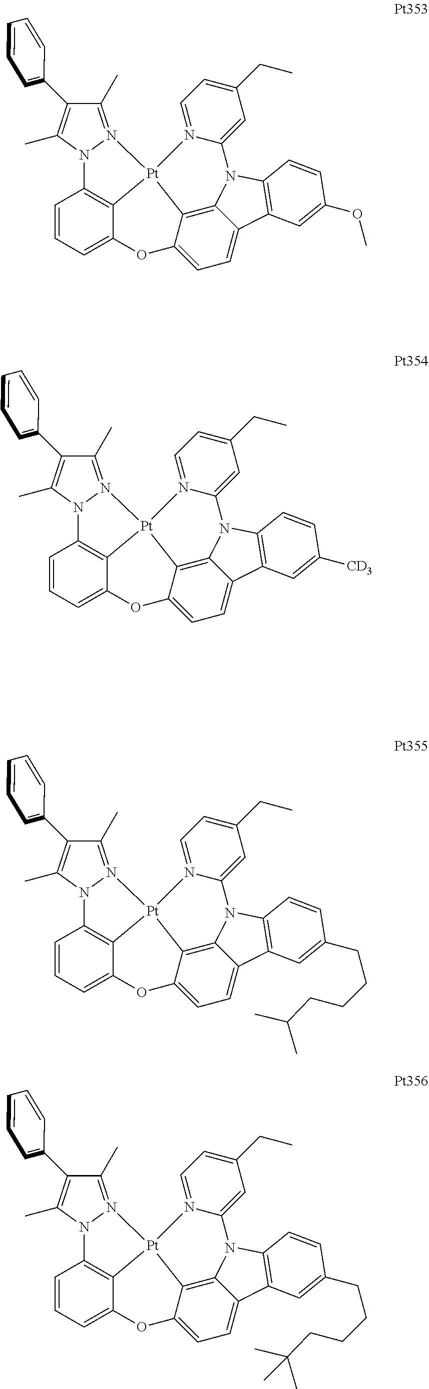

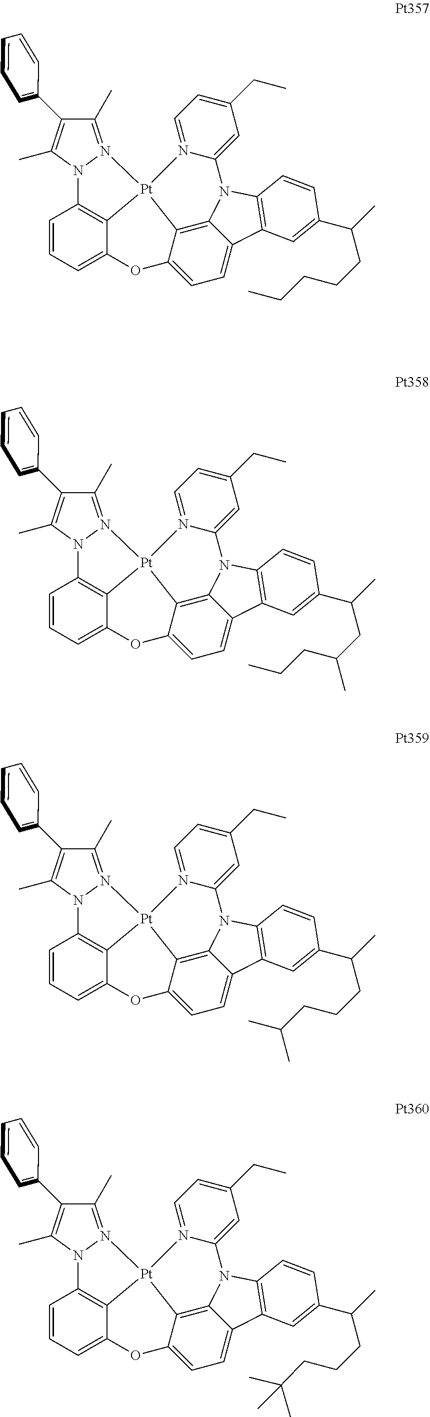

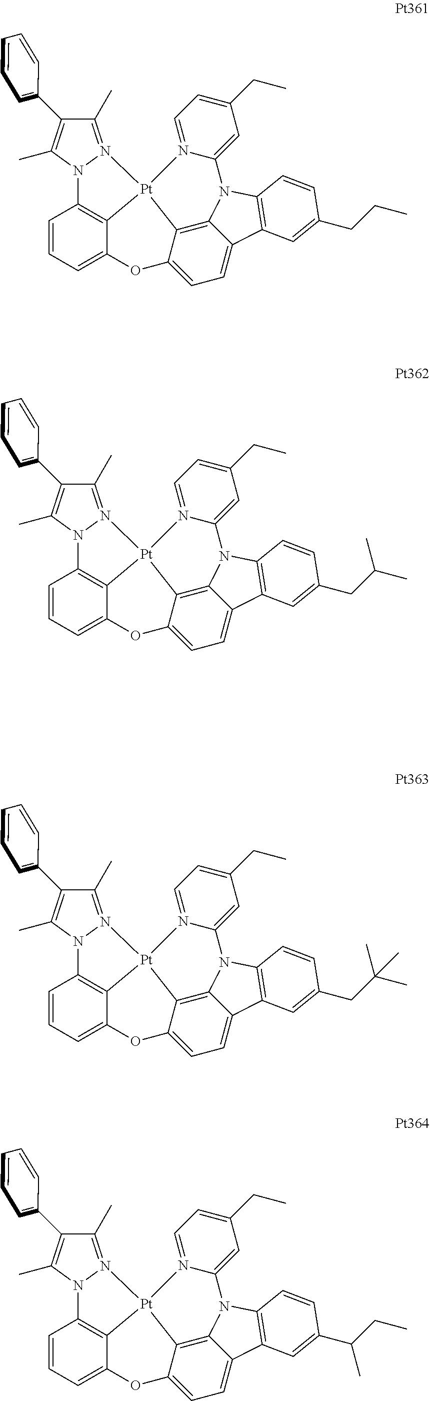

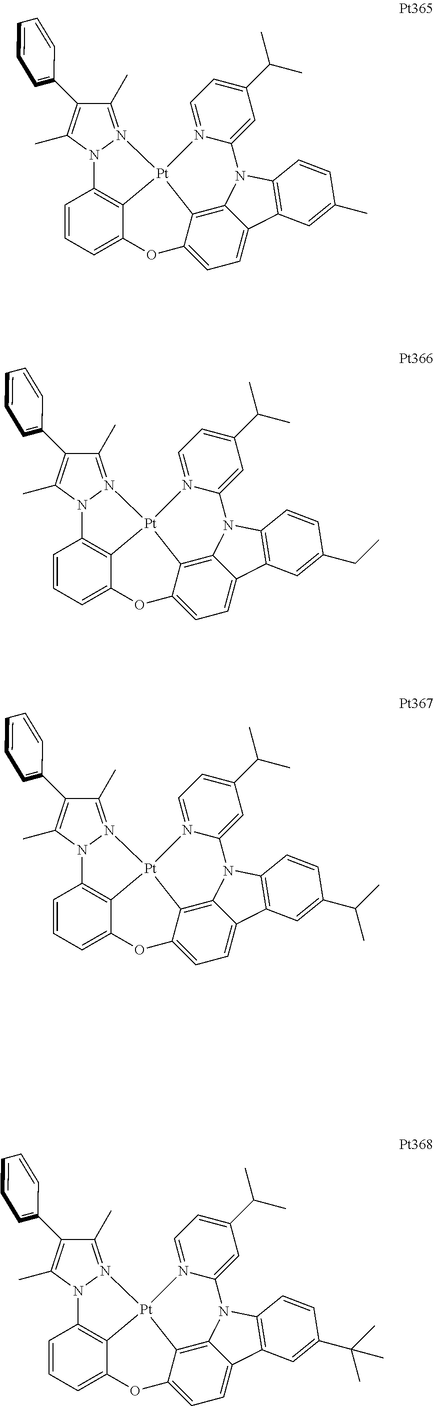

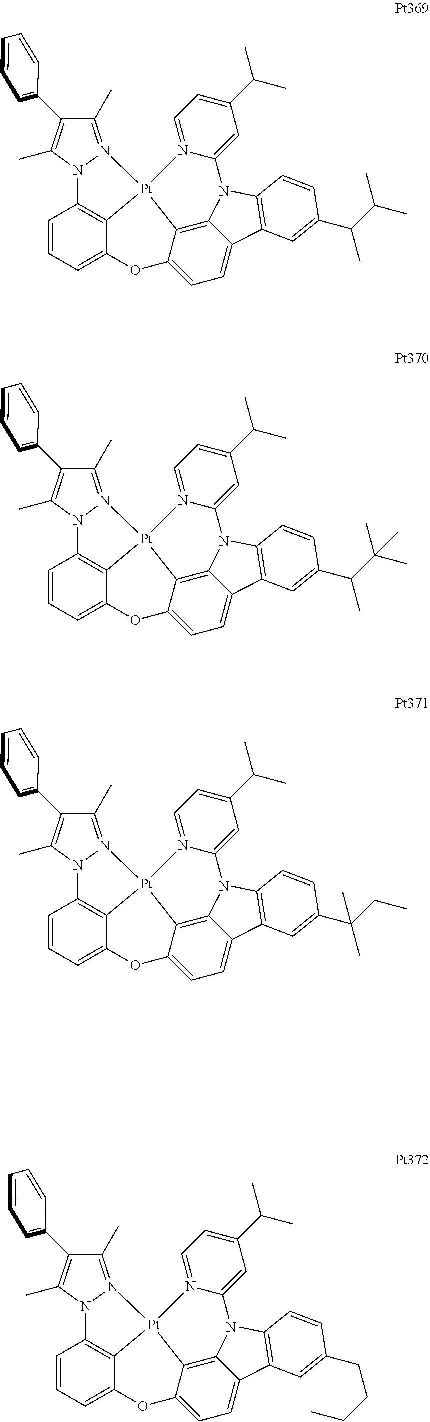

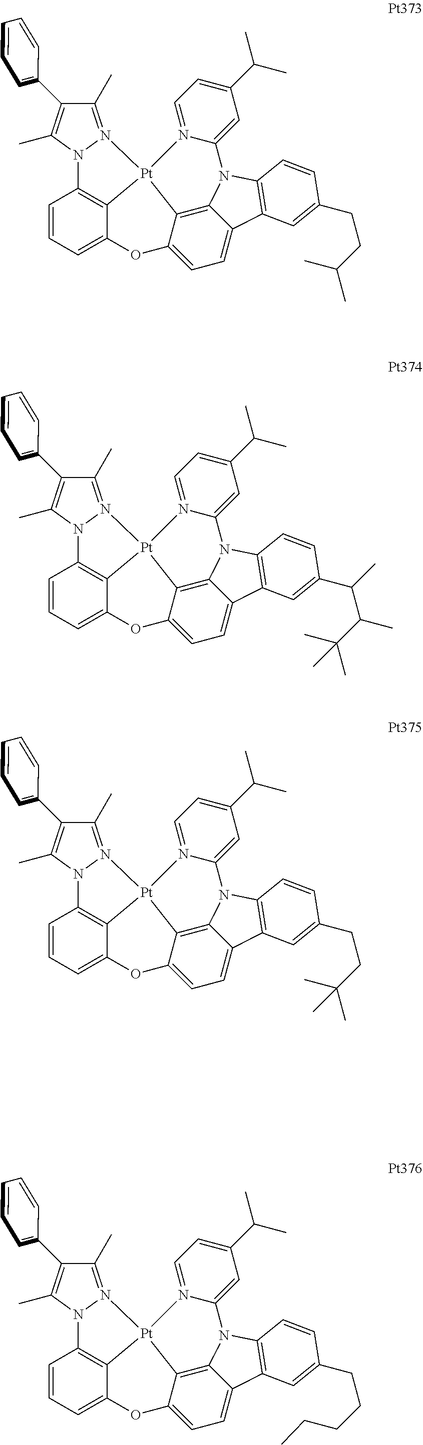

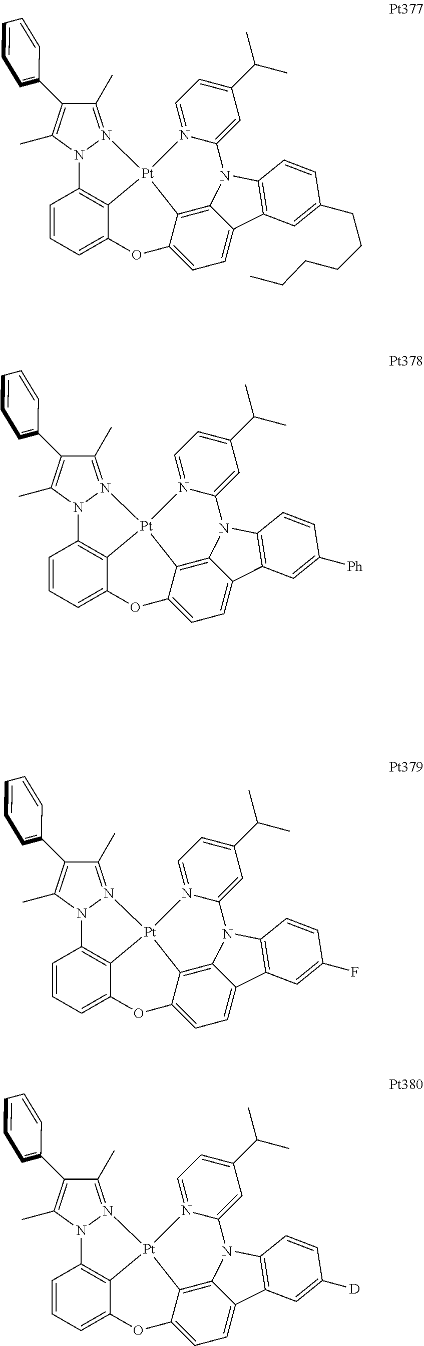

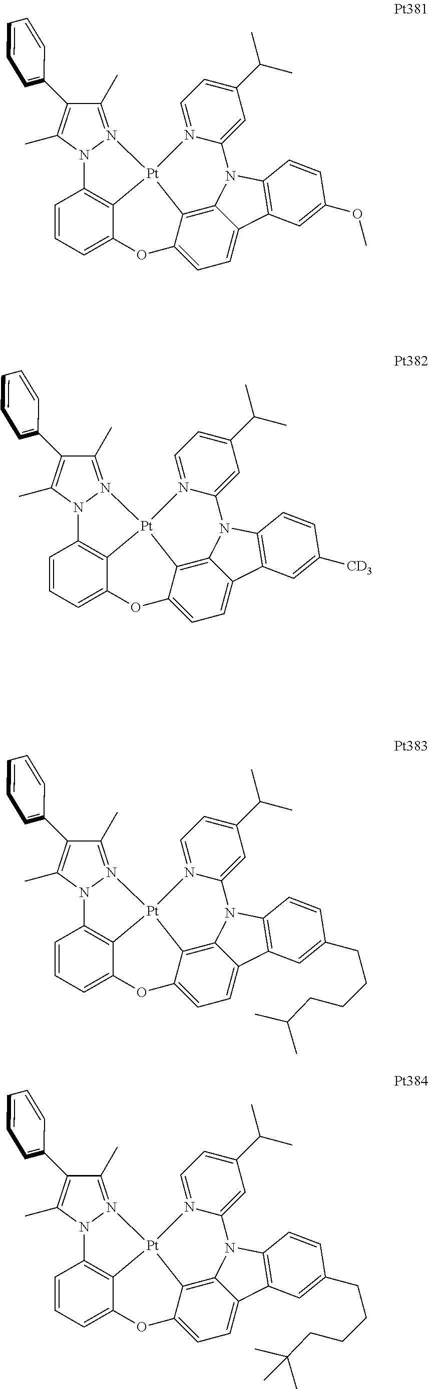

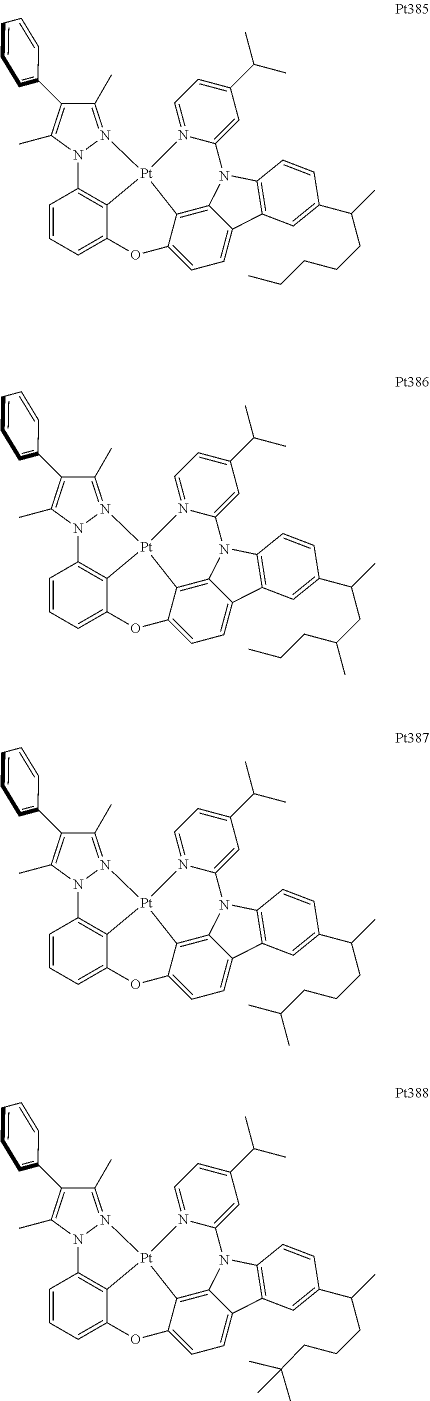

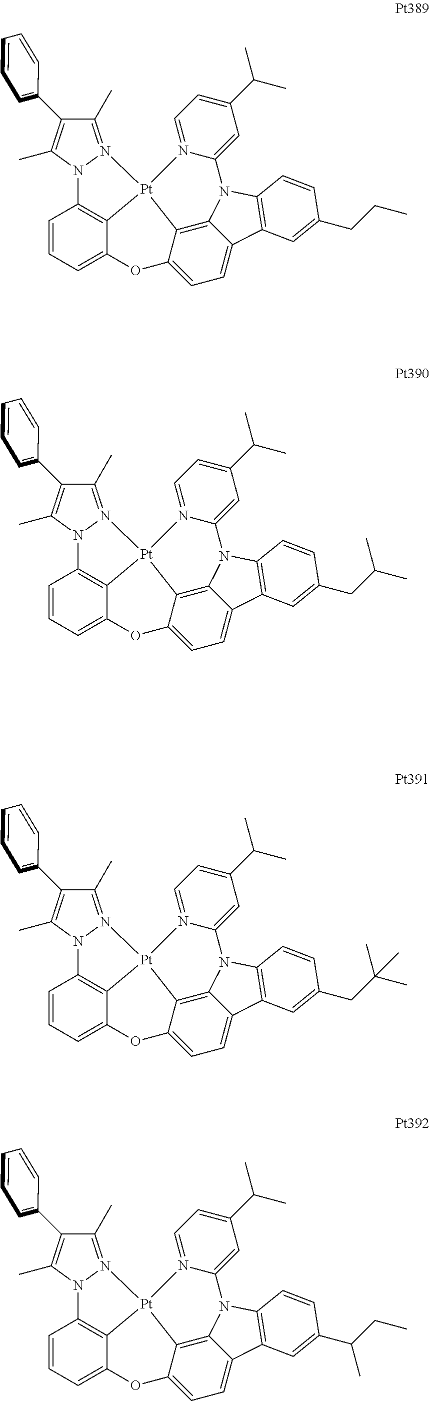

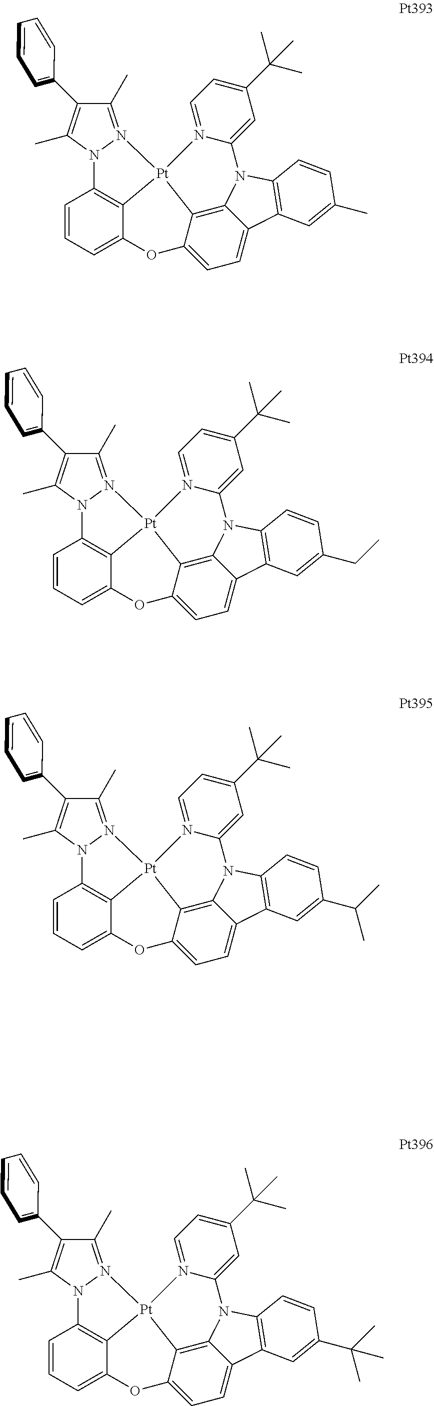

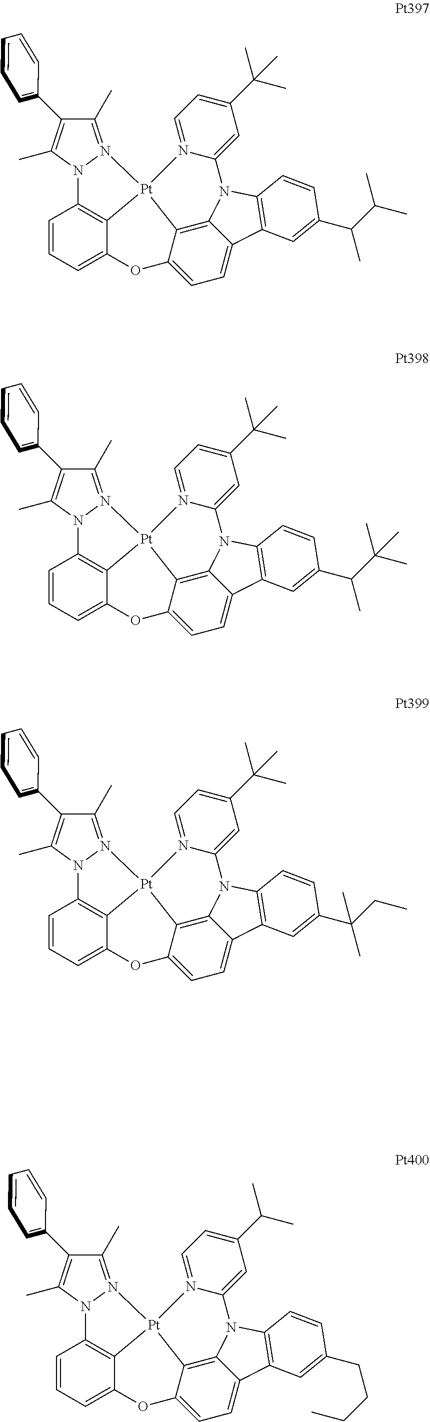

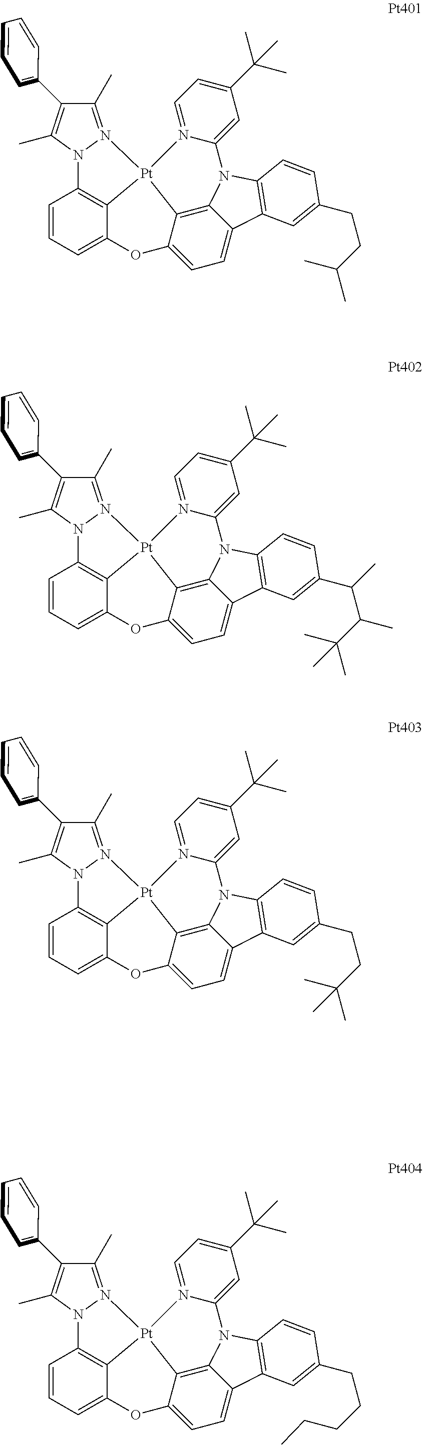

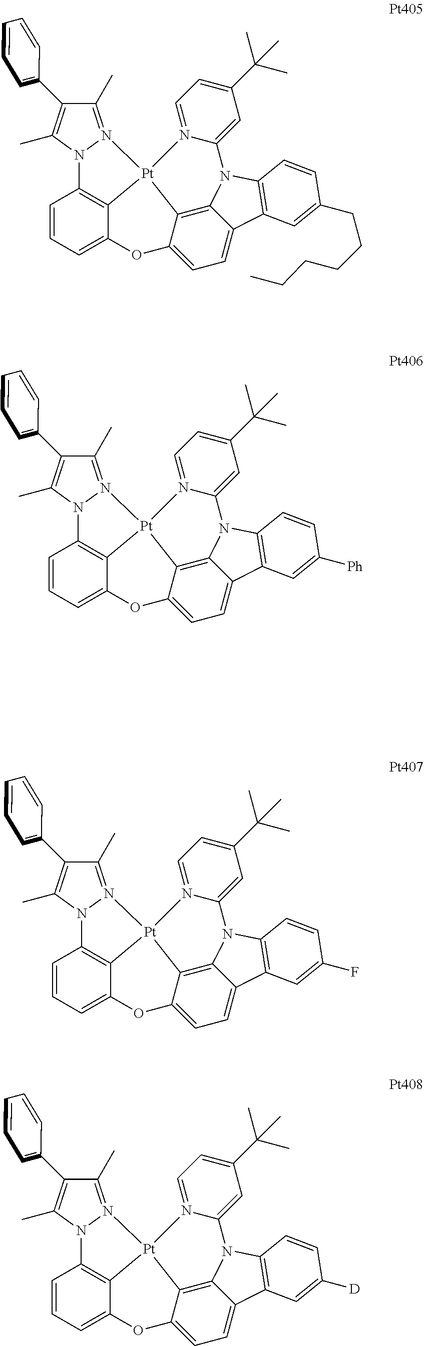

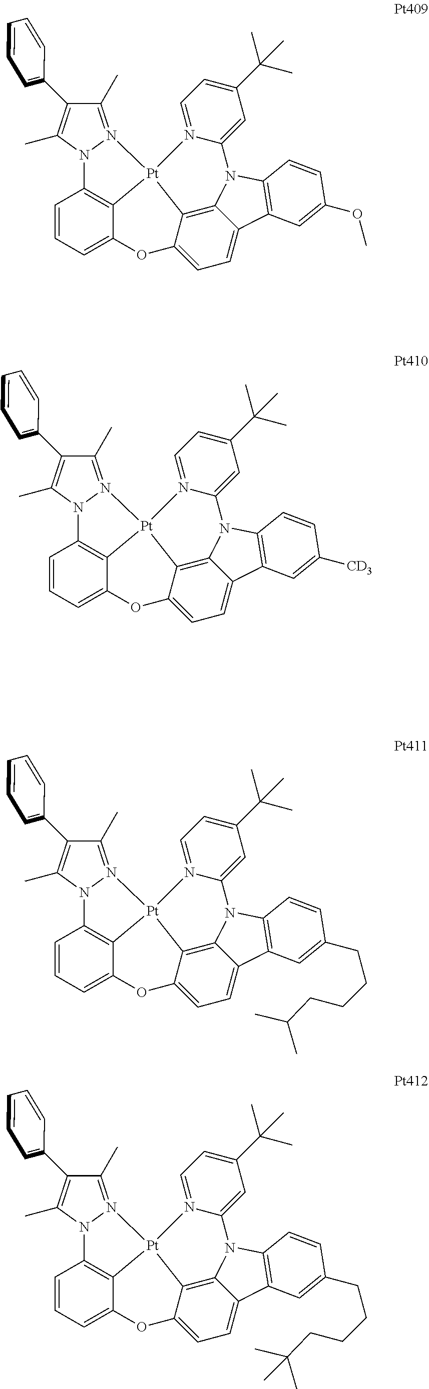

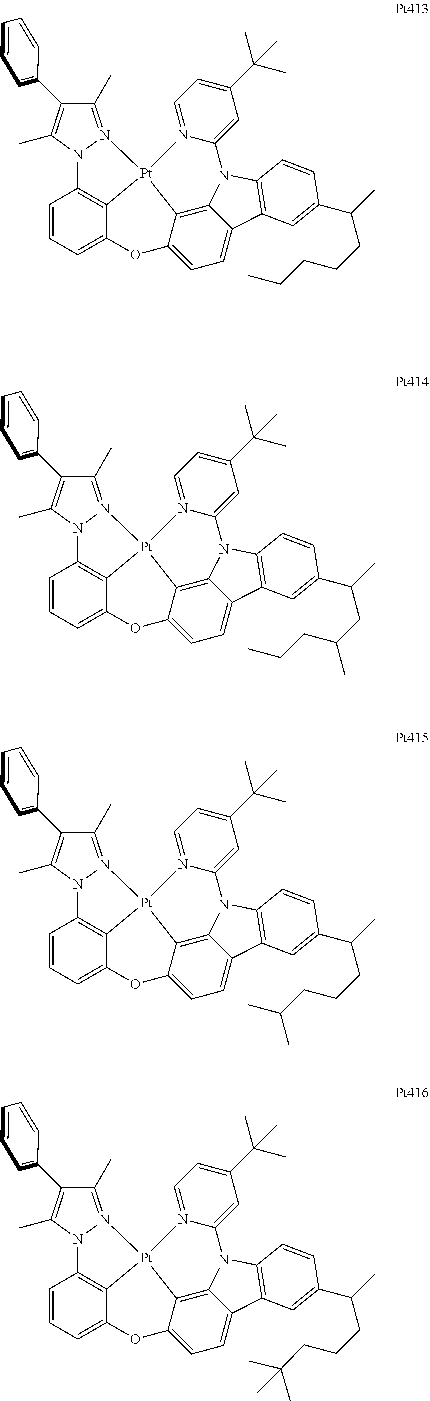

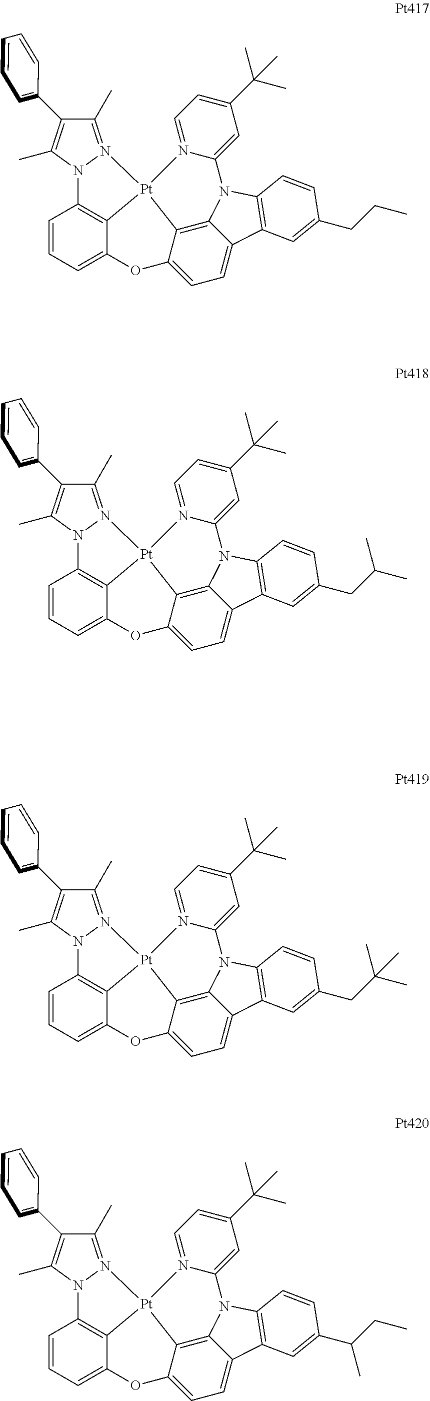

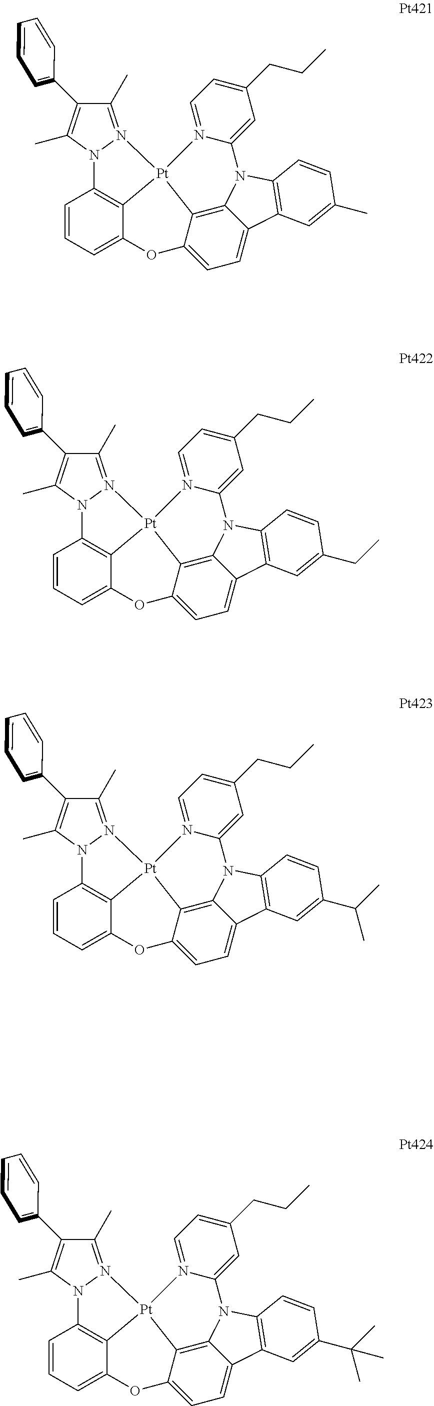

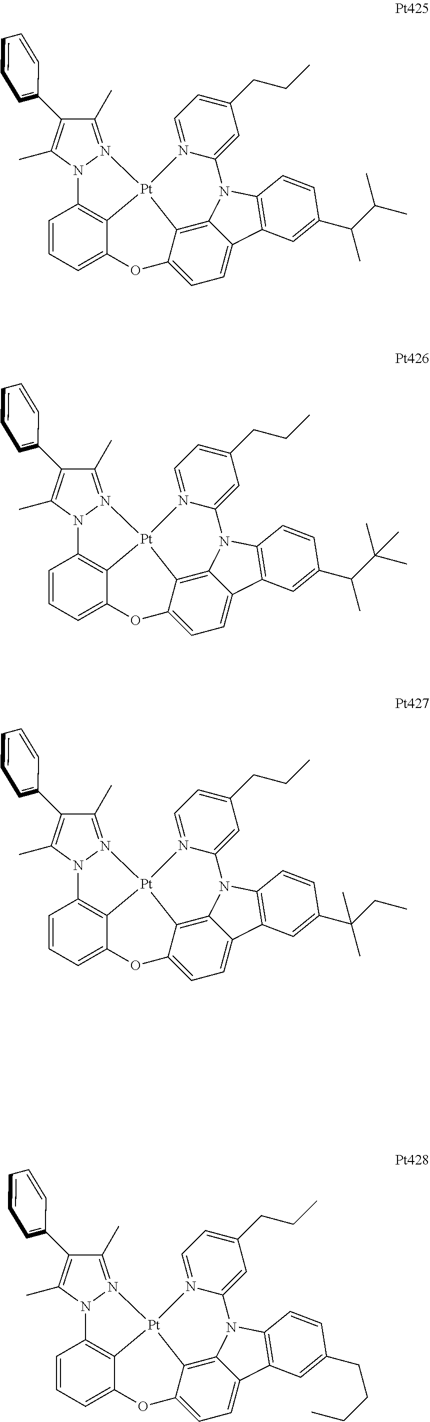

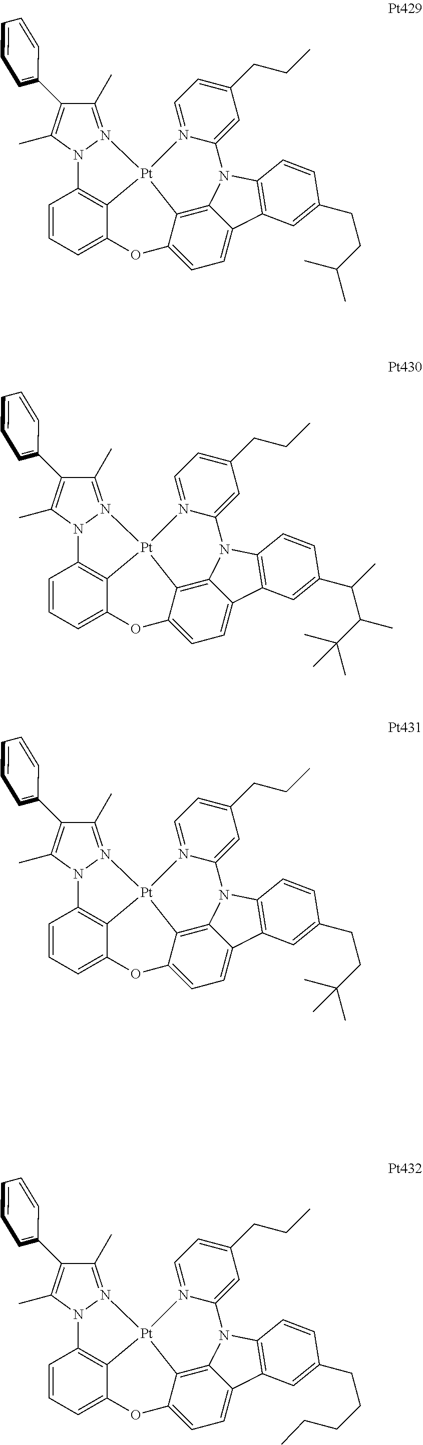

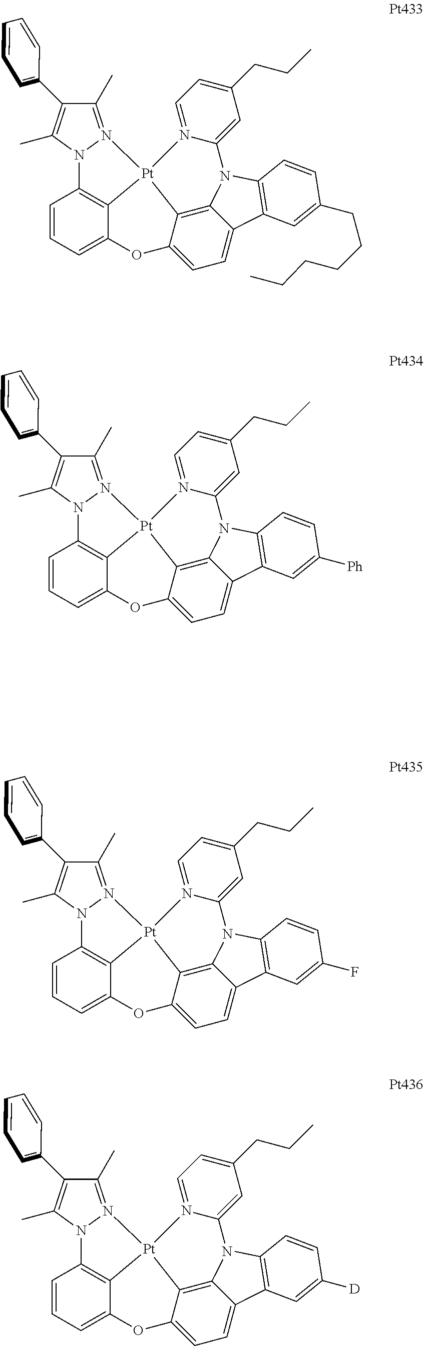

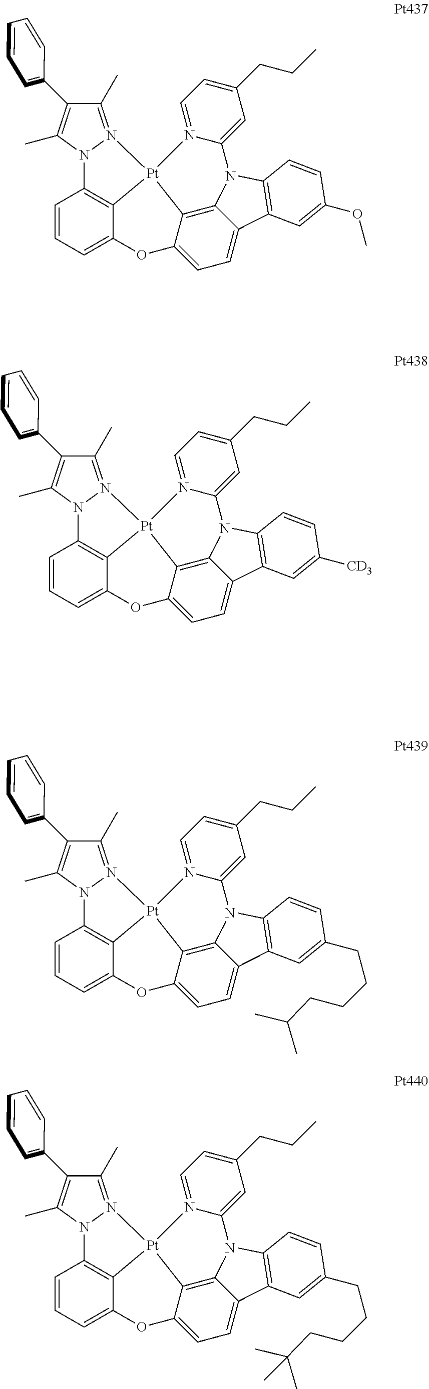

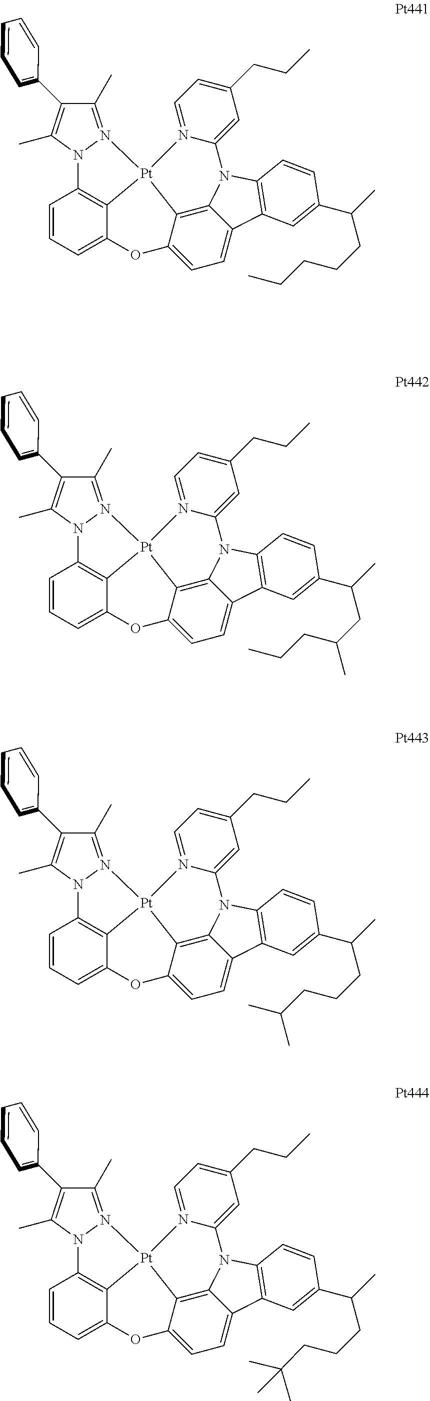

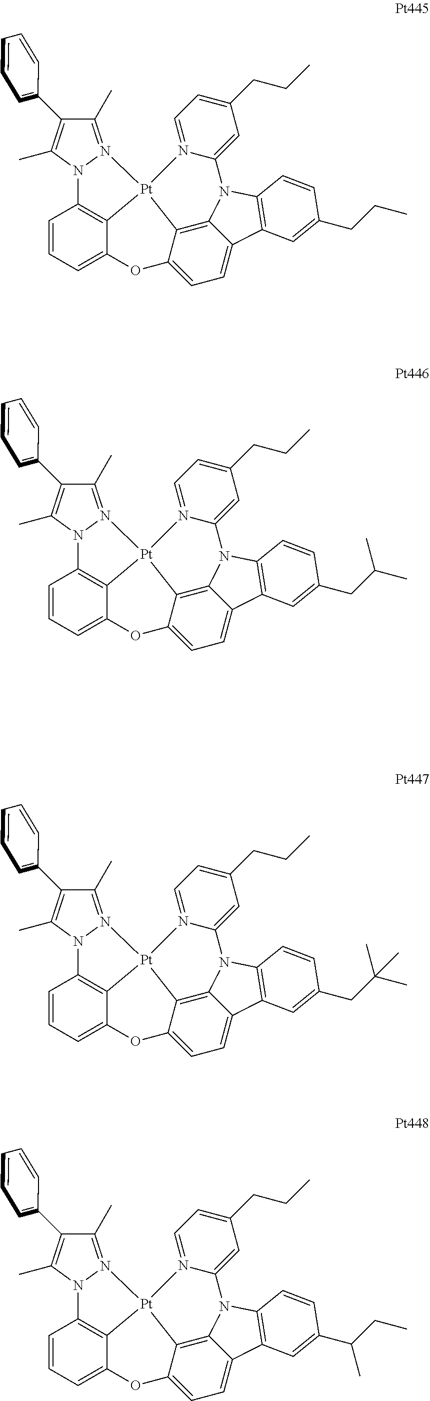

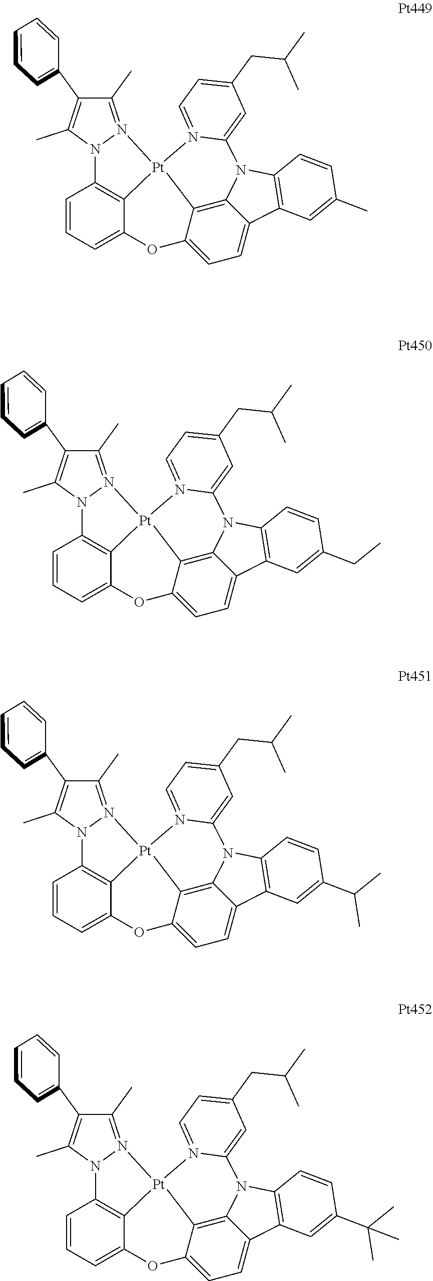

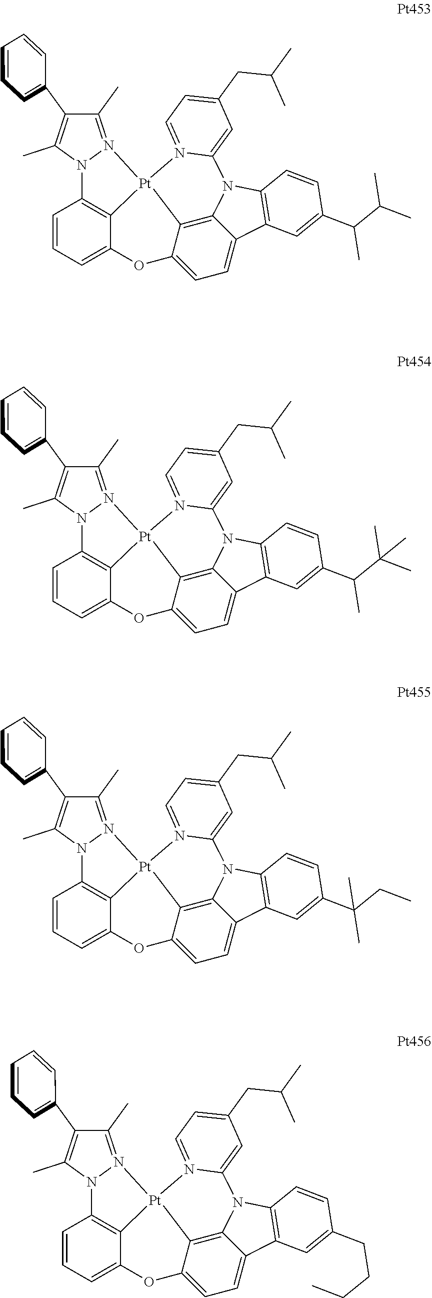

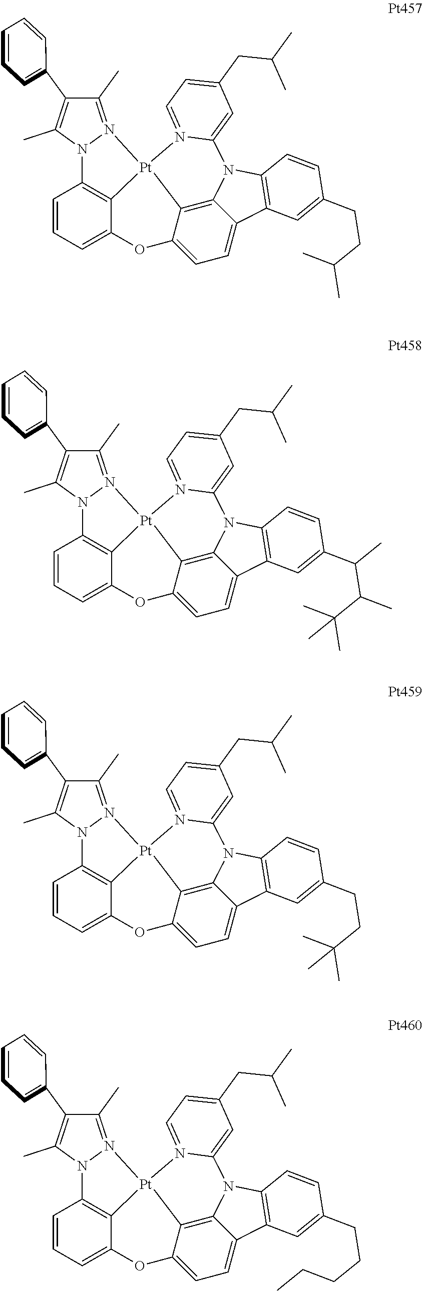

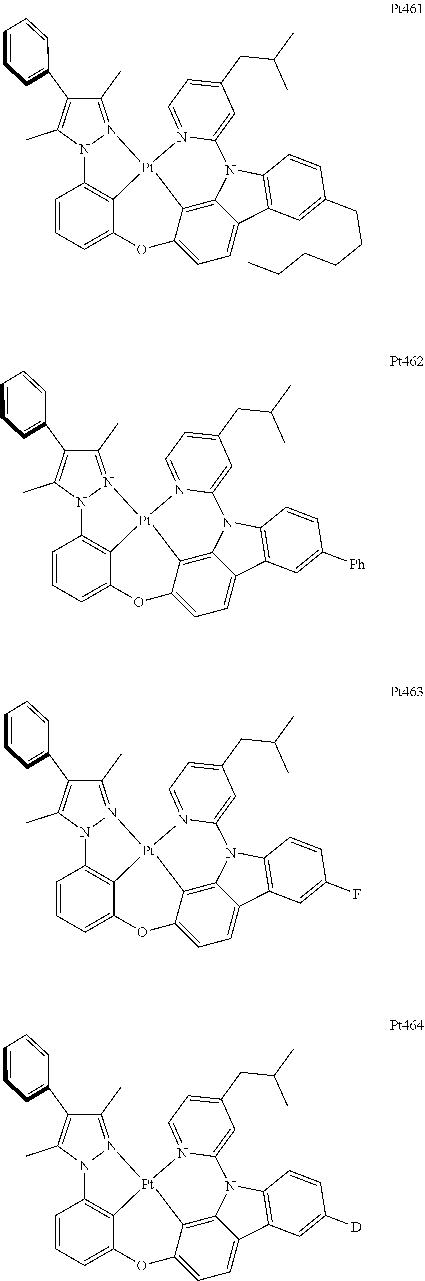

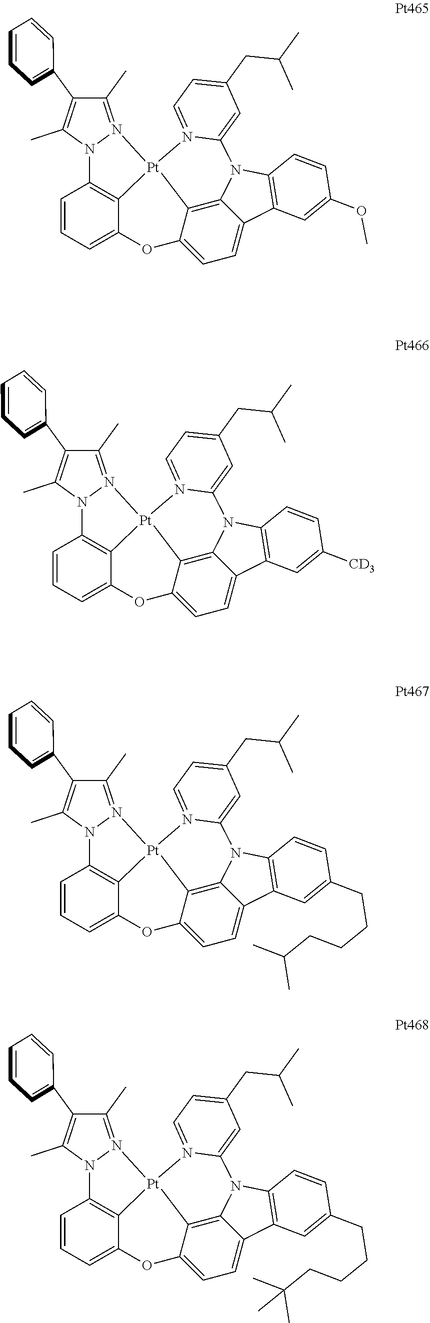

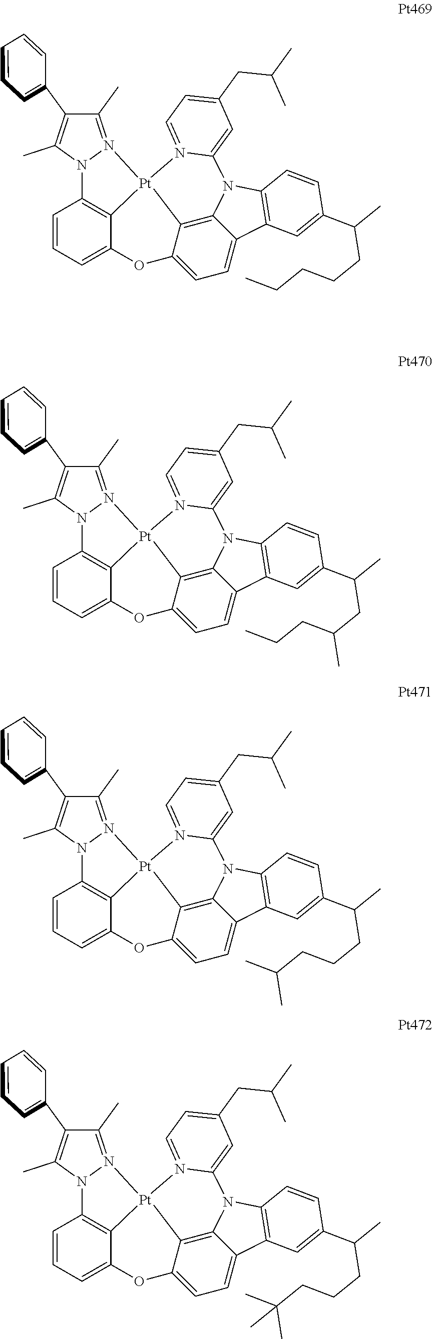

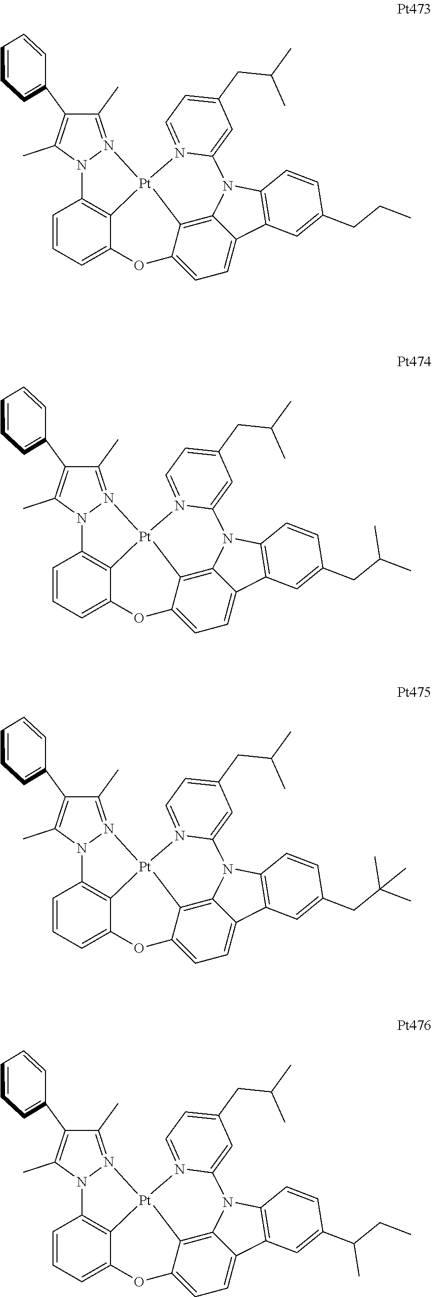

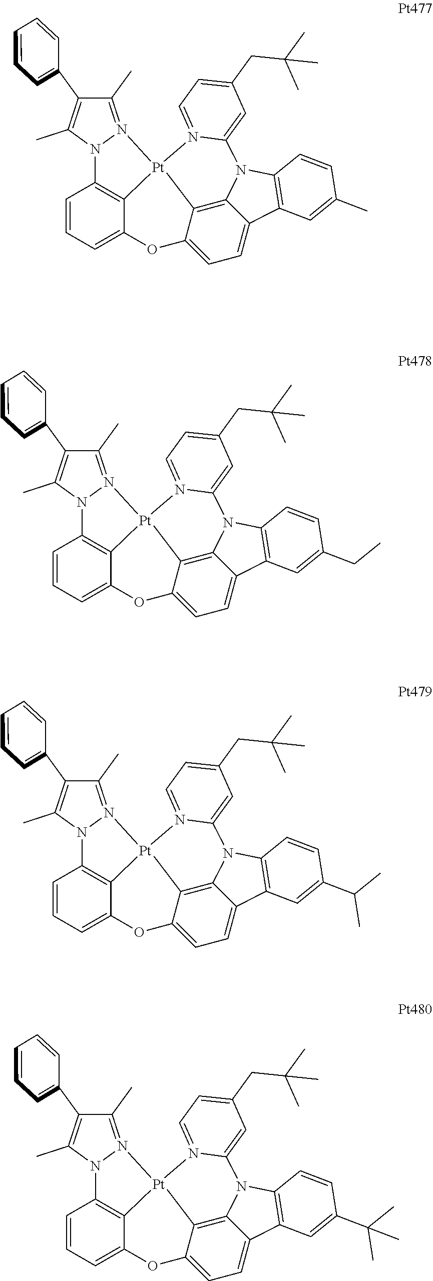

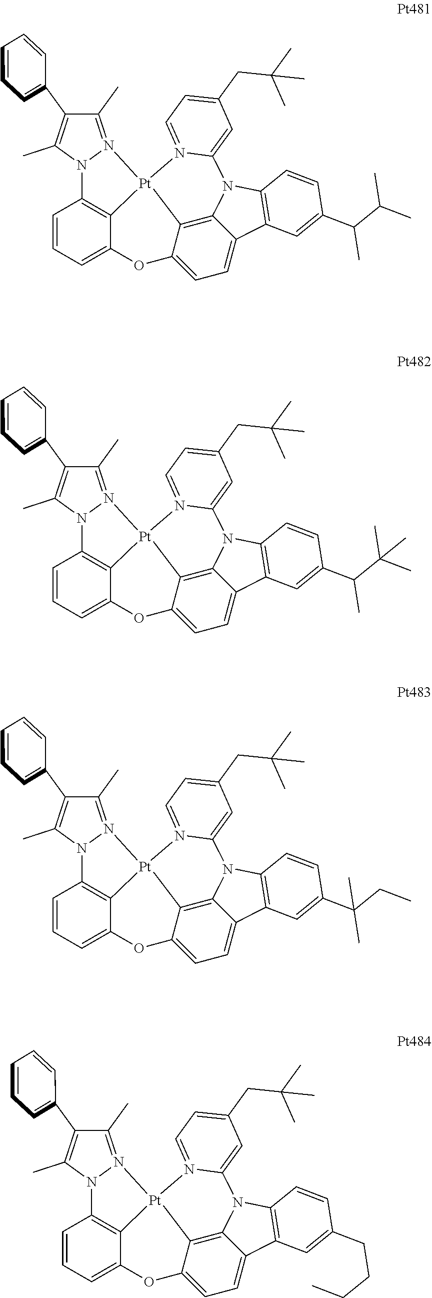

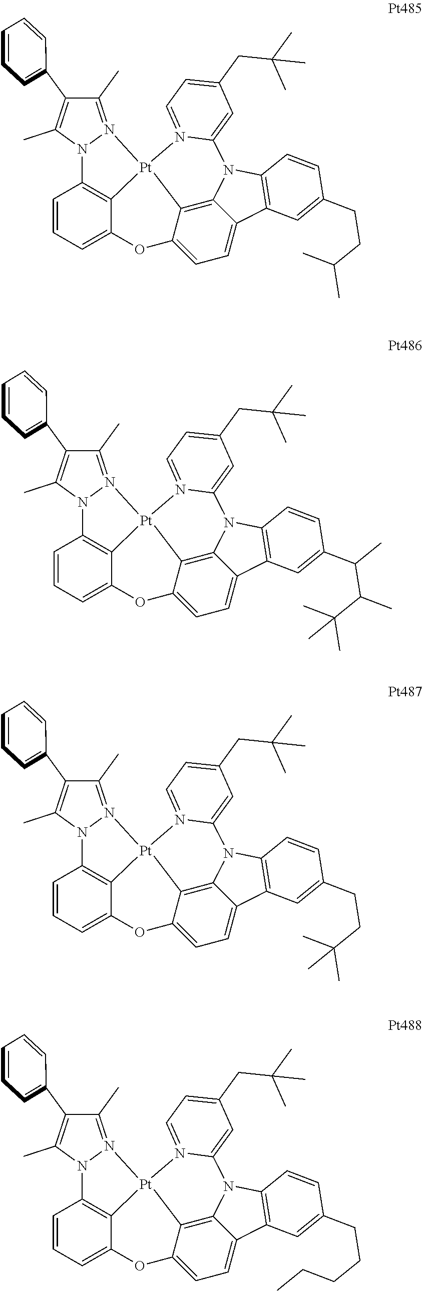

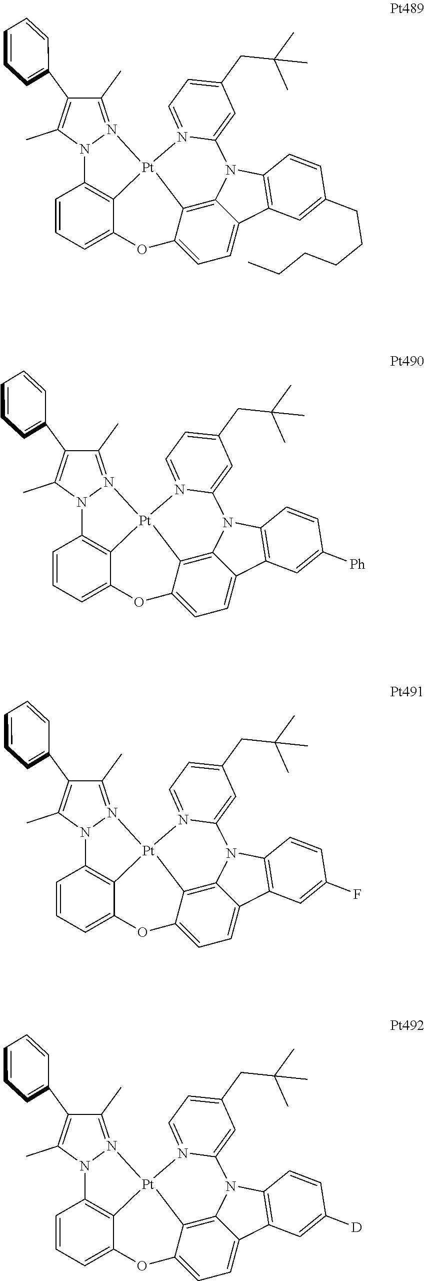

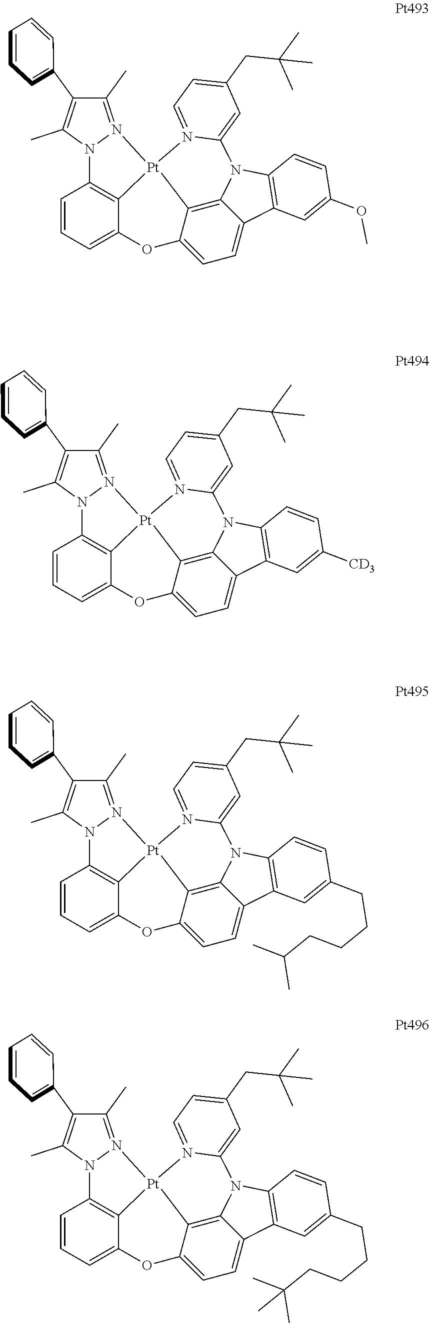

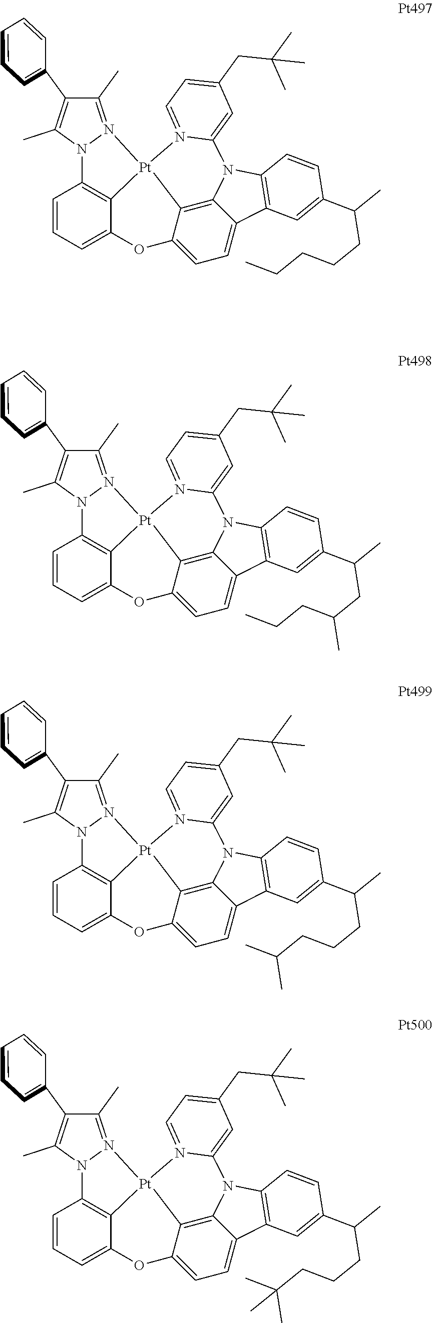

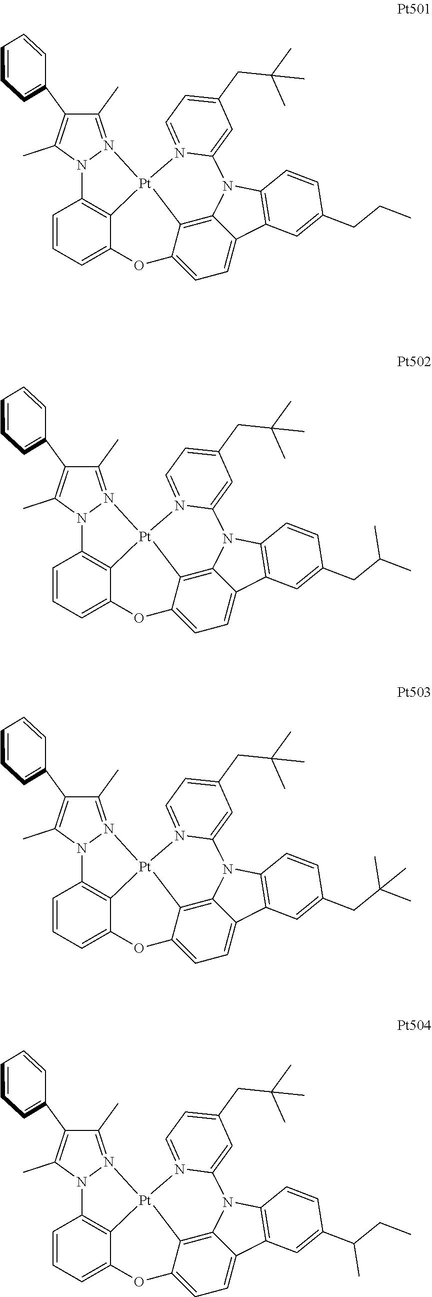

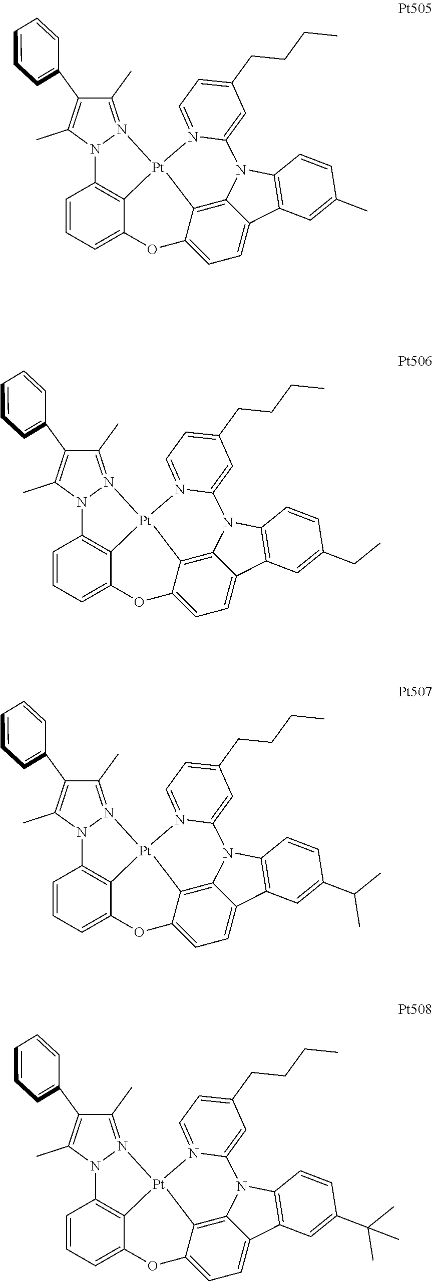

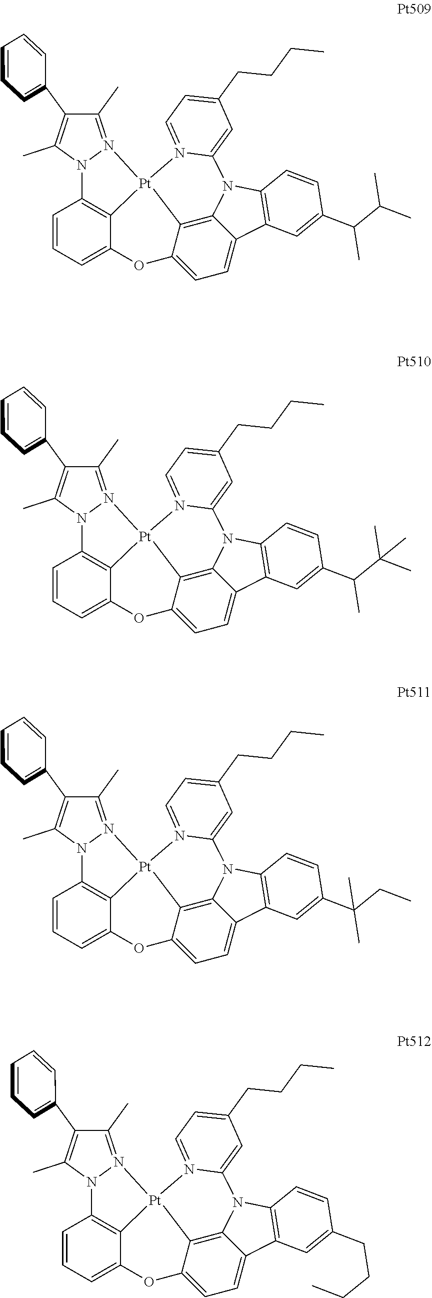

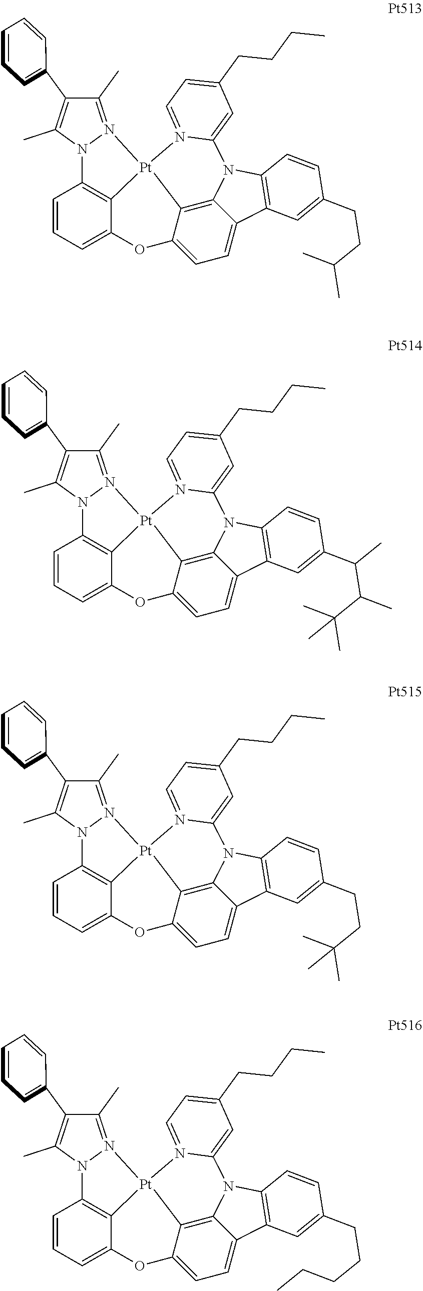

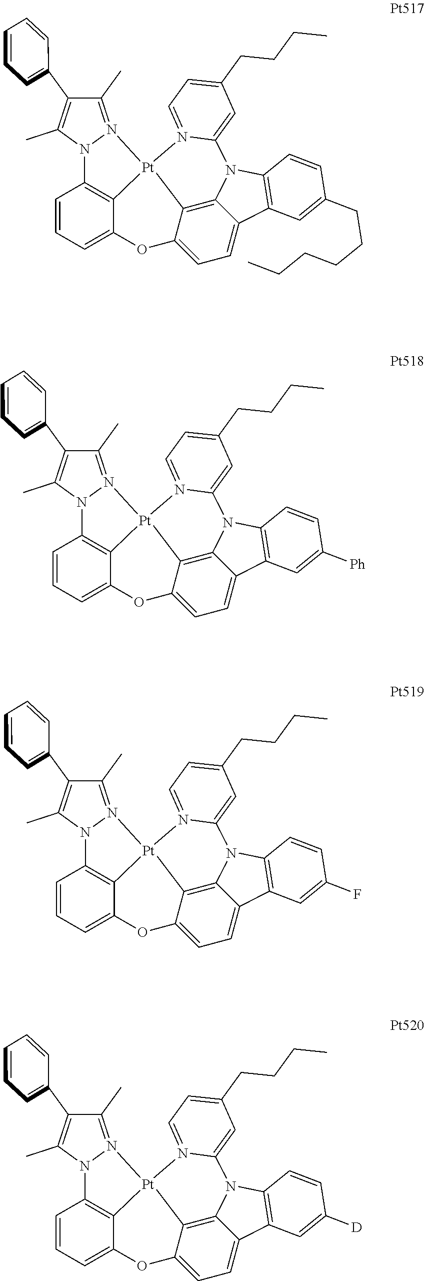

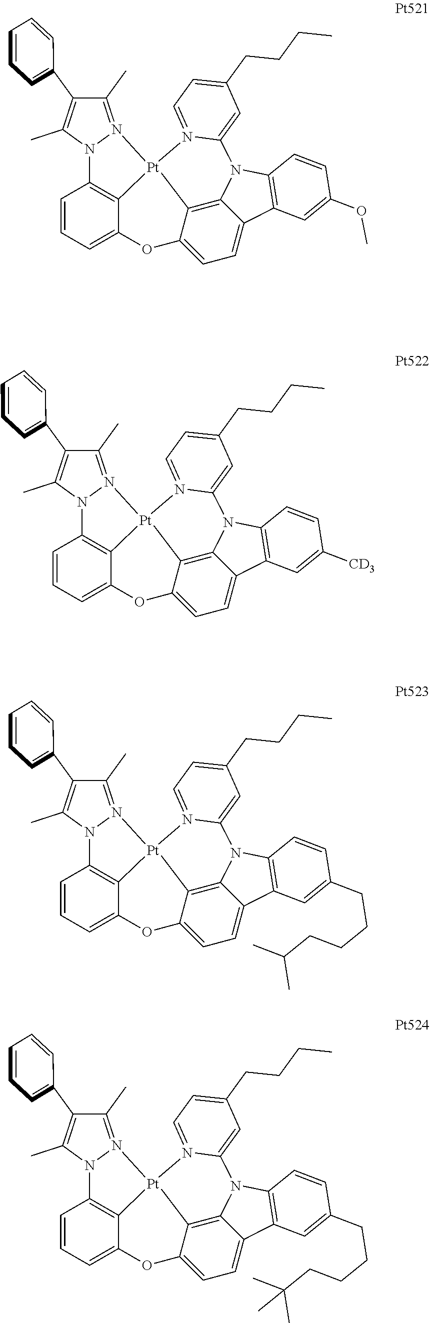

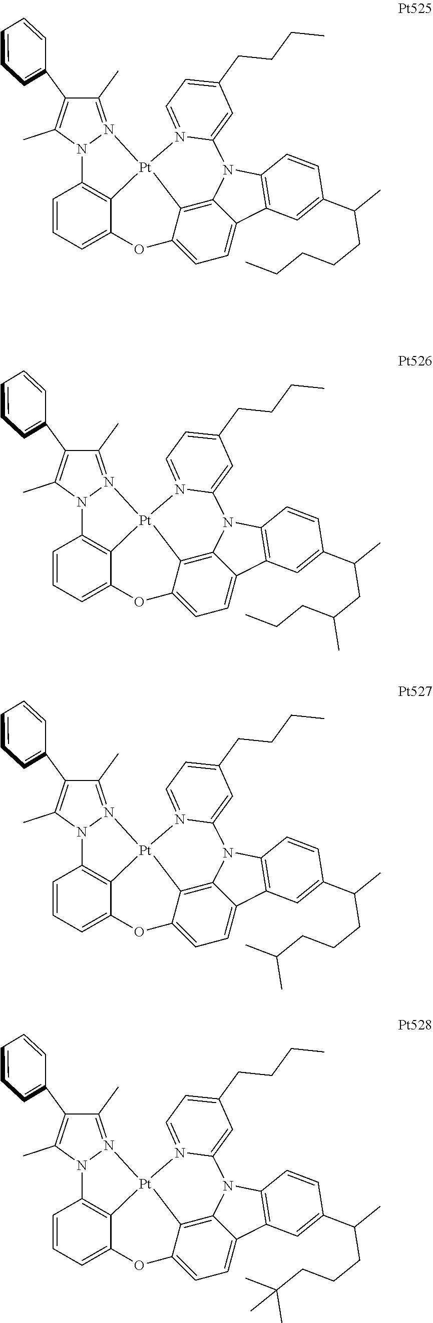

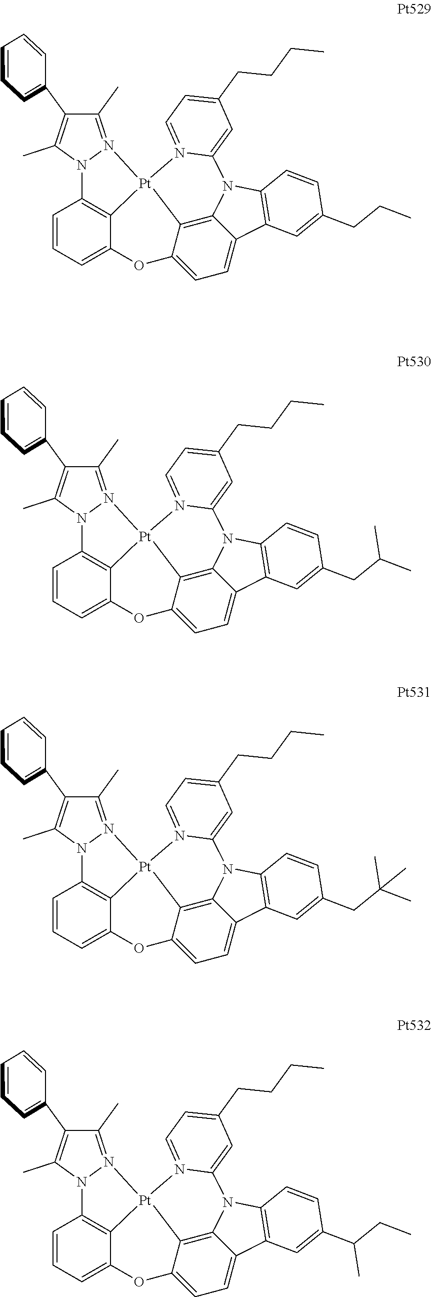

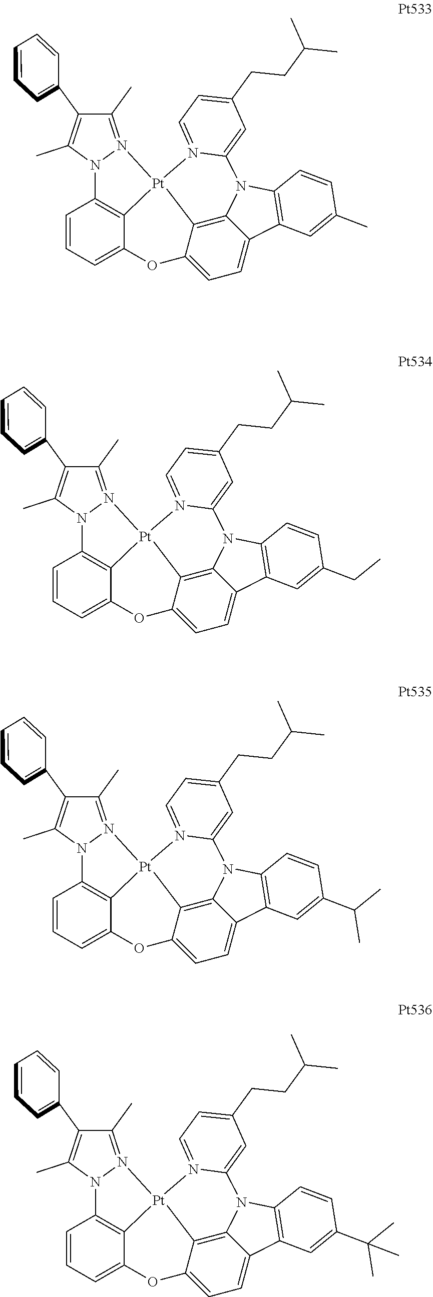

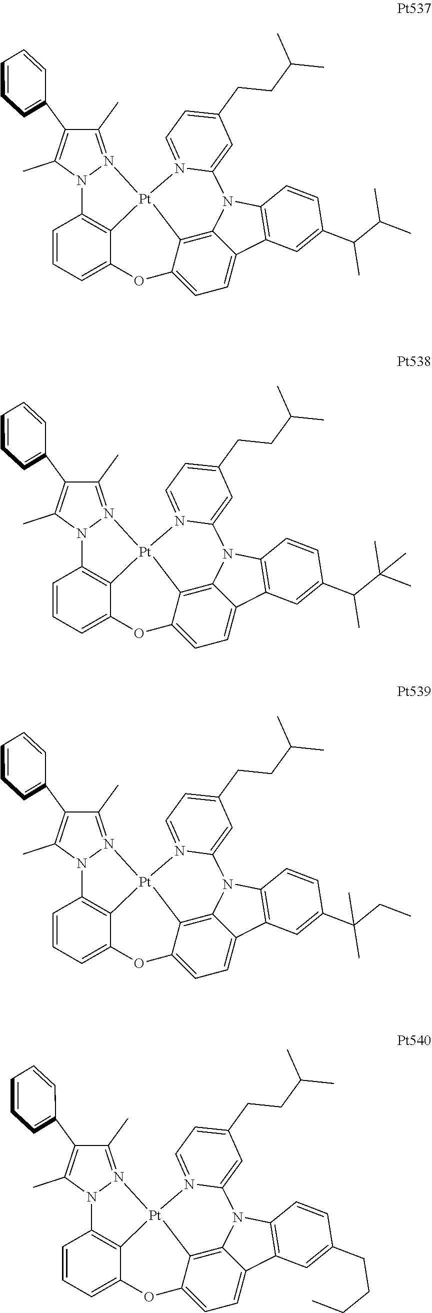

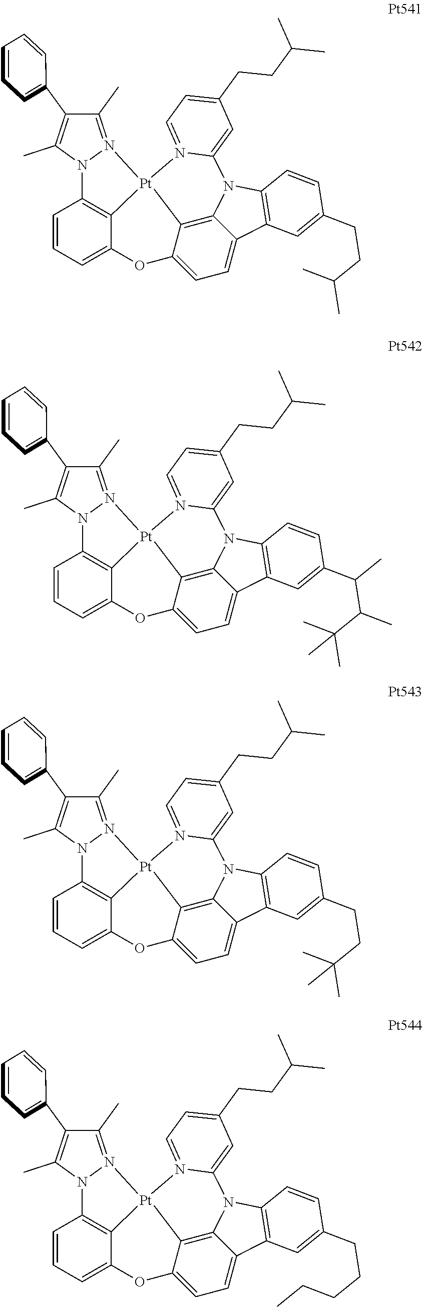

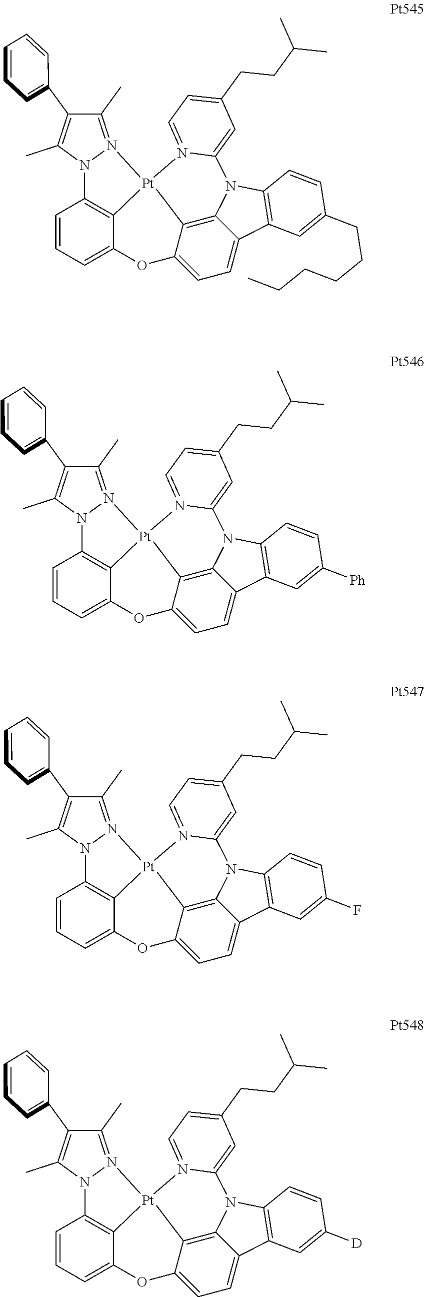

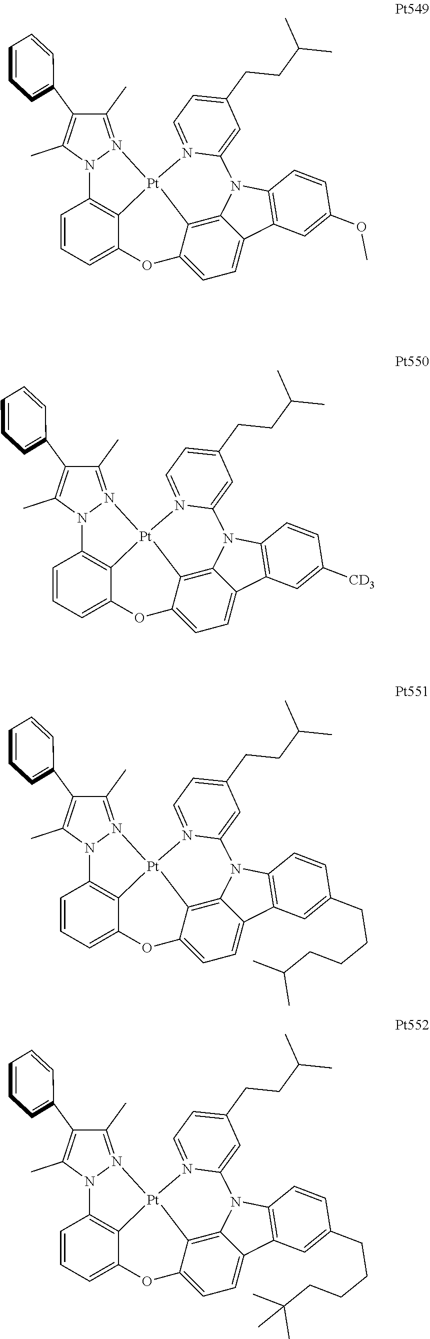

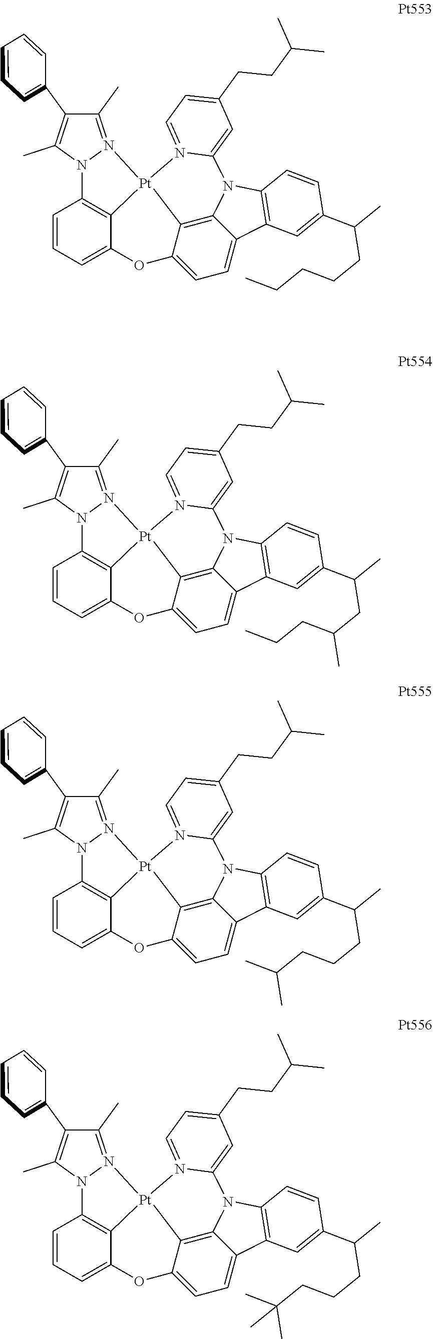

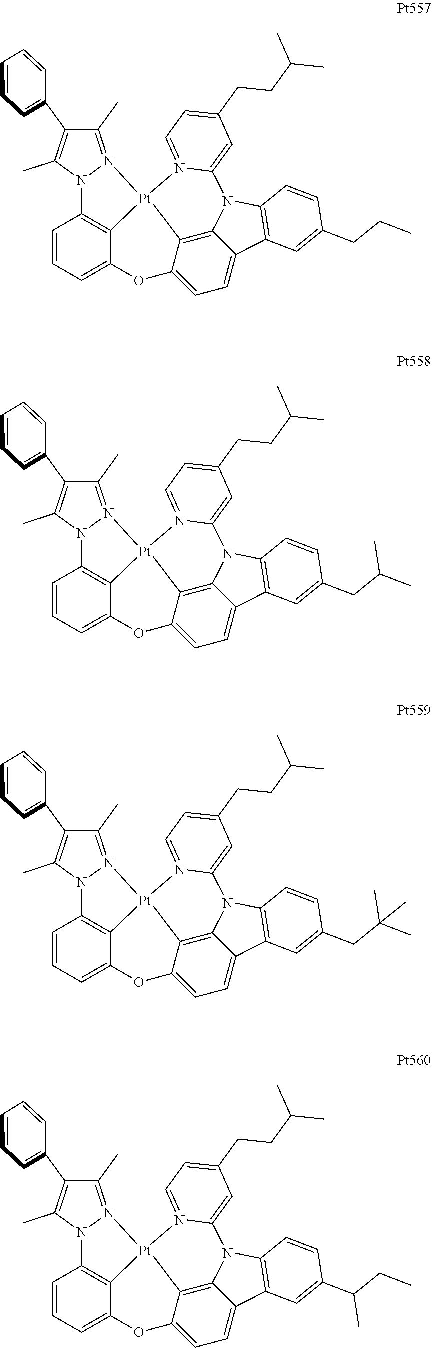

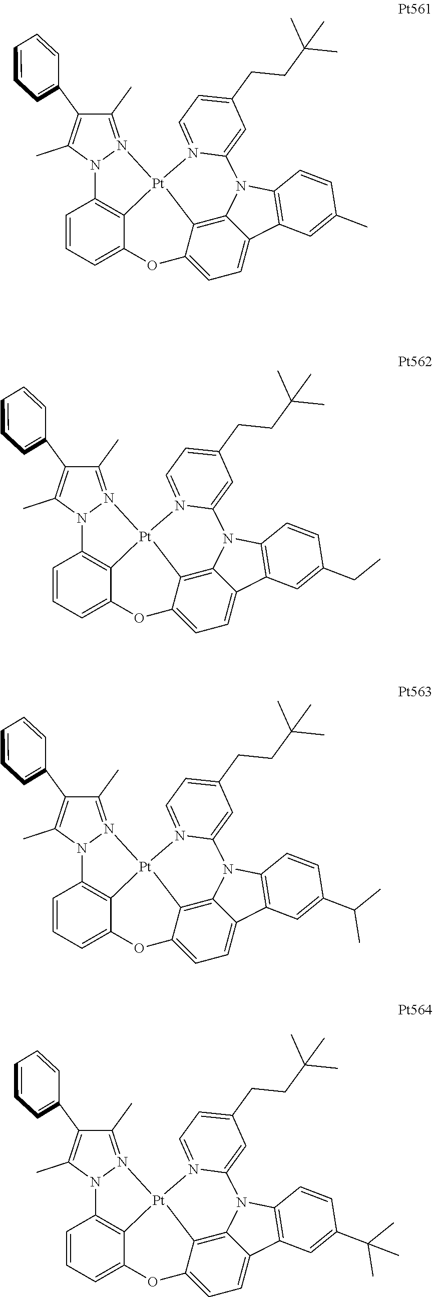

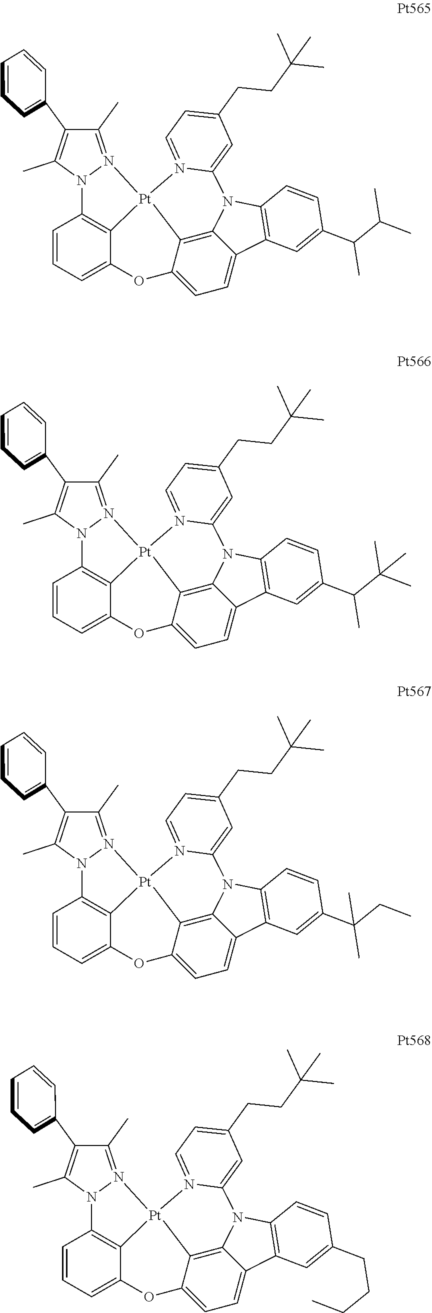

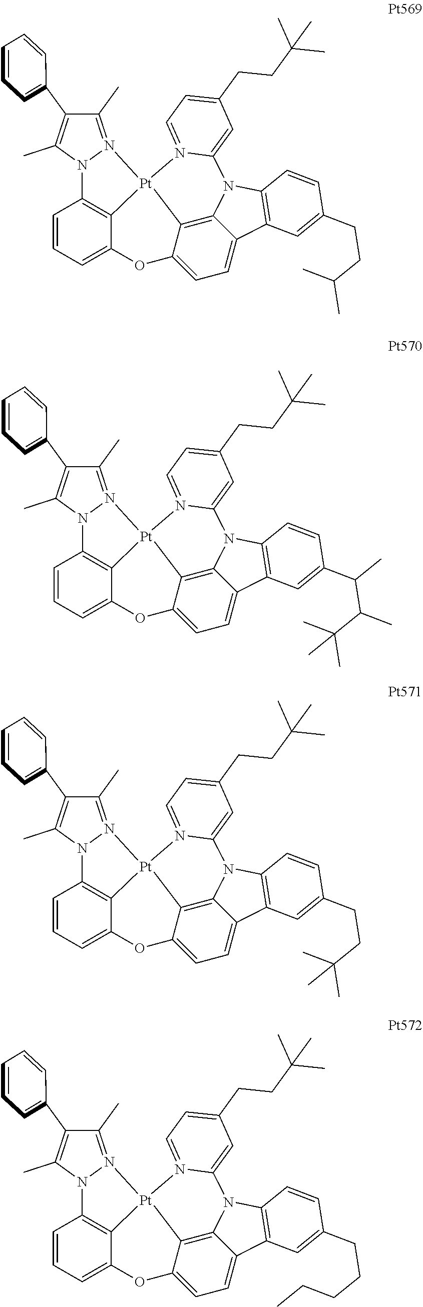

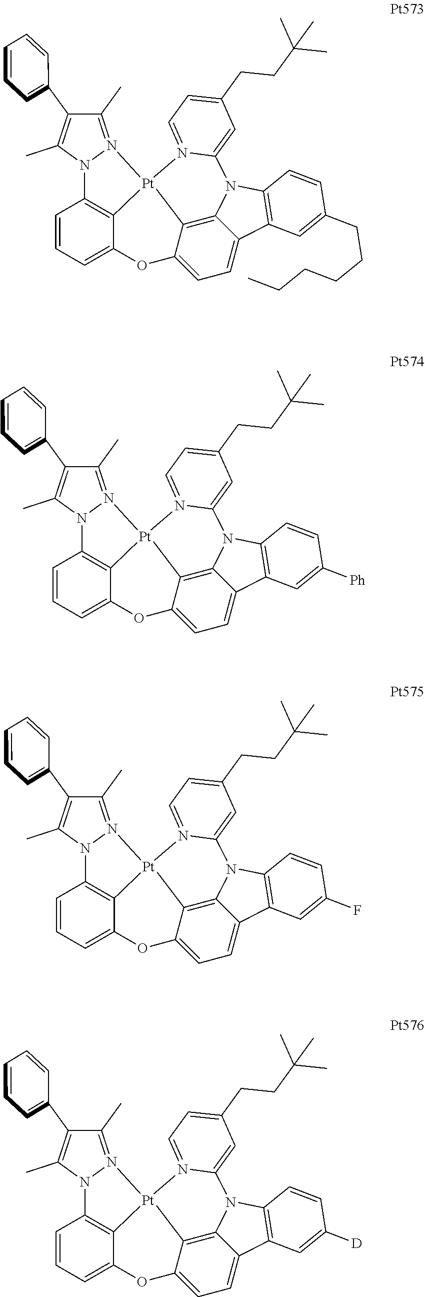

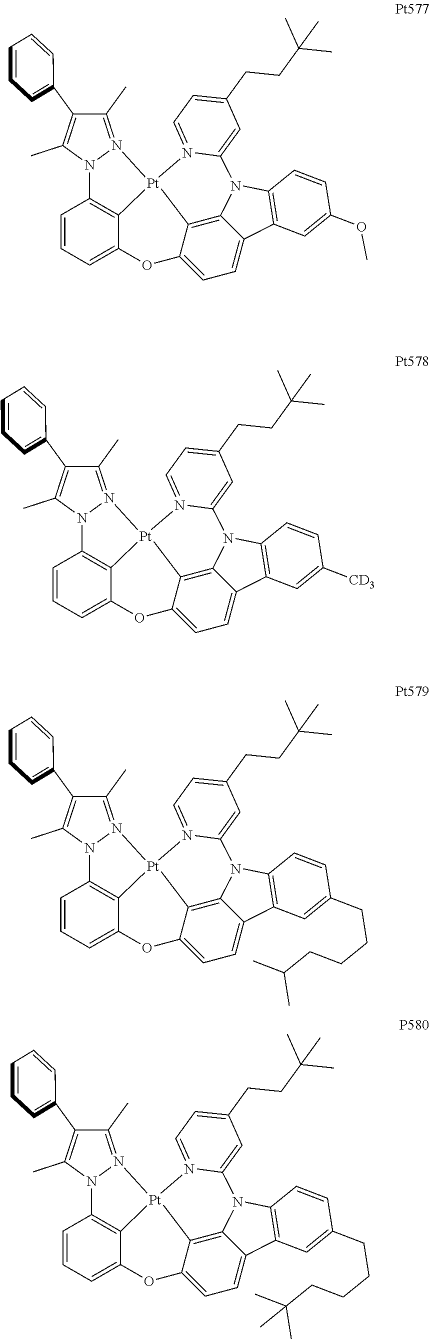

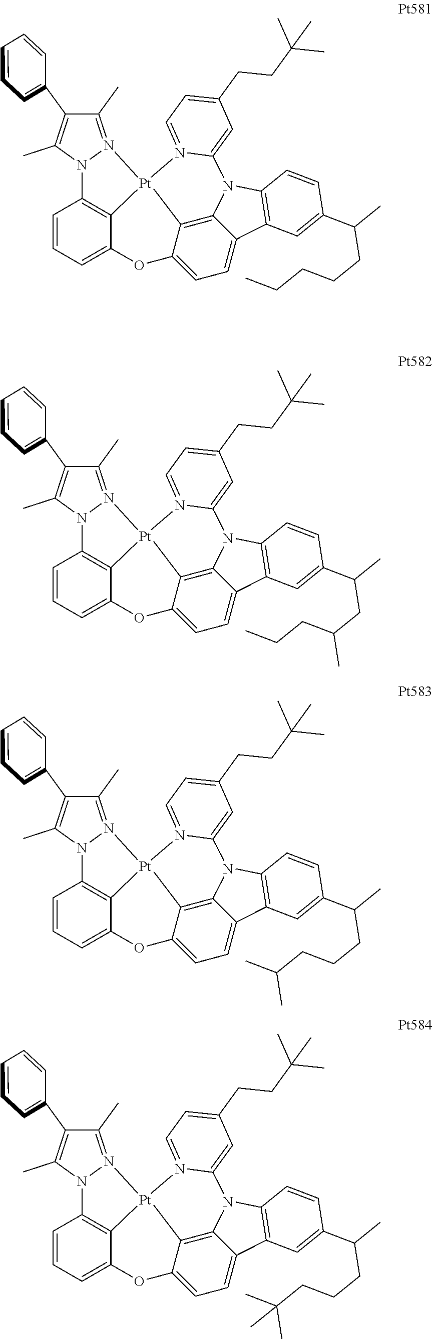

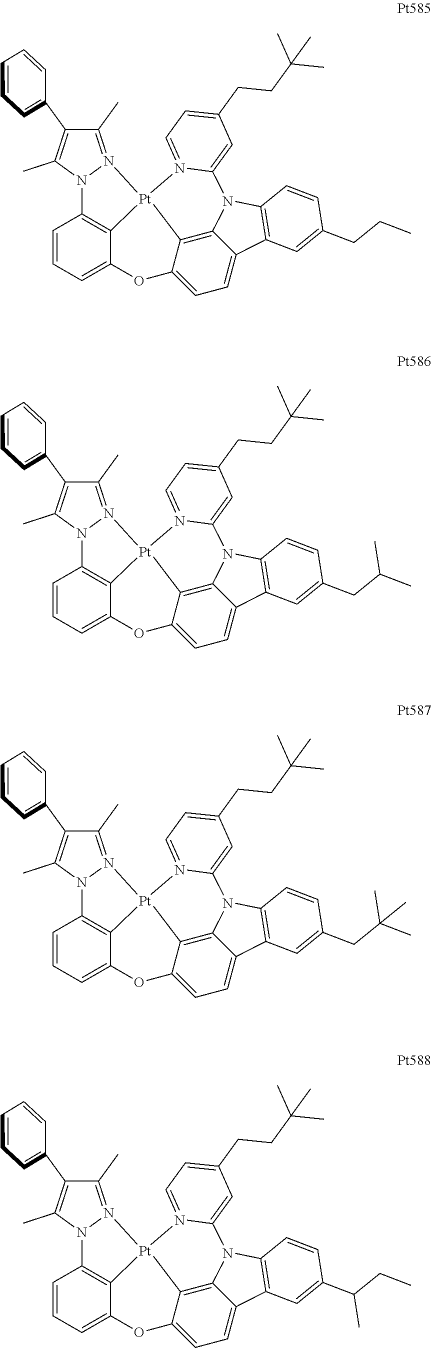

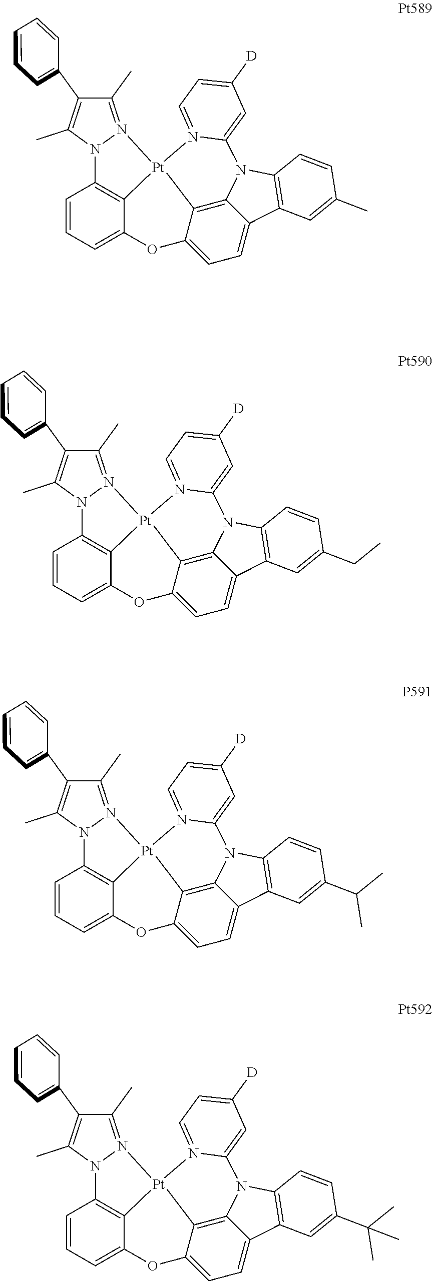

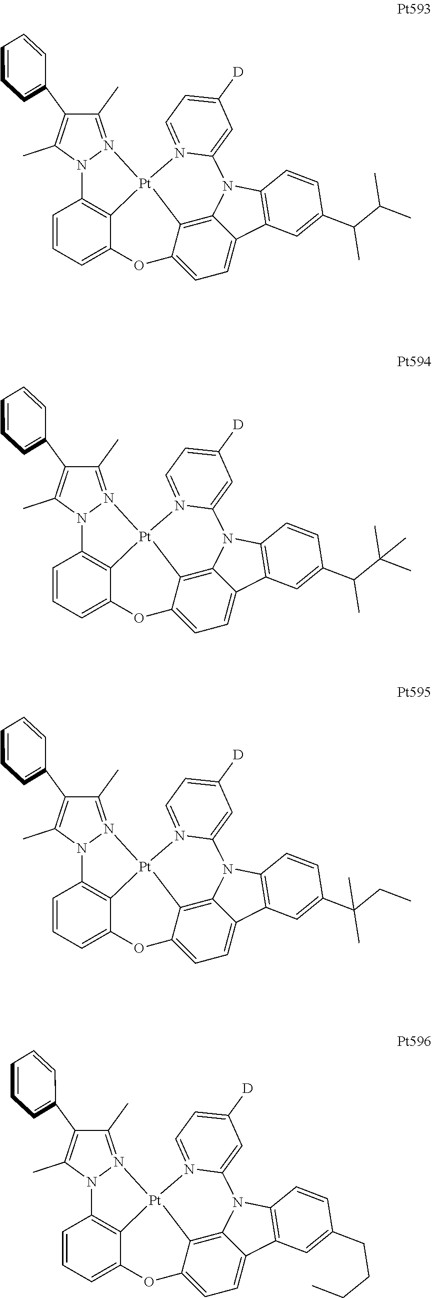

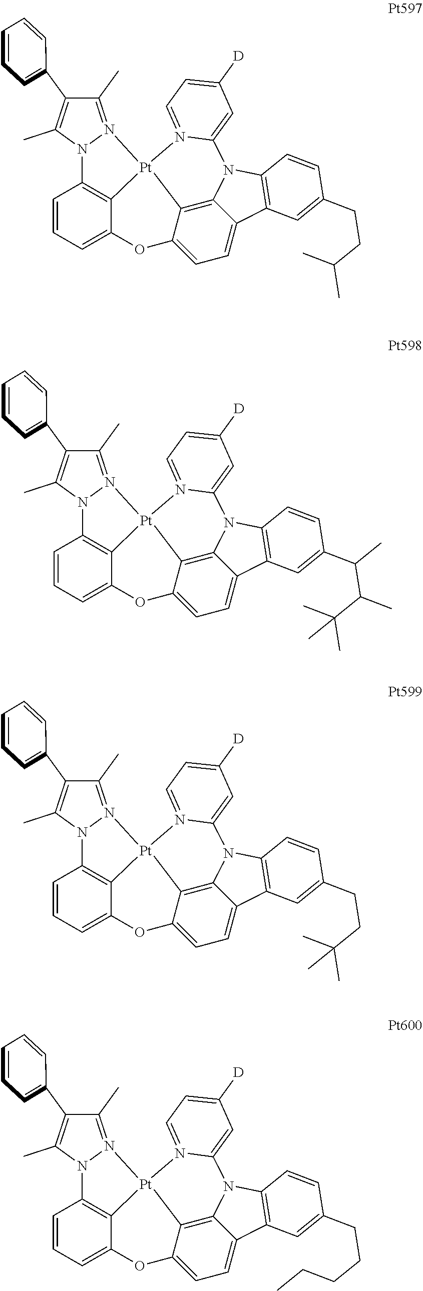

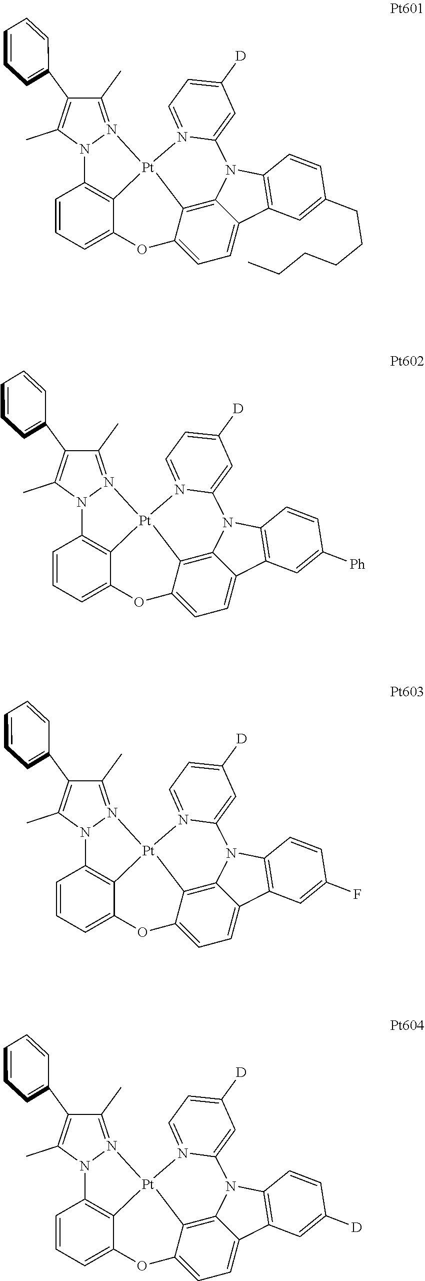

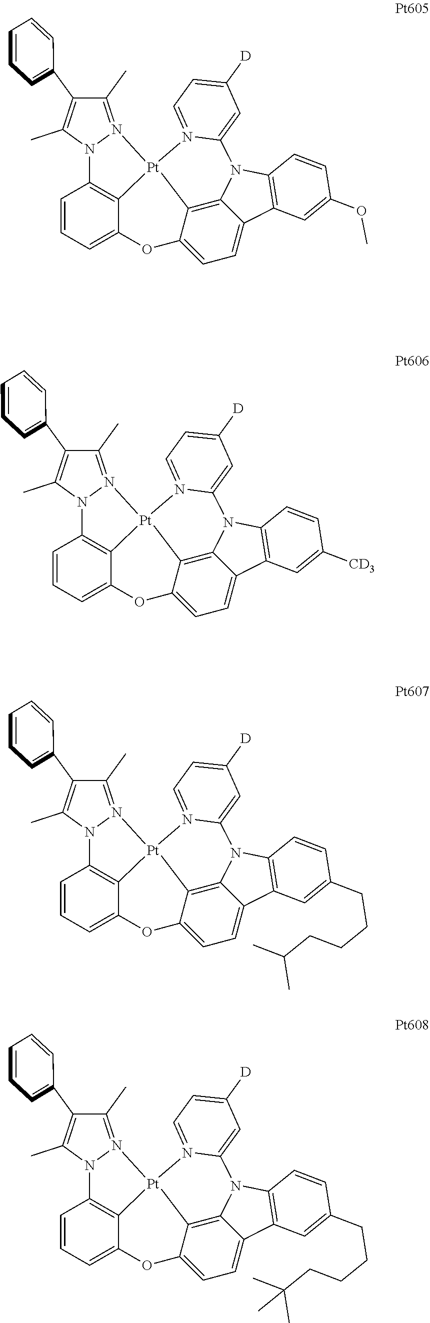

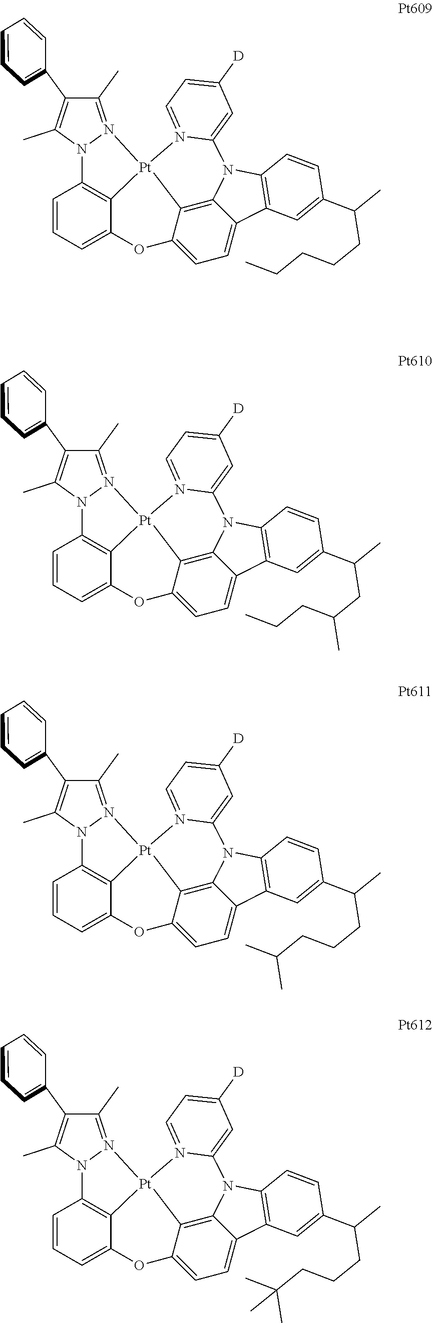

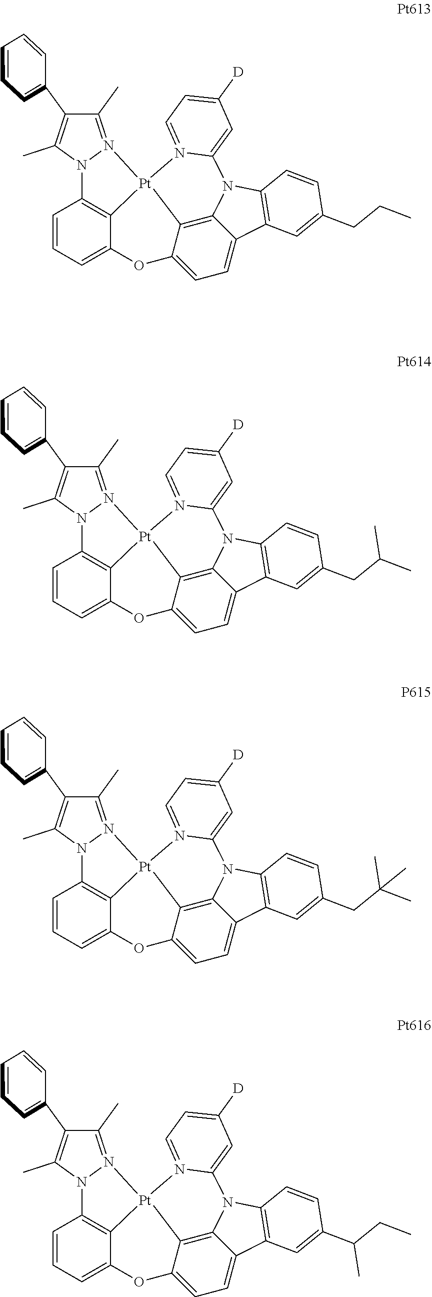

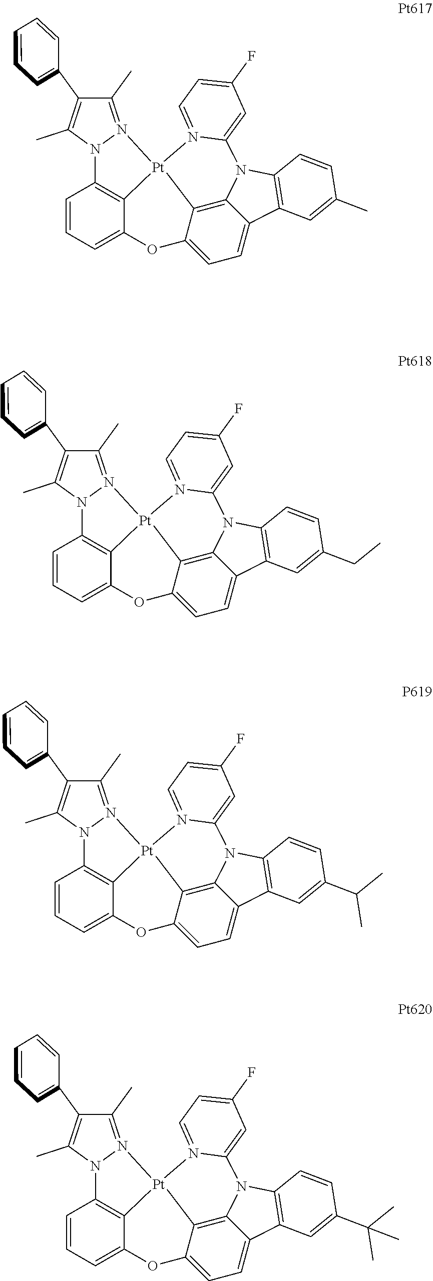

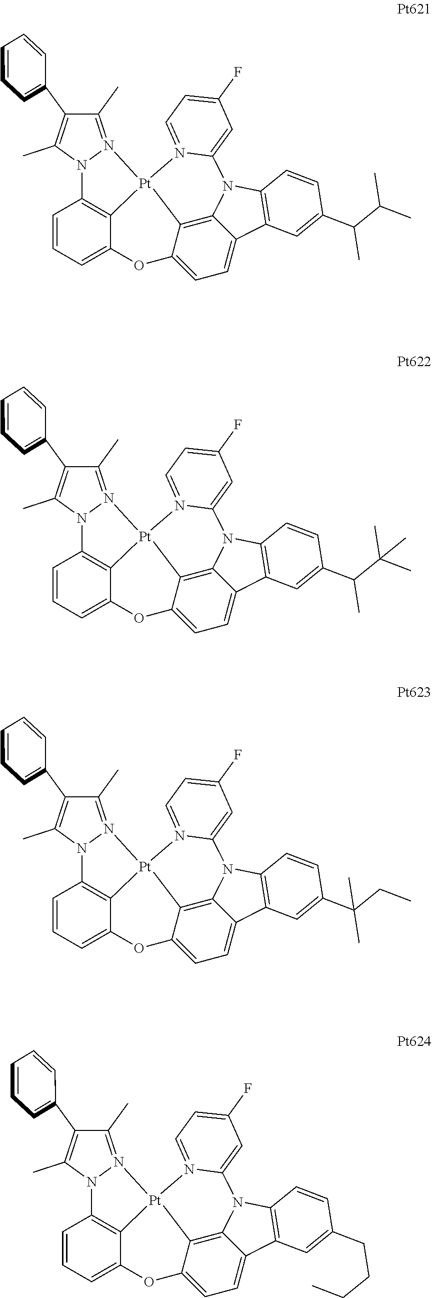

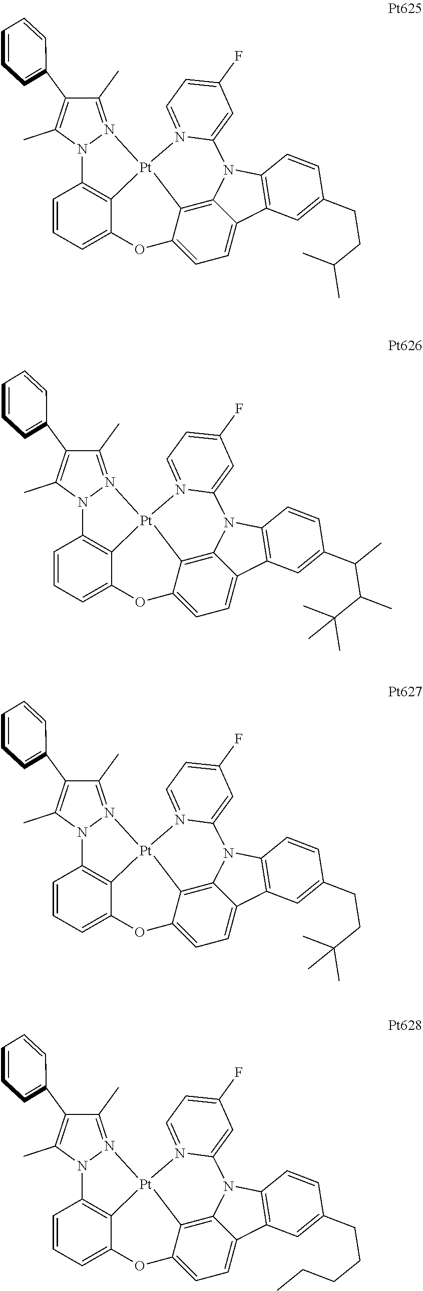

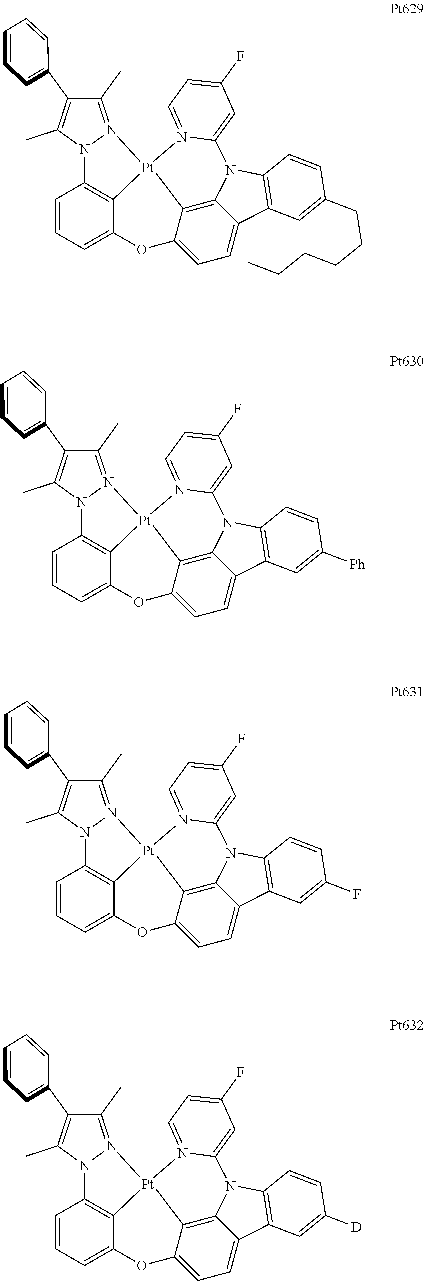

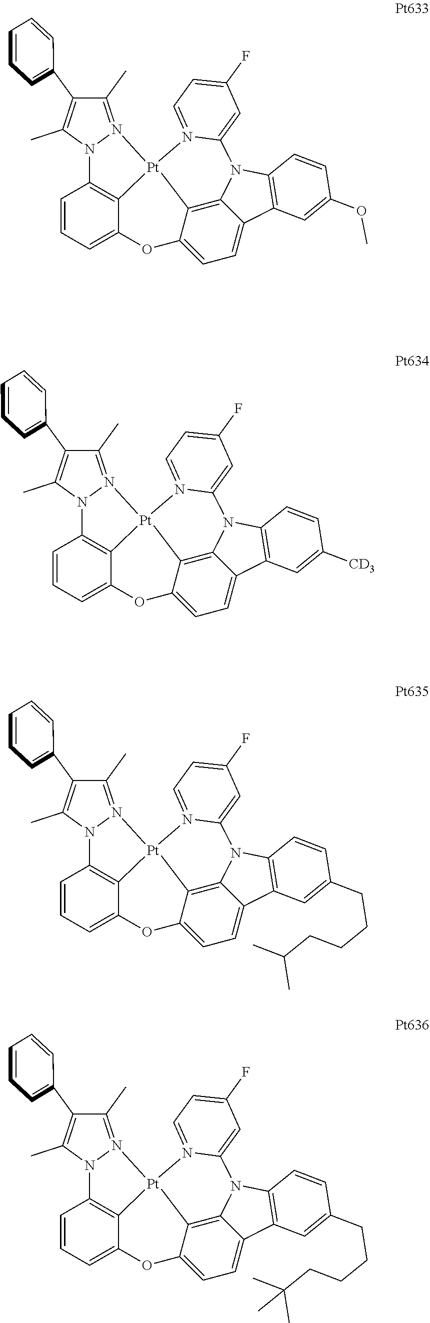

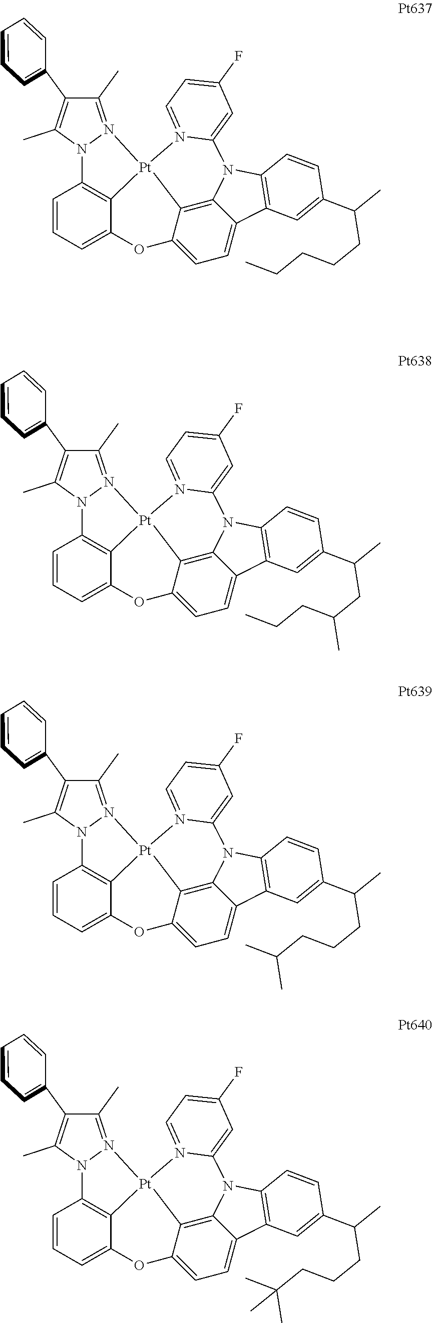

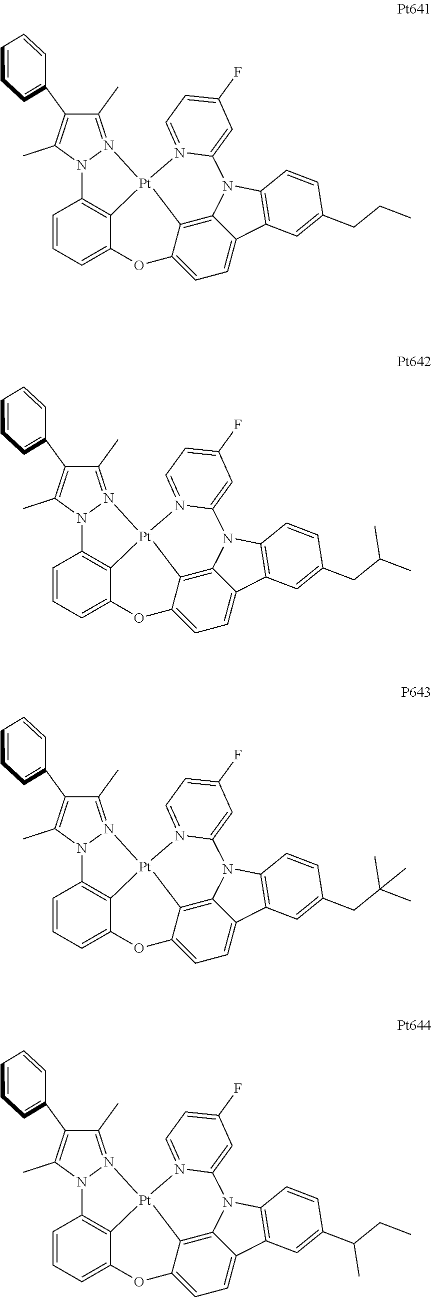

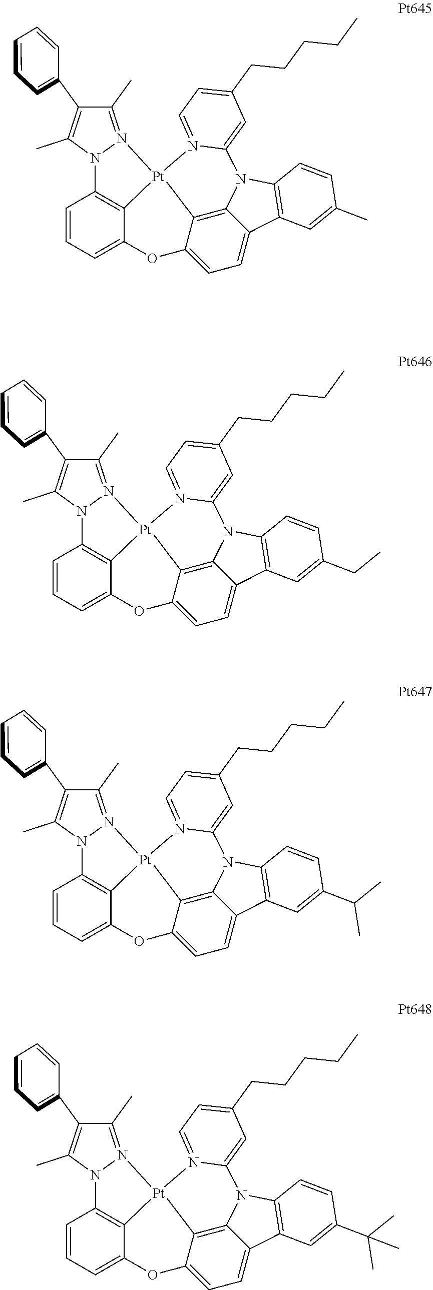

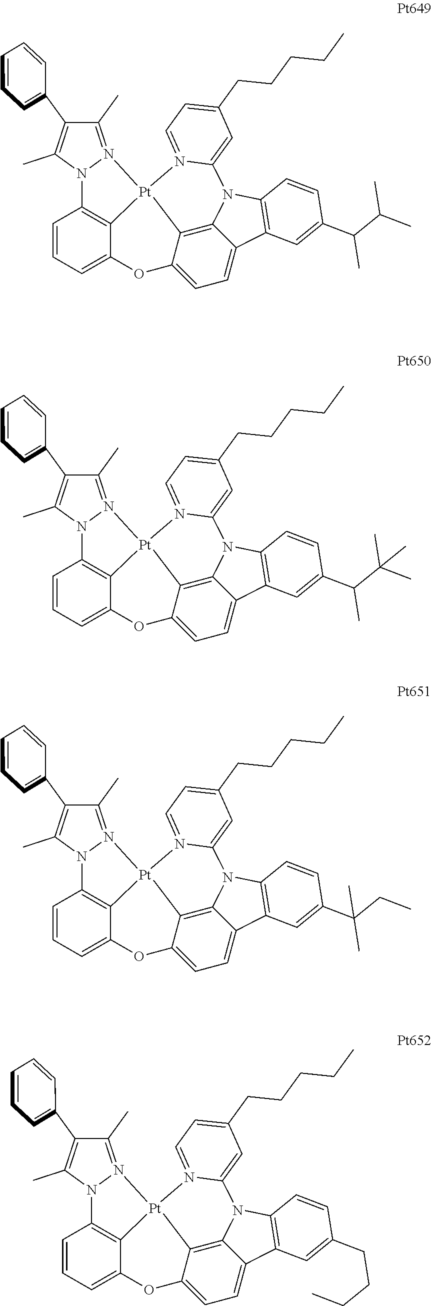

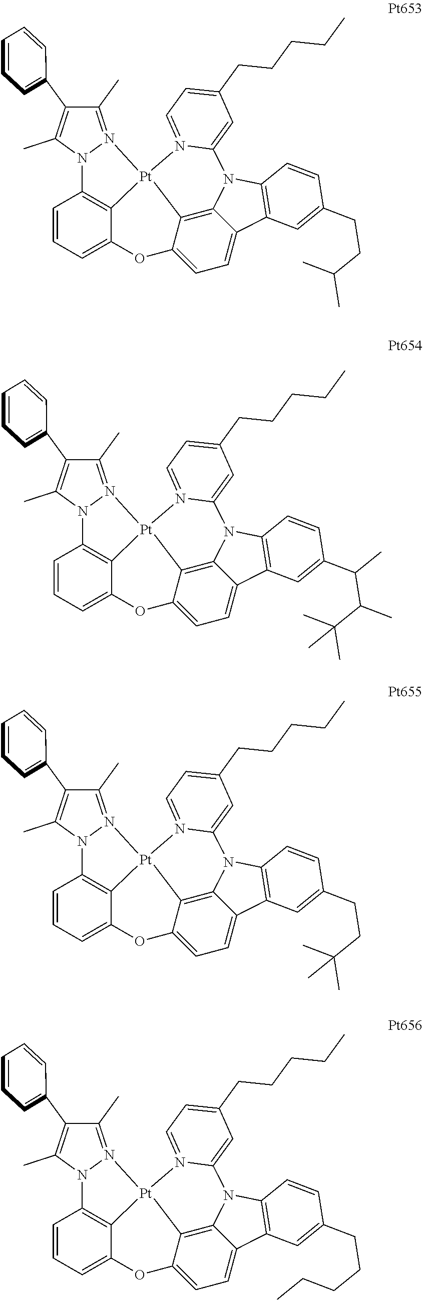

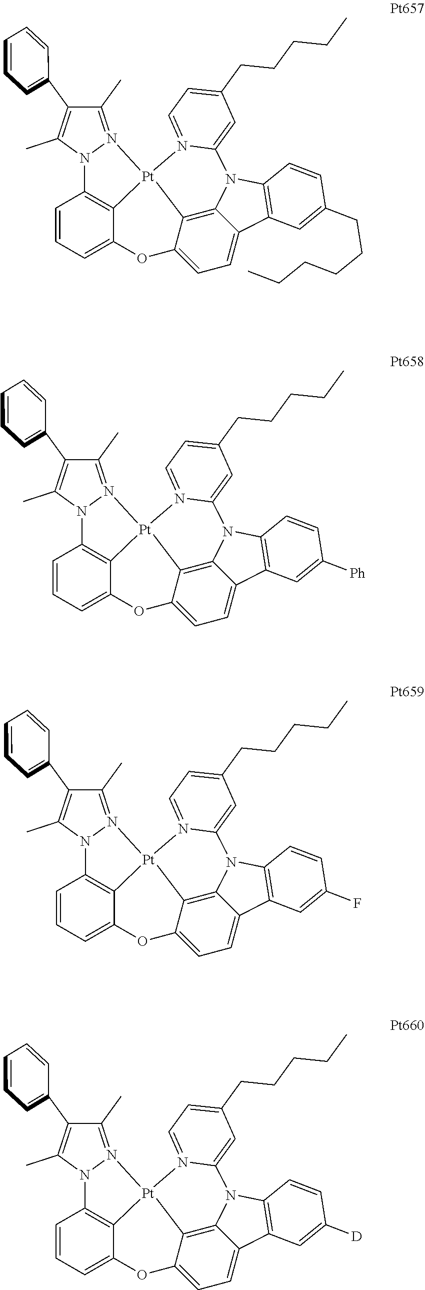

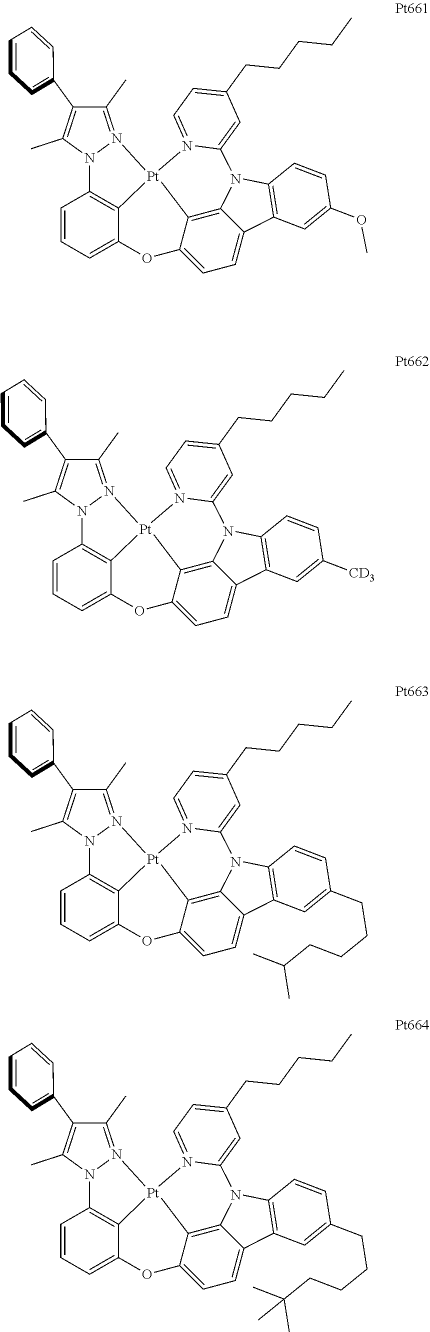

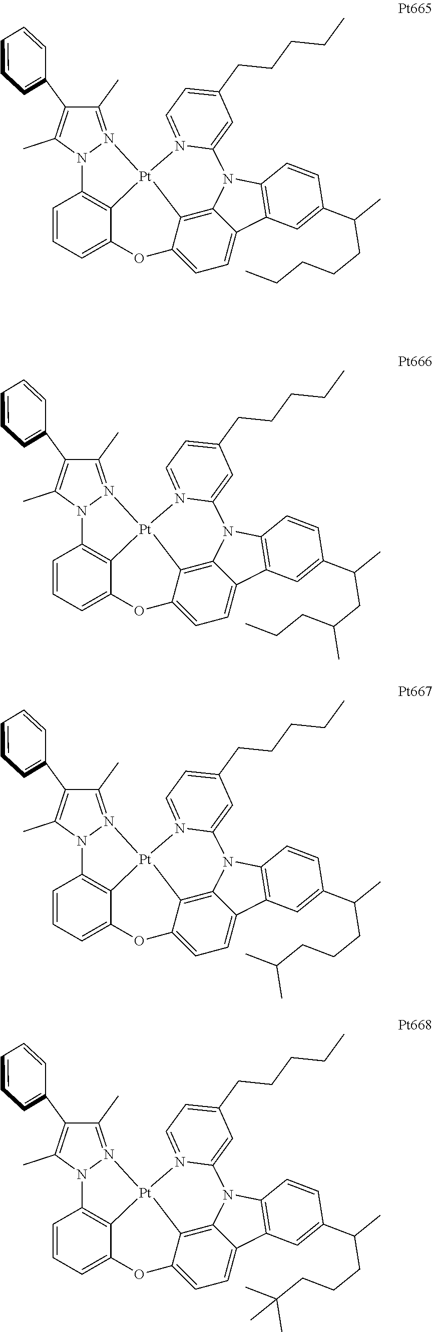

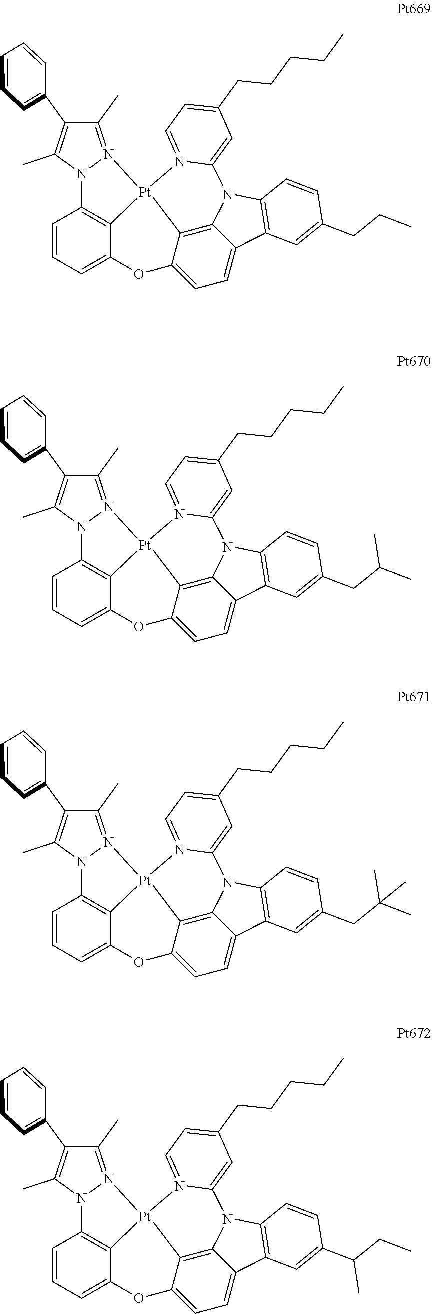

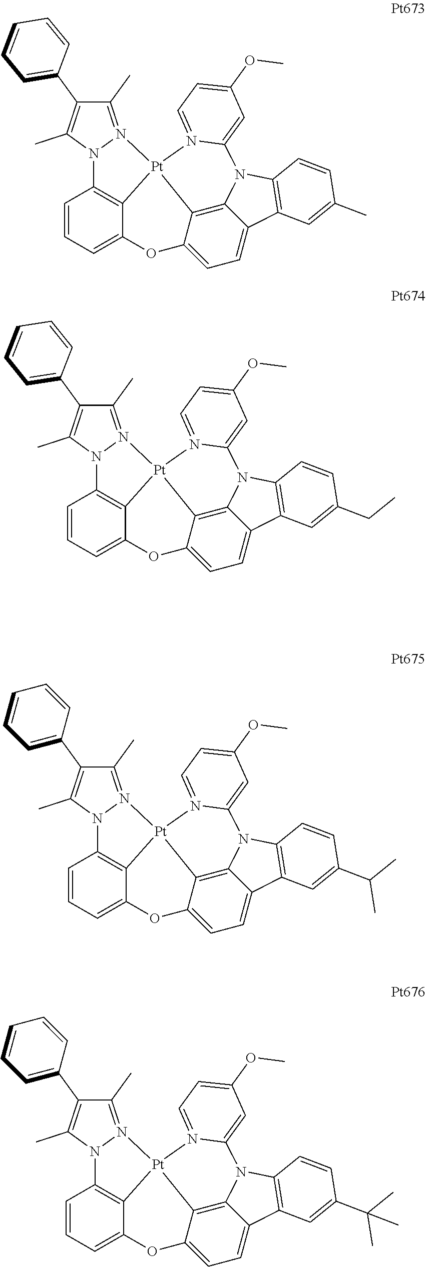

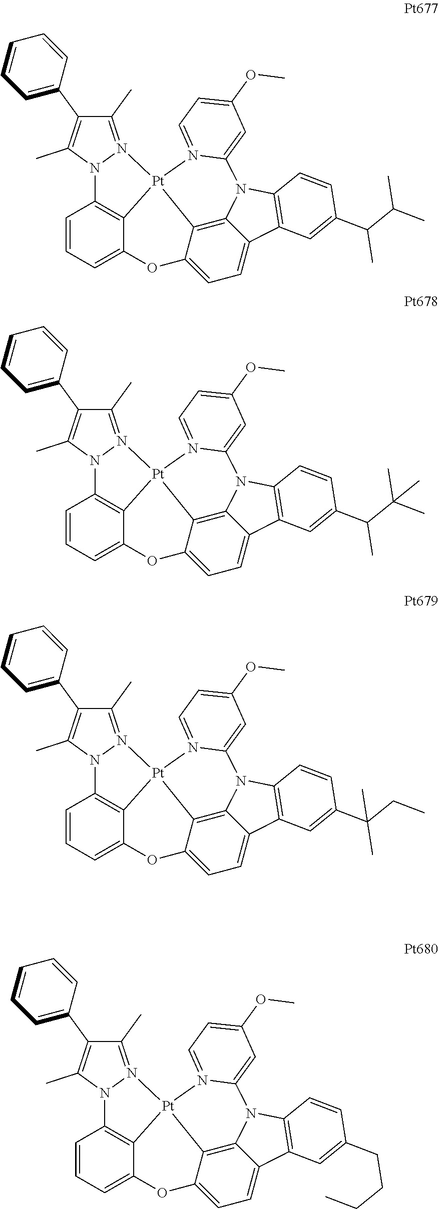

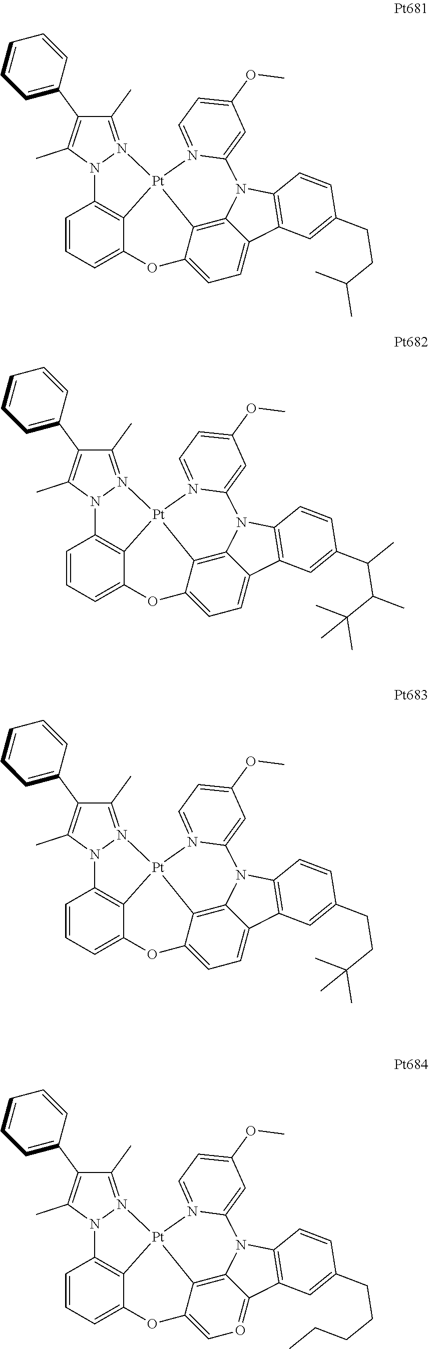

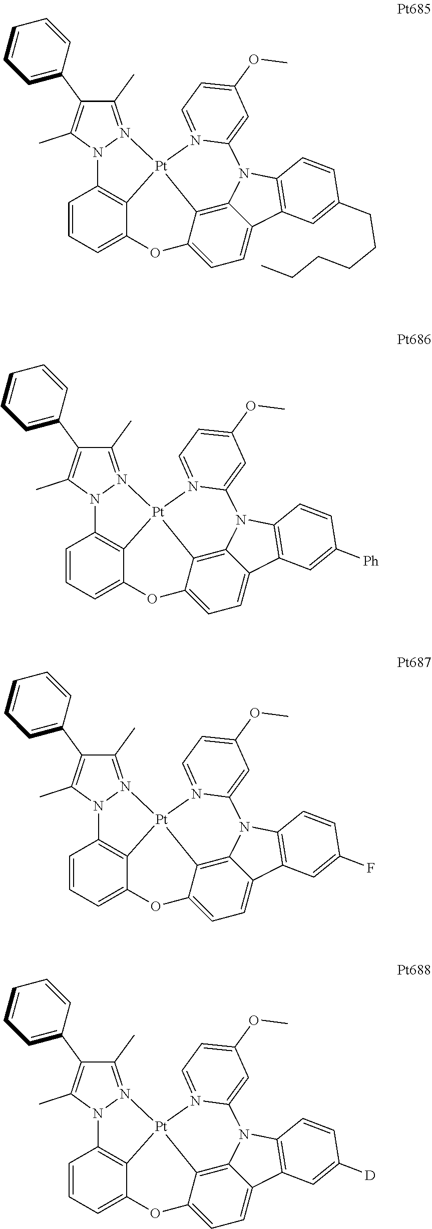

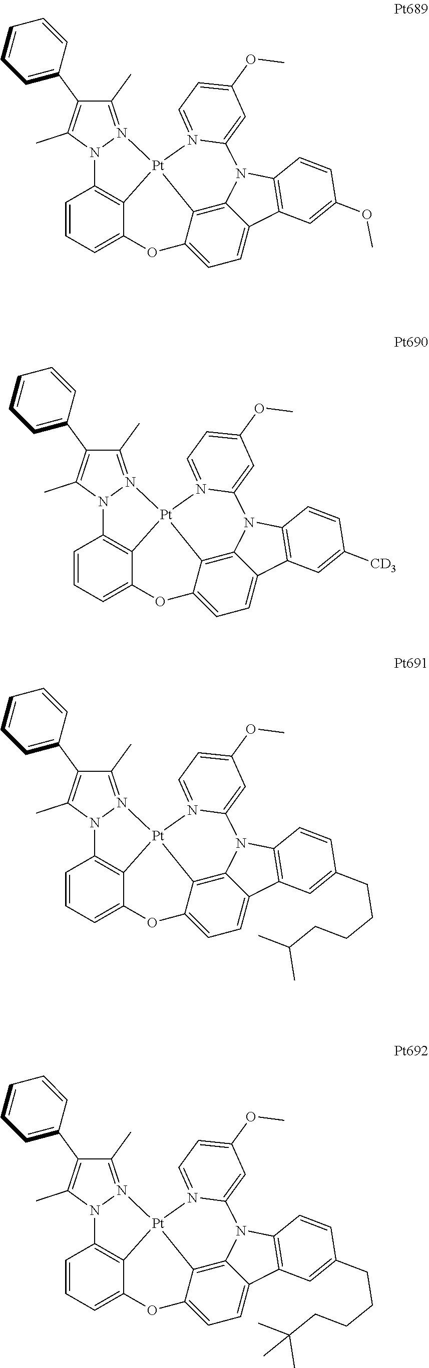

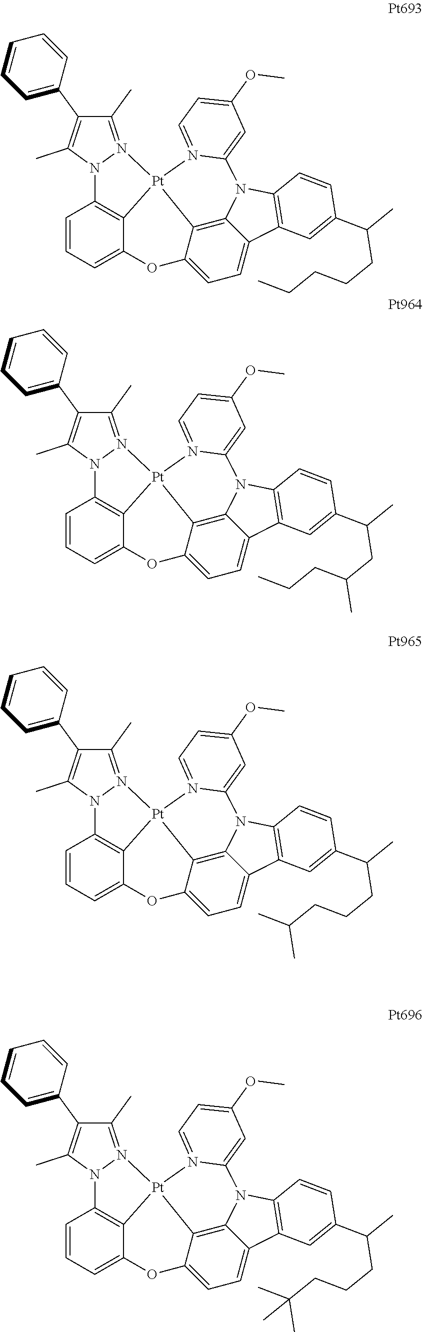

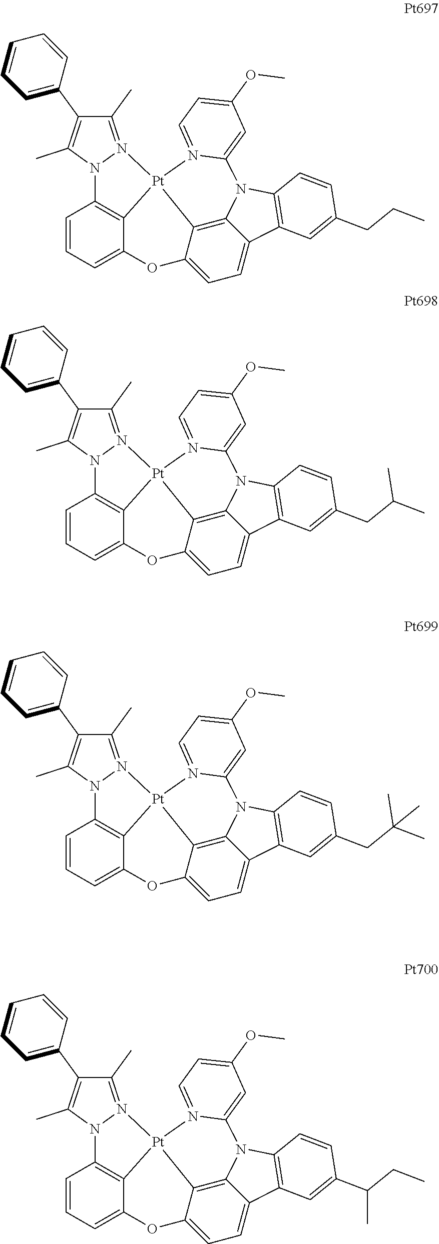

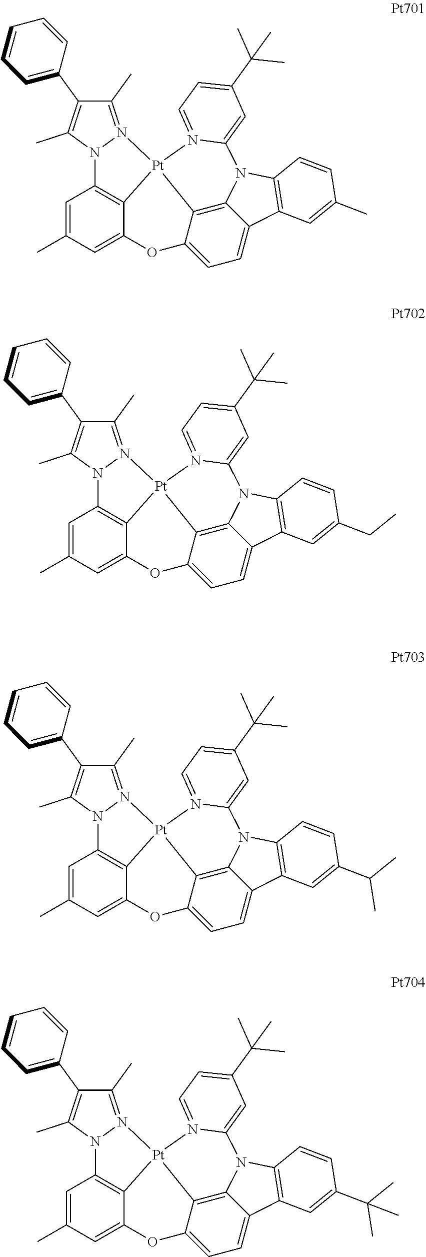

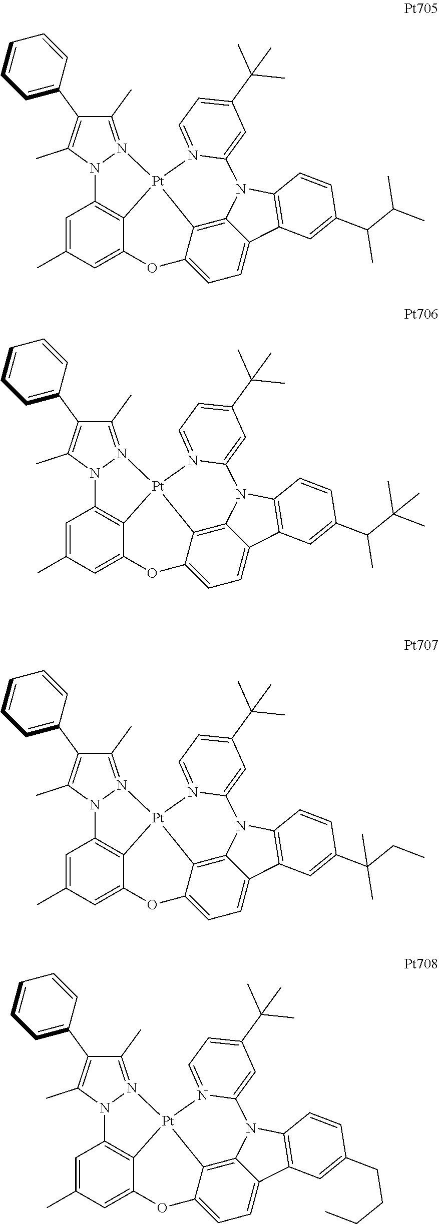

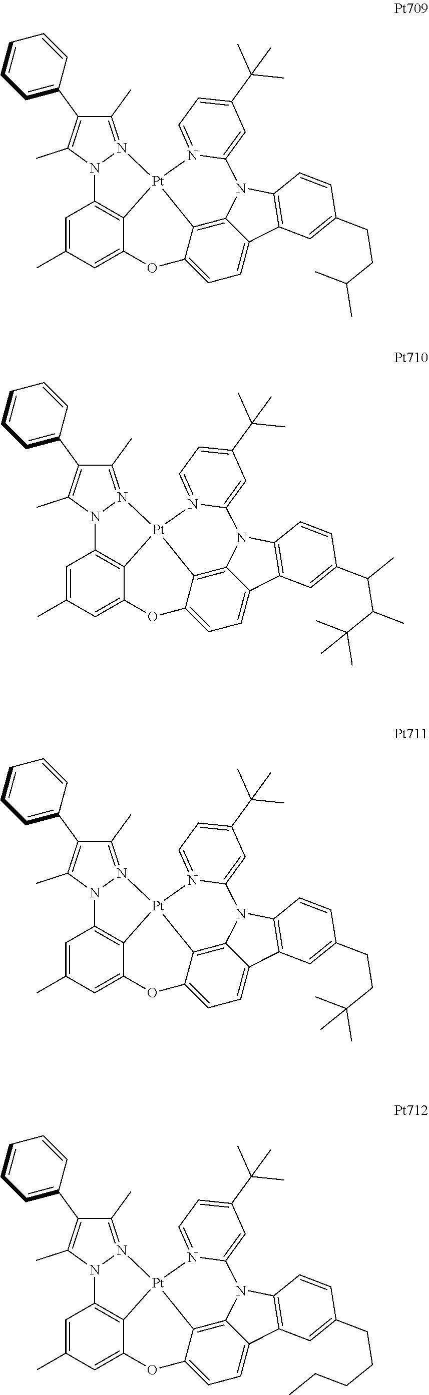

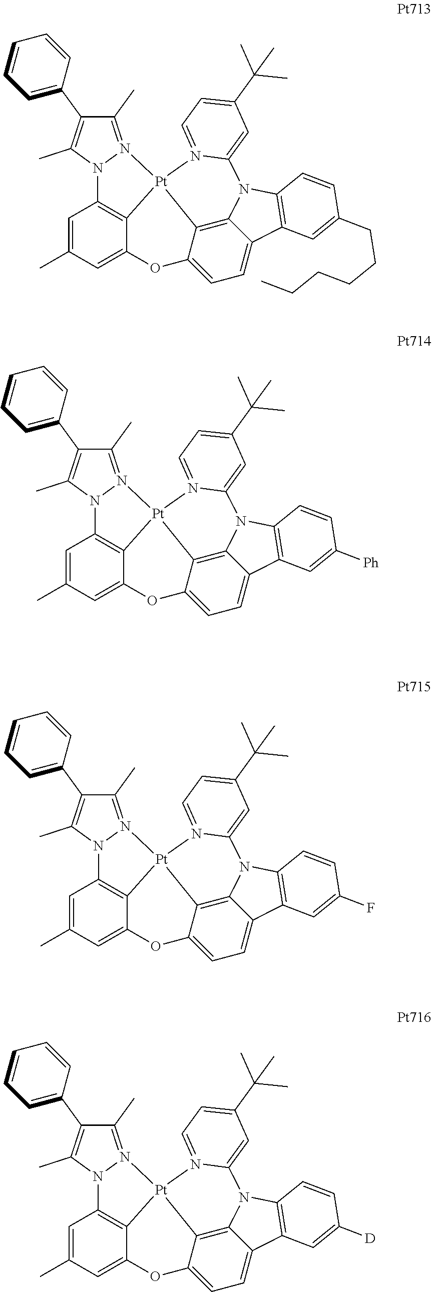

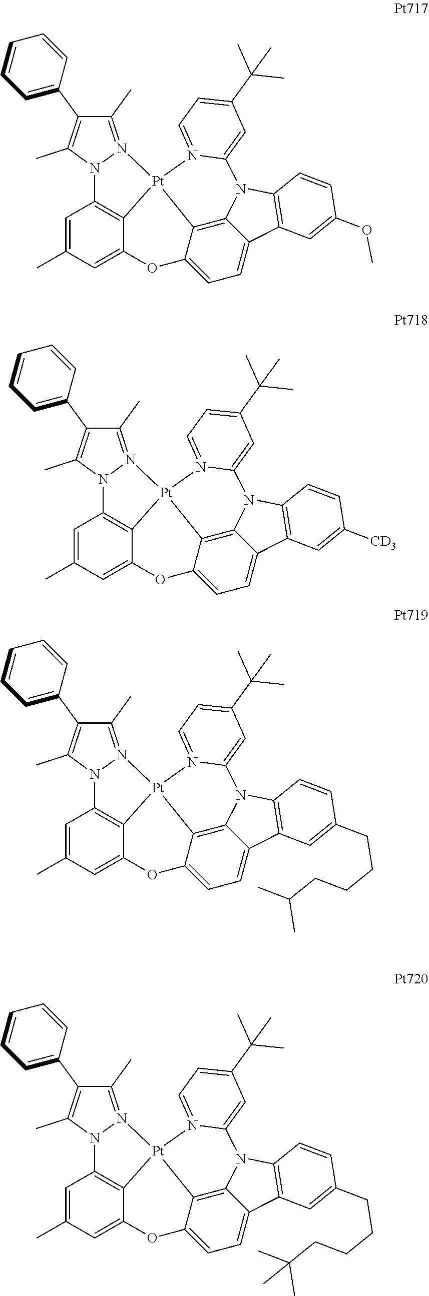

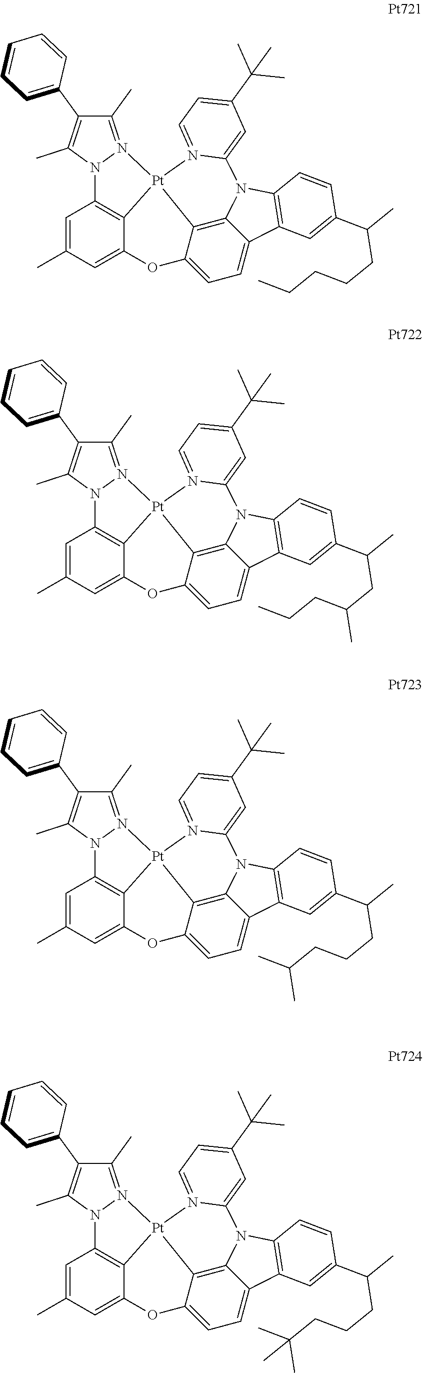

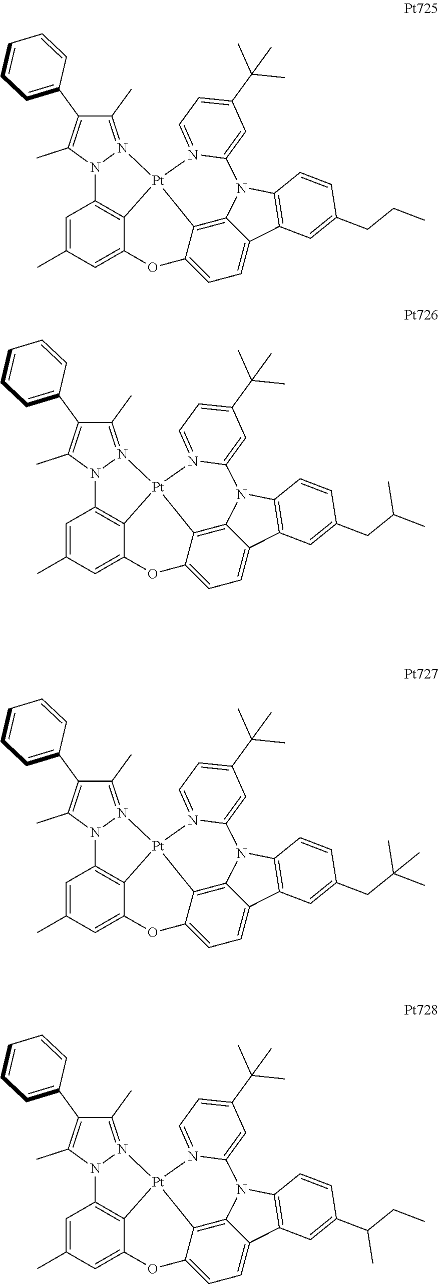

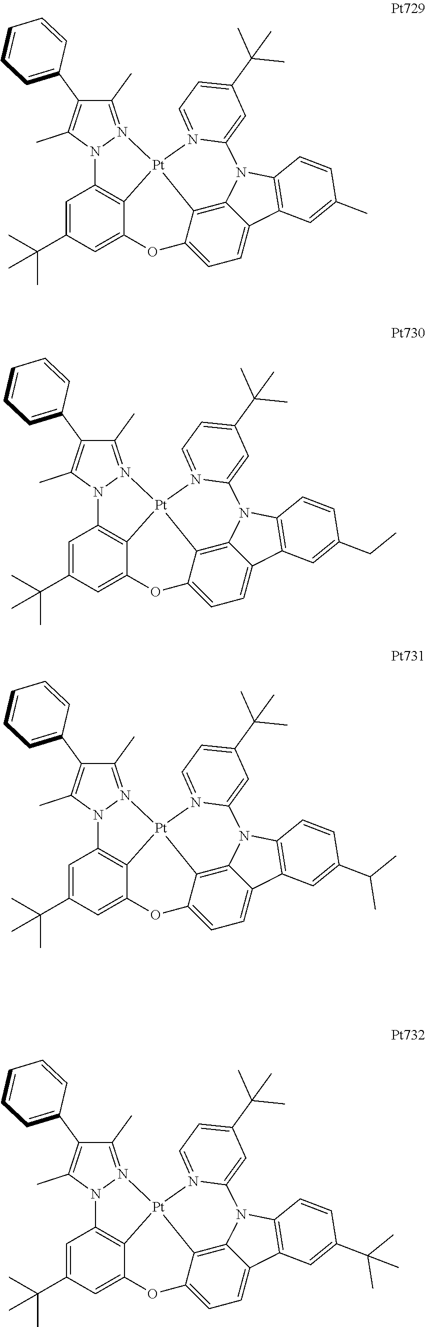

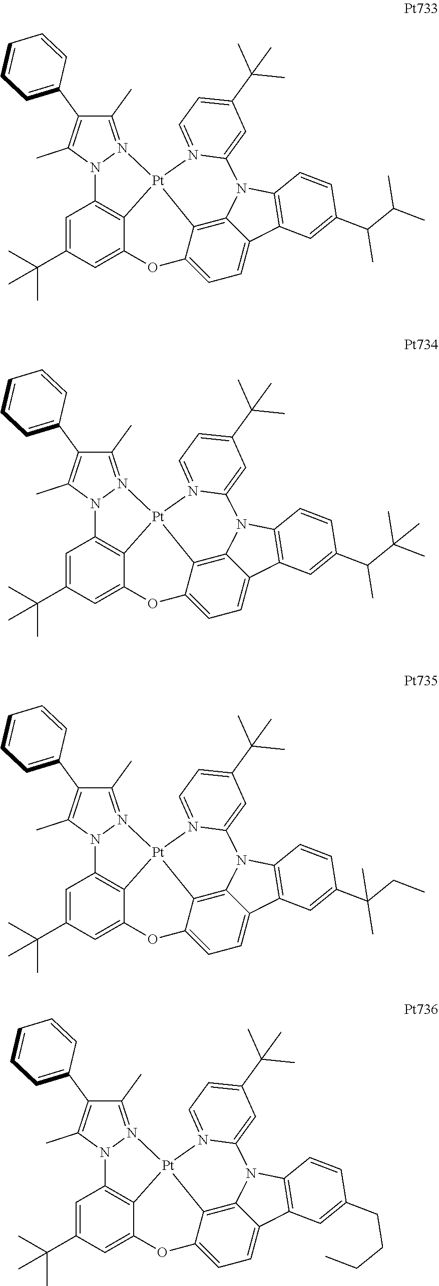

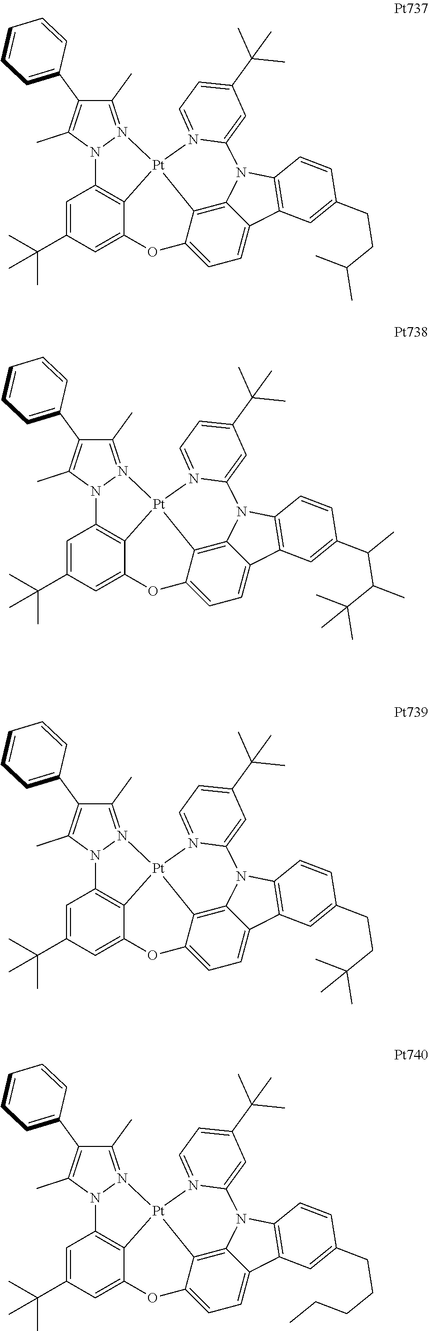

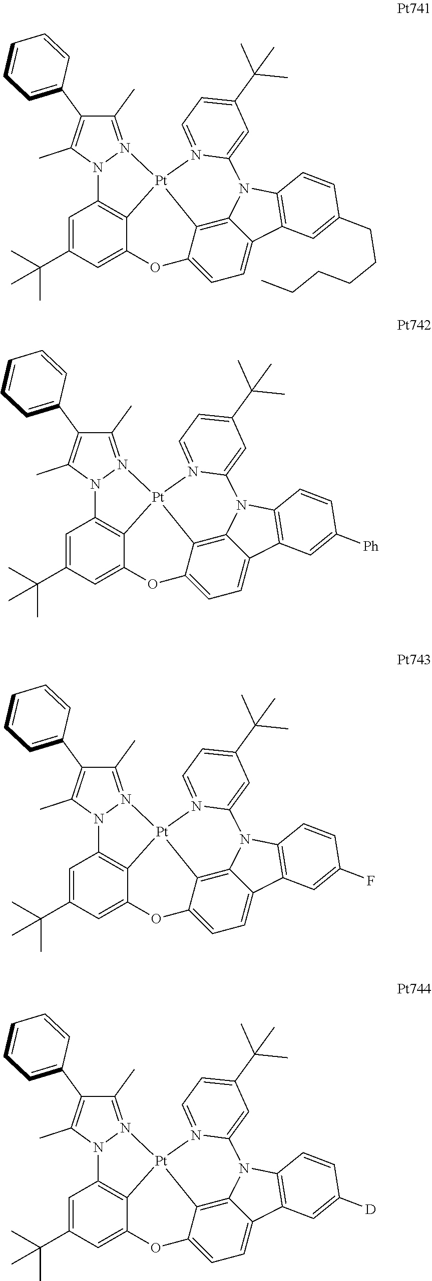

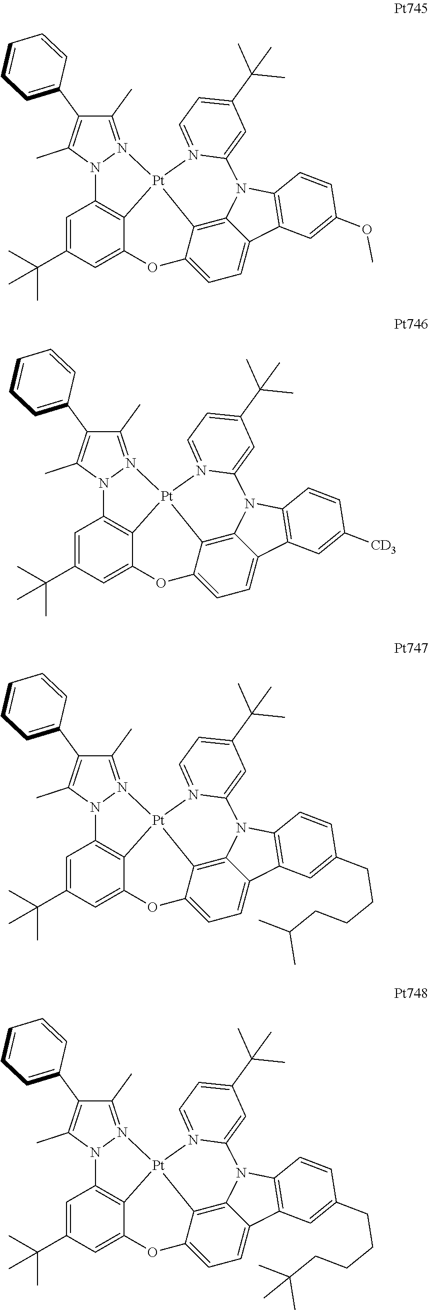

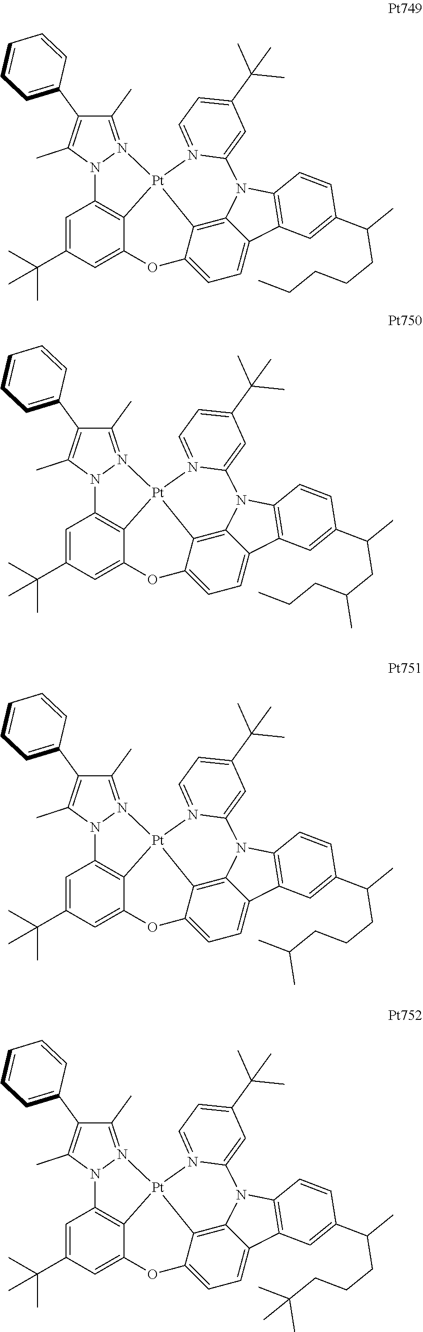

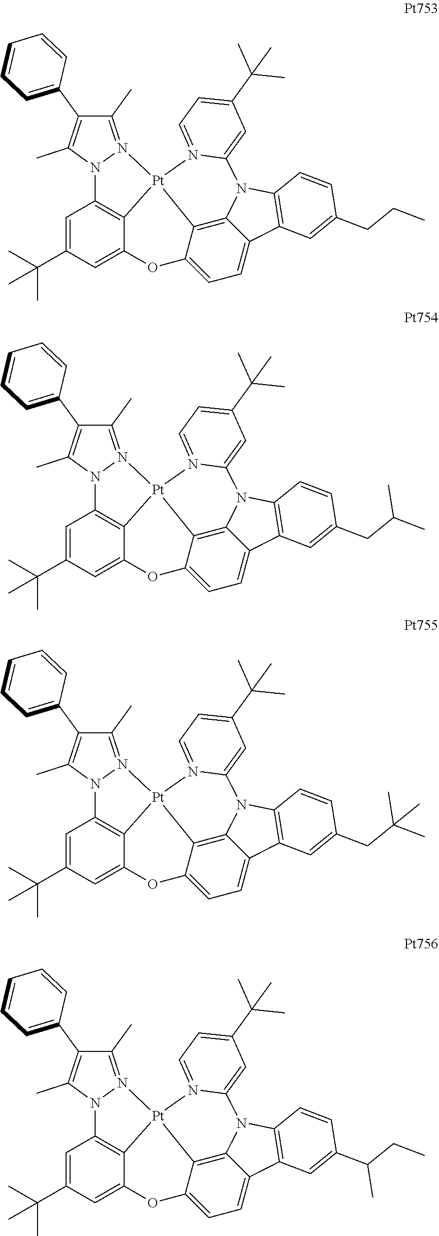

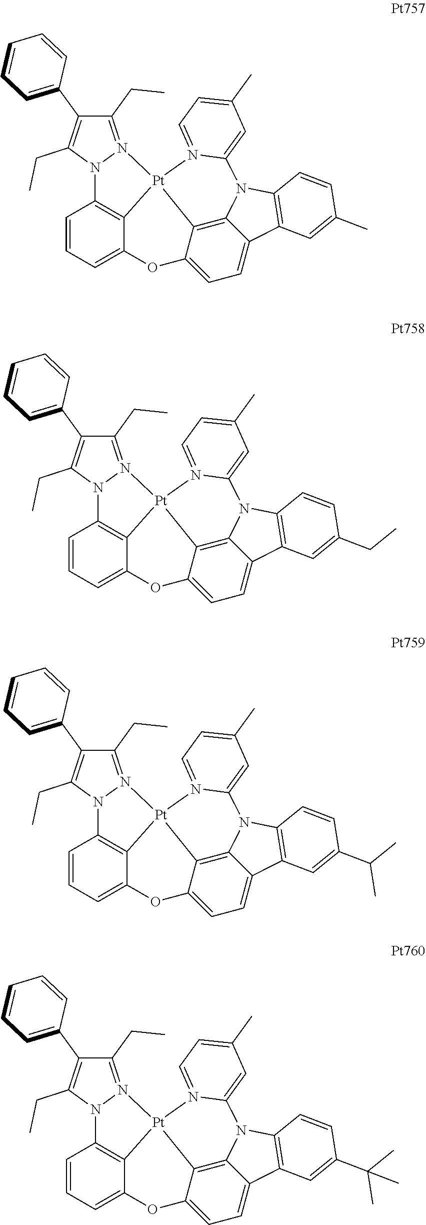

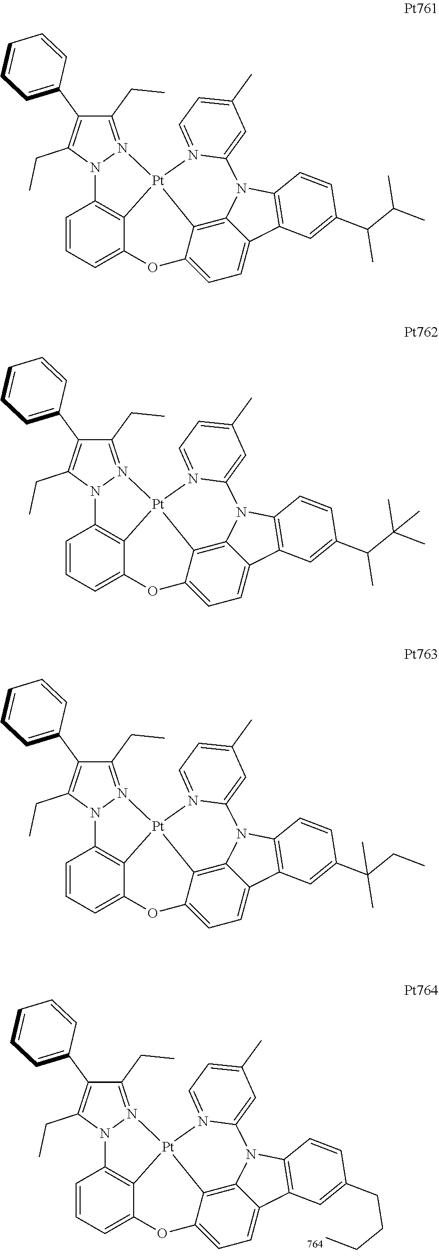

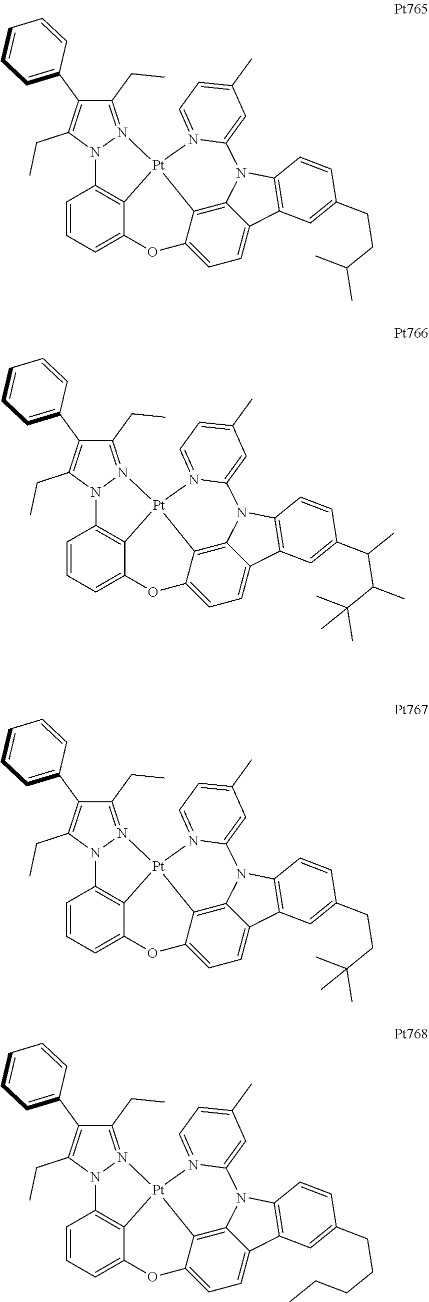

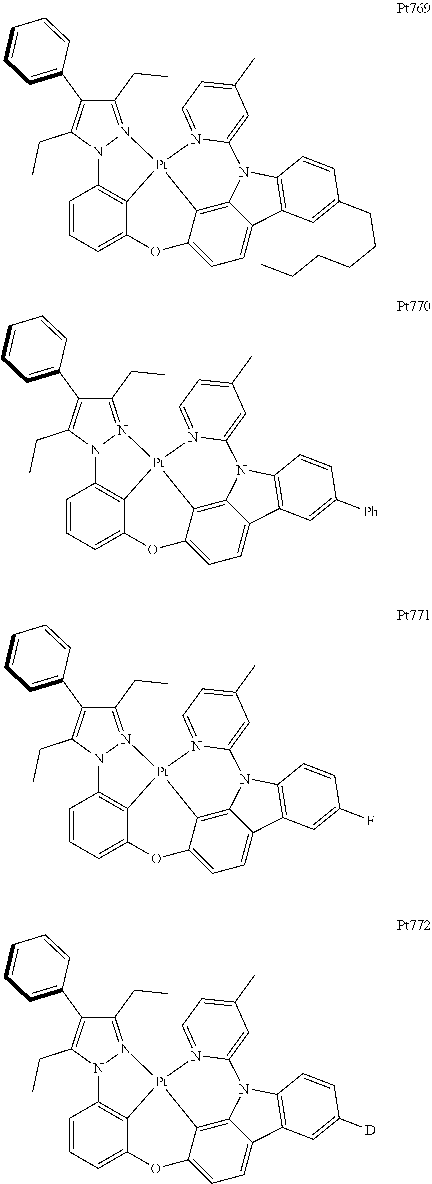

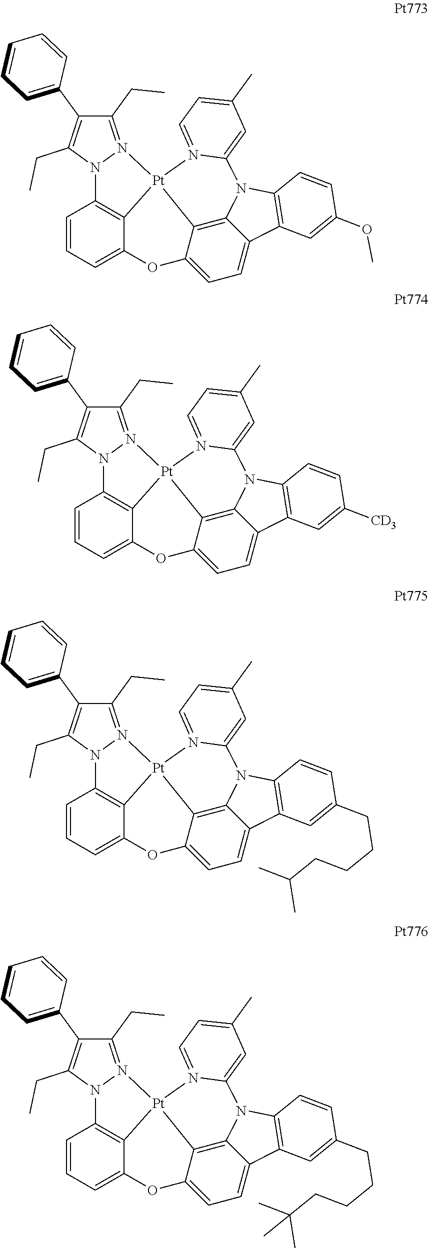

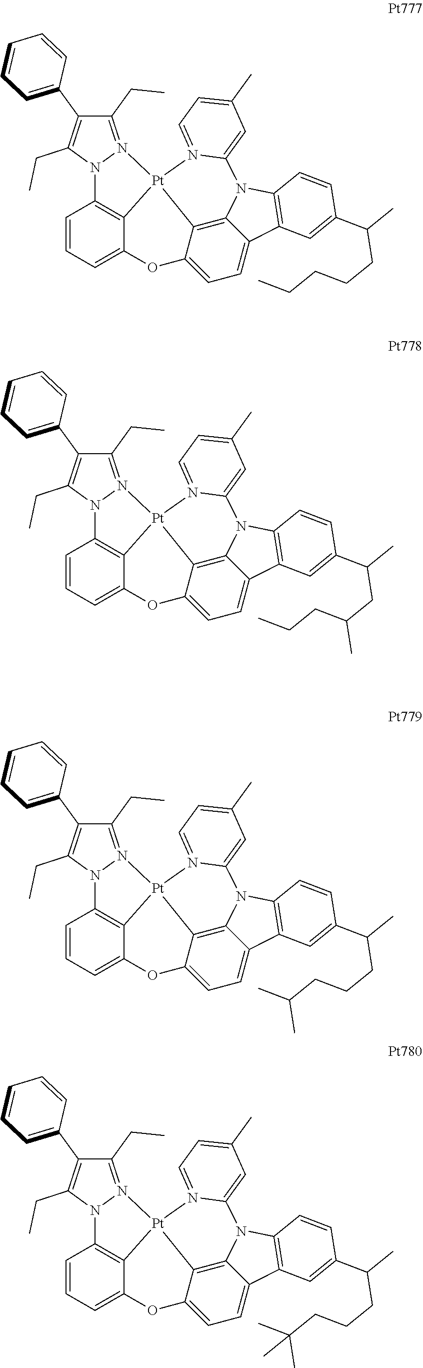

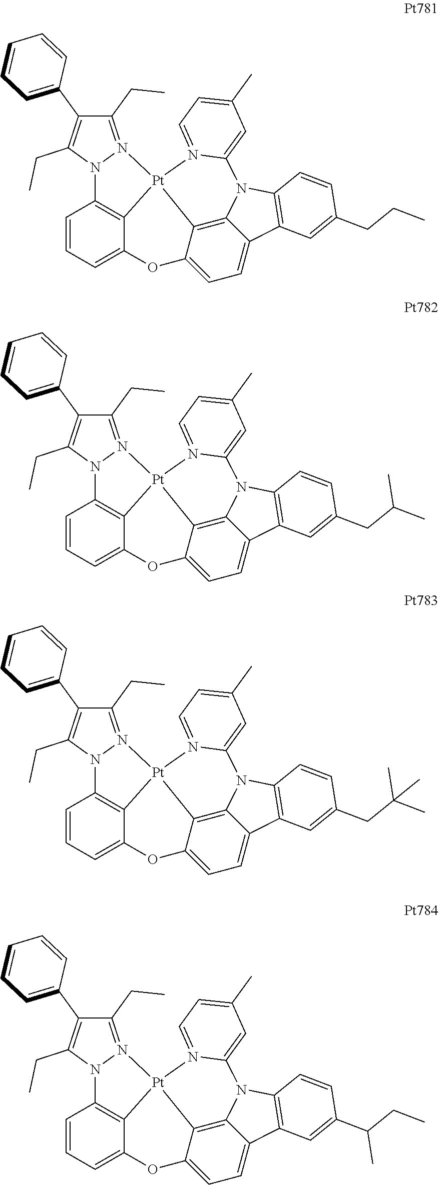

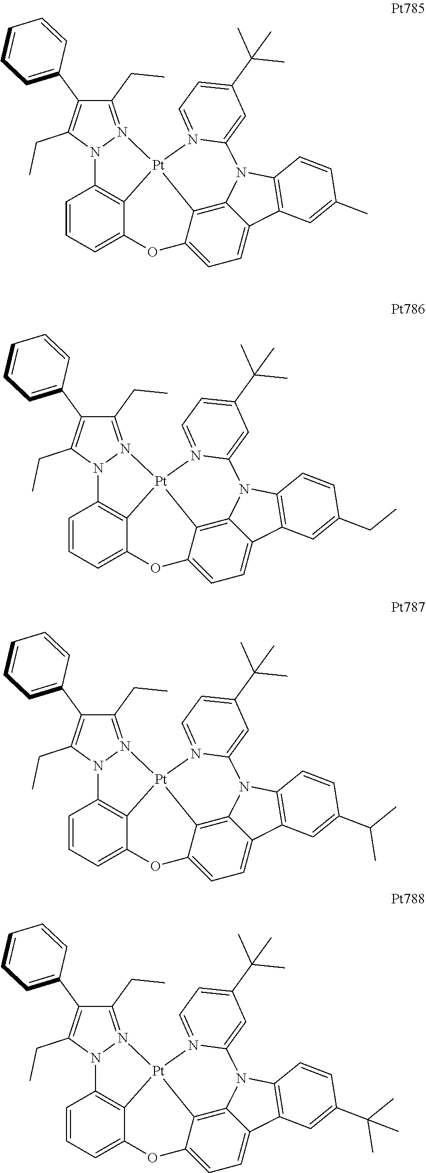

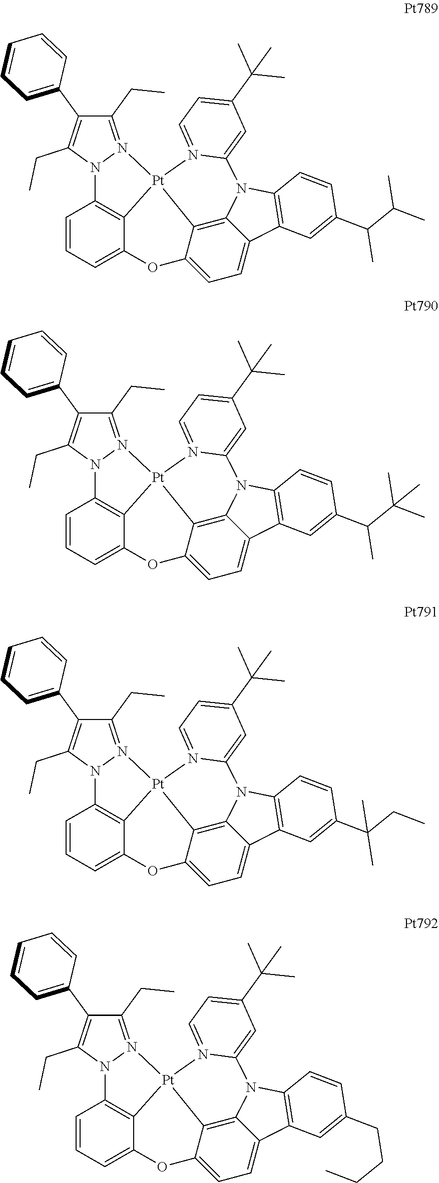

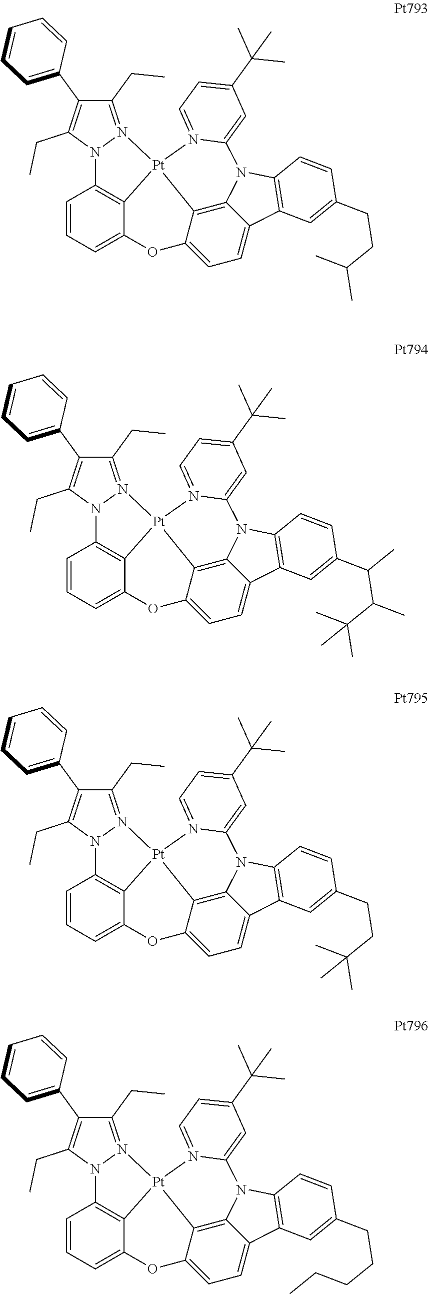

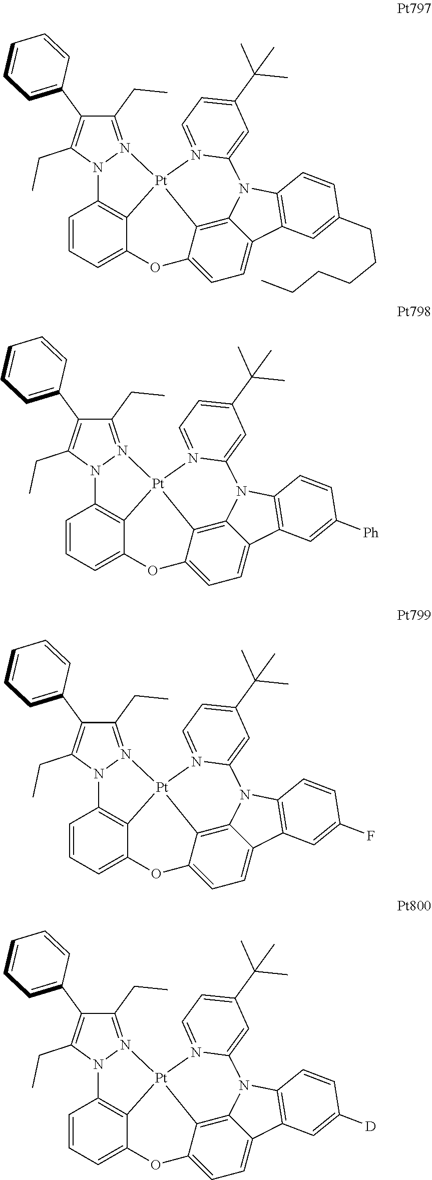

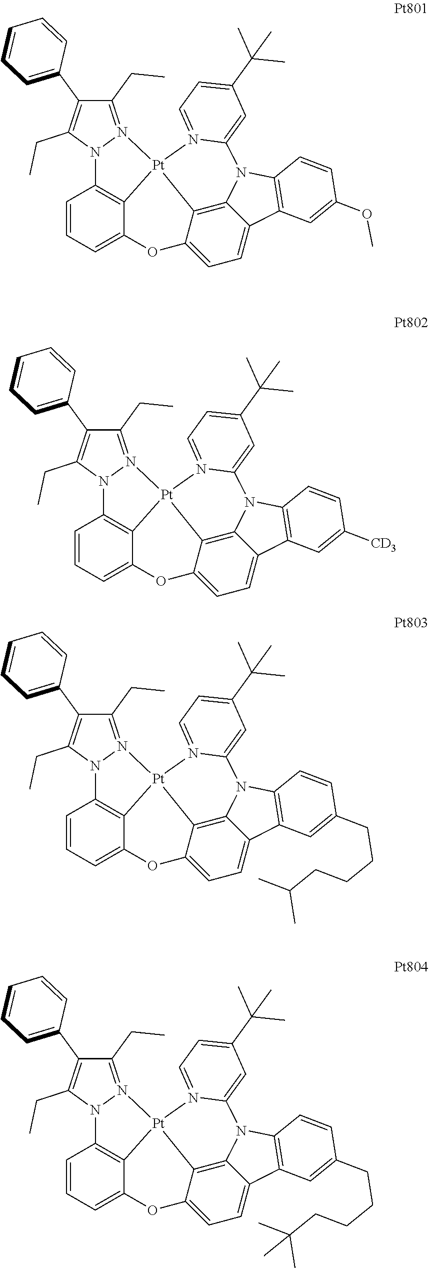

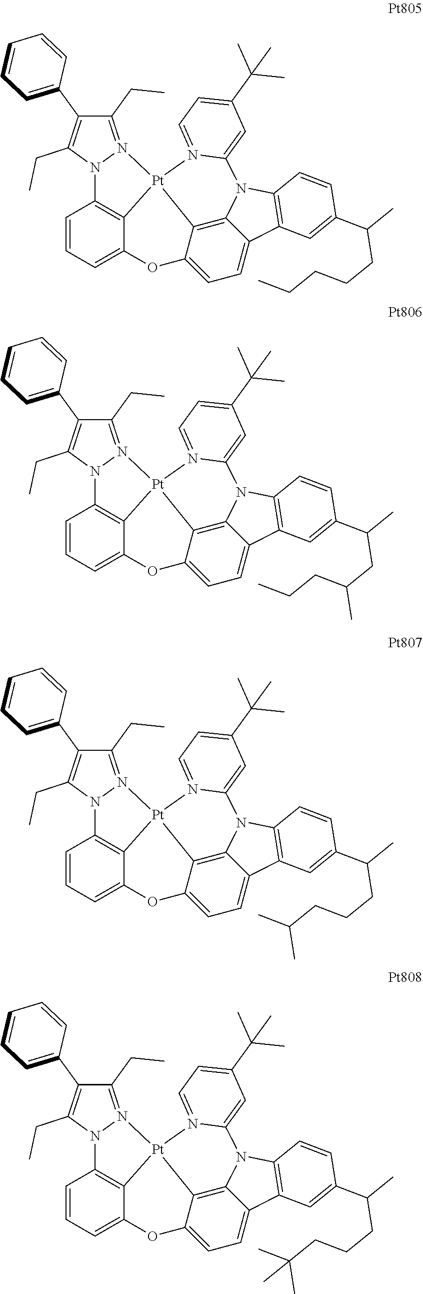

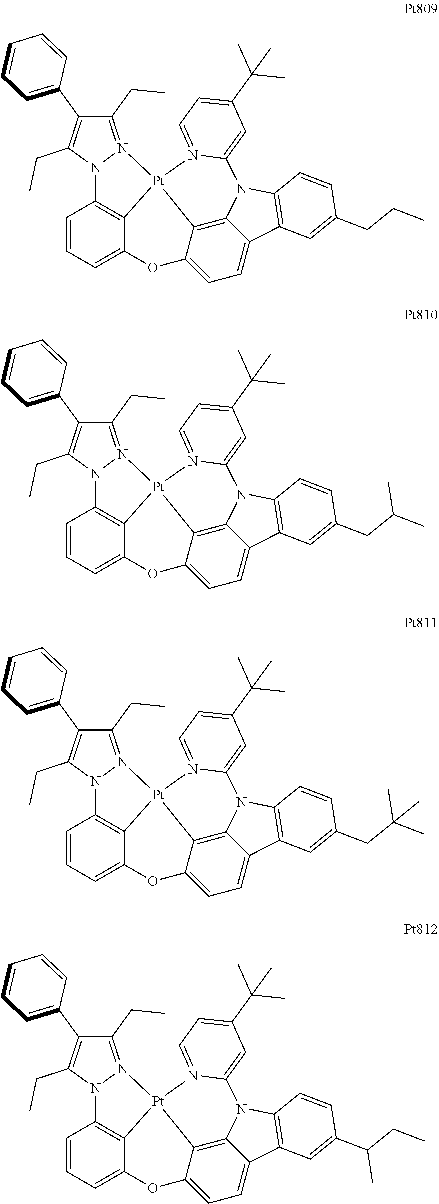

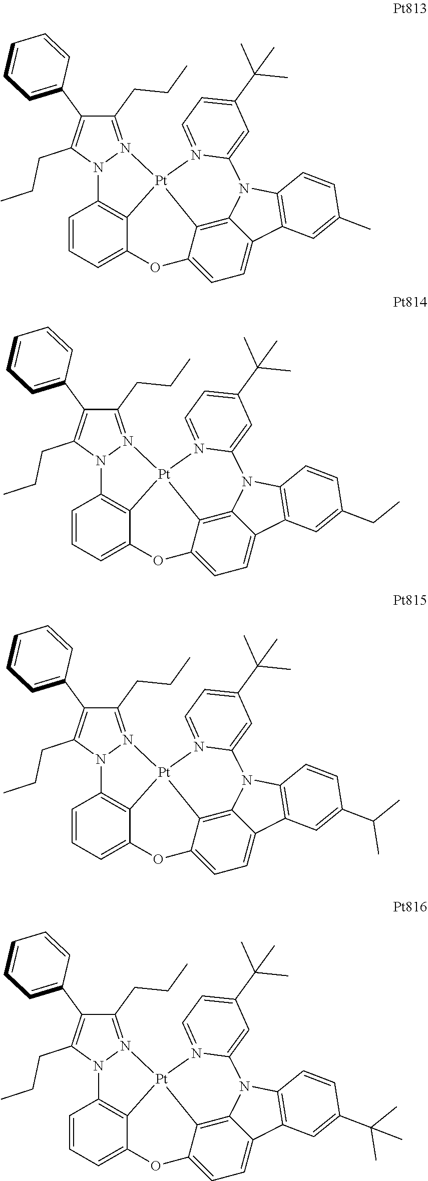

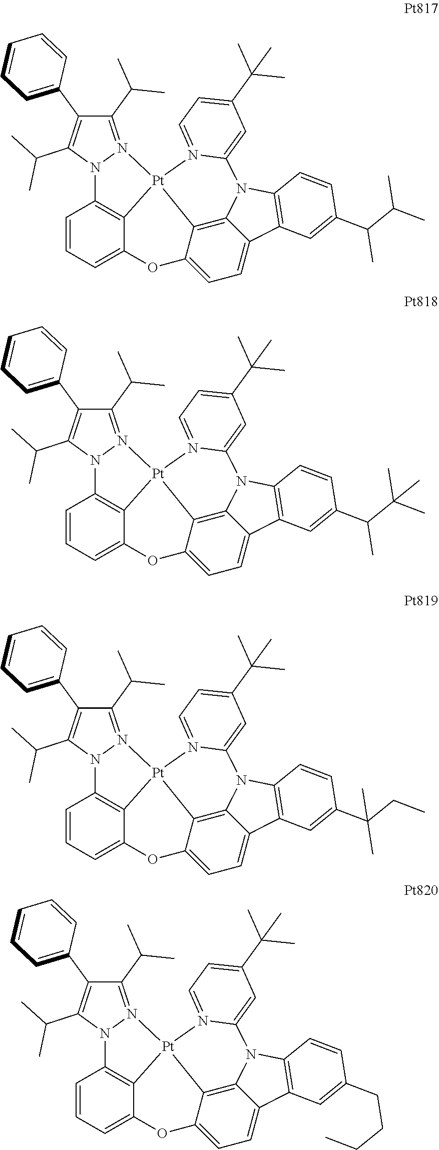

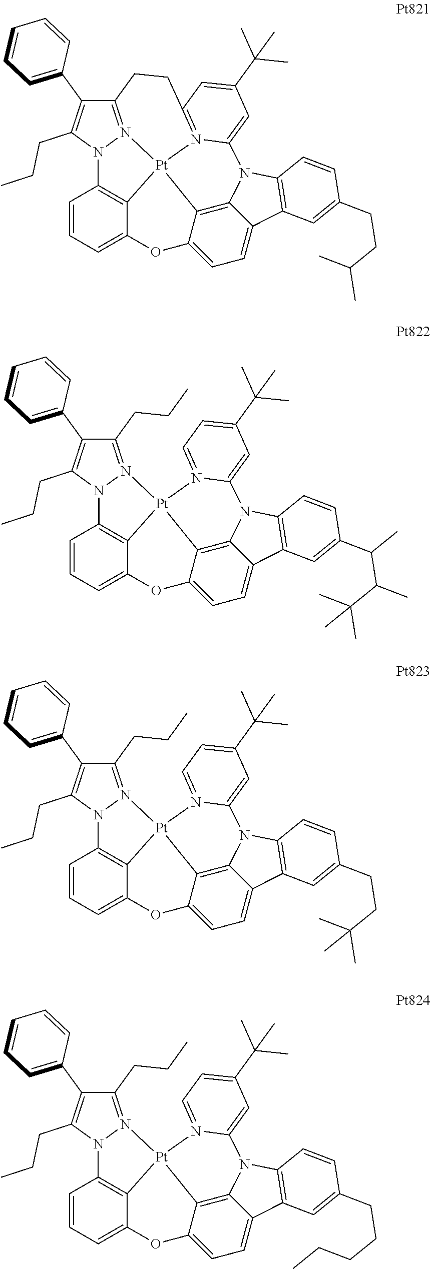

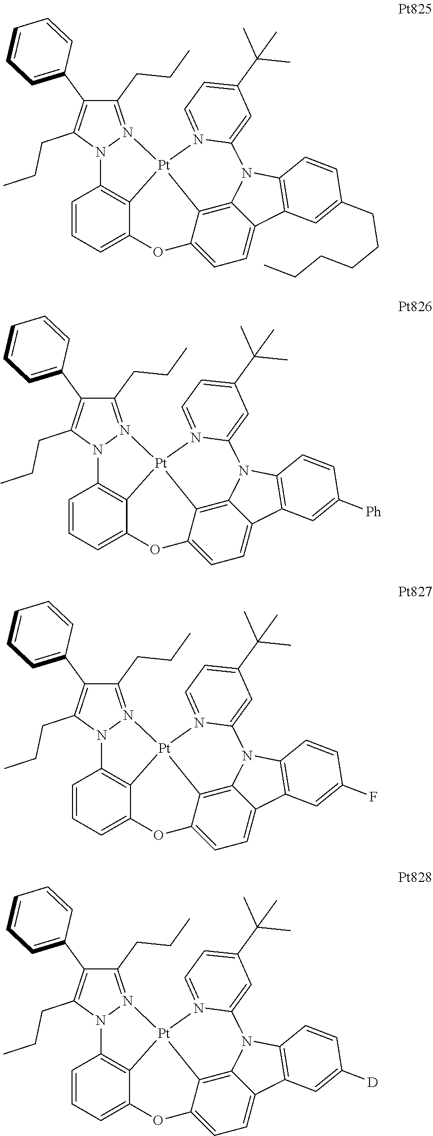

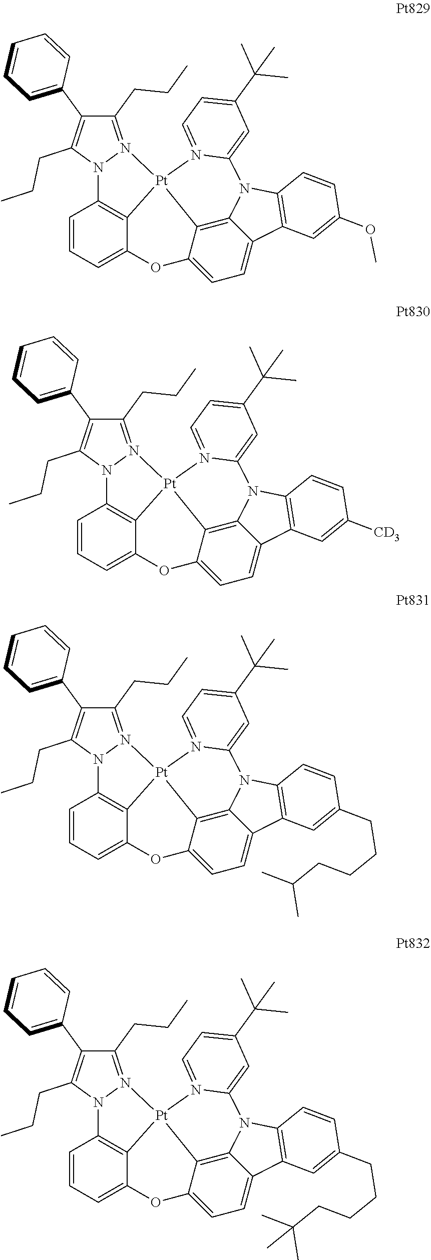

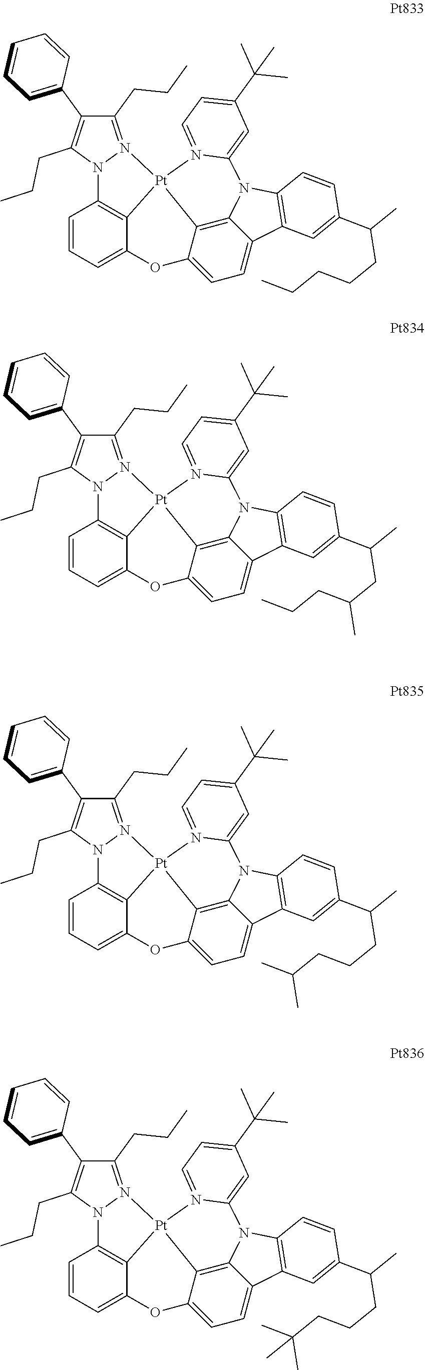

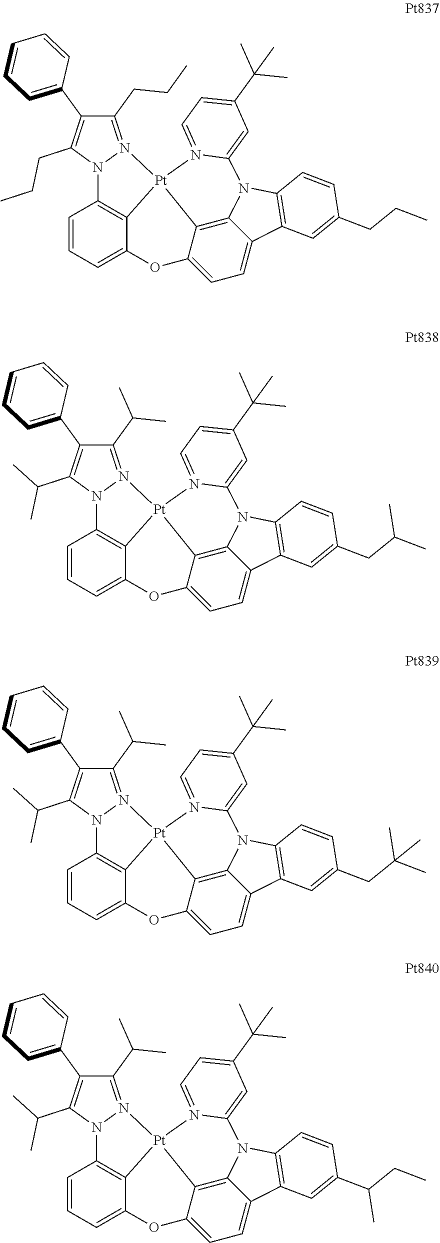

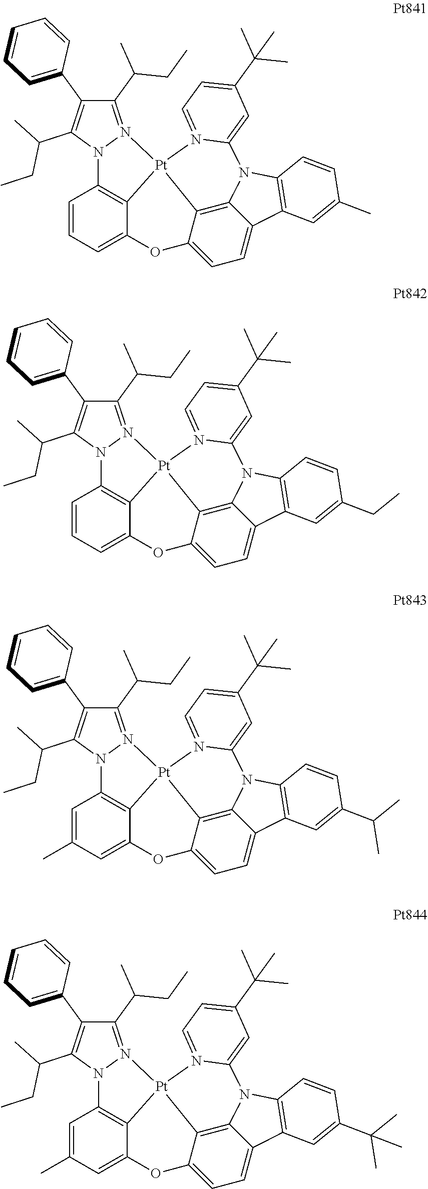

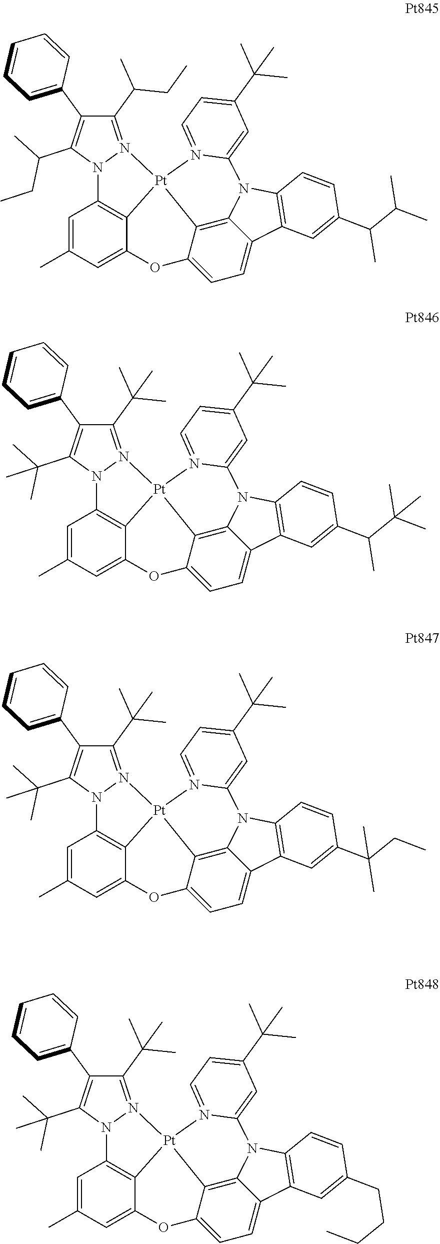

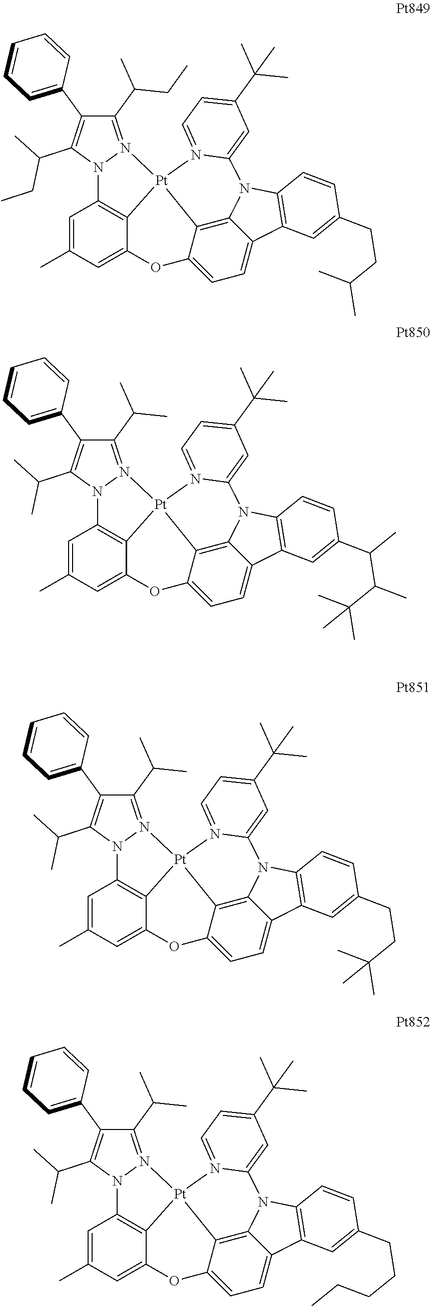

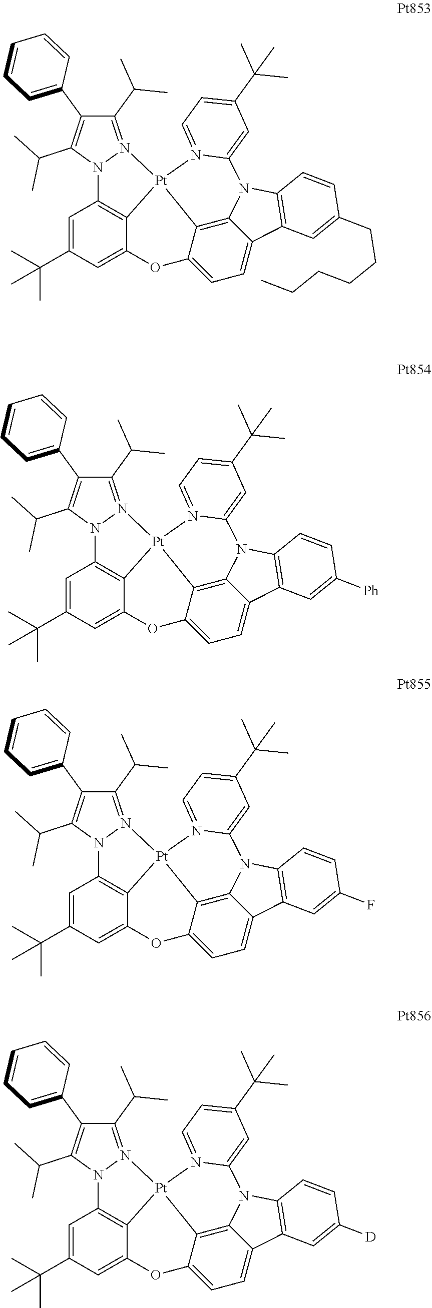

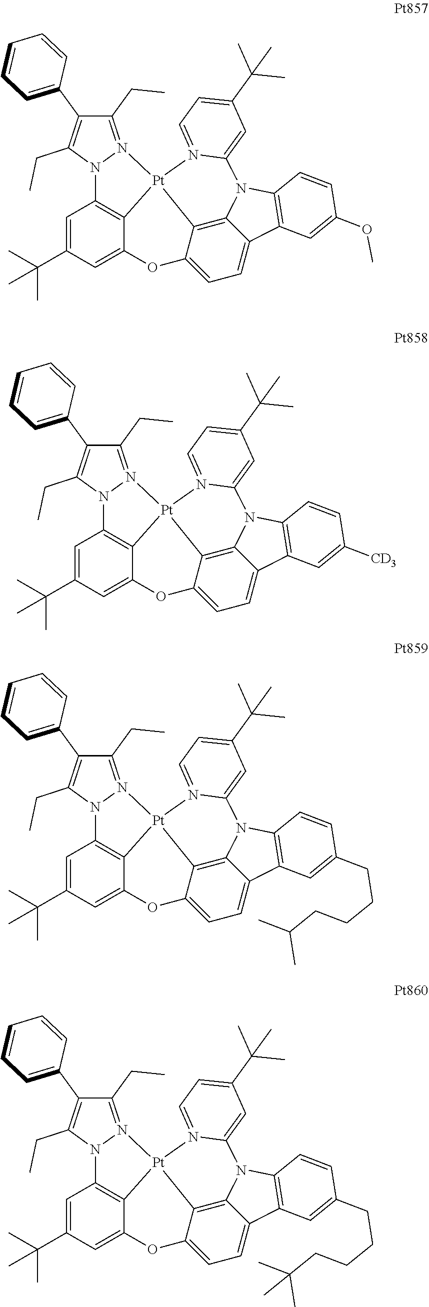

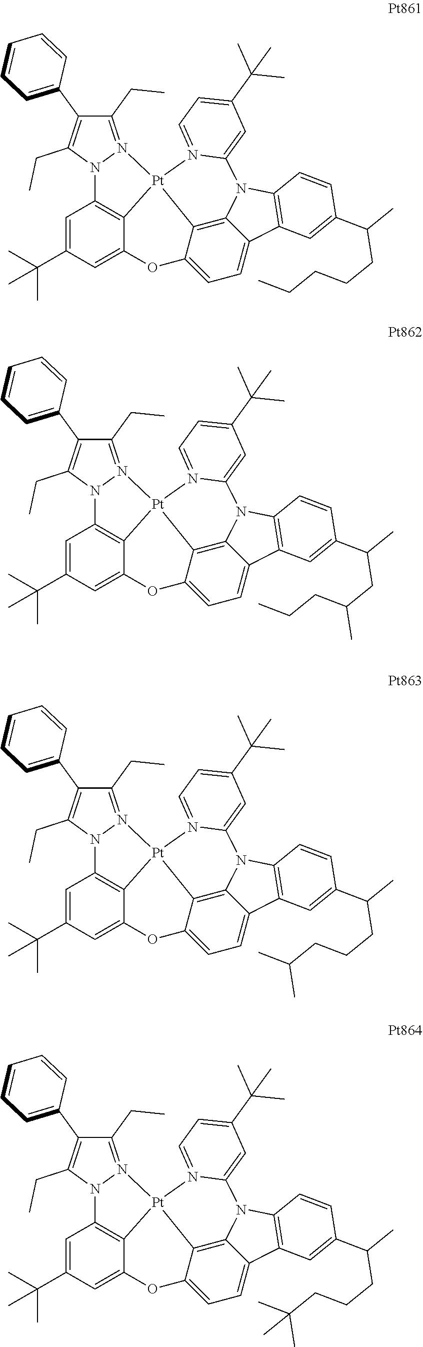

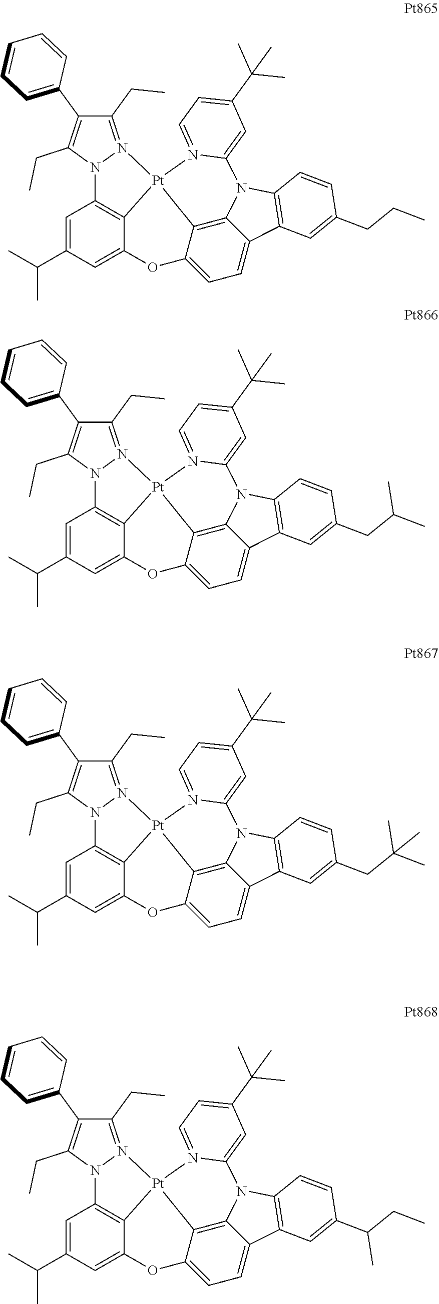

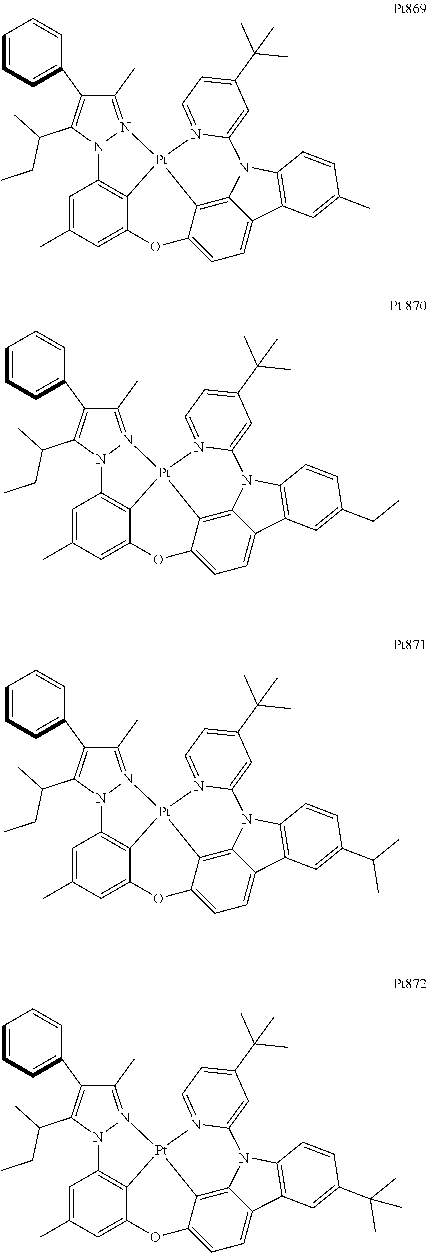

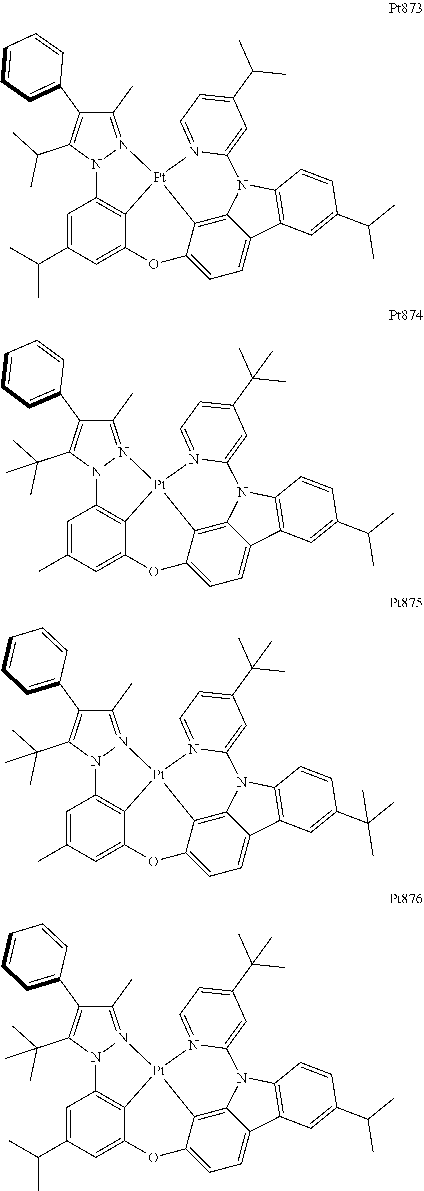

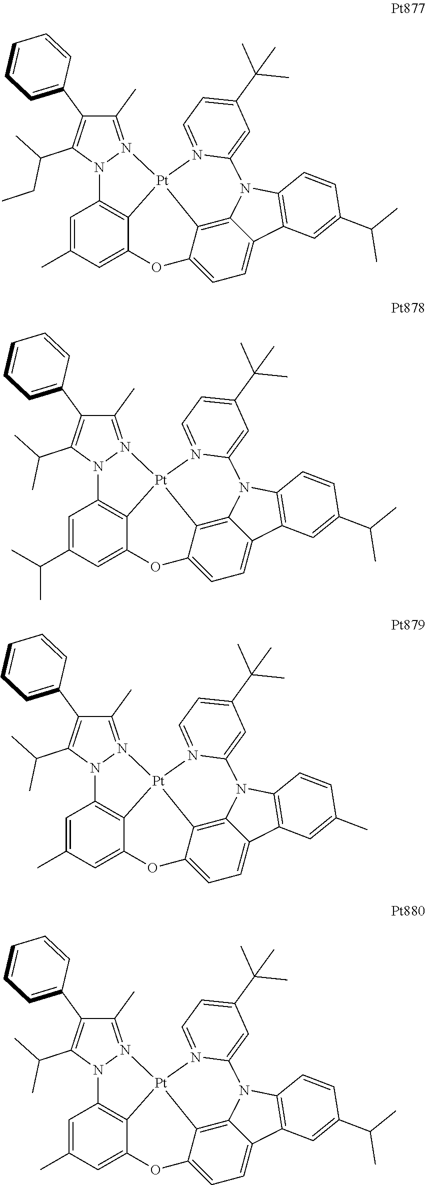

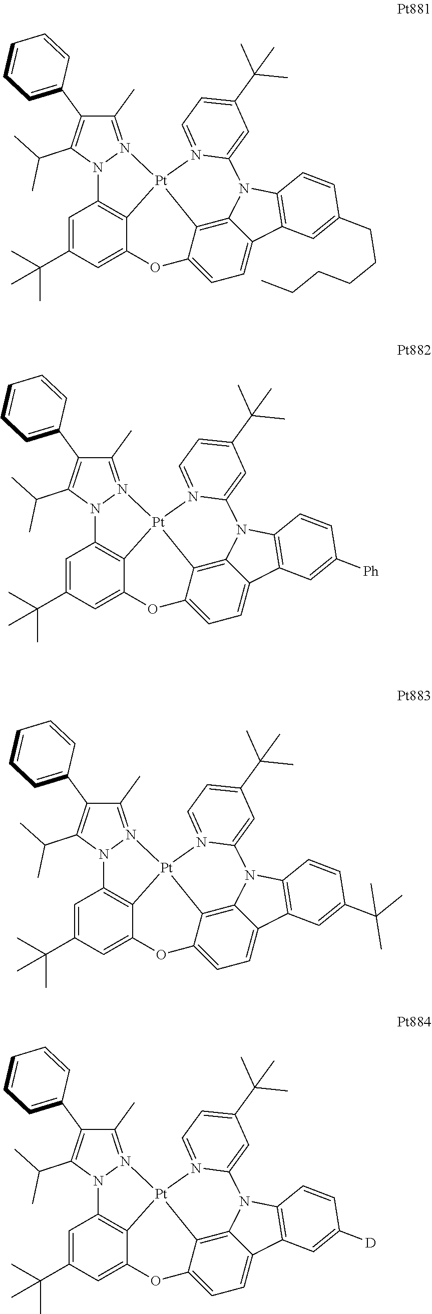

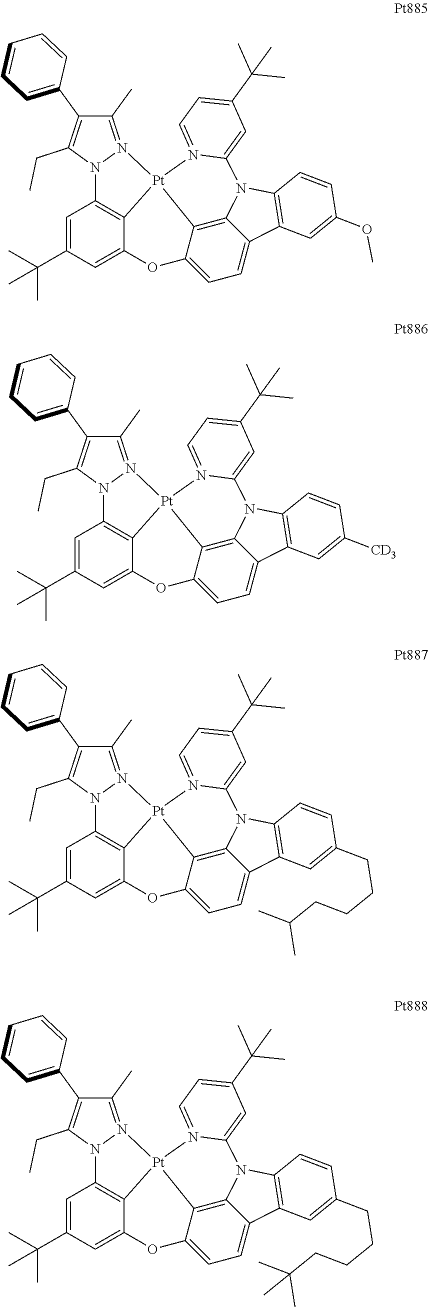

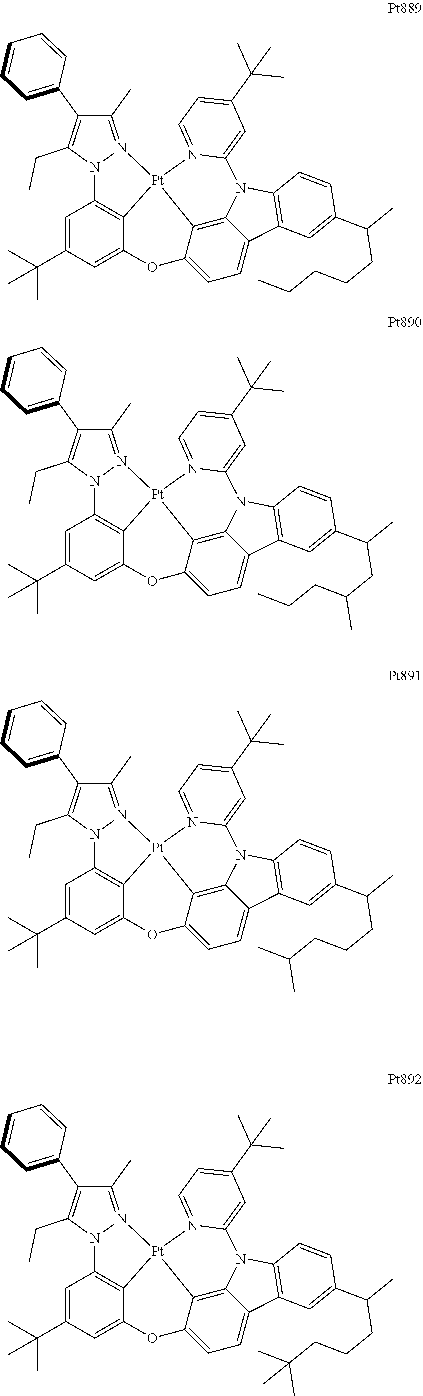

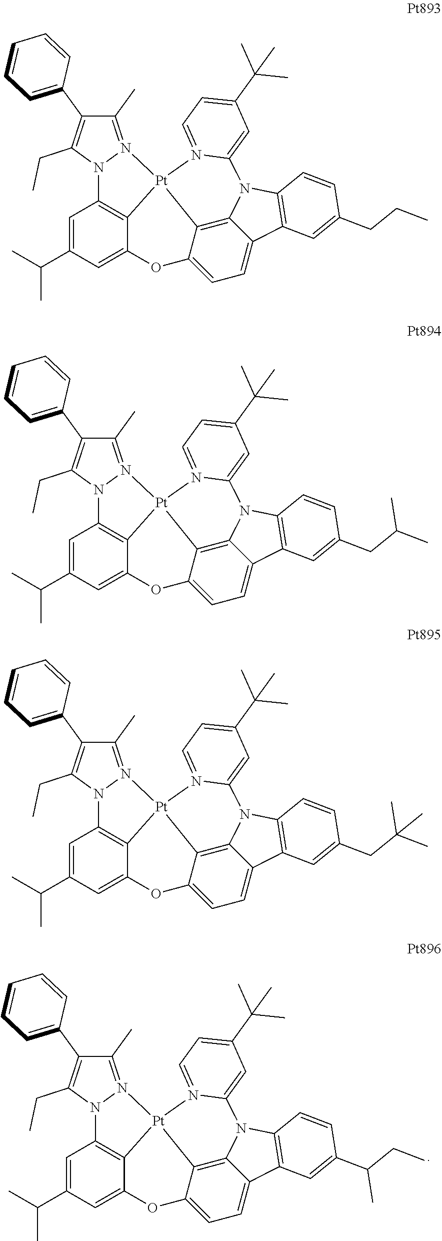

4. The complex according to claim 1, wherein the complex is electrically neutral.

5. A method for preparing the tetradentate cyclic-metal platinum complex comprising 6-substituted carbazole according to claim 1, wherein the complex is synthesized by using the following chemical reaction steps:

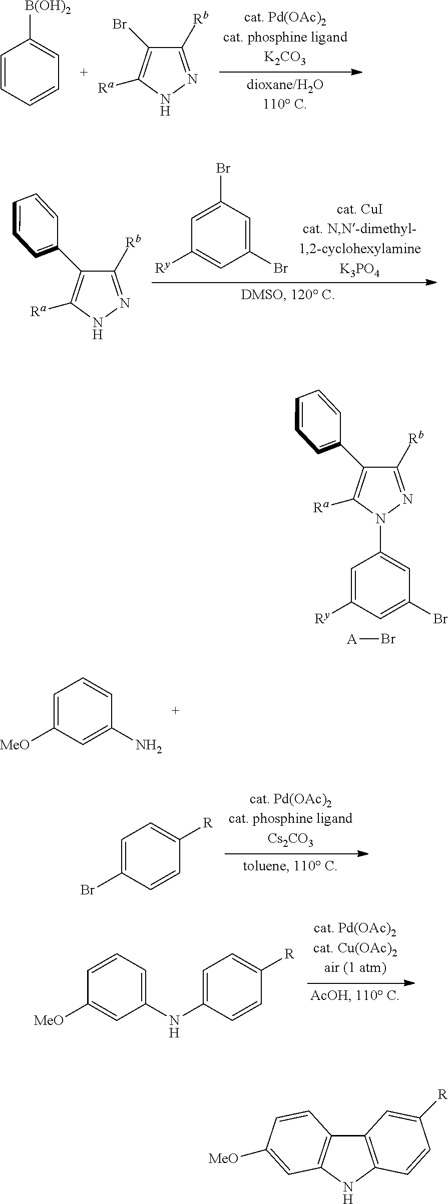

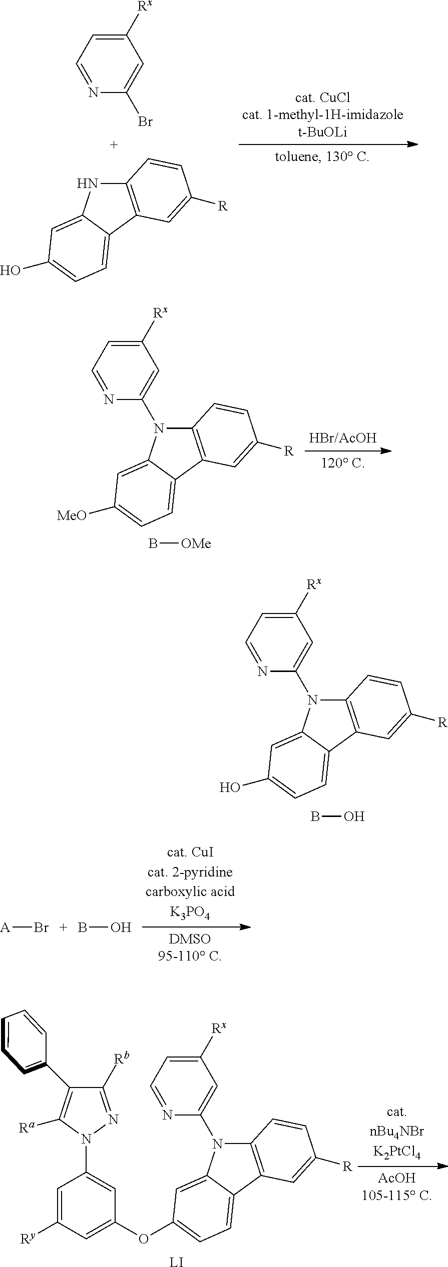

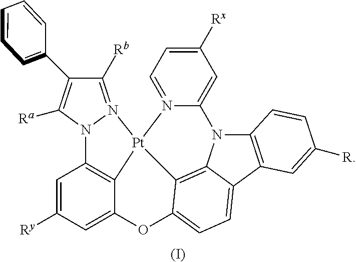

6. Use of the tetradentate cyclic-metal platinum complex comprising 6-substituted carbazole according to claim 1, in organic electroluminescent materials.

7. An optical or electrical-optical device, wherein the device comprising one or more tetradentate cyclic-metal platinum complex comprising 6-substituted carbazole according to claim 1.

8. The optical or electrical-optical device according to claim 7, wherein the device comprising a light absorbing unit, an organic light emitting diode, a light emitting device or a device that is capable of light-absorbing and light-emitting.

9. The optical or electrical-optical device according to claim 7, wherein the tetradentate cyclic-metal platinum complex comprising 6-substituted carbazole has 100% of internal quantum efficiency in the device.

10. An OLED device, wherein the luminescent material or host material in the OLED device comprising one or more tetradentate cyclic-metal platinum complex comprising 6-substituted carbazole according to claim 1.
